(19) United States
(12) Patent Application Publication
(10) Pub. No.: US 2025/0287842 A1
(43) Pub. Date: Sep. 11, 2025

(54) LIGHT EMITTING ELEMENT, POLYCYCLIC COMPOUND FOR THE SAME, AND ELECTRONIC DEVICE INCLUDING THE SAME

(71) Applicant: Samsung Display Co., Ltd., Yongin-si (KR)

(72) Inventors: MinJae SUNG, Yongin-si (KR); Hirokazu MIYASHITA, Yongin-si (KR); TAEIL KIM, Yongin-si (KR); JUNHA PARK, Yongin-si (KR); MUN-KI SIM, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 19/069,485

(22) Filed: Mar. 4, 2025

(30) Foreign Application Priority Data
Mar. 6, 2024 (KR) 10-2024-0032131

(51) Int. Cl. H10K 85/60; C07F 5/02; C09K 11/02; C09K 11/06; H10K 50/12; H10K 85/30; H10K 85/40; H10K 101/00

(52) U.S. Cl. CPC H10K 85/658; C07F 5/027; C09K 11/02; C09K 11/06; H10K 85/346; H10K 85/40; H10K 85/654; H10K 85/6572; C09K 2211/1007; C09K 2211/1014; C09K 2211/1018; C09K 2211/1022; C09K 2211/1029; C09K 2211/1044; C09K 2211/185; H10K 50/121; H10K 2101/90

(57) ABSTRACT

Embodiments provide a polycyclic compound, a light emitting element that includes the polycyclic compound, and an electronic device that includes the light emitting element. The light emitting element includes a first electrode, a second electrode disposed on the first electrode, and an emission layer disposed between the first electrode and the second electrode, and including the polycyclic compound. The polycyclic compound is represented by Formula 1, which is explained in the specification.

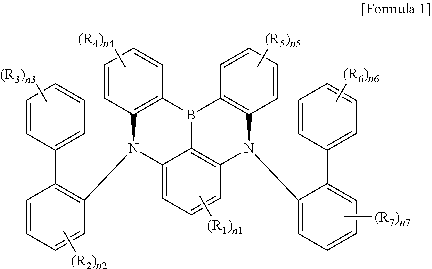

### CROSS-REFERENCE TO RELATED APPLICATION(S)

This patent application claims priority to and benefits of Korean Patent Application No. 10-2024-0032131 under 35 U.S.C. § 119, filed on Mar. 6, 2024, in the Korean Intellectual Property Office, the entire contents of which are incorporated herein by reference.

### BACKGROUND

### 1. Technical Field

The disclosure relates to a light emitting element, a polycyclic compound used therein, and an electronic device including the light emitting element.

### 2. Description of the Related Art

Ongoing development continues for an organic electroluminescence display device as an image display device. Unlike liquid crystal display devices and the like, organic electroluminescence display devices are so-called self-emissive display devices in which holes and electrons respectively injected from a first electrode and a second electrode recombine in an emission layer, so that in the emission layer, a light emitting material that includes an organic compound emits light to achieve display.

In the application of organic electroluminescence elements to display devices, there is a demand for organic electroluminescence elements having a low driving voltage, high luminous efficiency, and a long life. Thus, continuous development is required on materials for organic electroluminescence elements that are capable of stably achieving such characteristics.

In order to obtain a highly efficient organic electroluminescence element, development of technologies pertaining to phosphorescence emission, which utilizes triplet state energy, or to fluorescence emission, which utilizes triplet-triplet annihilation (TTA) in which singlet excitons are generated through collision of triplet excitons, have been conducted. Present research is directed to thermally activated delayed fluorescence (TADF) materials, which utilize a delayed fluorescence phenomena.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having improved element service life.

The disclosure also provides a polycyclic compound capable of improving the service life of a light emitting element.

The disclosure also provides a display device having excellent display quality, including a light emitting element having improved service life.

According to an embodiment, a light emitting element may include: a first electrode; a second electrode disposed on the first electrode; and an emission layer disposed between the first electrode and the second electrode and including a first compound represented by Formula 1.

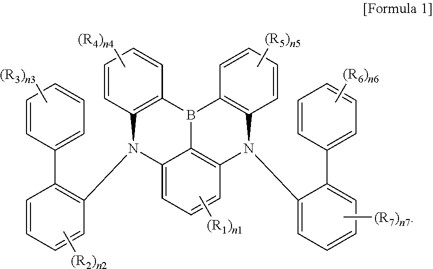

In Formula 1, R₁ to R₇ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkoxy group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n1 may be an integer from 0 to 3,
n2, n4, n5, and n7 may each independently be an integer from 0 to 4,
n3 and n6 may each independently be an integer from 0 to 5, and
at least one of R₁ to R₇ may be each independently be a group represented by Formula 2.

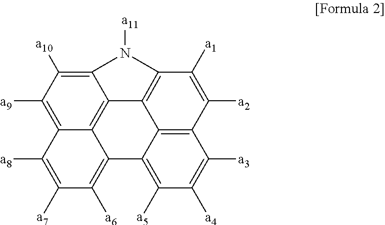

In Formula 2, one of a₁ to a₁₁ may be a position bonded to Formula 1, and
the remainder of a₁ to a₁₁ may each independently be a hydrogen atom, a deuterium atom, a substituted or unsubstituted alkyl group having 1 to 30 carbon atoms, or a substituted or unsubstituted aryl group having 6 to 30 ring-forming carbon atoms.

In an embodiment, a₁, a₃ to a₈, and a₁₀ may each independently be a hydrogen atom or a deuterium atom, a₂ and a₉ may each independently be a hydrogen atom, a deuterium atom, a substituted or unsubstituted t-butyl group, or a substituted or unsubstituted phenyl group, and a₁₁ may be a position bonded to Formula 1.

In an embodiment, the first compound may be represented by Formula 3, which is explained below.

In an embodiment, the first compound may be represented by one of Formulas 4-1 to 4-3, which are explained below.

In an embodiment, the first compound may be represented by one of Formulas 5-1 to 5-4, which are explained below.

In an embodiment, the first compound may be represented by one of Formulas 5-1-1 to 5-1-6, which are explained below.

In an embodiment, the first compound may be represented by Formula 5-2-1, which is explained below.

In an embodiment, the first compound may be represented by Formula 5-3-1, which is explained below.

In an embodiment, one or two of R₁ to R₇ may each independently be a group represented by Formula 2; and the remainder of R₁ to R₇ may each independently be a hydrogen atom, a deuterium atom, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted dibenzothiophene group, or bonded to an adjacent group to form a ring.

In an embodiment, in Formula 1, at least one of R₁ to R₇ may be a deuterium atom or may include a substituent containing a deuterium atom.

In an embodiment, the emission layer may further include at least one of a second compound represented by Formula HT-1, a third compound represented by Formula ET-1, and a fourth compound represented by Formula D-1.

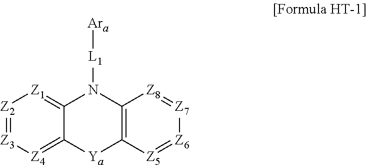

In Formula HT-1, Z₁ to Z₈ may each independently be N or C(Rₐ₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(Rₐ₂)Rₐ₃), or Si(Rₐ₄)(Rₐ₅); Arₐ may be a substituted or unsubstituted aryl group having 6 to 30 ring-forming carbon atoms, or a substituted or unsubstituted heteroaryl group having 2 to 30 ring-forming carbon atoms; and Rₐ₁ to Rₐ₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

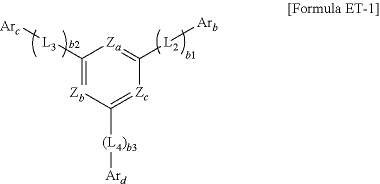

In Formula ET-1, at least one of Zₐ to Z_{c} may be N; the remainder of Zₐ to Z_{c} may each independently be C(Rₐ₆); Rₐ₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Ar_{b} to Ar_{d} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

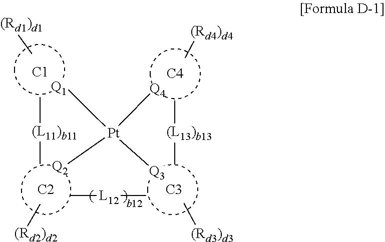

In Formula D-1, Q₁ to Q₄ may each independently be C or N; C1 to C4 may each independently be a substituted or unsubstituted hydrocarbon ring having 5 to 30 ring-forming carbon atoms, or a substituted or unsubstituted heterocycle having 2 to 30 ring-forming carbon atoms; L₁₁ to L₁₃ may each independently be a direct linkage,

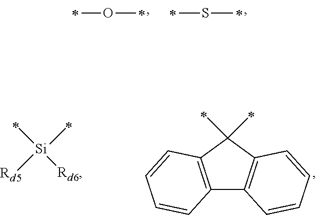

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b11 to b13 may each independently be 0 or 1; R_{d1} to R_{d6} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms; and d1 to d4 may each independently be an integer from 0 to 4.

In an embodiment, the light emitting element may further include the second compound, the third compound, and the fourth compound.

According to an embodiment, a polycyclic compound may be represented by Formula 1, which is explained herein.

In an embodiment, a₁, a₃ to a₈, and a₁₀ may each independently be a hydrogen atom or a deuterium atom, a₂ and a₉ may each independently be a hydrogen atom, a deuterium atom, a substituted or unsubstituted t-butyl group, or a substituted or unsubstituted phenyl group, and a₁₁ may be a position bonded to Formula 1.

In an embodiment, the polycyclic compound may be represented by Formula 3, which is explained below.

In an embodiment, the polycyclic compound may be represented by one of Formulas 4-1 to 4-3, which are explained below

In an embodiment, the polycyclic compound may be represented by one of Formulas 5-1 to 5-4, which are explained below.

In an embodiment, one or two of R₁ to R₇ may each independently be a group represented by Formula 2, and the remainder of R₁ to R₇ may each independently be a hydrogen atom, a deuterium atom, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, a substituted or unsubstituted dibenzothiophene group, or bonded to an adjacent group to form a ring.

In an embodiment, the polycyclic compound may have a triplet exciton lifetime less than or equal to about 2 μs.

In an embodiment, the polycyclic compound may be selected from Compound Group 1, which is explained below.

According to an embodiment, an electronic device may include a display device, and the display device may include: a circuit layer disposed on a base layer; and a display element layer disposed on the circuit layer and including a light emitting element, wherein
the light emitting element may include a first electrode, a second electrode disposed on the first electrode, and an emission layer disposed between the first electrode and the second electrode; and the emission layer may include a polycyclic compound represented by Formula 1, which is explained herein.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the inventive embodiments, and are incorporated in and constitute a part of this specification. The drawings illustrate embodiments of the disclosure and principles thereof. The above and other aspects and features of the disclosure will be more apparent by describing in detail embodiments thereof with reference to accompanying drawings, in which:

FIG. 1 is a block diagram of an electronic device according to an embodiment;

FIG. 2 shows schematic diagrams of electronic devices according to embodiments;

FIG. 3 is a schematic plan view of a display device according to an embodiment;

FIG. 4 is a schematic cross-sectional view of a display device according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a light emitting element according to an embodiment;

FIG. 8 is a schematic cross-sectional view of a light emitting element according to an embodiment;

FIG. 9 is a schematic cross-sectional view of a light emitting element according to an embodiment;

FIGS. 10A to 10D are each a diagram of an energy level of a polycyclic compound;

FIGS. 11 and 12 are each a schematic cross-sectional view of a display device according to an embodiment;

FIG. 13 is a schematic cross-sectional view of a display device according to an embodiment;

FIG. 14 is a schematic cross-sectional view of a display device according to an embodiment; and

FIG. 15 is a schematic diagram of a vehicle in which a display device according to an embodiment is disposed.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring, or a substituted or unsubstituted heterocycle. A hydrocarbon ring may be aliphatic or aromatic. A heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in the alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

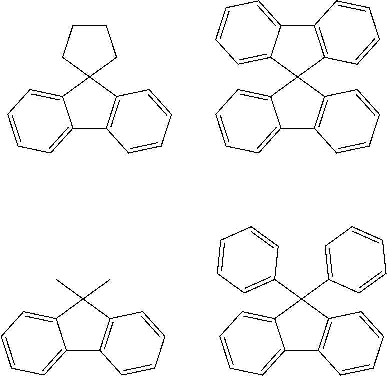

In the specification, the heterocyclic group may be any functional group or substituent derived from a ring that includes at least one of B, O, N, P, Si, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

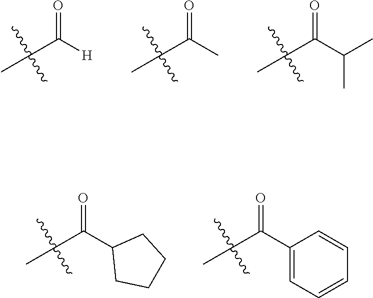

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may mean be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or to an aryl group as defined above. An oxy group may include an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

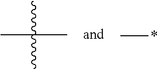

each represent a bond to a neighboring atom in a corresponding formula or moiety.

Hereinafter, embodiments will be described with reference to the accompanying drawings.

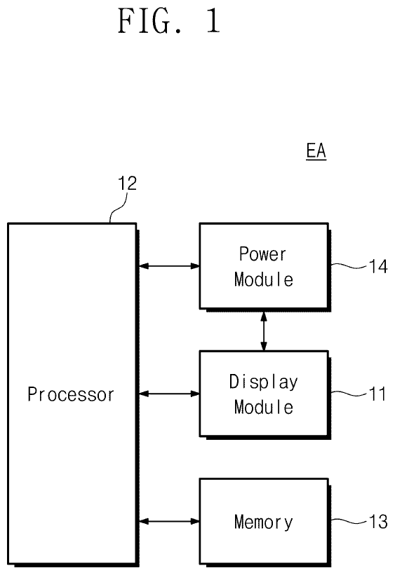

FIG. 1 is a block diagram of an electronic device according to an embodiment. Referring to FIG. 1, an electronic device EA according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and information for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts power supplied by the power supply module to generate power for the operation of the electronic device EA.

At least one module of the electronic device EA as described above may be included in the display device according to an embodiment as described herein. In embodiments, some individual components that are functionally included in a module may be included in the display device, and other components may be provided separately from the display device. For example, the display device may include the display module 11, and the processor 12, the memory 13, and the power module 14 may be provided within the electronic device EA, apart from the display device.

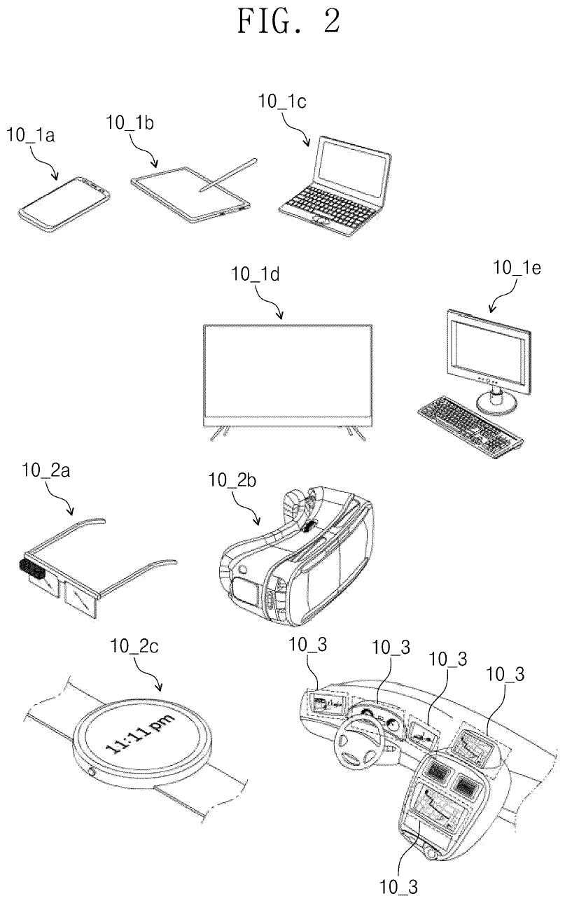

FIG. 2 shows schematic diagrams of electronic devices according to various embodiments.

Referring to FIG. 2, examples of electronic devices that include a display device according to an embodiment may include electronic devices for displaying images, such as a smartphone 10_1a, a tablet computer 10_1b, a laptop computer 10_1c, a television 10_1d, and a desktop monitor 10_1e. Further examples of electronic devices that include a display device according to an embodiment may include wearable electronic devices that include a display module such as smart glasses 10_2a, a head-mounted display 10_2b, and a smart watch 10_2c, as well as vehicle electronic devices 10_3 that include display modules such as a vehicle instrument panel, a center fascia, a center information display (CID) disposed on a dashboard, and a mirror display.

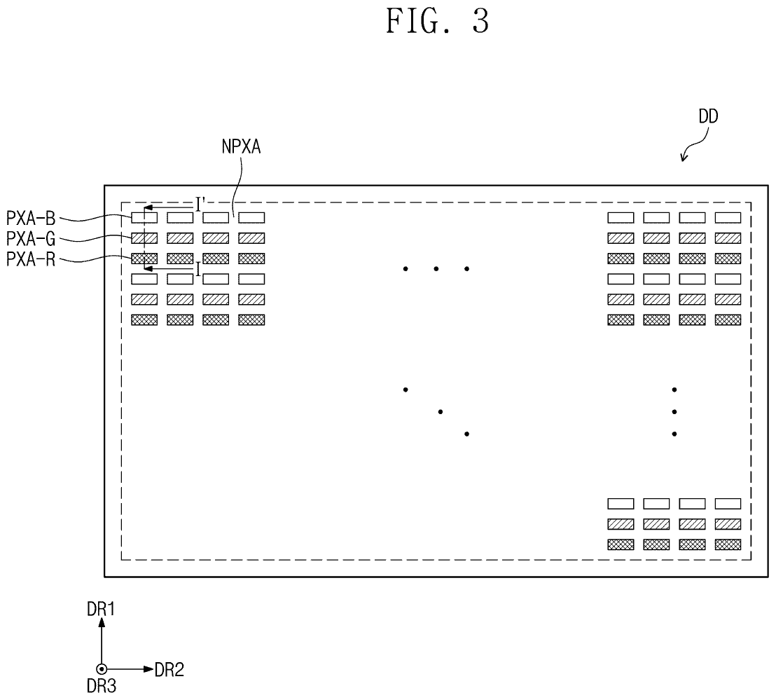

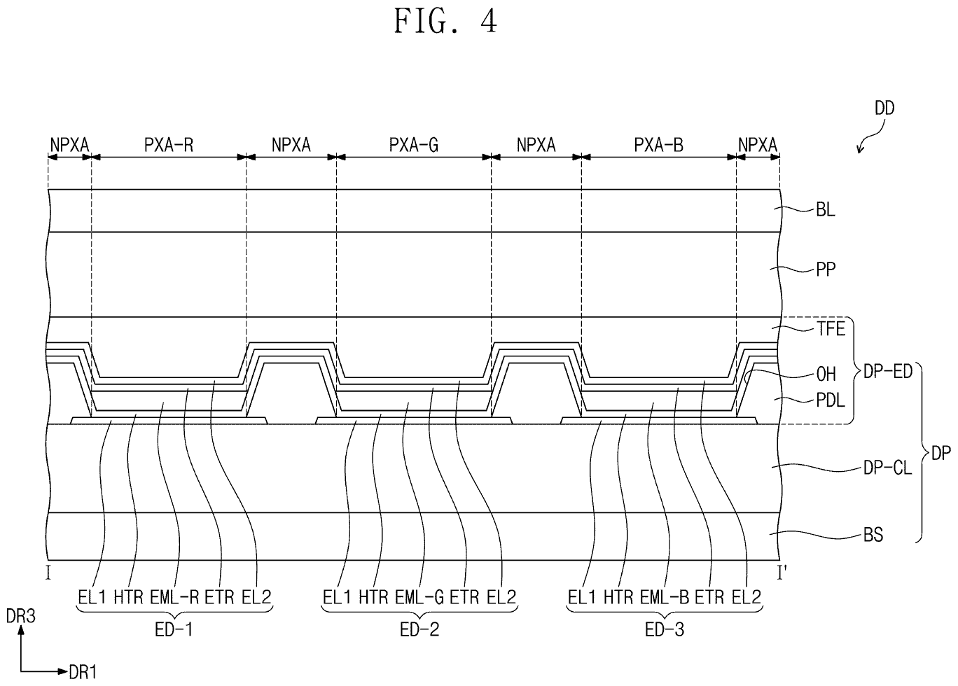

FIG. 3 is a schematic plan view of a display device DD according to an embodiment. FIG. 4 is a schematic cross-sectional view of a display device DD according to an embodiment. FIG. 4 is a schematic cross-sectional view of a portion of the display device DD taken along a virtual line I-I′ in FIG. 3. The display device DD according to an embodiment may be included in the electronic device EA as described above. The display device DD may be a part that provides an image in the electronic device EA.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

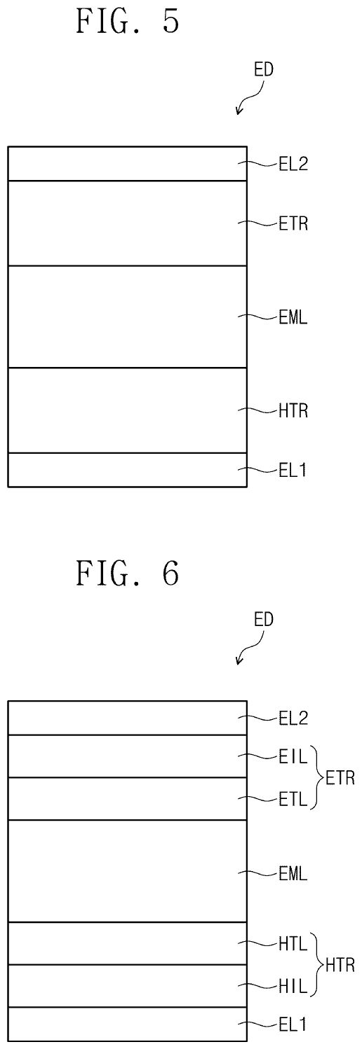

The light emitting elements ED-1, ED-2, and ED-3 may each have a structure of a light emitting element ED of an embodiment according to any one of FIGS. 5 to 9, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 4 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the entire light emitting elements ED-1, ED-2, and ED-3. However, embodiments are not limited thereto. Although not shown in FIG. 4, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may be provided by being patterned through an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the opening OH.

Referring to FIGS. 3 and 4, the display device DD may include a non-light emitting region NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 3 and 4, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B which are distinct from each other.

In the display device DD according to an embodiment, the light emitting elements ED-1, ED-2 and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit a light in a wavelength range that is different from the remainder. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 3, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 3 and 4 illustrate that the light emitting regions PXA-R, PXA-G, and PXA-B all have a similar area, but embodiments are not limited thereto. In an embodiment, the light emitting regions PXA-R, PXA-G, and PXA-B may be different in shape or size from each other according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 3, and the order in which the red light emitting region PXA-R, the green light emitting region PXA-G, and the blue light emitting region PXA-B are arranged may be provided in various combinations according to the display quality characteristics that are required in the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 5 to FIG. 9 are each a schematic cross-sectional view of a light emitting element according to an embodiment. A light-emitting element ED according to an embodiment may include a first electrode EL1, a second electrode EL2 facing the first electrode EL1, and at least one functional layer disposed between the first electrode EL1 and the second electrode EL2. The light-emitting element ED according to an embodiment may include a polycyclic compound according to an embodiment, which will be described later, in at least one functional layer.

The light emitting element ED may include a hole transport region HTR, an emission layer EML, an electron transport region ETR, etc., which are stacked as the at least one functional layer. For example, the light emitting element ED according to an embodiment may include a first electrode EL1, a hole transport region HTR, an emission layer EML, an electron transport region ETR, and a second electrode EL2, which are stacked in that order.

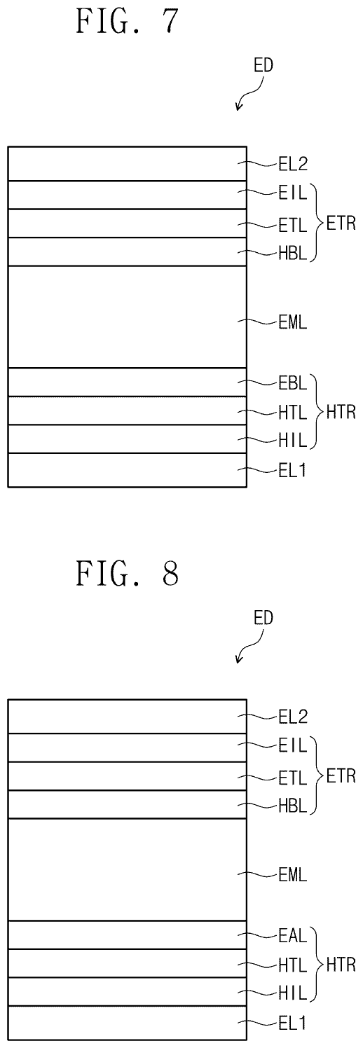

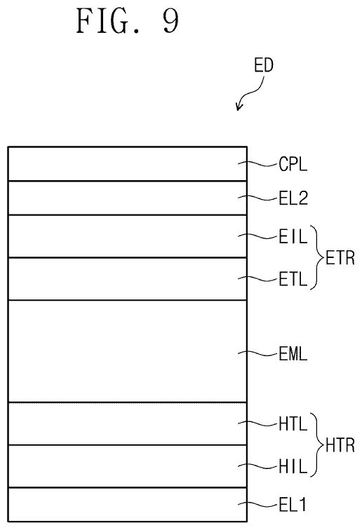

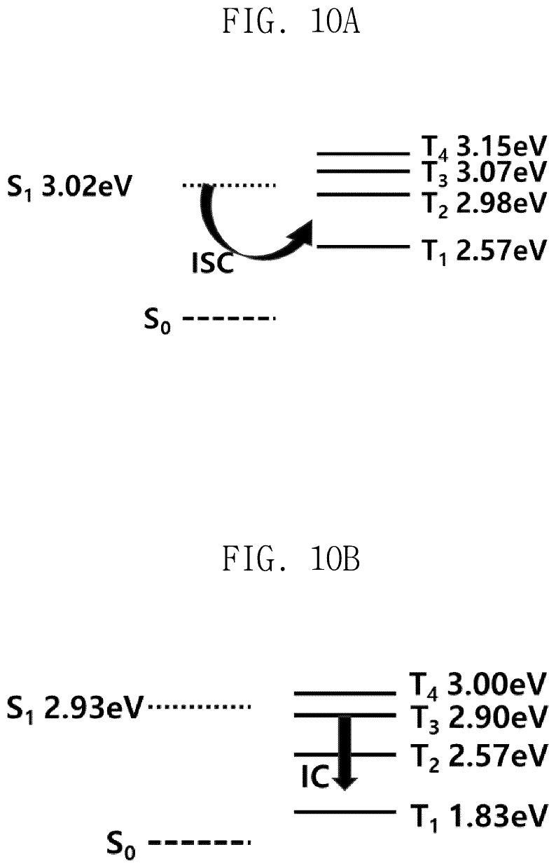

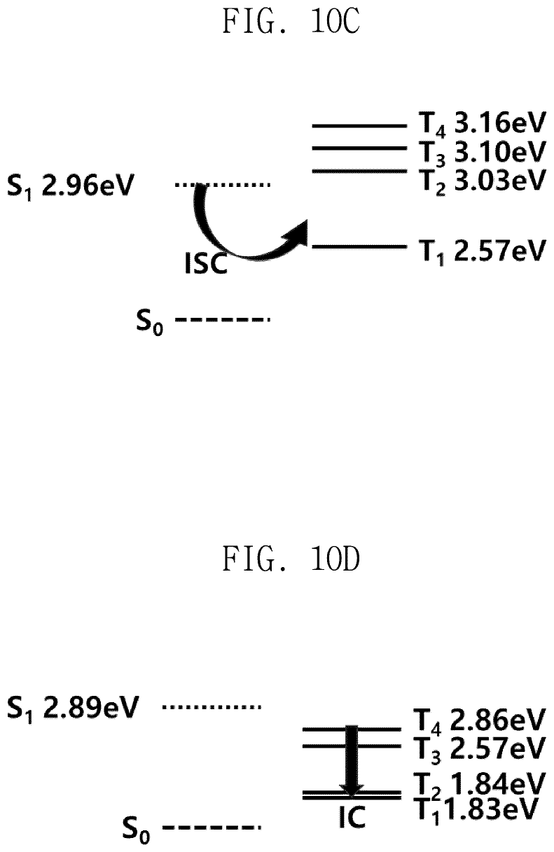

In comparison to FIG. 5, FIG. 6 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 5, FIG. 7 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. FIG. 8 is, in comparison to FIG. 5, a schematic cross-sectional view of a light emitting element ED according to an embodiment in which the hole transport region HTR includes a hole injection layer HIL, a hole transport layer HTL, and an auxiliary emission layer EAL, and the electron transport region ETR includes an electron injection layer EIL, an electron transport layer ETL, and a hole blocking layer HBL. In comparison to FIG. 6, FIG. 9 is a schematic cross-sectional view of a light emitting element ED according to an embodiment that includes a capping layer CPL disposed on a second electrode EL2.

The light emitting element ED may include a polycyclic compound according to an embodiment, which will be described later, in at least one functional layer included in the light emitting element ED. The light emitting element ED may include a polycyclic compound according to an embodiment, which will be described later, in at least one of the hole transport region HTR, the emission layer EML, or the electron transport region ETR. For example, in the light emitting element ED, the emission layer EML may include a polycyclic compound.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof or a mixture thereof (e.g., a mixture of Ag and Mg). In another embodiment, the first electrode EL1 may have a multilayered structure including a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be from about 700 Å to about 10,000 Å. For example, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer formed of a single material, a structure consisting of a layer including different materials, or a structure including multiple layers including different materials.

For example, the hole transport region HTR may have a single-layered structure of a hole injection layer HIL or a hole transport layer HTL, or may have a single-layered structure formed of a hole injection material and a hole transport material. In an embodiment, the hole transport region HTR may have a single-layered structure including different materials, or may have a structure in which a hole injection layer HIL/hole transport layer HTL, a hole injection layer HIL/hole transport layer HTL/auxiliary emission layer EAL, a hole injection layer HIL/auxiliary emission layer EAL, a hole transport layer HTL/auxiliary emission layer EAL, a hole injection layer HIL/hole transport layer HTL/auxiliary emission layer EAL/electron blocking layer EBL, or a hole injection layer HIL/hole transport layer HTL/electron blocking layer EBL are stacked in its respectively stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

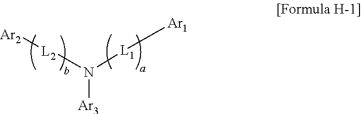

In Formula H-1, L₁ and L₂ may be each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may be each independently be an integer from 0 to 10. When a or b is 2 or greater, multiple L₁ and multiple L₂ may be each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may be each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be a compound selected from Compound Group H. However, the compounds listed in Compound Group H are only examples, and a compound represented by Formula H-1 is not limited to Compound Group H:

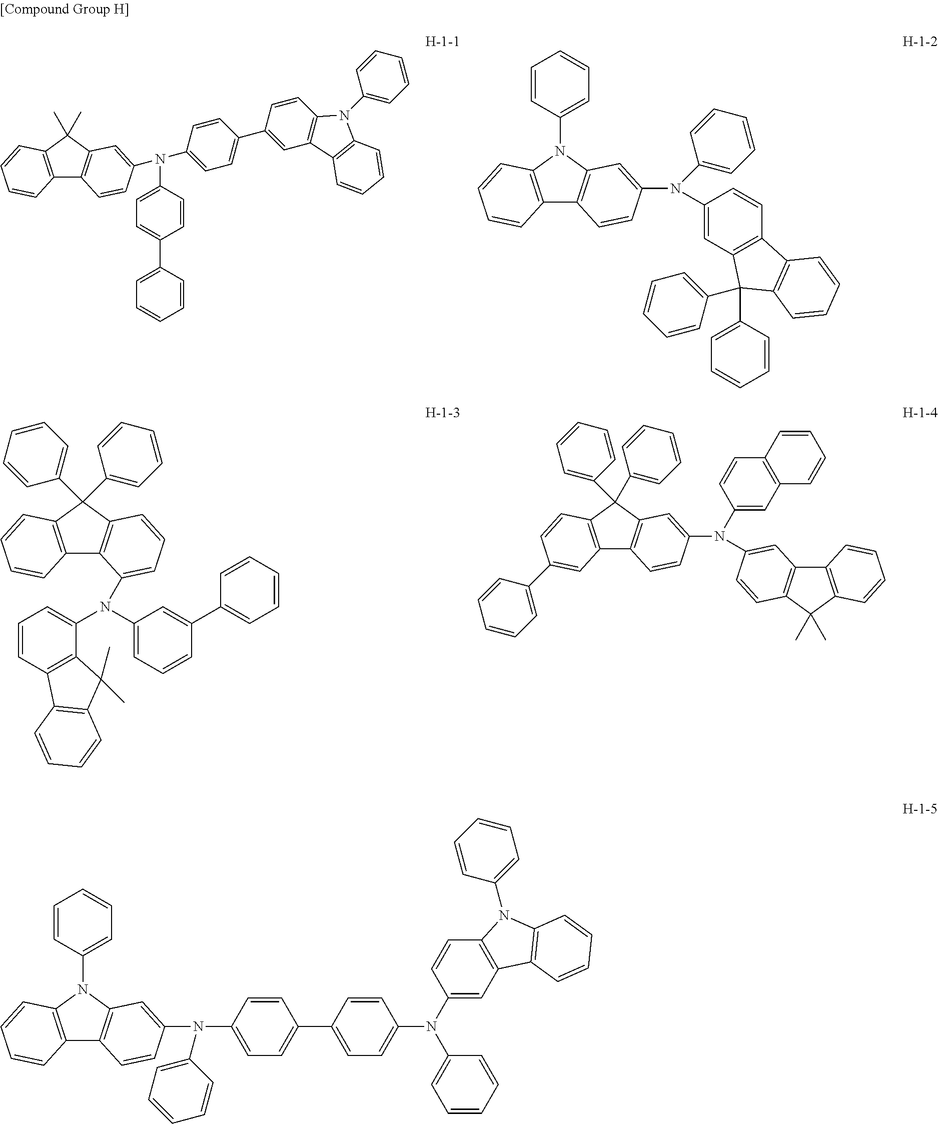 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

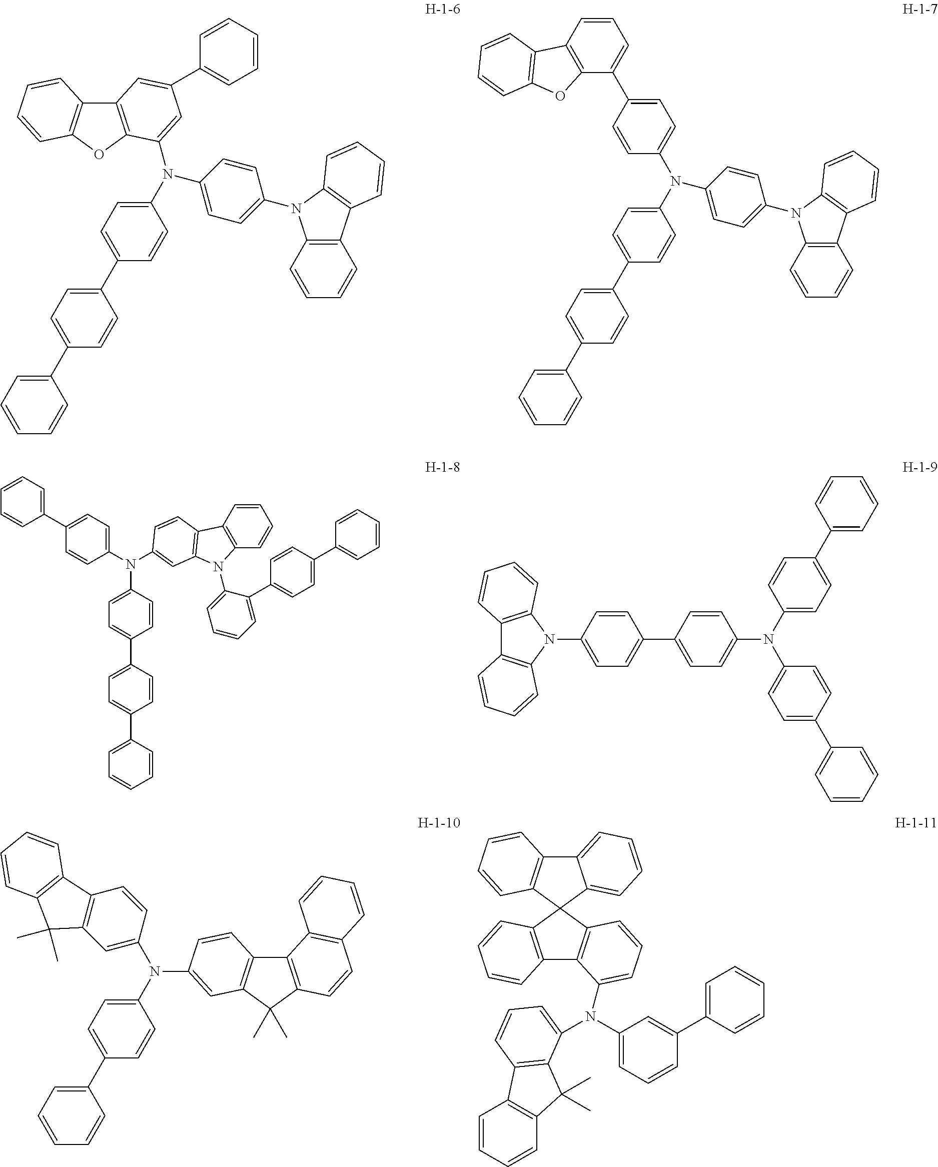

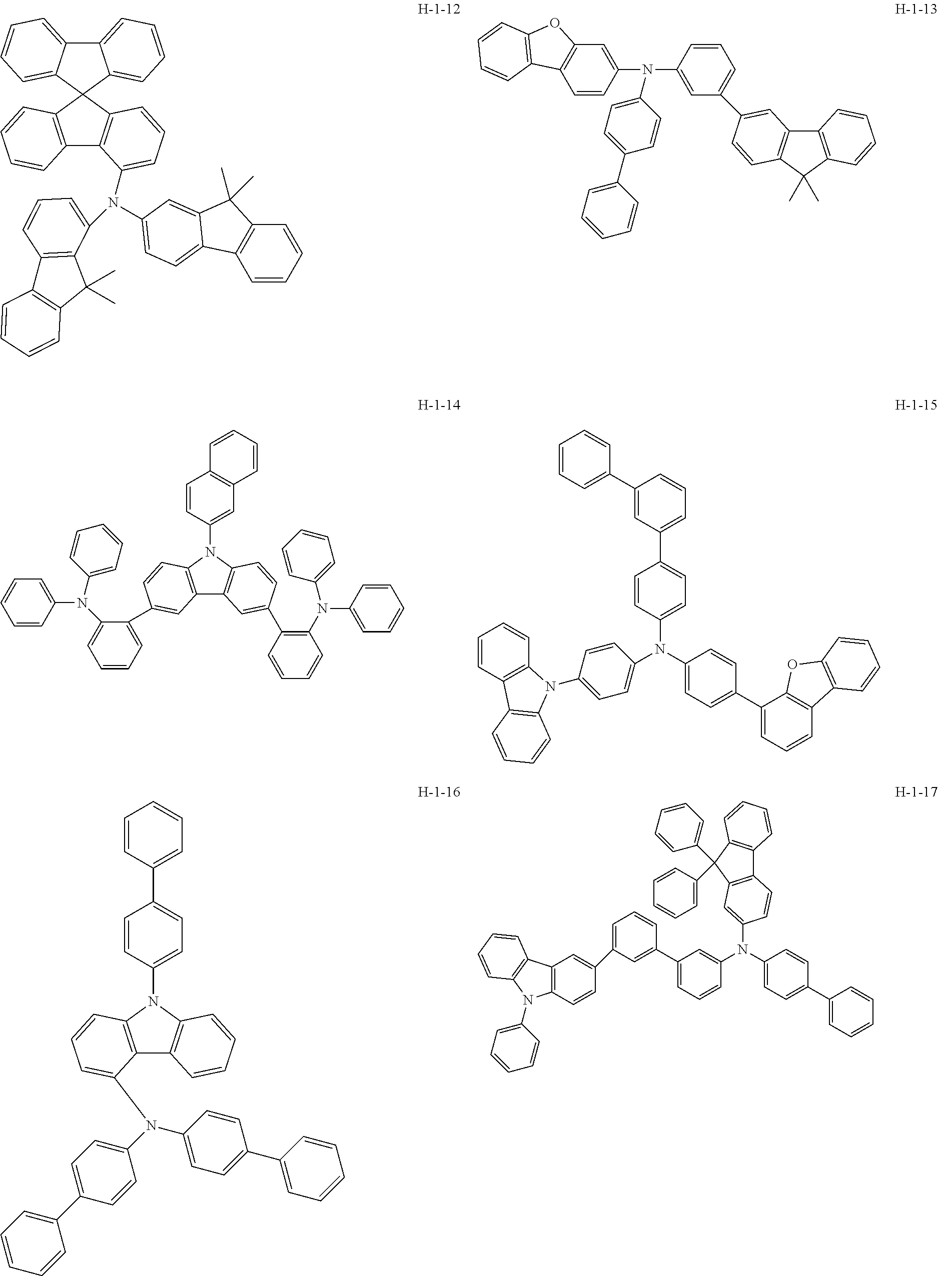

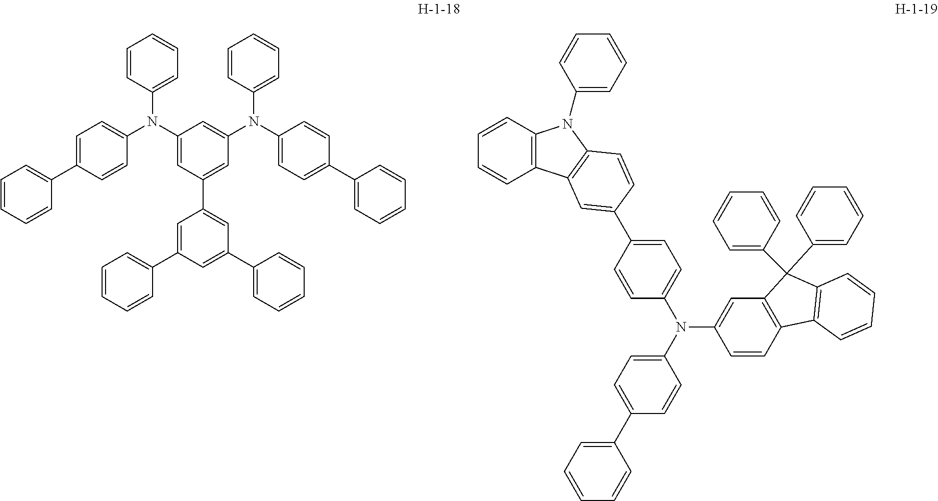 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an auxiliary emission layer EAL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, a thickness in a range of about 30 Å to about 1,000 Å. When the hole transport region HTR includes s hole transport layer HTL, the hole transport layer HTL may have a thickness in s range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of an auxiliary emission layer EAL and an electron blocking layer EBL in addition to the hole injection layer HIL and the hole transport layer HTL. The auxiliary emission layer EAL may compensate for a resonance distance according to a wavelength of light emitted from the emission layer EML and increase a light emission efficiency by controlling the hole charge balance. In an embodiment, the auxiliary emission layer EAL can also play a role in preventing electron injection into the hole transport region HTR. A material that may be included in the hole transport region HTR may be used as a material to be included in the auxiliary emission layer EAL. The electron blocking layer EBL may prevent the injection of electrons from an electron transport region ETR to the hole transport region HTR.

The emission layer EML may be provided on the hole transport region HTR. The emission layer EML may have a thickness in a range of, for example, about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

In the light emitting element ED according to an embodiment, the emission layer EML may include the polycyclic compound. In the light emitting element ED, the emission layer EML may include the polycyclic compound according to an embodiment, and may further include at least one of a second compound, a third compound, and a fourth compound. The second compound may include a fused ring of three rings, which contains a nitrogen atom as a ring-forming atom. The third compound may include a C6-ring group containing at least one nitrogen atom as a ring-forming atom. The fourth compound may include an organometallic complex. The second to fourth compounds will be described in more detail below.

In the specification, the first compound may be referred to as a polycyclic compound. The polycyclic compound according to an embodiment may include, as a central structure, a fused ring of five rings, which contains two nitrogen (N) atoms and one boron (B) atom as ring-forming atoms. In the specification, the central structure of the fused ring of five rings may be referred to as a “core”.

The polycyclic compound may have a structure in which first to third aromatic rings are fused through a first nitrogen atom, a second nitrogen atom, and a boron atom. The first aromatic ring may be linked to all of the first nitrogen atom, the second nitrogen atom, and the boron atom. The second aromatic ring may be linked to the first aromatic ring through the boron atom and the first nitrogen atom. The first aromatic ring may be linked to the third aromatic ring through the boron atom and the second nitrogen atom. In an embodiment, the first to third aromatic rings may each be linked to the boron atom.

The polycyclic compound according to an embodiment may include a phenanthro-carbazole group linked to the core. Accordingly, the polycyclic compound according to an embodiment locks electron density in the core and allows delayed fluorescence properties to be further improved in the core, and may thus have excellent electrical properties, high charge transport and luminescence capacity, and a high glass transition temperature, and prevent crystallization.

In an embodiment, the polycyclic compound may include at least one phenanthro-carbazole group. Accordingly, the polycyclic compound may better protect the core exhibiting multi-resonance characteristics and reduce exciton decay to other subpathways. For example, the boron atom of the core has electron-deficient properties due to vacant p-orbital, and may thus be bonded to nucleophiles and be modified into a tetrahedral structure from the trigonal bond structure thereof, but the polycyclic compound according to an embodiment includes a sterically bulky substituent, that is, a phenanthro-carbazole group, and may thus allow the boron atom of the core to effectively keep a trigonal bond structure. In an embodiment, the polycyclic compound containing a phenanthro-carbazole group may relatively increase intermolecular distance, contributing to increasing the lifetime of the light emitting element ED. In an embodiment, the polycyclic compound may include a first substituent and a second substituent, which are linked to the core. The first substituent and the second substituent may be linked to the first nitrogen atom and the second nitrogen atom forming the core. The first substituent may be linked to the first nitrogen atom, and the second substituent may be linked to the second nitrogen atom. The first substituent and the second substituent may each include a benzene moiety, and a sub-substituent substituted on carbon at a specific position of the benzene moiety. For example, the first substituent and the second substituent may each include a benzene moiety linked to the nitrogen atom of the core, and a structure in which a sub-substituent is linked to the benzene moiety at a position ortho to the nitrogen atom of the core. The sub-substituent may be a substituted or unsubstituted phenyl group, a substituted or unsubstituted dibenzofuran group, and/or a substituted or unsubstituted dibenzothiophene group.

The light emitting element ED according to an embodiment may include a polycyclic compound according to an embodiment. The polycyclic compound according to an embodiment may be represented by Formula 1. In the polycyclic compound represented by Formula 1, a benzene ring to which R₁ is linked may correspond to the first aromatic ring described above, a benzene ring to which R₄ is linked may correspond to the second aromatic ring described above, a benzene ring to which R₅ is linked may correspond to the third aromatic ring described above. In an embodiment, in the polycyclic compound represented by Formula 1, a benzene ring to which R₂ is linked may correspond to the first substituent, and a benzene ring to which R₇ is linked may correspond to the second substituent. A benzene ring to which R₃ is linked and a benzene ring to which R₆ is linked may correspond to the sub-substituents described above.

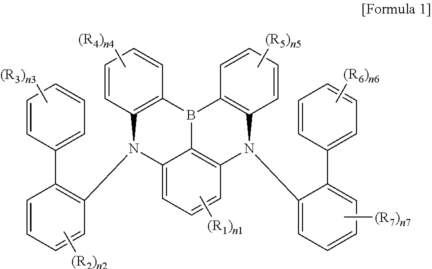

In Formula 1, R₁ to R₇ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkoxy group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms. For example, R₁ to R₇ may each independently be a hydrogen atom, a deuterium atom, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted dibenzothiophene group.

In another embodiment, in Formula 1, R₁ to R₇ may each independently be bonded to an adjacent group to form a ring. For example, two adjacent R₃ may be bonded to form a fused ring containing a heteroatom such as O and S, and two adjacent R₆ may be bonded to form a fused ring containing a hetero atom such as O and S.

In Formula 1, n1 may be an integer from 1 to 3. When n1 is 0, the polycyclic compound according to an embodiment may not be substituted with R₁. In Formula 1, When n1 is 3, and three R₁ are all hydrogen atoms, the case may be the same as when n1 is 0 in Formula 1. When n1 is 2 or greater, multiple R₁ may all be the same, or at least one of the R₁ may be different.

In Formula 1, n2, n4, n5, and n7 may each independently be an integer from 0 to 4. When n2, n4, n5, and n7 are each 0, the polycyclic compound according to an embodiment may not be substituted with each of R₂, R₄, R₅, and R₇. In Formula 1, when n2, n4, n5, and n7 are each 4, and multiple R₂, R₄, R₅, and R₇ are all hydrogen atoms, the case may be the same as when n2, n4, n5, and n7 are each 0 in Formula 1. When n2, n4, n5, and n7 are each 2 or greater, multiples of each of R₂, R₄, R₅, and R₇ may all be the same, or at least one of R₂, R₄, R₅, or R₇ may be different.

In Formula 1, n3 and n6 may each independently be an integer from 0 to 5. When n3 and n6 are each 0, the polycyclic compound according to an embodiment may not be substituted with each of R₃ and R₆. In Formula 1, when n3 and n6 are each 5 and R₃ and R₆ are all hydrogen atoms, the case may be the same as when n3 and n6 are each 0 in Formula 1. When n3 and n6 are each 2 or greater, multiples of each of R₃ and R₆ may all be the same, or at least one of R₃ or R₆ may be different.

In Formula 1, at least one of R₁ to R₇ may each independently be a group represented by Formula 2. For example, one or two of R₁ to R₇ may each independently be a group represented by Formula 2. The polycyclic compound according to an embodiment includes at least one phenanthro-carbazole group represented by Formula 2, and may thus increase relative intermolecular distance, thereby inhibiting intermolecular interactions that may cause a decrease in luminous efficiency.

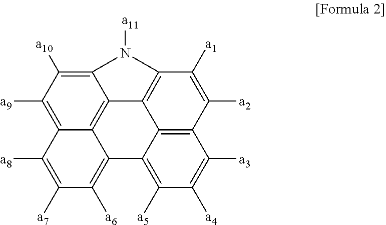

In Formula 2, one of a₁ to a₁₁ may be a position bonded to Formula 1. The remainder of a₁ to a₁₁, which are not bonded to Formula 1, may each independently be a hydrogen atom, a deuterium atom, a substituted or unsubstituted alkyl group having 1 to 30 carbon atoms, or a substituted or unsubstituted aryl group having 6 to 30 ring-forming carbon atoms. For example, a₁₁ may be a position bonded to Formula 1. However, embodiments are not limited thereto, and any one of a₁ to a₁₀ may be a position bonded to Formula 1.

In an embodiment, a₁₁ in Formula 2 may be a position bonded to Formula 1. In Formula 2, a₁ to a₁₀ which are not bonded to Formula 1 may each independently be a hydrogen atom, a deuterium atom, a substituted or unsubstituted t-butyl group, or a substituted or unsubstituted phenyl group. For example, a₁ to a₁₀ may all be hydrogen atoms or deuterium atoms. In another embodiment, a₁, a₃ to a₈, and a₁₀ may each independently be a hydrogen atom or a deuterium atom, and a₂ and a₉ may each independently be a hydrogen atom, a deuterium atom, a substituted or unsubstituted t-butyl group, or a substituted or unsubstituted phenyl group.

The polycyclic compound according to an embodiment represented by Formula 1 includes a phenanthro-carbazole group directly linked to the core or linked to the core through a first substituent and/or a second substituent, and represented by Formula 2, and may thus achieve long service life of the light emitting element ED.

One of the critical factors causing low lifetime in elements using thermally activated delayed fluorescence is a low rate of reverse inter-system crossing (RISC) in thermally activated delayed fluorescence (TADF) emitters. In accordance with the El-sayed rule, a spin-orbit coupling constant between a lowest excited singlet energy level (S1 energy level) and a lowest excited triplet energy level (T1 energy level) is close to 0, and accordingly, a direct transition between a lowest excited singlet energy level (Si energy level) and a lowest excited triplet energy level (T1 energy level) hardly occurs, and this allows a complex inter-system crossing (ISC) mechanism via a higher-order excited triplet energy level (Tn energy level, where n is 2 or greater) to be used. In an embodiment, exciton quenching, such as accumulated triplet exciton collision, takes place, causing degradation in the lifetime of organic light emitting elements.

The polycyclic compound according to an embodiment includes a structure in which at least one phenanthro-carbazole group is linked to a multiple resonance core, and thus reduces the higher-order excited triplet energy level (Tn energy level), and accordingly, may suppress complex inter-system crossing (ISC) from the S1 energy level to the Tn energy level even when RISC is reduced. In an embodiment, the polycyclic compound reduces the Tn energy level and thus induces a fast inter-conversion (IC) from Tn energy level to the T1 energy level, and accordingly, may reduce the concentration of triplet exciton accumulated in emitters, thereby achieving long lifetime of the light emitting element ED. In an embodiment, the polycyclic compound may have a low T1 energy level, and thus the triplet exciton at the Tn energy level transferred to the emitters is quenched through a non-luminescent transition without going through RISC, resulting in reduced triplet exciton lifetime (Tau). For example, in the polycyclic compound according to an embodiment, the T1 energy level may be less than or equal to about 1.9 eV. The polycyclic compound according to an embodiment may have a short triplet exciton lifetime less than or equal to about 2 μs (microsecond). For example, the polycyclic compound according to an embodiment may have a short triplet exciton lifetime in a range of about 1.2 μs to about 2 μs, and may thus be suitable to be used as a TADF material.

In an embodiment, the polycyclic compound may effectively keep a trigonal planar structure of the boron atom through a steric hindrance effect from the first and second substituents to which each sub-substituent is linked. As described above, the boron atom may have electron-deficient properties due to vacant p-orbital, and may thus be bonded to other nucleophiles and be modified into a tetrahedral structure, which may result in deterioration of an element. According to an embodiment, in the polycyclic compound, as the first substituent and the second substituent are introduced into the nitrogen atom of the core, the vacant p-orbital of the boron atom may be effectively protected, and accordingly, the deterioration caused by the structural deformation may be prevented.

In the polycyclic compound according to an embodiment, the steric hindrance effect caused by a phenanthro-carbazole group, the first substituent, and the second substituent may suppress intermolecular interactions to control aggregation, excimer formation, or exciplex formation, resulting in greater luminous efficiency. In the polycyclic compound of an embodiment, intermolecular aggregation is prevented, resulting in improved solubility to promote purification of the compound, and stability related to thermal comminution upon sublimation purification may be ensured. In an embodiment, the polycyclic compound may exhibit high color purity due to the fact that wavelength of emission spectrum measured in solution and wavelength of emission spectrum measured from a deposited film are the same.

The polycyclic compound according to an embodiment represented by Formula 1 has a bulky structure and thus widens the intermolecular distance to reduce dexter energy transfer, and accordingly, an increase in the concentration of triplet exciton in the polycyclic compound may be prevented. The triplet exciton at a high concentration remains in an excited state for a long period of time and may thus cause compound decomposition, and may induce hot exciton having high energy generated through triplet-triplet annihilation (TTA) to cause surrounding compound structures to collapse. In an embodiment, the triplet-triplet annihilation is a bimolecular reaction that fast-quenches the triplet exciton used for light emission, and may thus cause a decrease in luminous efficiency as a non-radiative transition. In an embodiment of the polycyclic compound, the intermolecular distance is increased through the substituents linked to the core to suppress the dexter energy transfer, and accordingly, service life deterioration caused by an increase in triplet concentration may be suppressed. Accordingly, when the polycyclic compound according to an embodiment is applied to the emission layer EML of the light emitting element ED, the luminous efficiency may be increased and the element service life may also be improved.

In an embodiment, the polycyclic compound represented by Formula 1 may be represented by Formula 3. In Formula 3, R₁, R₃ to R₆, n1, and n3 to n6 may be the same as described in Formula 1.

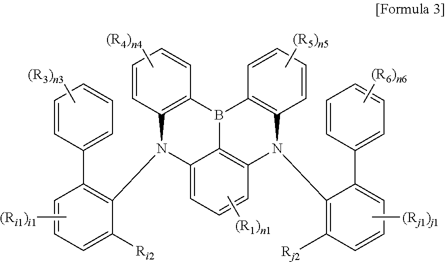

In Formula 3, Rᵢ₁ and Rⱼ₁ may each independently be a hydrogen atom, a deuterium atom, a substituted or unsubstituted alkyl group having 1 to 60 carbon atoms, or a substituted or unsubstituted aryl group having 6 to 60 ring-forming carbon atoms. For example, Rᵢ₁ and Rⱼ₁ may each independently be a hydrogen atom, a deuterium atom, a substituted or unsubstituted t-butyl group, or a substituted or unsubstituted phenyl group.

In Formula 3, Rᵢ₂ and Rⱼ₂ may each independently be a substituted or unsubstituted aryl group having 6 to 60 ring-forming carbon atoms, or a substituted or unsubstituted heteroaryl group having 2 to 60 ring-forming carbon atoms. For example, Rᵢ₂ and Rⱼ₂ may each independently be a substituted or unsubstituted phenyl group, a substituted or unsubstituted biphenyl group, a substituted or unsubstituted dibenzofuran group, or a substituted or unsubstituted dibenzothiophene group, or a substituted or unsubstituted phenanthro-carbazole group.

In Formula 3, i1 and j1 may each independently be an integer from 0 to 3. When i1 and j1 are each 0, the polycyclic compound according to an embodiment may not be substituted with each of Rᵢ₁ and Rⱼ₁. In Formula 1, when i1 and j1 are each 3 and Rᵢ₁ and Rⱼ₁ are all hydrogen atoms, the case may be the same as when i1 and j1 are each 0 in Formula 3. When i1 and j1 are each 2 or greater, multiples of each of Rᵢ₁ and Rⱼ₁ may all be the same, or at least one of Rᵢ₁ or Rⱼ₁ may be different.

In Formula 3, at least one of R₁, R₃ to R₆, Rᵢ₂, and Rⱼ₂ may each independently be a group represented by Formula 2. In an embodiment, one or two of R₁, R₃ to R₆, Rᵢ₂, and Rⱼ₂ may each independently be a group represented by Formula 2. For example, one of R₁, R₃ to R₆, Rᵢ₂, and Rⱼ₂ may be a group represented by Formula 2. For another example, any two of R₁, R₃ to R₆, Rᵢ₂, and Rⱼ₂ may each independently be a group represented by Formula 2. In an embodiment, the polycyclic compound represented by Formula 1 may be represented by one of Formulas 4-1 to 4-3. In Formulas 4-1 to 4-3, R₂, R₃, R₆, R₇, n2, n3, n6, and n7 may be the same as described in Formula 1.

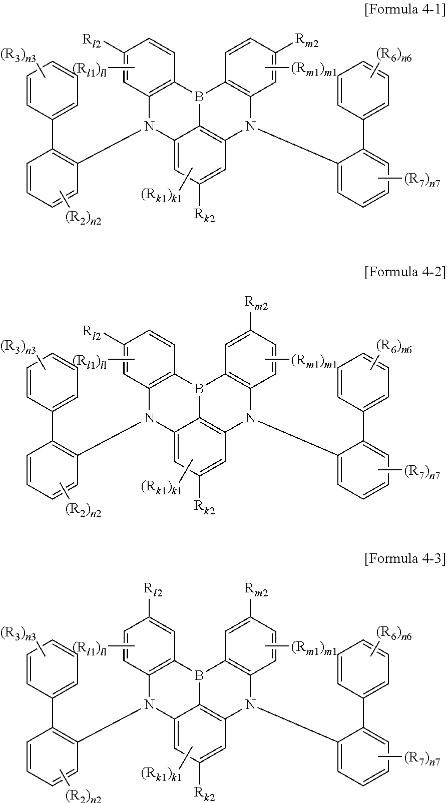

In Formulas 4-1 to 4-3, Rₖ₁, Rₗ₁, and Rₘ₁ may each independently be a hydrogen atom, a deuterium atom, a substituted or unsubstituted alkyl group having 1 to 60 carbon atoms, or a substituted or unsubstituted aryl group having 6 to 60 ring-forming carbon atoms. For example, Rₖ₁, Rₗ₁, and Rₘ₁ may all be hydrogen atoms. However, embodiments are not limited thereto. For example, at least one of Rₖ₁, Rₗ₁, or Rₘ₁ may be a deuterium atom.

In Formulas 4-1 to 4-3, Rₖ₂, Rₗ₂, and Rₘ₂ may each independently be a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms. For example, Rₖ₂, Rₗ₂, and Rₘ₂ may each independently be a substituted or unsubstituted t-butyl group, a substituted or unsubstituted phenyl group, a substituted or unsubstituted carbazole group, a substituted or unsubstituted dibenzofuran group, a substituted or unsubstituted dibenzothiophene group, or a substituted or unsubstituted phenanthro-carbazole group.

In Formulas 4-1 to 4-3, k1 may be an integer from 0 to 2. When k1 is 0, the polycyclic compound according to an embodiment may not be substituted with Rₖ₁. In Formula 1, when k1 is 2 and two Rₖ₁ are all hydrogen atoms, the case may be the same as when k1 is 0 in Formula 1. When k1 is 2, two Rₖ₁ may all be the same, or one of the two Rₖ₁ may be different from the other Rₖ₁.

In Formulas 4-1 to 4-3, 11 and m1 may each independently be an integer from 0 to 3. When l1 and m1 are each 0, the polycyclic compound according to an embodiment may not be substituted with each of Rₗ₁ and Rₘ₁. In Formulas 4-1 to 4-3, when l1 and m1 are each 3 and each of three Rₗ₁ and Rₘ₁ are all hydrogen atoms, the case may be the same as when l1 and m1 are each 0 in Formulas 4-1 to 4-3. When l1 and m1 are each 2 or greater, multiples of each Rₗ₁ and Rₘ₁ may all be the same, or at least one of Rₗ₁ or Rₘ₁ may be different.

In Formulas 4-1 to 4-3, at least one of R₂, R₃, R₆, R₇, Rₖ₂, Rₗ₂, and Rₘ₂ may each independently be a substituted or unsubstituted phenanthro-carbazole group. For example, at least one of R₂, R₃, R₆, R₇, Rₖ₂, Rₗ₂, and Rₘ₂ may each independently be a group represented by Formula 2. In an embodiment, one or two of R₂, R₃, R₆, R₇, Rₖ₂, Rₗ₂, and Rₘ₂ may each independently be a group represented by Formula 2.

For example, in Formulas 4-1 to 4-3, one of R₂, R₃, R₆, R₇, Rₖ₂, Rₗ₂, and Rₘ₂ may be a group represented by Formula 2. In an embodiment, R₂, R₇, Rₖ₂, Rₗ₂, or Rₘ₂ may be a group represented by Formula 2. In another embodiment, any two of R₂, R₃, R₆, R₇, Rₖ₂, Rₗ₂, and Rₘ₂ may each independently be a group represented by Formula 2. In an embodiment, Rₗ₂ and Rₘ₂ may each independently be a group represented by Formula 2, but embodiments are not limited thereto.

In an embodiment, the polycyclic compound represented by Formula 1 may be represented by one of Formulas 5-1 to 5-4.

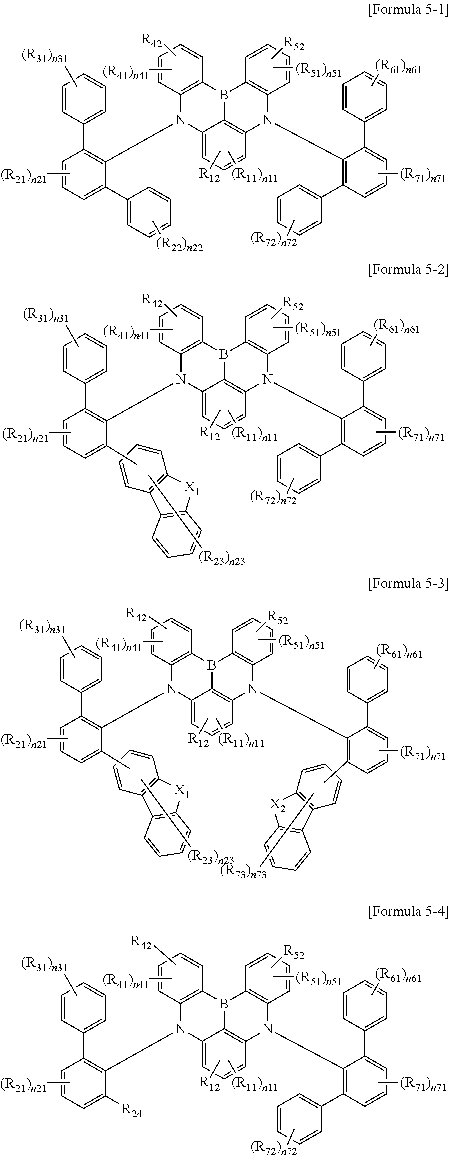

In Formulas 5-1 to 5-4, R₁₁, R₂₁, R₂₂, R₂₃, R₃₁, R₄₁, R₅₁, R₆₁, R₇₁, R₇₂, and R₇₃ may each independently be a hydrogen atom, a deuterium atom, a substituted or unsubstituted alkyl group having 1 to 60 carbon atoms, or a substituted or unsubstituted aryl group having 6 to 60 ring-forming carbon atoms. For example, R₁₁, R₂₁, R₂₂, R₂₃, R₃₁, R₄₁, R₅₁, R₆₁, R₇₁, R₇₂, and R₇₃ may each independently be a hydrogen atom, a deuterium atom, a substituted or unsubstituted t-butyl group, a substituted or unsubstituted phenyl group, or a substituted or unsubstituted biphenyl group. In another embodiment, R₃₁ and R₆₁ may be bonded to an adjacent group to form a ring. For example, two adjacent R₃₁ may be bonded to form a fused ring containing a heterocycle such as O and S, and two adjacent R₆₁ may be bonded to form a fused ring containing a heterocycle such as O and S.

In Formulas 5-1 to 5-4, R₁₂, R₂₄, R₄₂, and R₅₂ may each independently be a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms. For example, R₁₂, R₂₄, R₄₂, and R₅₂ may each independently be a substituted or unsubstituted t-butyl group, a substituted or unsubstituted phenyl group, a substituted or unsubstituted biphenyl group, a substituted or unsubstituted carbazole group, or a substituted or unsubstituted phenanthro-carbazole group.

In Formulas 5-1 to 5-4, n11 may be an integer from 0 to 2. When n11 is 0, the polycyclic compound according to an embodiment may not be substituted with R₁₁. In Formulas 5-1 to 5-4, when n11 is 2 and two R₁₁ are all hydrogen atoms, the case may be the same when n11 is G in Formulas 5-1 to 5-4. When n11 is 2, two R₁₁ may all be the same, or one of the two R₁₁ may be different from the other.

In Formulas 5-1 to 5-4, n21, n41, n51, and n71 may each independently be an integer from 0 to 3. When n21, n41, n51, and n71 are each 0, the polycyclic compound according to an embodiment may not be substituted with each of R₂₁, R₄₁, R₅₁, and R₇₁. In Formulas 5-1 to 5-4, when n21, n41, n51, and n71 are each 3, and each of R₂₁, R₄₁, R₅₁, and R₇₁ is all hydrogen atoms, the case may be the same as when n21, n41, n51, and n71 are each 0 in Formulas 5-1 to 5-4. When n21, n41, n51, and n71 are each 2 or greater, multiples of each of R₂₁, R₄₁, R₅₁, and R₇₁ may all be the same, or at least one of R₂₁, R₄₁, R₅₁, and R₇₁ may be different.

In Formulas 5-1 to 5-4, n22, n31, n61, and n72 may each independently be an integer from 0 to 5. When n22, n31, n61, and n72 are each 0, the polycyclic compound according to an embodiment may not be substituted with each of R₂₂, R₃₁, R₆₁, and R₇₂. In Formulas 5-1 to 5-4, when n22, n31, n61, and n72 are each 5, and each of R₂₂, R₃₁, R₆₁, and R₇₂ is all hydrogen atoms, the case may be the same as when n22, n31, n61, and n72 are each 0 in Formulas 5-1 to 5-4. When n22, n31, n61, and n72 are each 2 or greater, multiples of each of R₂₂, R₃₁, R₆₁, and R₇₂ may all be the same, or at least one of R₂₂, R₃₁, R₆₁, or R₇₂ may be different.

In Formulas 5-2 and 5-3, n23 and n73 may each independently be an integer from 0 to 7. When n23 and n73 are each 0, the polycyclic compound according to an embodiment may not be substituted with each of R₂₃ and R₇₃. In Formulas 5-2 and 5-3, when n23 and n73 are each 7 and each of R₂₃ and R₇₃ are all hydrogen atoms, the case may be the same as when n23 and n73 are each 0 in Formulas 2 and 5-3. When n23 and n73 are each 2 or greater, multiples of each of R₂₃ and R₇₃ may all be the same, or at least one of R₂₃ or R₇₃ may be different.

In Formulas 5-2 and 5-3, X₁ and X₂ may each independently be O or S. In the polycyclic compound according to an embodiment, a dibenzofuran group and/or a dibenzothiophene group may be linked to a first substituent and/or a second substituent at an ortho position to the nitrogen atom of the core.

In Formulas 5-1 to 5-3, at least one of R₁₂, R₄₂, and R₅₂ may each independently be a group represented by Formula 2. In an embodiment, one or two of R₁₂, R₄₂, and R₅₂ may each independently be a group represented by Formula 2. For example, R₁₂, R₄₂, or R₅₂ may be a group represented by Formula 2. For example, both R₄₂ and R₅₂ may each independently be a group represented by Formula 2.

In Formula 5-4, at least one of R₁₂, R₂₄, R₄₂, and R₅₂ may each independently be a group represented by Formula 2. In an embodiment, one or two of R₁₂, R₂₄, R₄₂, and R₅₂ may each independently be a group represented by Formula 2. For example, R₁₂, R₂₄, R₄₂, or R₅₂ may be a group represented by Formula 2. For example, both R₄₂ and R₅₂ may each independently be a group represented by Formula 2.

In an embodiment, the polycyclic compound represented by Formula 5-1 may be represented by one of Formulas 5-1-1 to 5-1-6. Formulas 5-1-1 to 5-1-6 each represent a case that further defines a position where the phenanthro-carbazole group represented by Formula 2 is linked to the polycyclic compound represented by Formula 5-1.

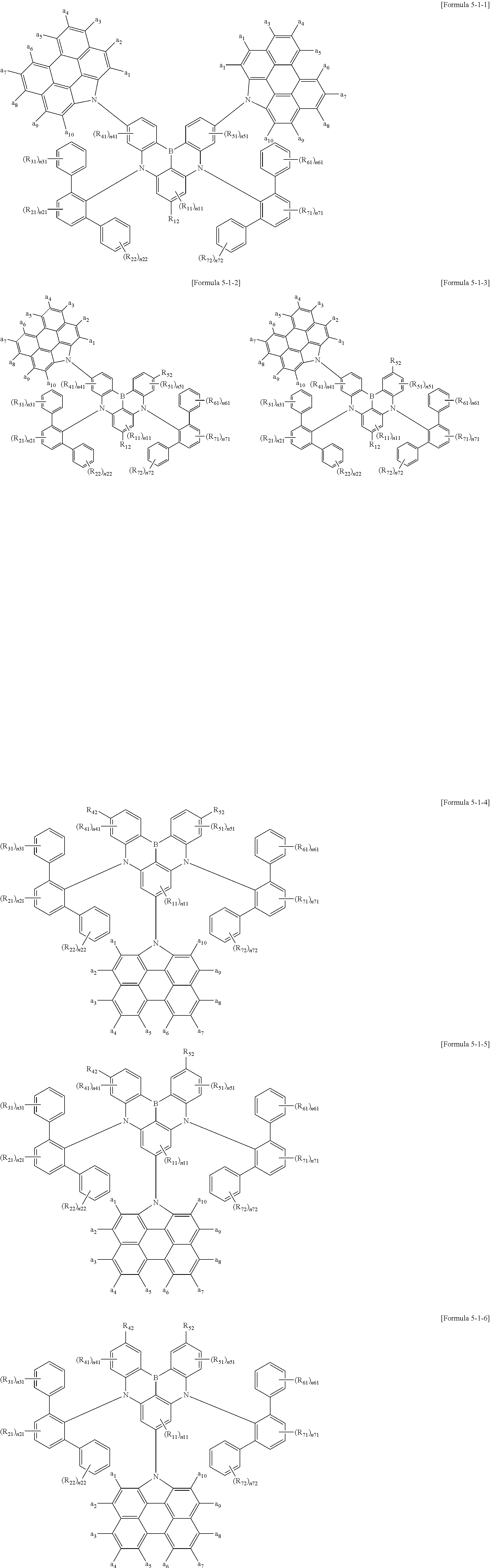

In Formulas 5-1-1 to 5-1-6, a₁ to a₁₀ may each independently be a hydrogen atom or a deuterium atom. For example, a₁ to a₁₀ may all be hydrogen atoms. However, embodiments are not limited thereto, and at least one of a₁ to a₁₀ may be a deuterium atom.

In Formulas 5-1-1 to 5-1-6, R₁₁, R₁₂, R₂₁, R₂₂, R₃₁, R₄₁, R₄₂, R₅₁, R₅₂, R₆₁, R₇₁, R₇₂, n11, n21, n22, n31, n41, n51, n61, n71, and n72 may be the same as described in Formula 5-1.

In an embodiment, the polycyclic compound represented by Formula 5-2 may be represented by Formula 5-2-1. Formula 5-2-1 represents a case that further defines a position where the phenanthro-carbazole group represented by Formula 2 is linked to the polycyclic compound represented by Formula 5-2.

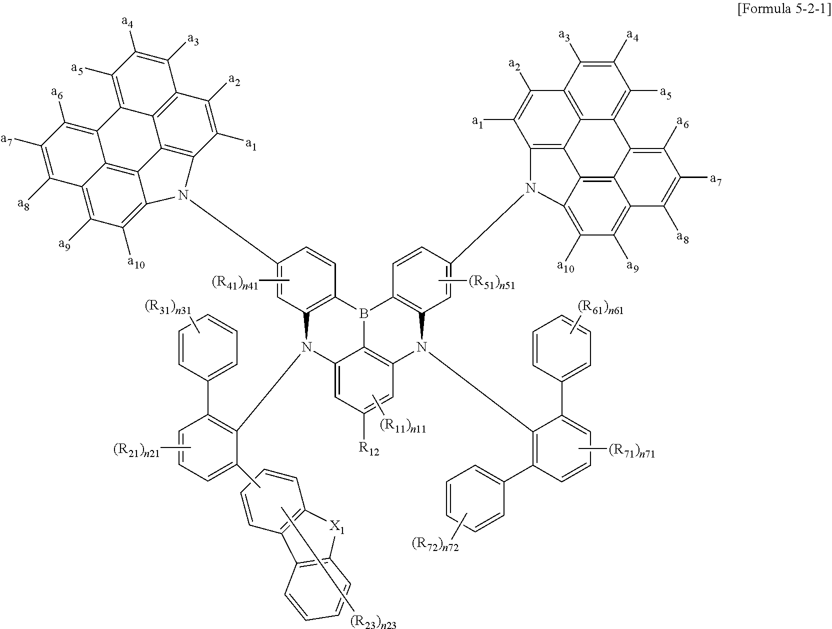

In Formula 5-2-1, a₁ to a₁₀ may each independently be a hydrogen atom or a deuterium atom. For example, a₁ to a₁₀ may all be hydrogen atoms. However, embodiments are not limited thereto, and at least one of a₁ to a₁₀ may be a deuterium atom.

In Formulas 5-2-1, X₁, R₁₁, R₁₂, R₂₁, R₂₃, R₃₁, R₄₁, R₅₁, R₆₁, R₇₁, R₇₂, n11, n21, n23, n31, n41, n51, n61, n71, and n72 may be the same as described in Formula 5-2.

In an embodiment, the polycyclic compound represented by Formula 5-3 may be represented by Formula 5-3-1. Formula 5-3-1 represents a case that further defines a position where the phenanthro-carbazole group represented by Formula 2 is linked to the polycyclic compound represented by Formula 5-3.

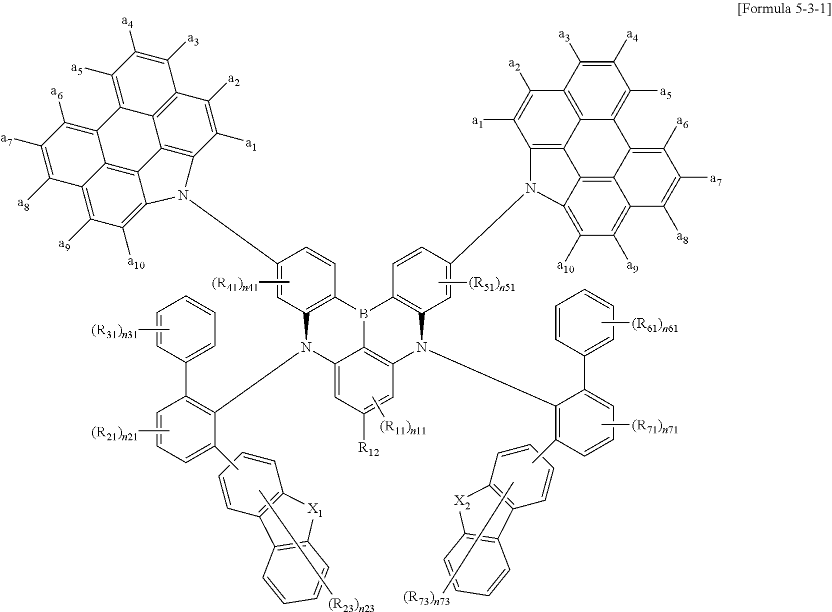

In Formulas 5-3-1, X₁, X₂, R₁₁, R₁₂, R₂₁, R₂₃, R₃₁, R₄₁, R₅₁, R₆₁, R₇₁, R₇₃, n11, n21, n23, n31, n41, n51, n61, n71, and n73 may be the same as described in Formula 5-3.

In an embodiment, the polycyclic compound according to an embodiment represented by Formula 1 may include at least one deuterium atom as a substituent. The polycyclic compound according to an embodiment represented by Formula 1 may include a structure in which at least one hydrogen atom is substituted with a deuterium atom.

A polycyclic compound according to an embodiment may be selected from Compound Group 1. At least one functional layer included in the light emitting element ED according to an embodiment may include at least one polycyclic compound selected from Compound Group 1. The light emitting element ED according to an embodiment may include at least one polycyclic compound selected from Compound Group 1 in an emission layer EML.

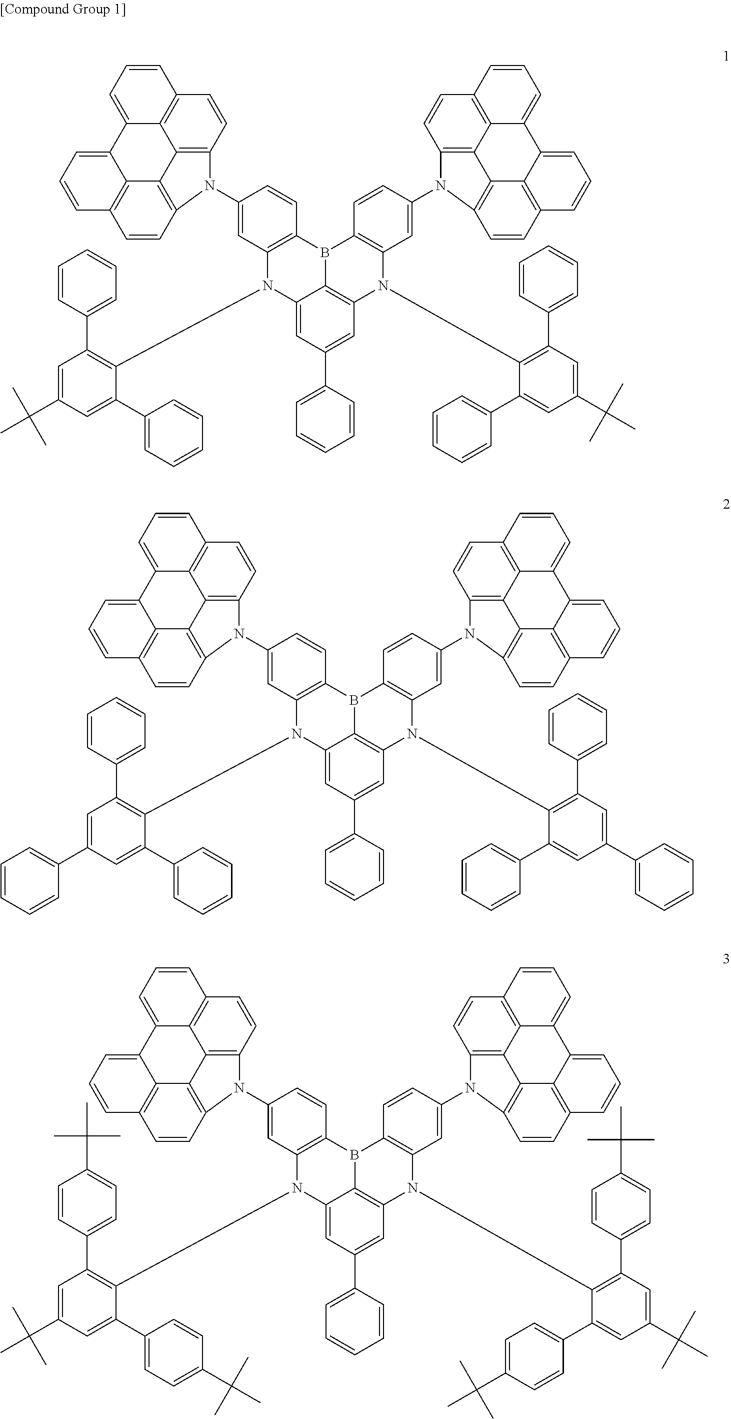

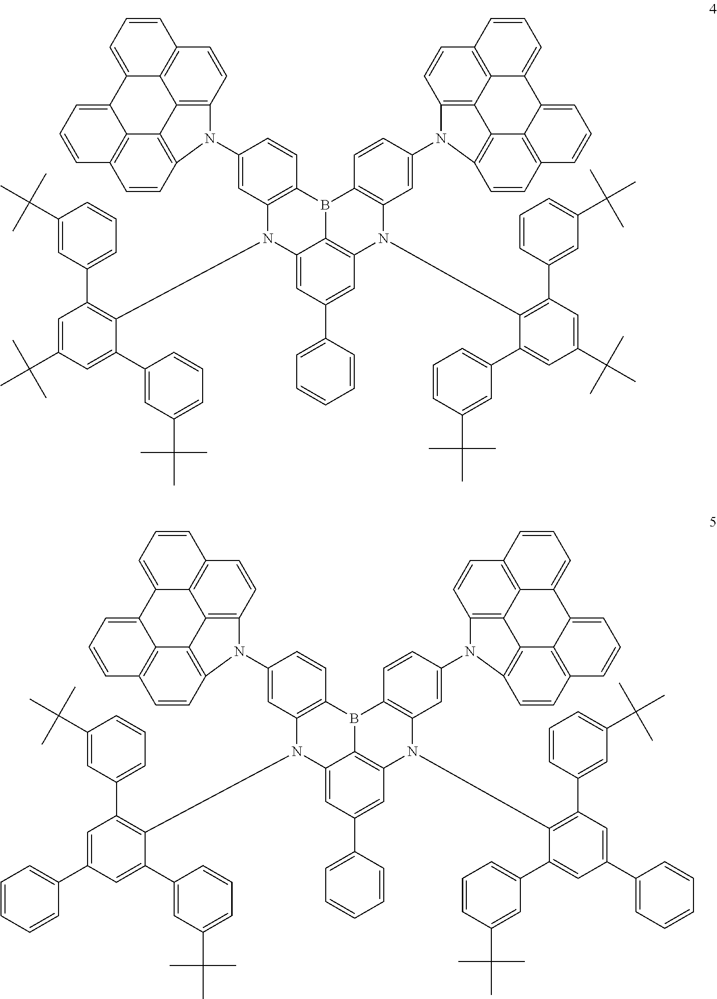 [SMILES: CC(C)(C)c1cccc(-c2cc(C(C)(C)C)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(-c5ccccc5)cc2c43)c1 ; CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(-c5ccccc5)cc2c43)c1]

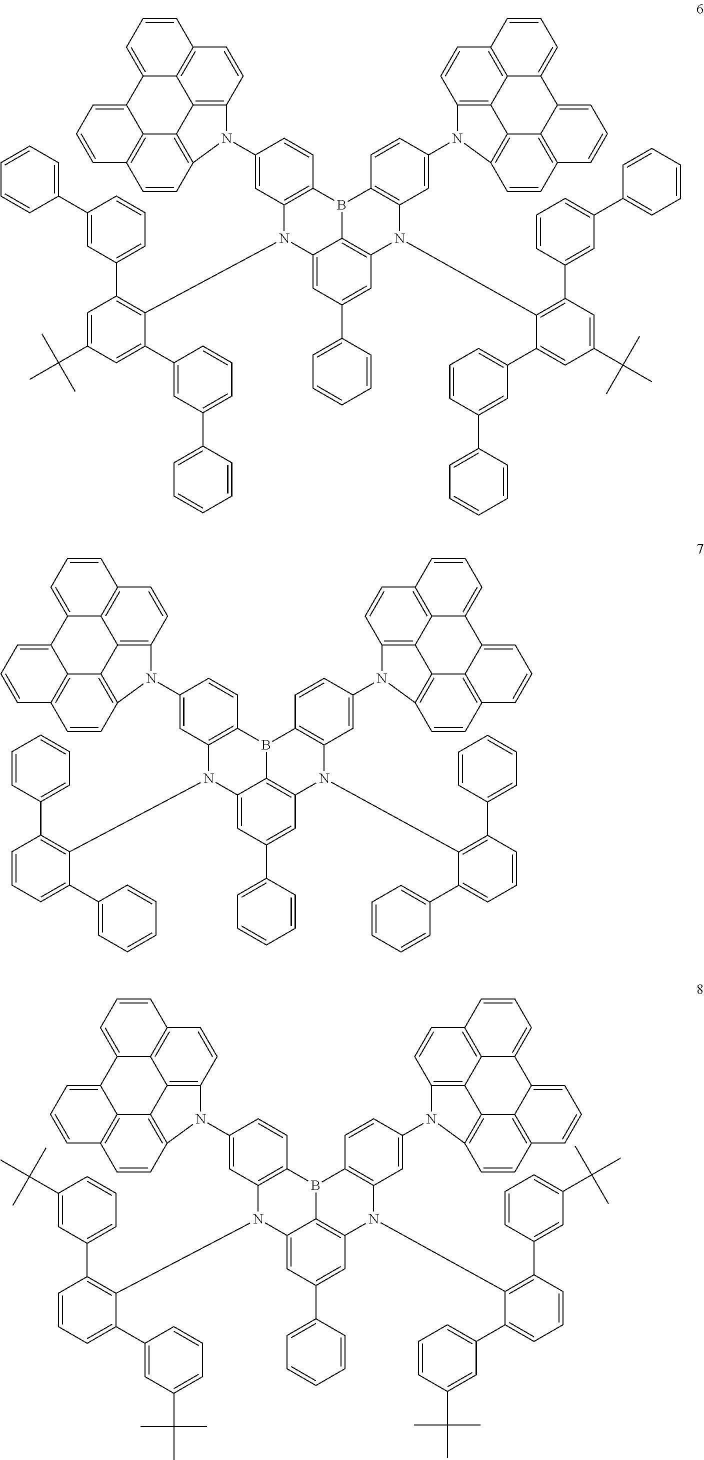

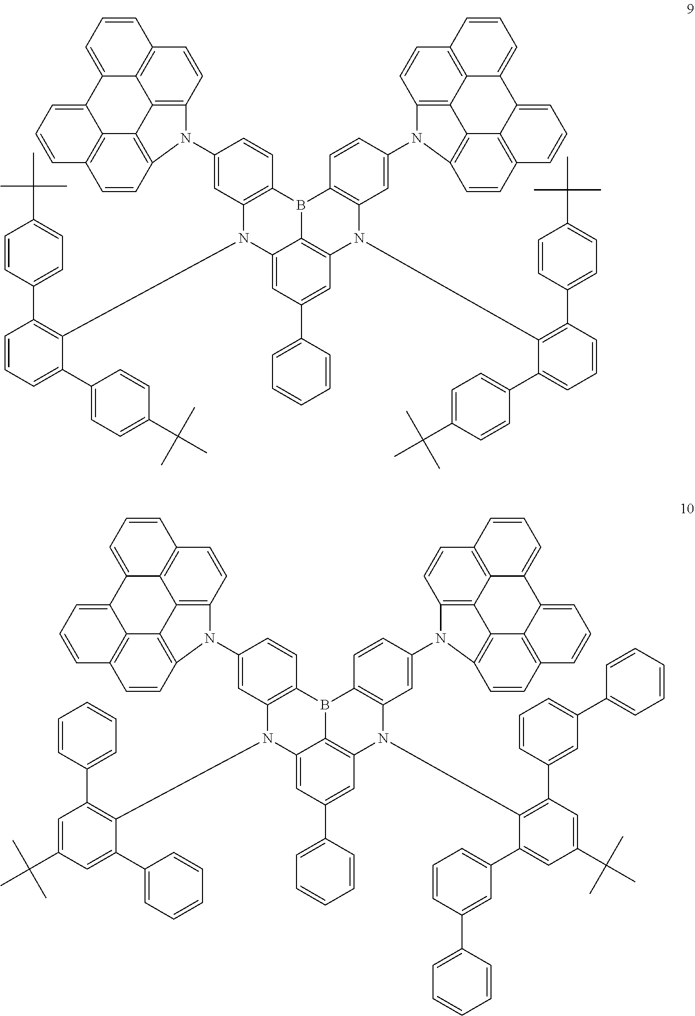

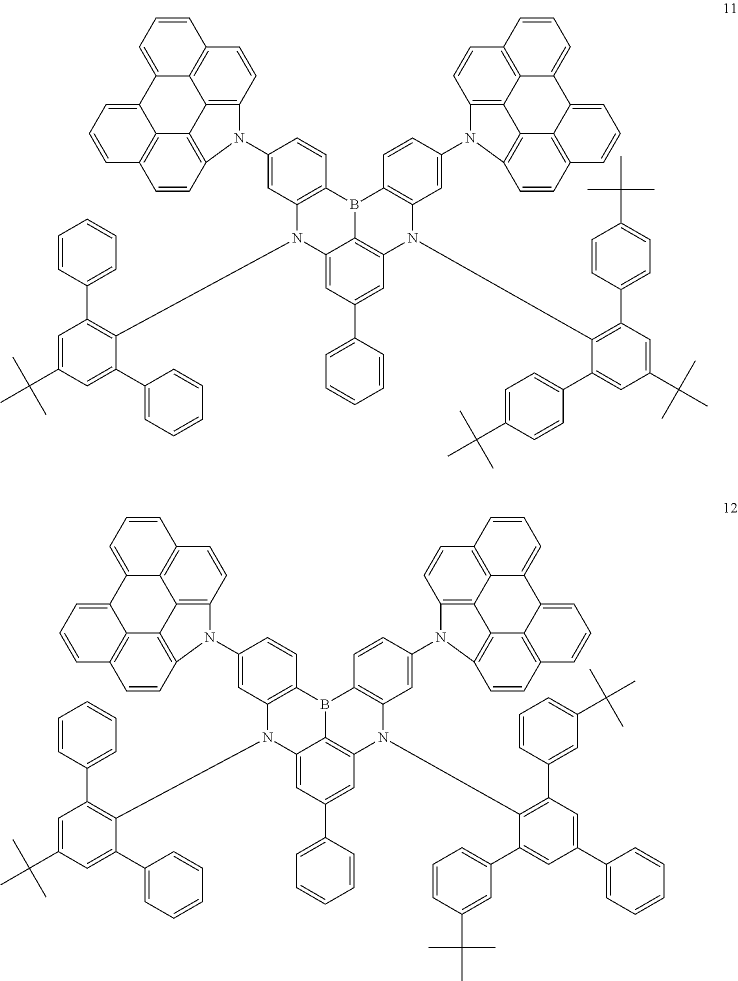

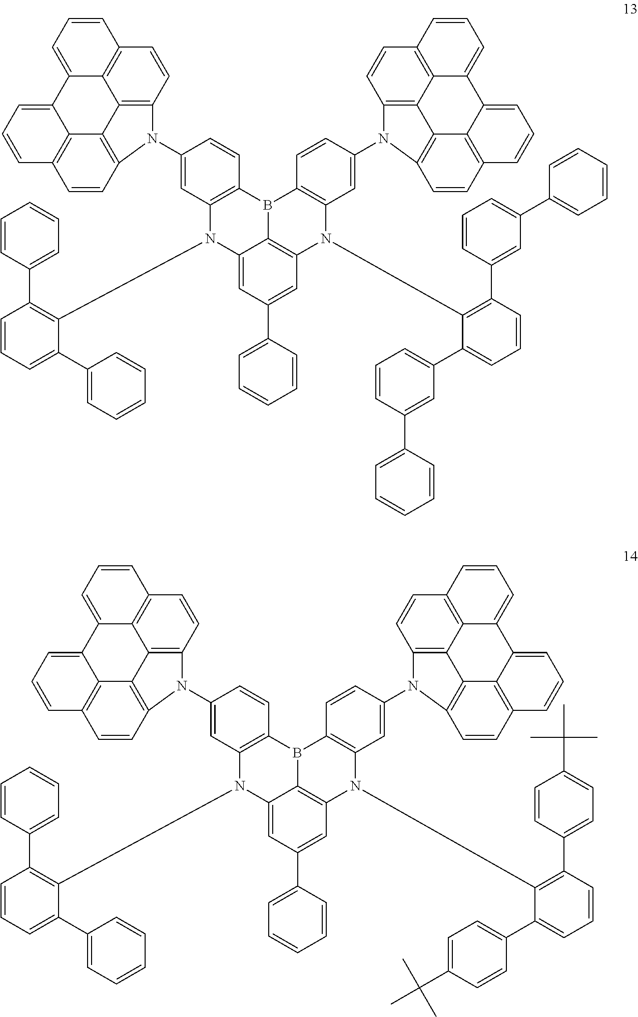 [SMILES: c1ccc(-c2cccc(-c3cccc(-c4cccc(-c5ccccc5)c4)c3N3c4cc(-n5c6ccc7cccc8c9cccc%10ccc5c(c%109)c6c78)ccc4B4c5ccc(-n6c7ccc8cccc9c%10cccc%11ccc6c(c%11%10)c7c89)cc5N(c5c(-c6ccccc6)cccc5-c5ccccc5)c5cc(-c6ccccc6)cc3c54)c2)cc1 ; CC(C)(C)c1ccc(-c2cccc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(-c5ccccc5)cc2c43)cc1]

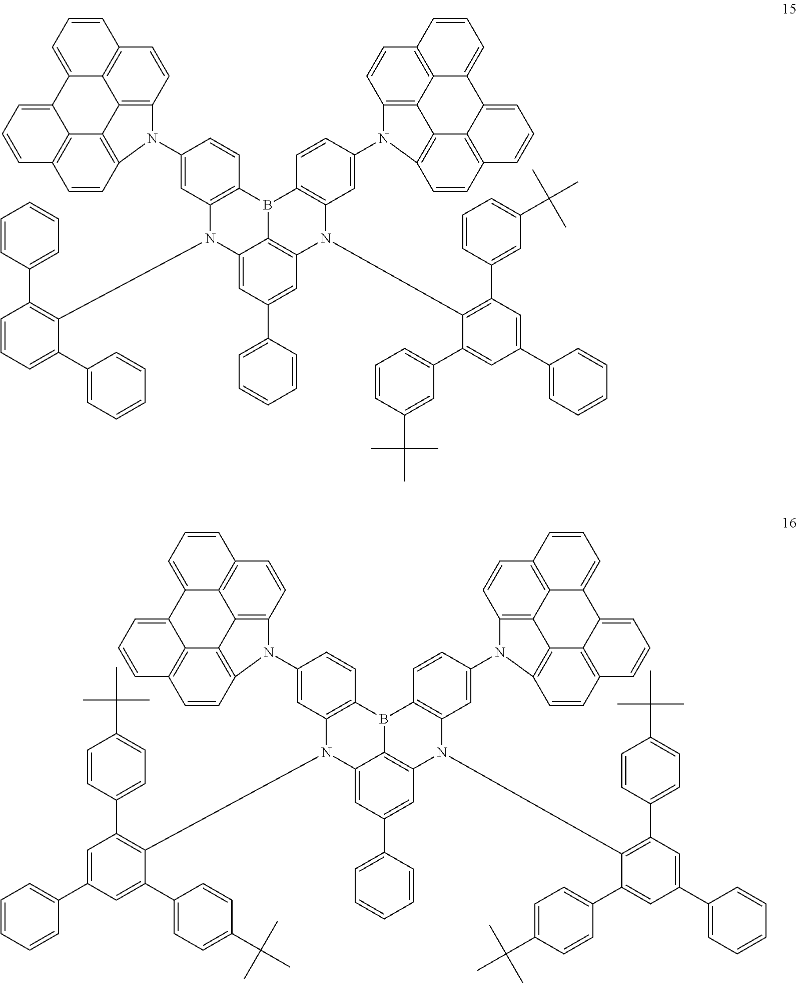 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(-c5ccccc5)cc2c43)c1 ; CC(C)(C)c1ccc(-c2cc(-c3ccccc3)cc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(-c5ccccc5)cc2c43)cc1]

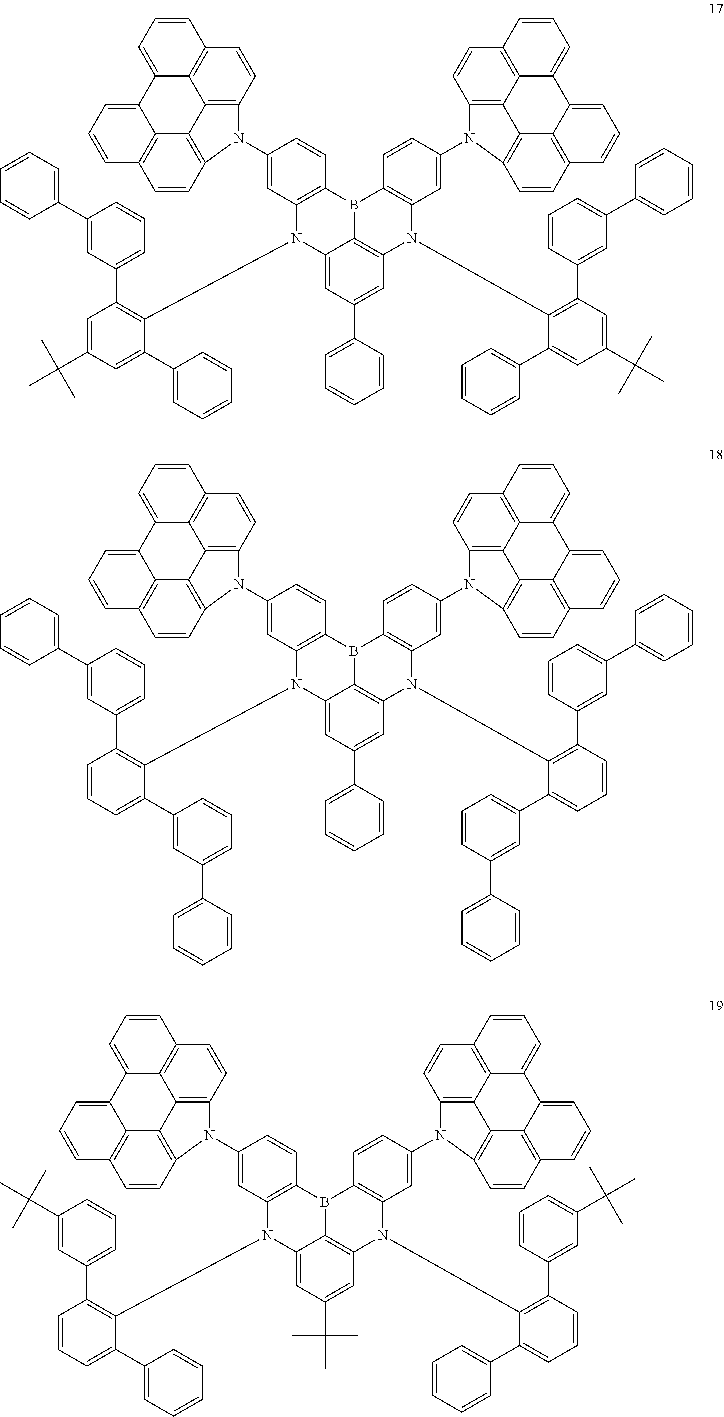

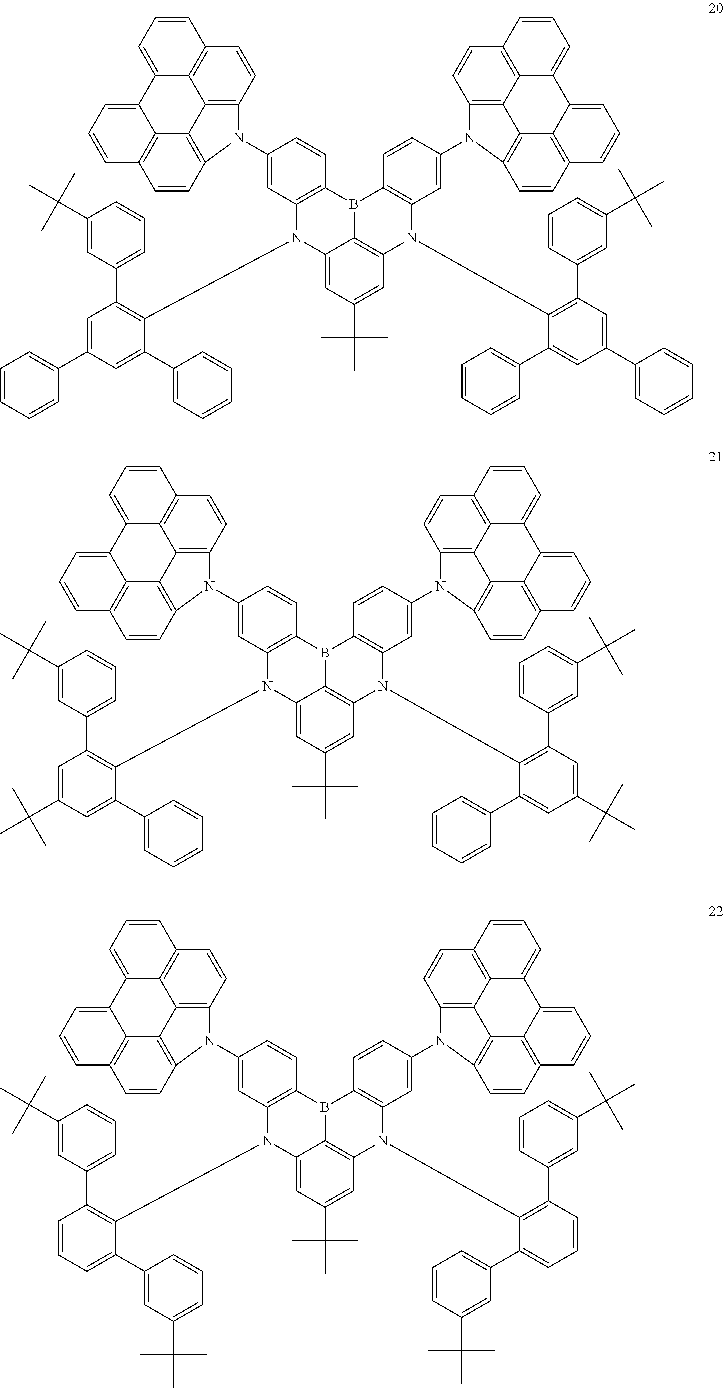

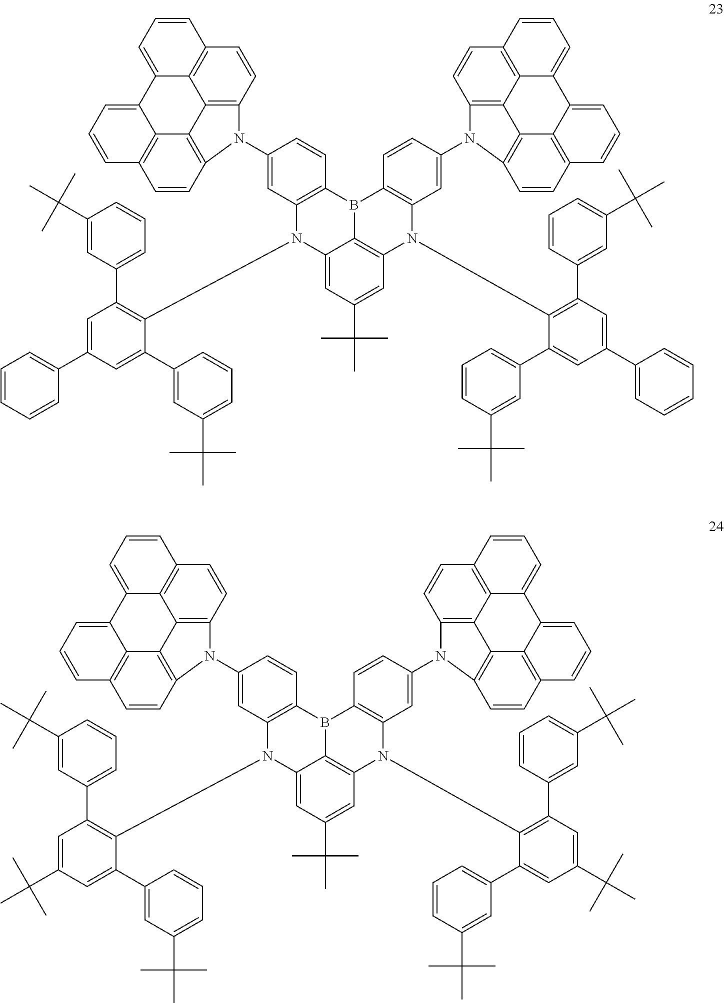 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cccc(-c2cc(C(C)(C)C)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(C(C)(C)C)cc2c43)c1]

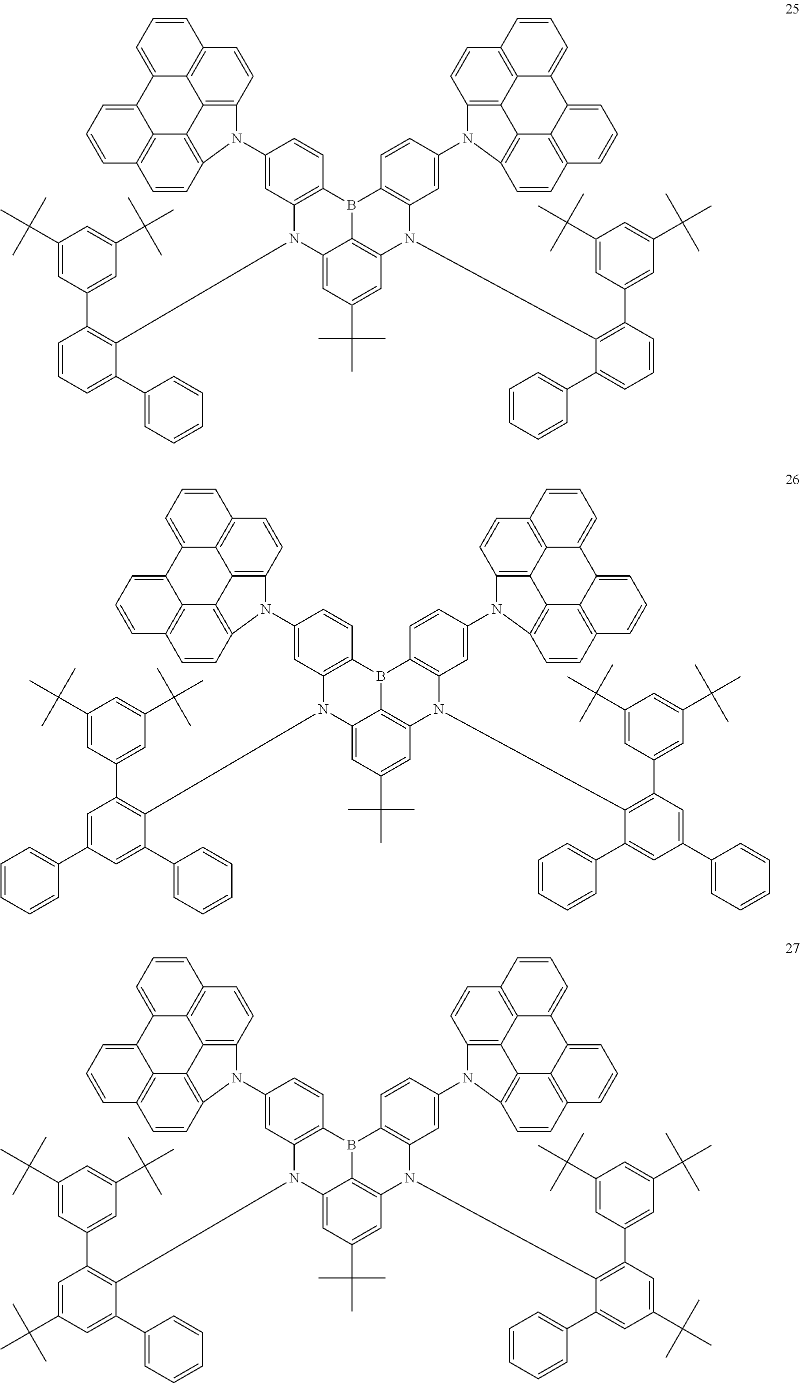

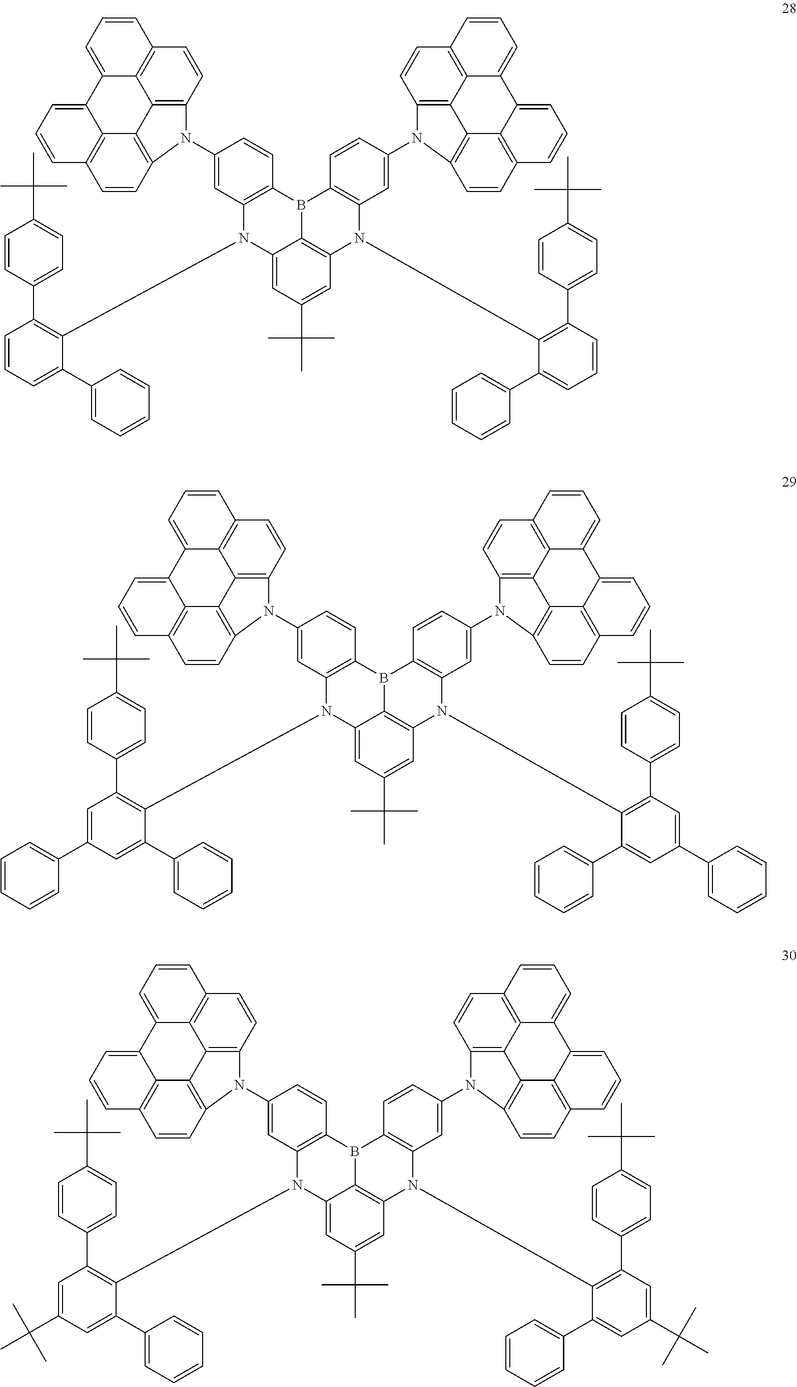

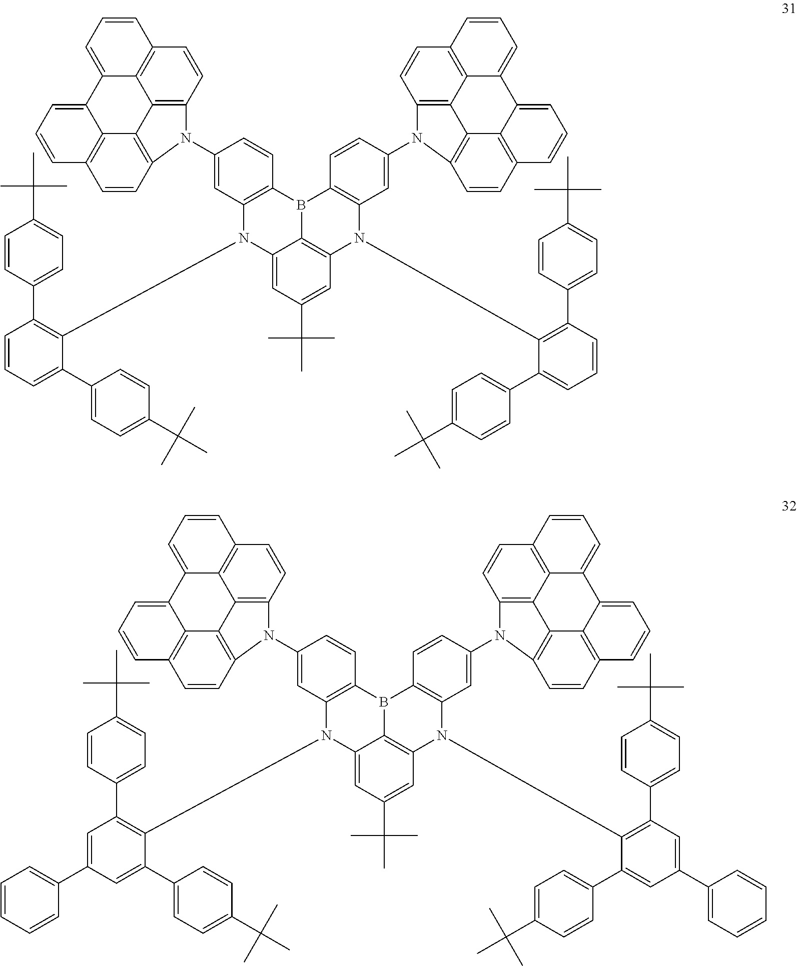 [SMILES: CC(C)(C)c1ccc(-c2cccc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(-c2cc(-c3ccccc3)cc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

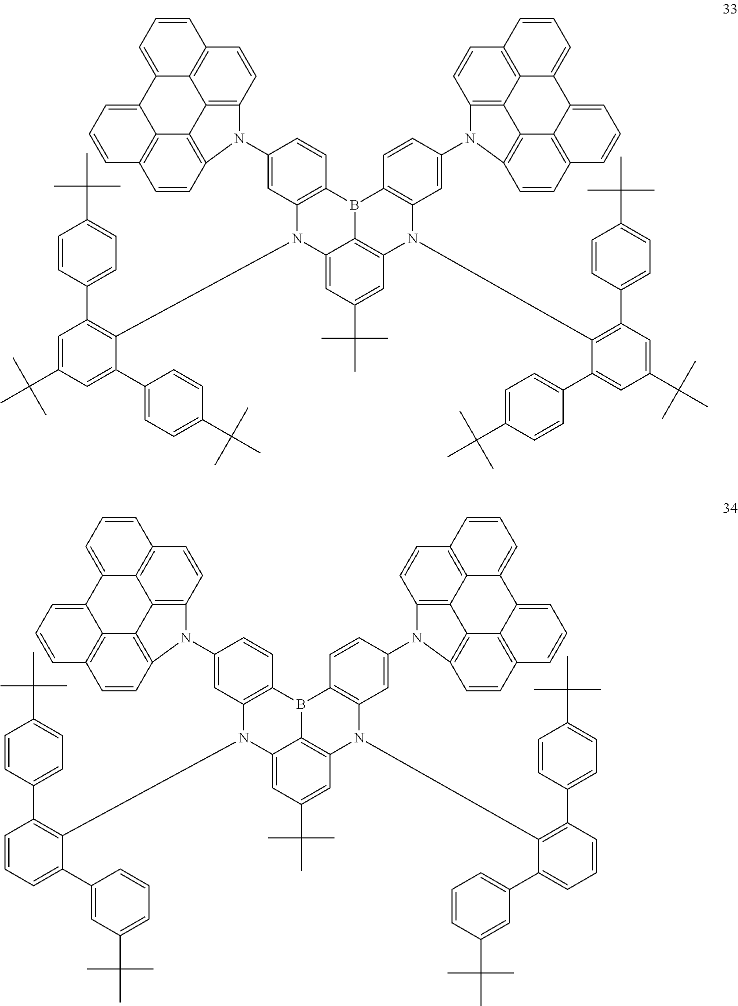

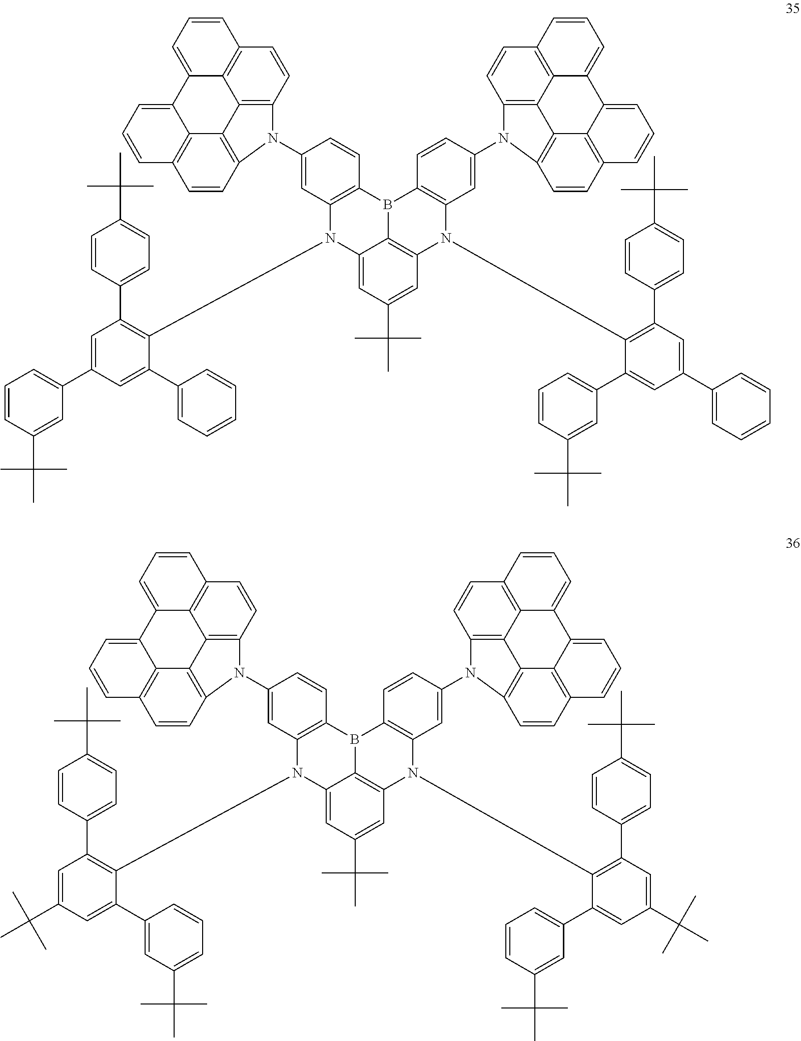 [SMILES: CC(C)(C)c1ccc(-c2cc(-c3cccc(C(C)(C)C)c3)cc(-c3ccccc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4cccc(C(C)(C)C)c4)c4cc(C(C)(C)C)cc2c43)cc1 ; CC(C)(C)c1ccc(-c2cc(C(C)(C)C)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4cccc(C(C)(C)C)c4)c4cc(C(C)(C)C)cc2c43)cc1]

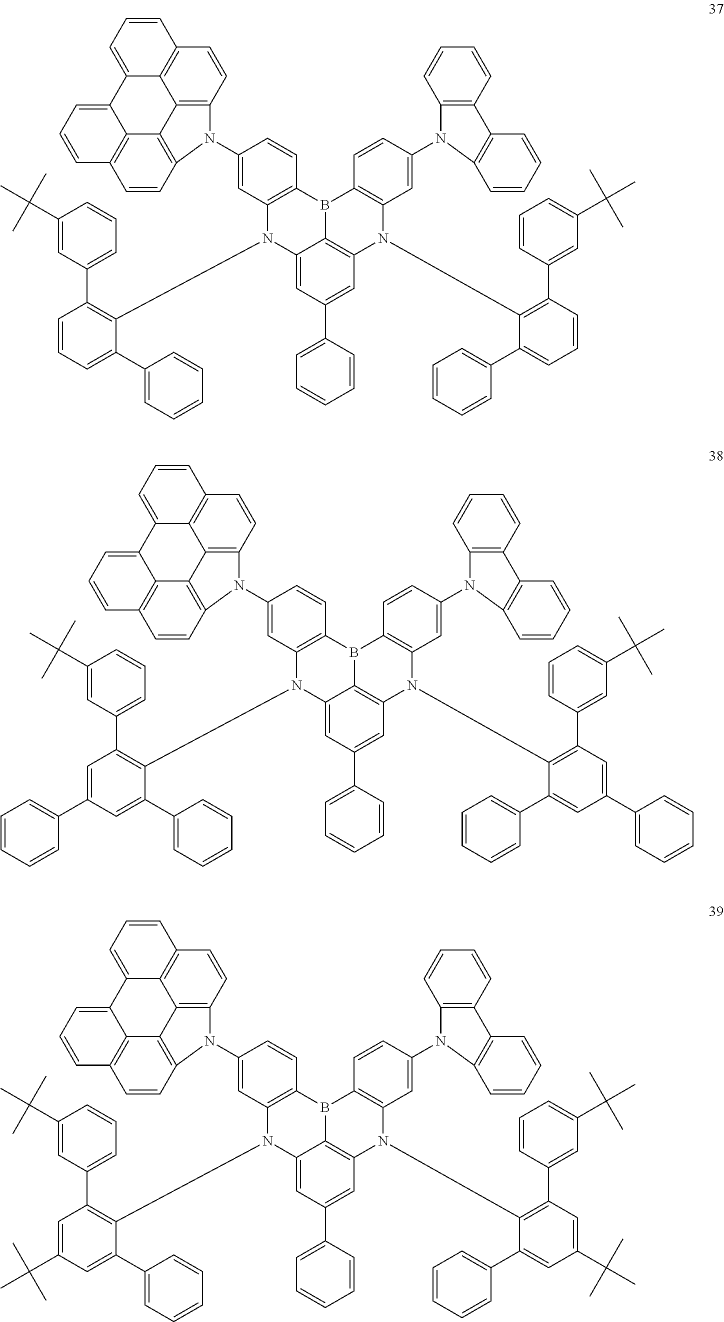

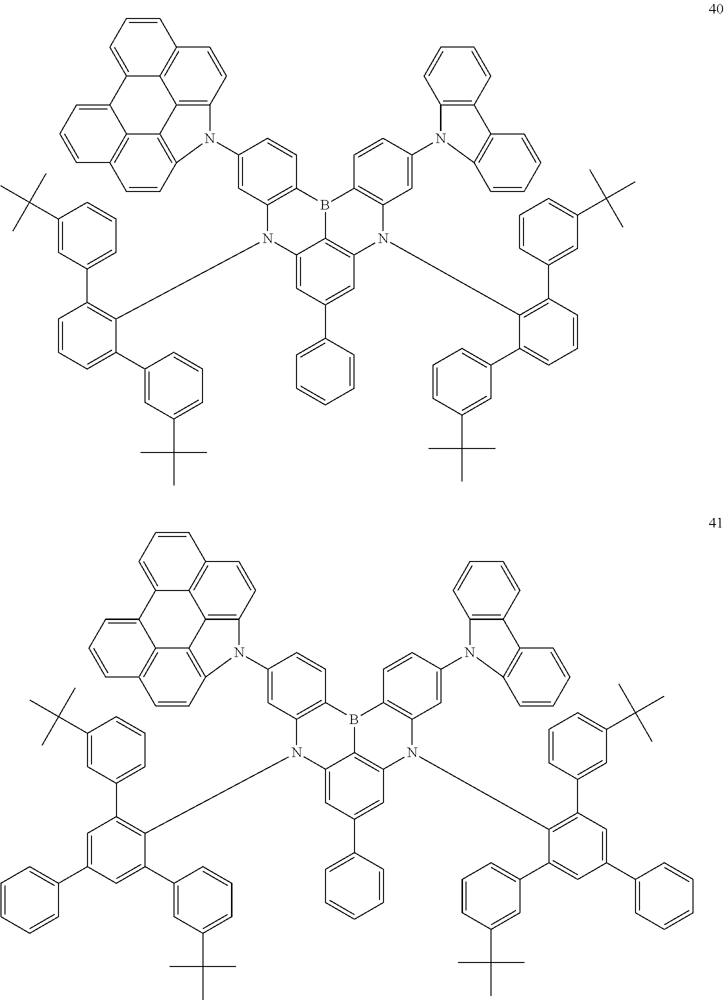 [SMILES: CC(C)(C)c1cccc(-c2cccc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(-c5ccccc5)cc2c43)c1 ; CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(-c5ccccc5)cc2c43)c1]

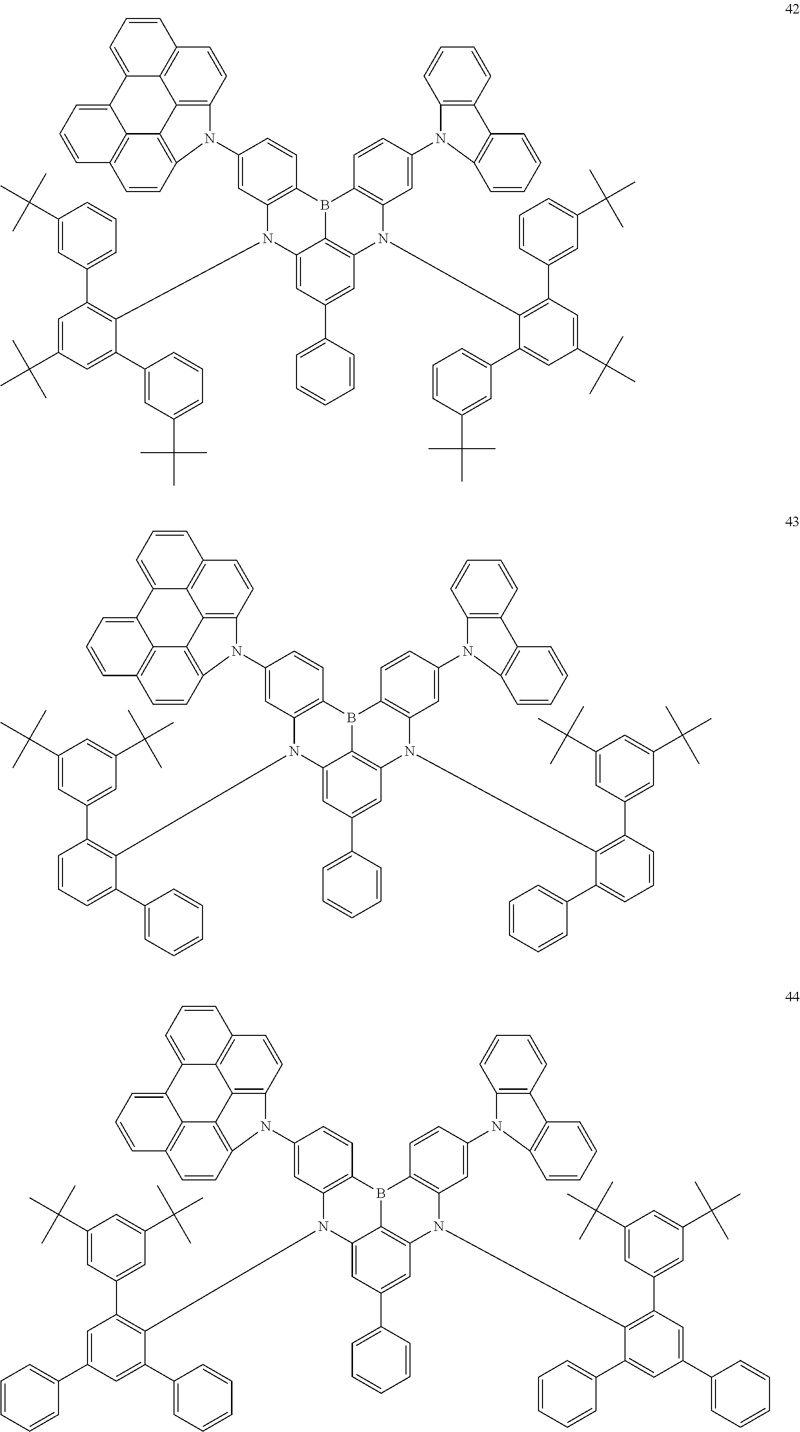

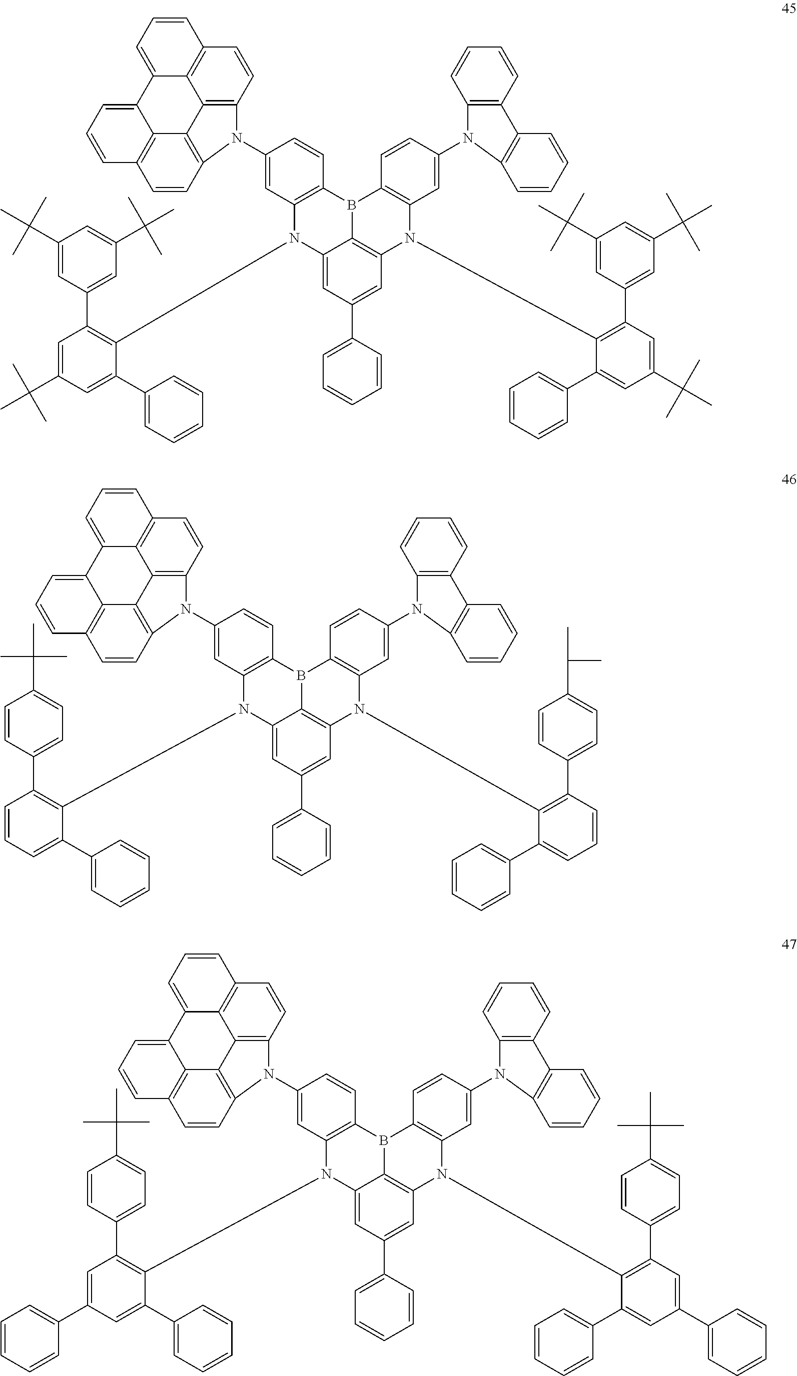

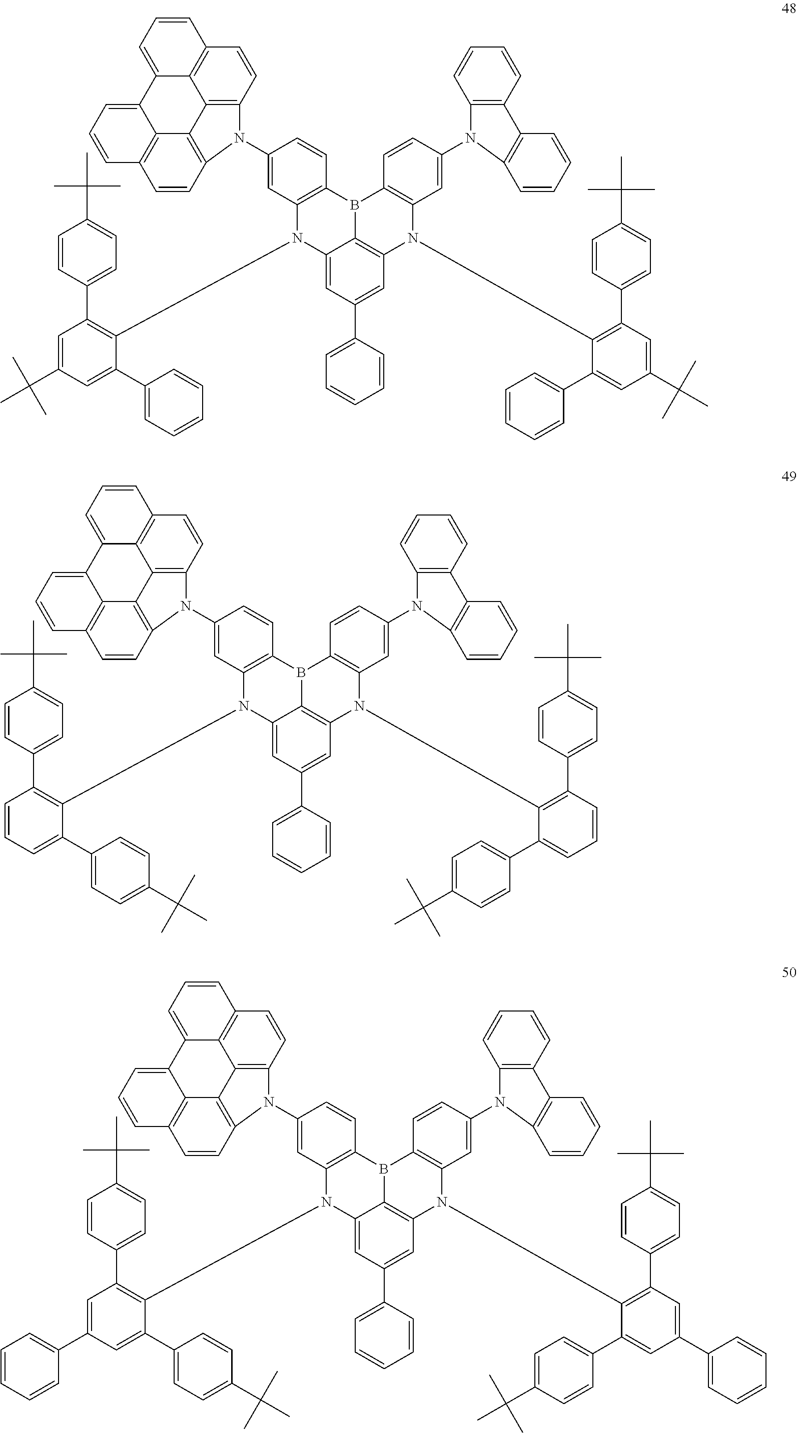

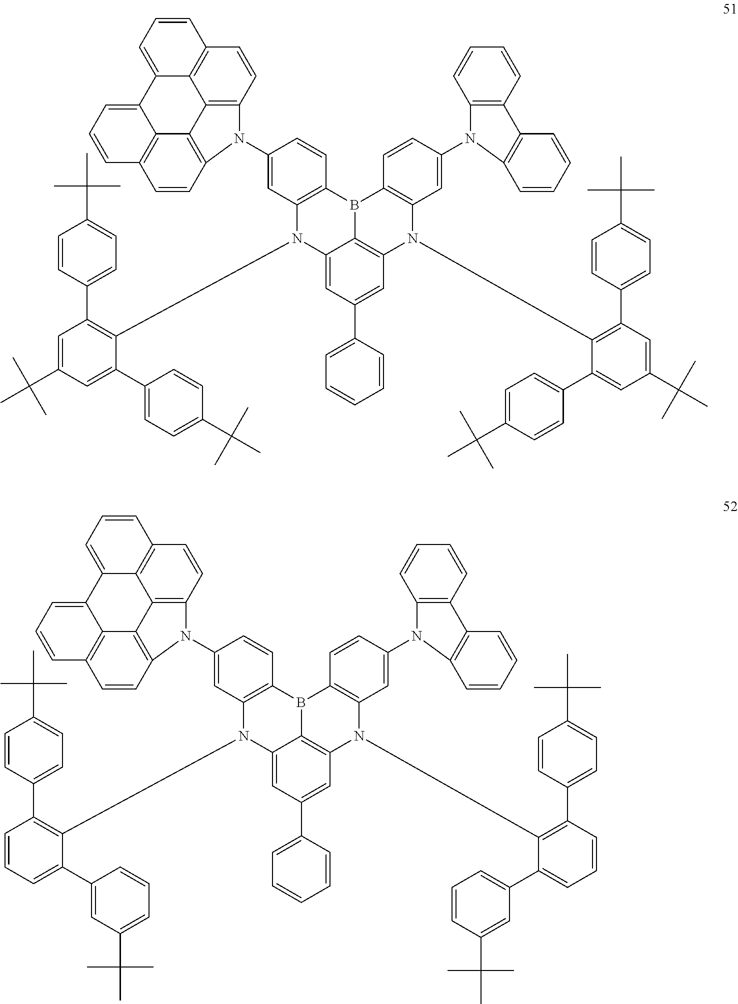

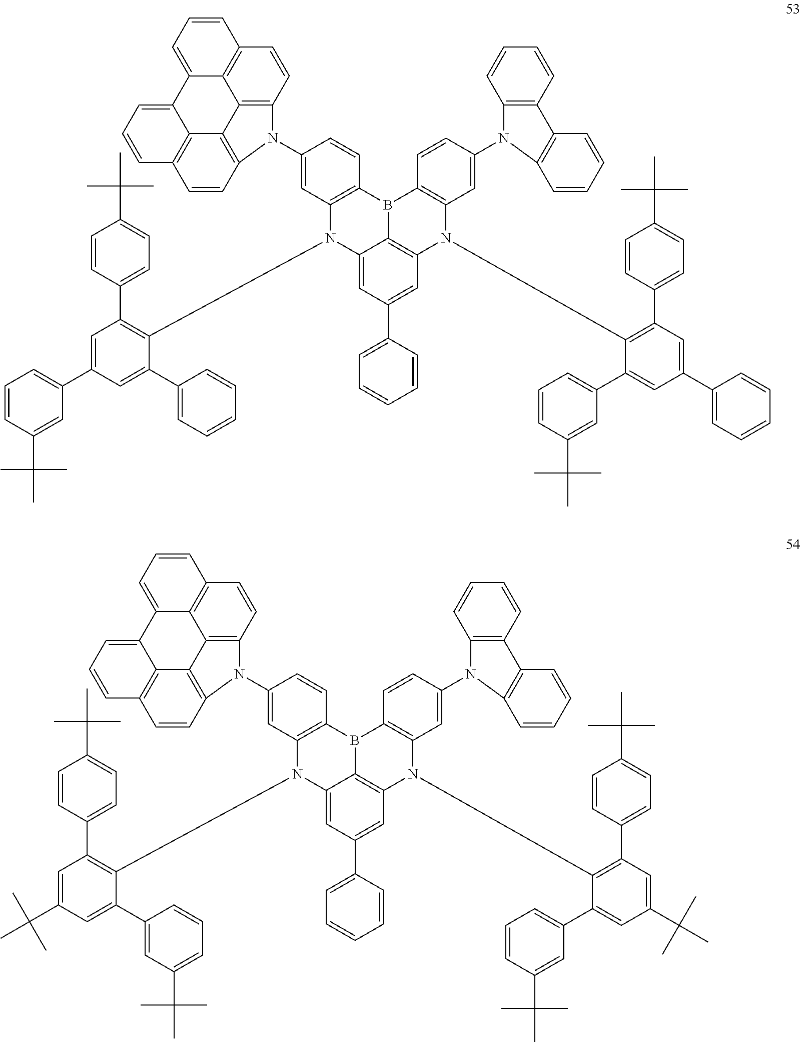 [SMILES: CC(C)(C)c1ccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(-c5cccc(C(C)(C)C)c5)cc4-c4ccc(C(C)(C)C)cc4)c4cc(-c5ccccc5)cc2c43)cc1 ; CC(C)(C)c1ccc(-c2cc(C(C)(C)C)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4cccc(C(C)(C)C)c4)c4cc(-c5ccccc5)cc2c43)cc1]

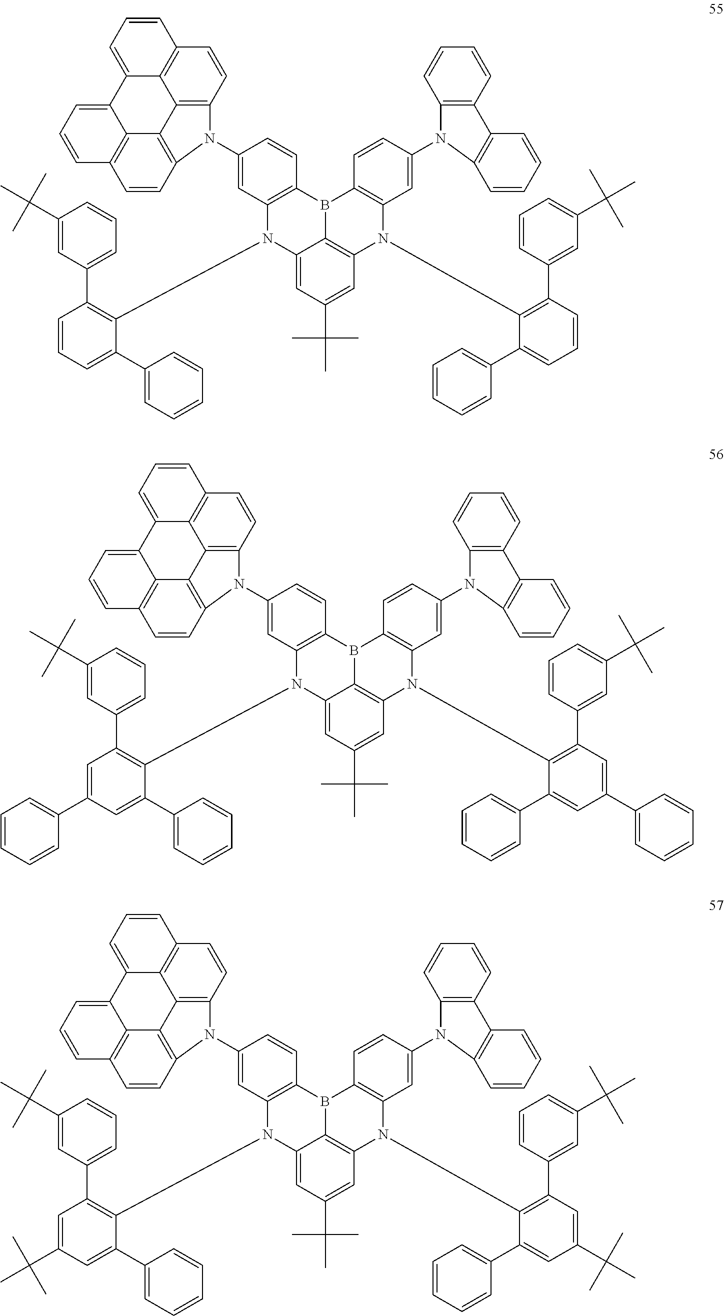

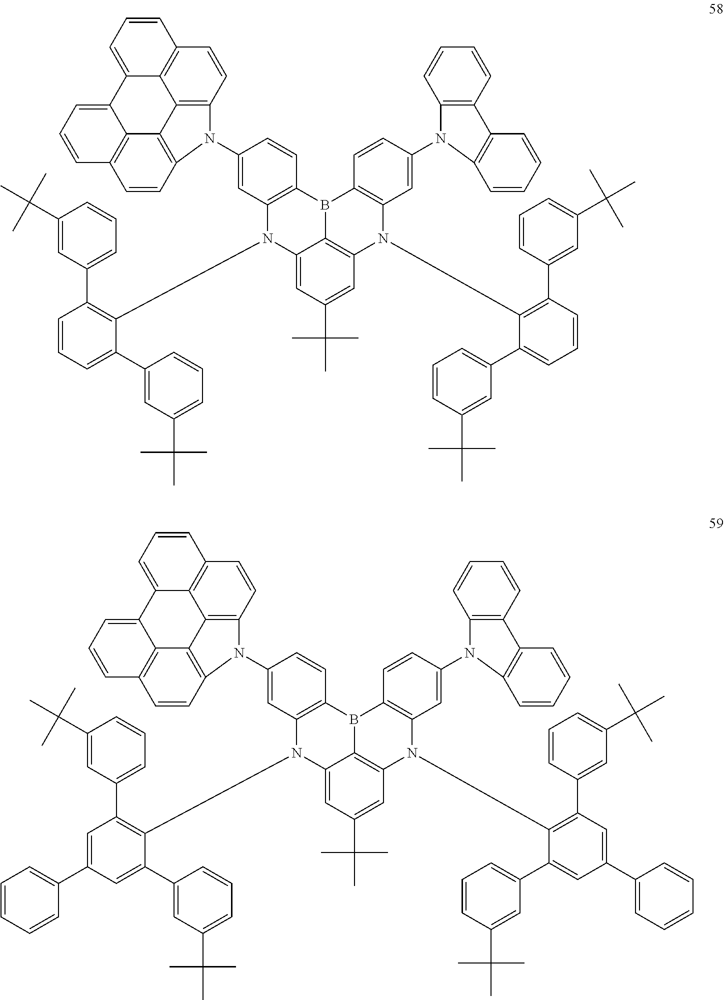 [SMILES: CC(C)(C)c1cccc(-c2cccc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1]

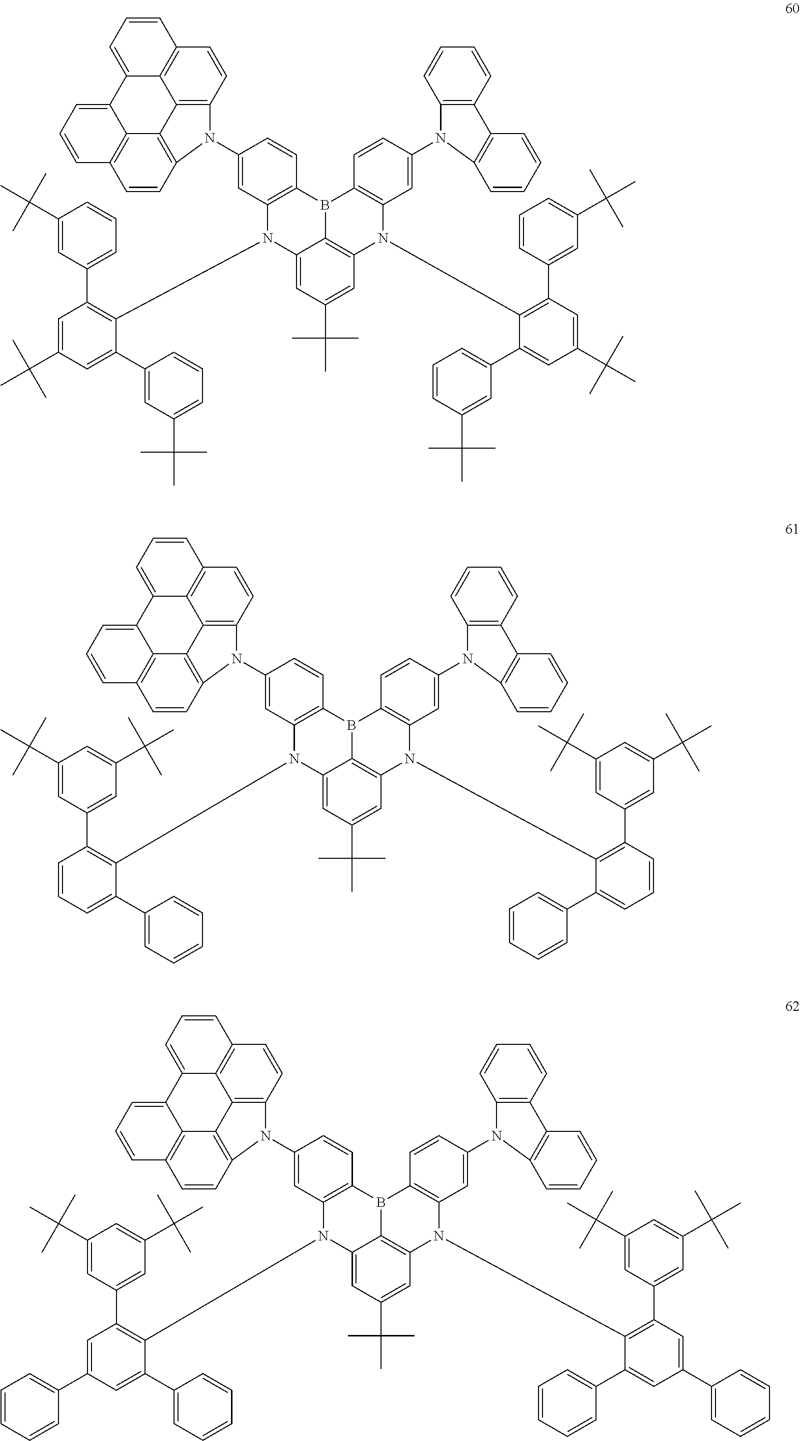

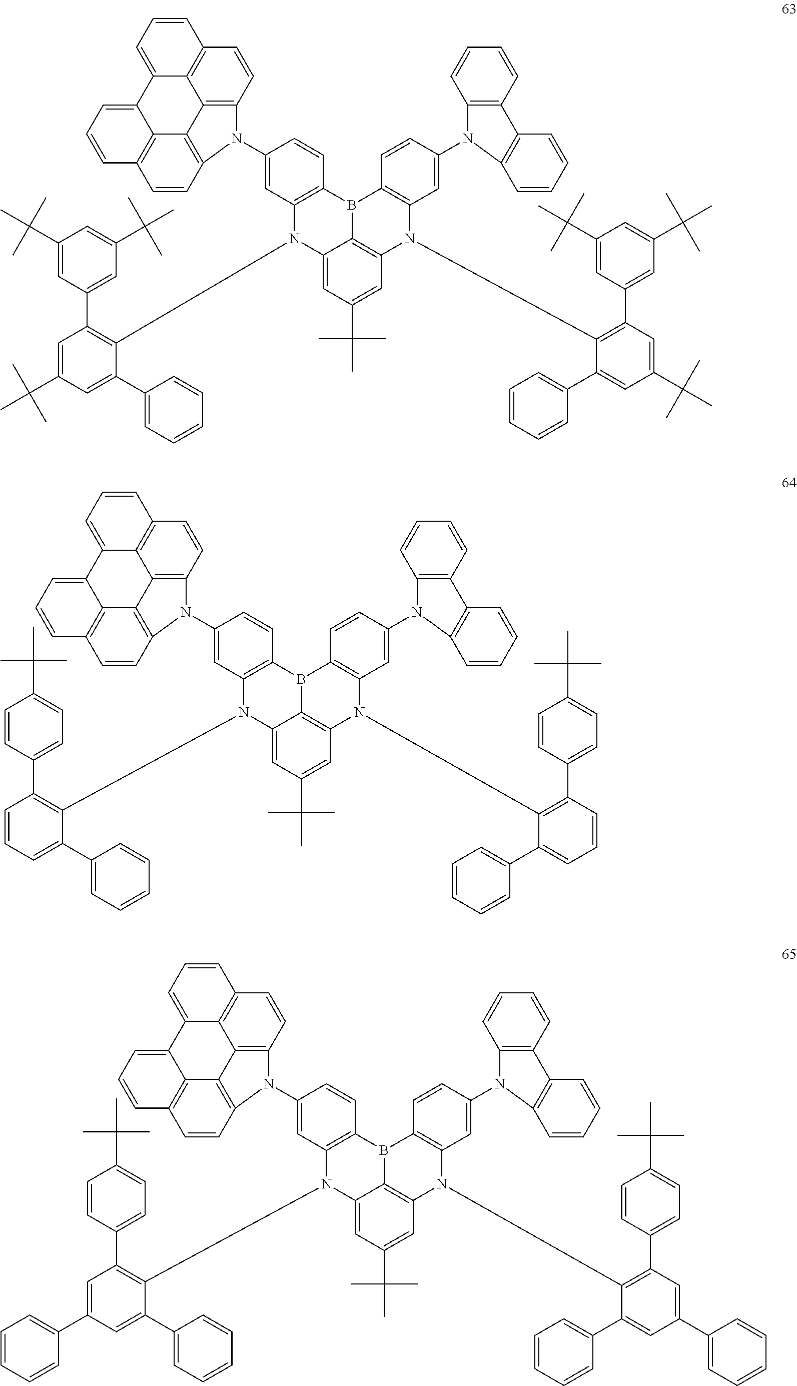

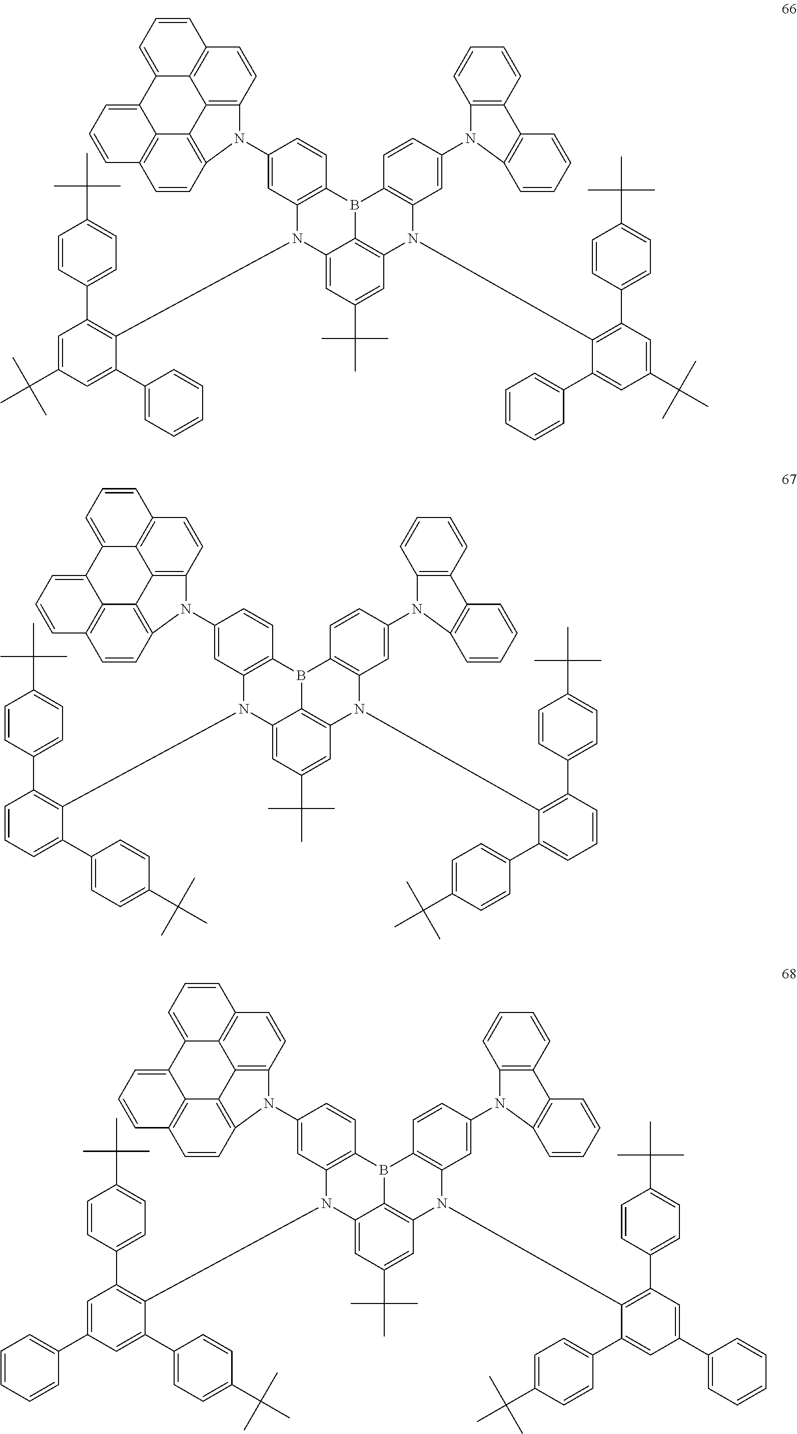

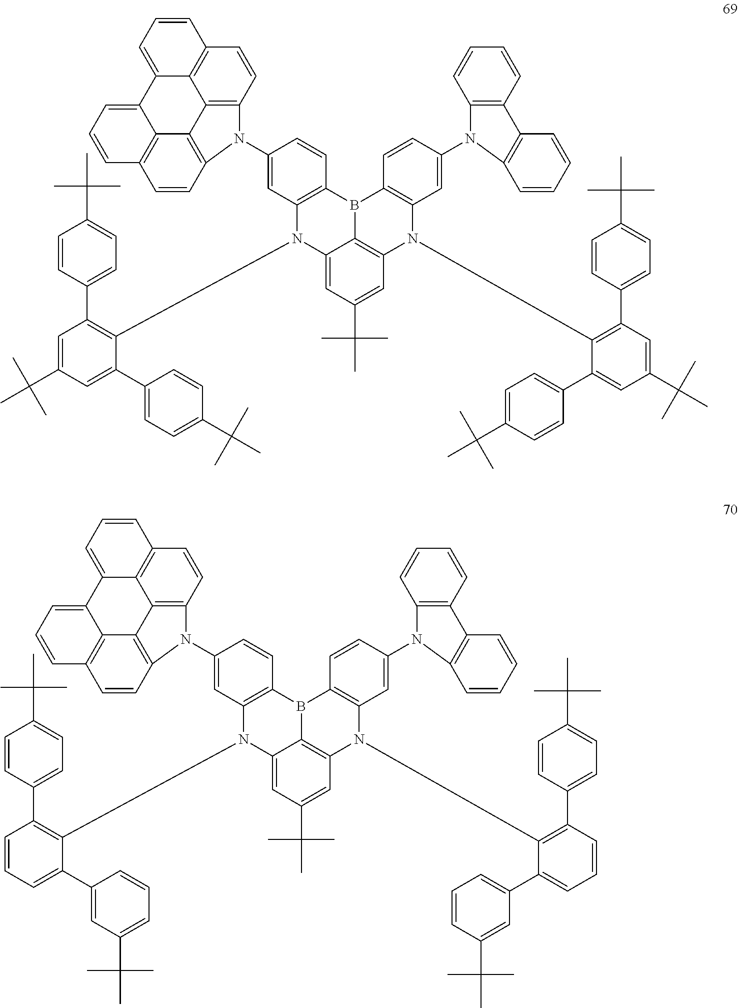

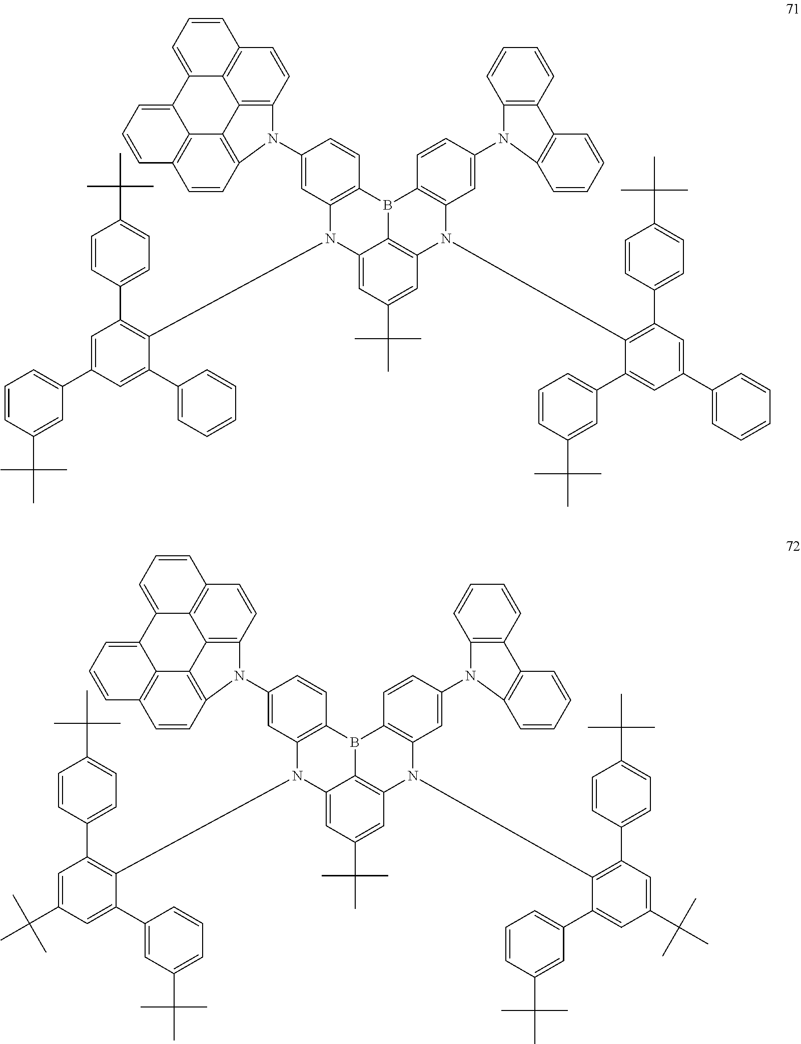 [SMILES: CC(C)(C)c1ccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(-c5cccc(C(C)(C)C)c5)cc4-c4ccc(C(C)(C)C)cc4)c4cc(C(C)(C)C)cc2c43)cc1 ; CC(C)(C)c1ccc(-c2cc(C(C)(C)C)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4cccc(C(C)(C)C)c4)c4cc(C(C)(C)C)cc2c43)cc1]

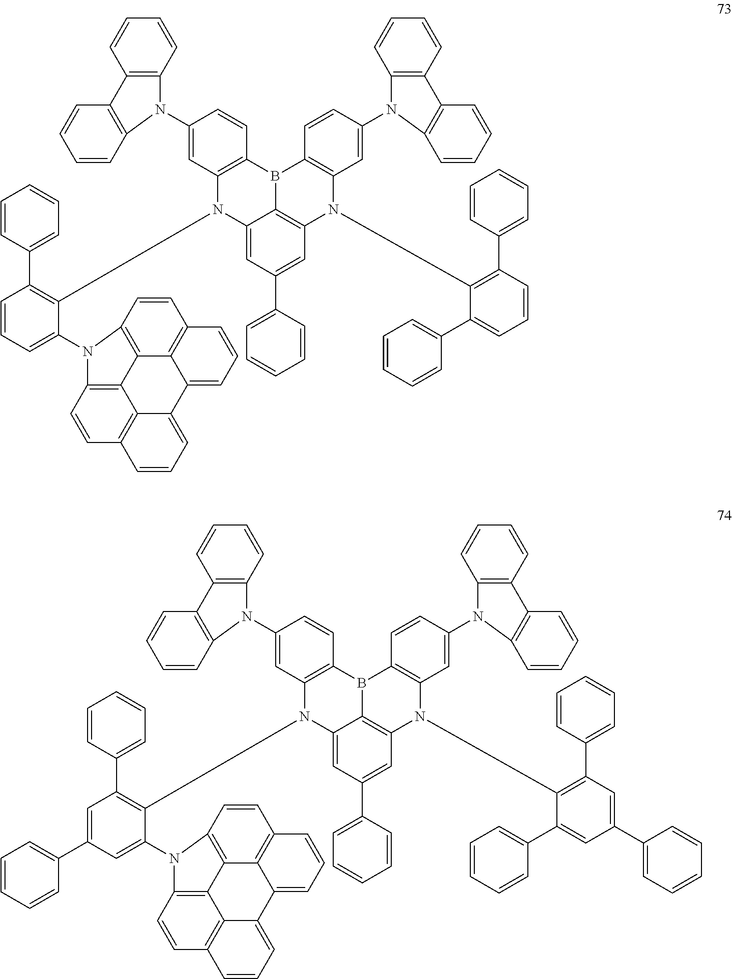 [SMILES: c1ccc(-c2cc3c4c(c2)N(c2c(-c5ccccc5)cccc2-n2c5ccc6cccc7c8cccc9ccc2c(c98)c5c67)c2cc(-n5c6ccccc6c6ccccc65)ccc2B4c2ccc(-n4c5ccccc5c5ccccc54)cc2N3c2c(-c3ccccc3)cccc2-c2ccccc2)cc1 ; c1ccc(-c2cc(-c3ccccc3)c(N3c4cc(-n5c6ccccc6c6ccccc65)ccc4B4c5ccc(-n6c7ccccc7c7ccccc76)cc5N(c5c(-c6ccccc6)cc(-c6ccccc6)cc5-n5c6ccc7cccc8c9cccc%10ccc5c(c%109)c6c78)c5cc(-c6ccccc6)cc3c54)c(-c3ccccc3)c2)cc1]

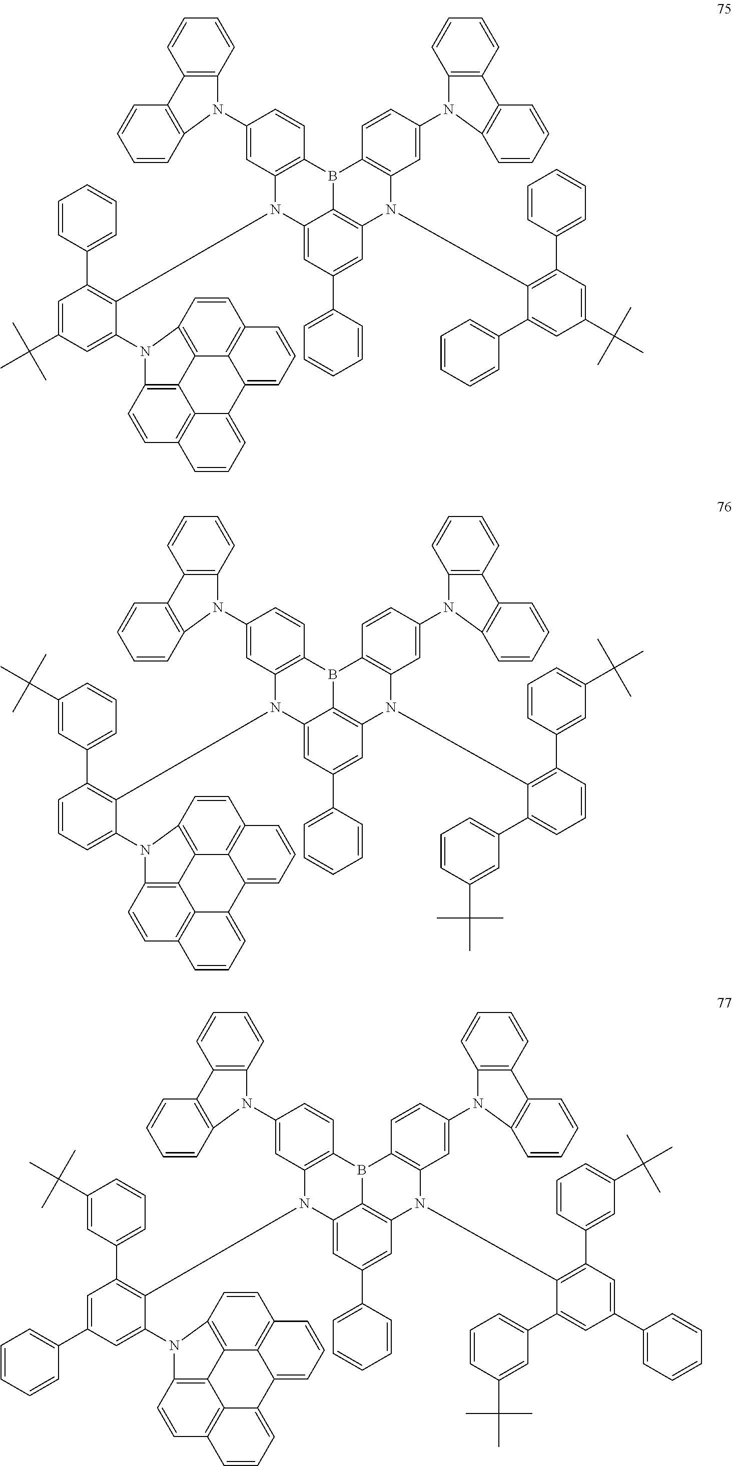

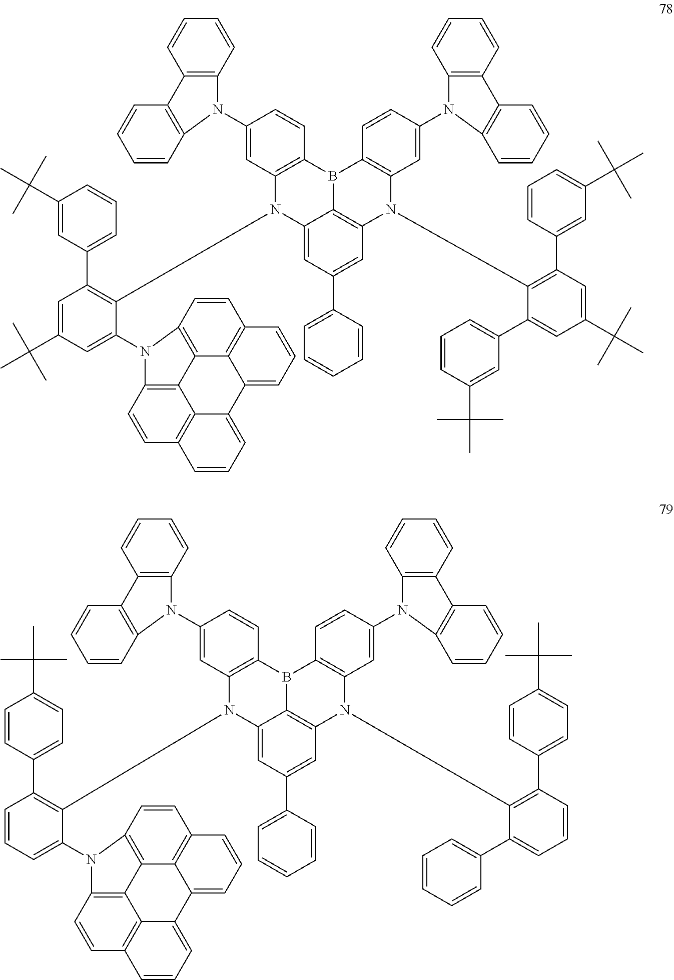

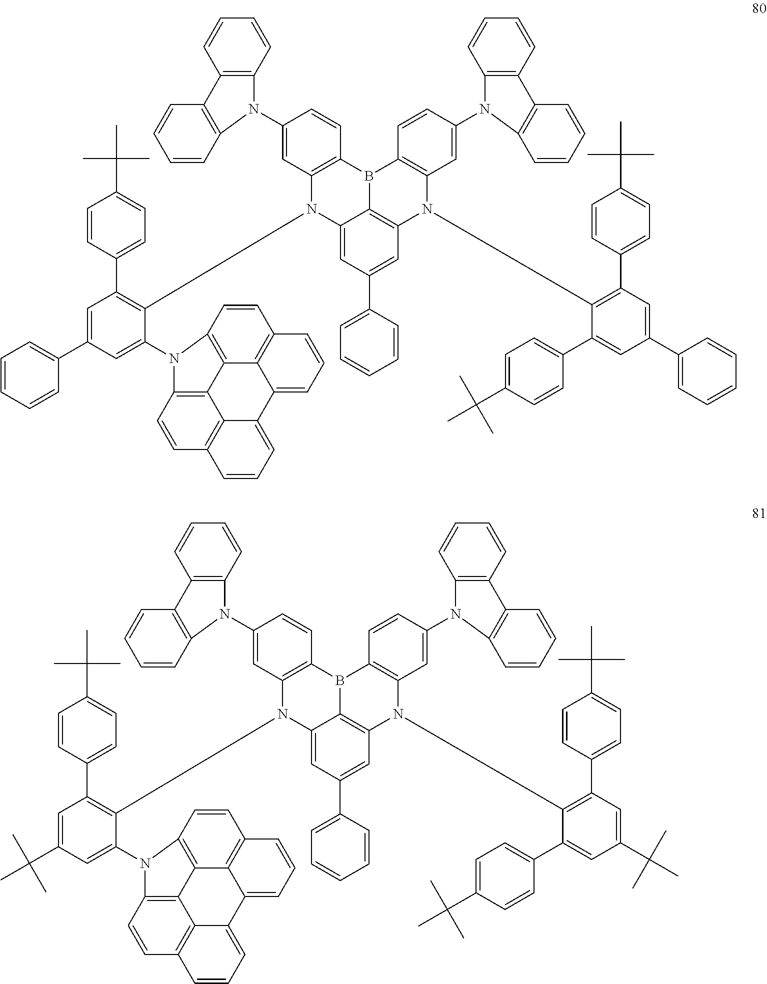

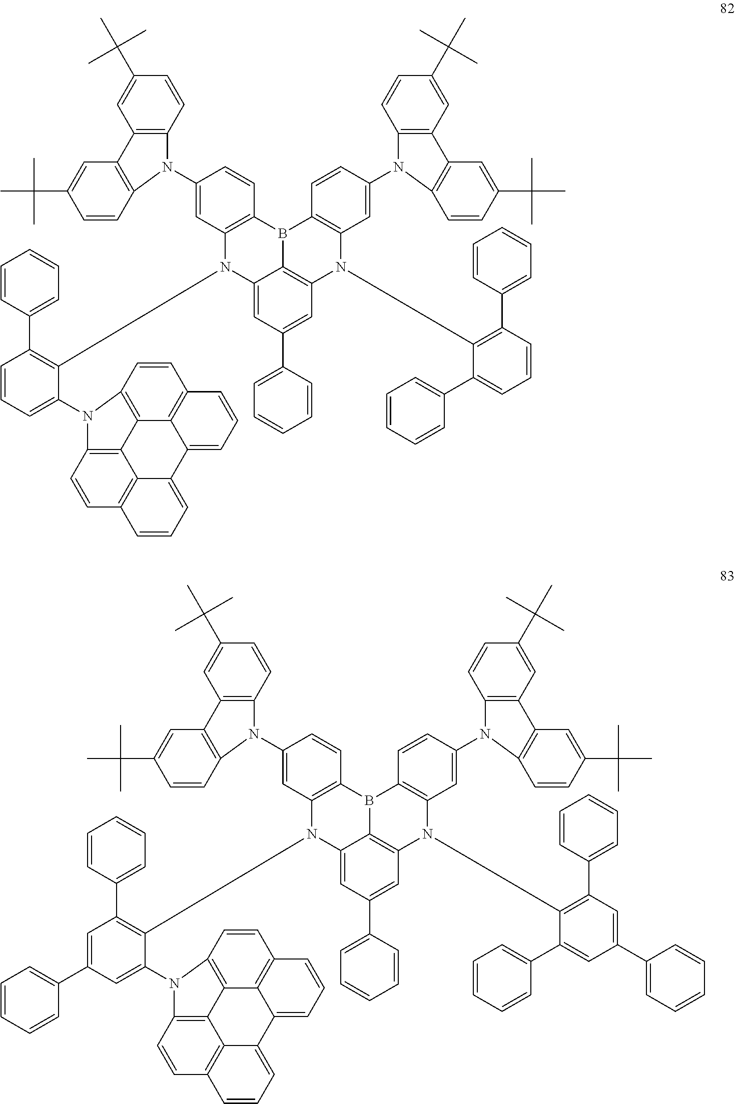 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2ccccc2)cccc1-n1c2ccc3cccc4c5cccc6ccc1c(c65)c2c34 ; CC(C)(C)c1ccc2c(c1)c1cc(C(C)(C)C)ccc1n2-c1ccc2c(c1)N(c1c(-c3ccccc3)cc(-c3ccccc3)cc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2ccccc2)cc(-c2ccccc2)cc1-n1c2ccc3cccc4c5cccc6ccc1c(c65)c2c34]

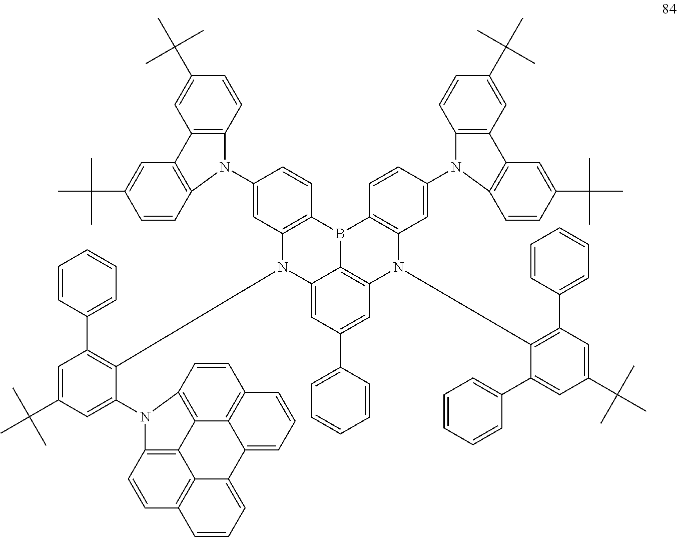 [SMILES: CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-n4c5ccc6cccc7c8cccc9ccc4c(c98)c5c67)c4cc(-c5ccccc5)cc2c43)c(-c2ccccc2)c1]

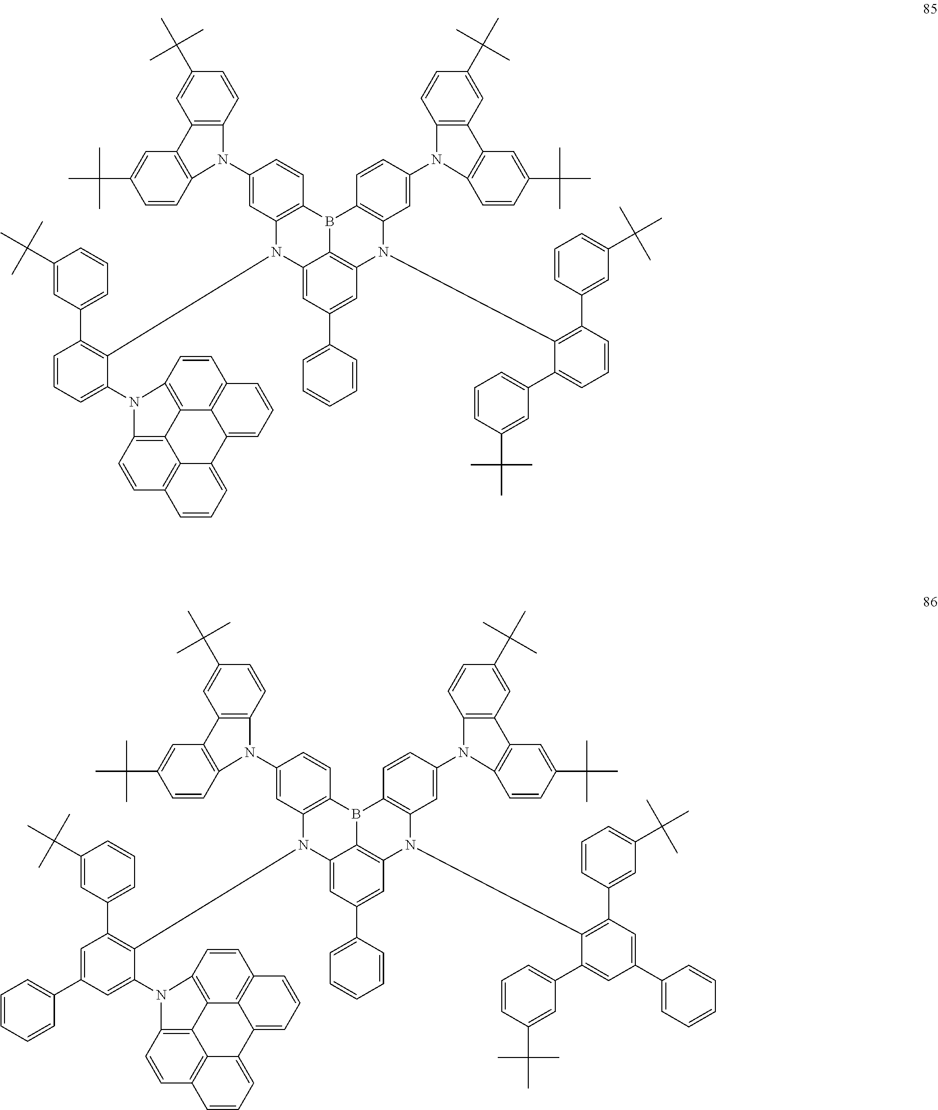

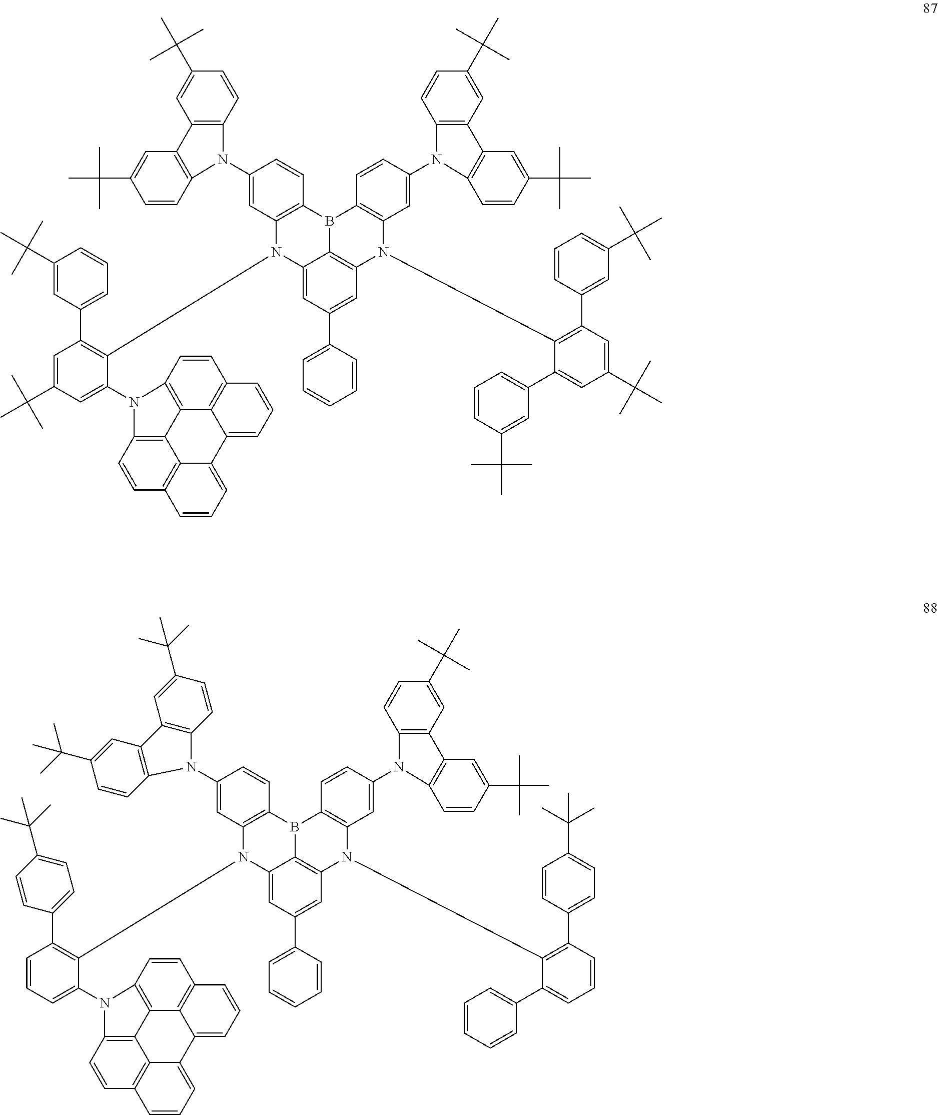

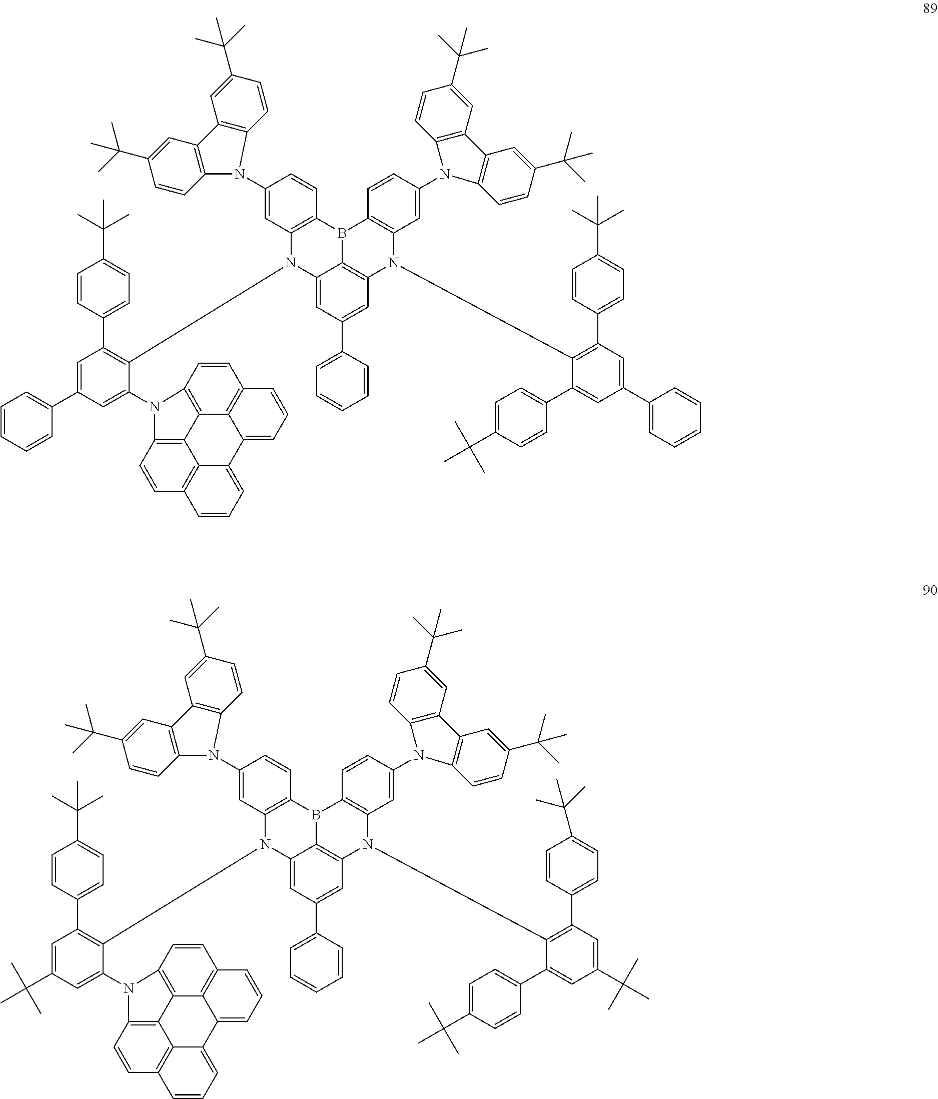

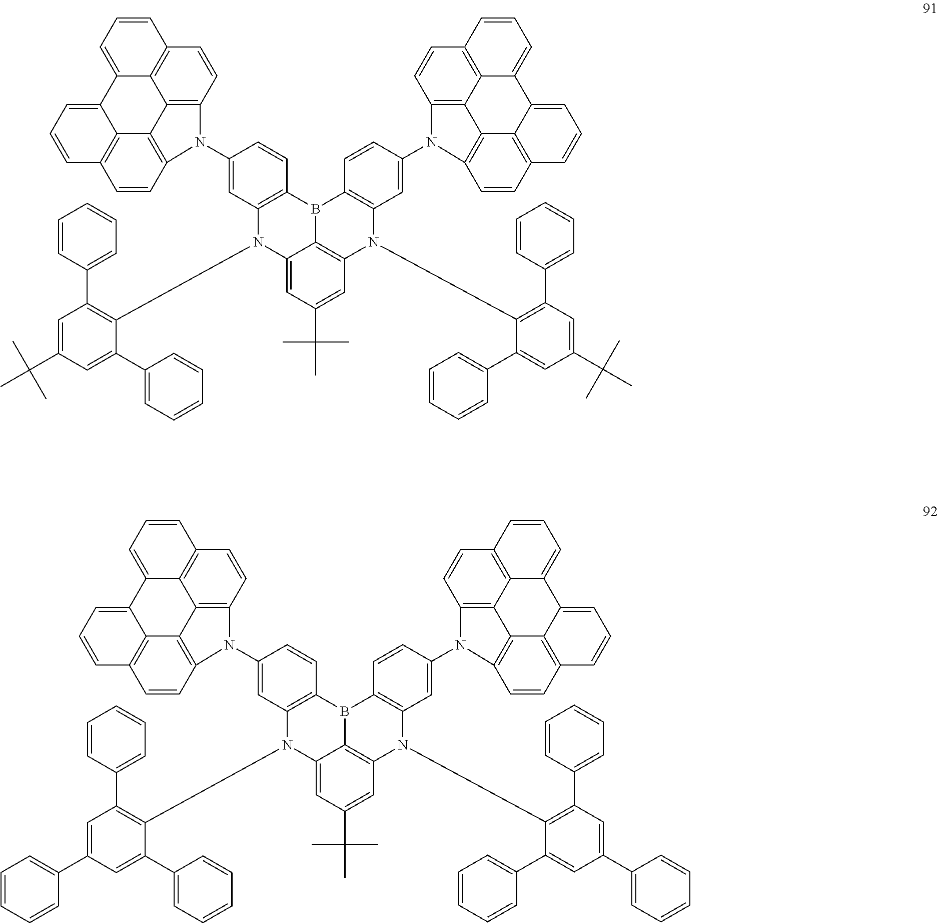 [SMILES: CC(C)(C)c1cc(-c2ccccc2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cc(-c2ccccc2)cc1-c1ccccc1]

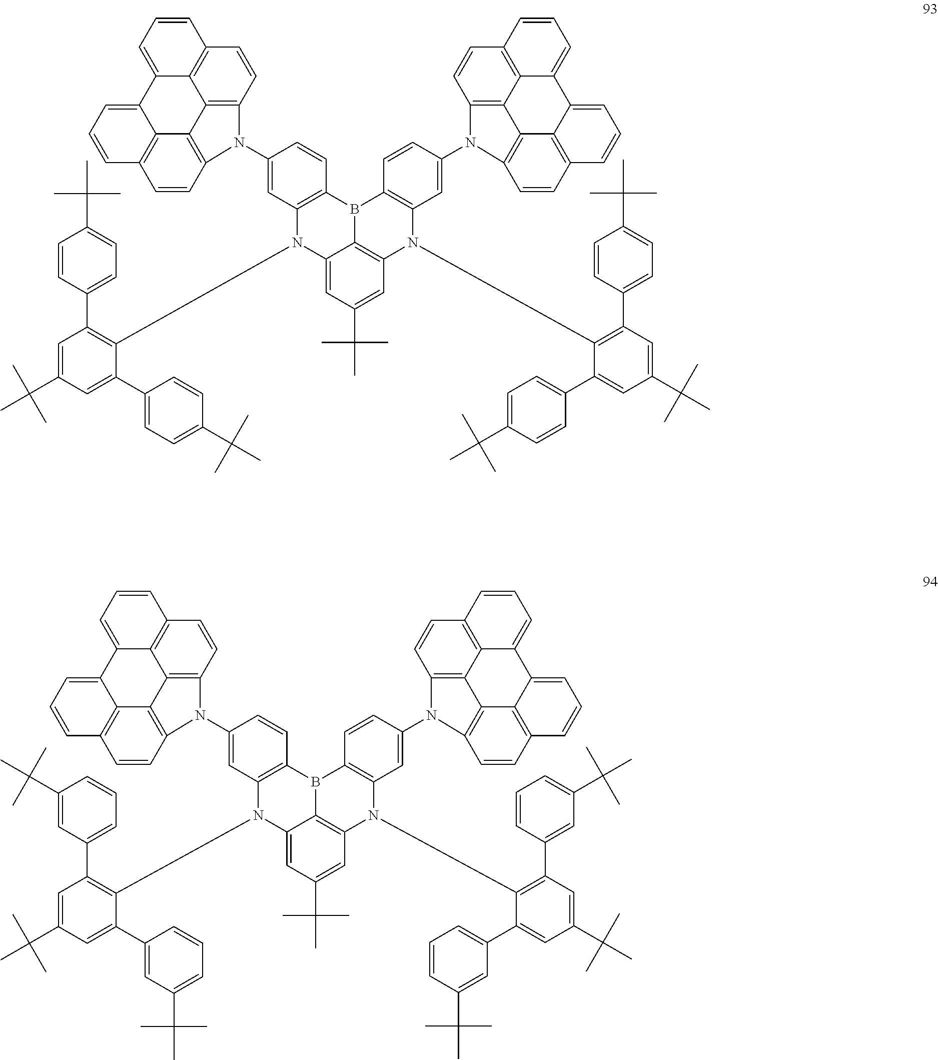

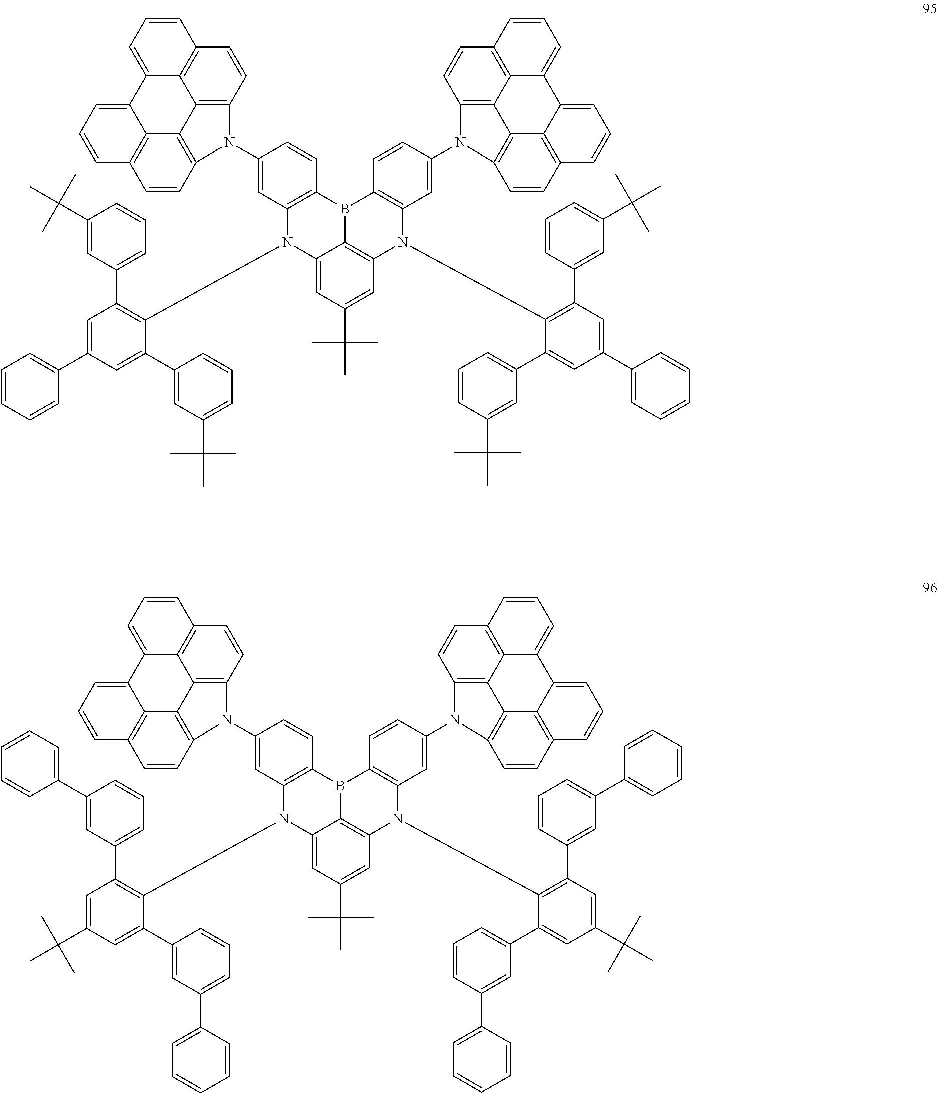 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2cccc(-c3ccccc3)c2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

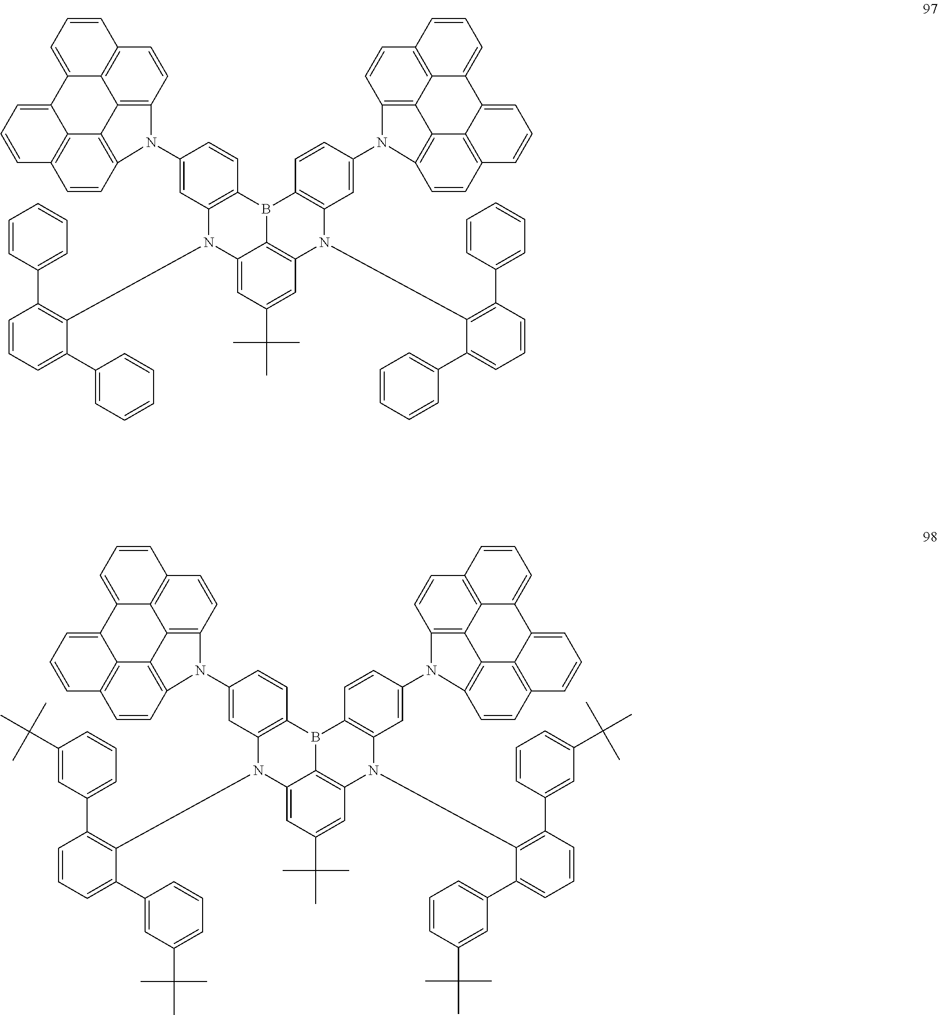 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1 ; CC(C)(C)c1cccc(-c2cccc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(C(C)(C)C)cc2c43)c1]

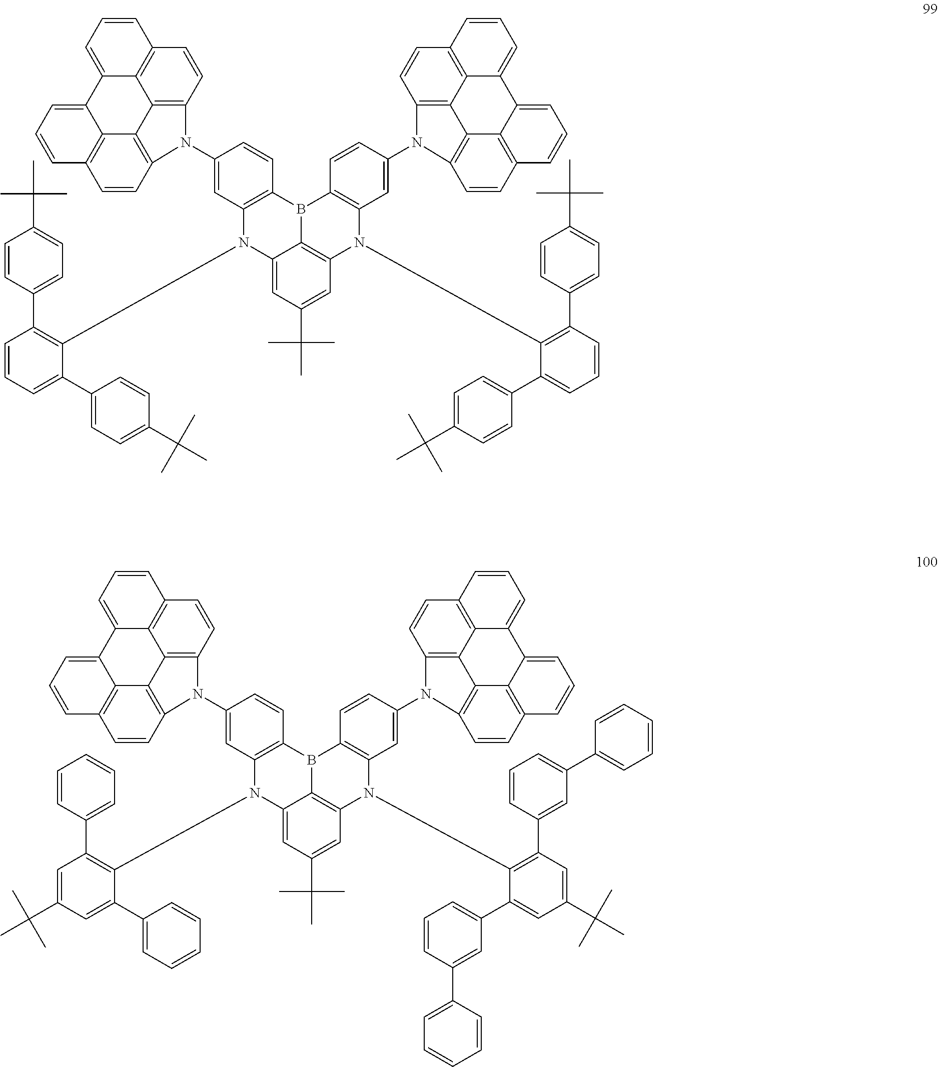

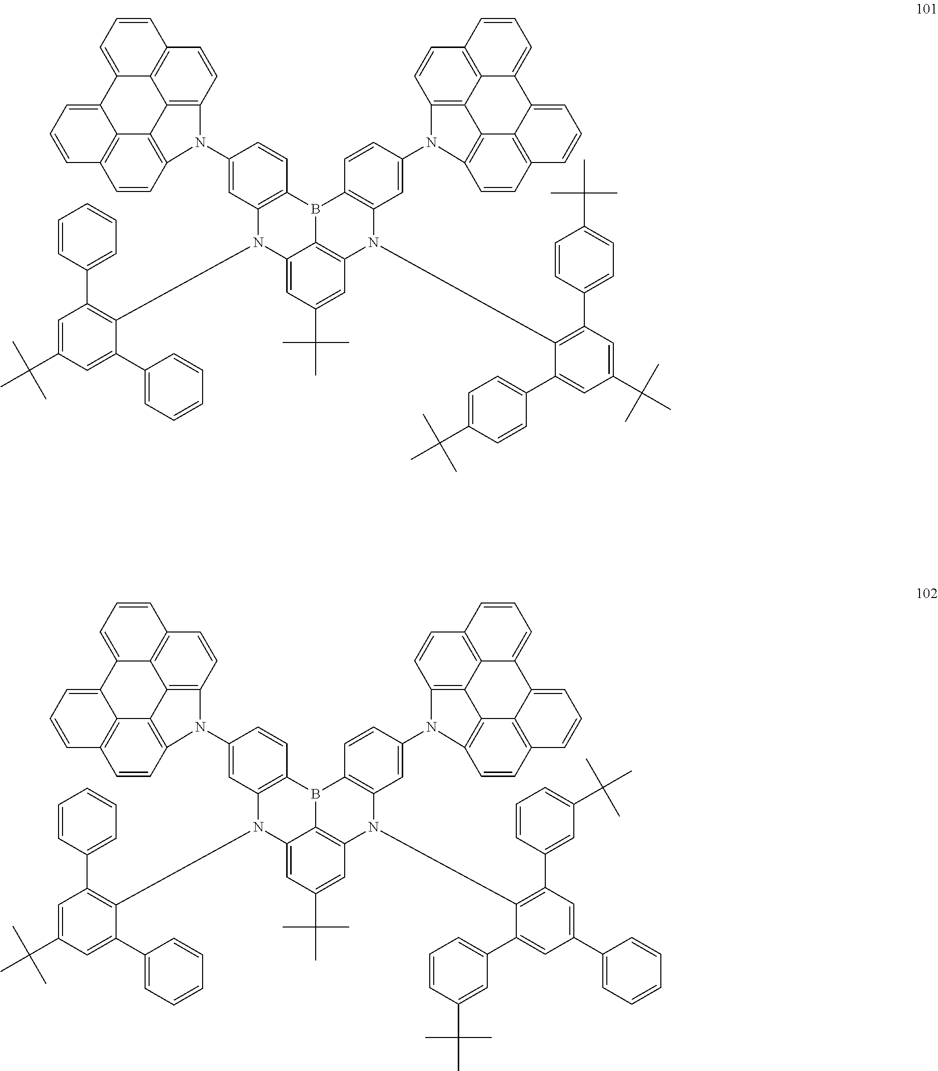

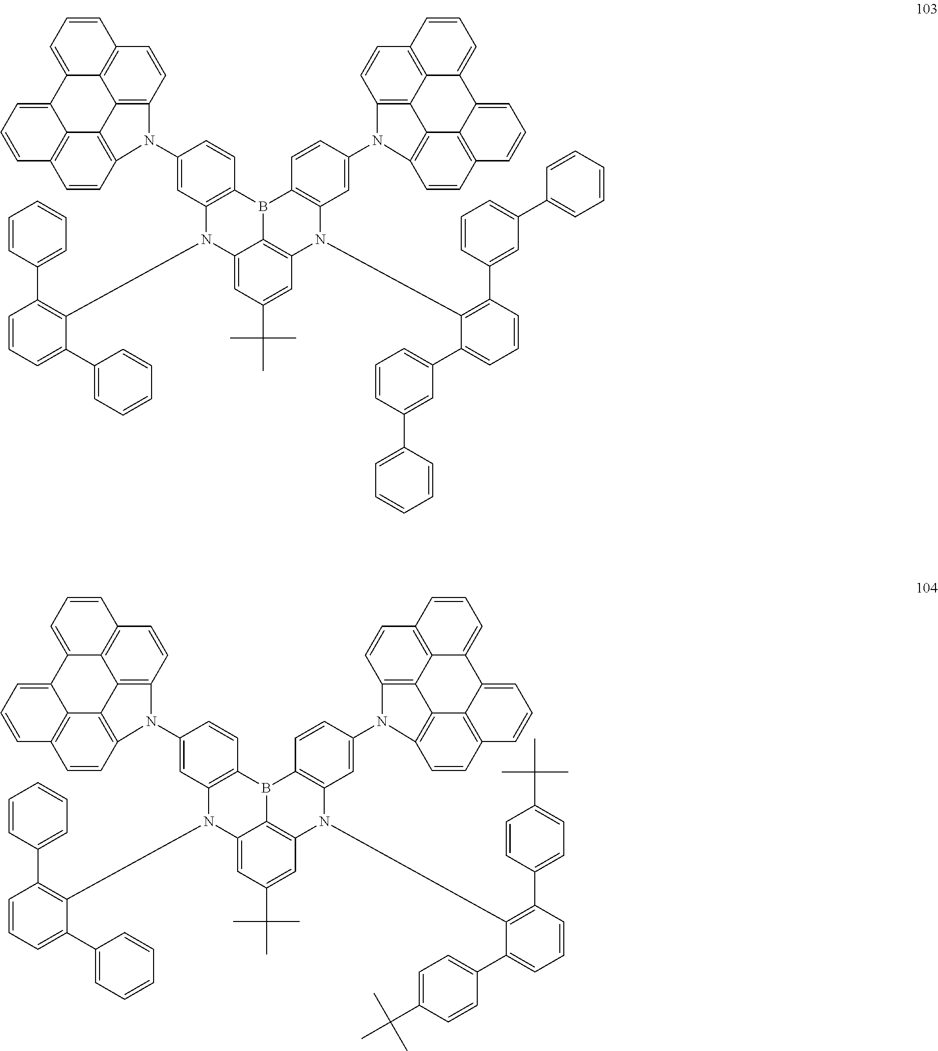 [SMILES: CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1 ; CC(C)(C)c1ccc(-c2cccc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)cc1]

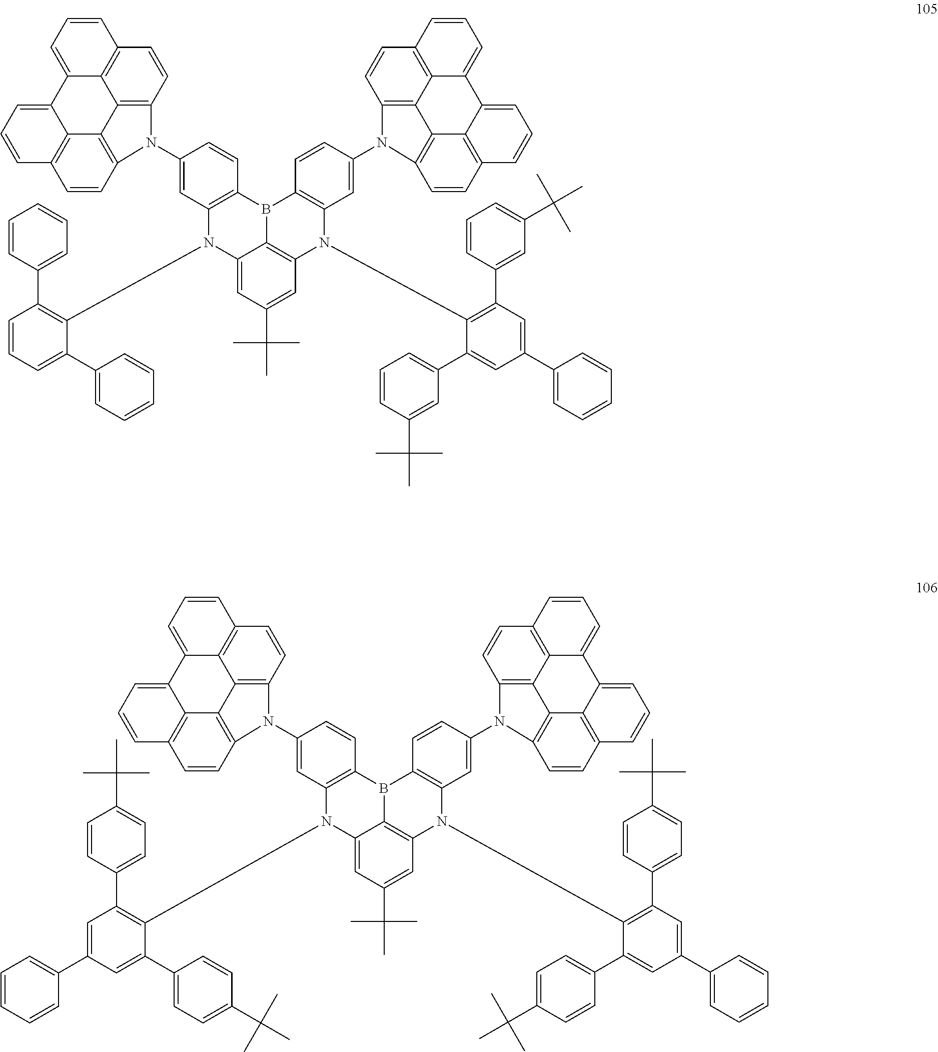 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)c1 ; CC(C)(C)c1ccc(-c2cc(-c3ccccc3)cc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

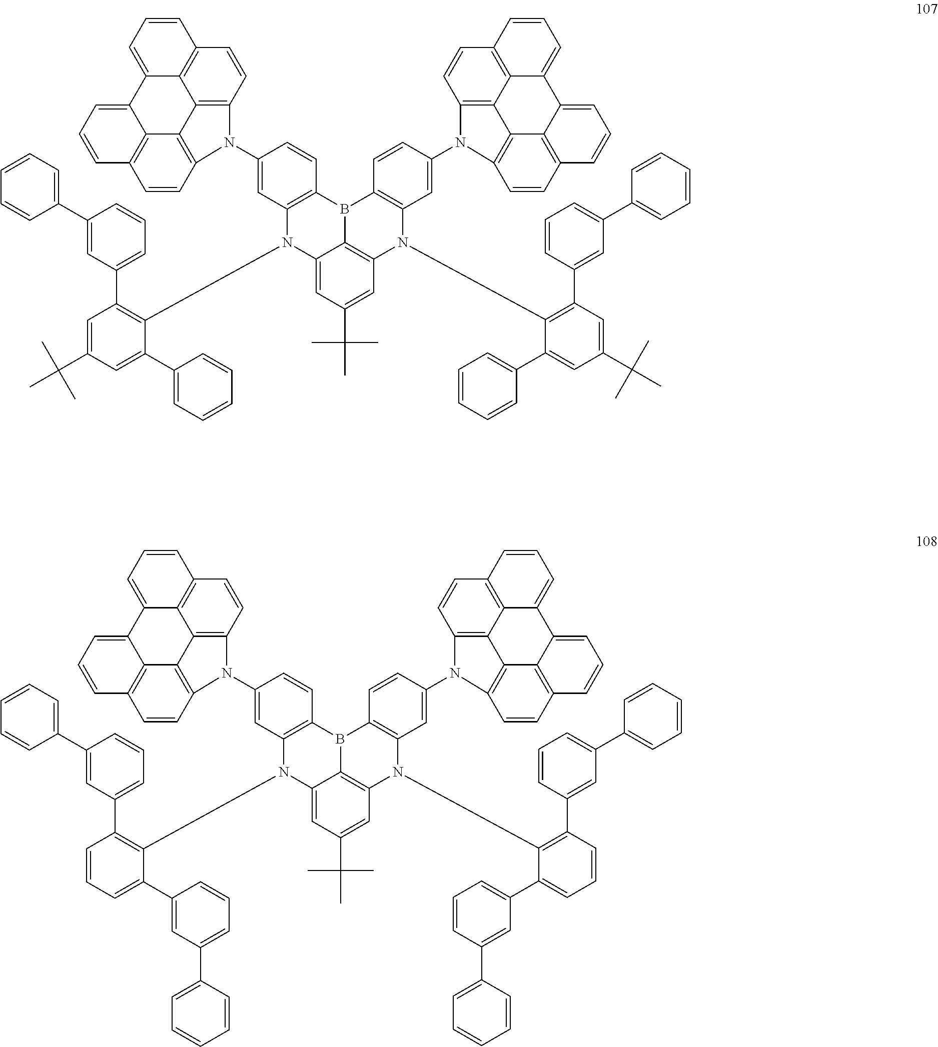 [SMILES: CC(C)(C)c1cc(-c2ccccc2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2cccc(-c3ccccc3)c2)cccc1-c1cccc(-c2ccccc2)c1]

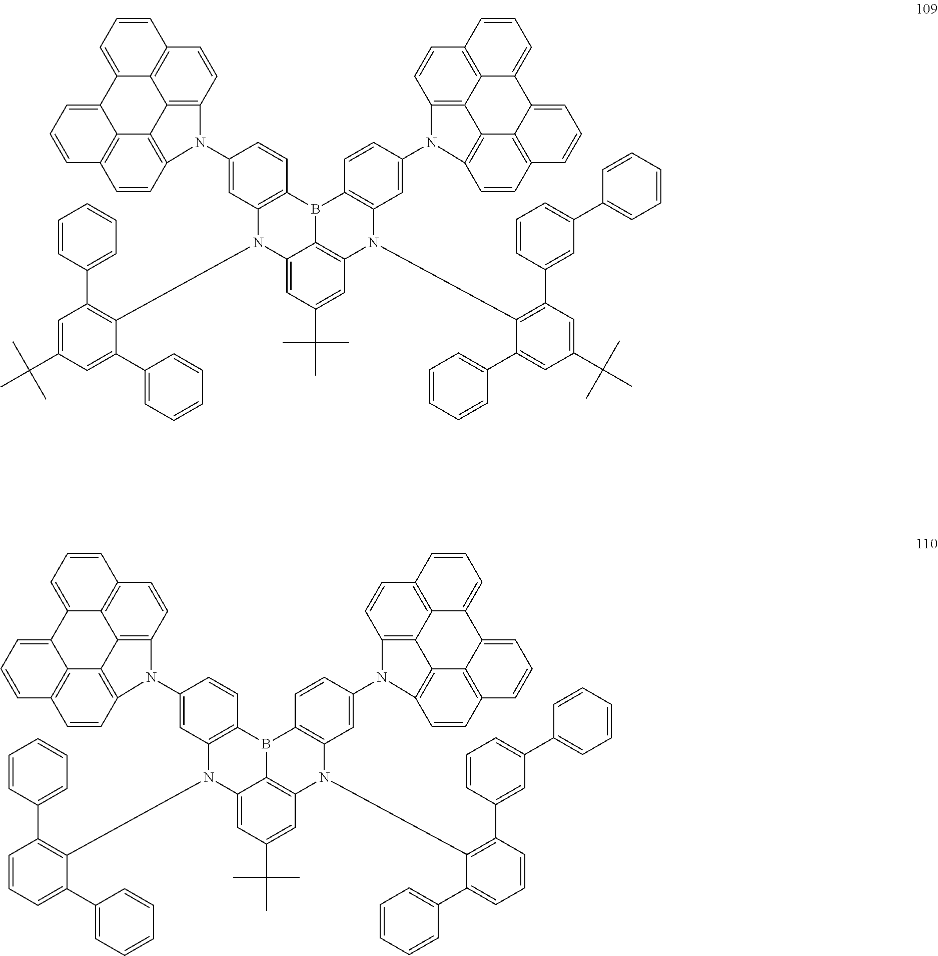 [SMILES: CC(C)(C)c1cc(-c2ccccc2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2ccccc2)c1 ; CC(C)(C)c1cc2c3c(c1)N(c1c(-c4ccccc4)cccc1-c1cccc(-c4ccccc4)c1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1]

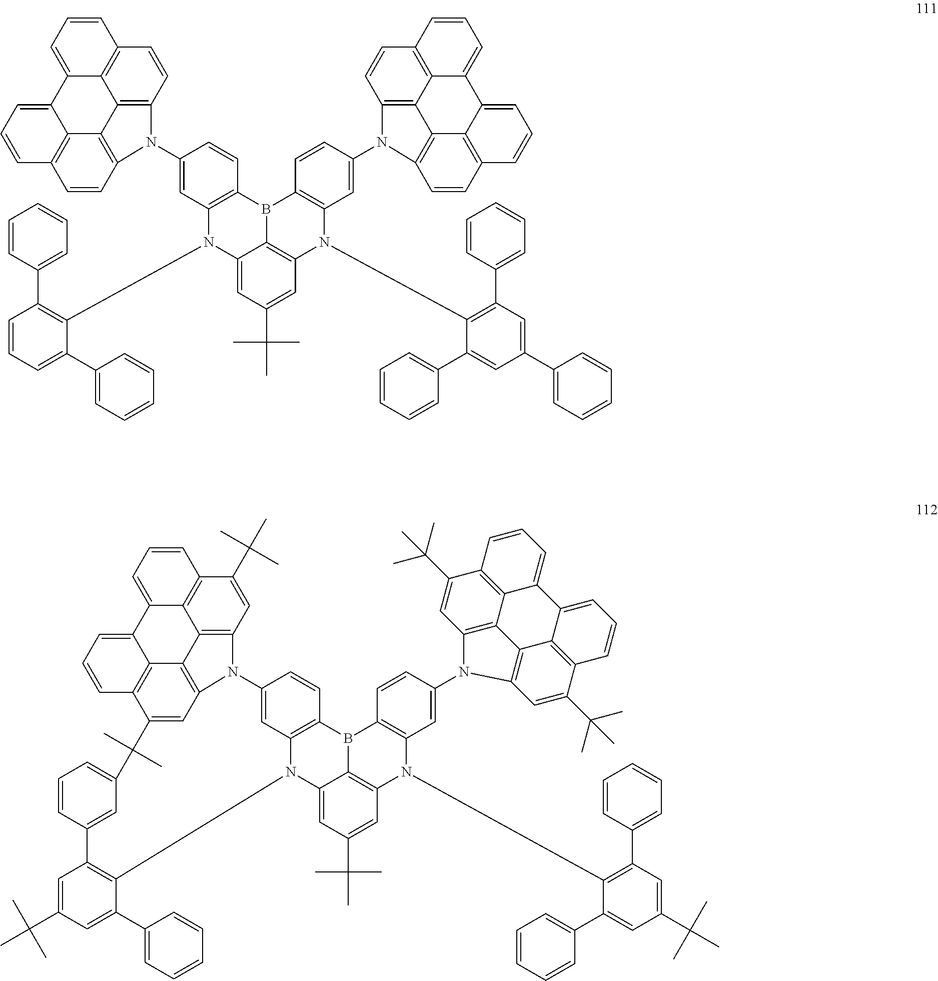 [SMILES: CC(C)(C)c1cc2c3c(c1)N(c1c(-c4ccccc4)cc(-c4ccccc4)cc1-c1ccccc1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1 ; CC(C)(C)c1cc(-c2ccccc2)c(N2c3cc(-n4c5cc(C(C)(C)C)c6cccc7c8cccc9c(C(C)(C)C)cc4c(c98)c5c67)ccc3B3c4ccc5cc4N(c4cc(C(C)(C)C)cc2c43)c2c(-c3ccccc3)cc(C(C)(C)C)cc2-c2cccc(c2)C(C)(C)c2cc3c4c6c2cccc6c2cccc6c(C(C)(C)C)cc(c4c62)n3-5)c(-c2ccccc2)c1]

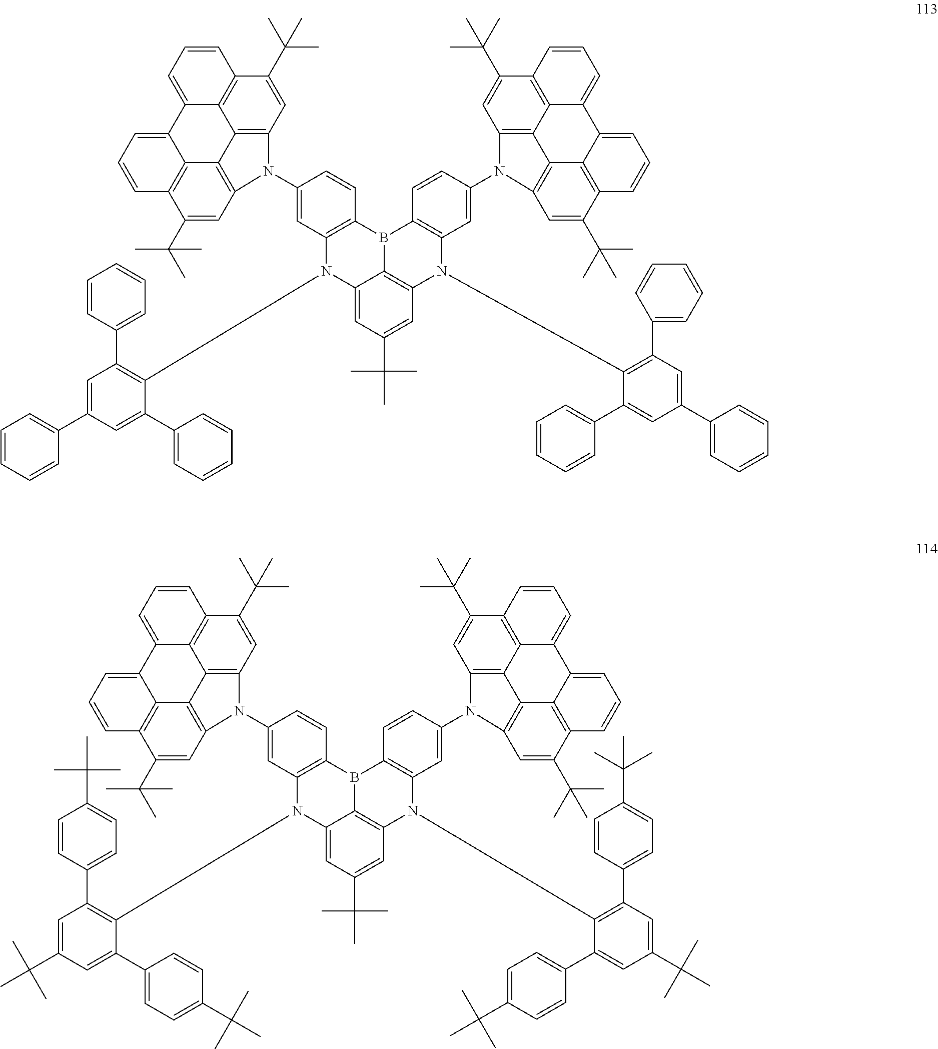

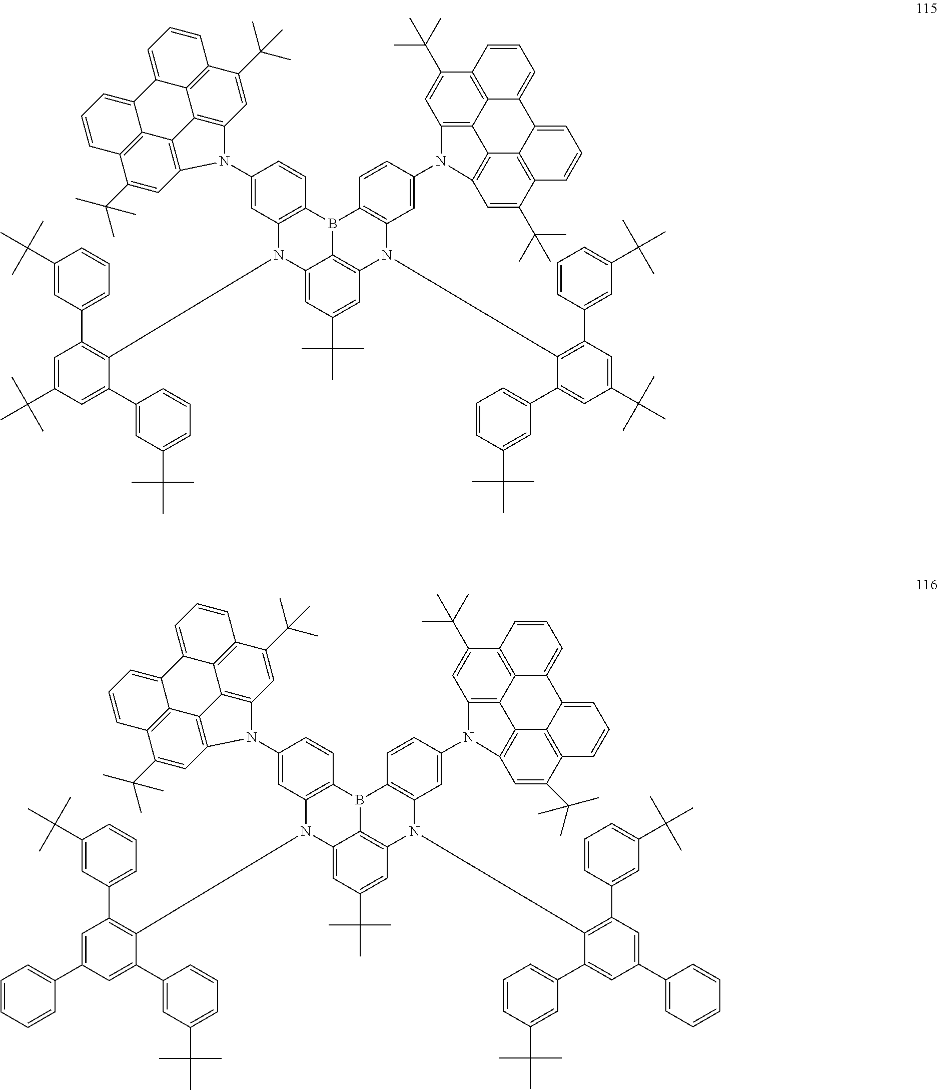

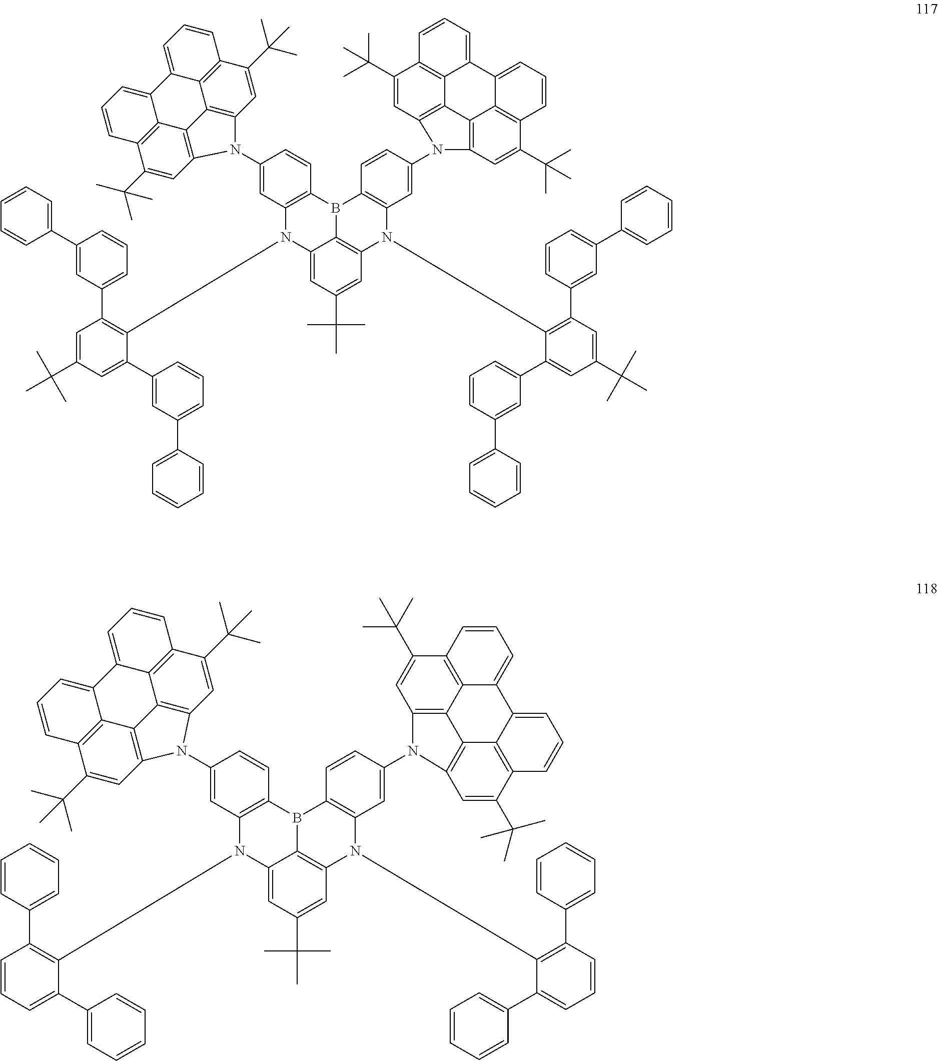

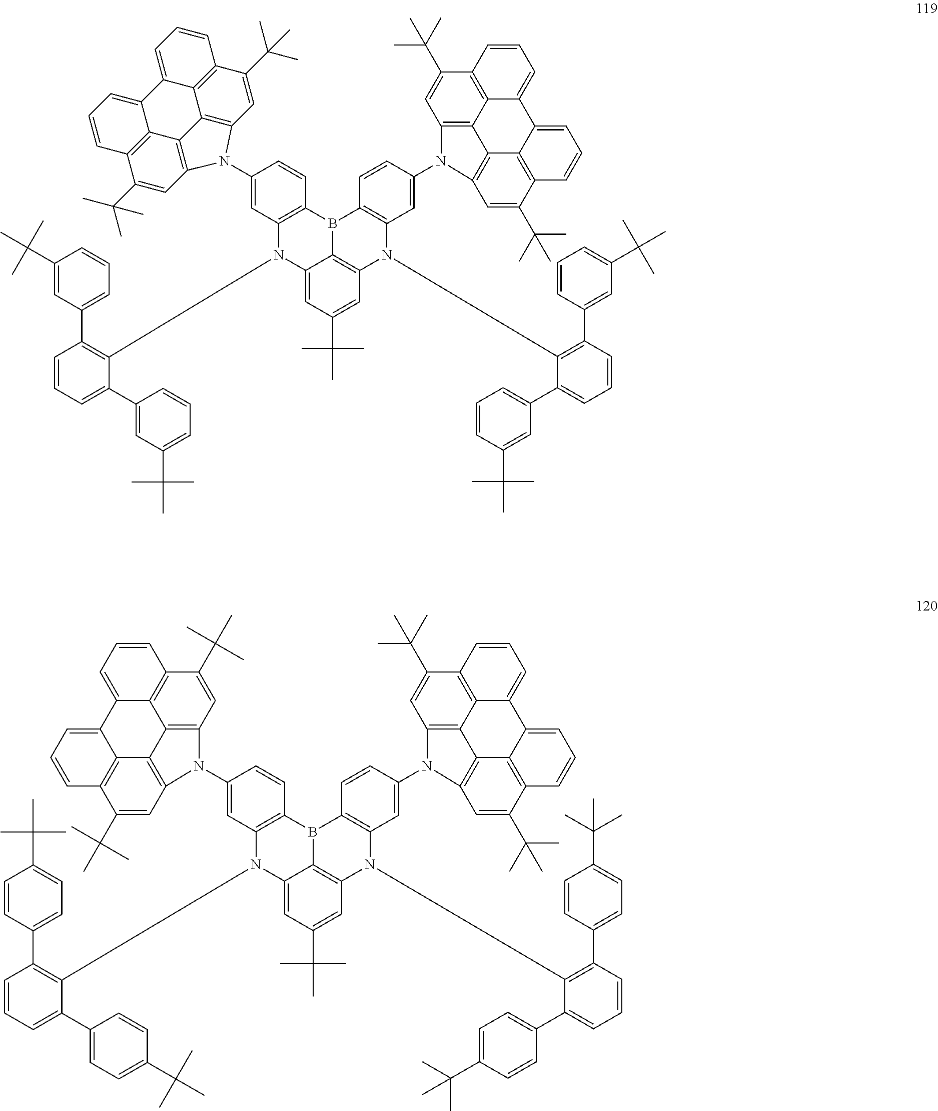

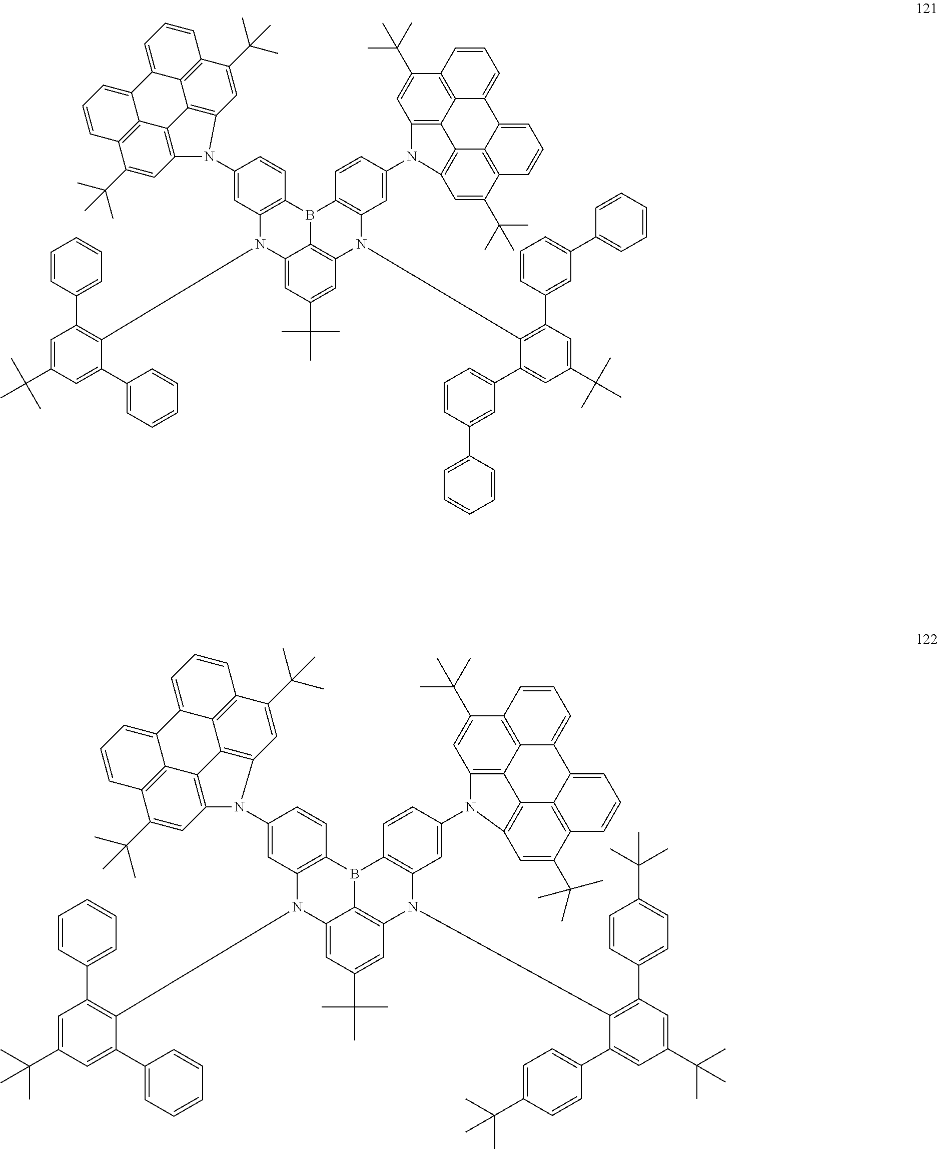

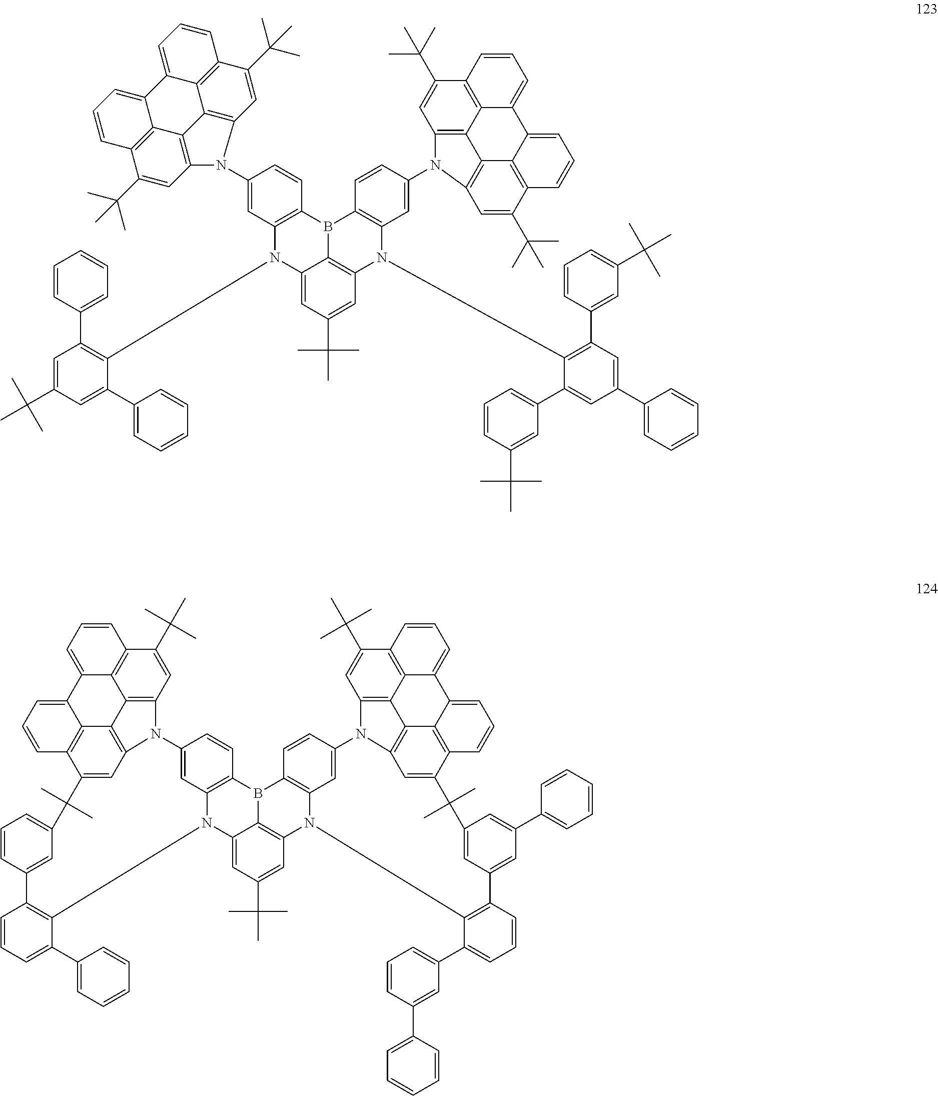 [SMILES: CC(C)(C)c1cccc(-c2cc(-c3ccccc3)cc(-c3cccc(C(C)(C)C)c3)c2N2c3cc(-n4c5cc(C(C)(C)C)c6cccc7c8cccc9c(C(C)(C)C)cc4c(c98)c5c67)ccc3B3c4ccc(-n5c6cc(C(C)(C)C)c7cccc8c9cccc%10c(C(C)(C)C)cc5c(c%109)c6c78)cc4N(c4c(-c5ccccc5)cc(C(C)(C)C)cc4-c4ccccc4)c4cc(C(C)(C)C)cc2c43)c1 ; CC(C)(C)c1cc2c3c(c1)N1c4cc(ccc4B3c3ccc4cc3N2c2c(-c3ccccc3)cccc2-c2cccc(c2)C(C)(C)c2cc3c5c6c2cccc6c2cccc6c(C(C)(C)C)cc(c5c62)n3-4)-n2c3cc(C(C)(C)C)c4cccc5c6cccc7c(cc2c(c76)c3c45)C(C)(C)c2cc(-c3ccccc3)cc(c2)-c2cccc(-c3cccc(-c4ccccc4)c3)c21]

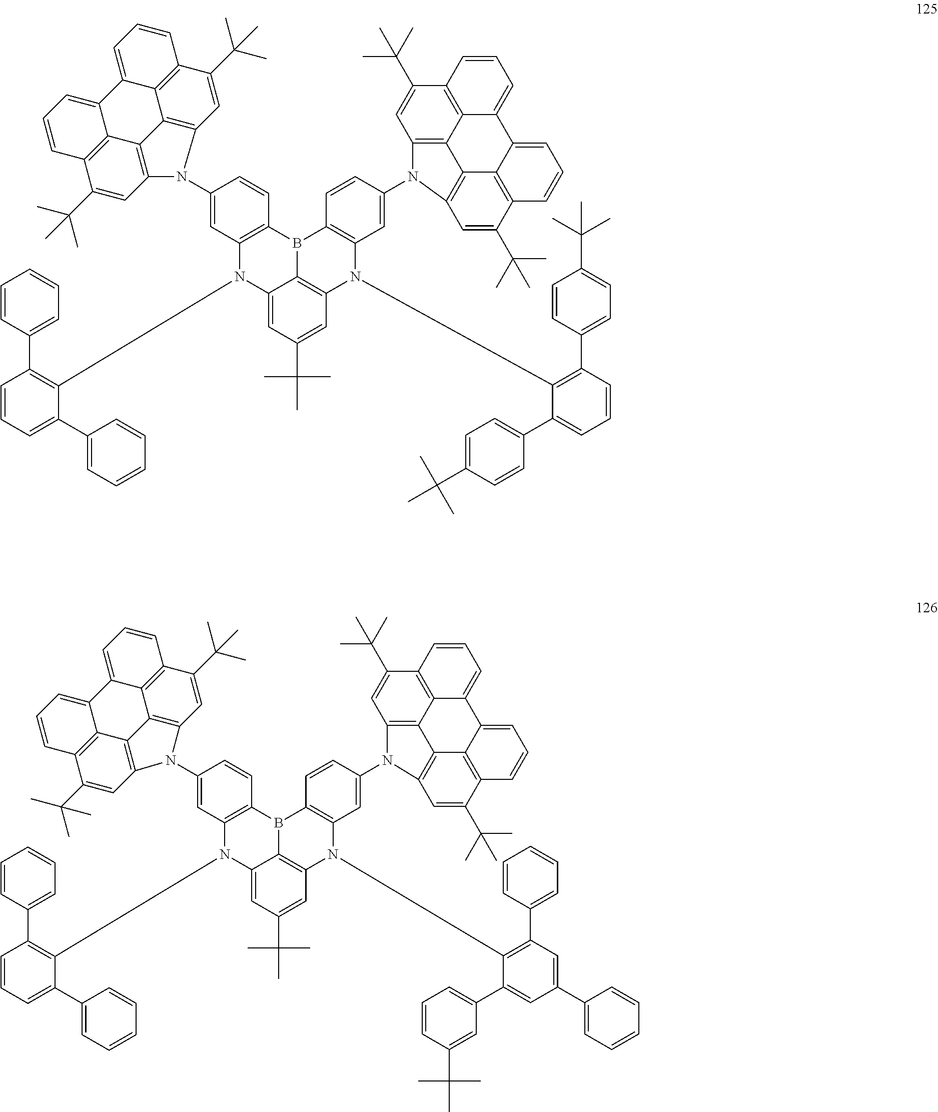 [SMILES: CC(C)(C)c1ccc(-c2cccc(-c3ccc(C(C)(C)C)cc3)c2N2c3cc(-n4c5cc(C(C)(C)C)c6cccc7c8cccc9c(C(C)(C)C)cc4c(c98)c5c67)ccc3B3c4ccc(-n5c6cc(C(C)(C)C)c7cccc8c9cccc%10c(C(C)(C)C)cc5c(c%109)c6c78)cc4N(c4c(-c5ccccc5)cccc4-c4ccccc4)c4cc(C(C)(C)C)cc2c43)cc1 ; CC(C)(C)c1cccc(-c2cc(-c3ccccc3)cc(-c3ccccc3)c2N2c3cc(-n4c5cc(C(C)(C)C)c6cccc7c8cccc9c(C(C)(C)C)cc4c(c98)c5c67)ccc3B3c4ccc(-n5c6cc(C(C)(C)C)c7cccc8c9cccc%10c(C(C)(C)C)cc5c(c%109)c6c78)cc4N(c4c(-c5ccccc5)cccc4-c4ccccc4)c4cc(C(C)(C)C)cc2c43)c1]

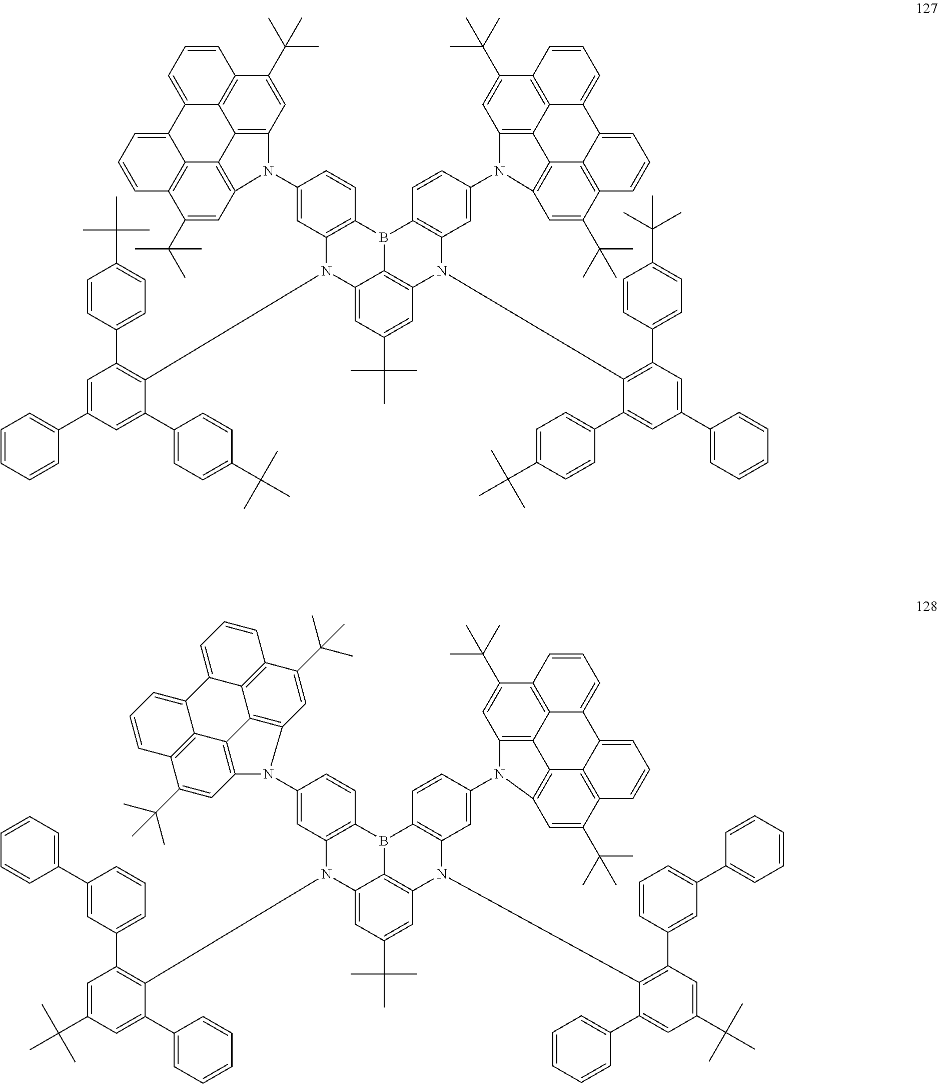

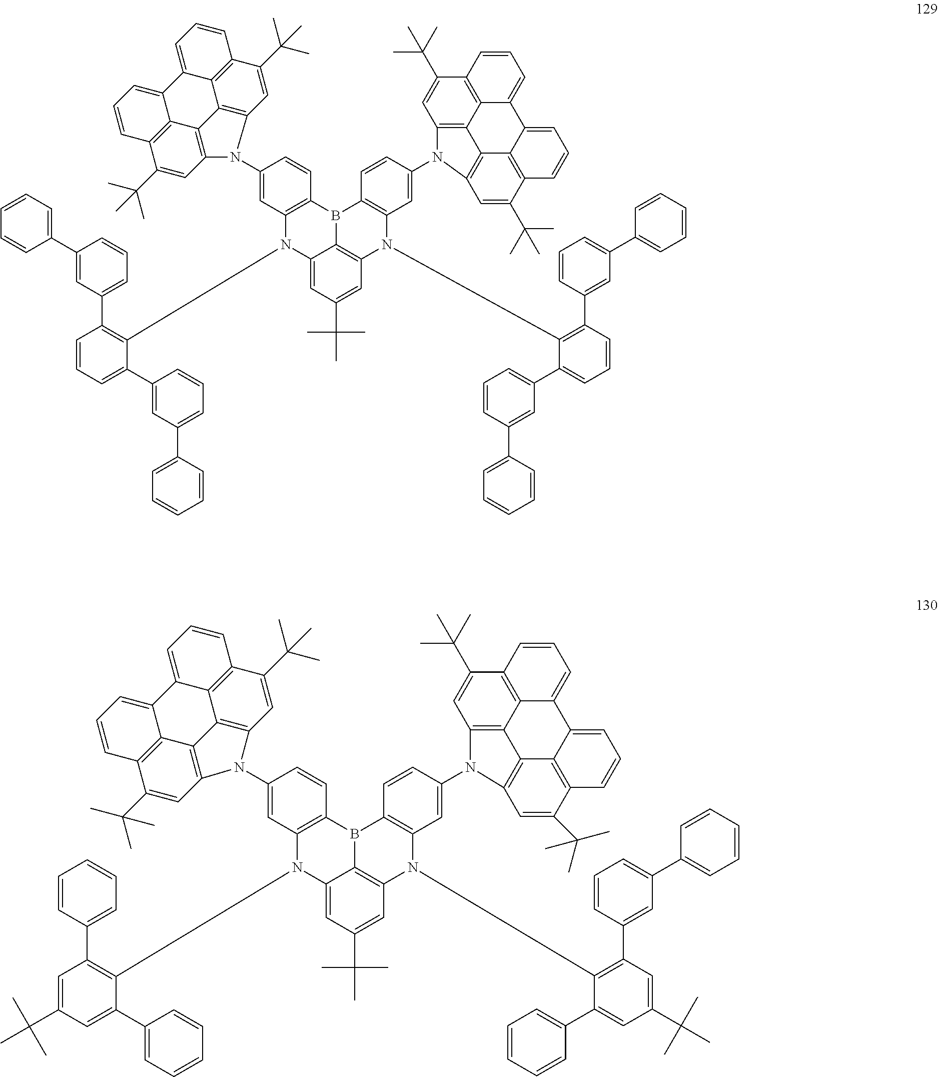

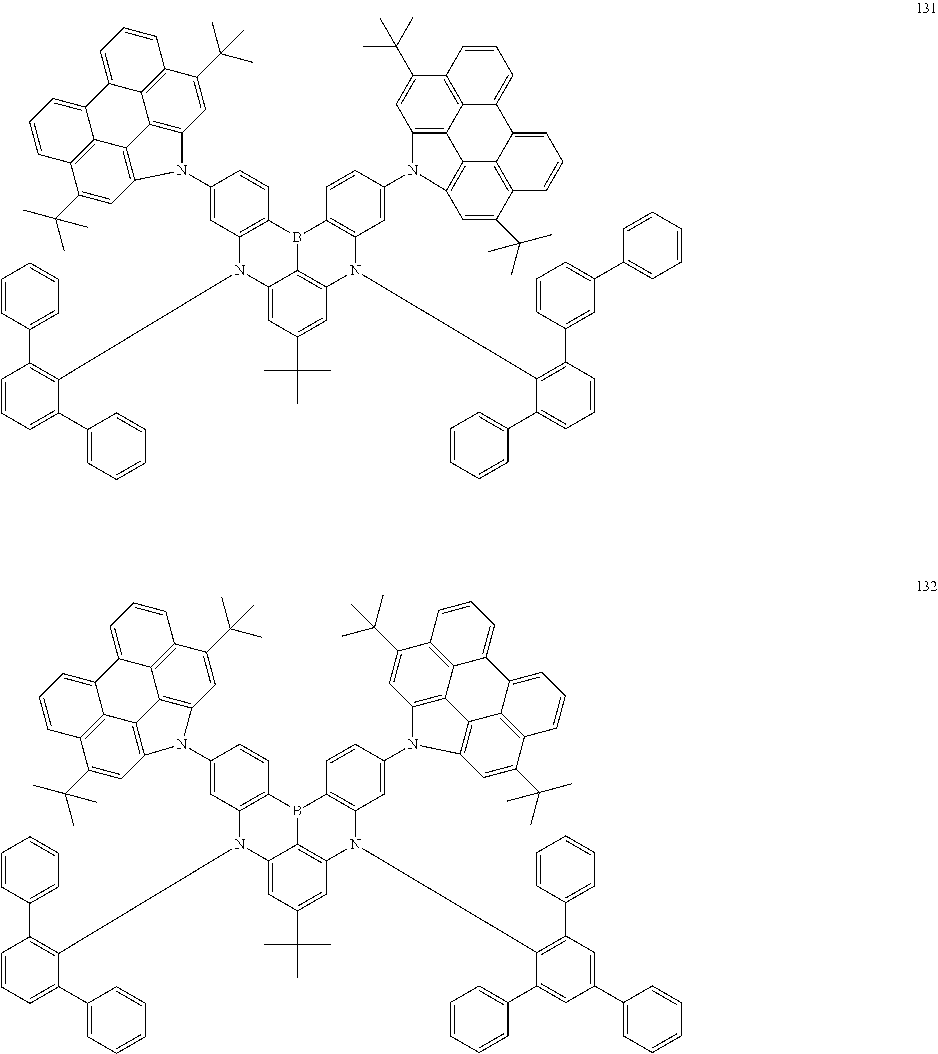 [SMILES: CC(C)(C)c1cc2c3c(c1)N(c1c(-c4ccccc4)cccc1-c1cccc(-c4ccccc4)c1)c1cc(-n4c5cc(C(C)(C)C)c6cccc7c8cccc9c(C(C)(C)C)cc4c(c98)c5c67)ccc1B3c1ccc(-n3c4cc(C(C)(C)C)c5cccc6c7cccc8c(C(C)(C)C)cc3c(c87)c4c56)cc1N2c1c(-c2ccccc2)cccc1-c1ccccc1 ; CC(C)(C)c1cc2c3c(c1)N(c1c(-c4ccccc4)cc(-c4ccccc4)cc1-c1ccccc1)c1cc(-n4c5cc(C(C)(C)C)c6cccc7c8cccc9c(C(C)(C)C)cc4c(c98)c5c67)ccc1B3c1ccc(-n3c4cc(C(C)(C)C)c5cccc6c7cccc8c(C(C)(C)C)cc3c(c87)c4c56)cc1N2c1c(-c2ccccc2)cccc1-c1ccccc1]

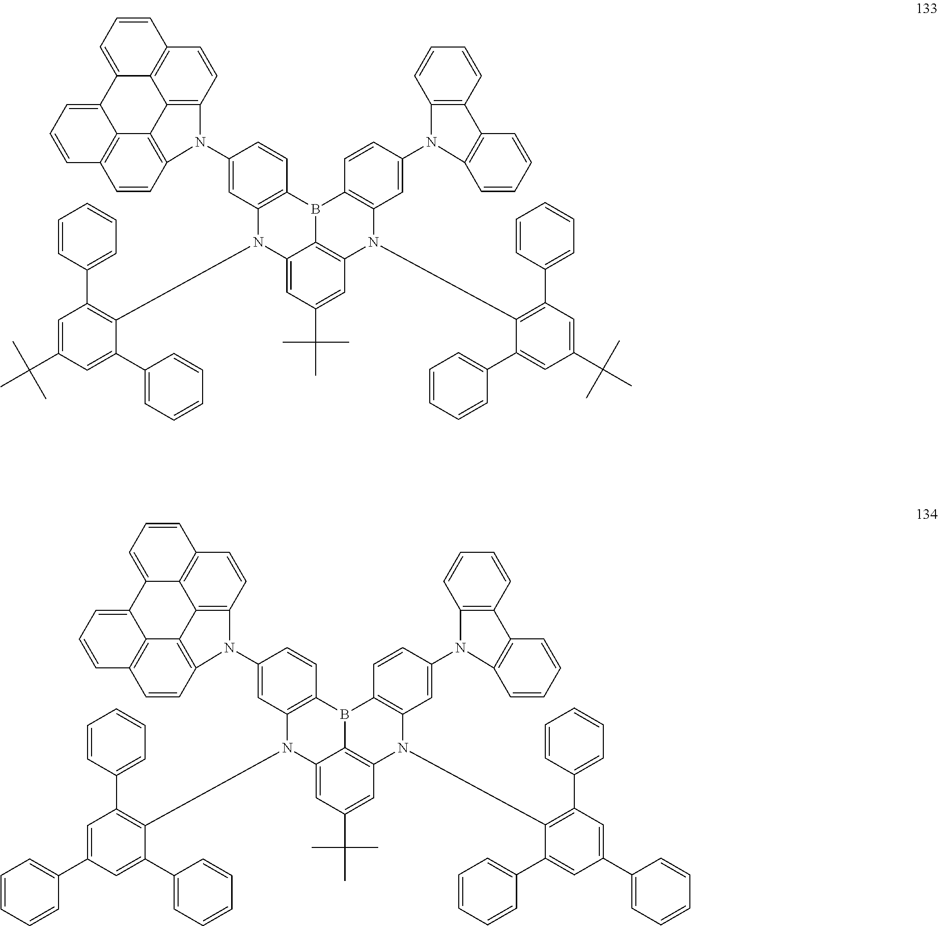 [SMILES: CC(C)(C)c1cc(-c2ccccc2)c(N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cc(-c2ccccc2)cc1-c1ccccc1]

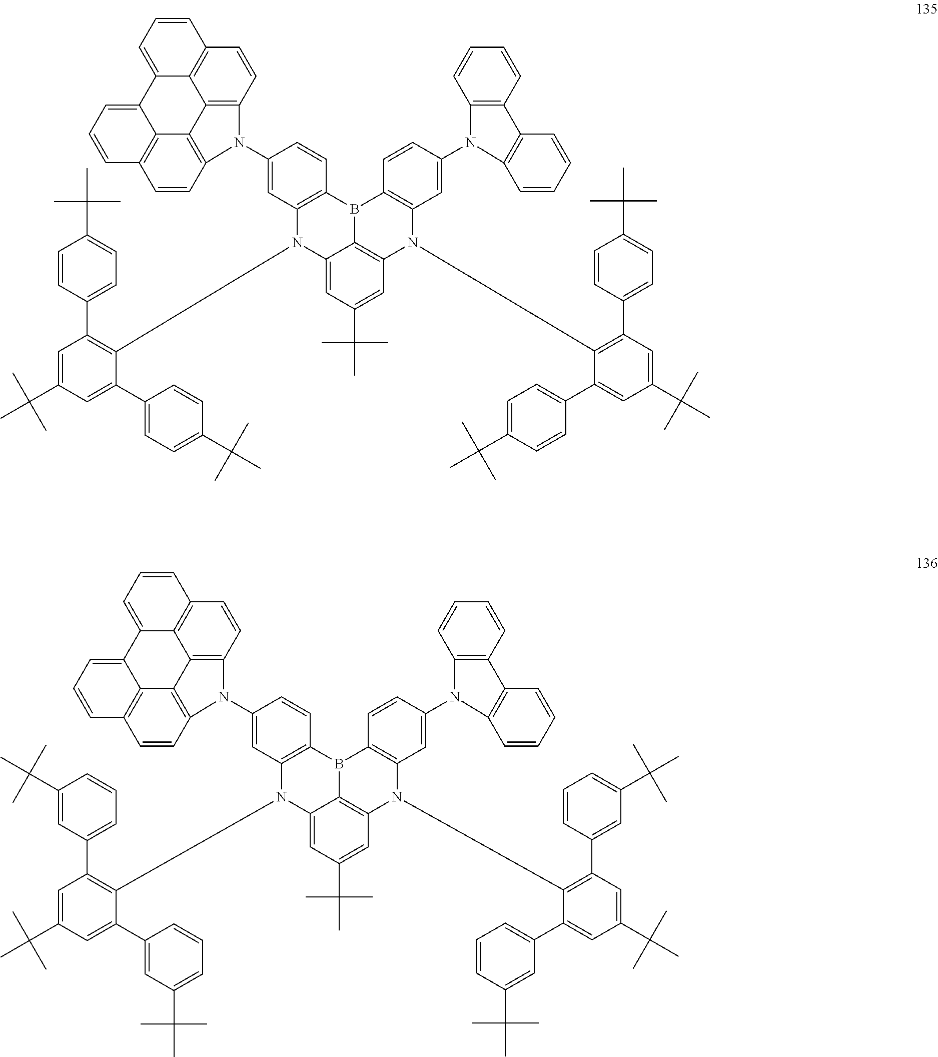

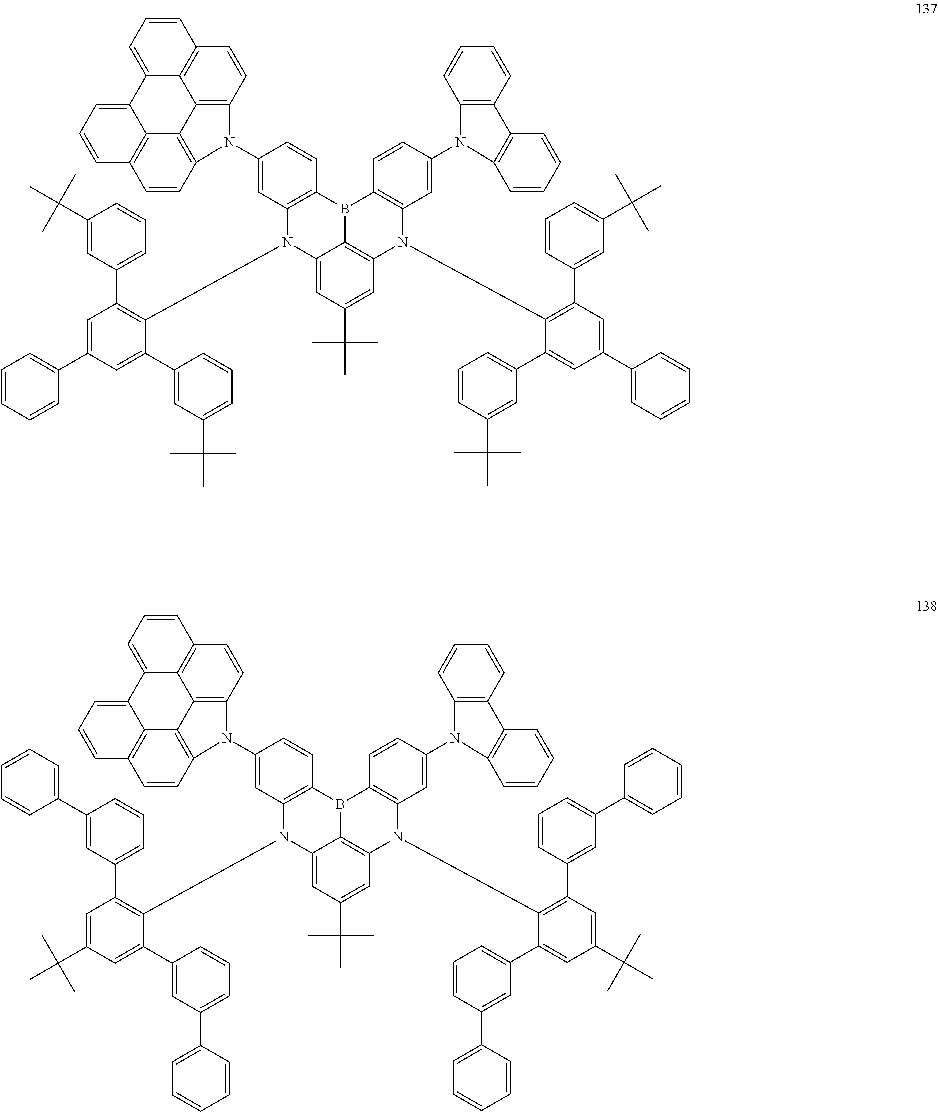 [SMILES: CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2cccc(-c3ccccc3)c2)c(N2c3cc(-n4c5ccccc5c5ccccc54)ccc3B3c4ccc(-n5c6ccc7cccc8c9cccc%10ccc5c(c%109)c6c78)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

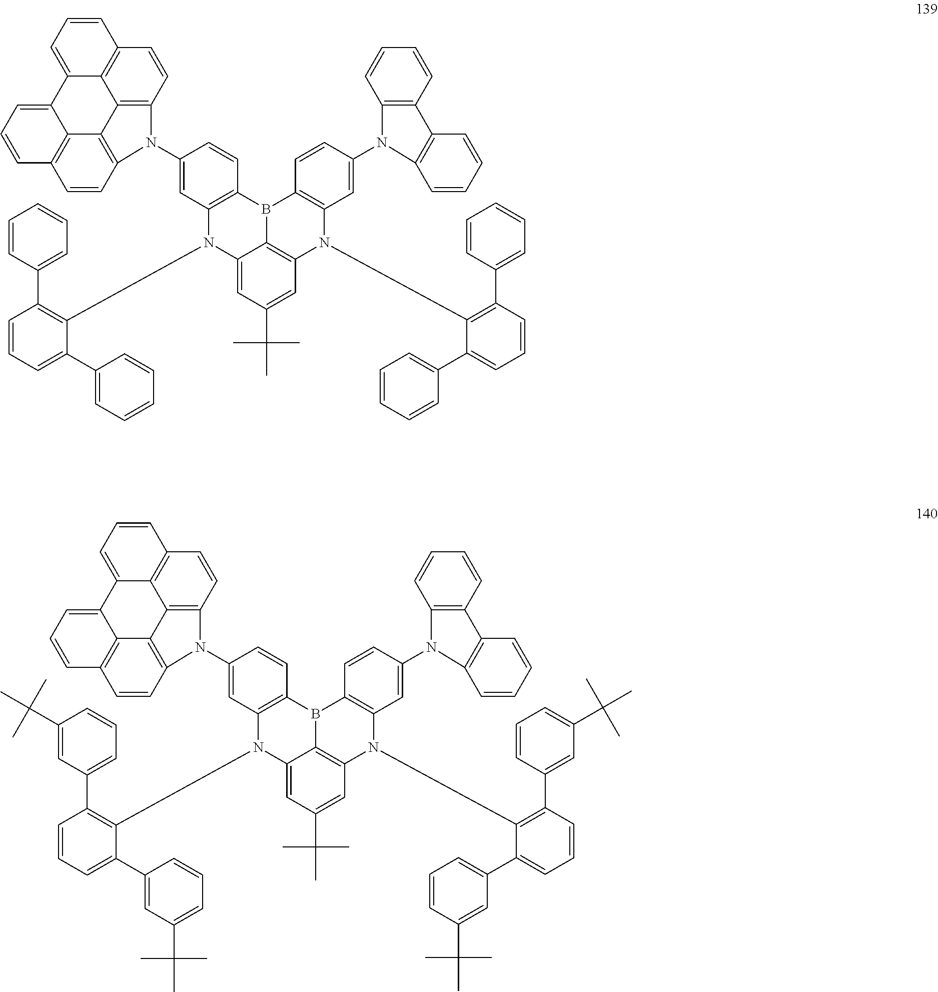 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cccc1-c1ccccc1 ; CC(C)(C)c1cccc(-c2cccc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(C(C)(C)C)cc2c43)c1]

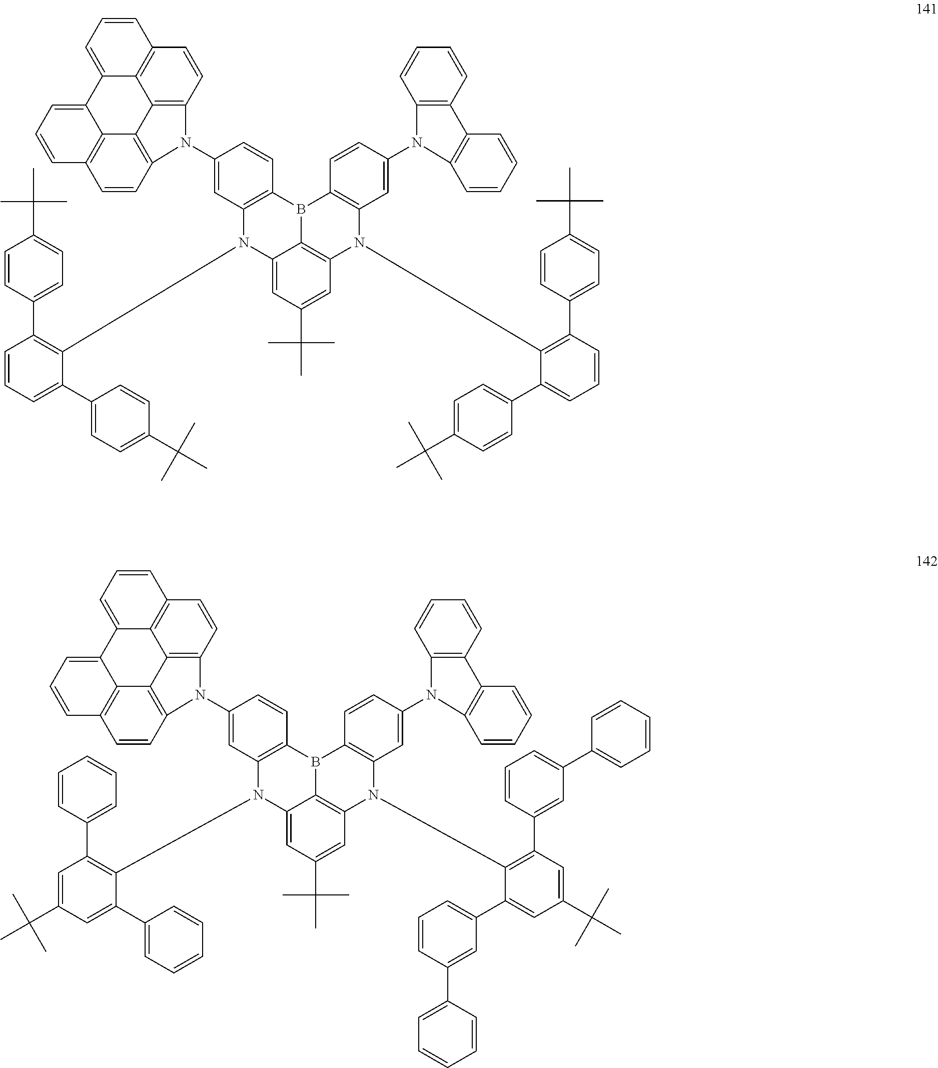

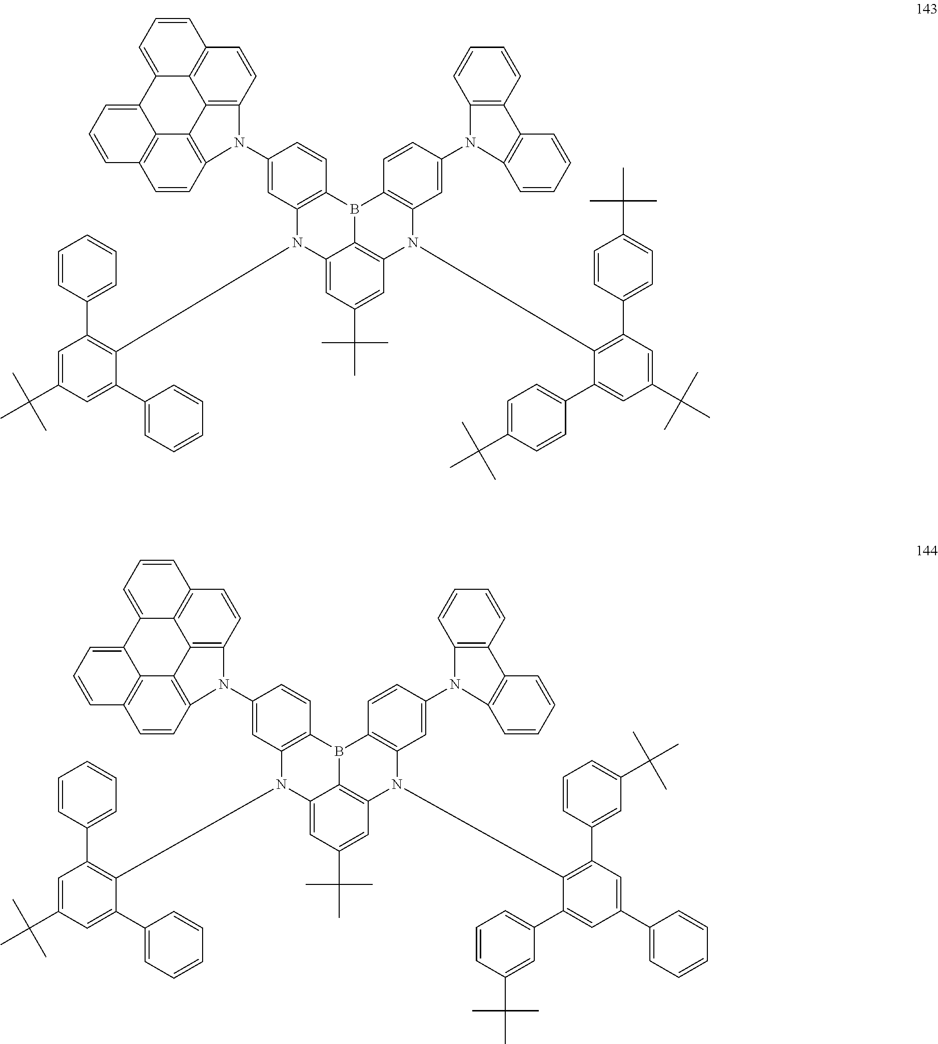

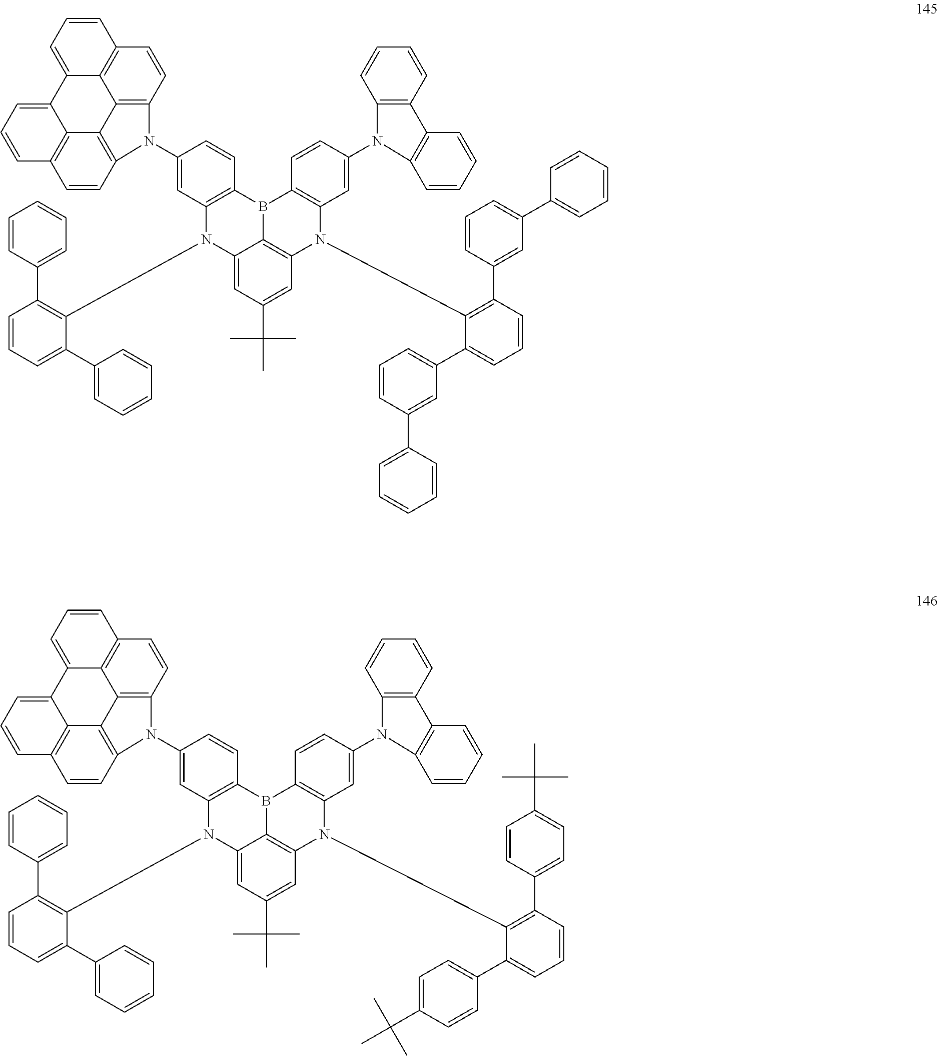 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2cccc(-c3ccccc3)c2)cccc1-c1cccc(-c2ccccc2)c1 ; CC(C)(C)c1ccc(-c2cccc(-c3ccc(C(C)(C)C)cc3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)cc1]

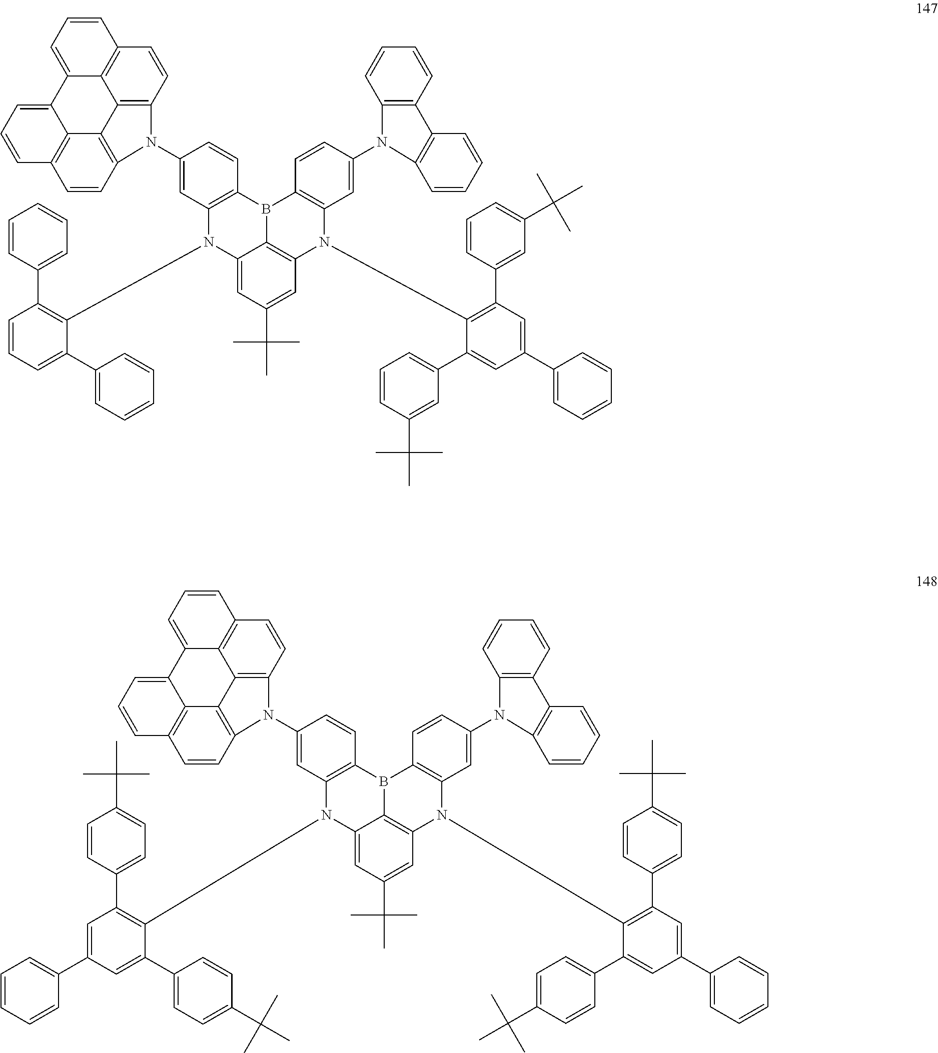 [SMILES: CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)c1 ; CC(C)(C)c1ccc(-c2cc(-c3ccccc3)cc(-c3ccc(C(C)(C)C)cc3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

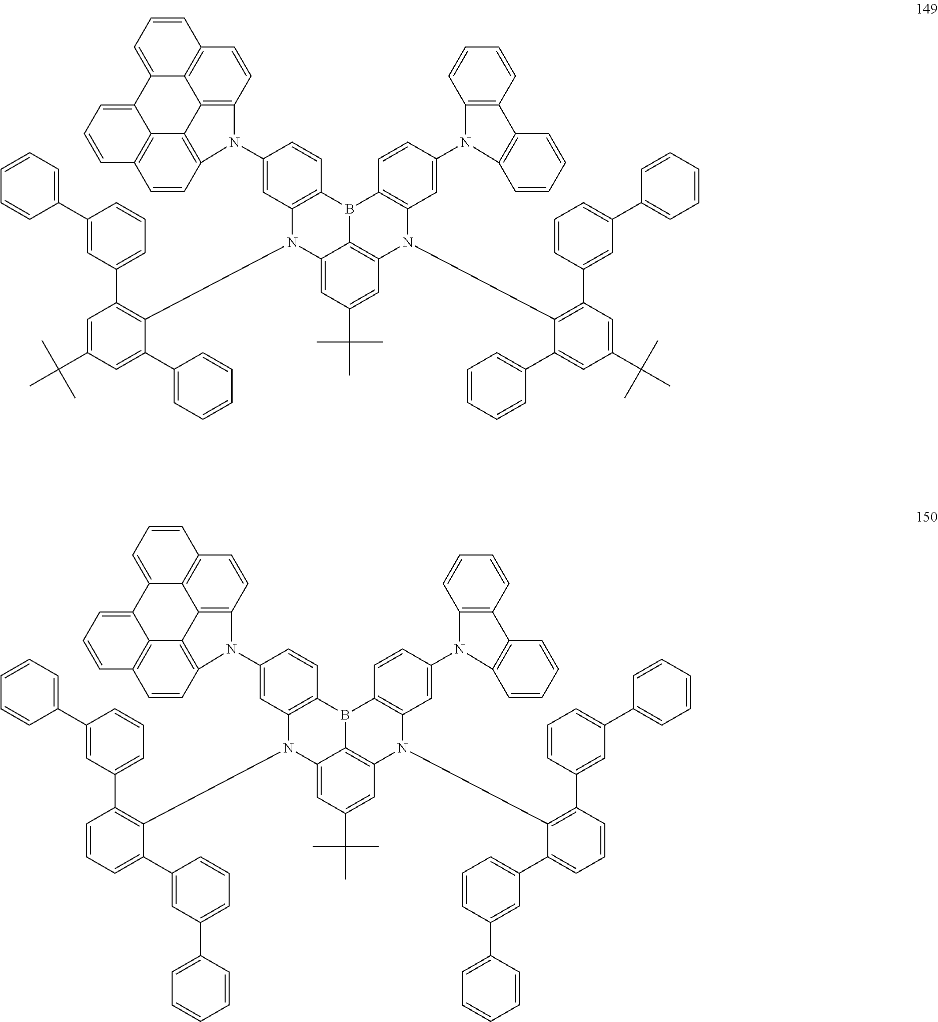 [SMILES: CC(C)(C)c1cc(-c2ccccc2)c(N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-n3c4ccccc4c4ccccc43)cc1N2c1c(-c2cccc(-c3ccccc3)c2)cccc1-c1cccc(-c2ccccc2)c1]

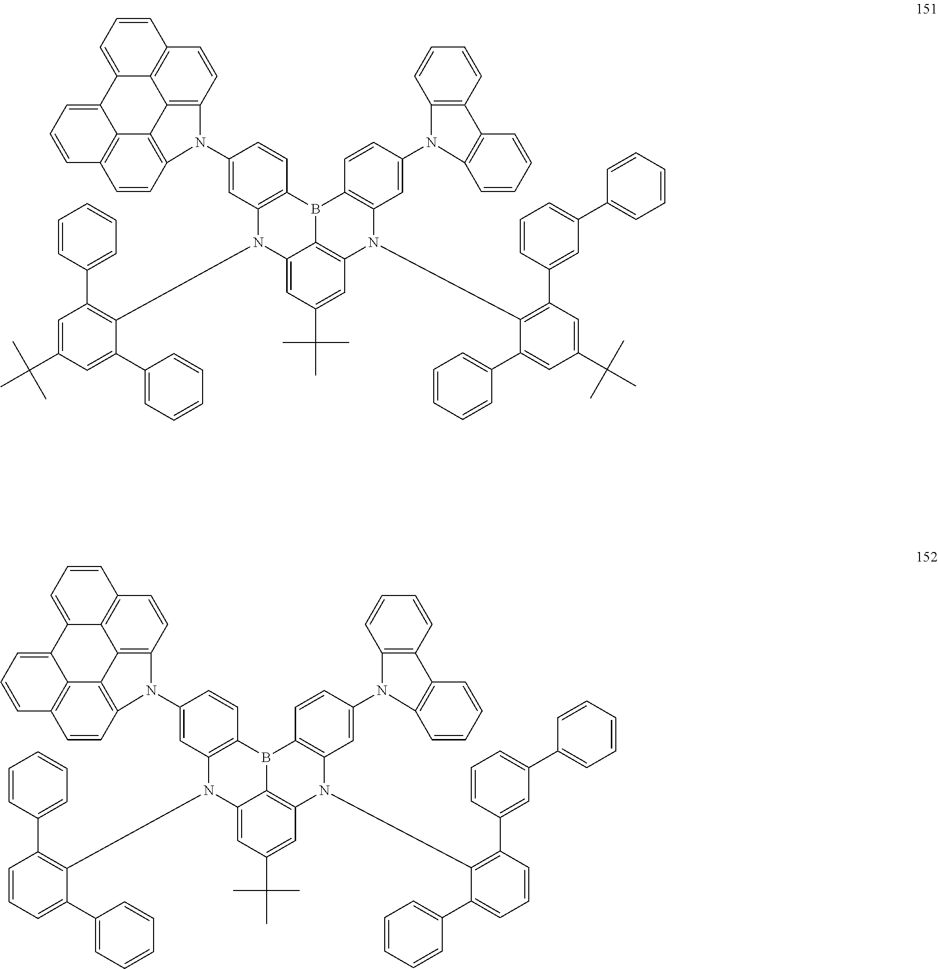 [SMILES: CC(C)(C)c1cc(-c2ccccc2)c(N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cccc1-c1cccc(-c2ccccc2)c1]

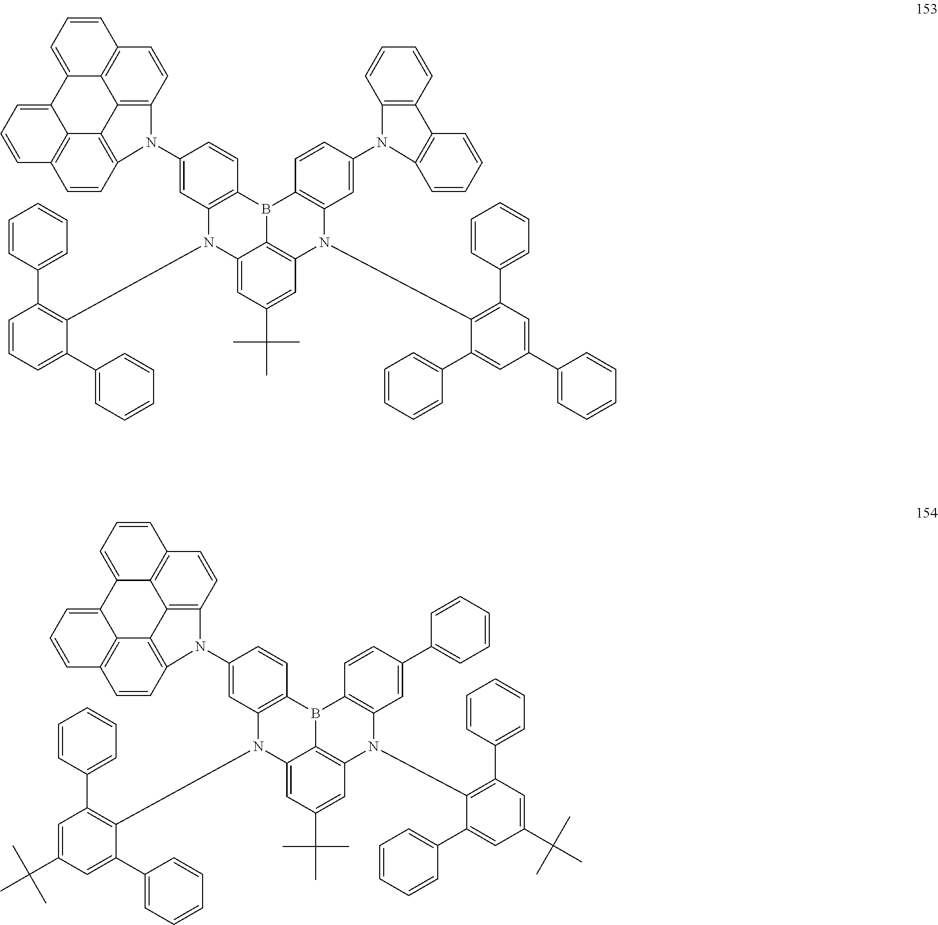 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cc(-c2ccccc2)cc1-c1ccccc1 ; CC(C)(C)c1cc(-c2ccccc2)c(N2c3cc(-c4ccccc4)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2ccccc2)c1]

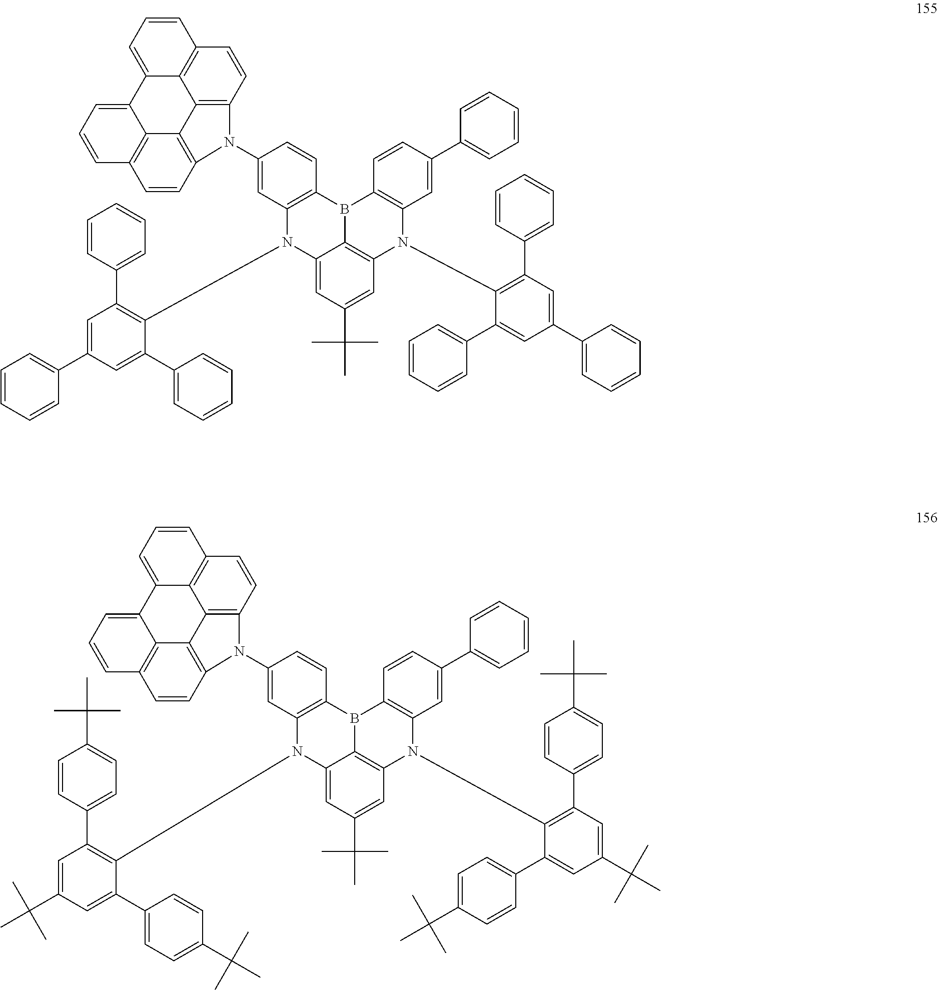 [SMILES: CC(C)(C)c1cc2c3c(c1)N(c1c(-c4ccccc4)cc(-c4ccccc4)cc1-c1ccccc1)c1cc(-n4c5ccc6cccc7c8cccc9ccc4c(c98)c5c67)ccc1B3c1ccc(-c3ccccc3)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-c4ccccc4)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

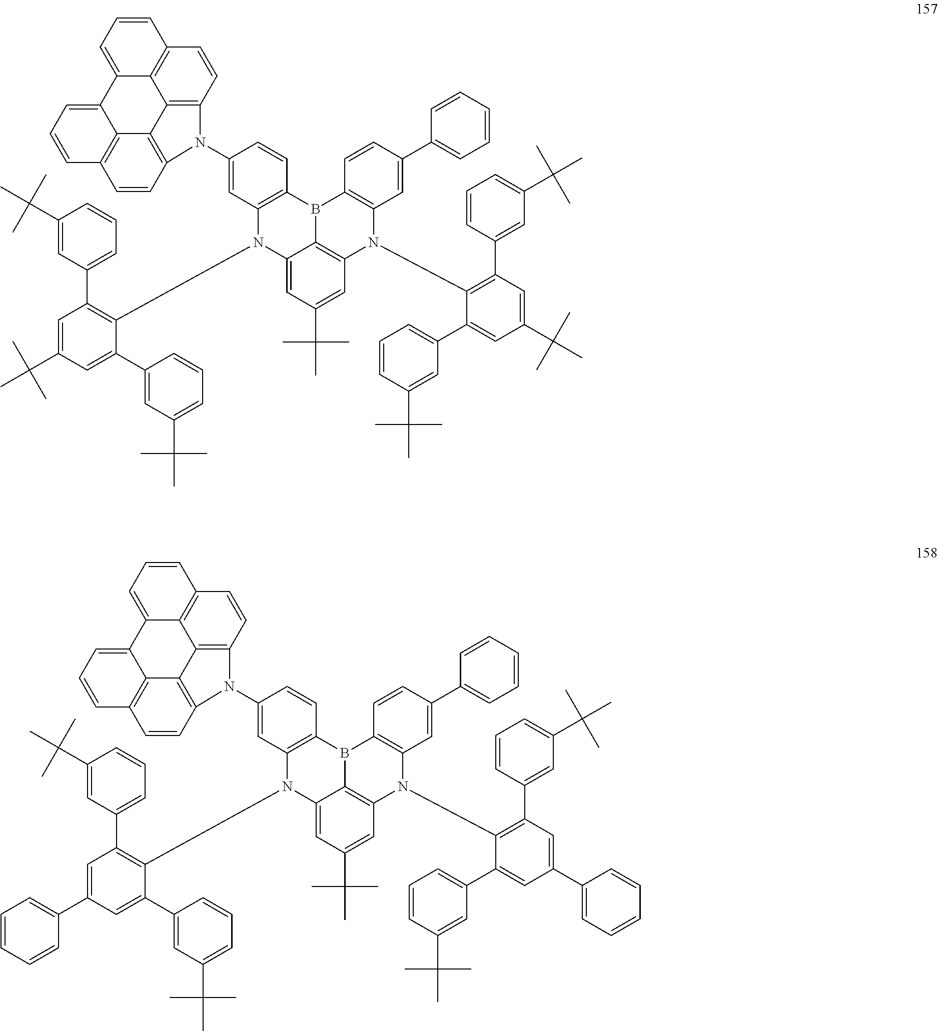 [SMILES: CC(C)(C)c1cccc(-c2cc(C(C)(C)C)cc(-c3cccc(C(C)(C)C)c3)c2N2c3cc(-c4ccccc4)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-c4ccccc4)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1]

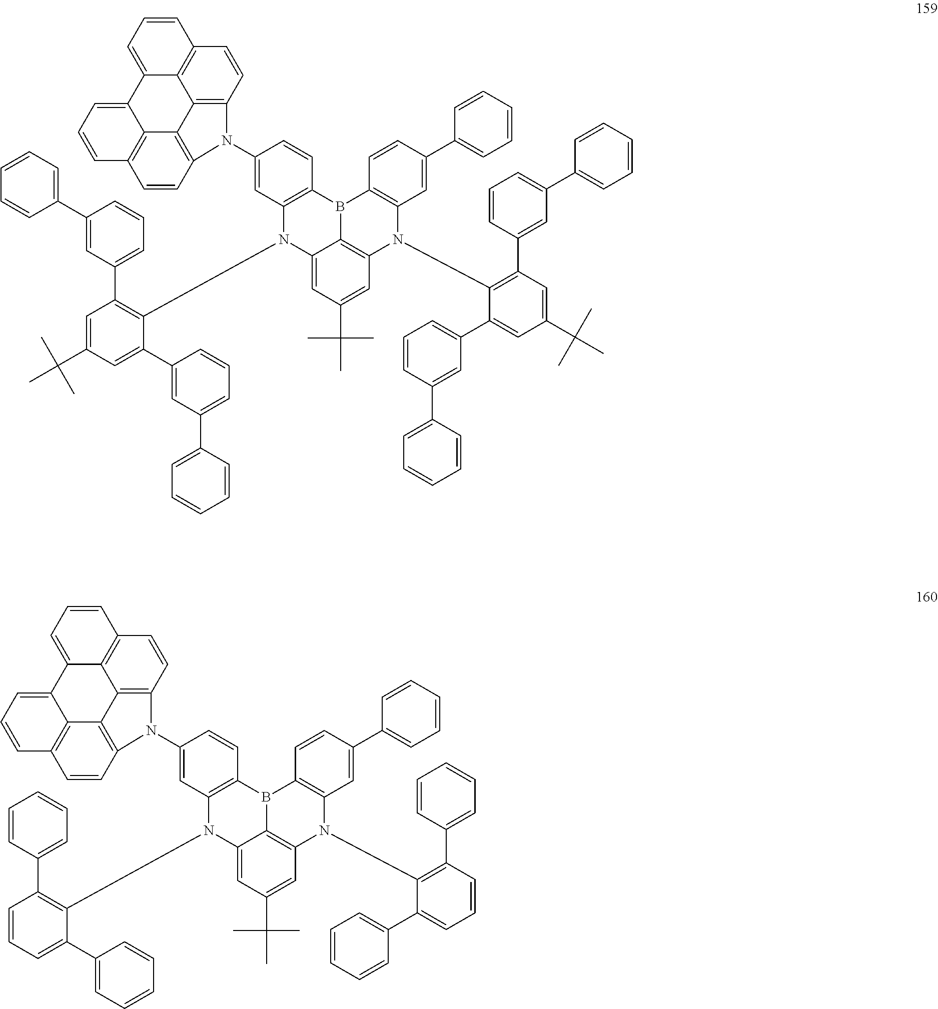 [SMILES: CC(C)(C)c1cc(-c2cccc(-c3ccccc3)c2)c(N2c3cc(-c4ccccc4)ccc3B3c4ccc(-n5c6ccc7cccc8c9cccc%10ccc5c(c%109)c6c78)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-c3ccccc3)cc1N2c1c(-c2ccccc2)cccc1-c1ccccc1]

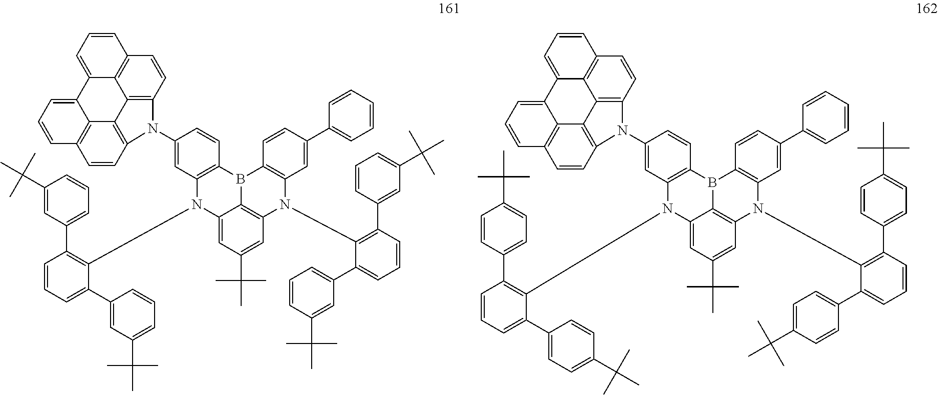 [SMILES: CC(C)(C)c1cccc(-c2cccc(-c3cccc(C(C)(C)C)c3)c2N2c3cc(-c4ccccc4)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(C(C)(C)C)cc2c43)c1 ; CC(C)(C)c1ccc(-c2cccc(-c3ccc(C(C)(C)C)cc3)c2N2c3cc(-c4ccccc4)ccc3B3c4ccc(-n5c6ccc7cccc8c9cccc%10ccc5c(c%109)c6c78)cc4N(c4c(-c5ccc(C(C)(C)C)cc5)cccc4-c4ccc(C(C)(C)C)cc4)c4cc(C(C)(C)C)cc2c43)cc1]

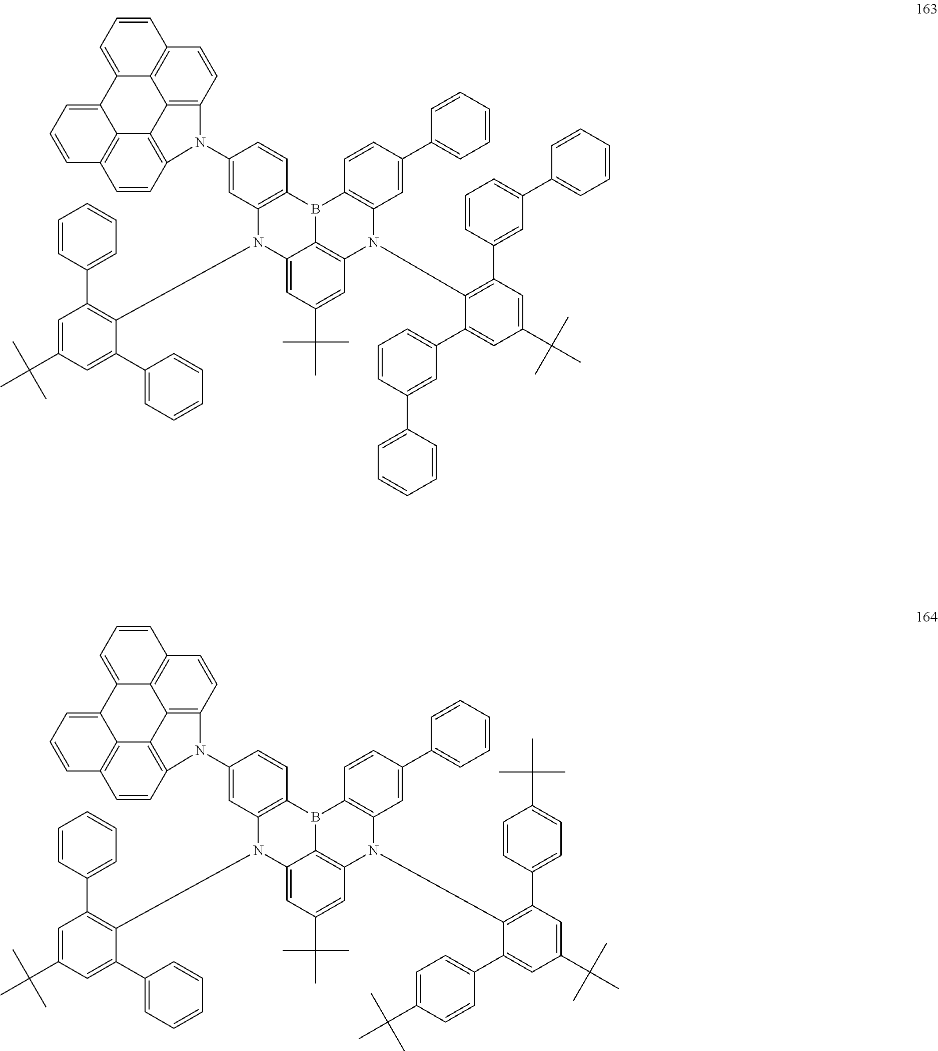 [SMILES: CC(C)(C)c1cc(-c2cccc(-c3ccccc3)c2)c(N2c3cc(-c4ccccc4)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1ccc(-c2cc(C(C)(C)C)cc(-c3ccc(C(C)(C)C)cc3)c2N2c3cc(-c4ccccc4)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)cc1]

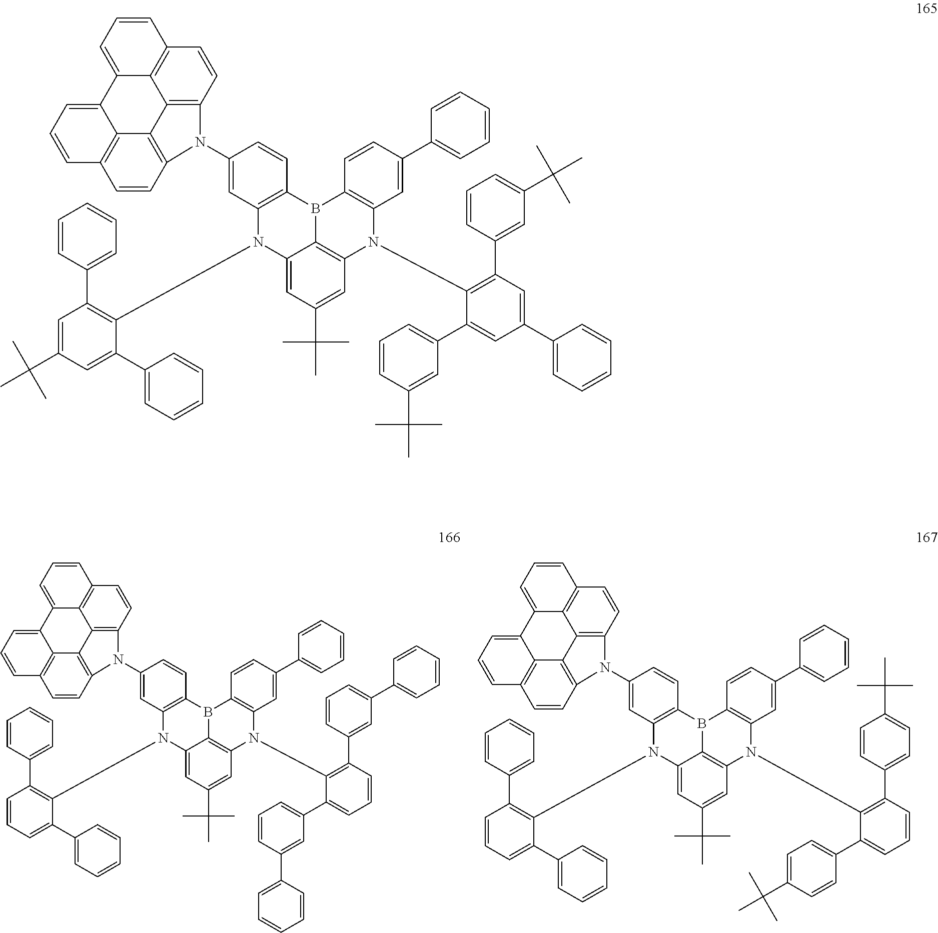

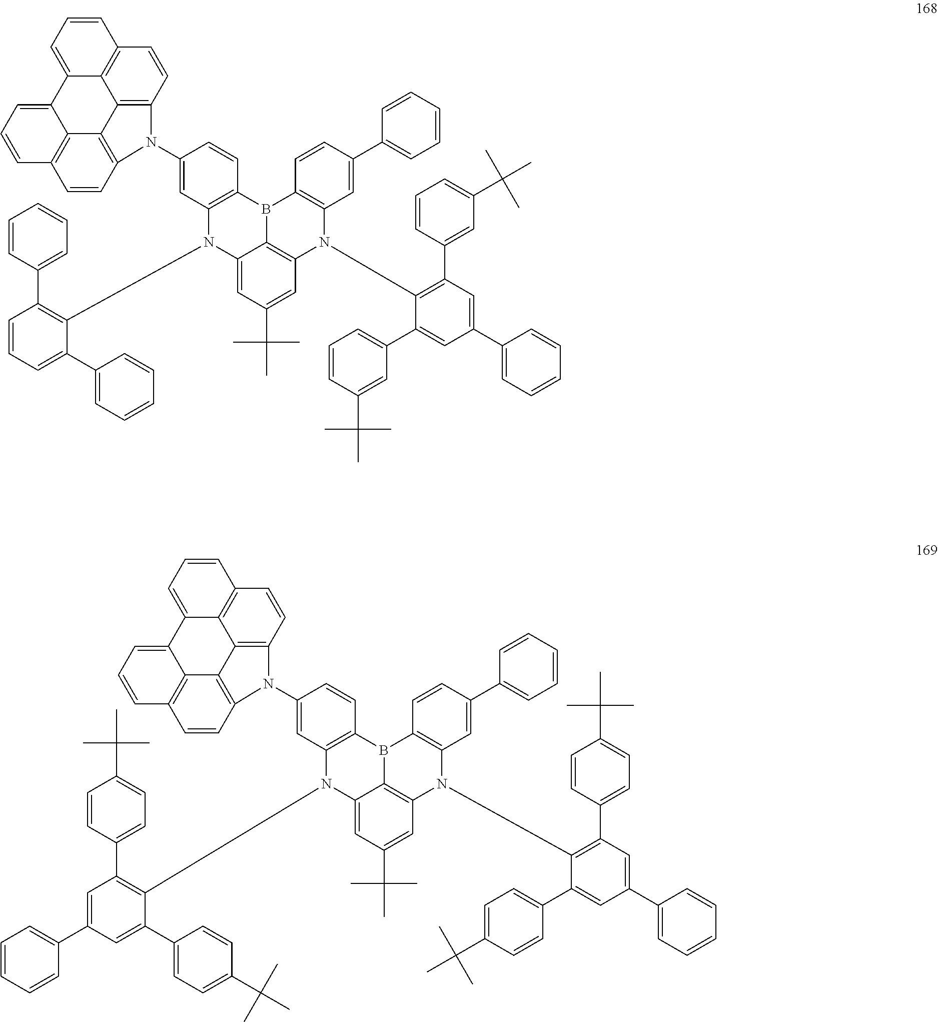 [SMILES: CC(C)(C)c1cccc(-c2cc(-c3ccccc3)cc(-c3cccc(C(C)(C)C)c3)c2N2c3cc(-c4ccccc4)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)c1 ; CC(C)(C)c1ccc(-c2cc(-c3ccccc3)cc(-c3ccc(C(C)(C)C)cc3)c2N2c3cc(-c4ccccc4)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

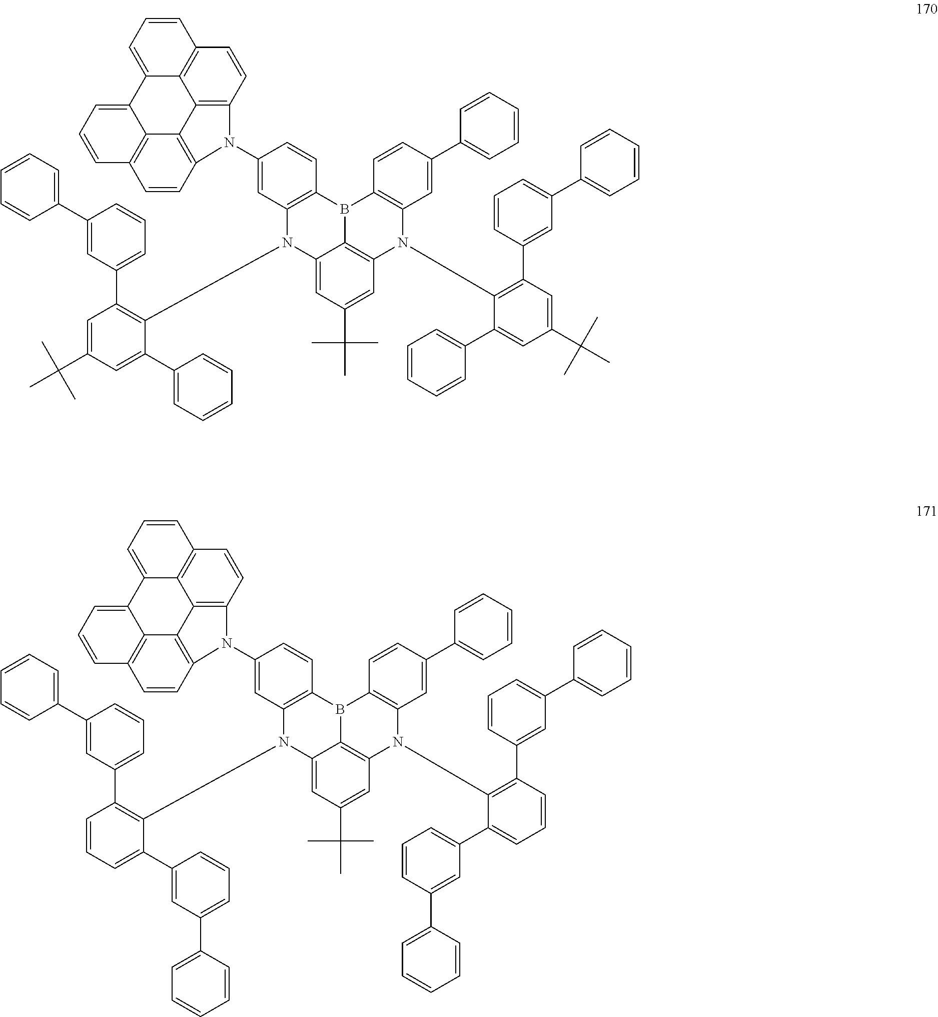 [SMILES: CC(C)(C)c1cc(-c2ccccc2)c(N2c3cc(-c4ccccc4)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-c3ccccc3)cc1N2c1c(-c2cccc(-c3ccccc3)c2)cccc1-c1cccc(-c2ccccc2)c1]

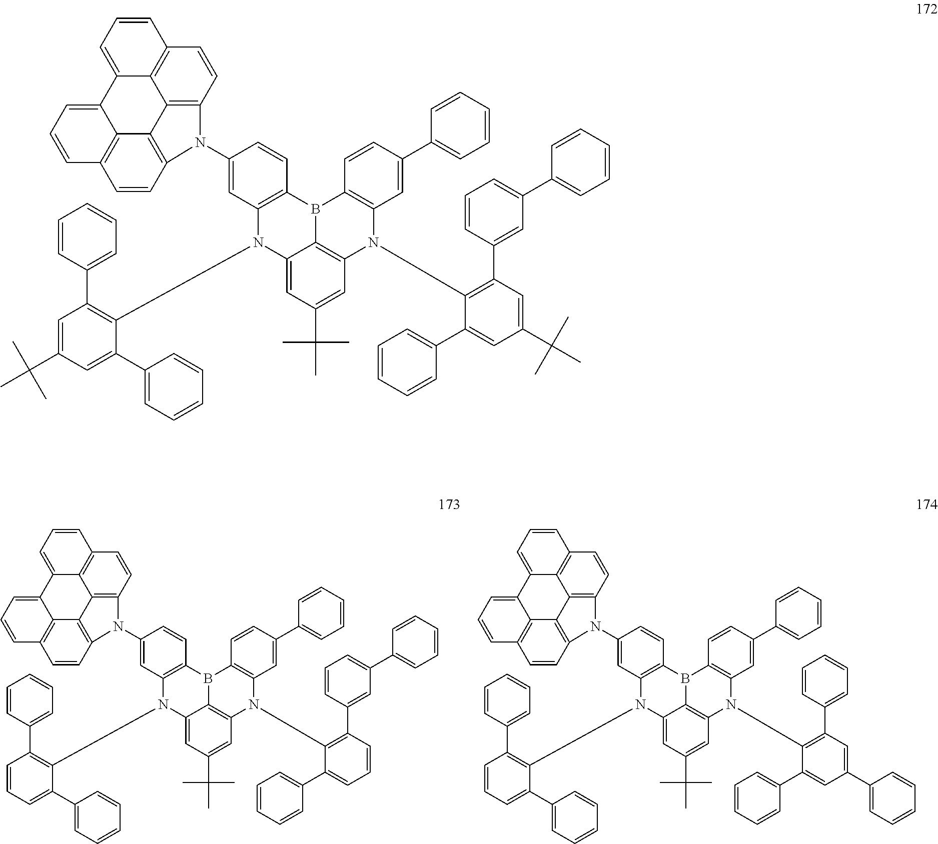

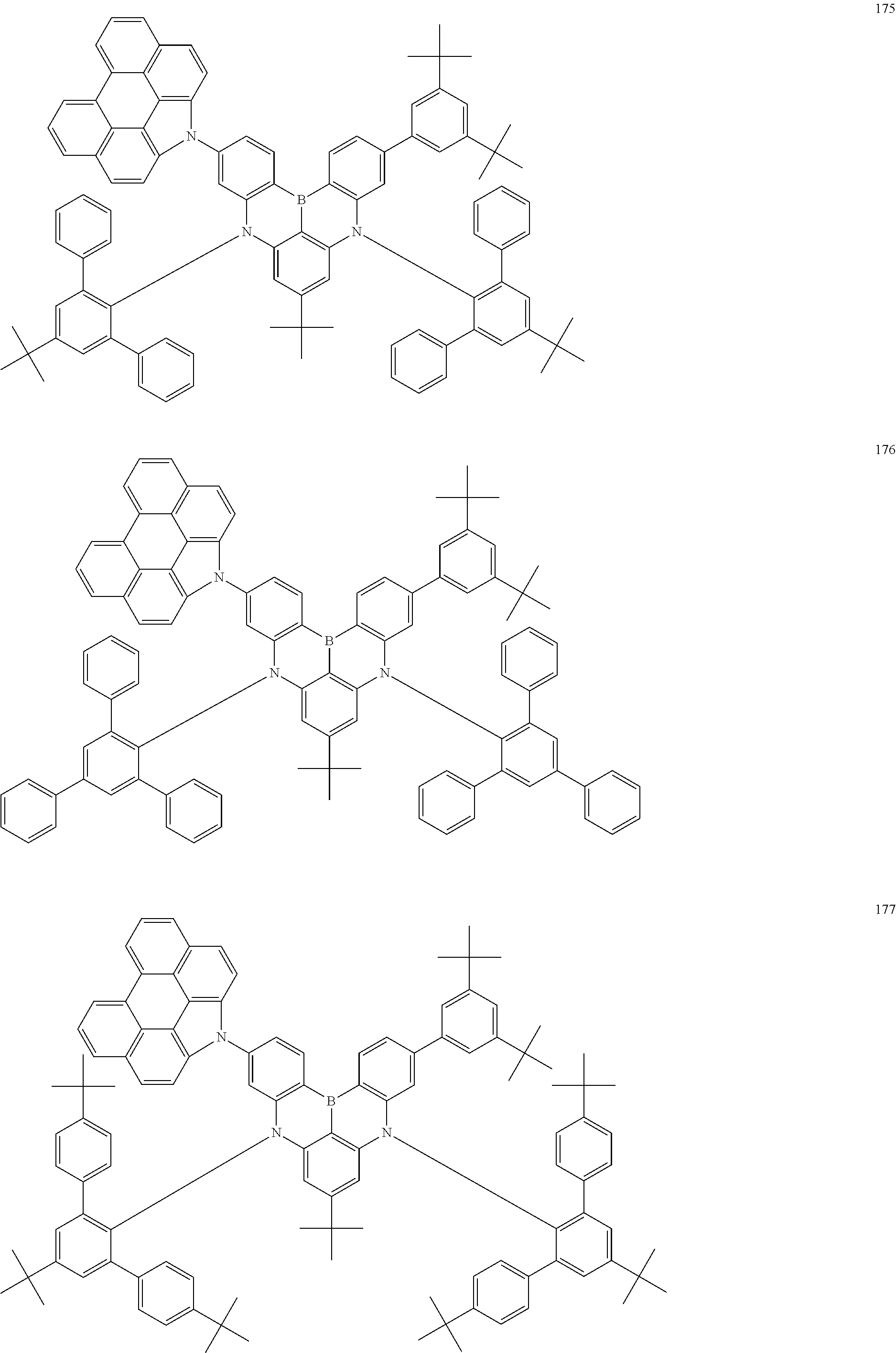

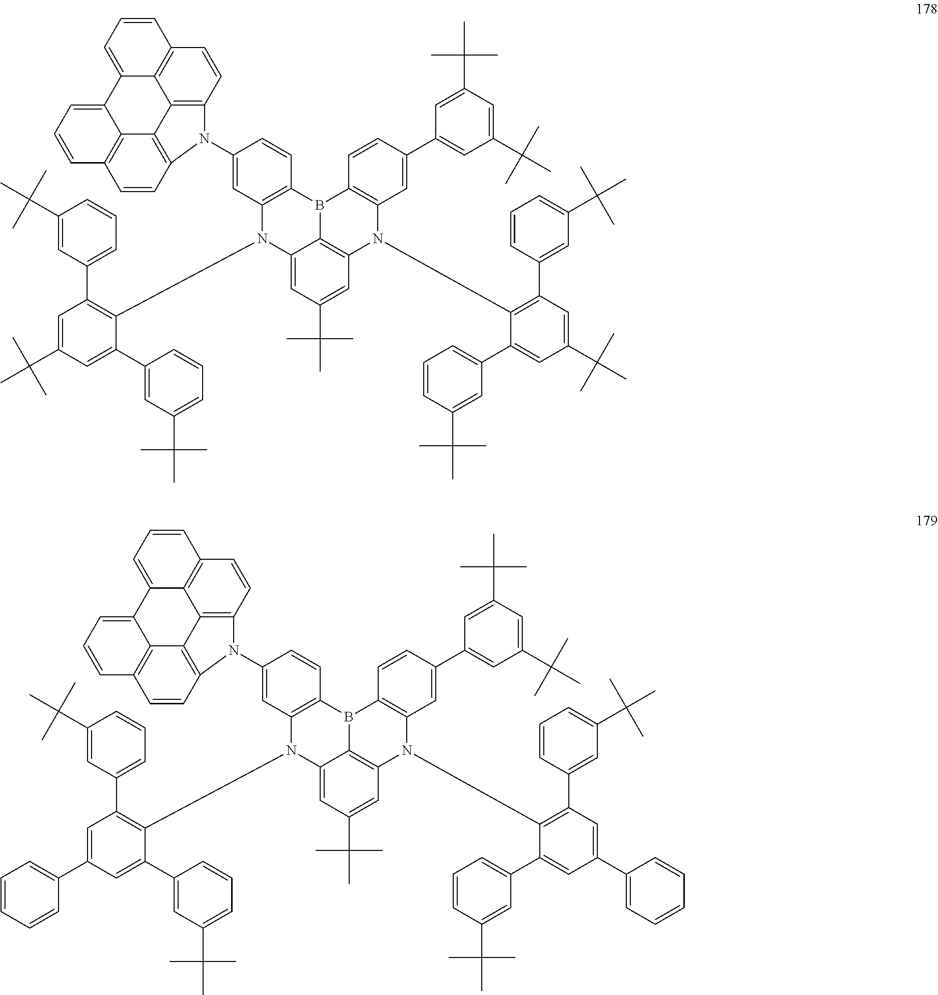 [SMILES: CC(C)(C)c1cccc(-c2cc(C(C)(C)C)cc(-c3cccc(C(C)(C)C)c3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1]

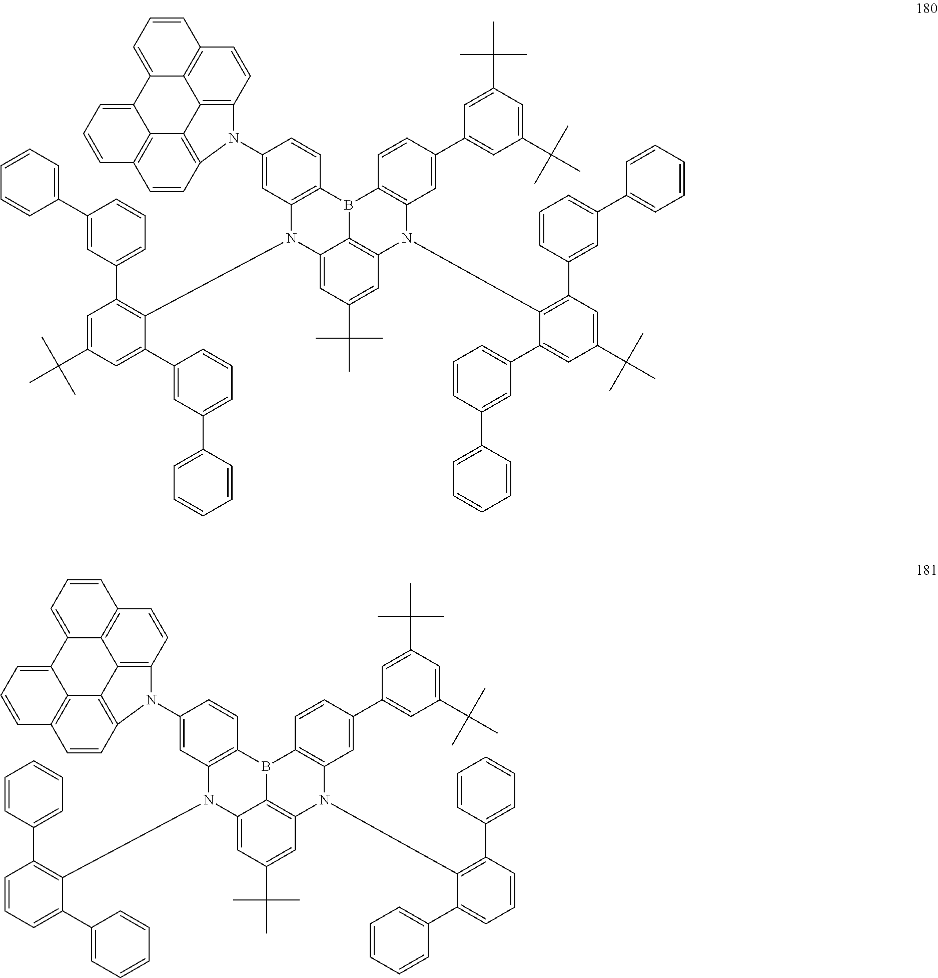 [SMILES: CC(C)(C)c1cc(-c2ccc3c(c2)N(c2c(-c4cccc(-c5ccccc5)c4)cc(C(C)(C)C)cc2-c2cccc(-c4ccccc4)c2)c2cc(C(C)(C)C)cc4c2B3c2ccc(-n3c5ccc6cccc7c8cccc9ccc3c(c98)c5c67)cc2N4c2c(-c3cccc(-c4ccccc4)c3)cc(C(C)(C)C)cc2-c2cccc(-c3ccccc3)c2)cc(C(C)(C)C)c1 ; CC(C)(C)c1cc(-c2ccc3c(c2)N(c2c(-c4ccccc4)cccc2-c2ccccc2)c2cc(C(C)(C)C)cc4c2B3c2ccc(-n3c5ccc6cccc7c8cccc9ccc3c(c98)c5c67)cc2N4c2c(-c3ccccc3)cccc2-c2ccccc2)cc(C(C)(C)C)c1]

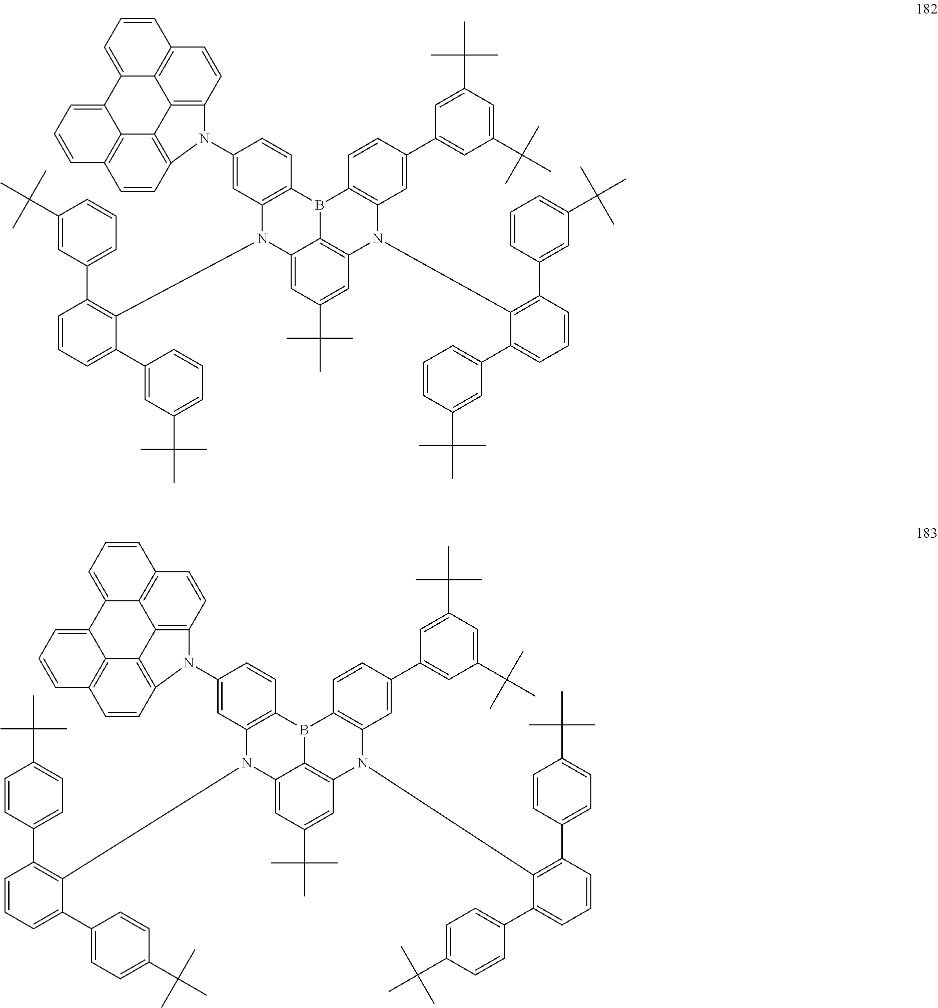

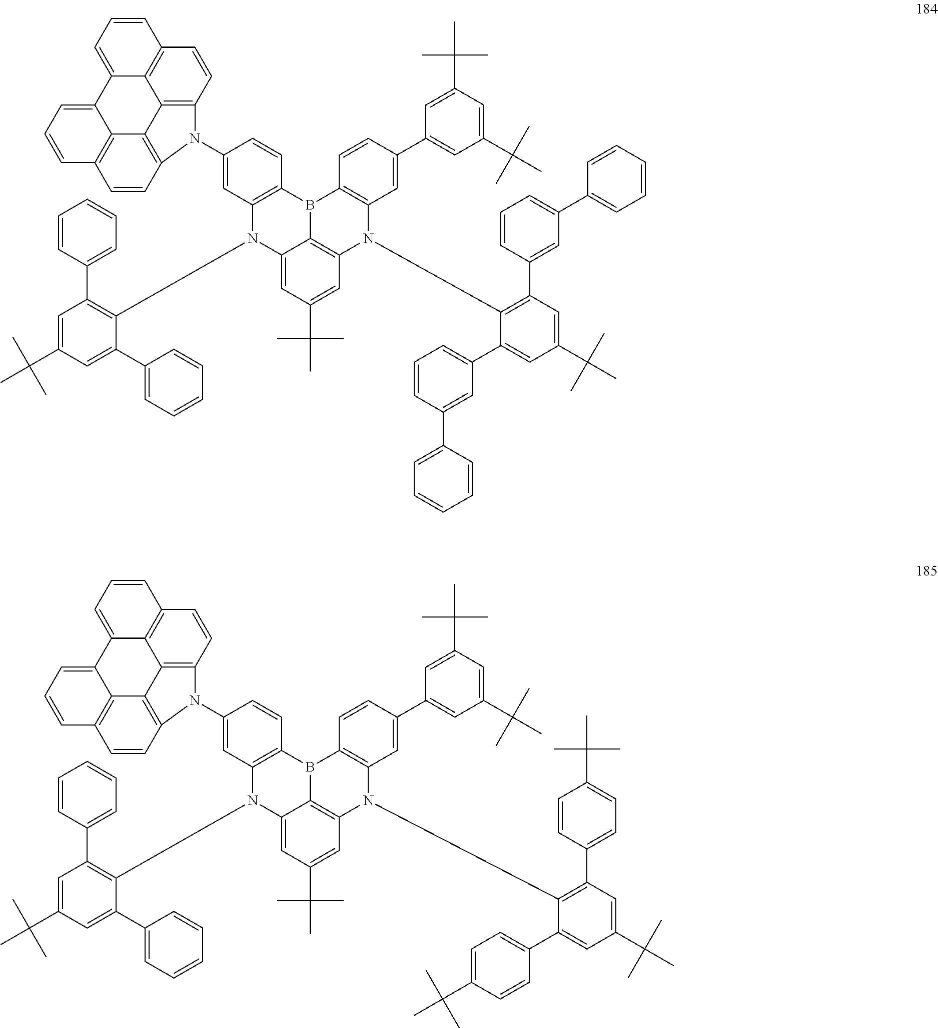 [SMILES: CC(C)(C)c1cc(-c2ccc3c(c2)N(c2c(-c4cccc(-c5ccccc5)c4)cc(C(C)(C)C)cc2-c2cccc(-c4ccccc4)c2)c2cc(C(C)(C)C)cc4c2B3c2ccc(-n3c5ccc6cccc7c8cccc9ccc3c(c98)c5c67)cc2N4c2c(-c3ccccc3)cc(C(C)(C)C)cc2-c2ccccc2)cc(C(C)(C)C)c1 ; CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)cc1]

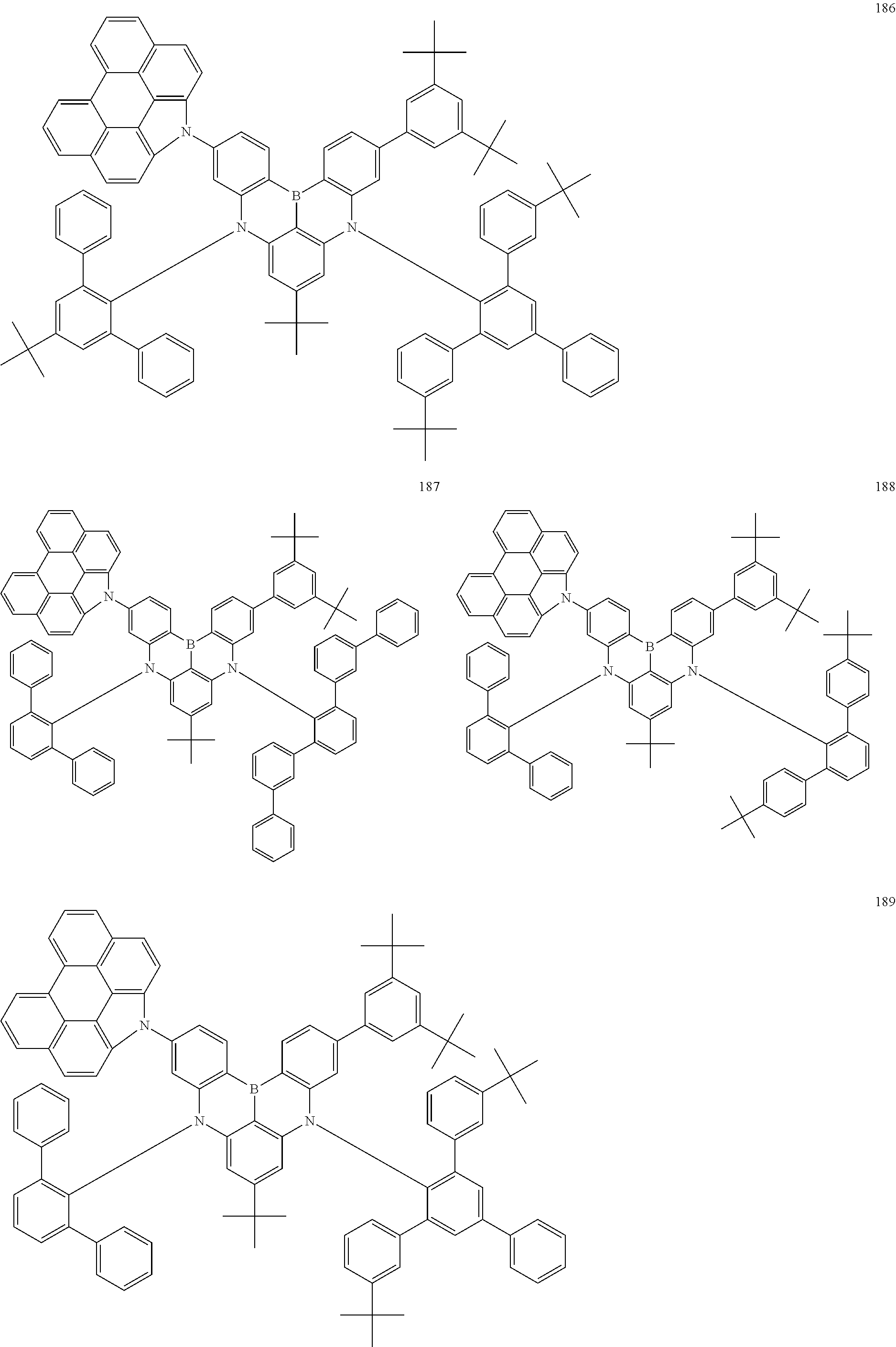

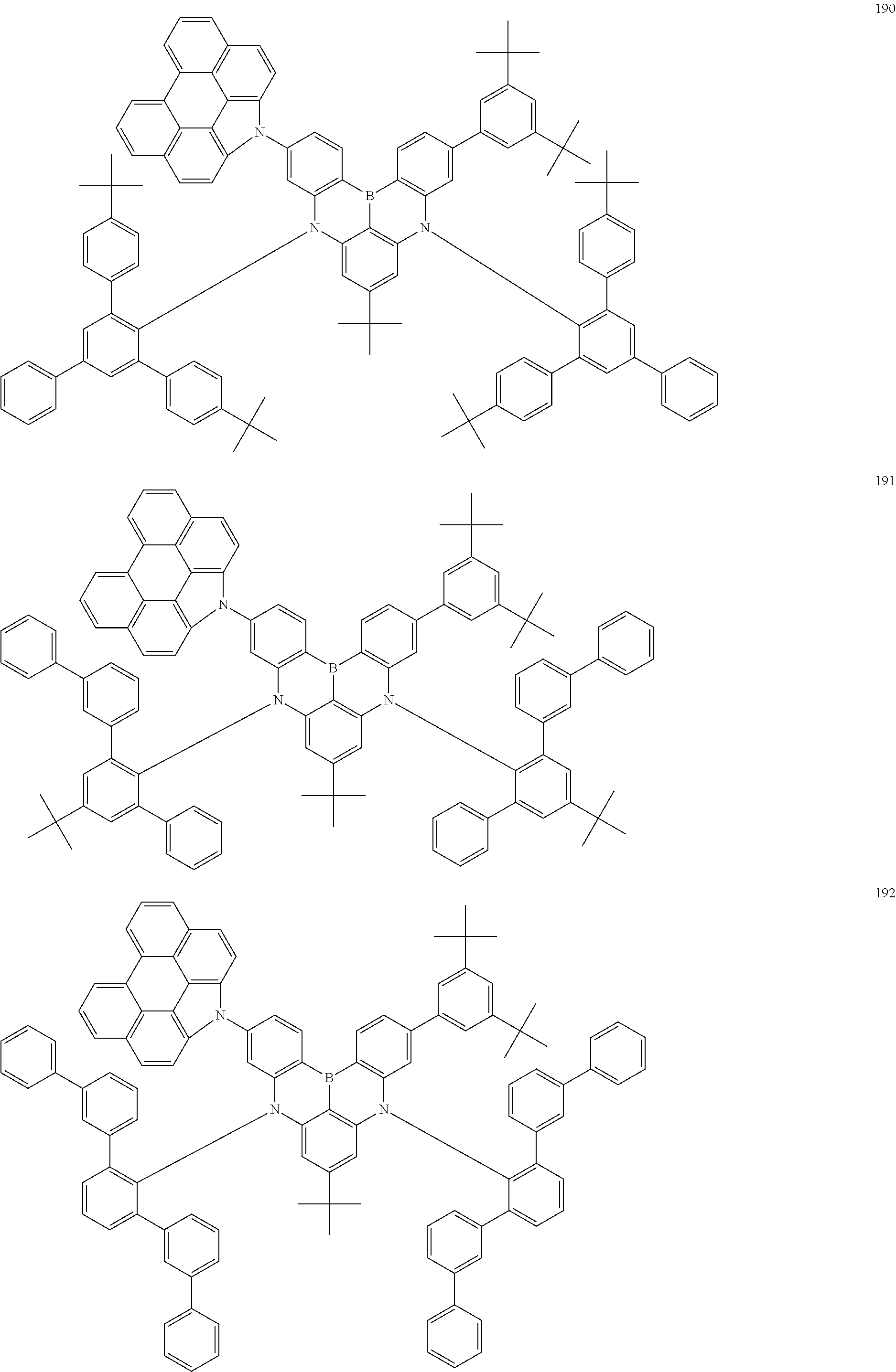

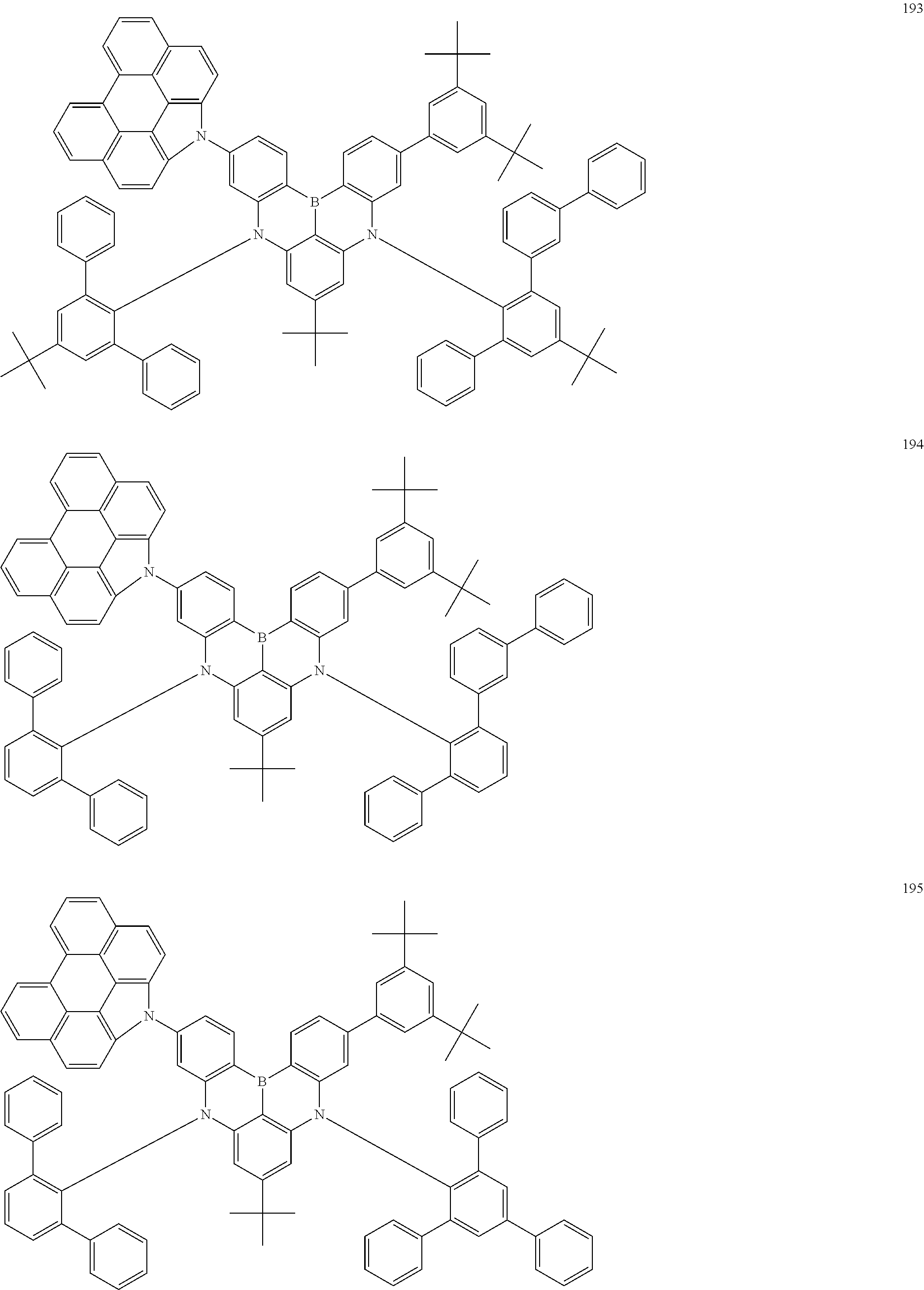

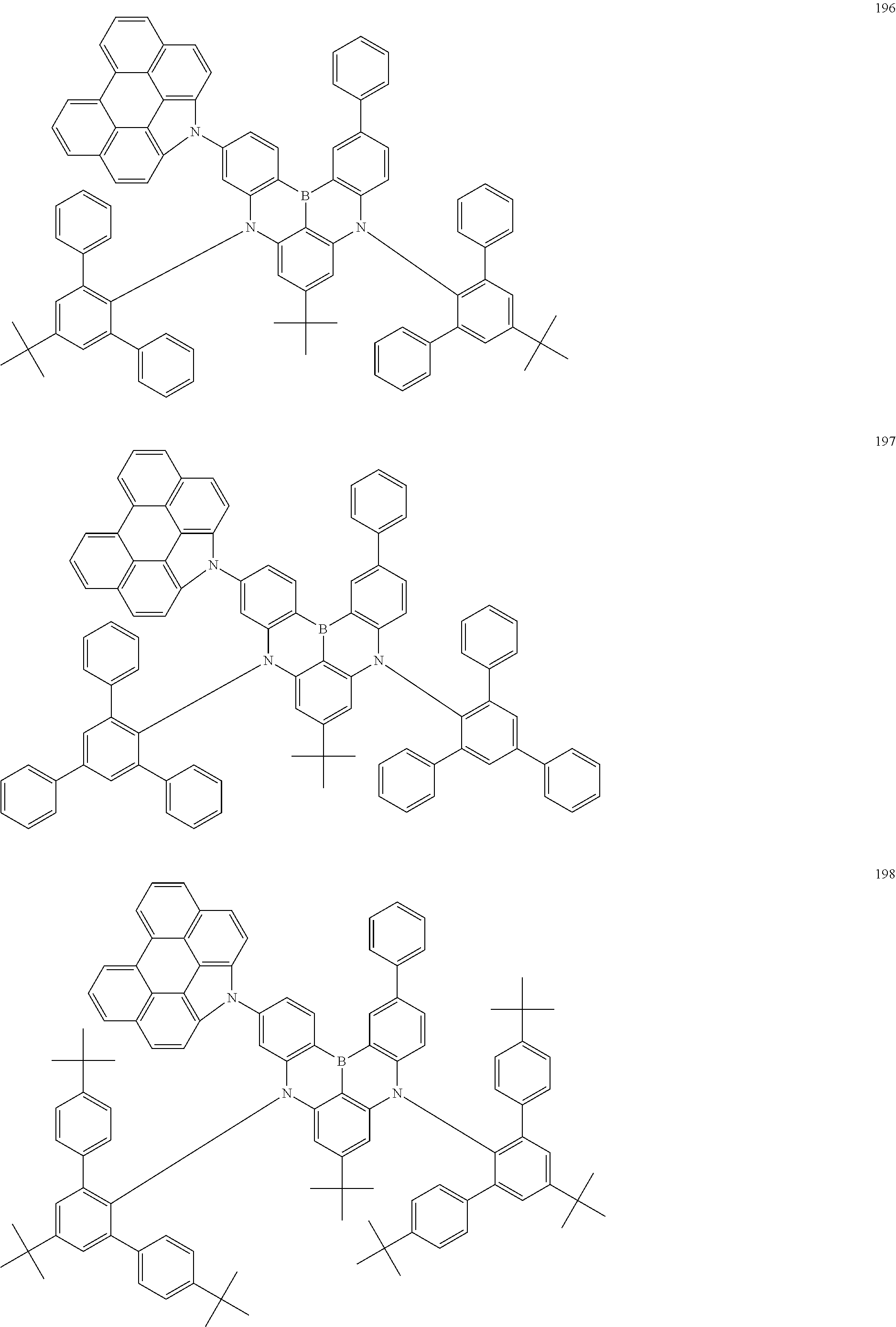

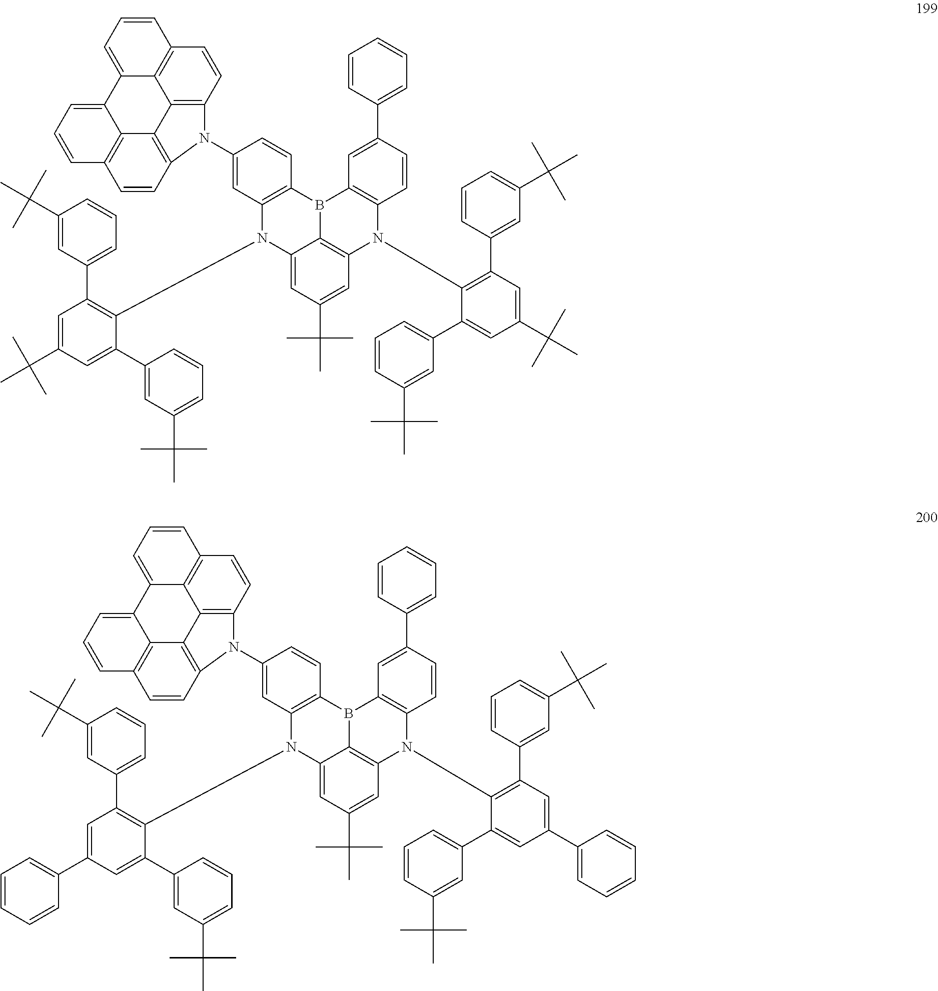

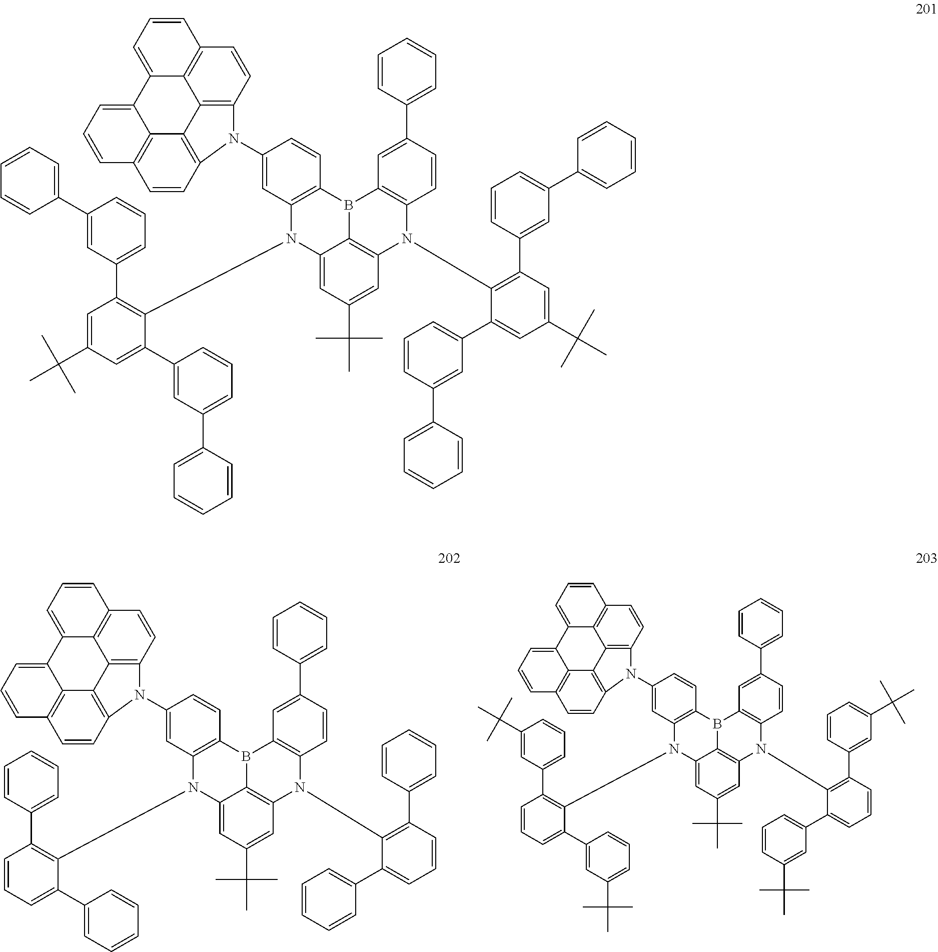

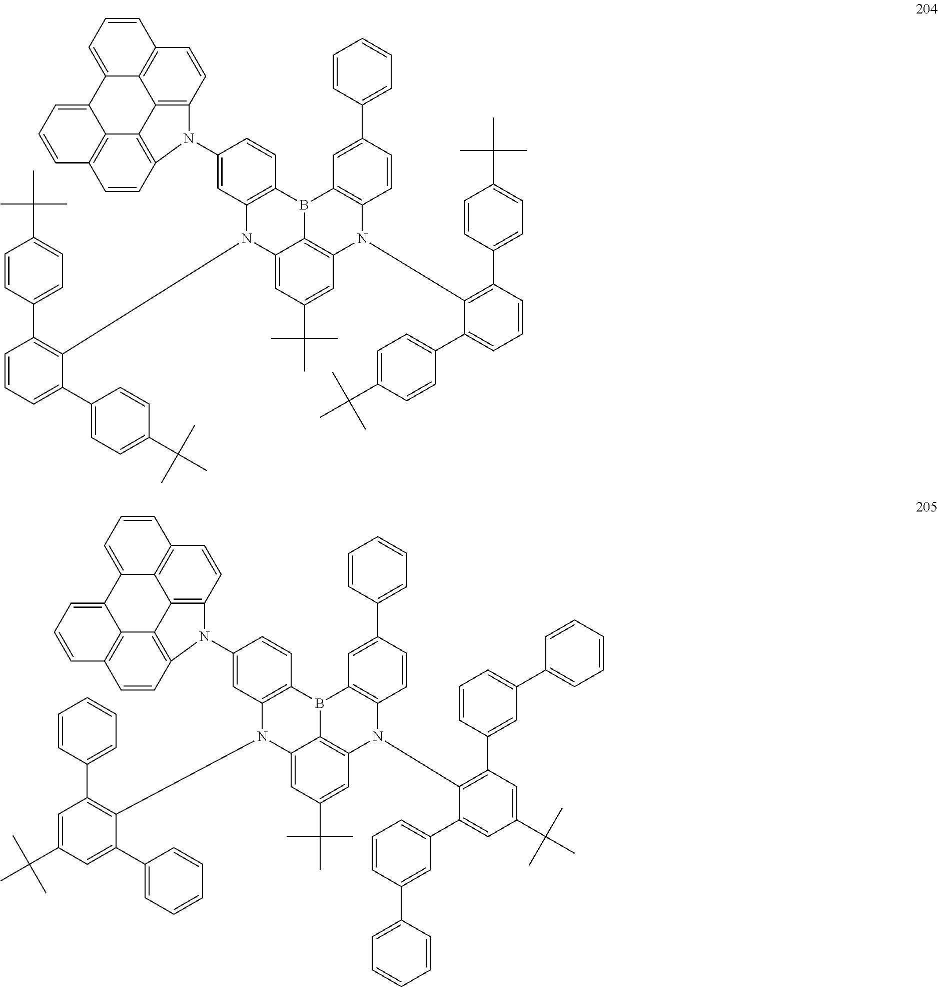

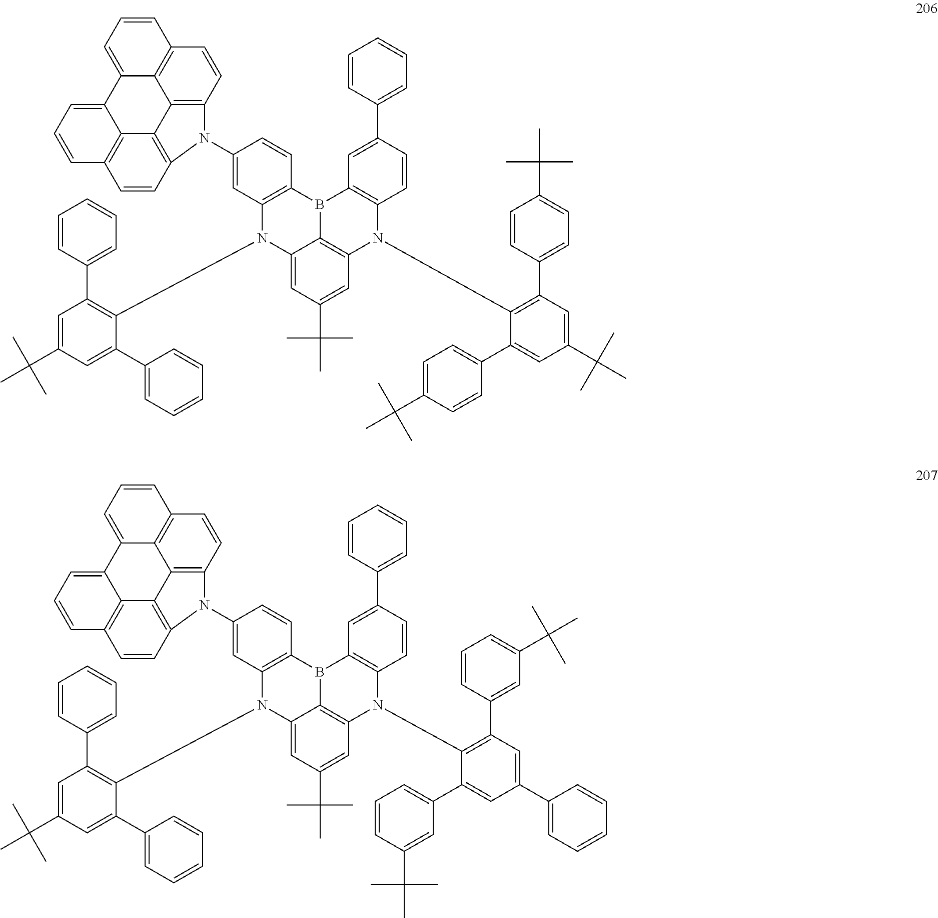

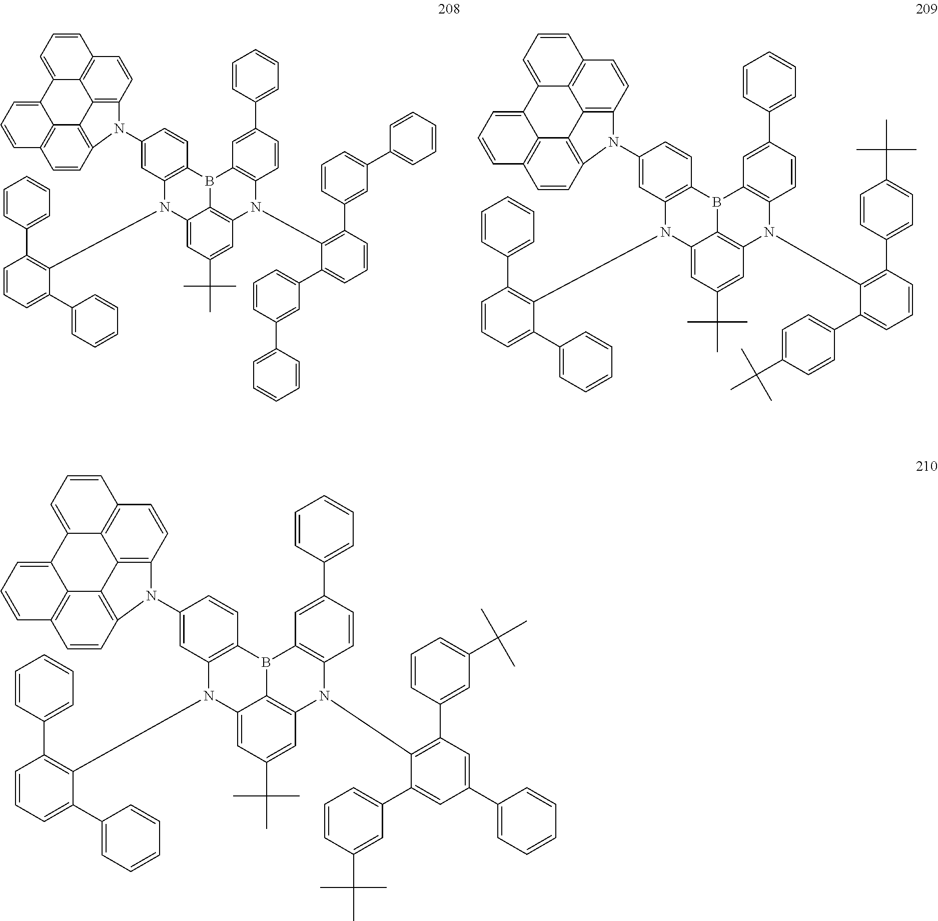

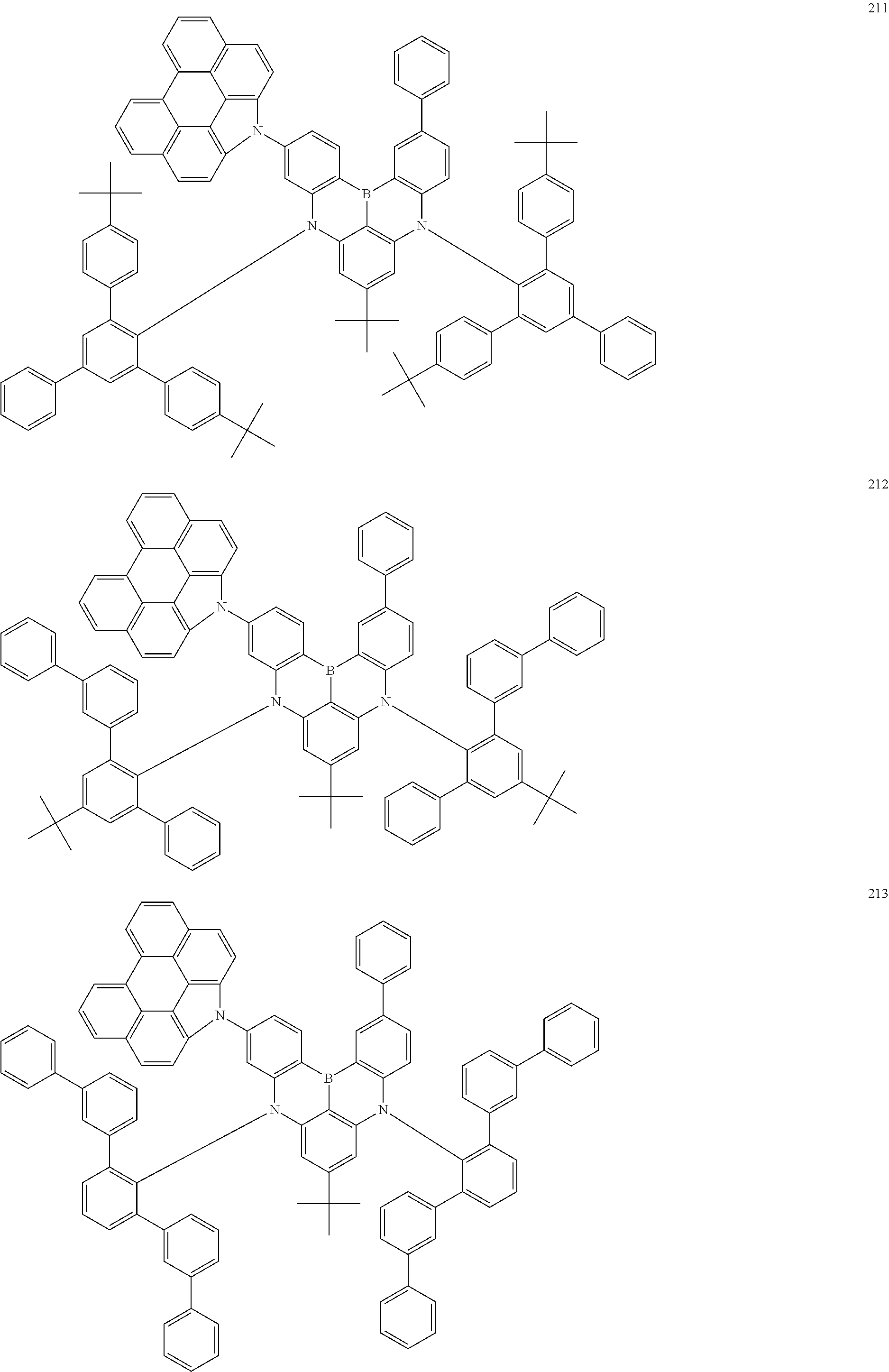

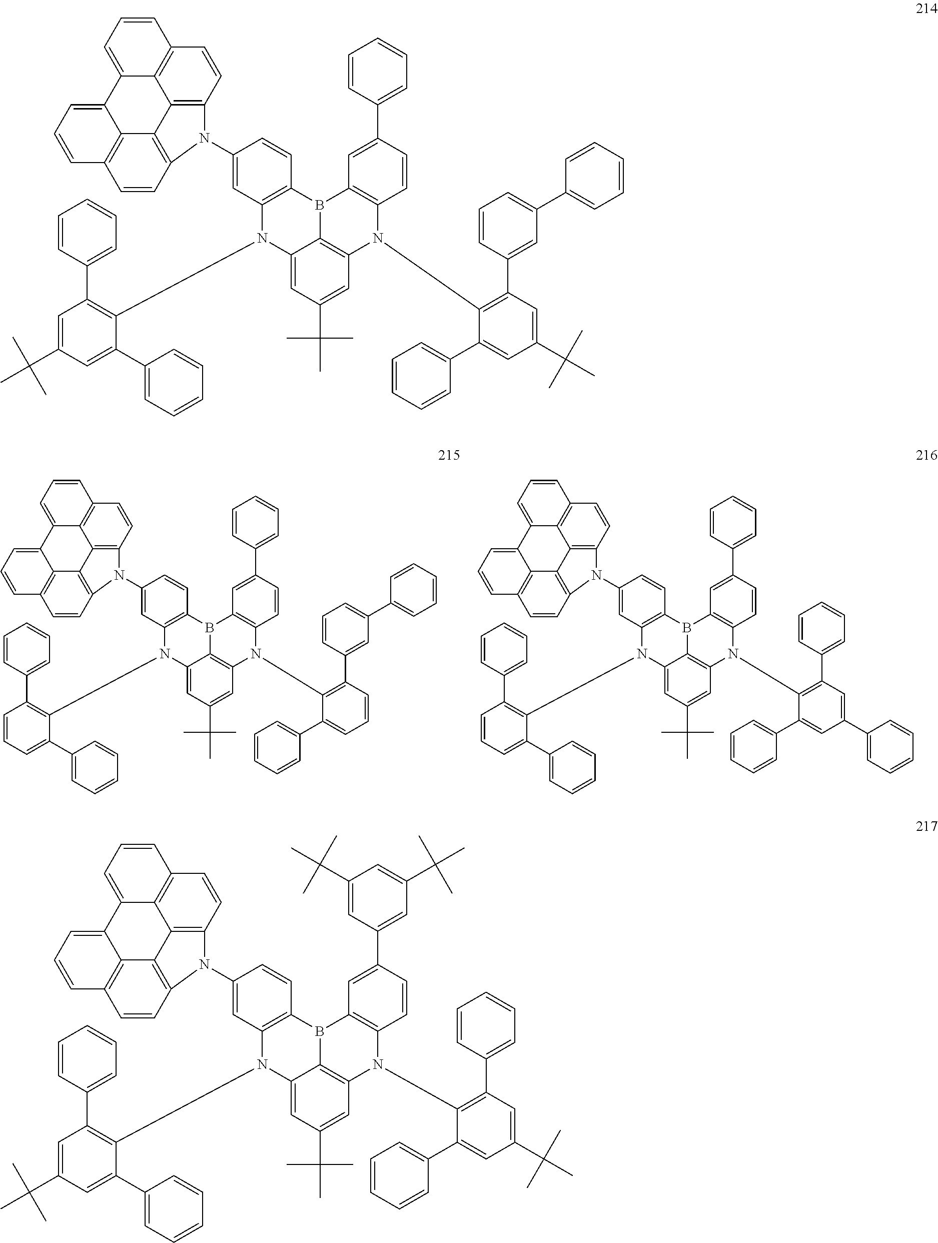

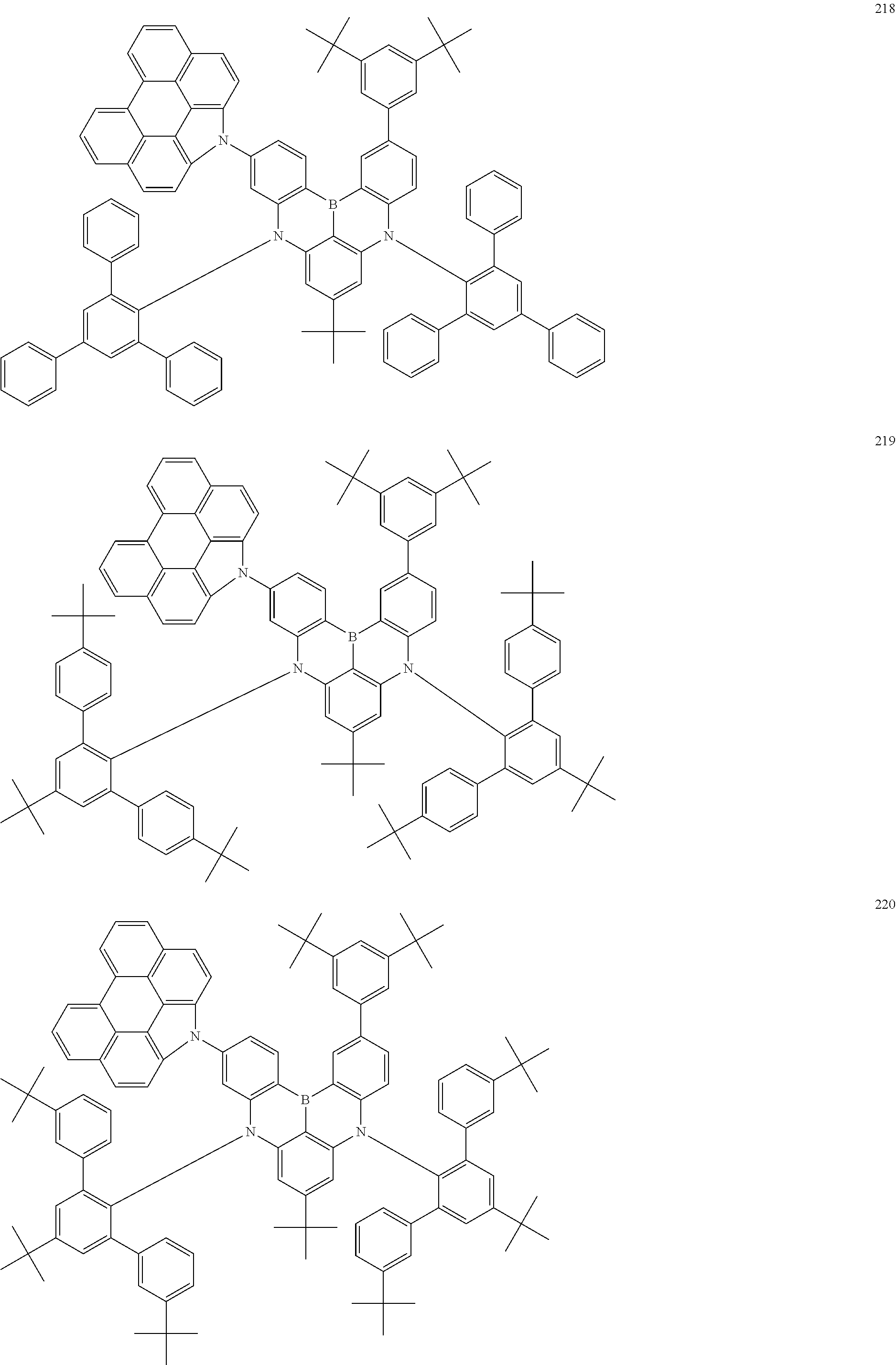

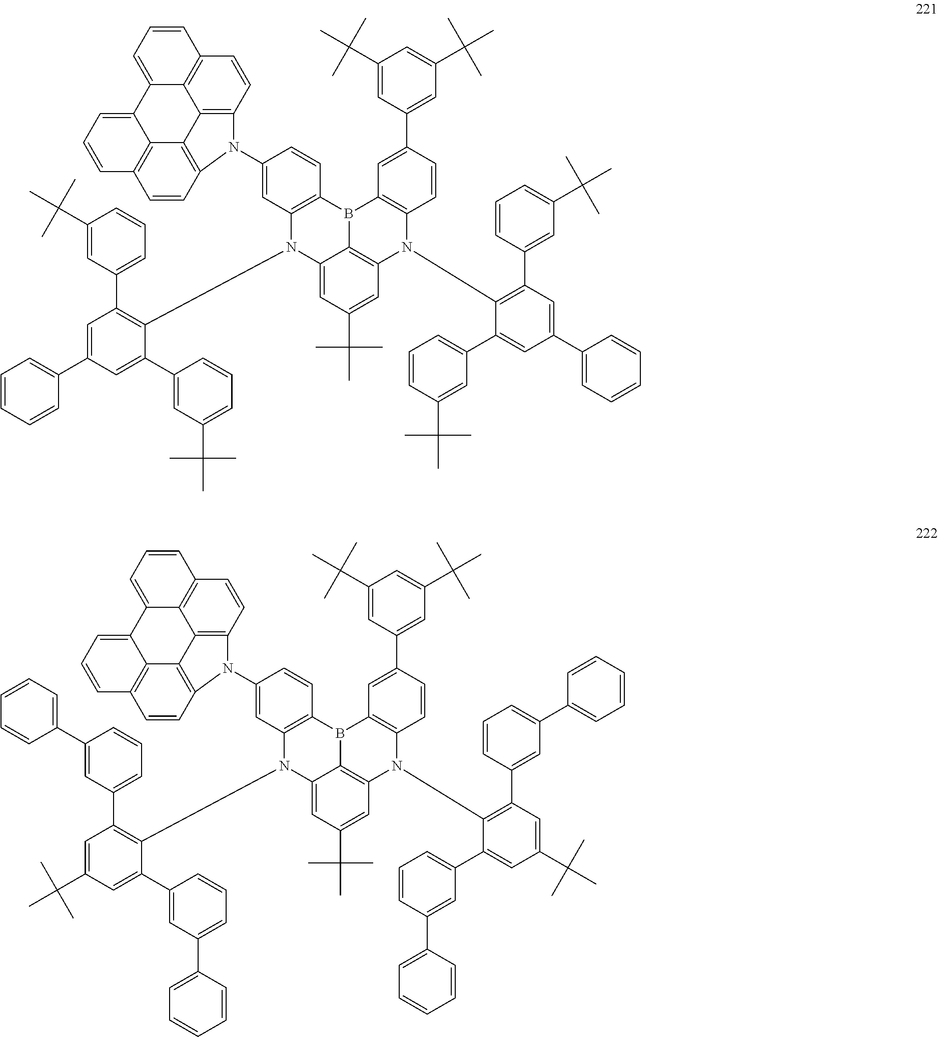 [SMILES: CC(C)(C)c1cccc(-c2cc(-c3ccccc3)cc(-c3cccc(C(C)(C)C)c3)c2N2c3ccc(-c4cc(C(C)(C)C)cc(C(C)(C)C)c4)cc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2ccc3c(c2)B2c4ccc(-n5c6ccc7cccc8c9cccc%10ccc5c(c%109)c6c78)cc4N(c4c(-c5cccc(-c6ccccc6)c5)cc(C(C)(C)C)cc4-c4cccc(-c5ccccc5)c4)c4cc(C(C)(C)C)cc(c42)N3c2c(-c3cccc(-c4ccccc4)c3)cc(C(C)(C)C)cc2-c2cccc(-c3ccccc3)c2)cc(C(C)(C)C)c1]

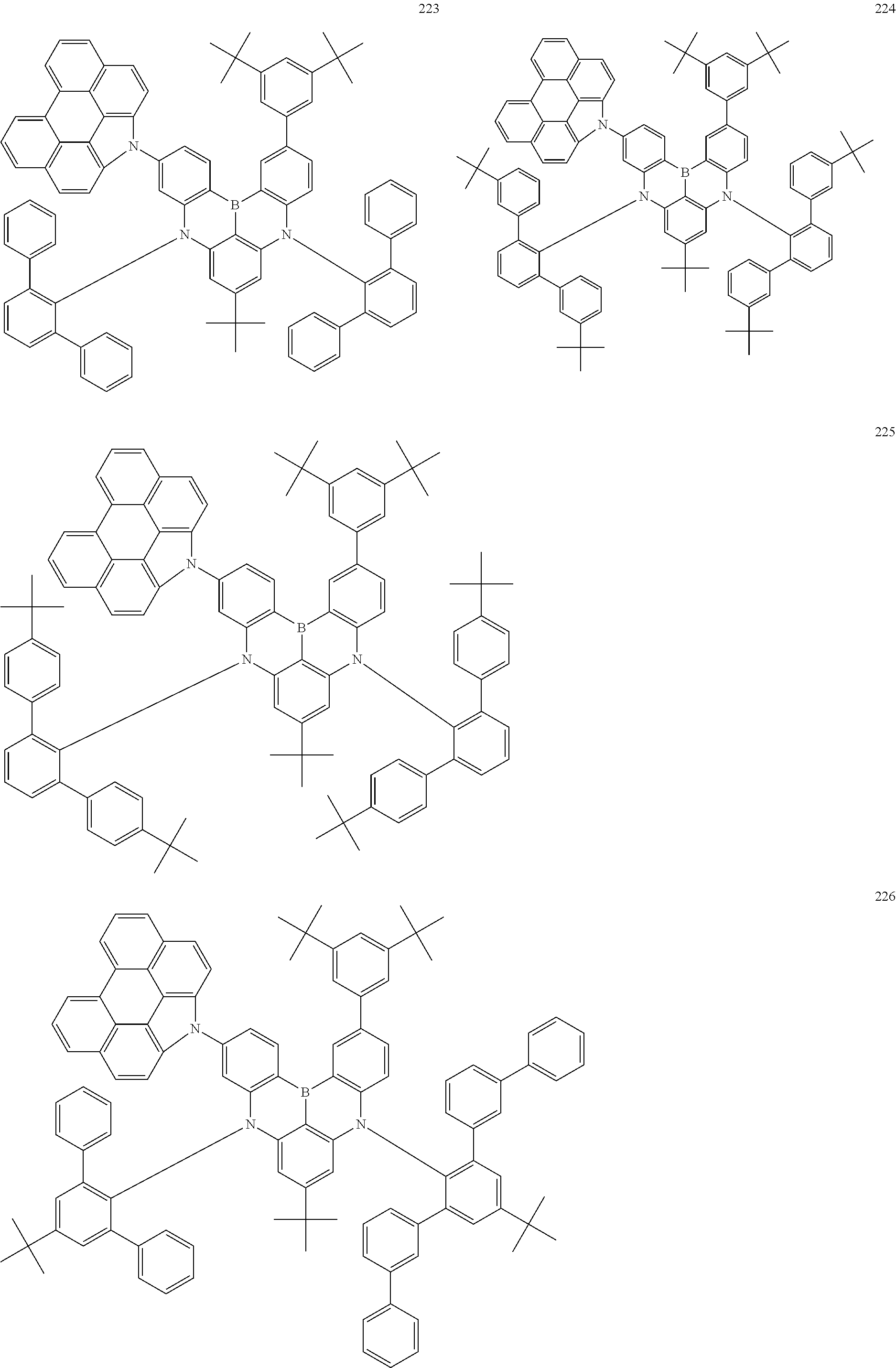

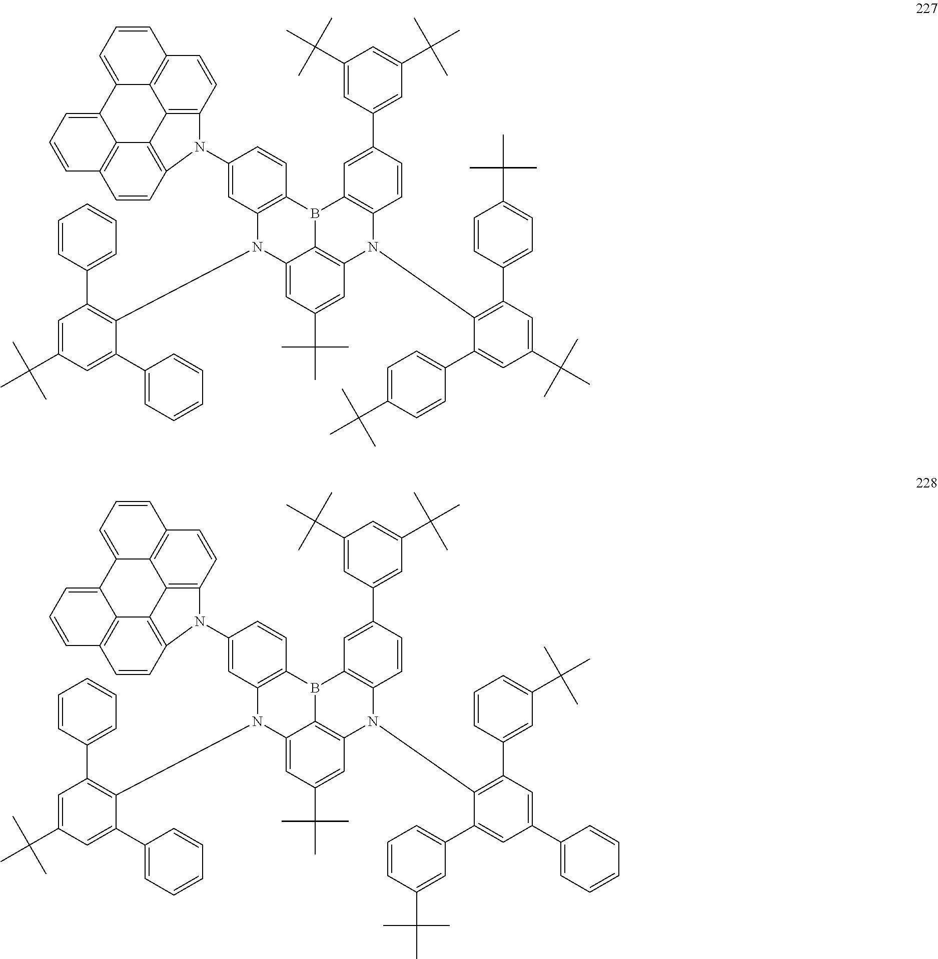

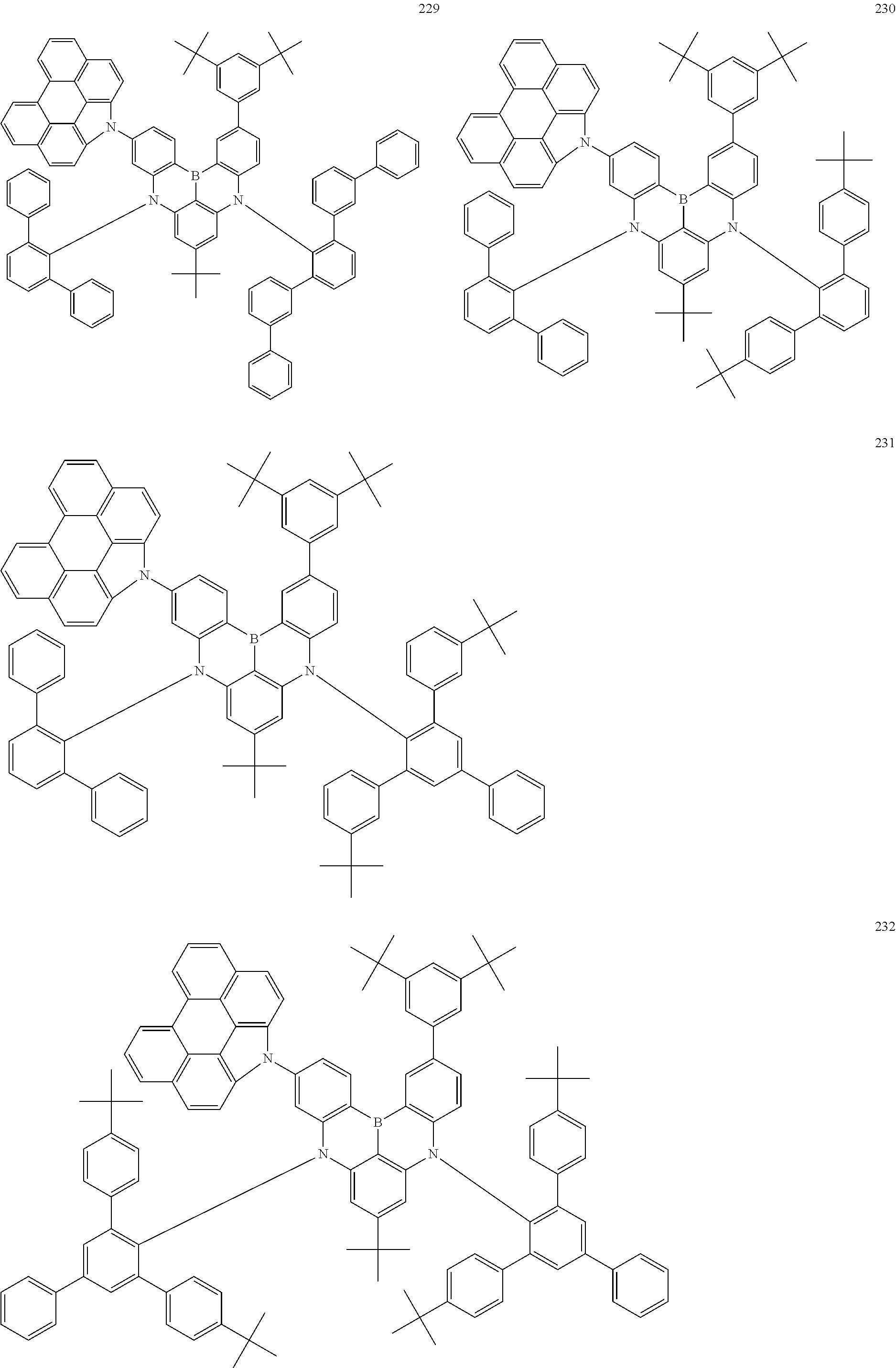

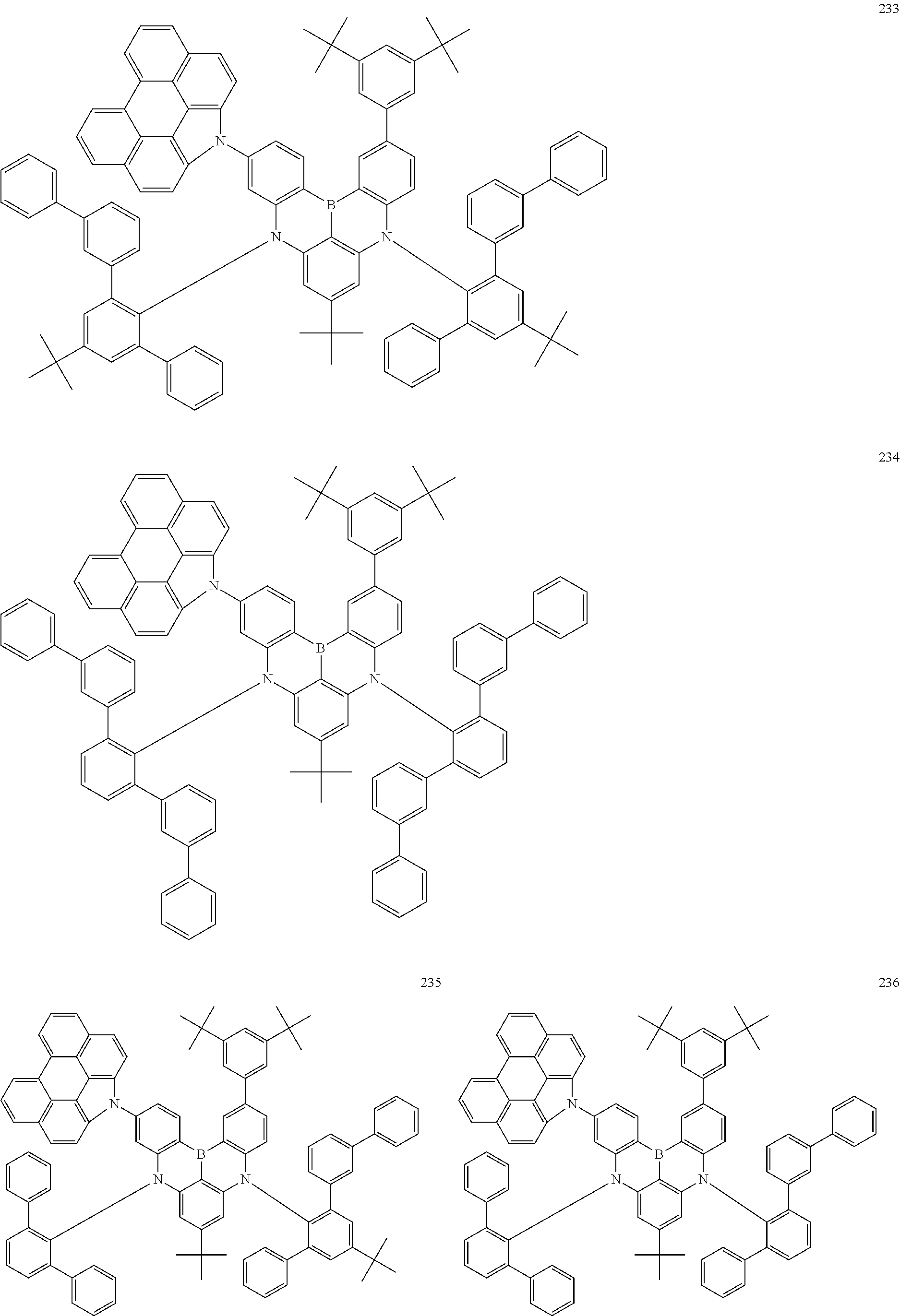

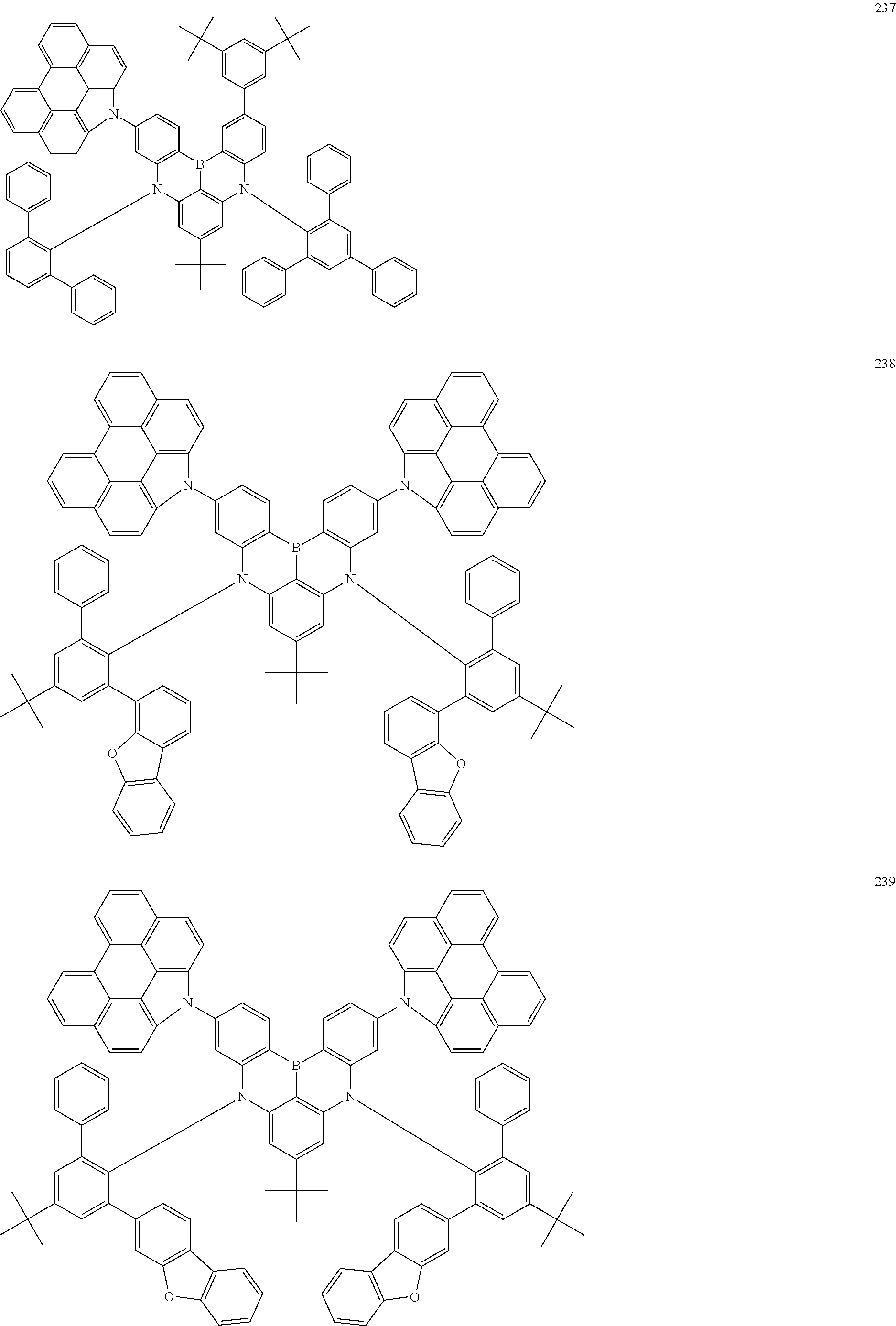

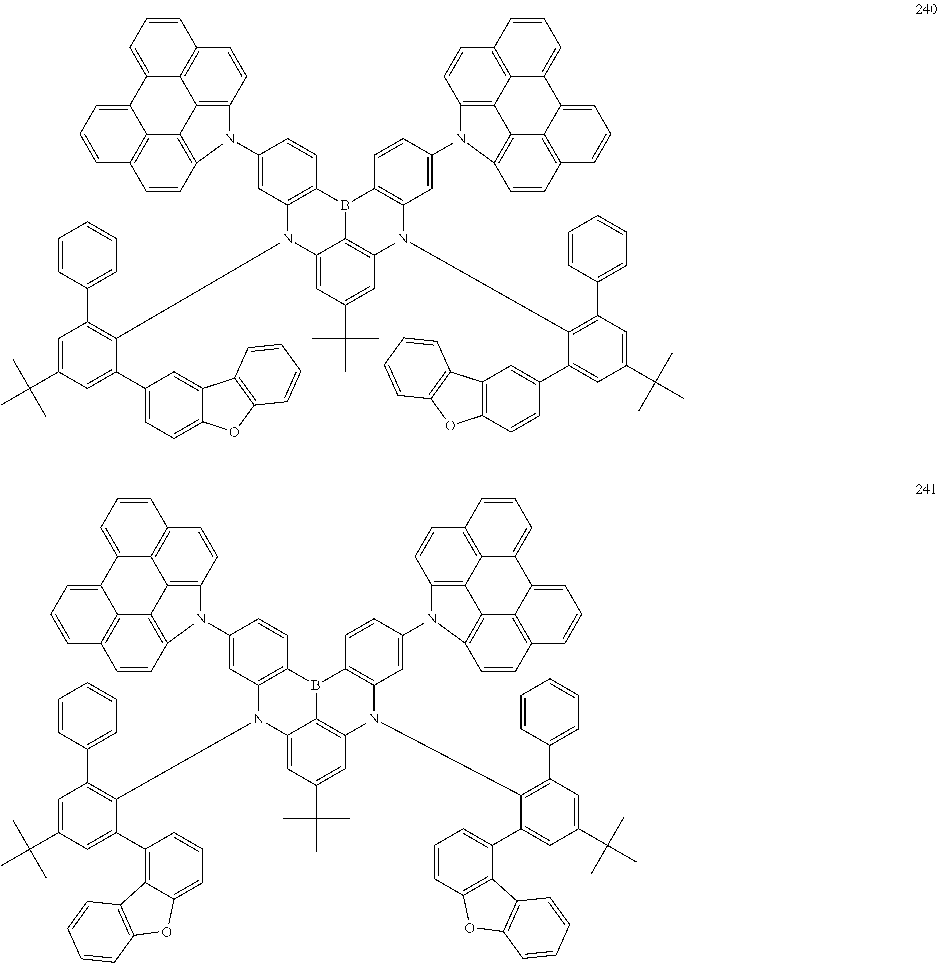

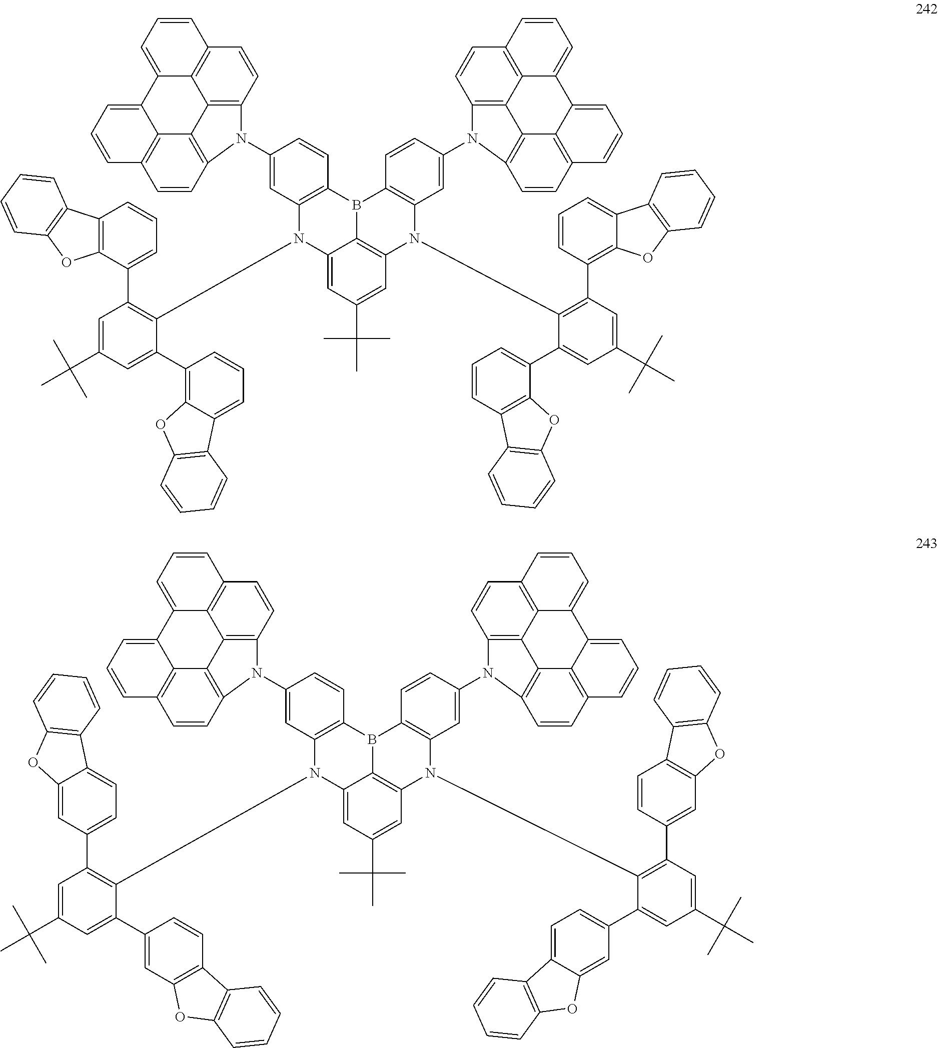

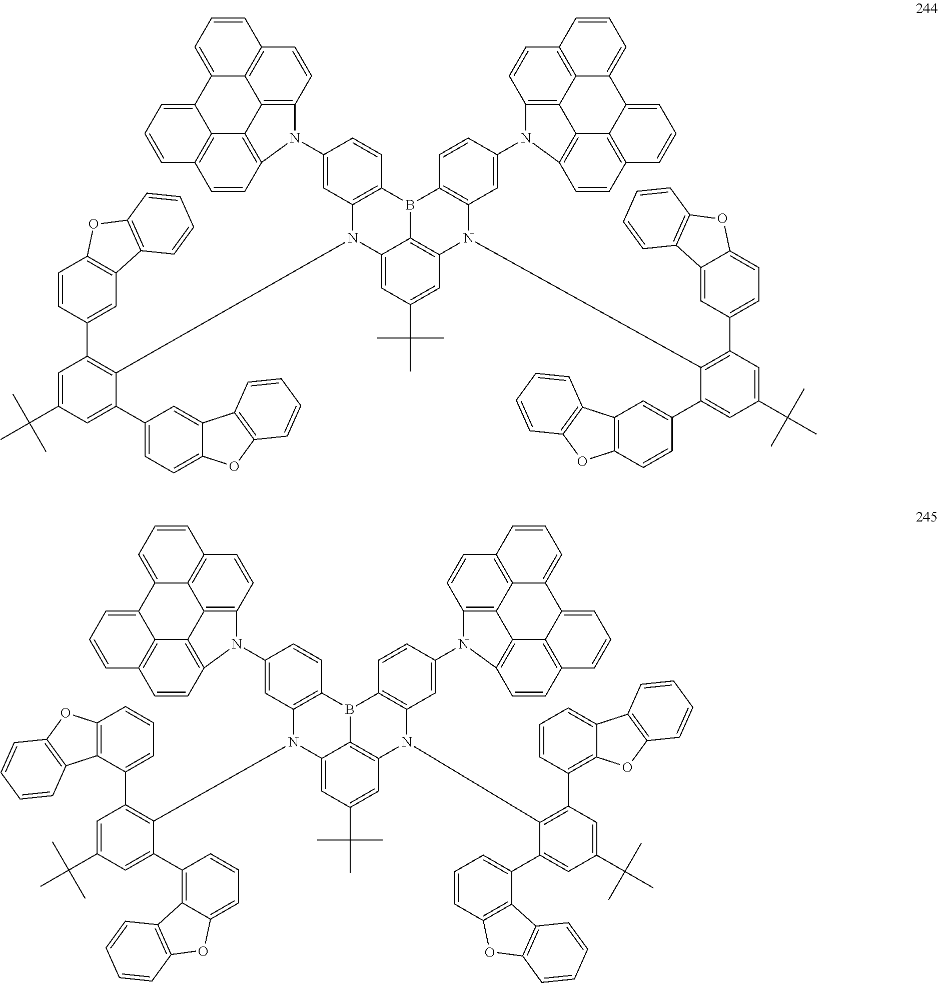 [SMILES: CC(C)(C)c1cc(-c2ccc3oc4ccccc4c3c2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc6oc7ccccc7c6c5)cc(C(C)(C)C)cc4-c4ccc5oc6ccccc6c5c4)c4cc(C(C)(C)C)cc2c43)c(-c2ccc3oc4ccccc4c3c2)c1 ; CC(C)(C)c1cc(-c2cccc3c2oc2ccccc23)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc6oc7ccccc7c56)cc(C(C)(C)C)cc4-c4cccc5oc6ccccc6c45)c4cc(C(C)(C)C)cc2c43)c(-c2cccc3oc4ccccc4c23)c1]

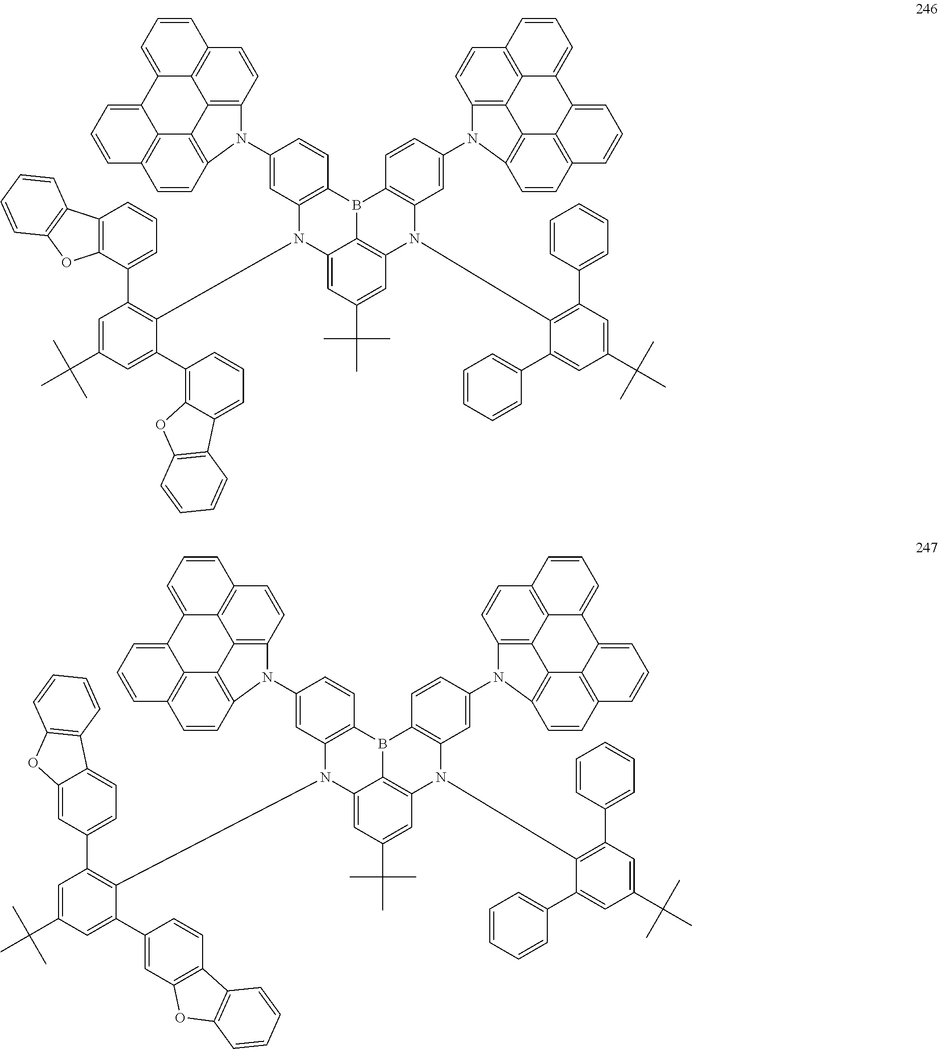

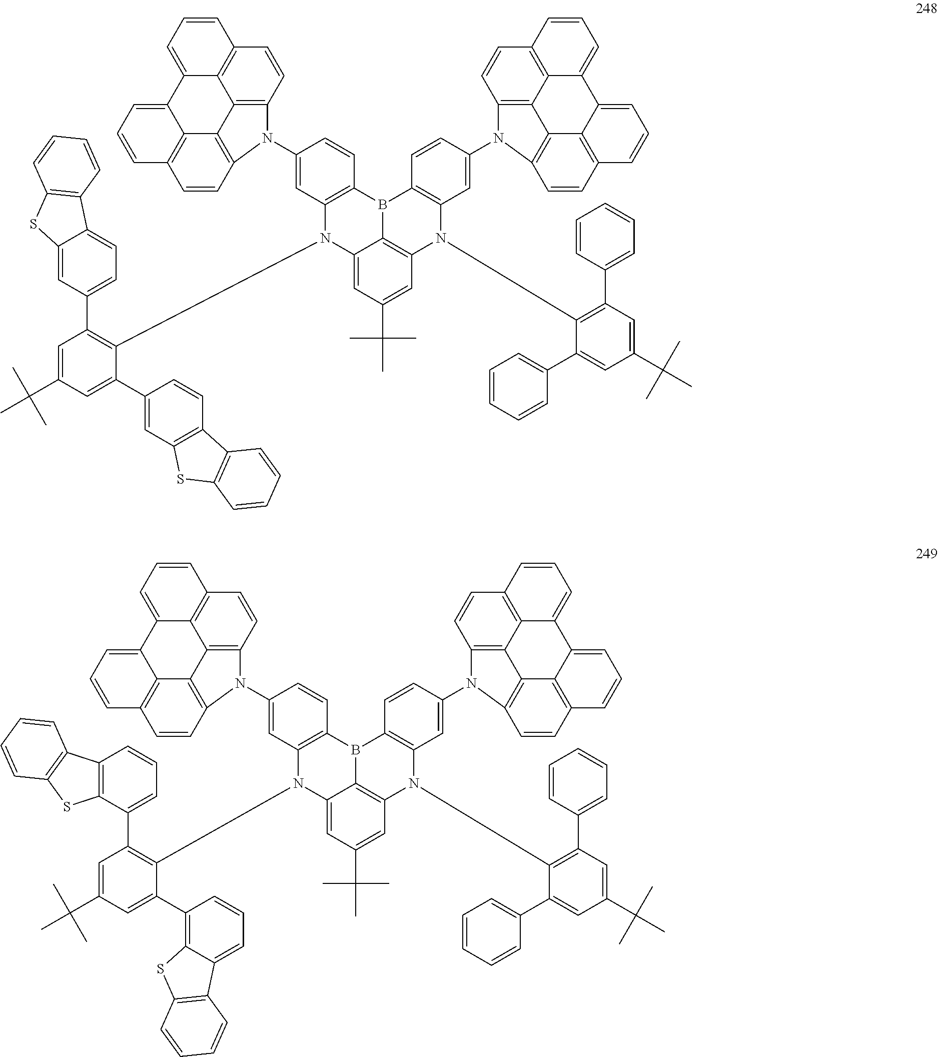 [SMILES: CC(C)(C)c1cc(-c2ccccc2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc6c(c5)sc5ccccc56)cc(C(C)(C)C)cc4-c4ccc5c(c4)sc4ccccc45)c4cc(C(C)(C)C)cc2c43)c(-c2ccccc2)c1 ; CC(C)(C)c1cc(-c2ccccc2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc6c5sc5ccccc56)cc(C(C)(C)C)cc4-c4cccc5c4sc4ccccc45)c4cc(C(C)(C)C)cc2c43)c(-c2ccccc2)c1]

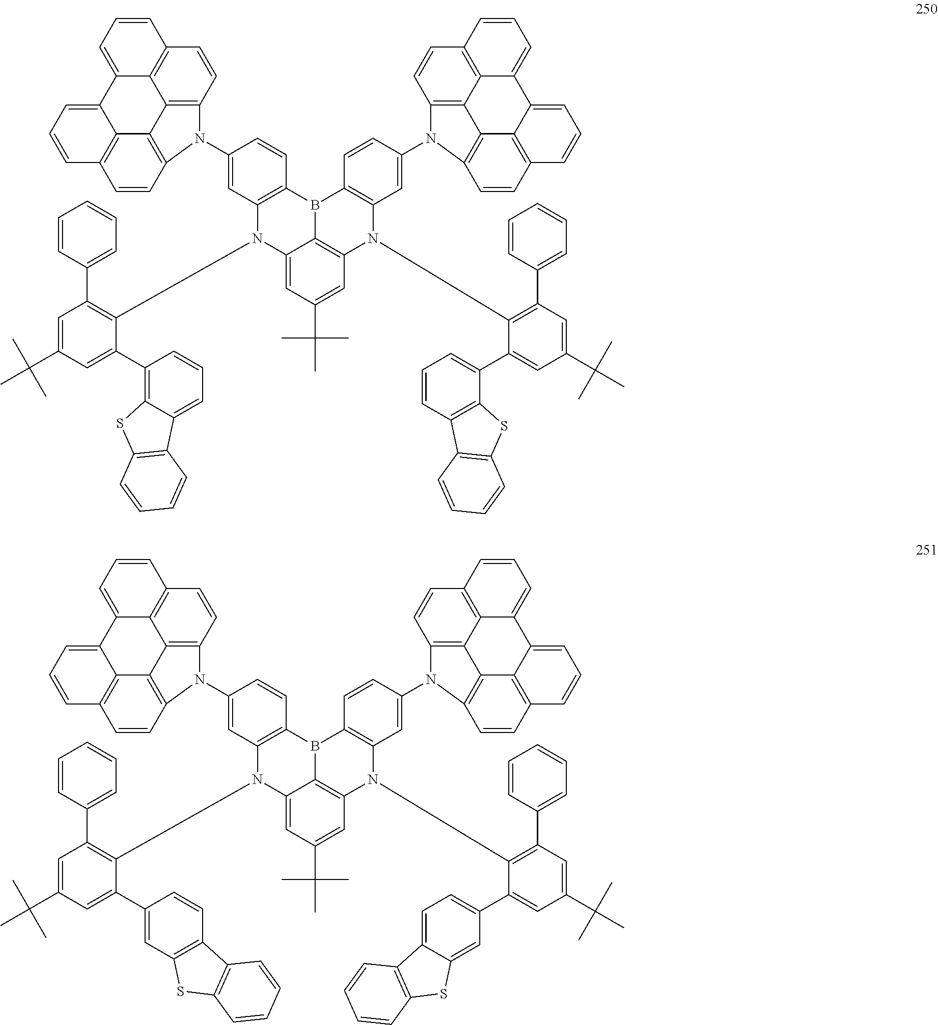

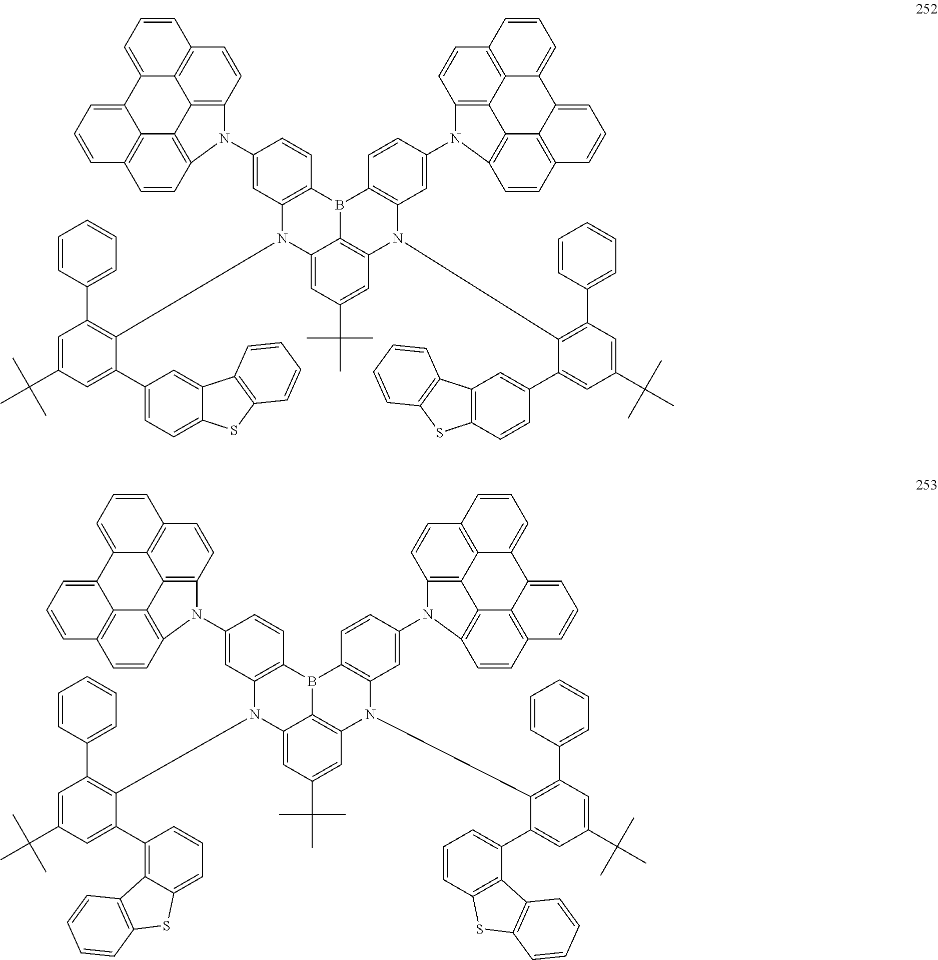

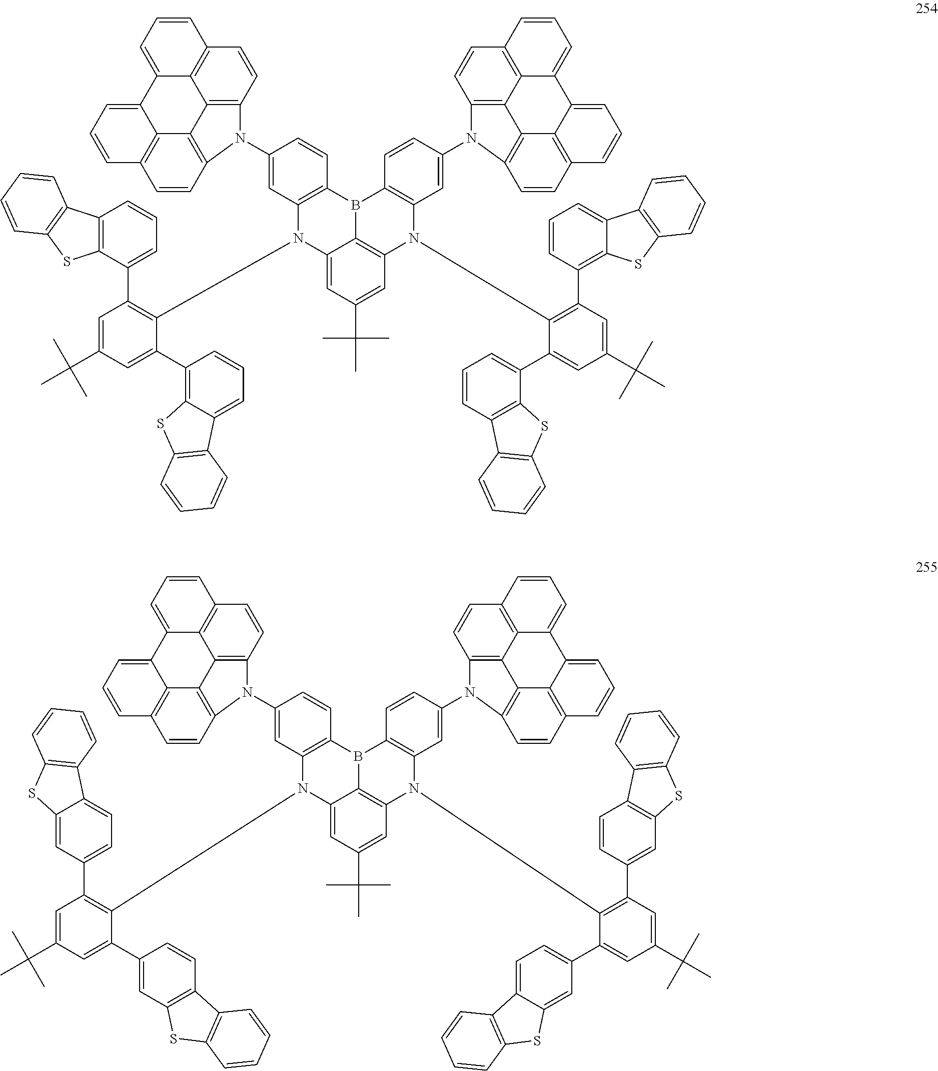

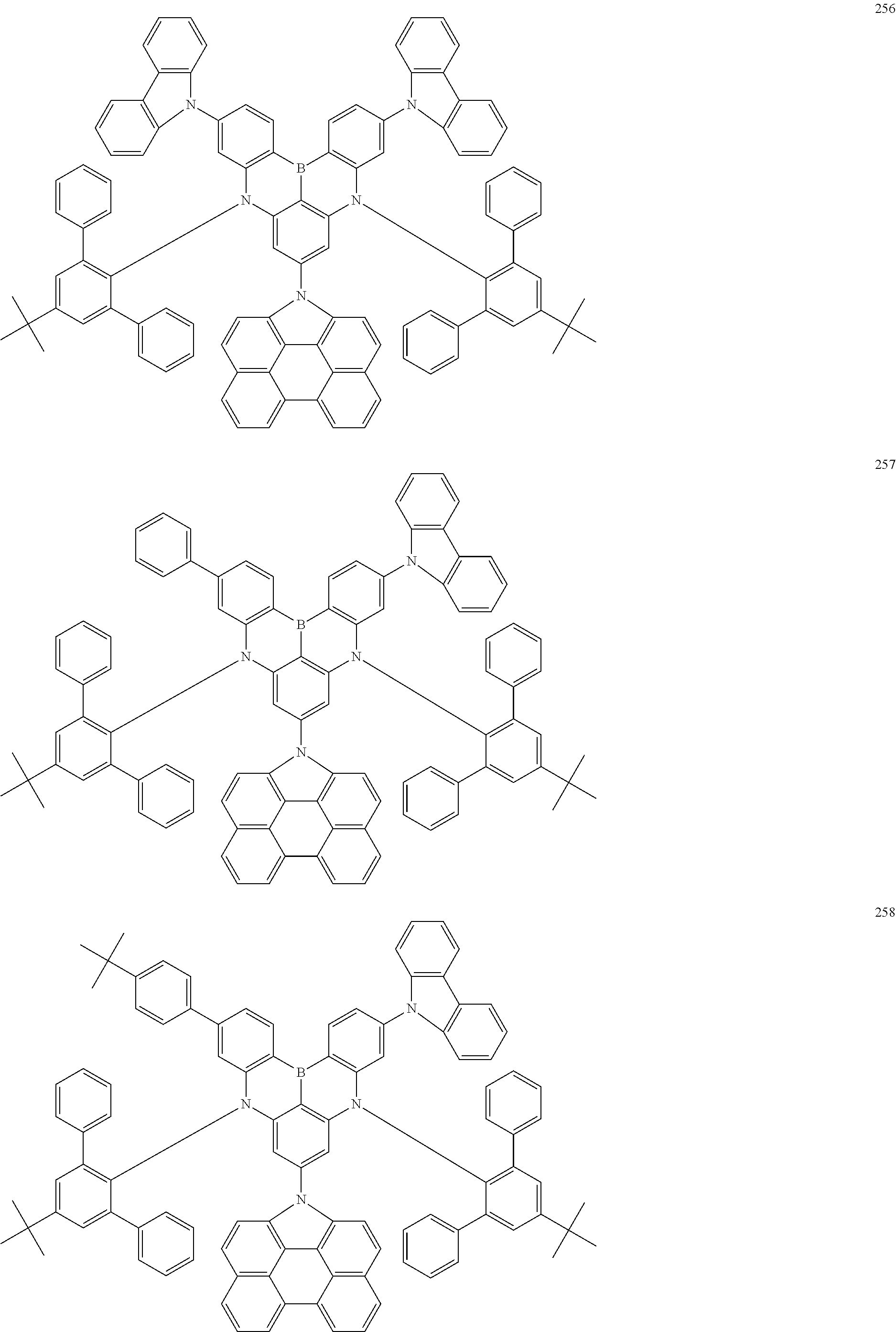

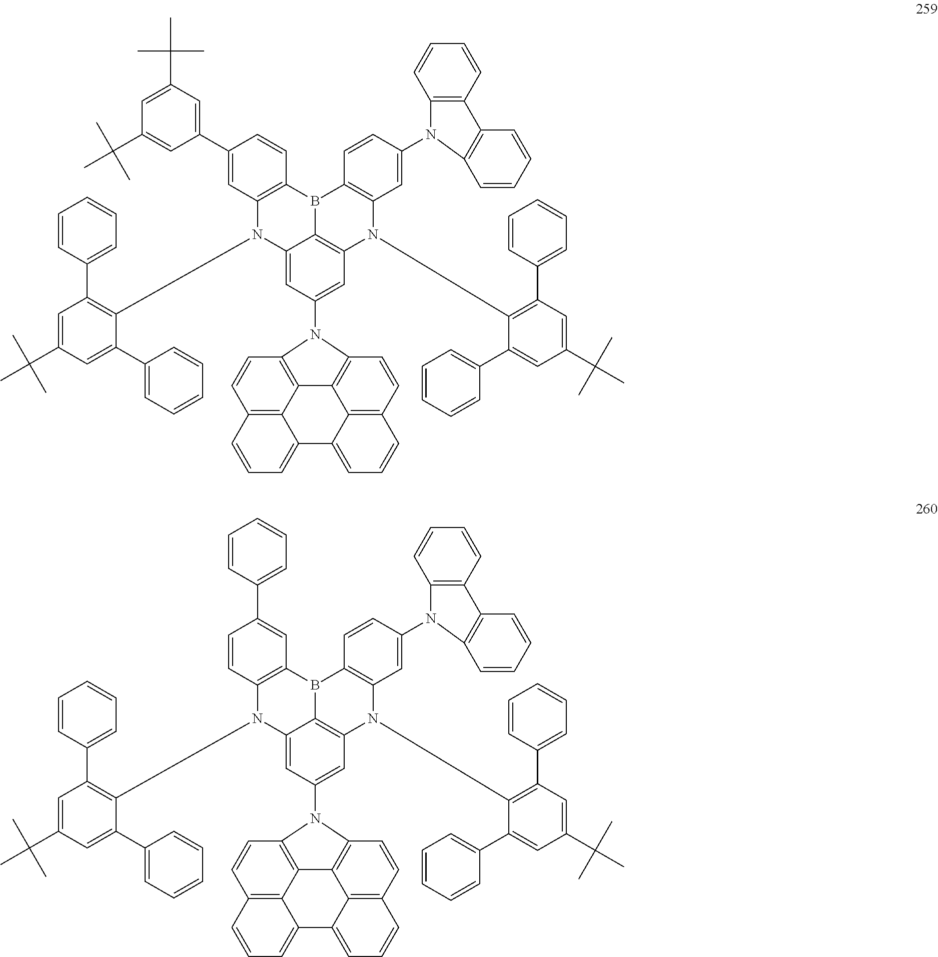

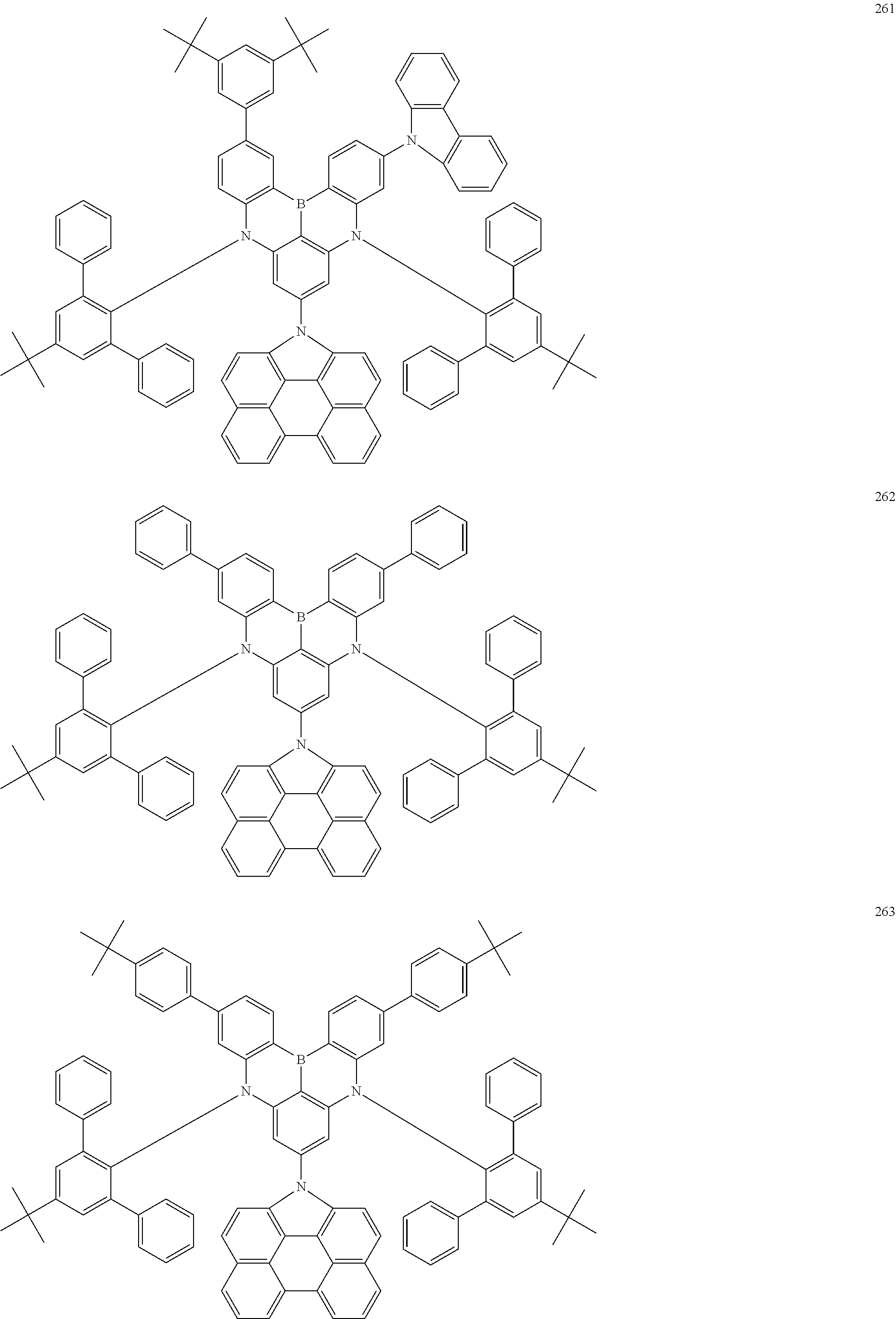

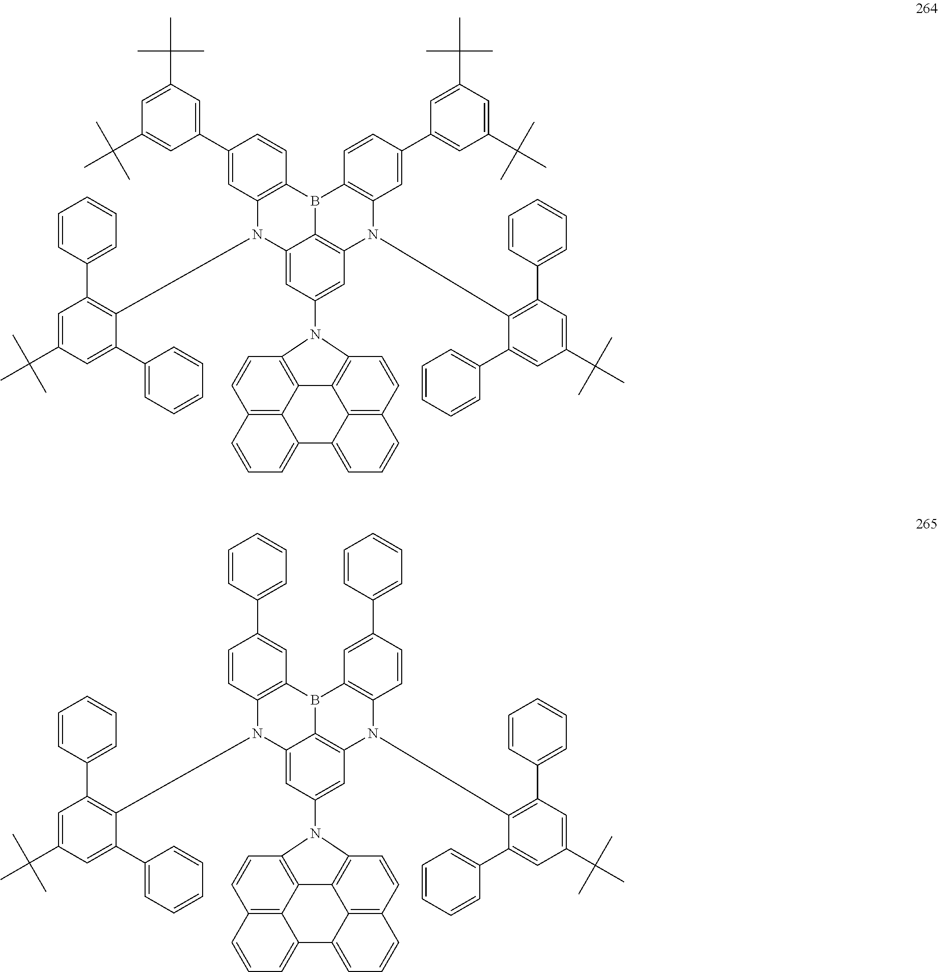

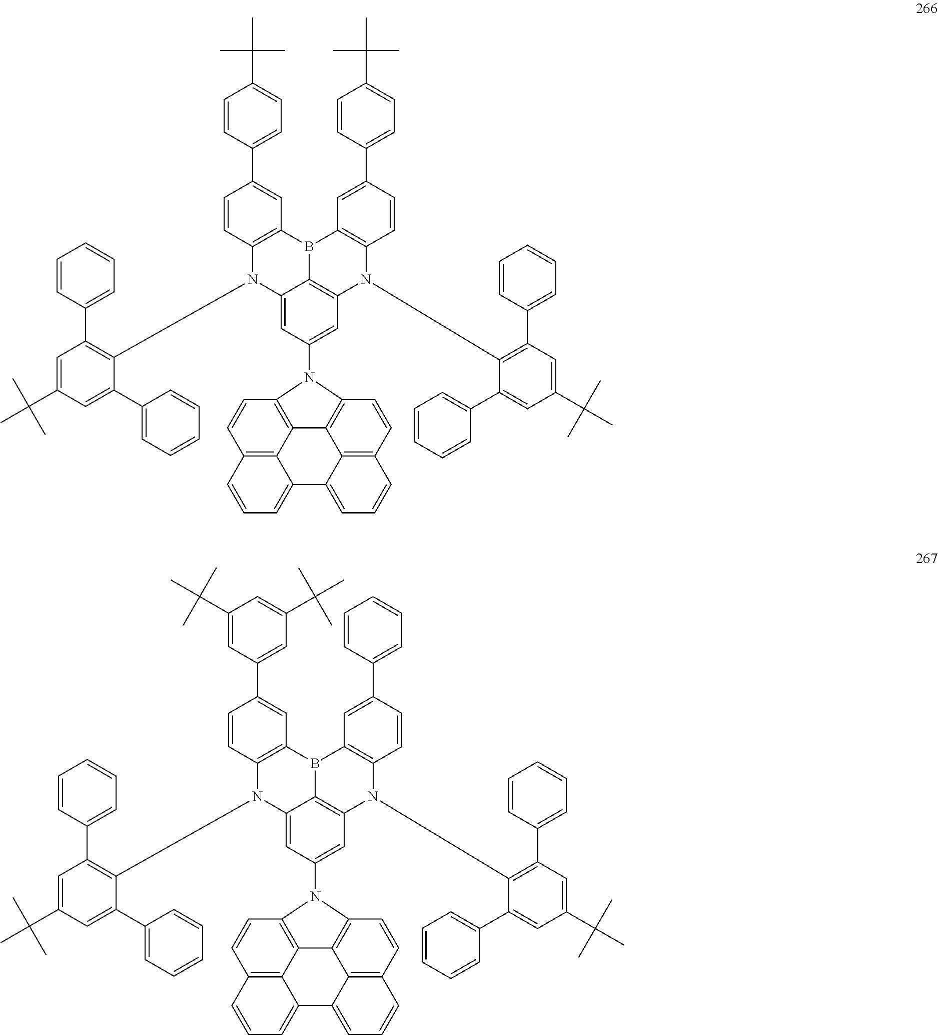

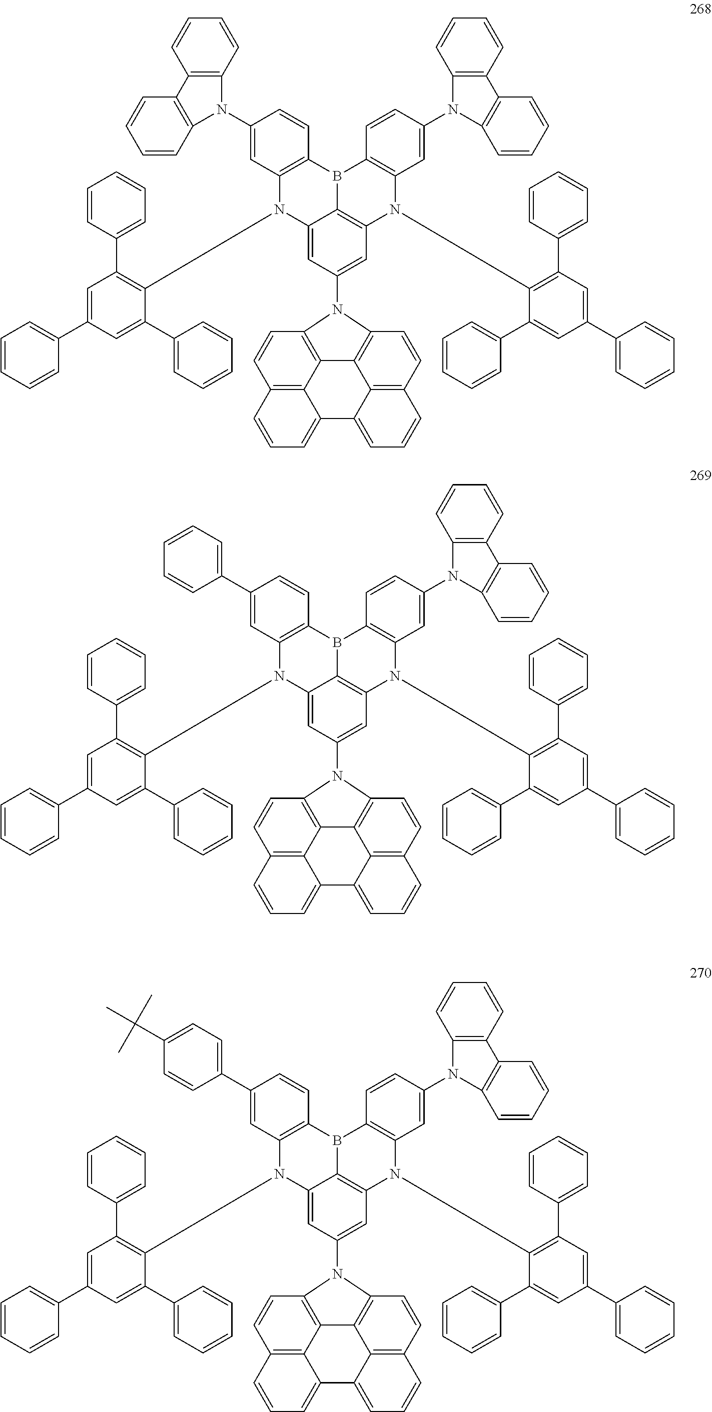

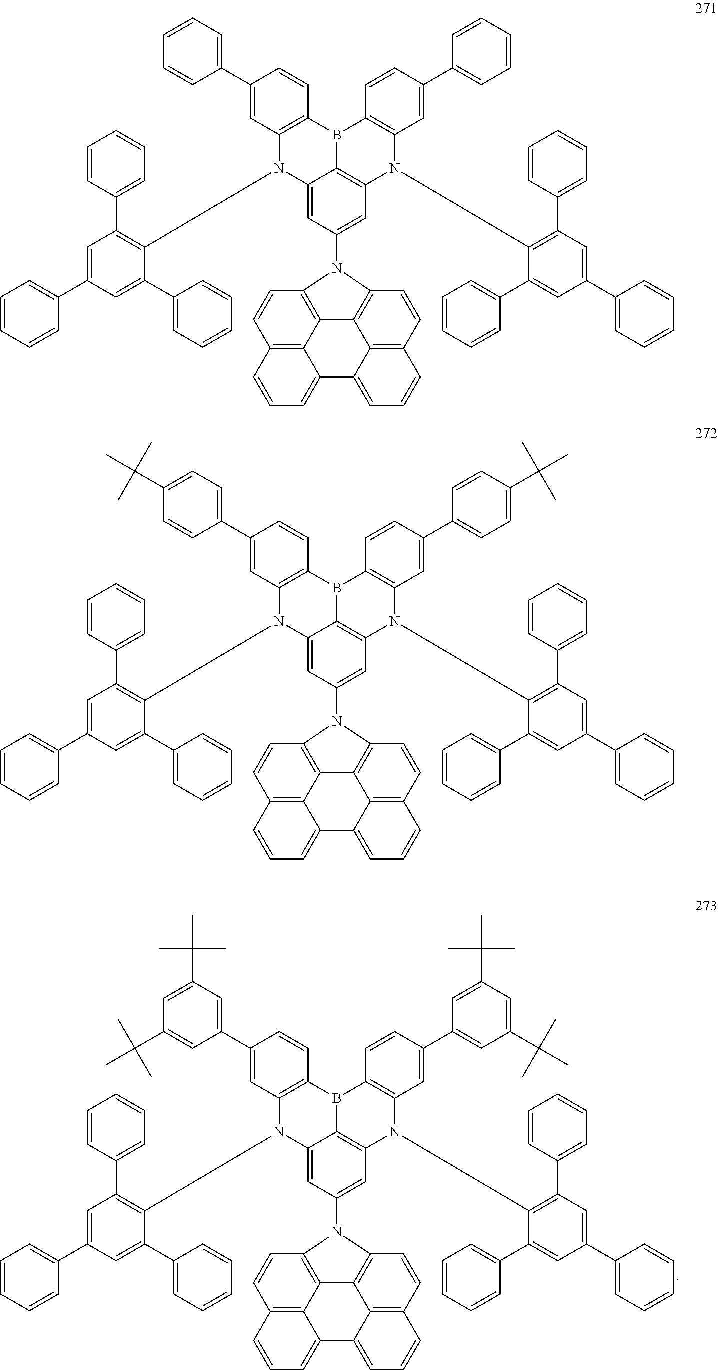

An emission spectrum of the polycyclic compound represented by Formula 1 may have a full width at half maximum (FWHM) in a range of about 10 nm to about 50 nm. For example, the emission spectrum of the polycyclic compound represented by Formula 1 may have FWHM in a range of about 20 nm to about 40 nm. As the emission spectrum of the polycyclic compound represented by Formula 1 may have an FWHM in any of the ranges described above, luminous efficiency may be improved when the polycyclic compound is applied to a light emitting element ED. In an embodiment, a service life of the light emitting element ED may be improved when the polycyclic compound according to an embodiment is used as a blue light emitting element material for a light emitting element.

In an embodiment, the polycyclic compound represented by Formula 1 may be a thermally activated delayed fluorescence (TADF) emitting material. The polycyclic compound represented by Formula 1 includes at least one phenanthro-carbazole group represented by Formula 2, and may thus have further improved delayed fluorescence. In an embodiment, the polycyclic compound represented by Formula 1 includes a phenanthro-carbazole group represented by Formula 2 and thus reduces Tn energy level, and accordingly, may suppress ISC even when RISC is reduced, and achieve long service life of the light emitting element ED by reducing the concentration of triplet exciton within molecules.

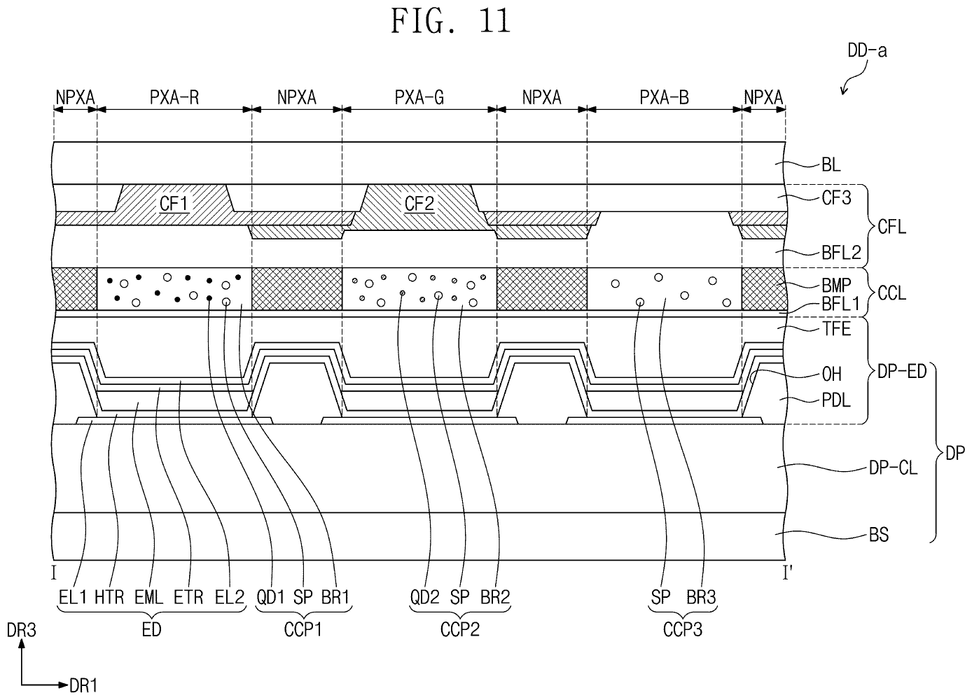

FIGS. 10A to 10D are each a diagram of an energy level of a polycyclic compound. FIGS. 10A and 10C each show energy levels for Comparative Example Compounds with no phenanthro-carbazole group represented by Formula 2, and FIGS. 10B and 10D each show energy levels for polycyclic compounds containing a phenanthro-carbazole group represented by Formula 2. FIG. 10A shows Comparative Example Compound X1, and FIG. 10B shows polycyclic compound X2 in which a phenyl group is linked to a benzene moiety linked to a nitrogen atom of a core to be positioned para to the nitrogen atom of the core. FIG. 10C shows Comparative Example Compound X3, and FIG. 10D shows polycyclic compound 91 according to an embodiment.

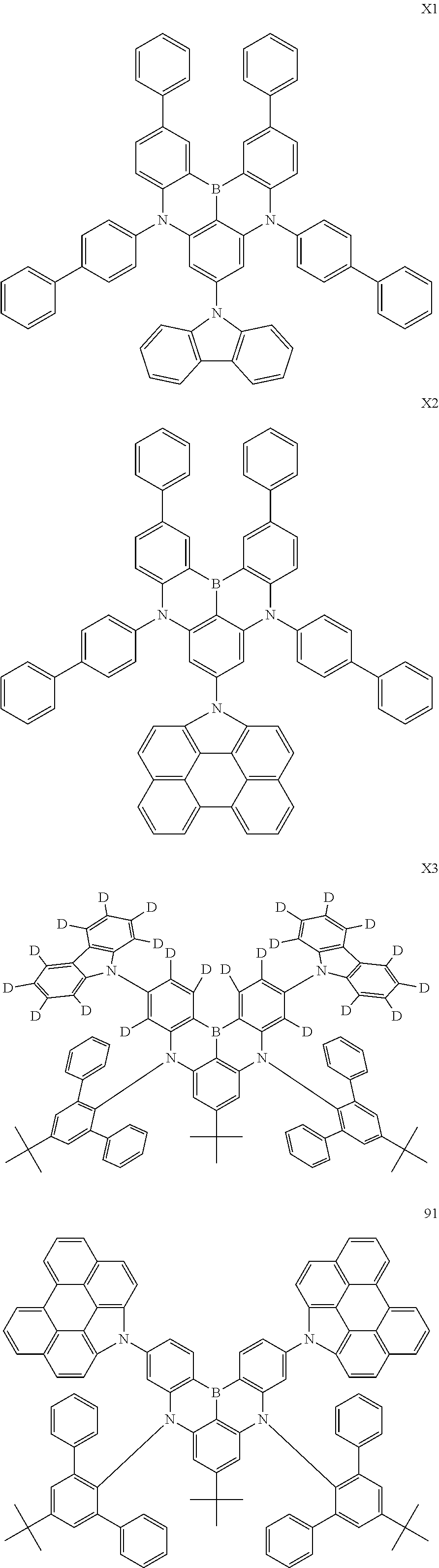

Referring to FIG. 10A, as for Comparative Example Compound X1 with no phenanthro-carbazole group, a complex inter-system crossing (ISC) mechanism via a higher-order excited triplet energy level (Tn energy level, where n is 4) is used. In an embodiment, exciton quenching, such as collision of triplet exciton accumulated within molecules as described above, may take place, causing degradation in the lifetime of organic light emitting elements. Referring to FIG. 10B, polycyclic compound X2 has a third lowest triplet energy level (T3) which is lower than a lowest singlet energy level (S1), and may thus suppress ISC. Ass the T3 energy level becomes lower than Si, a fast IC from T3 to T1 may be induced. It is seen from the comparison between Compound X1 and Compound X2 that the light emitting element ED may exhibit long lifetime due to the effect of reducing the triplet exciton concentration according to with/without a phenanthro-carbazole group.

Referring to FIGS. 10C and 10D, as for Comparative Example Compound X3 with no phenanthro-carbazole group, a complex inter-system crossing (ISC) mechanism via a higher-order excited triplet energy level (Tn level, where n is 4) is used. In the case of Comparative Example Compound X3 as well, exciton quenching, such as accumulated triplet exciton collision, may take place, causing degradation in the lifetime of organic light emitting elements. Polycyclic compound X4 according to an embodiment has the fourth lowest triplet energy level (T4) which is lower than the lowest singlet energy level (S1), and may thus suppress ISC. As the T4 energy level becomes lower than the S1 energy level, a fast IC from T4 to T1 is induced, and accordingly, long lifetime may be shown due to the effect of reducing the molecular triplet exciton concentration.

In an embodiment, the polycyclic compound represented by Formula 1 may be a light emitting material having a central light emitting wavelength in a wavelength range of about 430 nm to about 490 nm. For example, the polycyclic compound represented by Formula 1 may be a blue thermally activated delayed fluorescence (TADF) dopant. However, embodiments are not limited thereto, and when the polycyclic compound is used as a light emitting material, a first dopant may be used as a dopant material emitting light in various wavelength ranges, such as a red light emitting dopant and a green light emitting dopant.

In the light emitting element ED according to an embodiment, the emission layer EML may emit delayed fluorescence. For example, the emission layer EML may emit light of thermally activated delayed fluorescence (TADF).

In an embodiment, the emission layer EML of the light emitting element ED may emit blue light. For example, the emission layer EML of a light emitting element ED may emit blue light in a wavelength range less than or equal to about 490 nm. However, embodiments are not limited thereto, and the emission layer EML may emit green light or red light.

In an embodiment, the polycyclic compound may be included in the emission layer EML. The polycyclic compound may be included in the emission layer EML as a dopant material. The polycyclic compound may be a thermally activated delayed fluorescent material. The polycyclic compound may be used as a thermally activated delayed fluorescent dopant. For example, in the light emitting element ED, the emission layer EML may include at least one of the polycyclic compounds shown in Compound Group as a thermally activated delayed fluorescence dopant. However, the use of the polycyclic compound is not limited thereto.

In an embodiment, the emission layer EML may include multiple compounds. The emission layer EML according to an embodiment may include the polycyclic compound represented by Formula 1 that is a first compound, and may include at least one of a second compound represented by Formula HT-1, a third compound represented by Formula ET-1, or a fourth compound represented by Formula D-1.

In an embodiment, in the emission layer EML, the second compound and the third compound form an exciplex, and energy may be transferred from the exciplex to the first compound to emit light. The emission layer EML may include the first compound, the second compound, the third compound, and the fourth compound. In the emission layer EML, the second compound and the third compound form an exciplex, and energy may be transferred from the exciplex to the fourth compound and the first compound to emit light. The fourth compound may be referred to as a phosphorescent sensitizer. For example, the fourth compound may emit light of phosphorescence or transfer energy to the first compound as an auxiliary dopant. However, this is only an example, and embodiments are not limited thereto.

In an embodiment, the light emitting element ED may include all of a first compound, a second compound, a third compound, and a fourth compound, and the emission layer EML may thus include a combination of two host materials and two dopant materials. In the light emitting element ED according to an embodiment, the emission layer EML may include the first compound emitting delayed fluorescence, the second compound and the third compound that are two different hosts, and the fourth compound that includes an organometallic complex, and may thus exhibit excellent luminous efficiency.

In an embodiment, the emission layer EML may include a second compound represented by Formula HT-1. In an embodiment, the second compound may be used as a hole transporting host material of the emission layer EML.

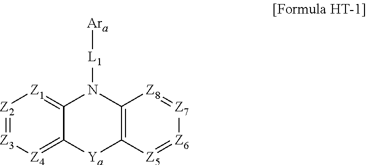

In Formula HT-1, Z₁ to Z₈ may be each independently N or C(Rₐ₁). For example, all of Z₁ to Z₈ may be C(Rₐ₁). In another example, one of Z₁ to Z₈ may be N, and the remainder of Z₁ to Z₈ may each independently be C(Rₐ₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(Rₐ₂)(Rₐ₃), or Si(Rₐ₄)(Rₐ₅). For example, the two benzene rings that are linked to the nitrogen atom in Formula HT-1 may be linked to each other via a direct linkage,

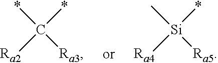

In Formula HT-1, when Yₐ is a direct linkage, the second compound represented by Formula HT-1 may include a carbazole moiety.

In Formula HT-1, Arₐ may be a substituted or unsubstituted aryl group having 6 to 30 ring-forming carbon atoms, or a substituted or unsubstituted heteroaryl group having 2 to 30 ring-forming carbon atoms. For example, Arₐ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, Rₐ₁ to Rₐ₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, Rₐ₁ to Rₐ₅ may be each independently a hydrogen atom or a deuterium atom. For example, Rₐ₁ to Rₐ₅ may be each independently an unsubstituted methyl group or an unsubstituted phenyl group.

In an embodiment, the second compound represented by Formula HT-1 may be selected from Compound Group 2. The emission layer EML may include at least one compound selected from Compound Group 2 as a hole transporting host material.

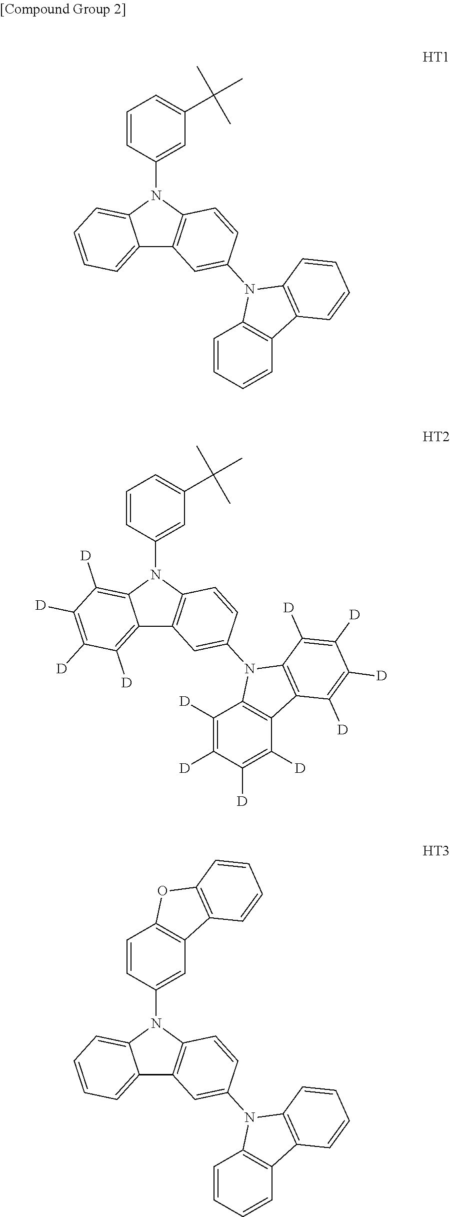 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

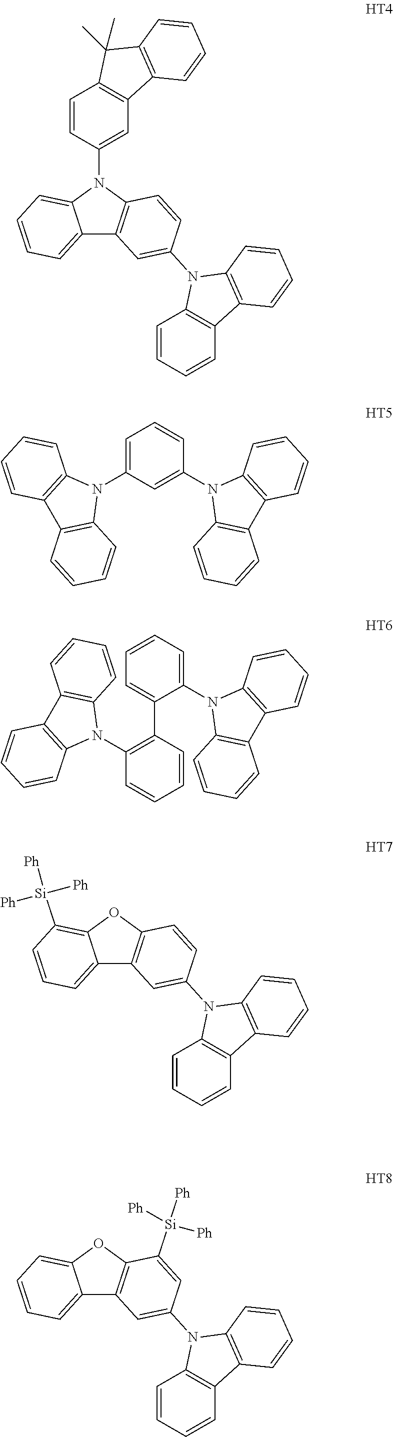 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

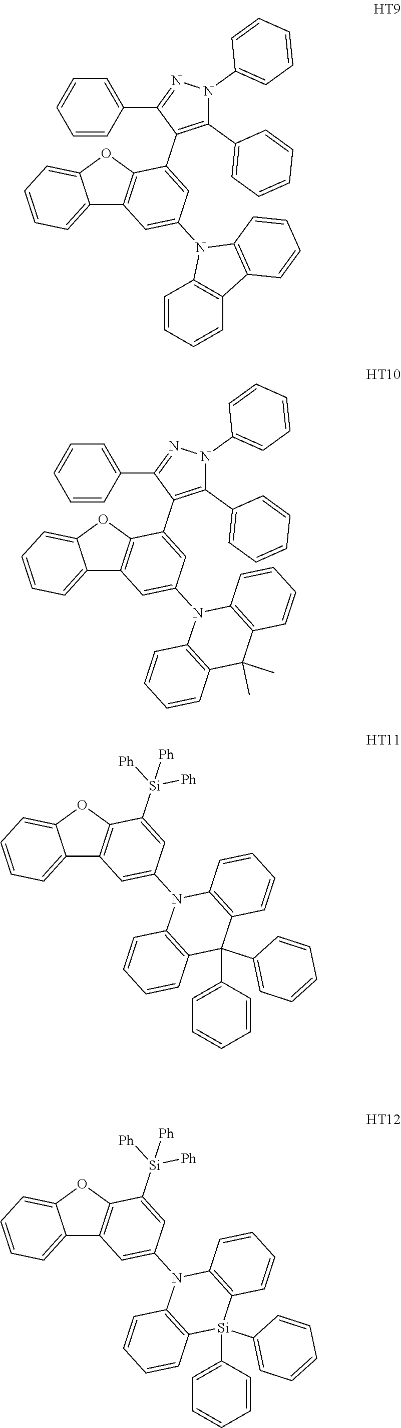

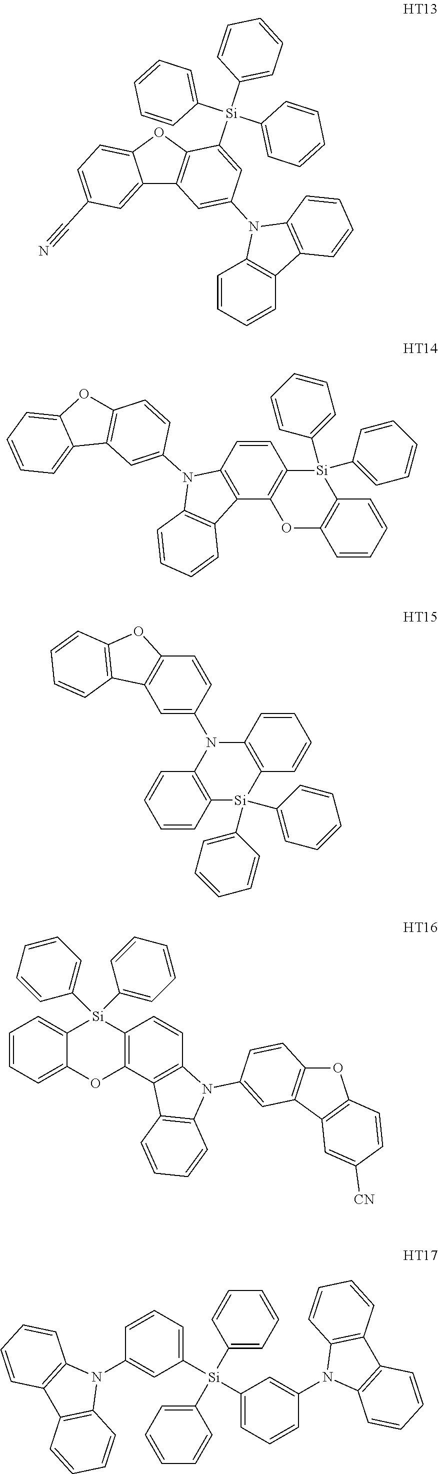 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

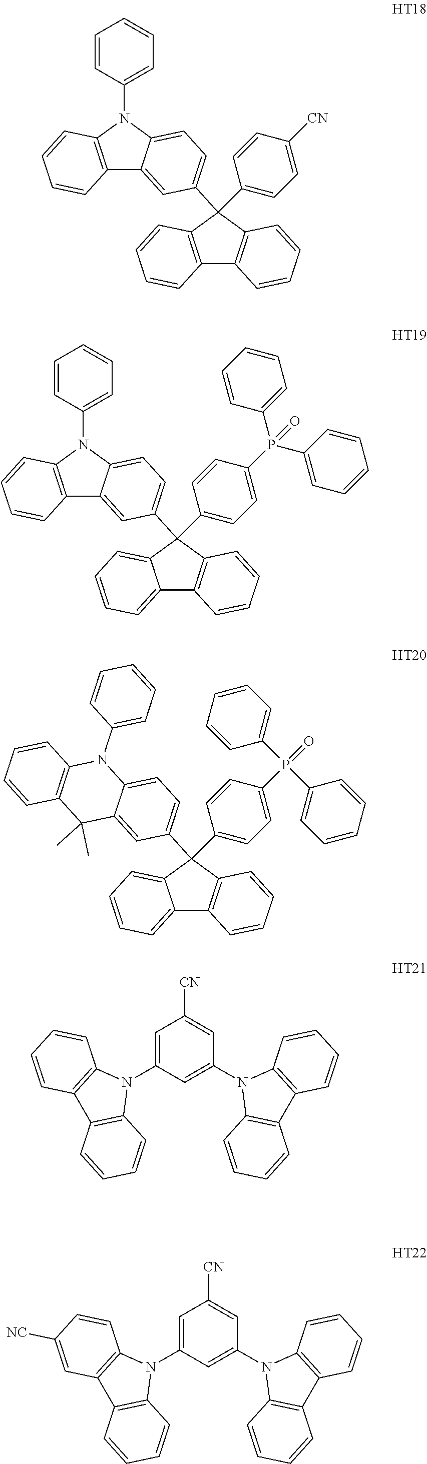 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

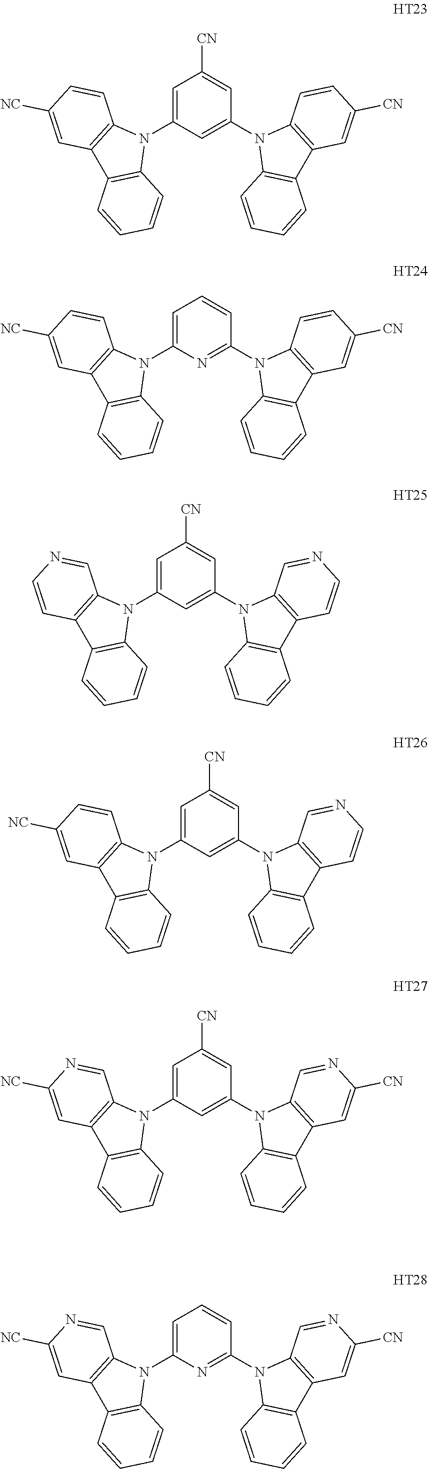 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

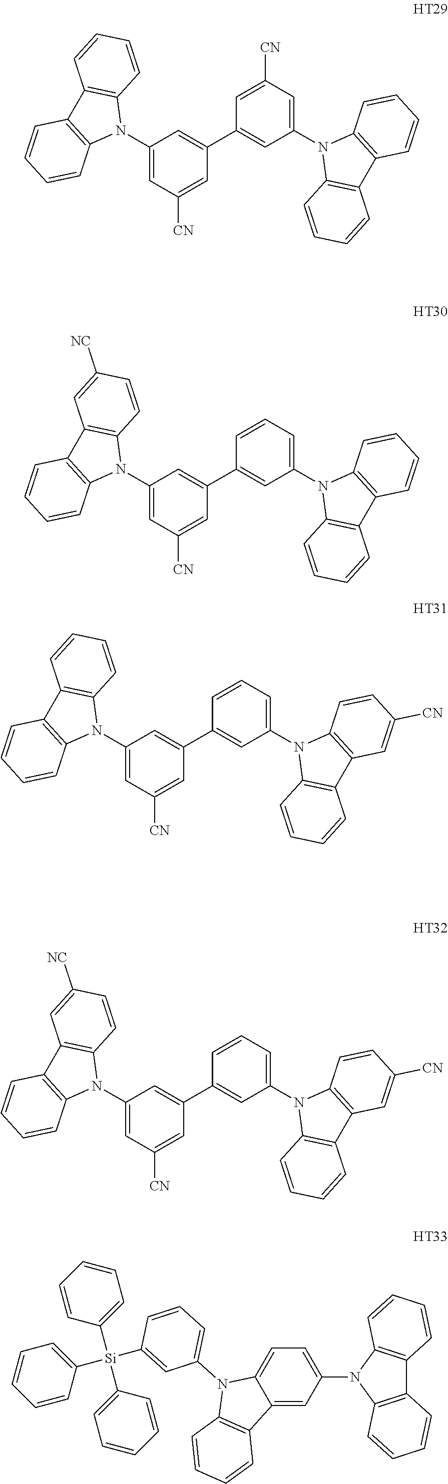 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

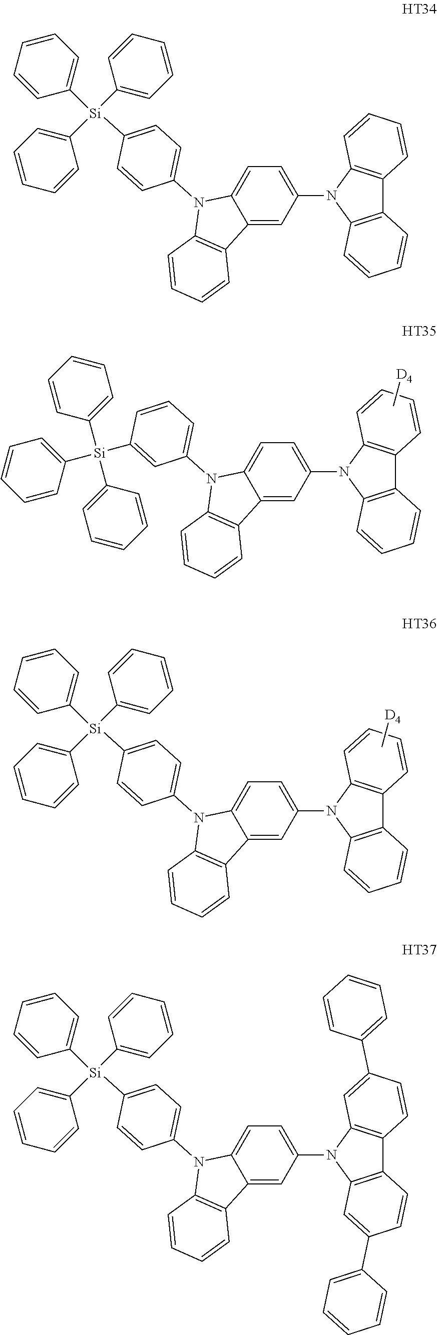

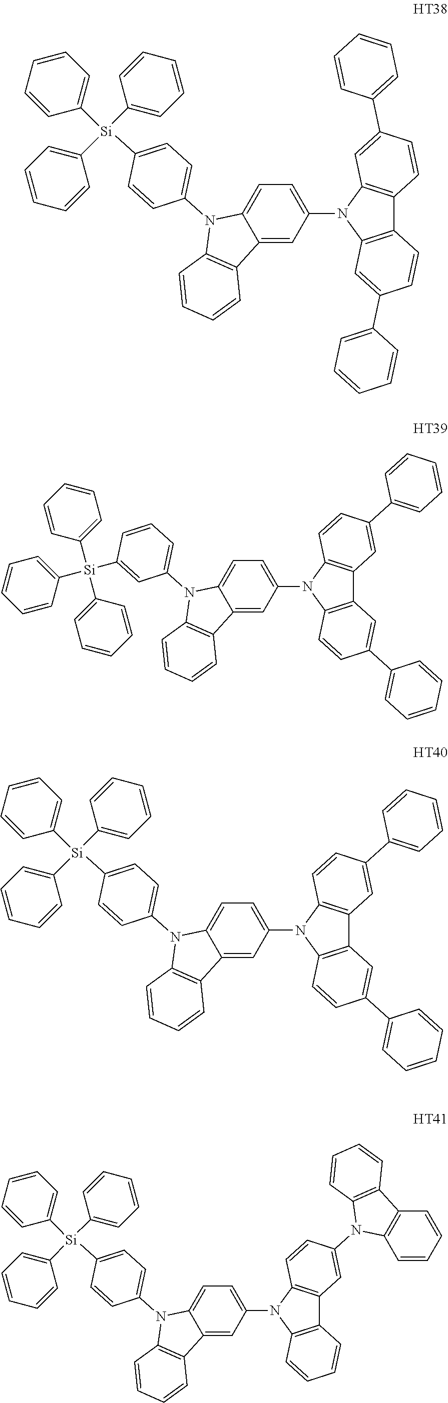 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

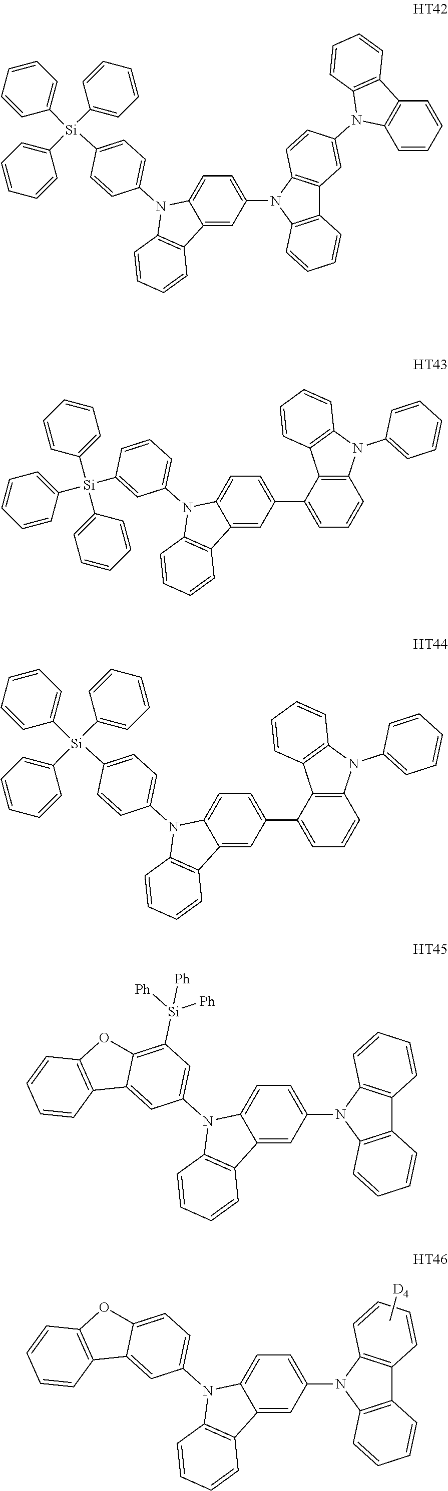

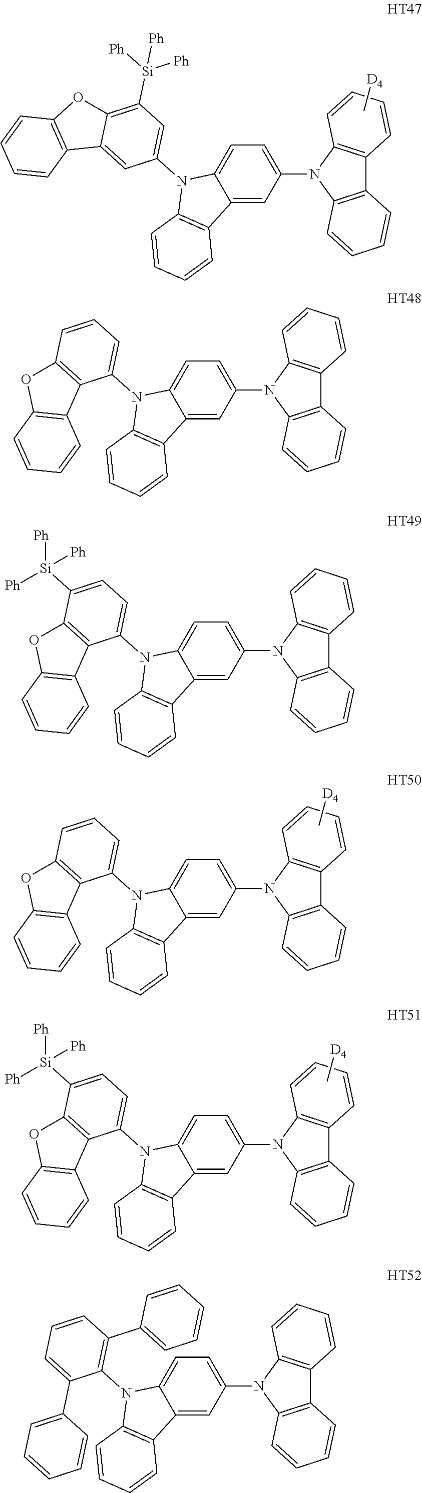

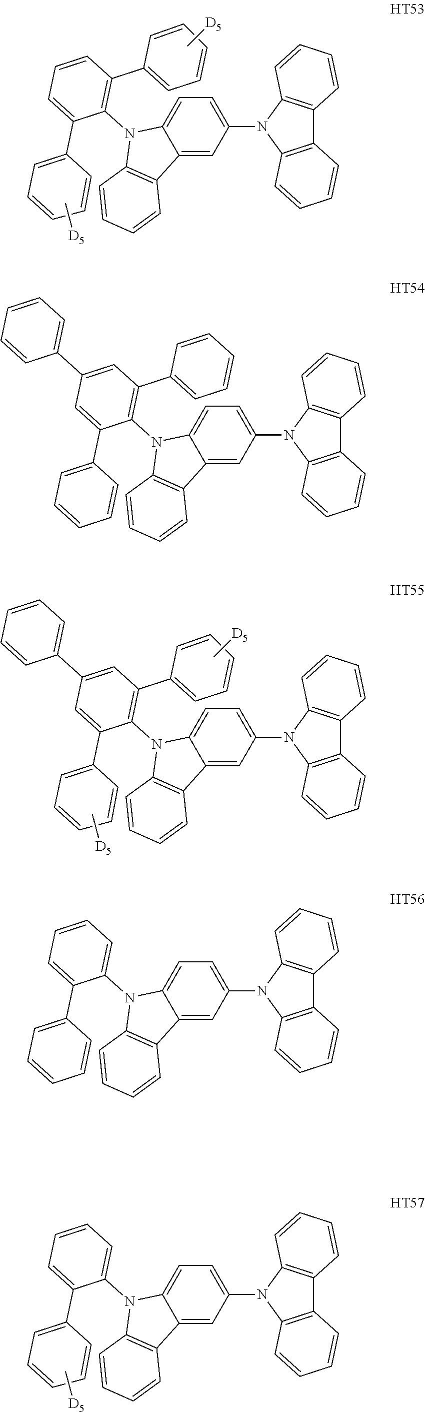

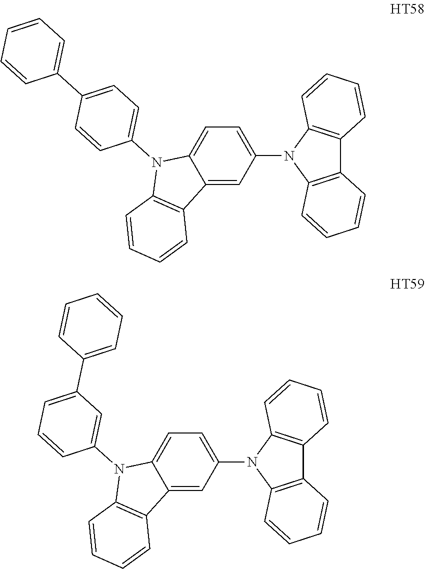 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In Compound Group 2, “D” represents a deuterium atom, and “Ph” represents a substituted or unsubstituted phenyl group. For example, in an embodiment, in the compounds presented in Compound Group 2, “Ph” represents an unsubstituted phenyl group.

In an embodiment, the emission layer EML may include the third compound represented by Formula ET-1. For example, the third compound may be used as an electron transport host material for the emission layer EML.

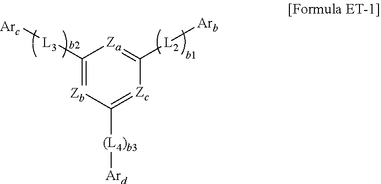

In an embodiment, in Formula ET-1, at least one of Zₐ to Z_{c} may be N, and the remainder of Zₐ to Z_{c} may each independently be C(Rₐ₆). For example, one of Zₐ to Z_{c} may be N, and the remainder of Zₐ to Z_{c} may each independently be C(Rₐ₆). Thus, the third compound represented by Formula ET-1 may include a pyridine moiety. In another embodiment, two of Zₐ to Z_{c} may be N, and the remainder of Zₐ to Z_{c} may each independently be C(Rₐ₆). Thus, the third compound represented by Formula ET-1 may include a pyrimidine moiety. In another embodiment, Zₐ to Z_{c} may all be N. Thus, the third compound represented by Formula ET-1 may include a triazine moiety.

In Formula ET-1, Rₐ₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar_{b} to Ar_{d} may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar_{b} to Ar_{d} may be each independently a substituted or unsubstituted phenyl group, or a substituted or unsubstituted carbazole group.

In Formula ET-1, L₂ to L₄ may be each independently a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are 2 or greater, multiples of each of L₂ to L₄ may be each independently a substituted or unsubstituted arylene group having 6 to 30 ring-forming carbon atoms, or a substituted or unsubstituted heteroarylene group having 2 to 30 ring-forming carbon atoms.

In an embodiment, the third compound may be selected from Compound Group 3. The light emitting element ED according to an embodiment may include a compound selected from Compound Group 3.

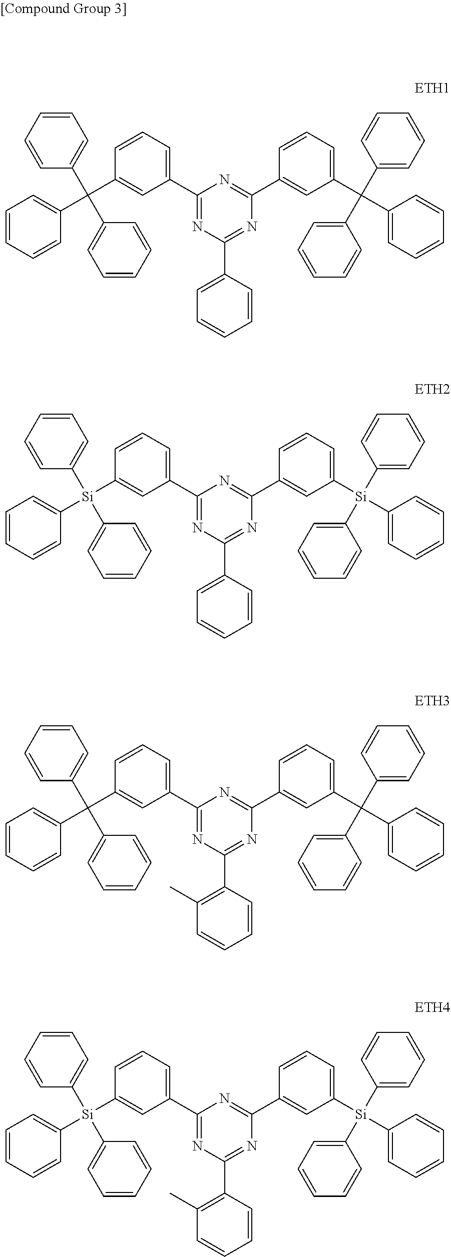 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

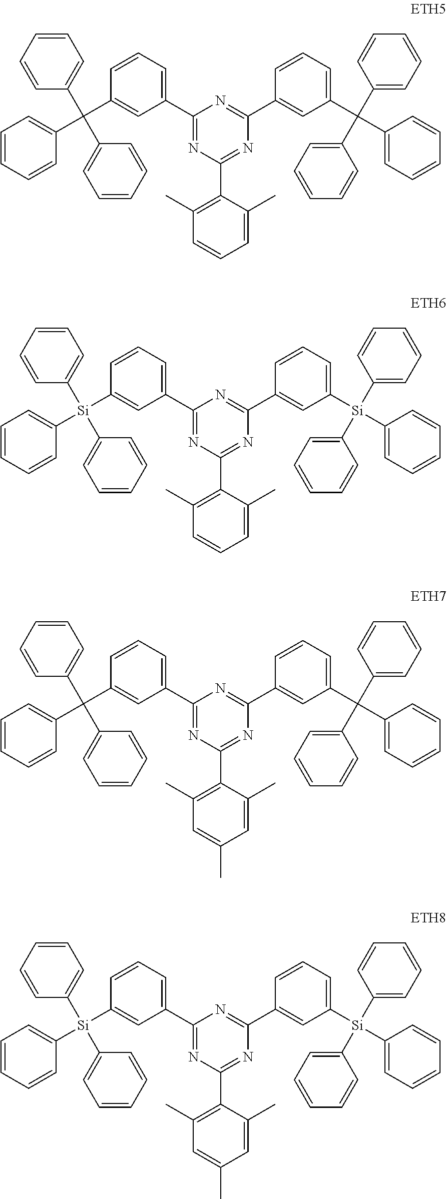 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

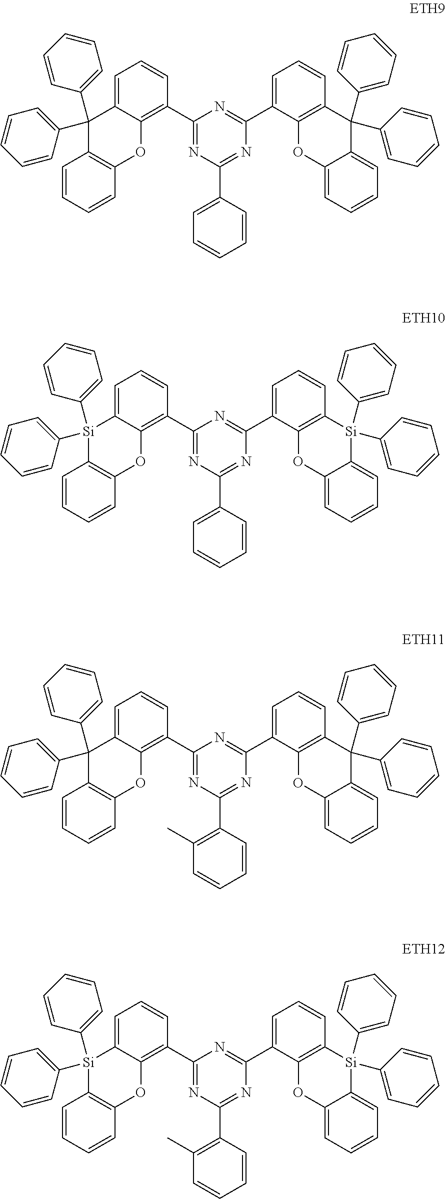 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

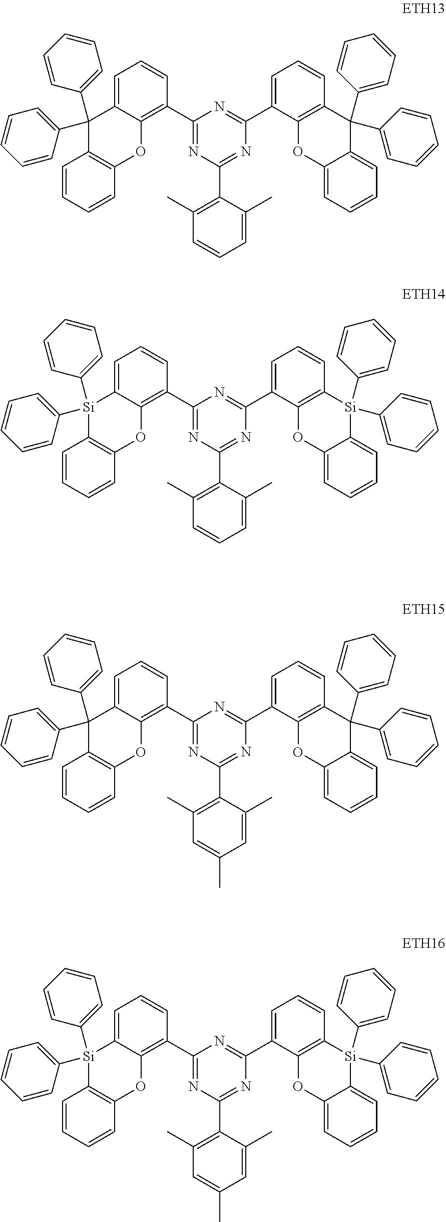 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

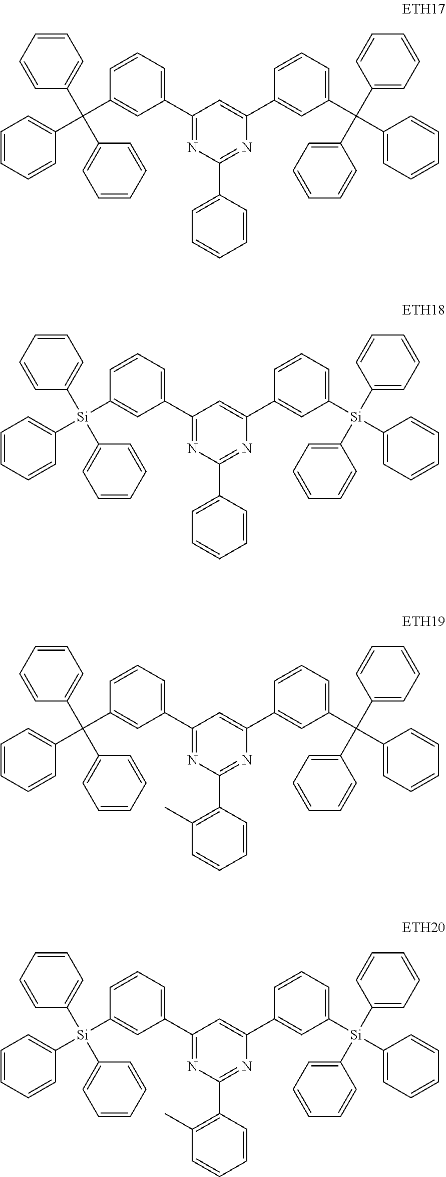 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

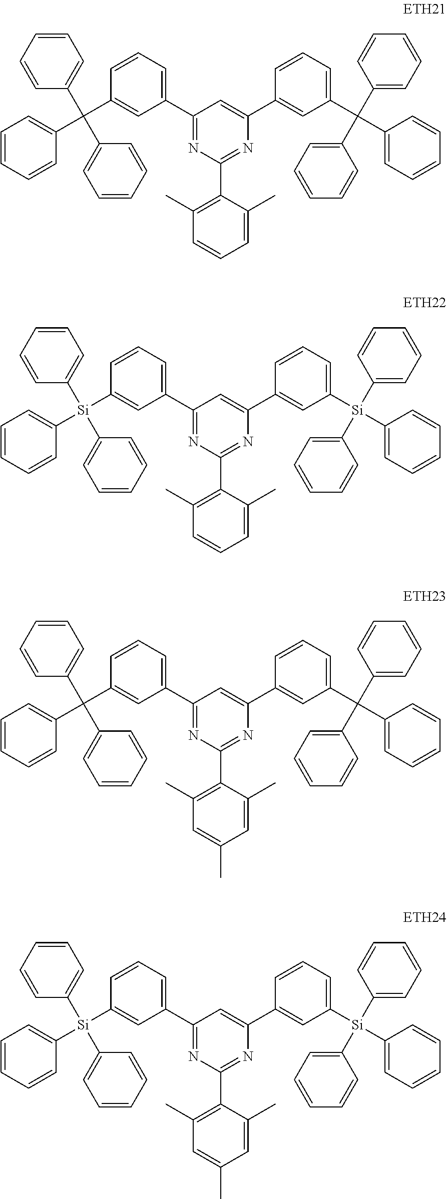 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

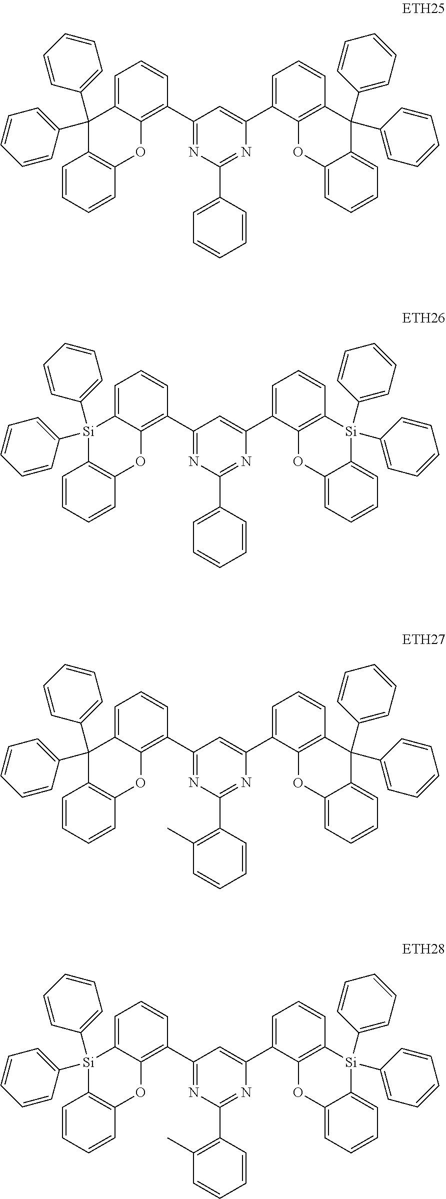 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

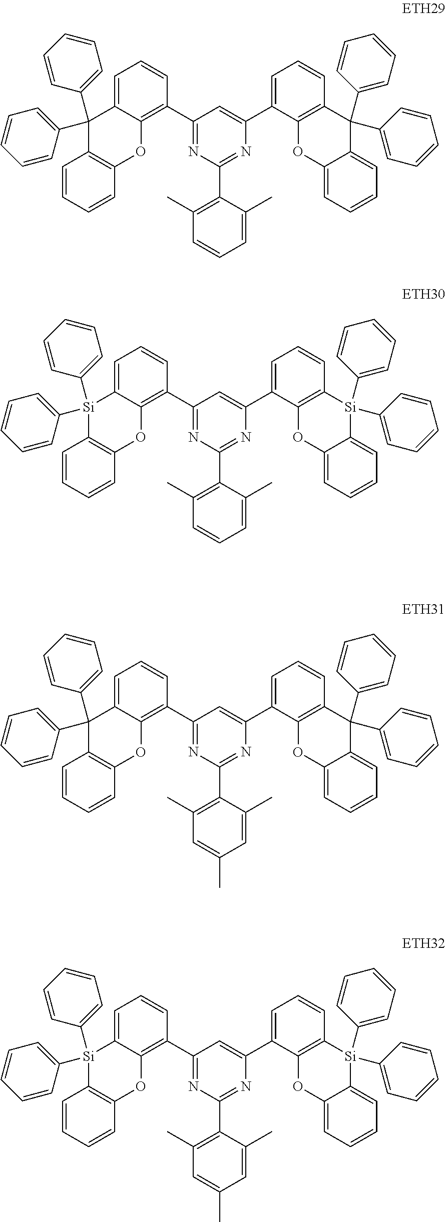 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

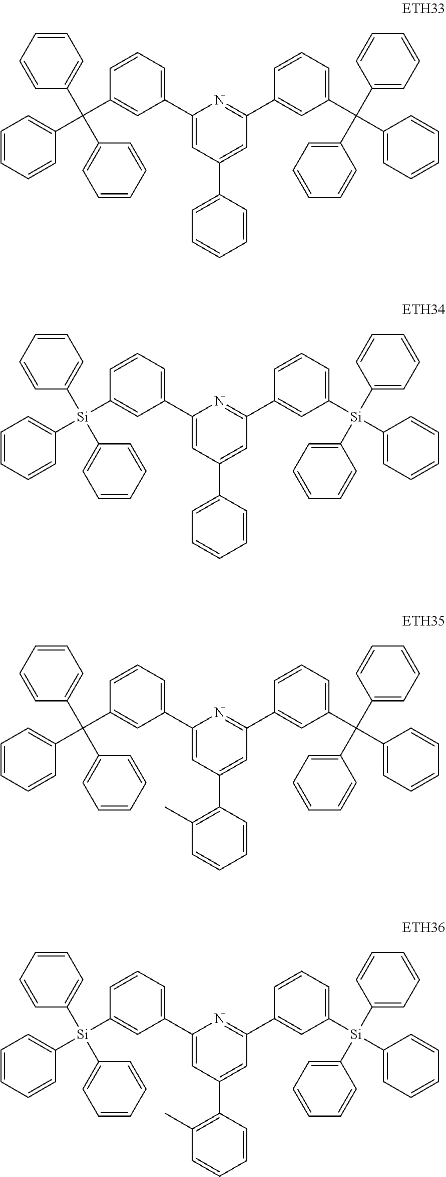 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

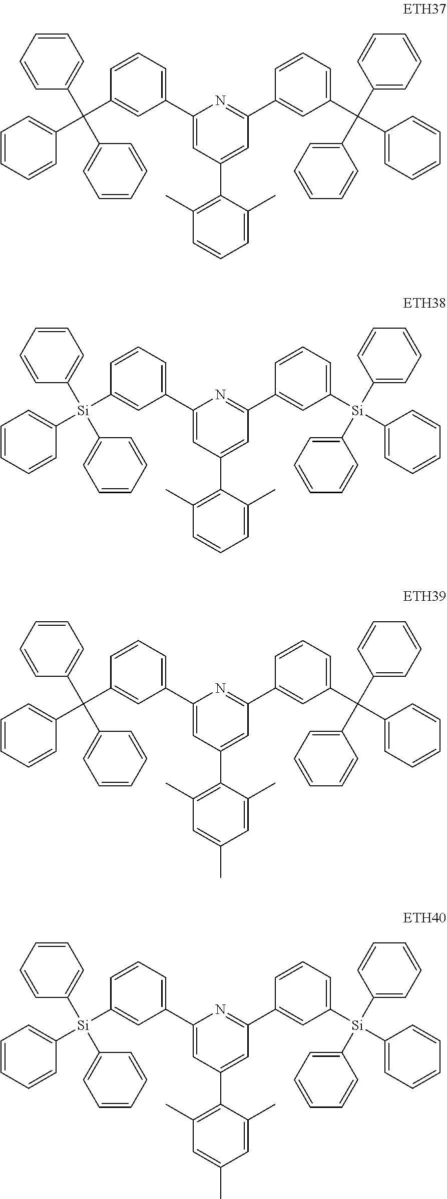 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

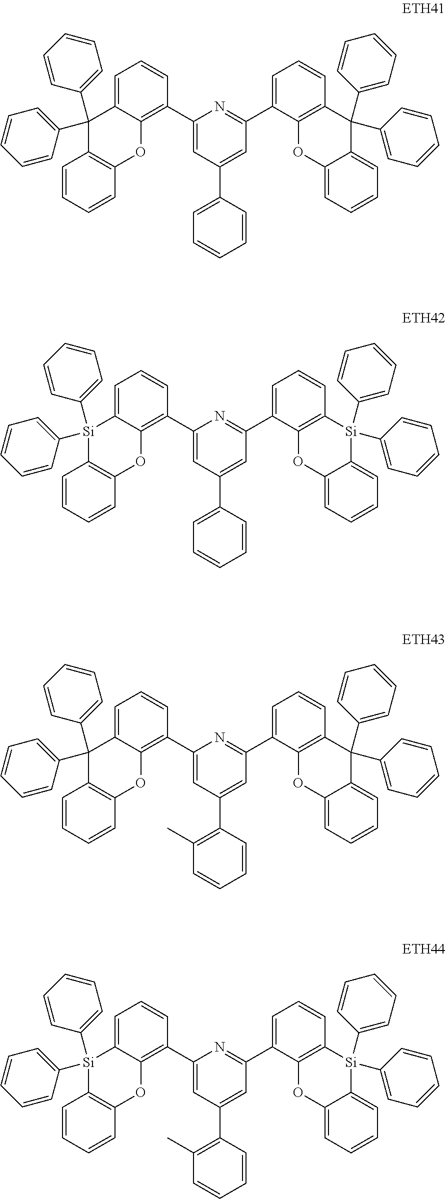 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

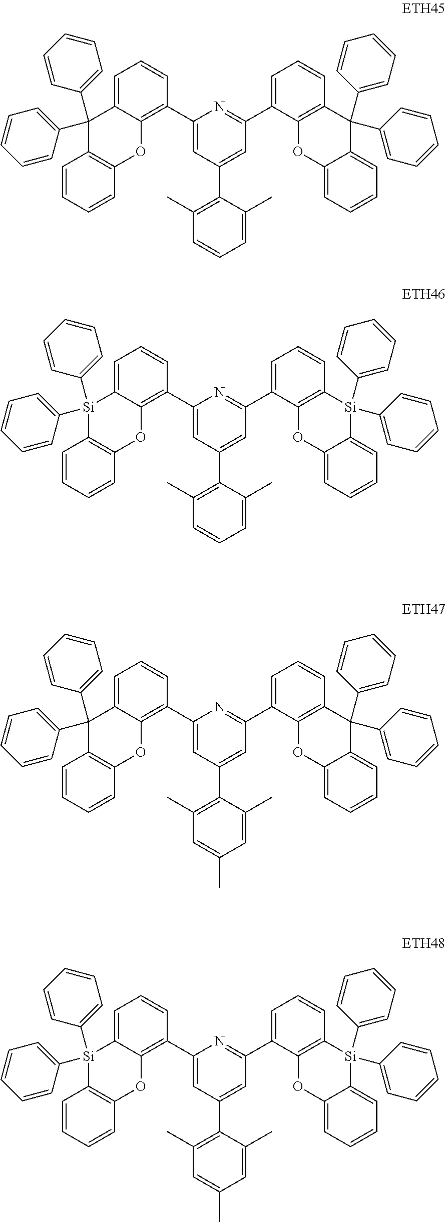 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

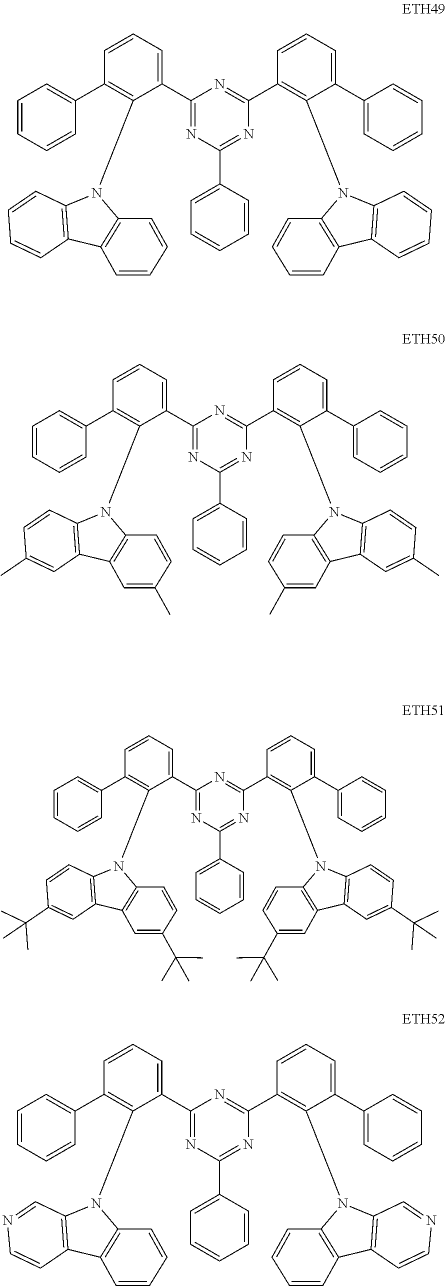

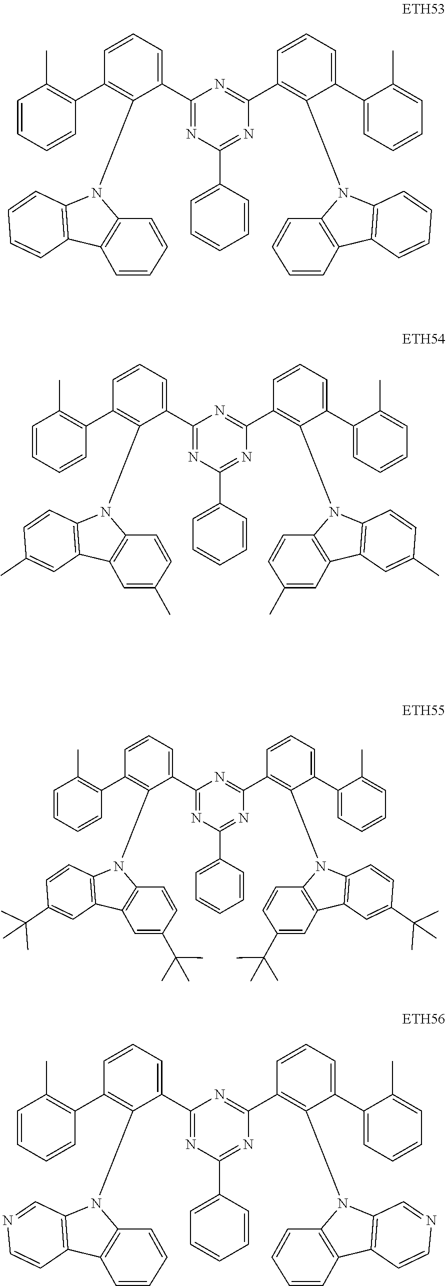

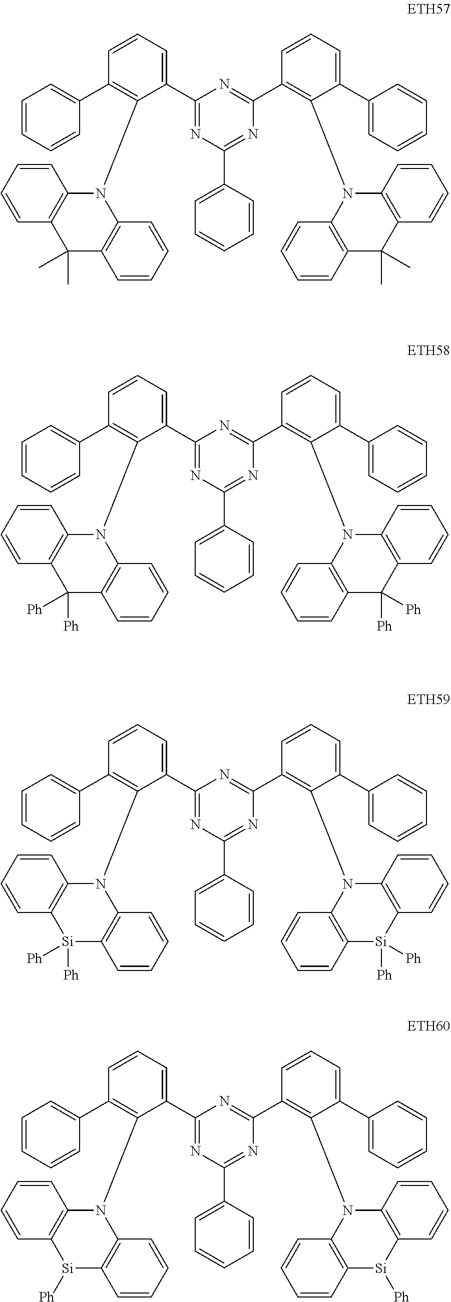

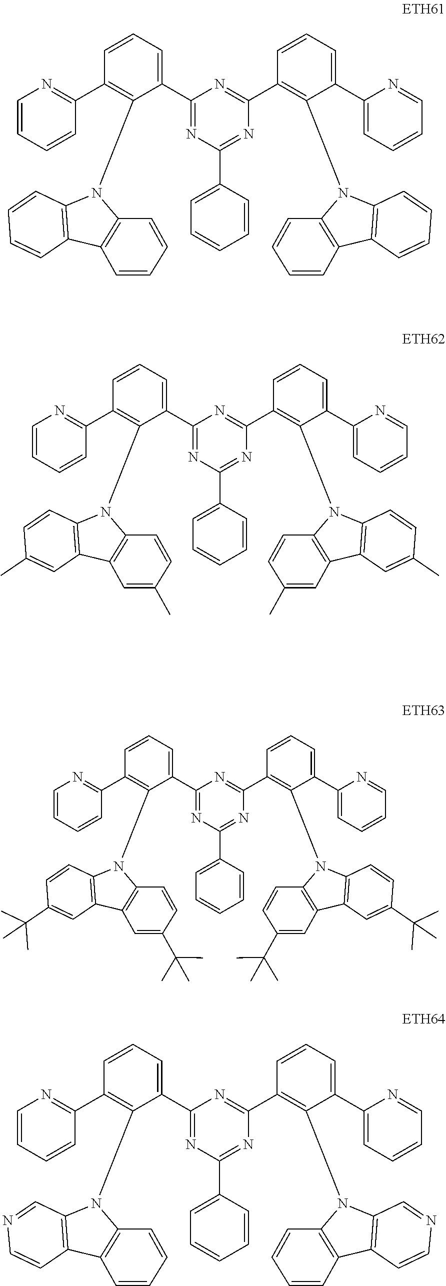

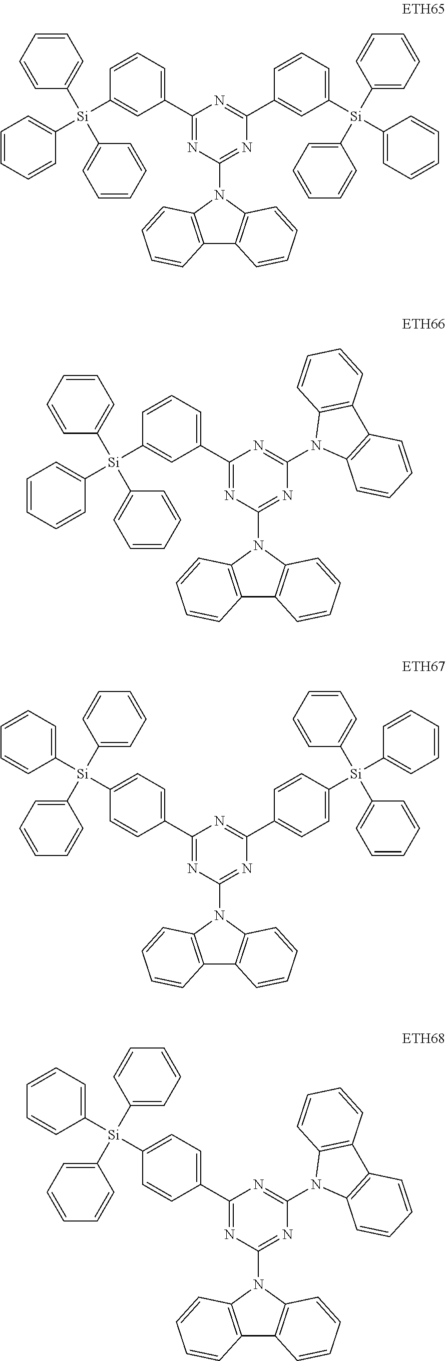 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

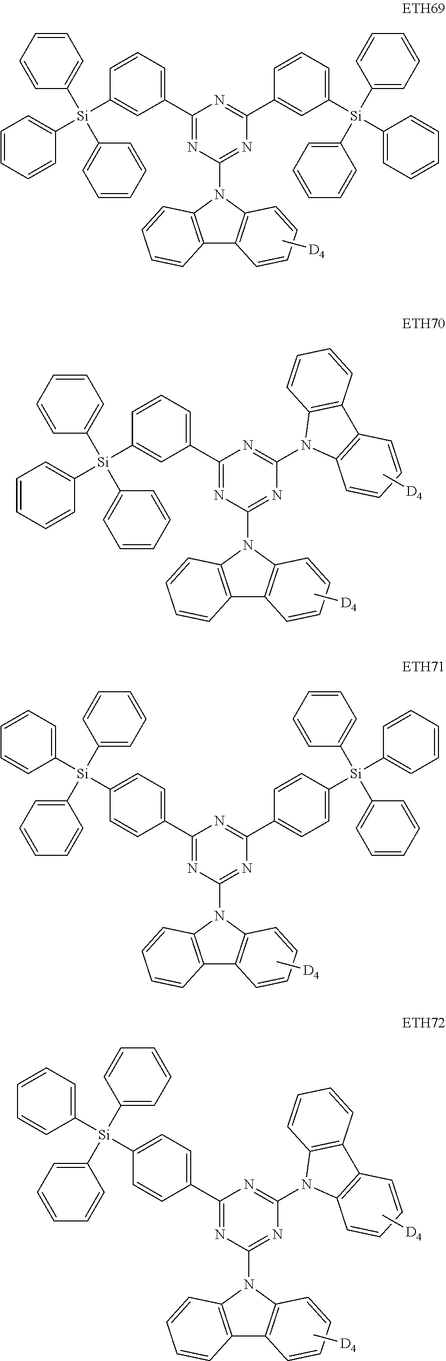

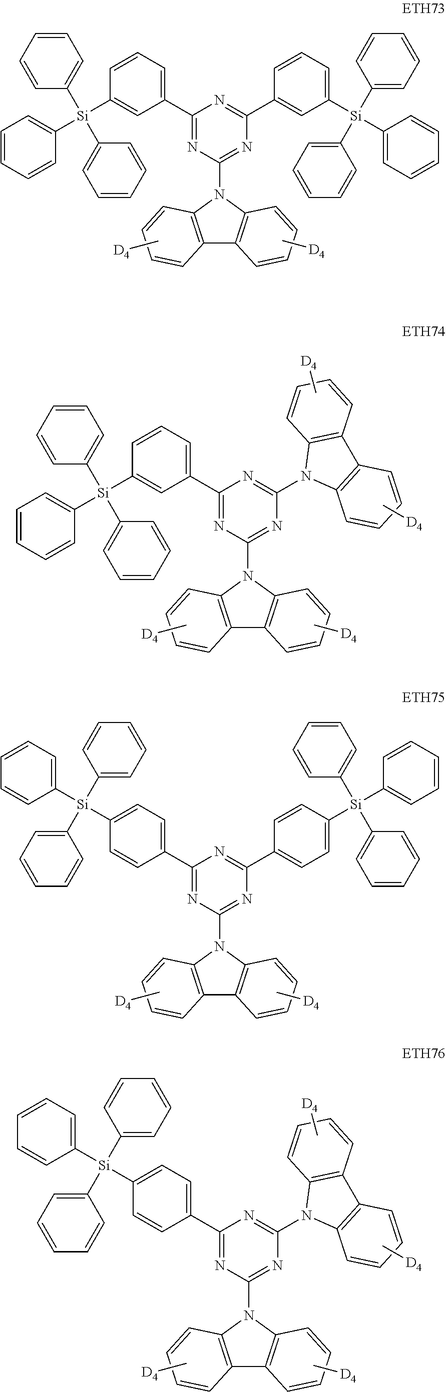

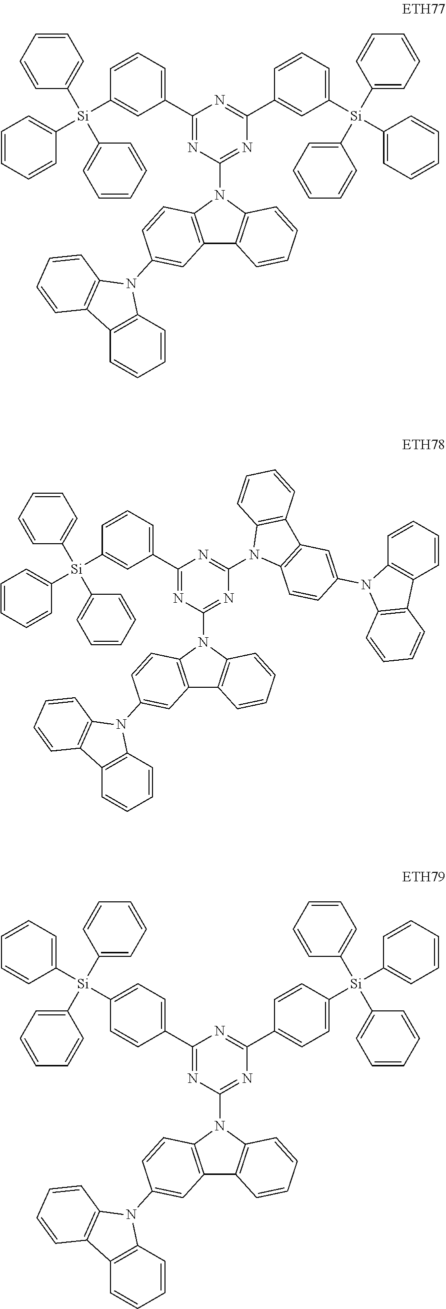 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

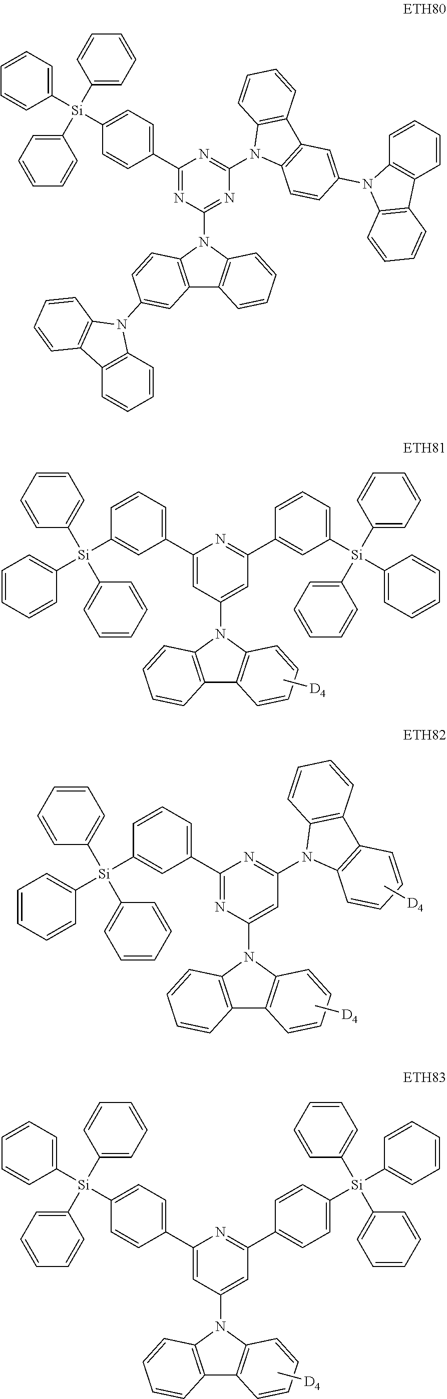

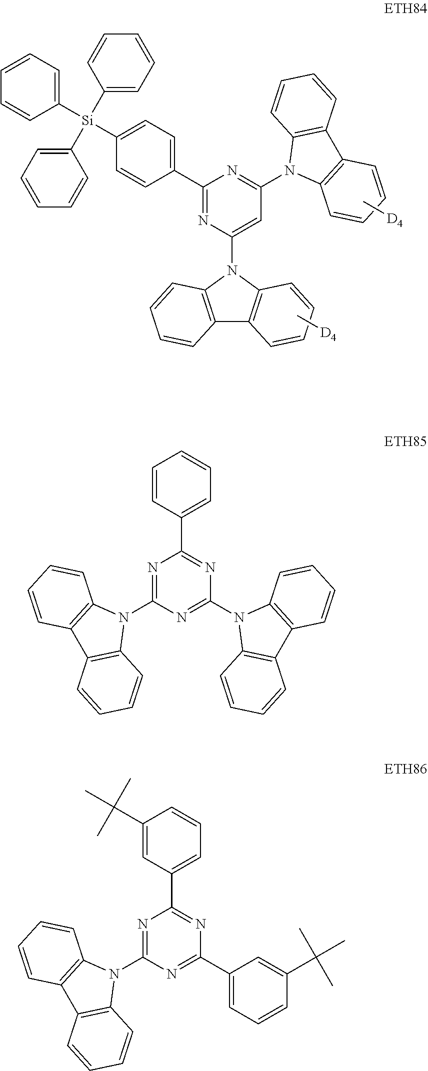

In Compound Group 3, “D” represents a deuterium atom and “Ph” represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy (T1) of the exciplex formed by the hole transporting host and the electron transporting host may be in a range of about 2.4 eV to about 3.0 eV. The triplet energy level of the exciplex may be a value that is smaller than an energy gap of each host material. The exciplex may have a triplet energy level less than or equal to about 3.0 eV which is an energy gap between the hole transporting host and the electron transporting host.

In an embodiment, the emission layer EML may include a fourth compound in addition to the first compound, the second compound, and the third compound as described above. The fourth compound may be used as a phosphorescent sensitizer in an emission layer EML. The energy may be transferred from the fourth compound to the first compound, thereby emitting light.

In an embodiment, the emission layer EML may further include, as the fourth compound, an organometallic complex that includes platinum (Pt) as a central metal atom and ligands linked to the central metal atom. In an embodiment, the emission layer EML in the light emitting element ED may include, as the fourth compound, a compound represented by Formula D-1:

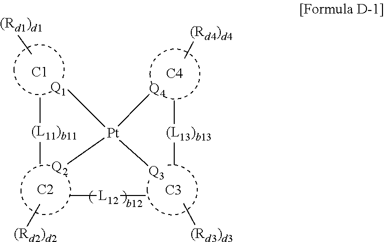

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage,

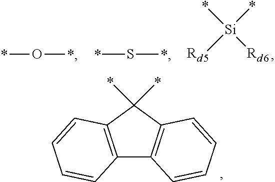

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” represents a bond to one of C1 to C4.

In Formula D-1, b11 to b13 may each independently be 0 or 1. If b11 is 0, C1 and C2 may not be directly bonded to each other. If b12 is 0, C2 and C3 may not be directly bonded to each other. If b13 is 0, C3 and C4 may not be directly bonded to each other.

In Formula D-1, R_{d1} to R_{d6} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group, or a substituted or unsubstituted t-butyl group.

In Formula D-1, d1 to d4 may each independently be an integer from 0 to 4. If d1 to d4 are each 0, the fourth compound may not be substituted with each of R_{d1} to R_{d4}. A case where d1 to d4 are each 4 and four groups of each of R_{d1} to R_{d4} are all hydrogen atoms, may be the same as a case where d1 to d4 are each 0. When d1 to d4 are each 2 or more, multiple groups of each of R_{d1} to R_{d4} may all be the same, or at least one thereof may be different from the remainder.

In an embodiment, in Formula D-1, C1 to C4 may be each independently a substituted or unsubstituted hydrocarbon ring or a substituted or unsubstituted heterocycle that is represented by one of C-1 to C-4:

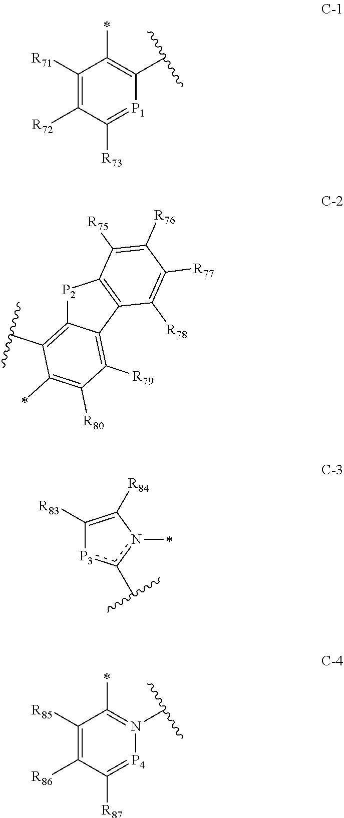

In Formula C-1 to Formula C-4, P₁ may be [symbol] or C(R₇₄), P₂ may be [symbol] or N(R₈₁), P₃ may be [symbol] or N(R₈₂), and P₄ may be or [symbol] or C(R₈₈). In Formula C-1 to Formula C-4, R₇₁ to R₈₈ may be each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4, “ [symbol] ” represents a bond to Pt that is a central metal atom, and “ [symbol] ” represents a bond to a neighboring cyclic group (C1 to C4) or to a linking moiety (L₁₁ to L₁₃).

In an embodiment, the emission layer EML may include the first compound, which is a polycyclic compound, and at least one of the second, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound form an exciplex, and energy may be transferred from the exciplex to the fourth compound and to the first compound to emit light. In an embodiment, the fourth compound may be a sensitizer. In the light emitting element ED, the fourth compound included in the emission layer EML may serve as a sensitizer to transfer energy from the host to the first compound, which may be a light emitting dopant. For example, the fourth compound serving as an auxiliary dopant may accelerate the energy transfer to the first compound serving as the light emitting dopant, thereby increasing a light emitting ratio of the first compound. Accordingly, the emission layer EML may have increased luminous efficiency. When the energy transfer to the first compound is increased, excitons formed in the emission layer EML do not accumulate in the emission layer EML and emit light quickly, resulting in less deterioration of a light emitting element ED. Accordingly, the light emitting element ED of an embodiment may have increased lifespan.

In an embodiment, the light emitting element ED may include all of a first compound, a second compound, a third compound, and a fourth compound, and the emission layer EML may thus include a combination of two host materials and two dopant materials. In the light emitting element ED, the emission layer EML may include the second compound and the third compound that are two different hosts, the first compound emitting delayed fluorescence, and the fourth compound containing an organometallic complex, and may thus exhibit excellent light emitting efficiency.

In an embodiment, the fourth compound represented by Formula D-1 may be selected from Compound Group 4. The emission layer EML may include at least one compound selected from Compound Group 4 as a sensitizer material.

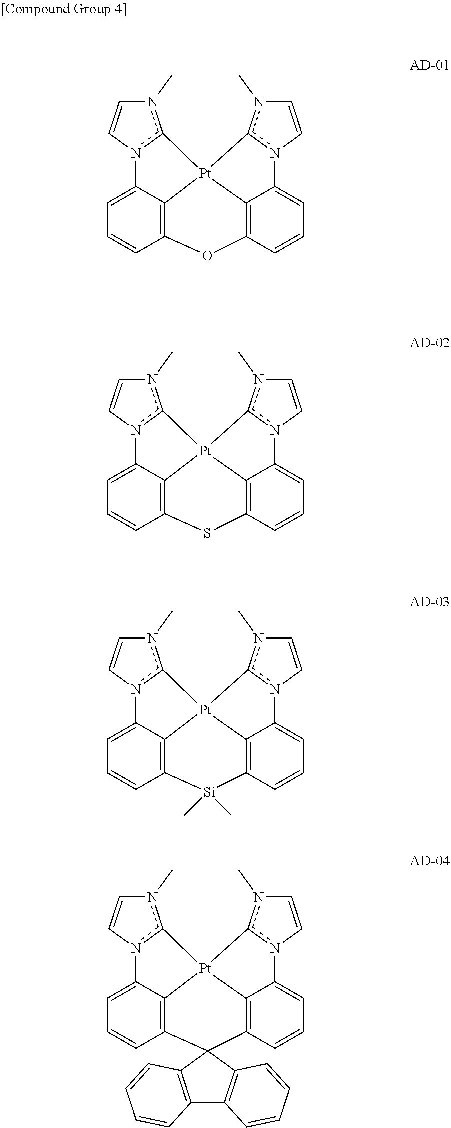

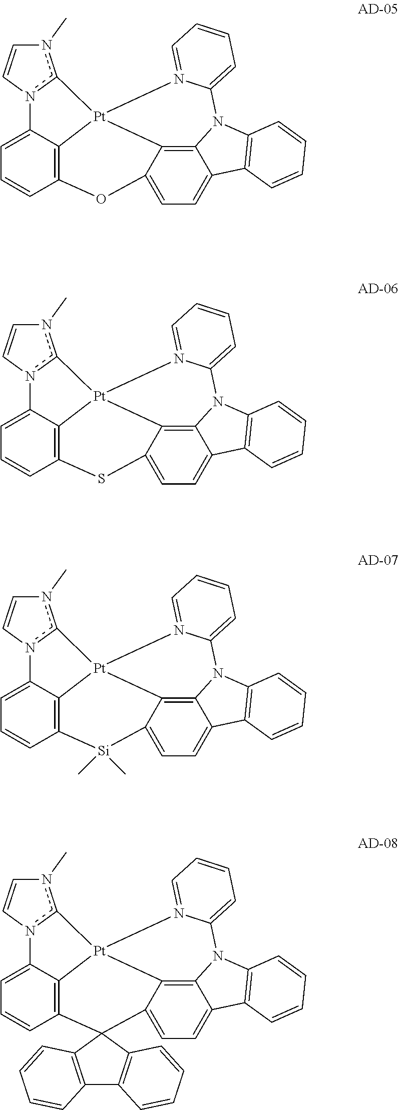

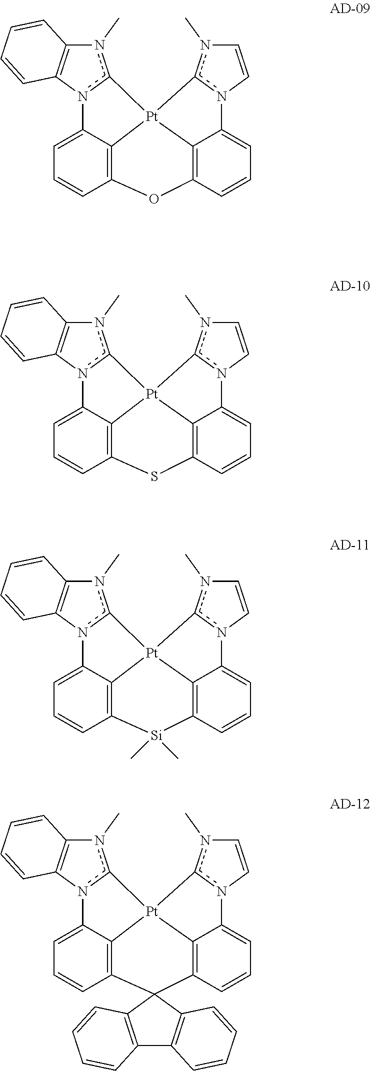

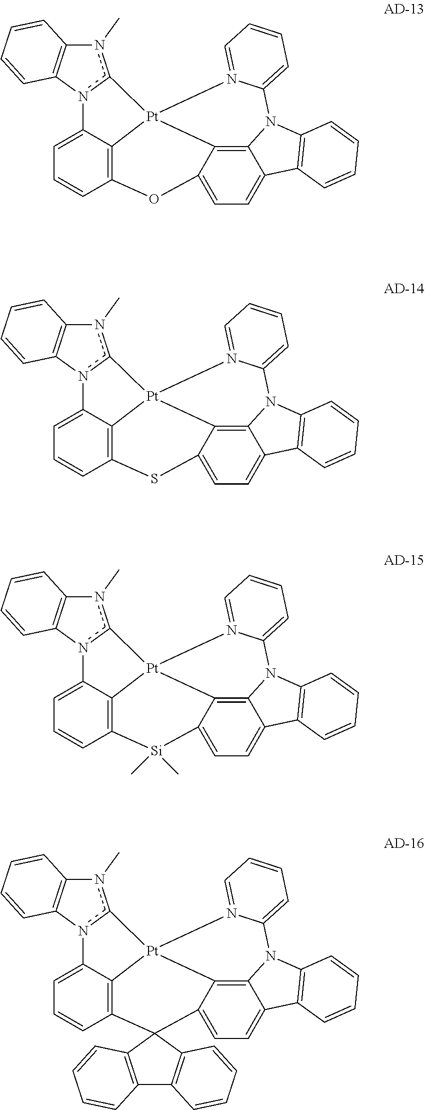

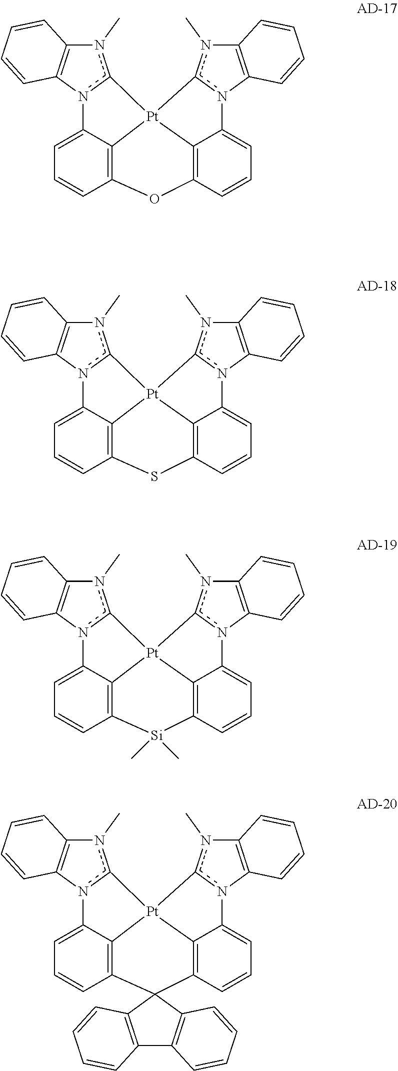

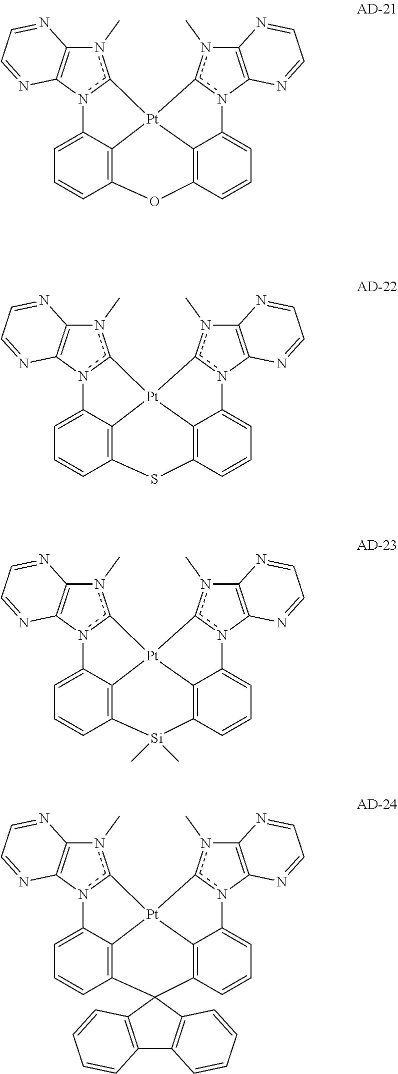

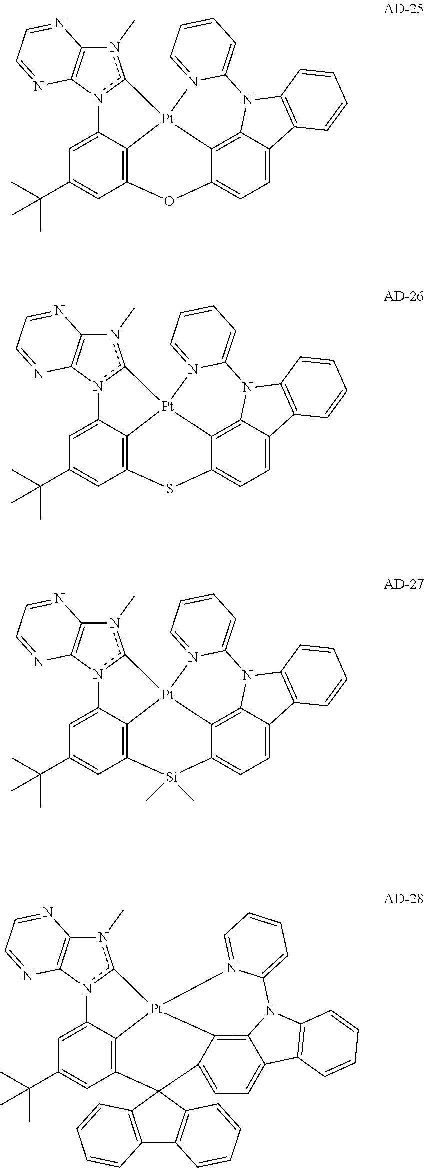

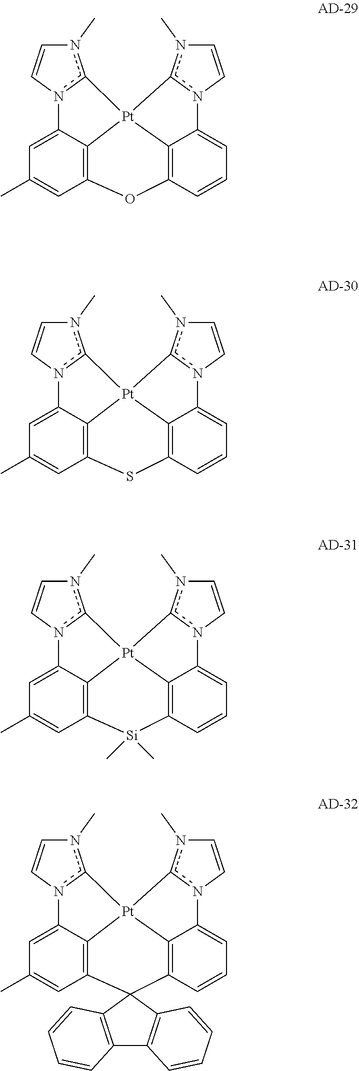

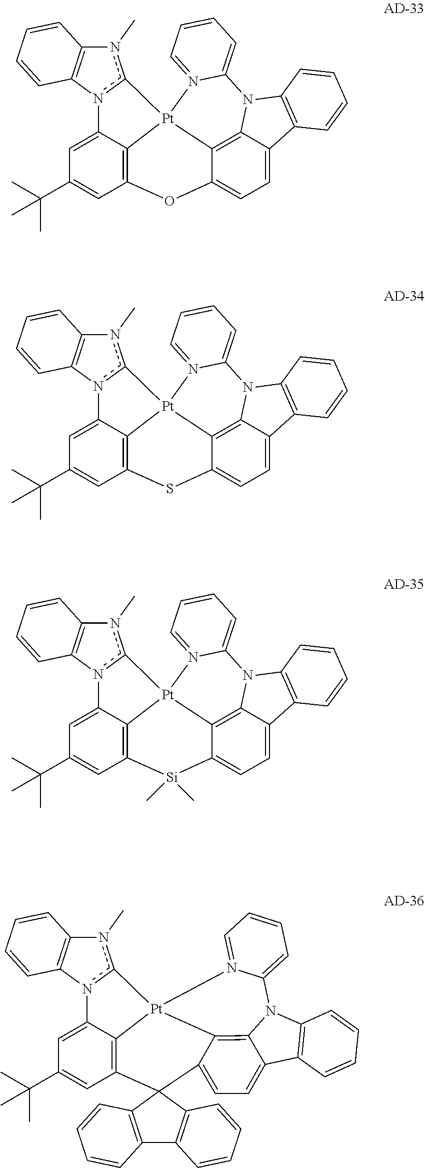

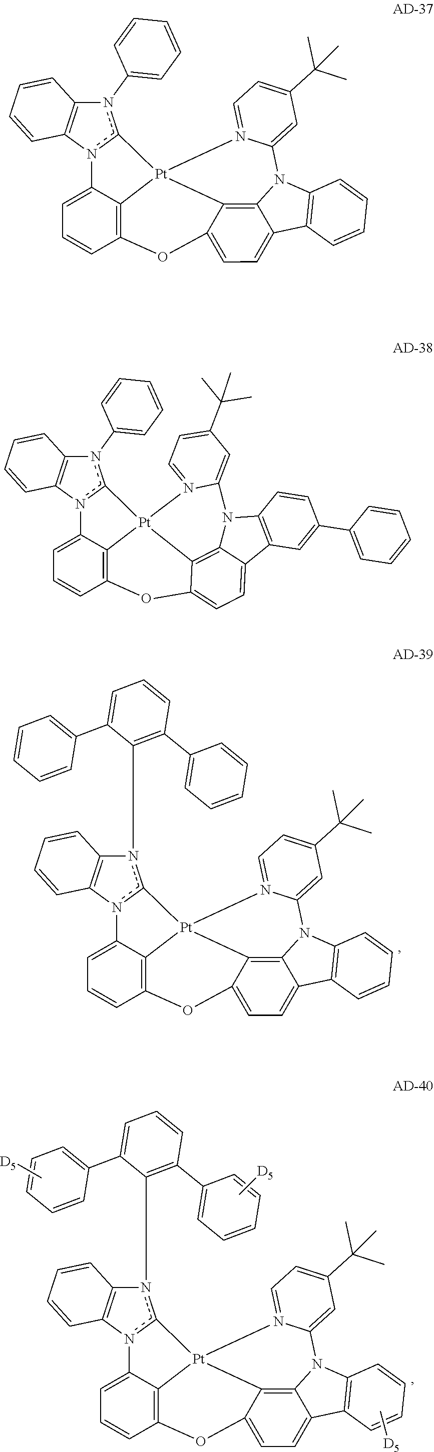

In Compound Group 4, “D” represents a deuterium atom.

In an embodiment, the light emitting element ED may include multiple emission layers. The multiple emission layers may be stacked between a first electrode and a second electrode, so that a light emitting element ED that includes multiple emission layers may emit white light. The light emitting element including multiple emission layers may be a light emitting element having a tandem structure. When the light emitting element ED includes multiple emission layers, at least one emission layer EML may include the first compound represented by Formula 1. When the light emitting element ED includes multiple emission layers, at least one emission layer EML may include the first compound, the second compound, the third compound, and the fourth compound as described above.

When the emission layer EML in the light emitting element ED includes the first compound, the second compound, and the third compound, with respect to a total weight of the first compound, the second compound, and the third compound, an amount of the first compound may be in a range of about 0.1 wt % to about 5 wt %. However, embodiments are not limited thereto. When an amount of the first compound satisfies the range described above, energy transfer from the second compound and the third compound to the first compound may increase, and thus the luminous efficiency and device service life may increase.

A total amount of the second compound and the third compound in the emission layer EML may be the remainder of the total weight of the first compound, the second compound, and the third compound, excluding the amount of the first compound. For example, a combined amount of the second compound and the third compound in the emission layer EML may be in a range of about 65 wt % to about 95 wt % with respect to a total weight of the first compound, the second compound, and the third compound.

Within the total combined amount of the second compound and the third compound, a weight ratio of the second compound to the third compound may be in a range of about 3:7 to about 7:3.

When the amounts of the second compound and the third compound satisfy the above-described ranges and ratios, a charge balance characteristic in the emission layer EML may be improved, and thus the luminous efficiency and device service life may increase. When the contents of the second compound and the third compound deviate from the above-described ratio range, a charge balance in the emission layer EML may not be achieved, and thus the luminous efficiency may be reduced and the device may readily deteriorate.

When the emission layer EML includes the fourth compound, the content of the fourth compound in the emission layer EML may be in a range of about 4 wt % to about 30 wt % with respect to a total weight of the first compound, the second compound, the third compound, and the fourth compound. However, embodiments are not limited thereto. When an amount of the fourth compound satisfies the above-described range, the energy delivery from the host to the first compound that is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described ranges and ratios, excellent luminous efficiency and long service life may be achieved.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In each light emitting element ED according to embodiments as shown in each of FIGS. 5 to 9, the emission layer EML may further include a host and dopant of the related art in addition to the above-described host and dopant, and for example the emission layer EML may include a compound represented by Formula E-1. The compound represented by Formula E-1 may be used as a fluorescent host material.

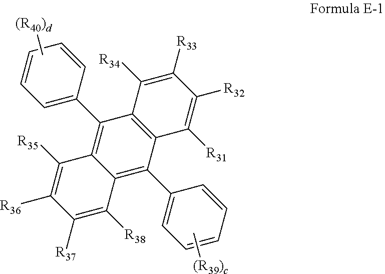

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

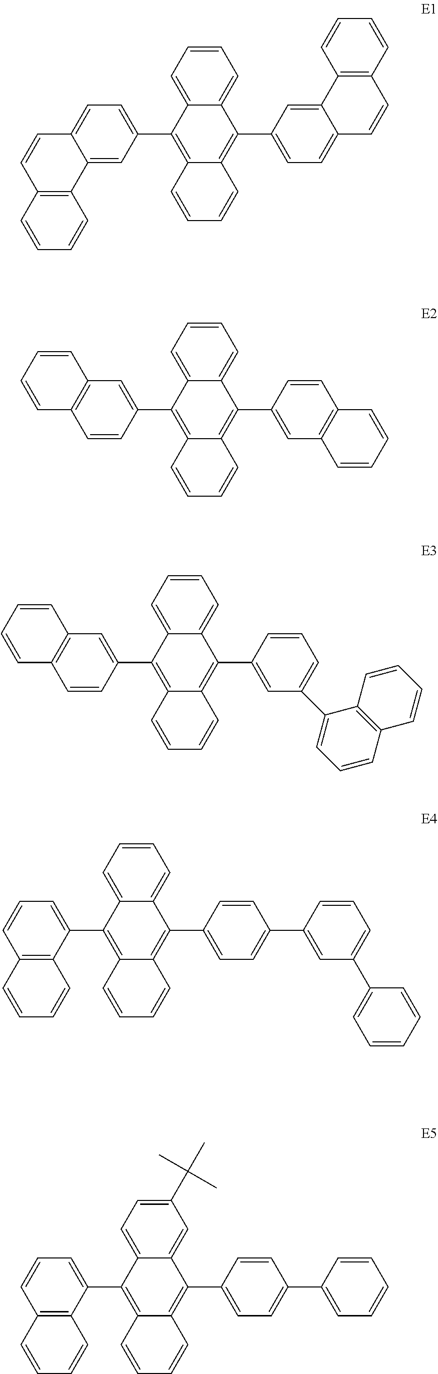

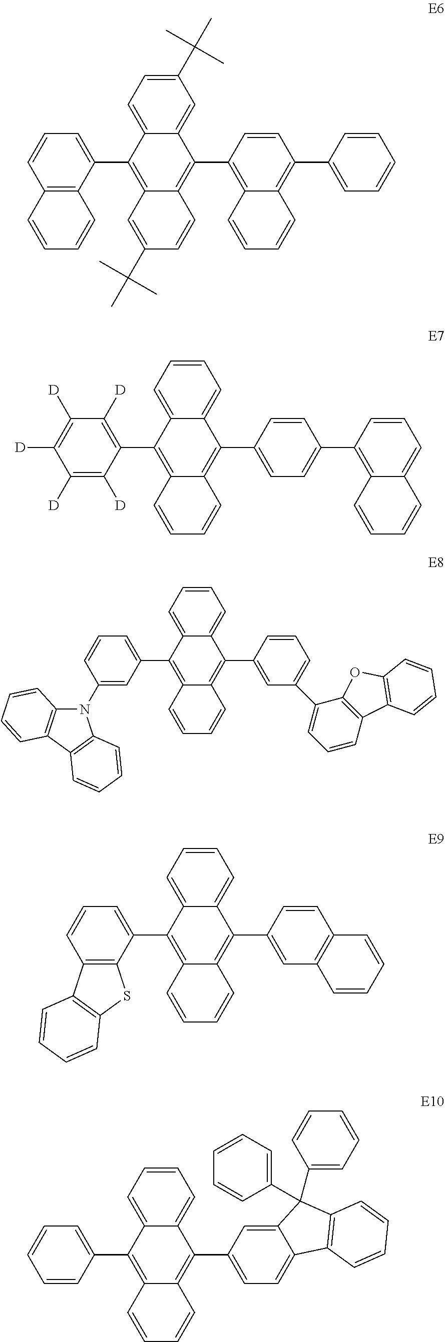

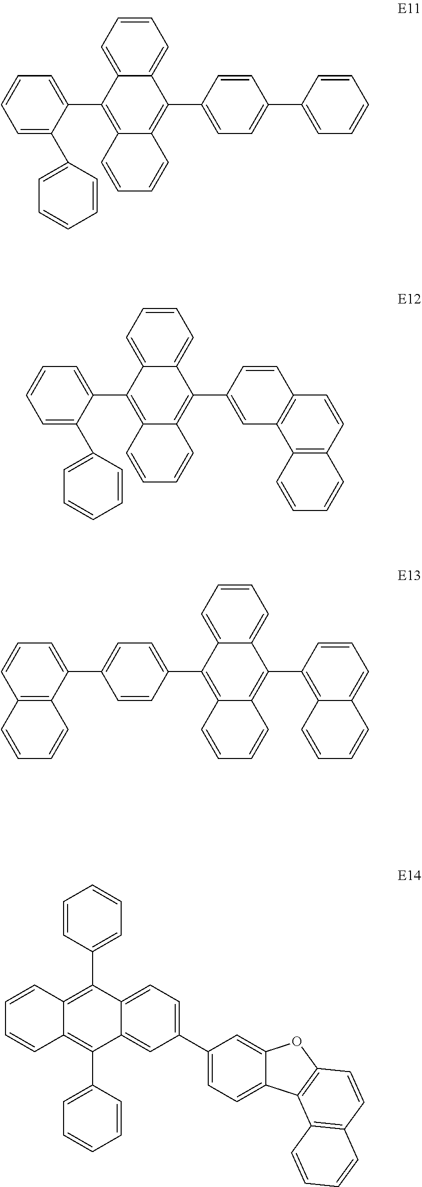

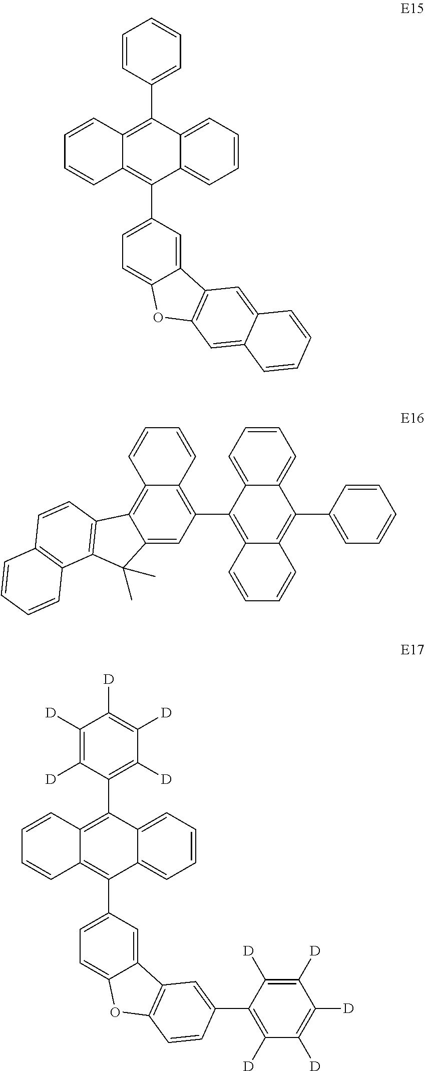

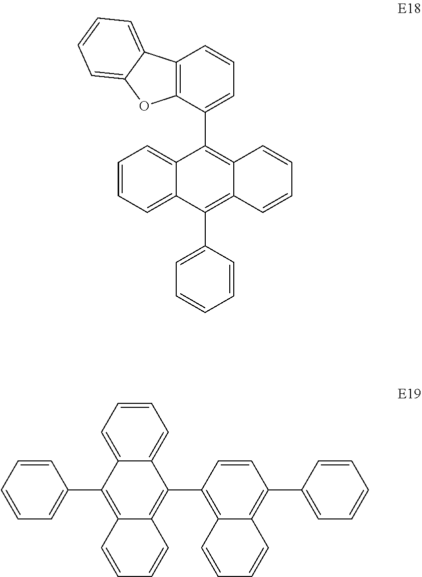

In an embodiment, the emission layer EML may include a compound represented by Formula E-2a or Formula E-2b. The compound represented by Formula E-2a or Formula E-2b may be used as a host material for a phosphorescent light emitting element.

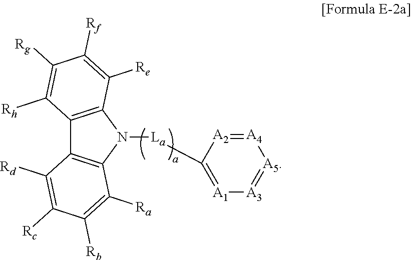

In Formula E-2a, a may be an integer from 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ may be each independently a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may be N, and the remainder of A₁ to A₅ may each independently be C(Rᵢ).

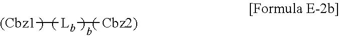

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple L_{b} may be each independently a substituted or unsubstituted arylene group having 6 to 30 ring-forming carbon atoms, or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 below are only examples, and the compound represented by Formula E-2a or Formula E-2b is not limited to Compound Group E-2.

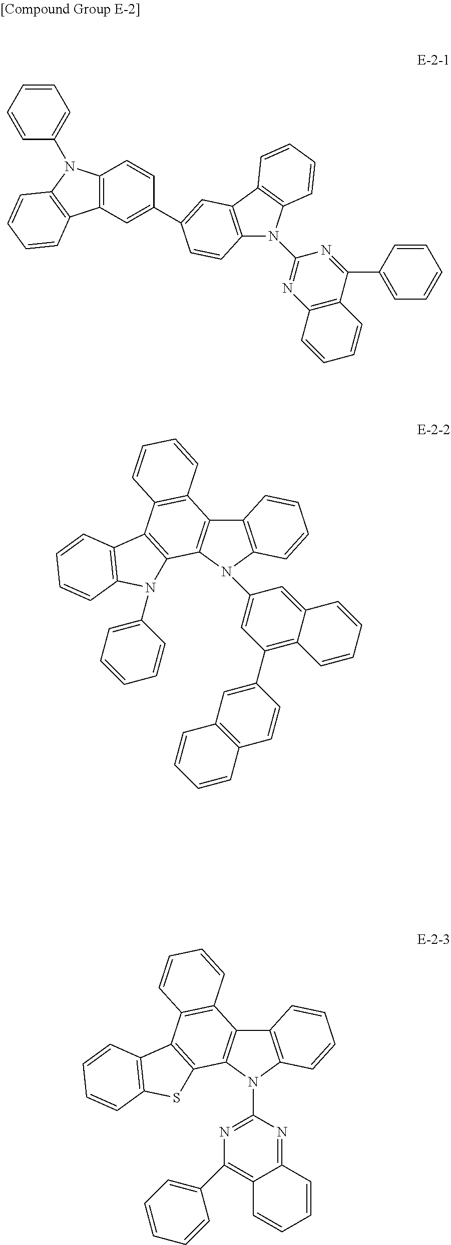 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5cc(-c6ccc7ccccc7c6)c6ccccc6c5)c4c32)cc1 ; c1ccc(-c2nc(-n3c4ccccc4c4c5ccccc5c5c6ccccc6sc5c43)nc3ccccc23)cc1]

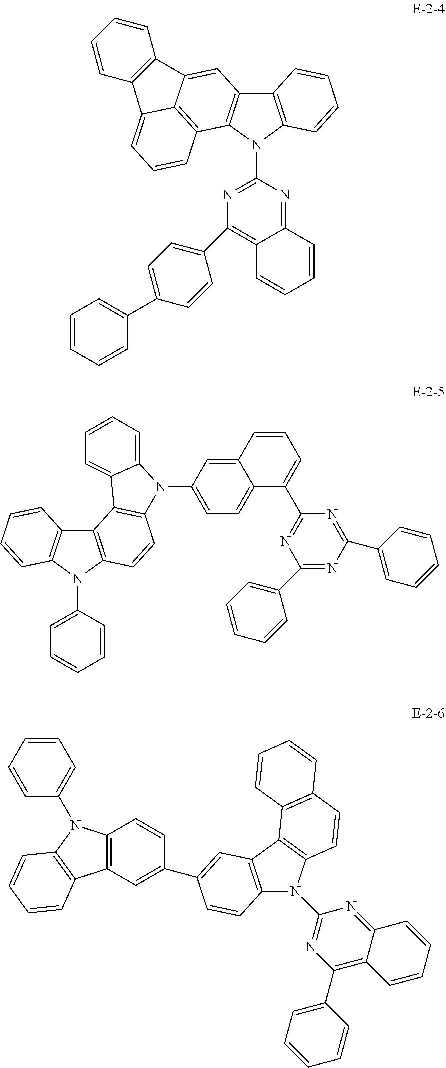 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

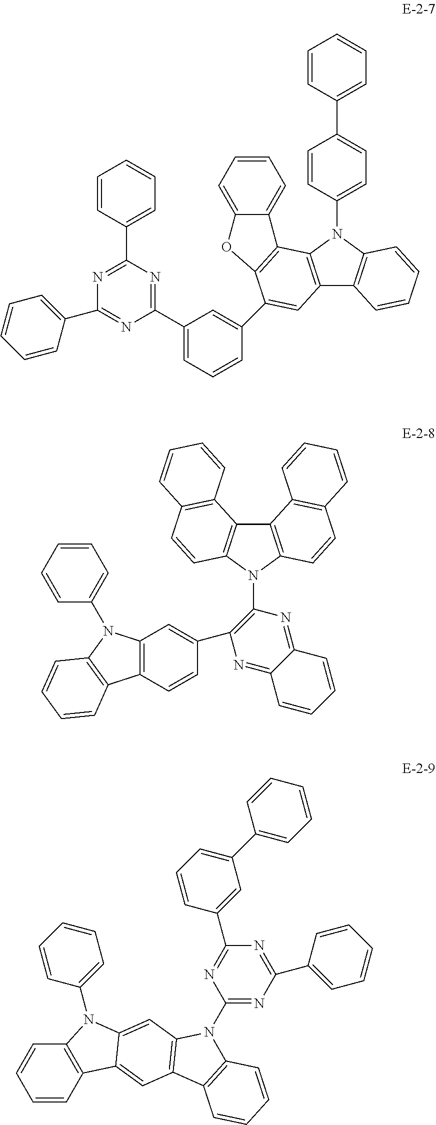 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

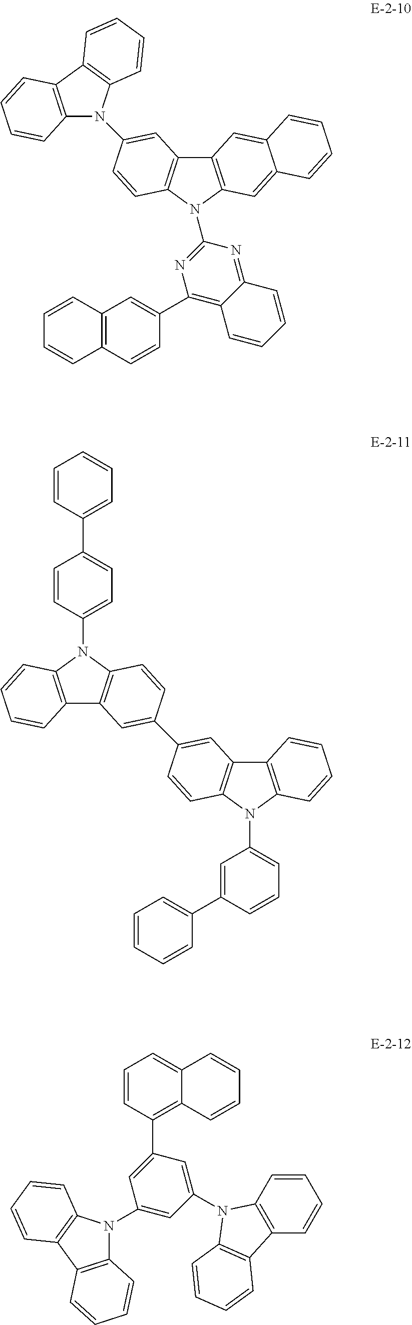 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

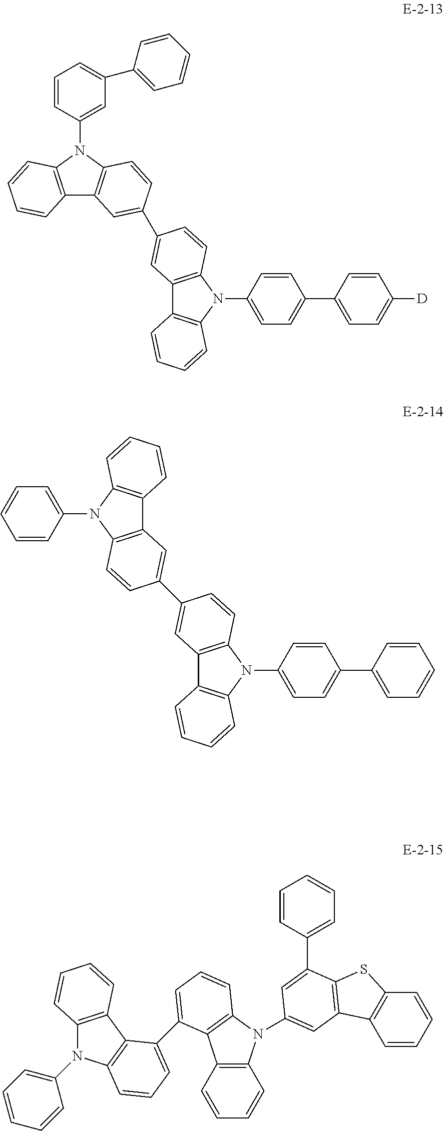 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

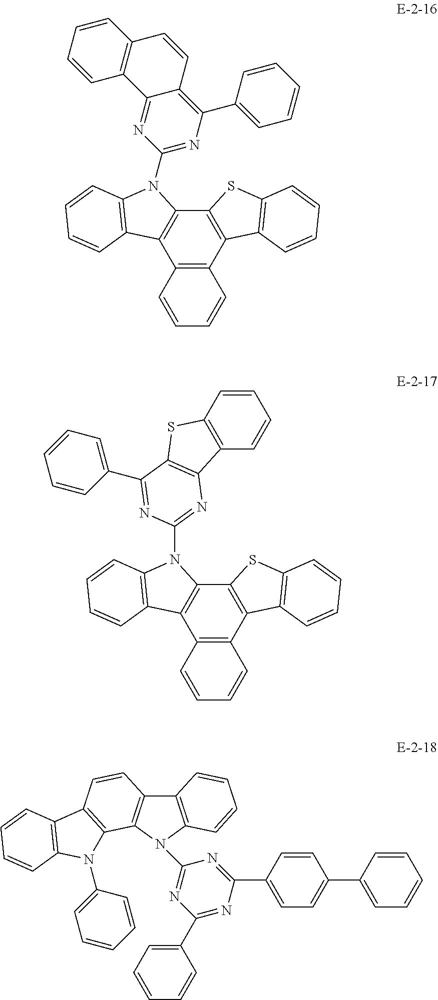 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

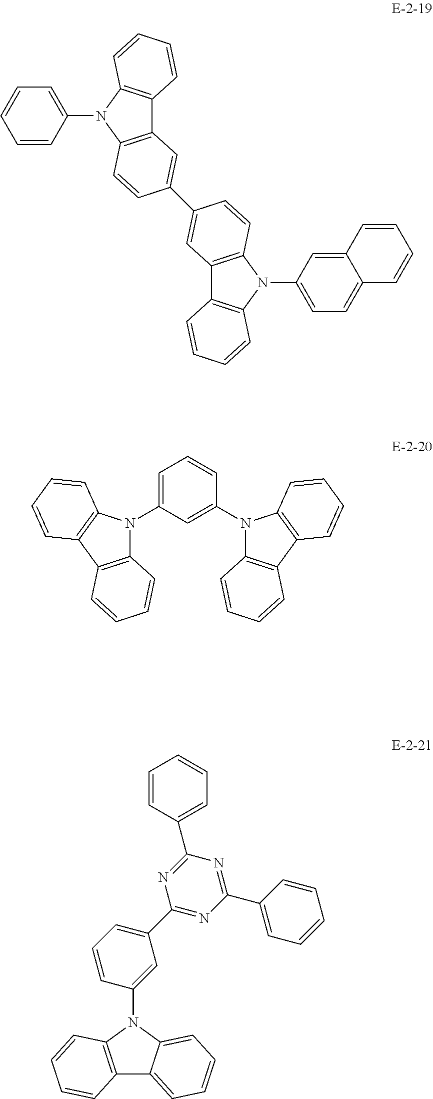 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

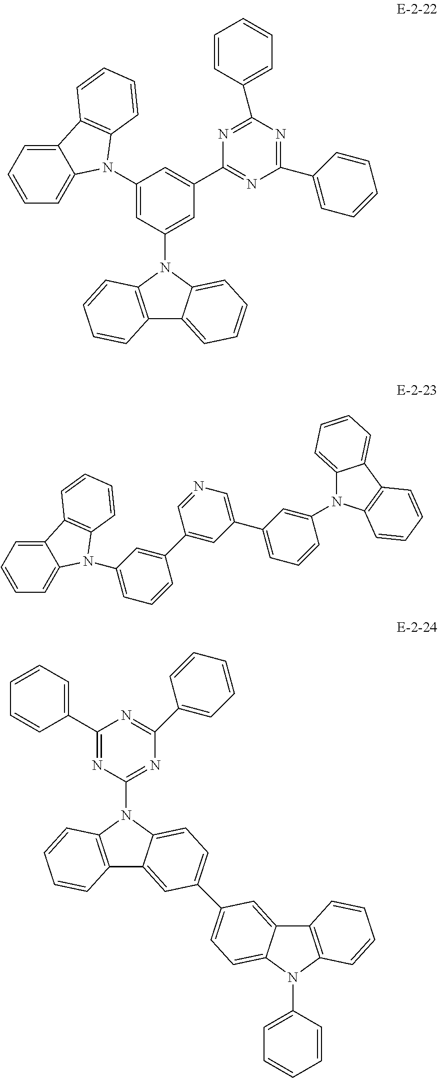 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In an embodiment, the emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include the compound represented by Formula M-a. The compound represented by Formula M-a may be used as a phosphorescent dopant material.

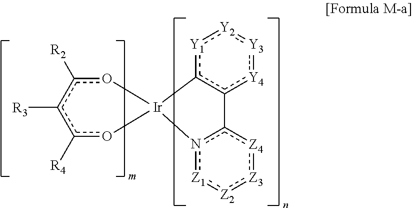

In Formula M-a above, Y₁ to Y₄ and Z₁ to Z₄ may each independently be C(R₁) or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

In an embodiment, the compound represented by Formula M-a may be any compound selected from Compound M-a1 to Compound M-a25. However, Compounds M-a1 to M-a25 are only examples, and the compound represented by Formula M-a is not limited to those Compounds M-a1 to M-a25.

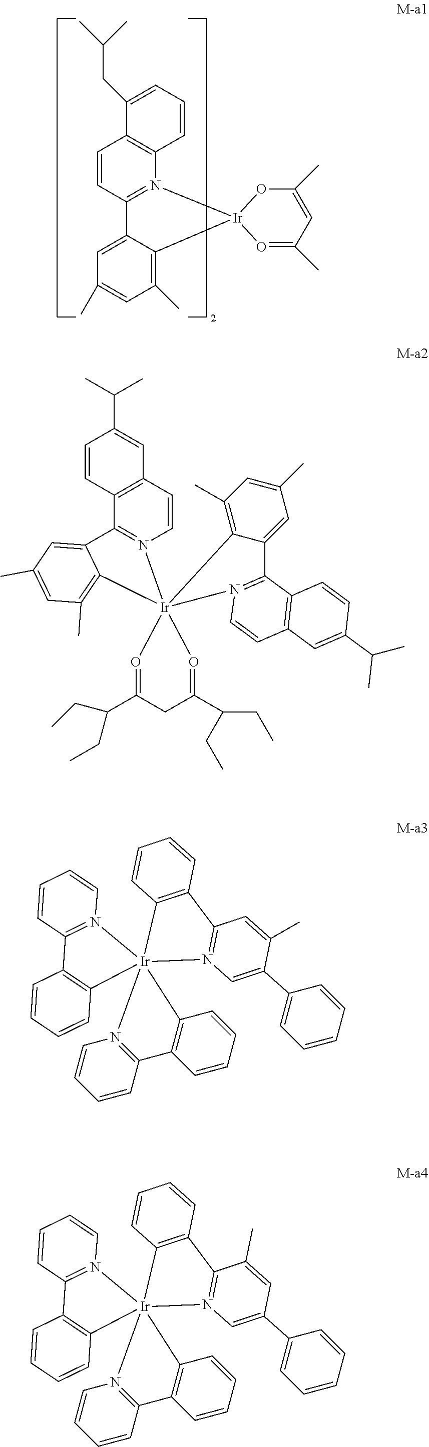

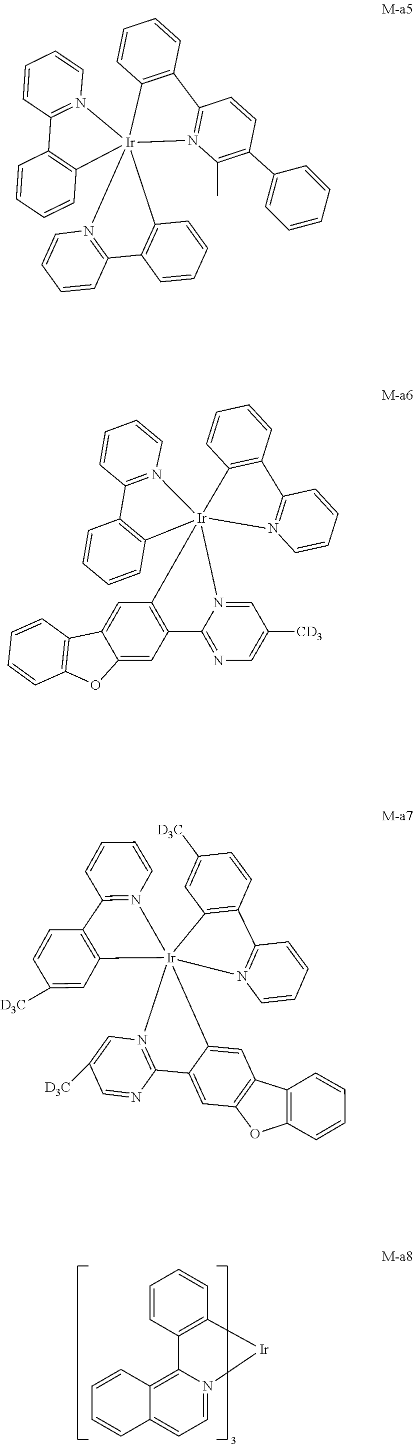

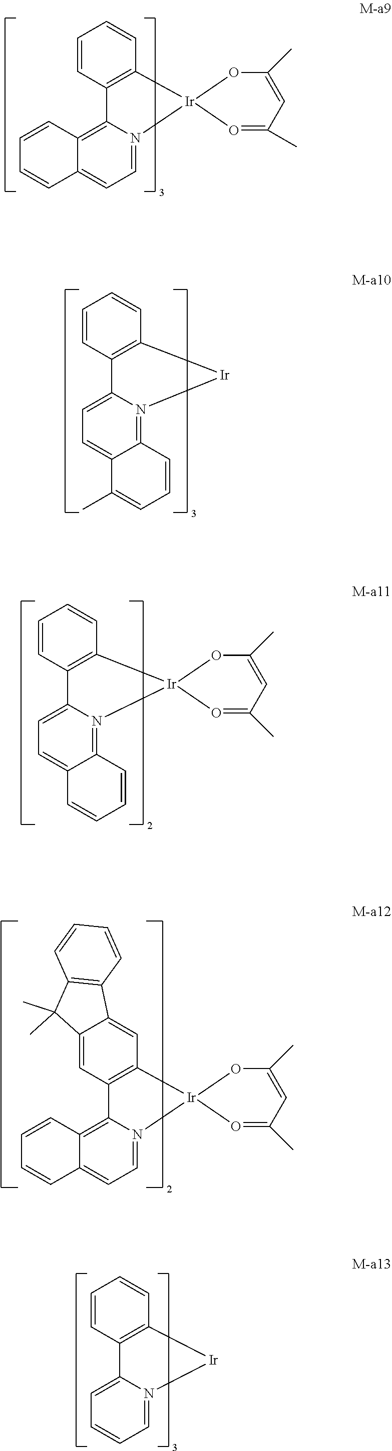

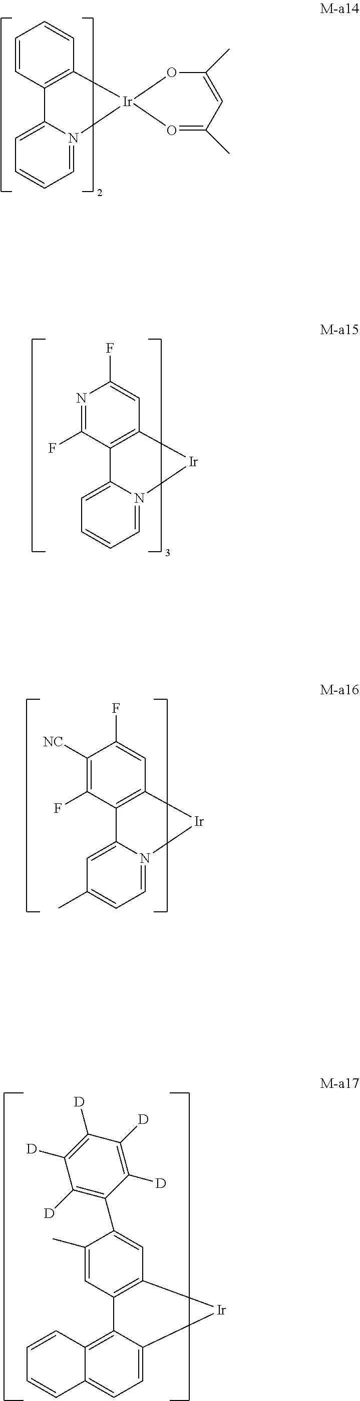

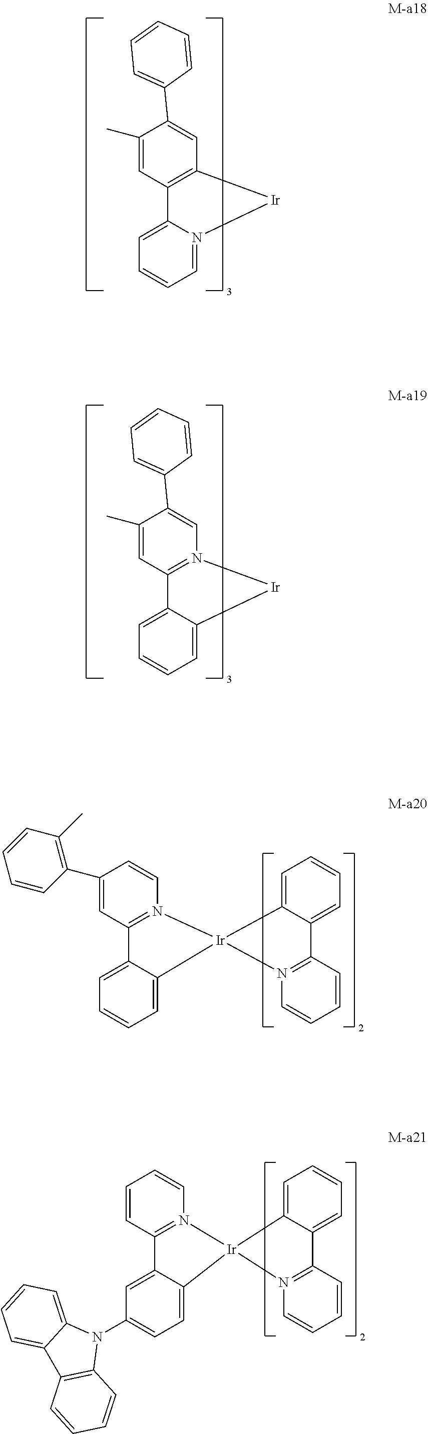

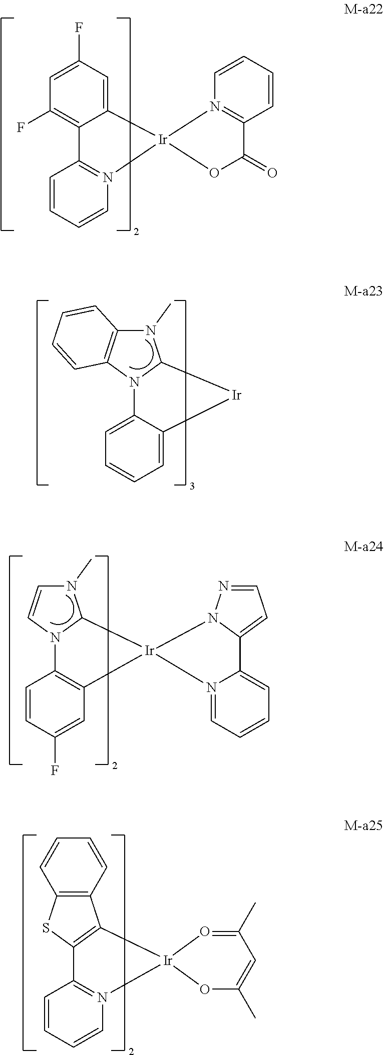

In an embodiment, the emission layer EML may include a compound represented by any one of Formula F-a to Formula F-c. The compound represented by Formula F-a to Formula F-c below may be used as a fluorescent dopant material.

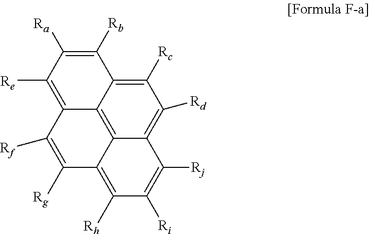

In Formula F-a, two of Rₐ to Rⱼ may each independently be substituted with a group represented by

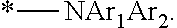

The remainder of Rₐ to Rⱼ, that are not substituted with the group represented by

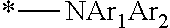

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

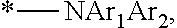

Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ and Ar₂ may be a heteroaryl group containing O or S as a ring-forming atom.

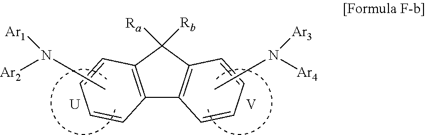

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having a fluorene core in Formula F-b may be a cyclic compound having four rings. When U and V is each 0, the fused ring in Formula F-b may be a cyclic compound having three rings. When U and V is each 1, a fused ring having a fluorene core in Formula F-b may be a cyclic compound having five rings.

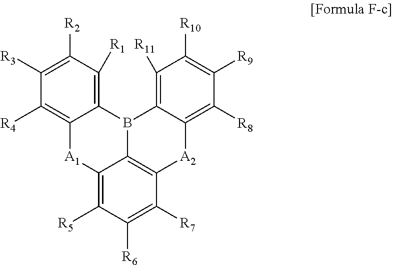

In Formula F-c, A₁ and A₂ may each independently be O, S, Se, or N(Rₘ), and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to substituents of an adjacent ring to form a fused ring. For example, when A₁ and A₂ are each independently N(Rₘ), A₁ may be bonded to R₄ or R₅ to form a ring, and/or A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex including iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. Specifically, iridium(III) bis(4,6-difluorophenylpyridinato-N,C2) (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

In an embodiment, the emission layer may include quantum dots. Herein, a quantum dot may be a crystal of a semiconductor compound. A quantum dot may emit light of various emission wavelengths depending on a size of the crystal. A quantum dot may emit light of various emission wavelengths by adjusting an elemental ratio in the quantum dot compound.

A quantum dot may have a diameter in a range of, for example, about 1 nm to about 10 nm.

The quantum dot may be synthesized through a wet chemical process, a metal organic chemical vapor deposition process, a molecular beam epitaxy process, or a process similar thereto.

The wet chemical process is a method of mixing an organic solvent and a precursor material and growing a quantum dot particle crystal. When the crystal grows, the organic solvent may naturally serve as a dispersant coordinated to a surface of the quantum dot crystal and may control the growth of the crystal. Therefore, the wet chemical process may be more readily performed than vapor deposition methods such as metal organic chemical vapor deposition (MOCVD) or molecular beam epitaxy (MBE), and may control the growth of quantum dot particles through a low-cost process.

The emission layer EML may include a quantum dot material. The quantum dot may include a Group II-VI compound, a Group III-VI compound, a Group I-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof.

Examples of a Group III-VI compound may include: a binary compound such as In₂S₃ or In₂Se₃; a ternary compound such as InGaS₃ or InGaSe₃; and any combination thereof.

Examples of a Group I-III-VI compound may include: a ternary compound such as AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP, etc.

Examples of a Group IV-VI compound may include a binary compound selected such as SnS, SnSe, SnTe, PbS, PbSe, PbTe, and a mixture thereof; a ternary compound selected such as SnSeS, SnSeTe, SnSTe, PbSeS, PbSeTe, PbSTe, SnPbS, SnPbSe, SnPbTe, and a mixture thereof; a quaternary compound selected such as SnPbSSe, SnPbSeTe, SnPbSTe, and a mixture thereof.

Examples of a Group IV element may include Si, Ge, and a mixture thereof. Examples of a Group IV compound may include a binary compound such as SiC, SiGe, and a mixture thereof.

Each element included in a compound such as a binary compound, a ternary compound, or a quaternary compound may be present in a particle at a uniform concentration distribution or at a non-uniform concentration distribution. For example, a formula may indicate elements that are included in a compound, but an elemental ratio in the compound may vary. For example, AgInGaS₂ may mean AgInₓGa₁₋ₓS₂ (wherein x is a real number between 0 to 1).

In an embodiment, a quantum dot may have a core/shell structure in which a quantum dot surrounds another quantum dot. In the core/shell structure, a concentration of an element that is present in the shell may have a concentration gradient that decreases toward the core.

In embodiments, a quantum dot may have the above-described core/shell structure that includes a nanocrystal core and a shell surrounding the core. The shell of the quantum dot may serve as a protection layer to prevent the chemical deformation of the core to maintain semiconductor properties, and/or may serve as a charging layer to impart electrophoresis properties to the quantum dot. The shell may be single-layered or multilayered. An example of a shell of a quantum dot may include a metal oxide, a non-metal oxide, a semiconductor compound, or a combination thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of a light emitting wavelength spectrum less than or equal to about 45 nm. For example, the quantum dot may have an FWHM of an emission wavelength spectrum less than or equal to about 40 nm. For example, the quantum dot may have an FWHM of an emission wavelength spectrum less than or equal to about 30 nm. The color purity or color reproducibility may be improved in any of the above ranges. Light emitted through a quantum dot may be emitted in all directions so that a wide viewing angle may be improved.

The form of the quantum dot may be any form used in the related art, but embodiments are not limited thereto. For example, a quantum dot may have a spherical form, a pyramidal form, a multi-arm form, or a cubic form, or a quantum dot may be in the form of nanoparticles, nanotubes, nanowires, nanofibers, nanoplate particles, etc.

As a size of a quantum dot is adjusted or an elemental ratio in the quantum dot compound is adjusted, it is possible to control the energy band gap, and thus light in various wavelength ranges may be obtained in the quantum dot emission layer. Therefore, utilizing the quantum dot as described above (using different sizes of quantum dots or different elemental ratios in the quantum dot compound), the light emitting element may emit light in various wavelengths. The adjustment of the size of the quantum dot or the elemental ratio in the quantum dot compound may be selected to emit red, green, and/or blue light. In an embodiment, the quantum dots may be configured to emit white light by combining various colors of light.

In the light emitting elements ED according to embodiments as shown in each of FIGS. 5 to 9, the electron transport region ETR may be provided on the emission layer EML. The electron transport region ETR may include at least one of a hole blocking layer HBL, an electron transport layer ETL, or an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or may have a single-layered structure that includes an electron injection material and an electron transport material. The electron transport region ETR may have a single-layered structure including different materials. In embodiments, the electron transport region ETR may have a structure in which an electron transport layer ETL/electron injection layer EIL, a hole blocking layer HBL/electron transport layer ETL/electron injection layer EIL are stacked in order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the electron transport region ETR may include a compound represented by Formula ET-2:

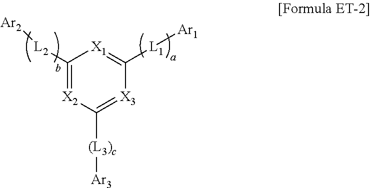

In Formula ET-2, at least one of X₁ to X₃ may each be N, and the remainder of X₁ to X₃ may each independently be C(Rₐ). Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each independently 2 or more, multiples of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include a compound selected from Compound Group 3 3.

In an embodiment, the electron transport region ETR may include at least one compound selected from Compound ET1 to Compound ET36:

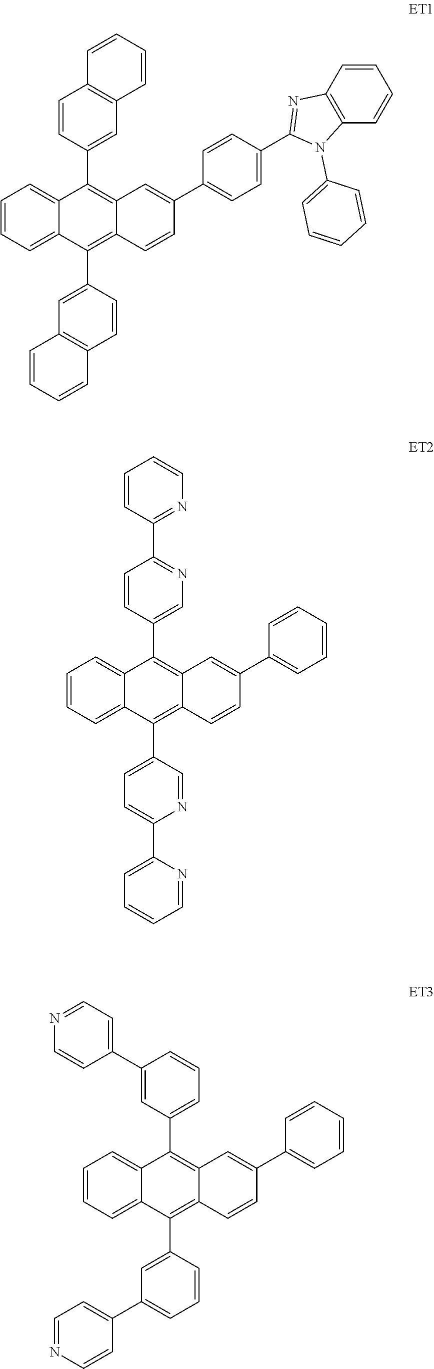 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

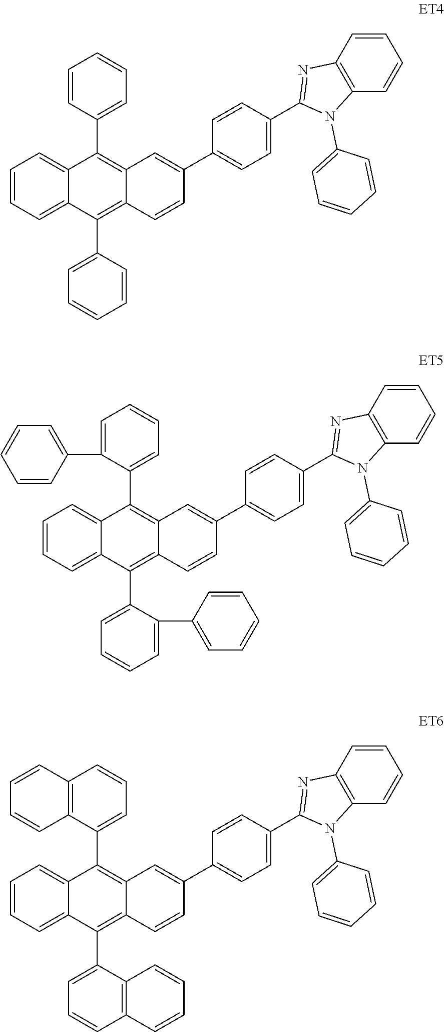 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

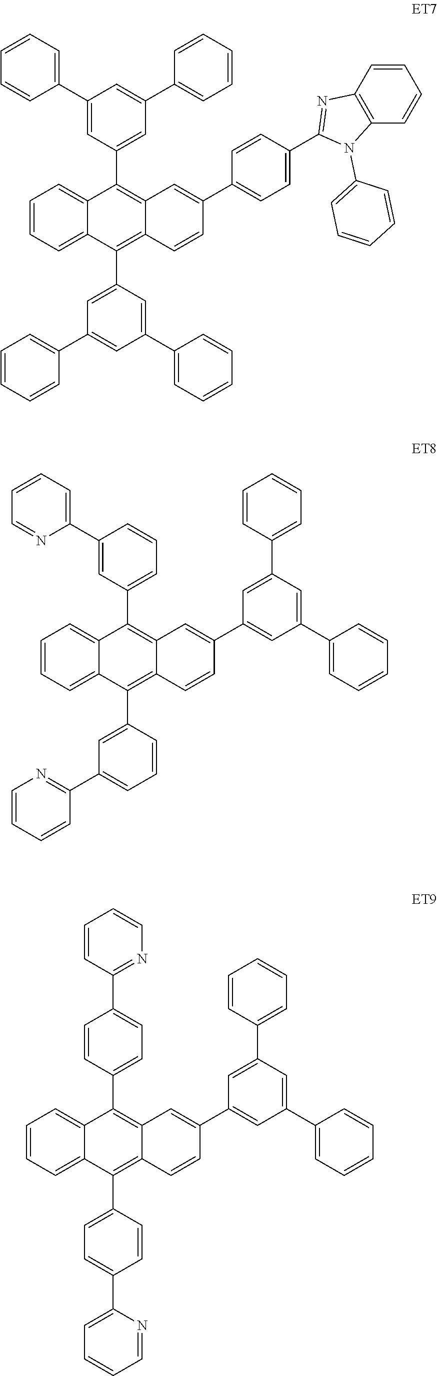 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

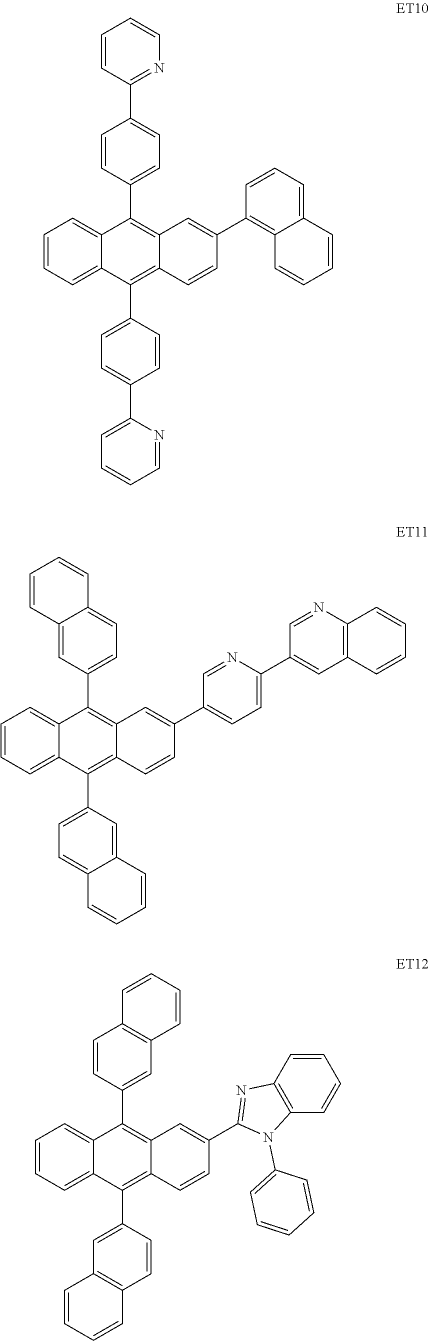 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

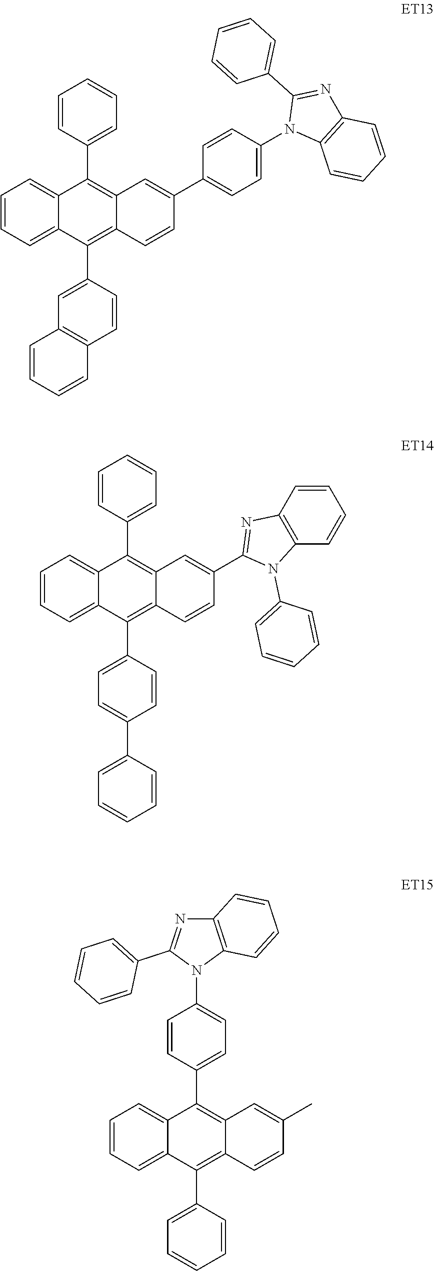 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

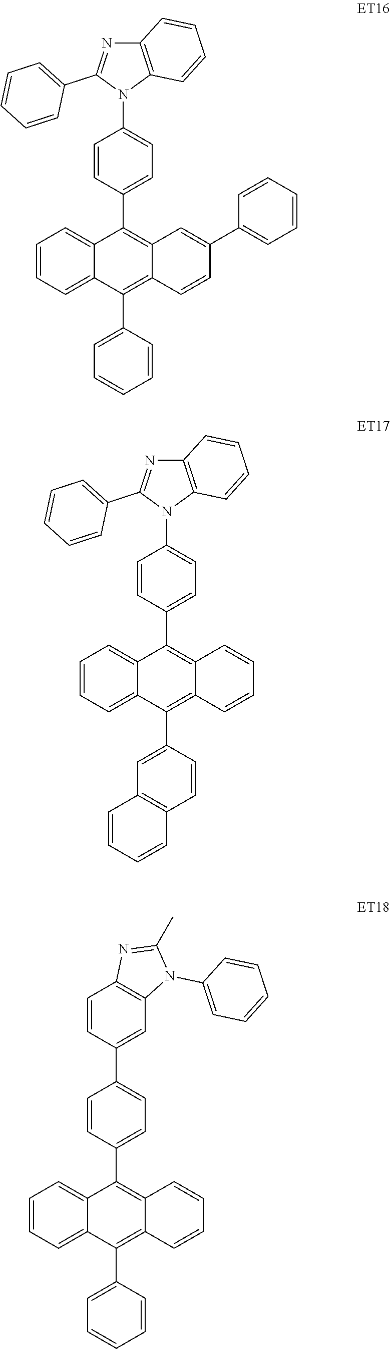 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

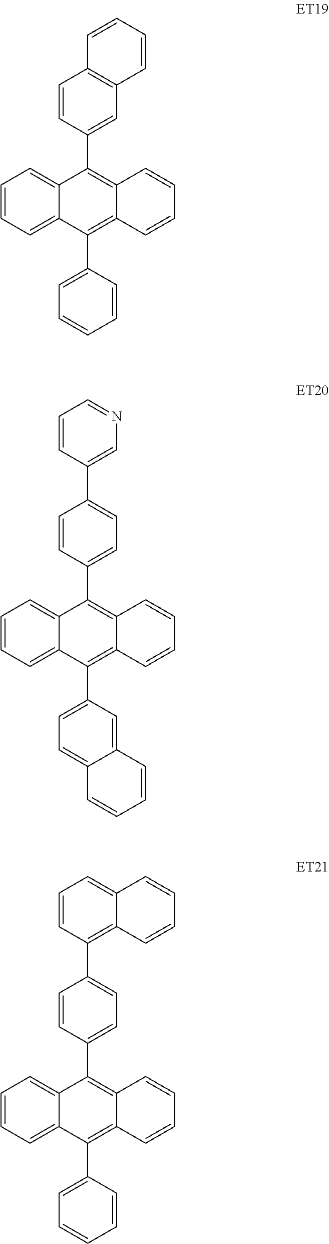

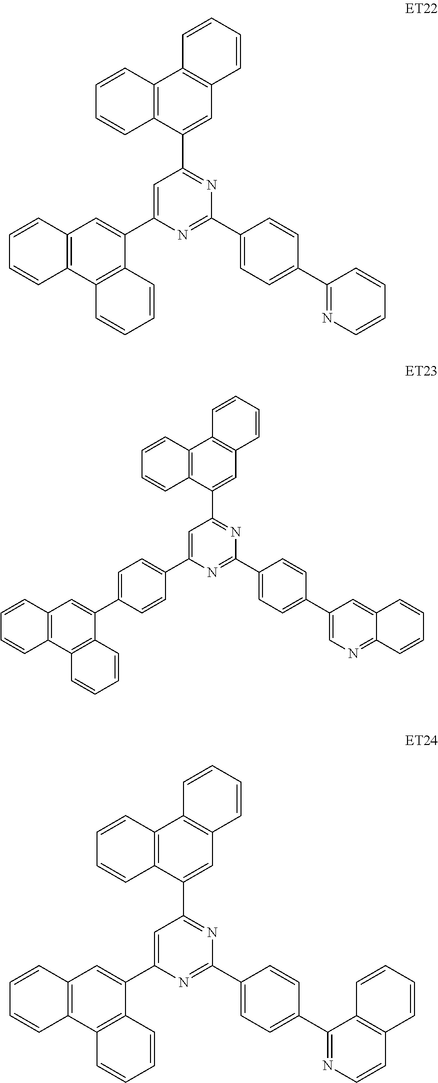 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

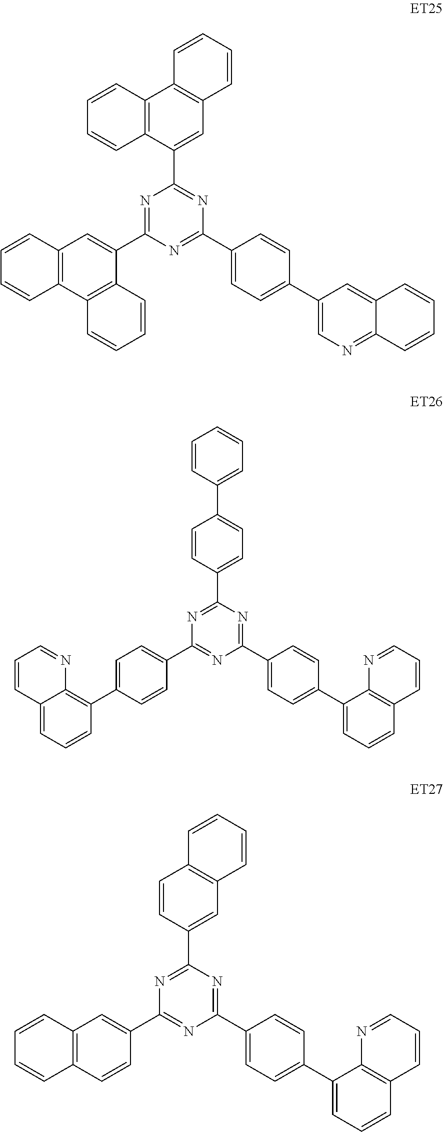 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

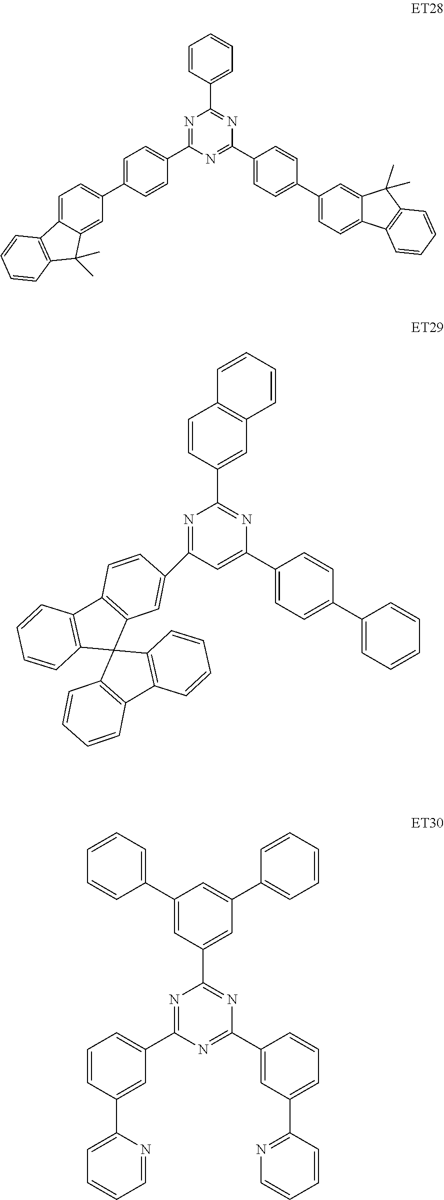 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

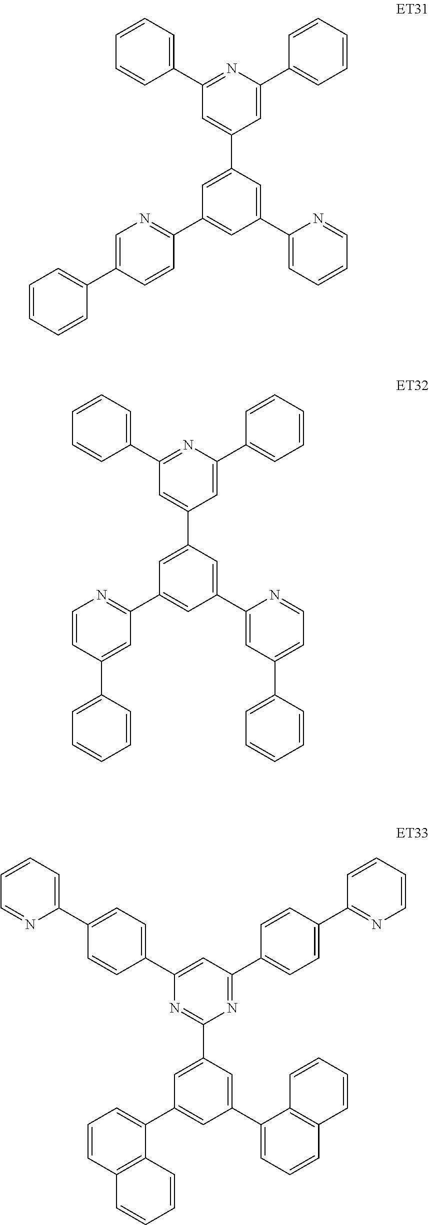 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

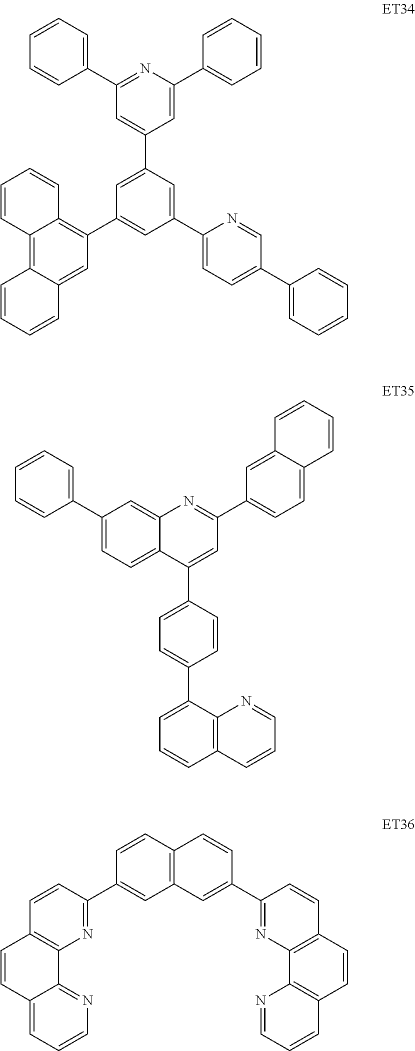 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide such as Yb; or a co-deposited material of a metal halide and a lanthanide. For example, the electron transport region ETR may include KI:Yb, RbI:Yb, LiF:Yb, etc., as a co-deposited material. The electron transport region ETR may be formed using a metal oxide such as Li₂O or BaO, or 8-hydroxyl-lithium quinolate (Liq), etc., but embodiments are not limited thereto. In another embodiment, the electron transport region ETR may include a mixture material of an electron transport material and an insulating organometallic salt. The organometallic salt may be a material having an energy band gap greater than or equal to about 4 eV. For example, the organometallic salt may include, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the hole transport region in at least one of the electron injection layer EIL, the electron transport layer ETL, or the hole blocking layer HBL.

When the electron transport region ETR includes an electron transport layer ETL, the electron transport layer ETL may have a thickness in a range of about 100 Å to about 1,000 Å. For example, the thickness of the electron transport layer ETL may be in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the thickness of the electron injection layer EIL may be in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayered structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is connected to an auxiliary electrode, resistance of the second electrode EL2 may be decreased.

In an embodiment, in the light emitting element ED, a capping layer CPL may further be disposed on the second electrode EL2. The capping layer CPL may have a multilayered structure or a single-layered structure.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

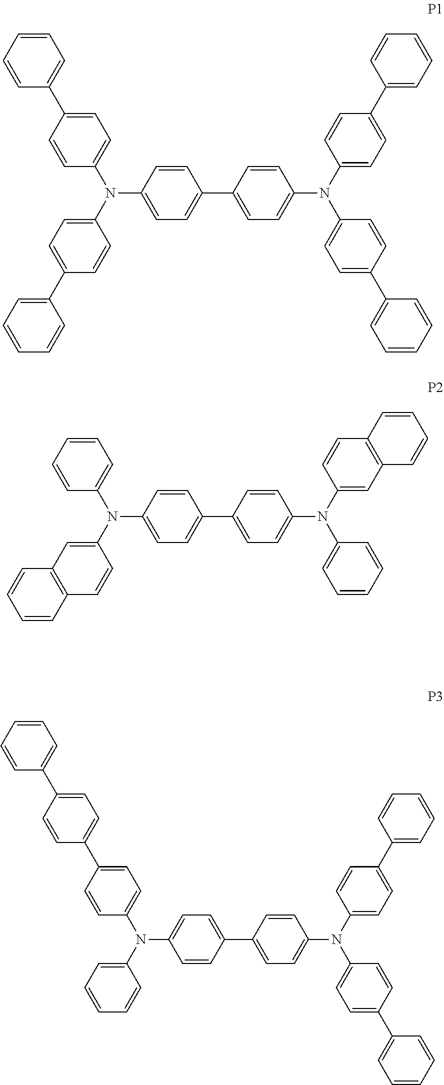 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

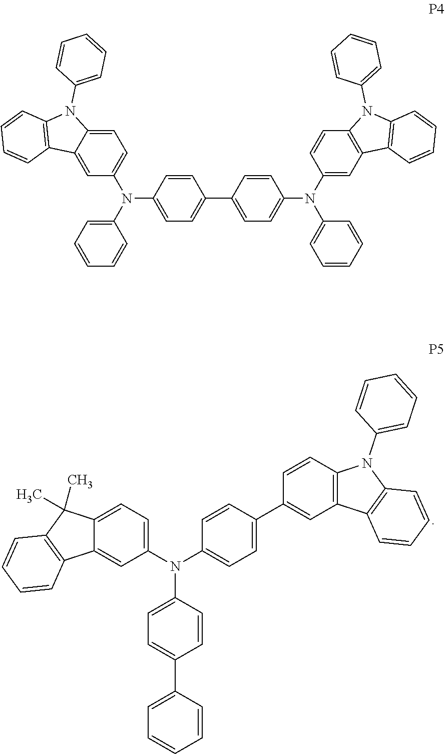 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be greater than or equal to about 1.6 The refractive index of the capping layer CPL may be greater than or equal to about 1.6, with respect to light in a wavelength range of about 550 nm to about 660 nm.

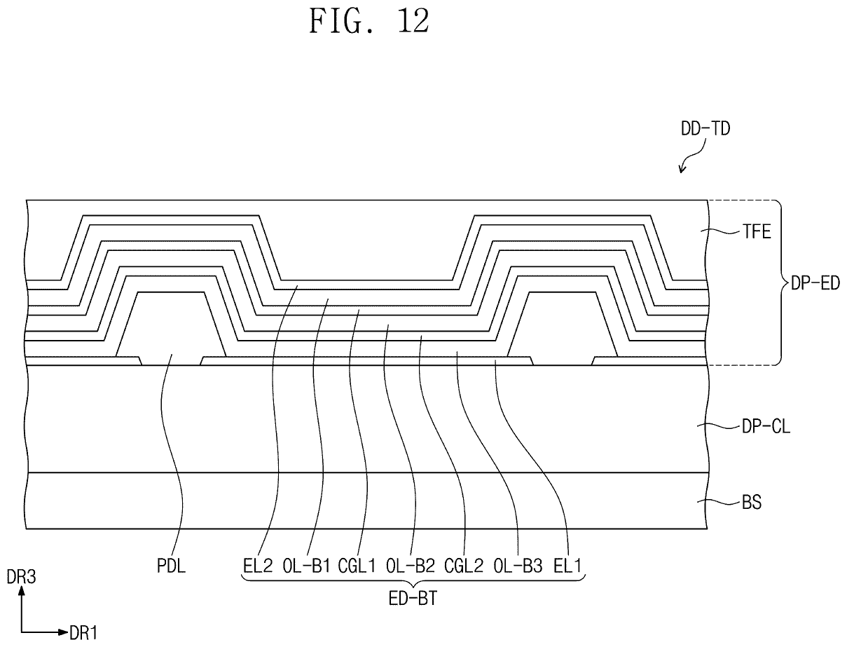

Each of FIGS. 11 to 14 are each a schematic cross-sectional view of a display device according to an embodiment. Hereinafter, in describing the display devices according to embodiments as shown in FIGS. 11 to 14, the duplicated features that have been described above with respect to FIGS. 3 to 9 are not described again, but differing features will be described.

Referring to FIG. 11, the display device DD-a according to an embodiment may include a display panel DP including a display device layer DP-ED, a light control layer CCL disposed on the display panel DP, and a color filter layer CFL. In an embodiment shown in FIG. 11, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 11 may be a same structure of the light emitting elements according to one of FIGS. 5 to 9 as described above.

The emission layer EML of the light emitting element ED included in a display device DD-a according to an embodiment may include the polycyclic compound according to an embodiment as described above.

Referring to FIG. 11, the emission layer EML may be disposed in an opening OH defined in a pixel defining film PDL. For example, the emission layer EML which is separated by the pixel defining film PDL and provided to correspond to each of the light emitting regions PXA-R, PXA-G, and PXA-B may emit light in a same wavelength range. In the display device DD-a, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may emit light by converting a wavelength of provided light. For example, the light control layer CCL may be a layer that includes the quantum dot or a layer that include the phosphor.

The light control layer CCL may include light control parts CCP1, CCP2 and CCP3. The light control parts CCP1, CCP2, and CCP3 may be spaced apart from each other.

Referring to FIG. 11, divided patterns BMP may be disposed between the light control parts CCP1, CCP2 and CCP3 which are spaced apart from each other, but embodiments are not limited thereto. In FIG. 11, it is shown that the divided patterns BMP do not overlap the light control parts CCP1, CCP2 and CCP3, but the edges of the light control parts CCP1, CCP2 and CCP3 may overlap at least a portion of the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light that is the second color light, and the second light control part CCP2 may provide green light that is the third color light. The third light control part CCP3 may provide blue light by that transmits the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include one of TiO₂, ZnO, Al₂O₃, SiO₂, and hollow sphere silica, or may be a mixture of at least two materials selected from TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 may be mediums in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2 and CCP3 from being exposed to moisture/oxygen. The barrier layer BFL1 may cover the light control parts CCP1, CCP2, and CCP3. In an embodiment, the barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic film. The barrier layers BFL1 and BFL2 may be formed of a single layer or of multiple layers.

In the display device DD-a of an embodiment, the color filter layer CFL may be disposed on the light control layer CCL. For example, the color filter layer CFL may be disposed (e.g., directly disposed) on the light control layer CCL. In an embodiment, the barrier layer BFL2 may be omitted.

The color filter layer CFL may include filters CF1, CF2, and CF3. The first to third filters CF1, CF2, and CF3 can be arranged so that they correspond respectively to a red light-emitting region PXA-R, a green light-emitting region PXA-G, and a blue light-emitting region PXA-B.

The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may be a yellow filter. The first filter CF1 and the second filter CF2 may not be provided as separate filters and may be provided as one filter.

Although not shown in the drawings, the color filter layer CFL may further include a light shielding part (not shown). The light shielding part may be a black matrix. The light shielding part (not shown) may include an organic light shielding material or an inorganic light shielding material containing a black pigment or dye. The light shielding part (not shown) may prevent light leakage, and may separate boundaries between the adjacent filters CF1, CF2, and CF3.

A base substrate BL may be disposed on the color filter layer CFL. The base substrate BL may provide a base surface in which the color filter layer CFL, the light control layer CCL, and the like are disposed. The base substrate BL may be a glass substrate, a metal substrate, a plastic substrate, etc. However, embodiments are not limited thereto, and the base substrate BL may be an inorganic layer, an organic layer, or a composite material layer. Although not shown in the drawings, in an embodiment, the base substrate BL may be omitted.

FIG. 12 is a schematic cross-sectional view of a portion of a display device according to an embodiment. In the display device DD-TD according to an embodiment, a light emitting element ED-BT may include light emitting structures OL-B1, OL-B2, and OL-B3. The light emitting element ED-BT may include a first electrode EL1 and a second electrode EL2 that face each other, and the light emitting structures OL-B1, OL-B2, and OL-B3 stacked in a thickness direction between the first electrode EL1 and the second electrode EL2. The light emitting structures OL-B1, OL-B2, and OL-B3 each may each include a hole transport region HTR (FIG. 11), an emission layer EML (FIG. 11), and an electron transport region ETR (FIG. 11) which may be disposed in that order between the first electrode EL1 and the second electrode EL2.

For example, the light emitting element ED-BT included in the display device DD-TD may be a light emitting element having a tandem structure and that includes multiple emission layers.

In an embodiment shown in FIG. 12, light emitted from the light emitting structures OL-B1, OL-B2, and OL-B3 may each be blue light. However, embodiments are not limited thereto, and the light emitted from the light emitting structures OL-B1, OL-B2, and OL-B3 may each have wavelength ranges that are different from each other. For example, the light emitting element ED-BT that includes the light emitting structures OL-B1, OL-B2, and OL-B3 which emit light having wavelength ranges different from each other may each emit white light.

Charge generation layers CGL1 and CGL2 may each be disposed between two adjacent light emitting structures among the light emitting structures OL-B1, OL-B2, and OL-B3. The charge generation layers CGL1 and CGL2 may each independently include a p-type charge generation layer and/or an n-type charge generation layer.

In an embodiment, at least one of the light emitting structures OL-B1, OL-B2, and OL-B3 included in the display device DD-TD may include the polycyclic compound according to an embodiment described above. For example, at least one of the emission layers included in the light emitting element ED-BT may include the polycyclic compound according to an embodiment.

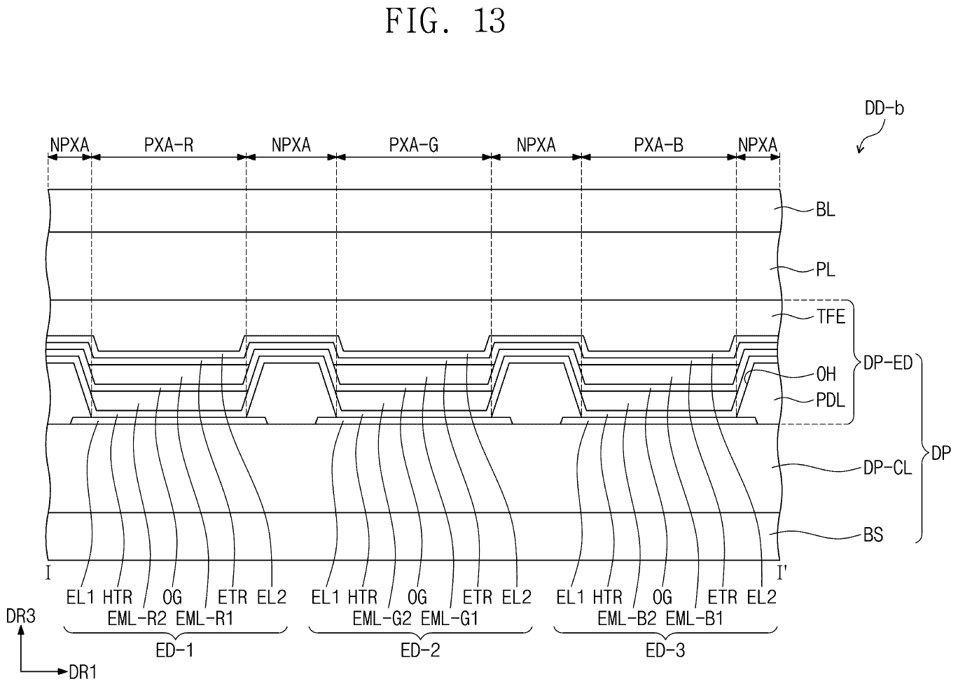

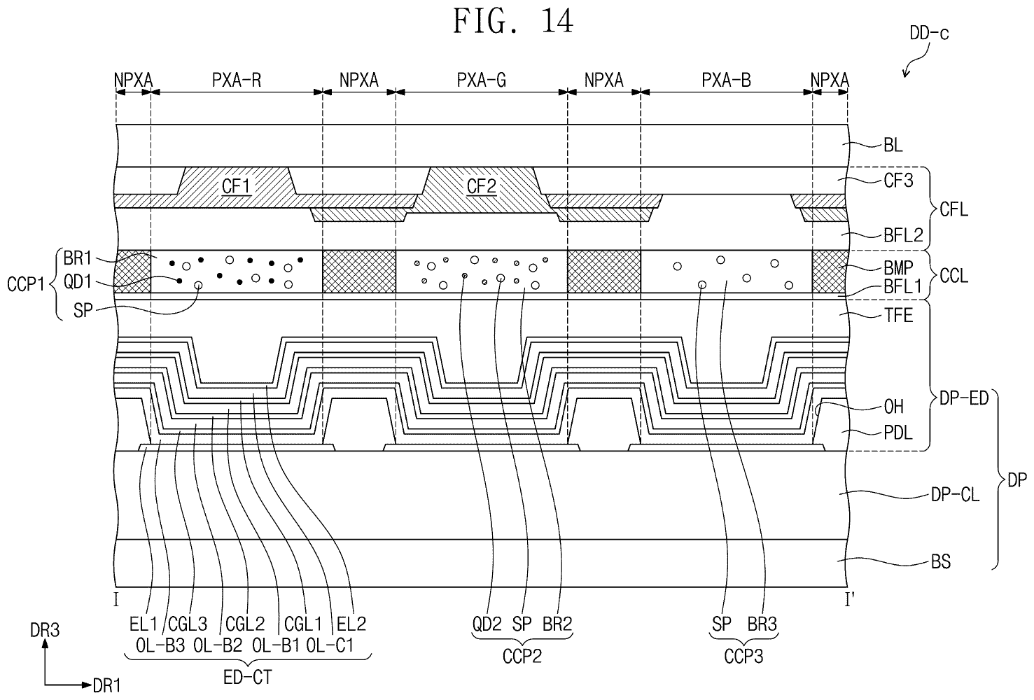

FIG. 13 is a schematic cross-sectional view of a display device DD-b according to an embodiment. FIG. 14 is a schematic cross-sectional view of a display device DD-c according to an embodiment.

Referring to FIG. 13, the display device DD-b according to an embodiment may include light emitting elements ED-1, ED-2, and ED-3 in which two emission layers are stacked. In comparison, the display device DD illustrated in FIG. 4, the embodiment illustrated in FIG. 13 is different at least in that the first to third light emitting elements ED-1, ED-2, and ED-3 each include two emission layers stacked that are in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region which may be stacked in that order. The emission auxiliary part OG may be provided as a common layer for the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 which are stacked in that order.

An optical auxiliary layer PL may be disposed on the display device layer DP-ED. The optical auxiliary layer PL may include a polarizing layer. The optical auxiliary layer PL may be disposed on the display panel DP and control light that is reflected in the display panel DP from an external light. Although not shown in the drawings the optical auxiliary layer PL in the display device DD-b may be omitted.

At least one emission layer included in a display device DD-b shown in FIG. 13 may include the polycyclic compound according to an embodiment as described above. For example, at least one of the first blue emission layer EML-B1 or the second blue emission layer EML-B2 may include the polycyclic compound according to an embodiment.

In contrast to FIGS. 12 and 13, FIG. 14 shows a display device DD-c that is different at least in that it includes four light emitting structures OL-B1, OL-B2, OL-B3, and OL-C1. A light emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2.

Charge generation layers CGL1, CGL2, and CGL3 may each be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

The charge generation layers CGL1, CGL2, and CGL3 disposed between adjacent light emitting structures OL-B1, OL-B2, OL-B3, and OL-C1 may each independently include a p-type charge generation layer and/or an n-type charge generation layer.

In an embodiment, at least one of the light emitting structures OL-B1, OL-B2, OL-B3, and OL-C1 included in the display device DD-c may include the polycyclic compound according to an embodiment as described above. For example, in an embodiment, at least one of the first to third light emitting structures OL-B1, OL-B2, and OL-B3 may each include the polycyclic compound according to an embodiment as described above.

The light emitting element ED represented by Formula 1 described above according to an embodiment includes the polycyclic compound according to an embodiment in at least one functional layer disposed between the first electrode EL1 and the second electrode EL2, and may thus exhibit excellent light emitting efficiency and improved lifespan. For example, the polycyclic compound according to an embodiment may be included in the emission layer EML of the light emitting element ED, and the light emitting element may exhibit long lifespan.

In an embodiment, the electronic device may include a display device that includes multiple light emitting elements, and a control part which controls the display device. The electronic device may be a device that is activated according to an electrical signal. The electronic device may include display devices according to various embodiments. Examples of an electronic device may include large-sized, medium-sized, and small-sized electronic apparatuses such as a television set, a monitor, a billboard, a personal computer, a laptop computer, a personal digital terminal, a display device for a vehicle, a game console, a portable electronic device, a smart watch, and a camera.

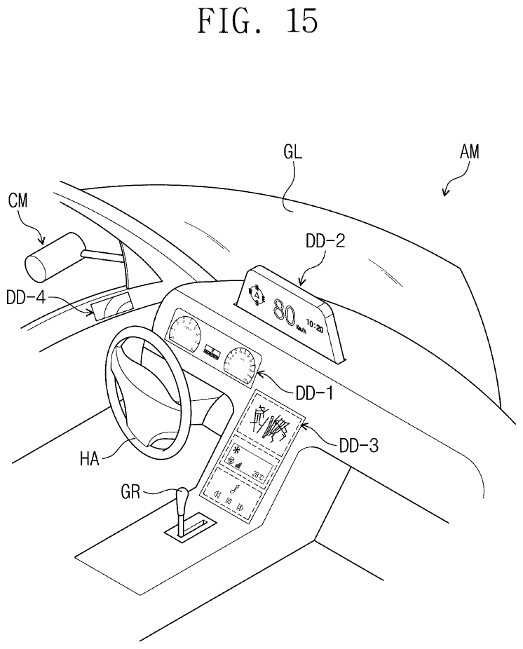

FIG. 15 is a schematic diagram of a vehicle AM that includes first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c as described above with reference to FIGS. 3, and 4, and 11 to 14.

FIG. 15 shows a vehicle AM, but this is only an example, and the first to fourth display devices DD-1, DD-2, DD-3, and DD-4 may be disposed in various transportation means such as a bicycle, a motorcycle, a train, a ship, and an airplane. In an embodiment, at least one of the first to fourth display devices DD-1, DD-2, DD-3, and DD-4 may have a structure according to one of display devices DD, DD-TD, DD-a, DD-b, and DD-c may be employed in a personal computer, a laptop computer, a personal digital terminal, a game console, a portable electronic device, a television, a monitor, a billboard, or the like. Herein, these are merely provided as examples, and the display devices may be included in other electronic devices.

At least one of the first to fourth display devices DD-1, DD-2, DD-3, and DD-4 may each independently include the light emitting element ED according to an embodiment as described with reference to any of FIGS. 5 to 9. The light emitting element ED may include a polycyclic compound according to an embodiment. At least one of the first to fourth display devices DD-1, DD-2, DD-3, or DD-4 includes the light emitting element ED containing the polycyclic compound of an embodiment, and may thus have increased display lifetime.

Referring to FIG. 15, the vehicle AM may include a steering wheel HA and a gear GR for driving the vehicle AM. The vehicle AM may include a front window GL disposed so as to face the driver.

The first display device DD-1 may be disposed in a first region that overlaps the steering wheel HA. For example, the first display device DD-1 may be a digital cluster which displays first information of the vehicle AM. The first information may include a first scale which indicates a driving speed of the vehicle AM, a second scale which indicates an engine speed (for example, revolutions per minute (RPM)), an image that represents a fuel gauge, etc. A first scale and a second scale may each be represented as a digital image.

The second display device DD-2 may be disposed in a second region facing the driver's seat that overlaps the front window GL. The driver's seat may be a seat in which the steering wheel HA is disposed. For example, the second display device DD-2 may be a head up display (HUD) which displays second information of the vehicle AM. The second display device DD-2 may be optically transparent. The second information may include digital numbers which indicate a driving speed, and may further include information such as the current time. Although not shown in the drawings, the second information of the second display device DD-2 may be displayed by being projected on the front window GL.

The third display device DD-3 may be disposed in a third region that is adjacent to the gearshift GR. For example, the third display device DD-3 may be disposed between the driver's seat and the passenger seat and may be a center information display (CID) for a vehicle for displaying third information. The passenger seat may be a seat spaced apart from the driver's seat with the gearshift GR disposed therebetween. The third information may include information about traffic conditions (e.g., navigation information), about music or radio that is playing, or about a video (or an image) that is displayed, about temperatures inside the vehicle AM, etc.

The fourth display device DD-4 may be spaced apart from the steering wheel HA and the gearshift GR, and may be disposed in a fourth region adjacent to the side of the vehicle AM. For example, the fourth display device DD-4 may be a digital side-view mirror which displays fourth information. The fourth display device DD-4 may display an image outside the vehicle AM taken by a camera module CM that is disposed outside the vehicle AM. The fourth information may include an external image of the vehicle AM.

The first to fourth information are only examples, and the first to fourth display devices DD-1, DD-2, DD-3, and DD-4 may further display information about the interior and exterior of the vehicle AM. The first to fourth information may include information that is different from each other. However, embodiments are not limited thereto, and a part of the first to fourth information may include a same information.

Hereinafter, a polycyclic compound according to an embodiment and a light emitting element according to an embodiment will be described in detail with reference to the Examples and the Comparative Examples. The, Examples shown below are only provided to facilitate in understanding the disclosure, and the scope thereof is not limited thereto.

### EXAMPLES

### 1. Synthesis of Polycyclic Compounds

A process of synthesizing polycyclic compounds according to an embodiment will be described in detail by describing synthesis methods for Compounds 4, 73, 96, 97, 133, and 154 as examples. In the following descriptions, a process of synthesizing polycyclic compounds is only provided as an example, and thus a process of synthesizing polycyclic compounds according to an embodiment is not limited to the Examples.

### (1) Synthesis of Compound 4

Compound 4 according to an embodiment may be synthesized by, for example, a process of Reaction Formula 1.

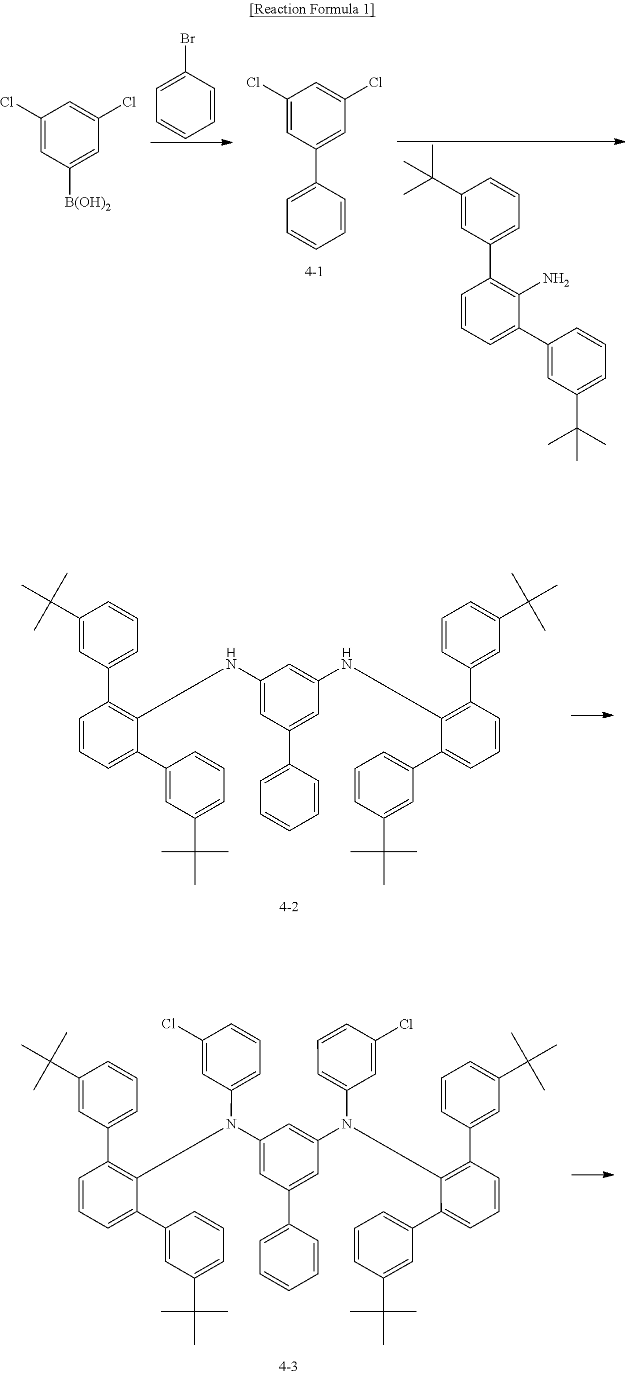

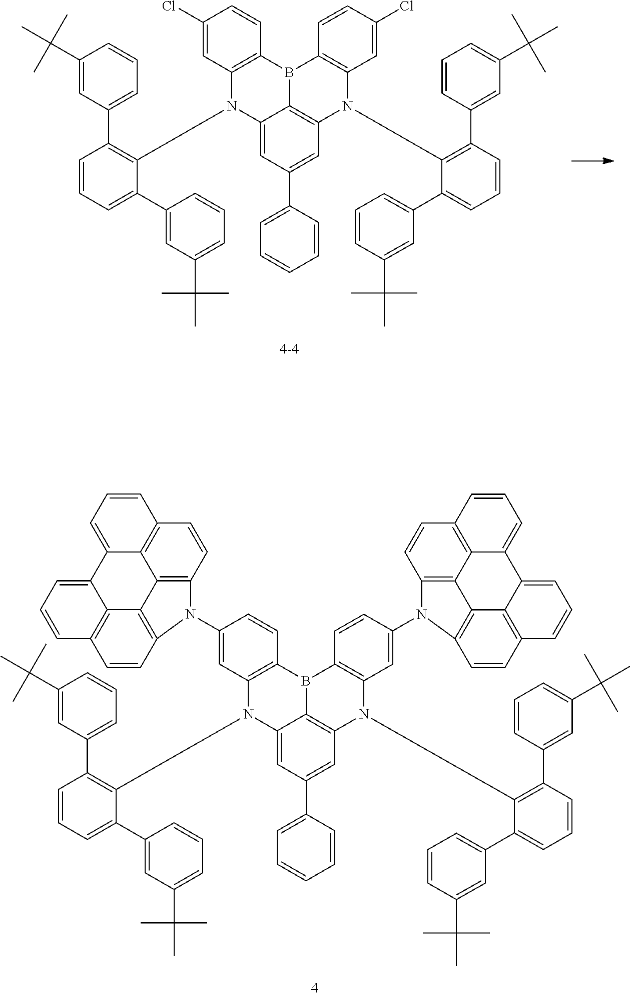

### 1) Synthesis of Intermediate Compound 4-1

(3,5-dichlorophenyl)boronic acid (1.2 eq), bromobenzene (1 eq), tris(dibenzylideneacetone)dipalladium(0) (0.05 eq), Pd(PPh₃)₄ (0.05 eq), and potassium carbonate (1.5 eq) were added and dissolved in a solvent of toluene/H₂O, and the reaction solution was stirred at 100° C. for 12 hours. After cooling the resultant product, water (1 L) and ethyl acetate (300 mL) were added thereto for extraction, and the organic layer was collected, dried over MgSO₄, and filtered. The filtered solution was subjected to reduced pressure to remove the solvent, and using CH₂Cl₂ and hexane as a developing solvent, the obtained reactant was purified and separated through column chromatography using silica gel to obtain Intermediate Compound 4-1. (Yield: 89%)

### 2) Synthesis of Intermediate Compound 4-2

In a nitrogen atmosphere, Intermediate Compound 4-1 (1 eq), 3,3″-di-tert-butyl-[1,1′:3′,1″-terphenyl]-2′-amine (2.1 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 4-2. (Yield: 81%)

### 3) Synthesis of Intermediate Compound 4-3

In a nitrogen atmosphere, Intermediate Compound 4-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 4-3. (Yield: 63%)

### 4) Synthesis of Intermediate Compound 4-4

In a nitrogen atmosphere, Intermediate Compound 4-3 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 4-4. (Yield: 45%)

### 5) Synthesis of Compound 4

In a nitrogen atmosphere, Intermediate Compound 4-4 (1 eq), 1H-phenanthro[1,10,9,8-cdefg]carbazole (2.4 eq), Pd₂dba₃ (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 4. (Yield: 60%)

### (2) Synthesis of Compound 73

Compound 73 according to an embodiment may be synthesized by, for example, a process of Reaction Formula 2.

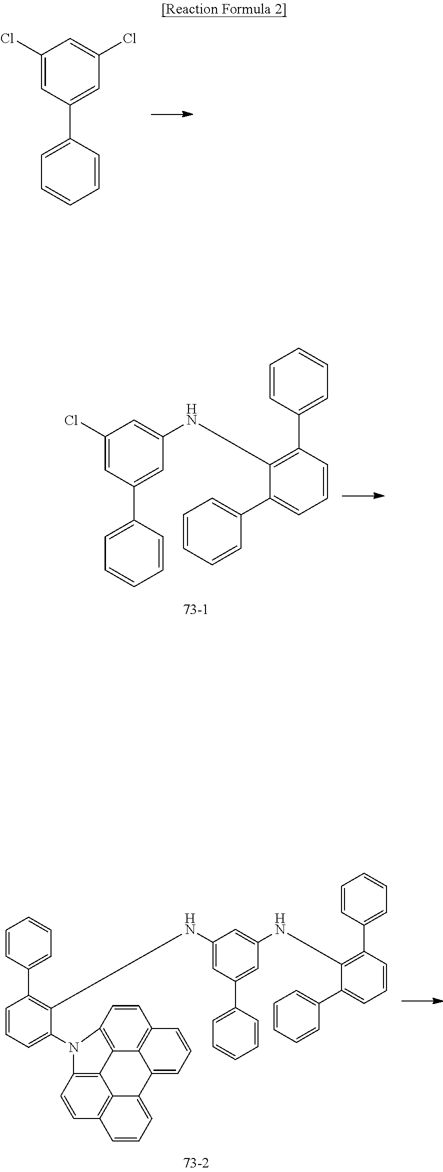 [SMILES: Clc1cc(Cl)cc(-c2ccccc2)c1 ; Clc1cc(Nc2c(-c3ccccc3)cccc2-c2ccccc2)cc(-c2ccccc2)c1 ; c1ccc(-c2cc(Nc3c(-c4ccccc4)cccc3-c3ccccc3)cc(Nc3c(-c4ccccc4)cccc3-n3c4ccc5cccc6c7cccc8ccc3c(c87)c4c56)c2)cc1]

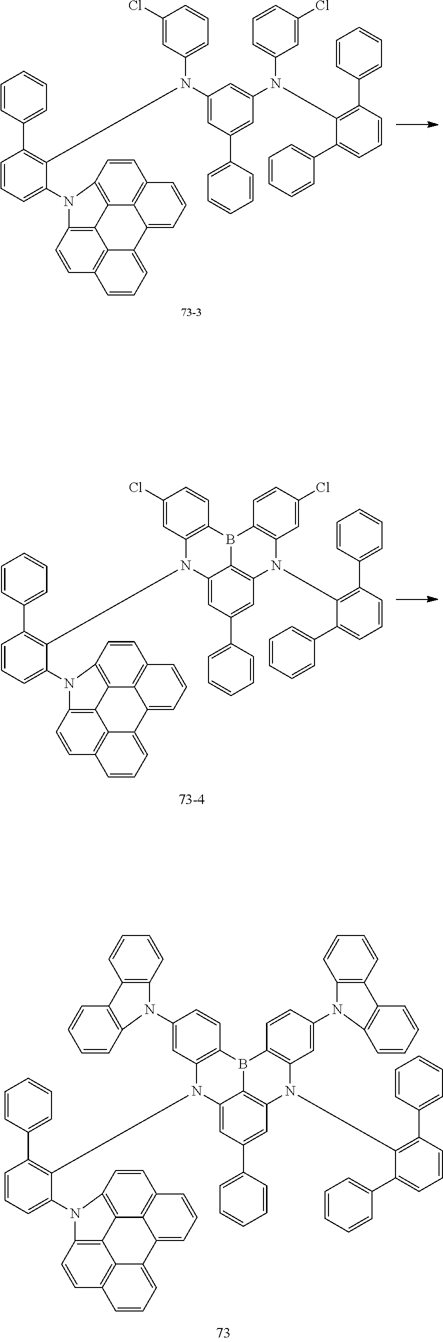 [SMILES: Clc1cccc(N(c2cc(-c3ccccc3)cc(N(c3cccc(Cl)c3)c3c(-c4ccccc4)cccc3-n3c4ccc5cccc6c7cccc8ccc3c(c87)c4c56)c2)c2c(-c3ccccc3)cccc2-c2ccccc2)c1 ; Clc1ccc2c(c1)N(c1c(-c3ccccc3)cccc1-c1ccccc1)c1cc(-c3ccccc3)cc3c1B2c1ccc(Cl)cc1N3c1c(-c2ccccc2)cccc1-n1c2ccc3cccc4c5cccc6ccc1c(c65)c2c34 ; c1ccc(-c2cc3c4c(c2)N(c2c(-c5ccccc5)cccc2-n2c5ccc6cccc7c8cccc9ccc2c(c98)c5c67)c2cc(-n5c6ccccc6c6ccccc65)ccc2B4c2ccc(-n4c5ccccc5c5ccccc54)cc2N3c2c(-c3ccccc3)cccc2-c2ccccc2)cc1]

### 1) Synthesis of Intermediate Compound 73-1

In a nitrogen atmosphere, 3,5-dichloro-1,1′-biphenyl (1 eq), [1,1′:3′,1″-terphenyl]-2′-amine (1.0 eq), Pd₂dba₃ (0.05 eq), tris-tert-butyl phosphine (0.1 eq), and sodium tert-butoxide (1.5 eq) were added and dissolved in toluene, and the reaction solution was stirred at 80° C. for 6 hours. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 73-1. (Yield: 58%)

### 2) Synthesis of Intermediate Compound 73-2

In a nitrogen atmosphere, Intermediate Compound 73-1 (1 eq), 3-(1H-phenanthro[1,10,9,8-cdefg]carbazol-1-yl)-[1,1′-biphenyl]-2-amine (1.0 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 73-2. (Yield: 75%)

### 3) Synthesis of Intermediate Compound 73-3

In a nitrogen atmosphere, Intermediate Compound 73-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 73-3. (Yield: 60%)

### 4) Synthesis of Intermediate Compound 73-4

In a nitrogen atmosphere, Intermediate Compound 73-3 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 73-4. (Yield: 35%)

### 5) Synthesis of Compound 73

In a nitrogen atmosphere, Intermediate Compound 73-4 (1 eq), carbazole (2.4 eq), Pd₂dba₃ (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 73. (Yield: 82%)

### (3) Synthesis of Compound 96

Compound 96 according to an embodiment may be synthesized by, for example, a process of Reaction Formula 3.

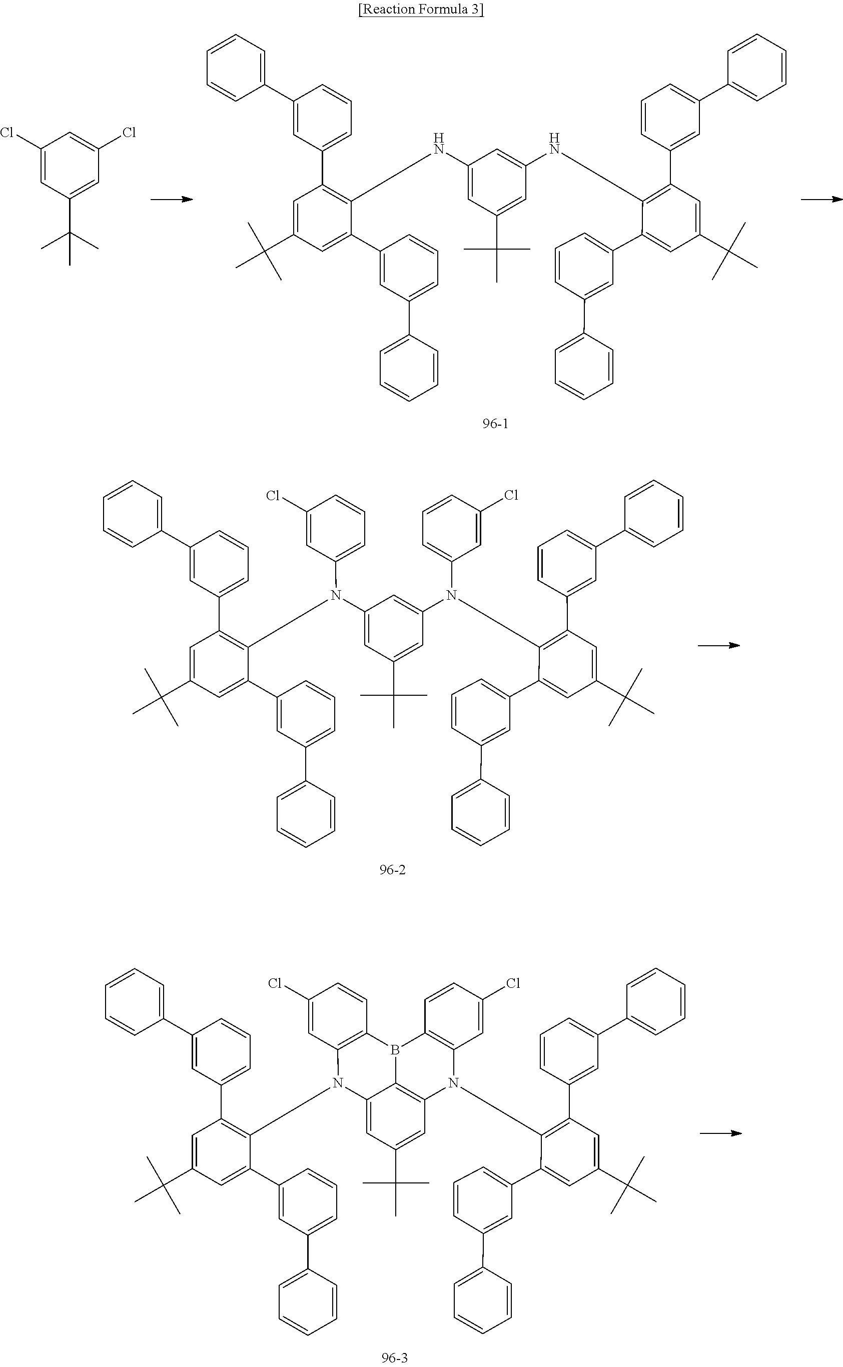

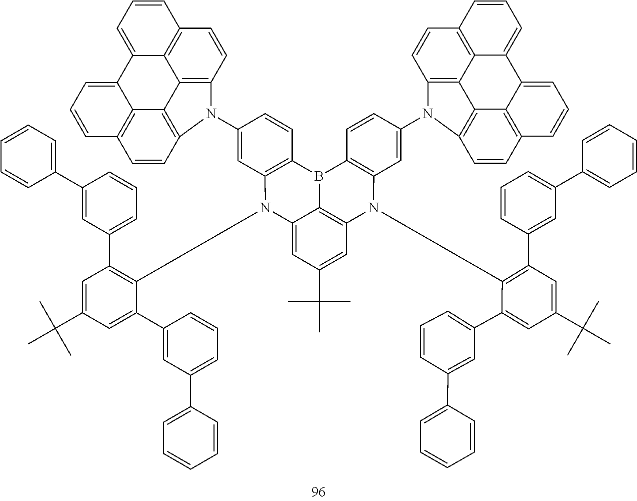 [SMILES: CC(C)(C)c1cc(-c2cccc(-c3ccccc3)c2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

### 1) Synthesis of Intermediate Compound 96-1

In a nitrogen atmosphere, 1-(tert-butyl)-3,5-dichlorobenzene (1 eq), 5″-(tert-butyl)-[1,1′:3′,1″:3″,1′″:3′″,1″″-quinquephenyl]-2″-amine (2.1 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 96-1. (Yield: 78%)

### 2) Synthesis of Intermediate Compound 96-2

In a nitrogen atmosphere, Intermediate Compound 96-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 96-2. (Yield: 66%)

### 3) Synthesis of Intermediate Compound 96-3

In a nitrogen atmosphere, Intermediate Compound 96-2 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 96-3. (Yield: 39%)

### 4) Synthesis of Compound 96

In a nitrogen atmosphere, Intermediate Compound 96-3 (1 eq), 1H-phenanthro[1,10,9,8-cdefg]carbazole (2.4 eq), Pd2dba3 (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 96. (Yield: 82%)

### (4) Synthesis of Compound 97

Compound 97 according to an embodiment may be synthesized by, for example, a process of Reaction Formula 4.

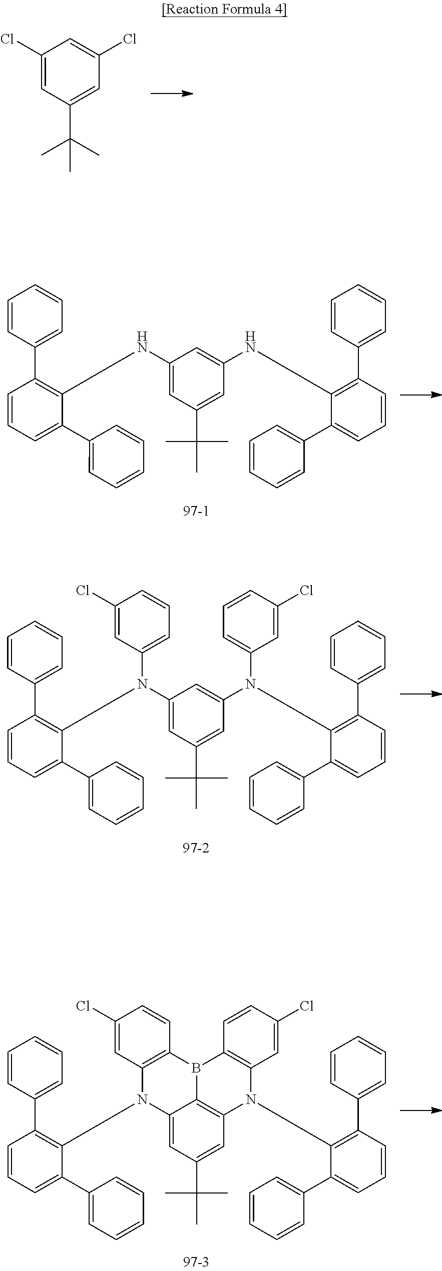 [SMILES: CC(C)(C)c1cc(Cl)cc(Cl)c1 ; CC(C)(C)c1cc(Nc2c(-c3ccccc3)cccc2-c2ccccc2)cc(Nc2c(-c3ccccc3)cccc2-c2ccccc2)c1 ; CC(C)(C)c1cc(N(c2cccc(Cl)c2)c2c(-c3ccccc3)cccc2-c2ccccc2)cc(N(c2cccc(Cl)c2)c2c(-c3ccccc3)cccc2-c2ccccc2)c1 ; CC(C)(C)c1cc2c3c(c1)N(c1c(-c4ccccc4)cccc1-c1ccccc1)c1cc(Cl)ccc1B3c1ccc(Cl)cc1N2c1c(-c2ccccc2)cccc1-c1ccccc1]

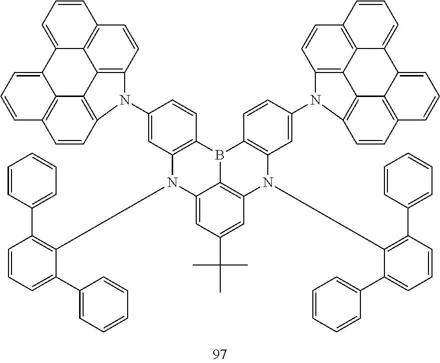 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1]

### 1) Synthesis of Intermediate Compound 97-1

In a nitrogen atmosphere, 1-(tert-butyl)-3,5-dichlorobenzene (1 eq), [1,1′: 3′,1″-terphenyl]-2′-amine (2.1 eq), Pd2dba3 (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 97-1. (Yield: 75%)

### 2) Synthesis of Intermediate Compound 97-2

In a nitrogen atmosphere, Intermediate Compound 97-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 97-2. (Yield: 61%)

### 3) Synthesis of Intermediate Compound 97-3

In a nitrogen atmosphere, Intermediate Compound 97-2 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 97-3. (Yield: 43%)

### 4) Synthesis of Compound 97

In a nitrogen atmosphere, Intermediate Compound 97-3 (1 eq), 1H-phenanthro[1,10,9,8-cdefg]carbazole (2.4 eq), Pd₂dba₃ (0.05 eq), tris-tert-butyl phosphine (0.1 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 97. (Yield: 83%)

### (5) Synthesis of Compound 133

Compound 133 according to an embodiment may be synthesized by, for example, a process of Reaction Formula 5.

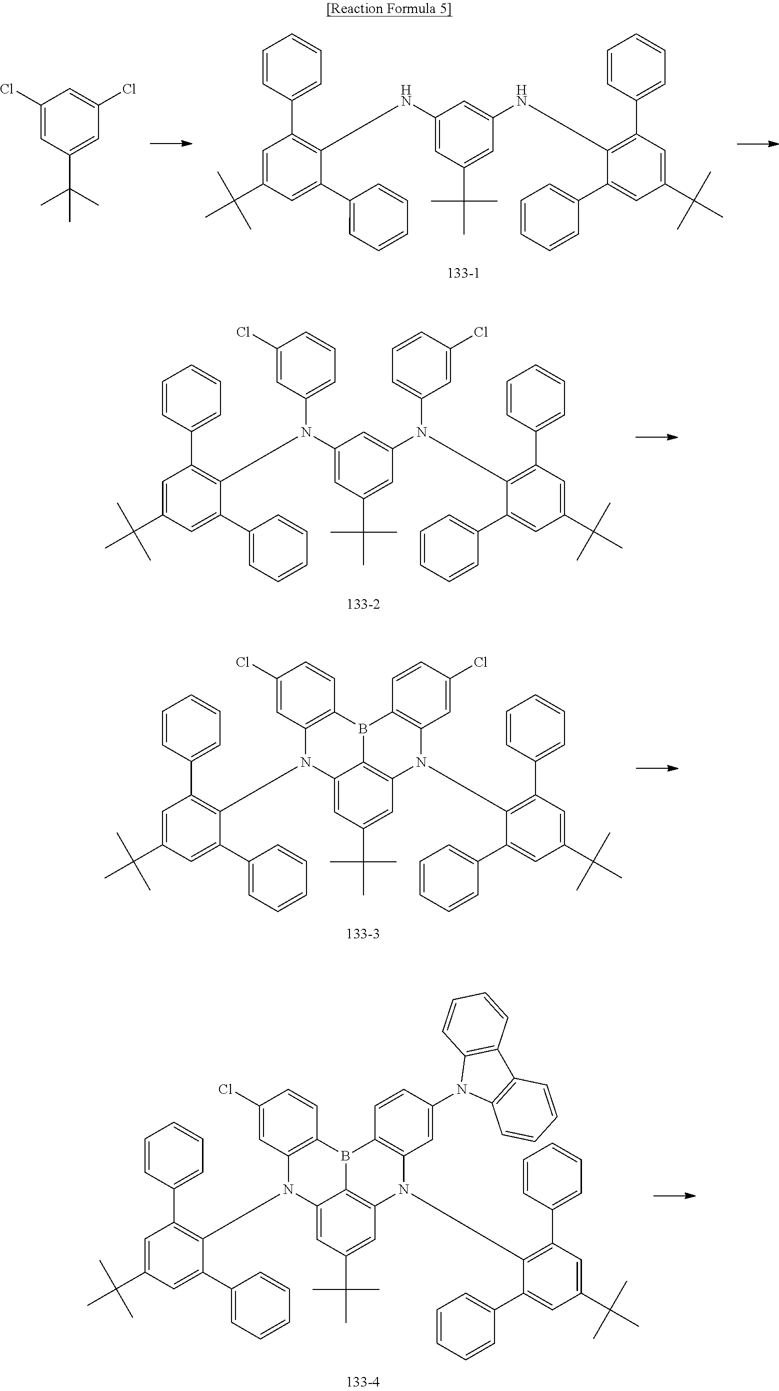

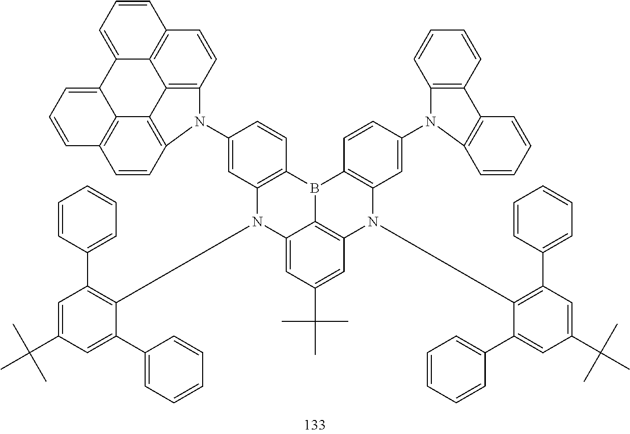 [SMILES: CC(C)(C)c1cc(-c2ccccc2)c(N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2ccccc2)c1]

### 1) Synthesis of Intermediate Compound 133-1

In a nitrogen atmosphere, 1-(tert-butyl)-3,5-dichlorobenzene (1 eq), 5′-(tert-butyl)-[1,1′:3′,1″-terphenyl] (2.1 eq), Pd₂dba₃ (0.1 eq), tris-tert-butyl phosphine (0.2 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 133-1. (Yield: 71%)

### 2) Synthesis of Intermediate Compound 133-2

In a nitrogen atmosphere, Intermediate Compound 133-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 133-2. (Yield: 60%)

### 3) Synthesis of Intermediate Compound 133-3

In a nitrogen atmosphere, Intermediate Compound 133-2 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 133-3. (Yield: 35%)

### 4) Synthesis of Compound 133-4

In a nitrogen atmosphere, Intermediate Compound 133-3 (1 eq), carbazole (1 eq), pd2dba3 (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 133-4. (Yield: 44%)

### 5) Synthesis of Compound 133

In a nitrogen atmosphere, Intermediate Compound 133-4 (1 eq), 1H-phenanthro[1,10,9,8-cdefg]carbazole (1.2 eq), Pd2dba3 (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 133. (Yield: 84%)

### (6) Synthesis of Compound 154

Compound 154 according to an embodiment may be synthesized by, for example, a process of Reaction Formula 6.

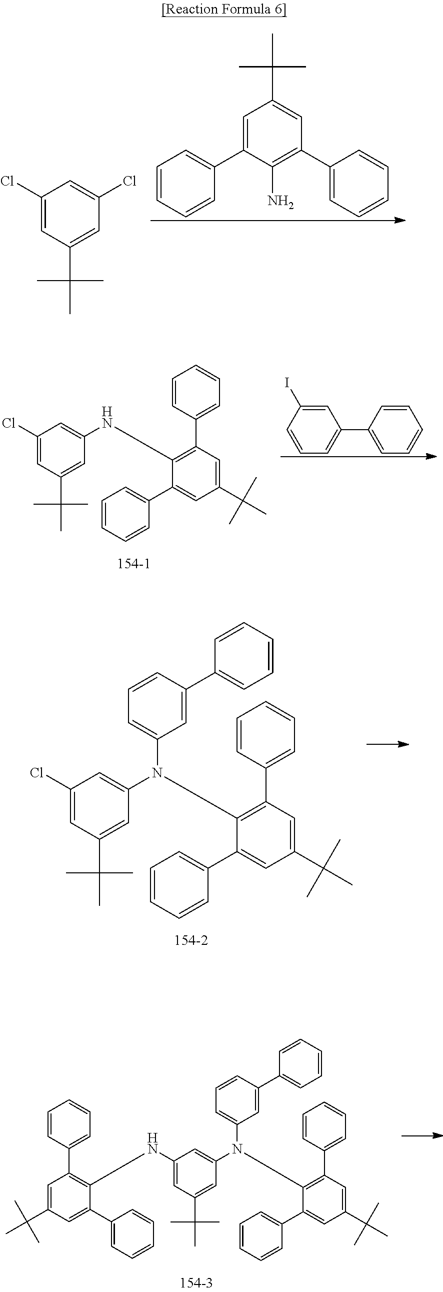

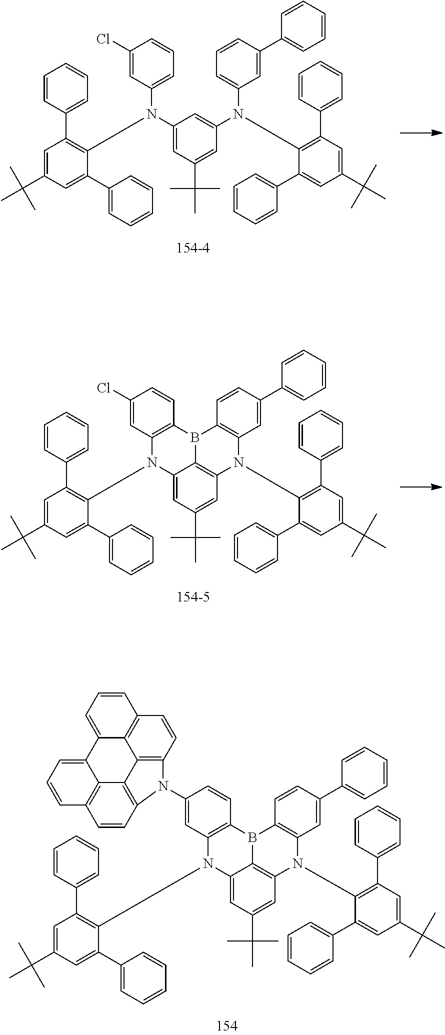

### 1) Synthesis of Intermediate Compound 154-1

In a nitrogen atmosphere, 1-(tert-butyl)-3,5-dichlorobenzene (1 eq), 5′-(tert-butyl)-[1,1′:3′,1″-terphenyl] (1 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 154-1. (Yield: 61%)

### 2) Synthesis of Intermediate Compound 154-2

In a nitrogen atmosphere, Intermediate Compound 154-1 (1 eq), 3-iodo-1,1′-biphenyl (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 154-2. (Yield: 60%)

### 3) Synthesis of Intermediate Compound 154-3

In a nitrogen atmosphere, Intermediate Compound 154-2 (1 eq), 5′-(tert-butyl)-[1,1′:3′,1″-terphenyl] (1 eq), Pd₂dba₃ (0.05 eq), tris-tert-butyl phosphine (0.1 eq), and sodium tert-butoxide (1.5 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 154-3. (Yield: 61%)

### 4) Synthesis of Intermediate Compound 154-4

In a nitrogen atmosphere, Intermediate Compound 154-3 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at 160° C. for 3 days. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Intermediate Compound 154-4. (Yield: 60%)

### 5) Synthesis of Intermediate Compound 154-5

In a nitrogen atmosphere, Intermediate Compound 154-4 (1 eq) was dissolved in o-dichlorobenzene and cooled using water and ice, and BBr₃ (5 equiv.) was slowly added dropwise, and the reaction solution was stirred at 180° C. for 24 hours. After cooling the resultant product, triethylamine (5 equiv.) was added thereto to terminate the reaction, and the organic layer was collected through extraction using water/CH₂Cl₂, dried over MgSO₄, and filtered. The filtered solution was subjected to reduced pressure to remove the solvent, and the obtained reactant was purified and separated through column chromatography using silica gel to obtain Intermediate Compound 154-5. (Yield: 35%)

### 6) Synthesis of Compound 154

In a nitrogen atmosphere, Intermediate Compound 154-5 (1 eq), 1H-phenanthro[1,10,9,8-cdefg]carbazole (2.4 eq), Pd2dba3 (0.1 eq), tris-tert-butyl phosphine (0.2 eq), and sodium tert-butoxide (3 eq) were added and dissolved in o-xylene, and the reaction solution was stirred at 140° C. for 1 day. After cooling the resultant product, water and ethyl acetate were added thereto for extraction, and the organic layer was collected, dried over MgSO₄, and filtered. The filtered solution was subjected to reduced pressure to remove the solvent, and the obtained reactant was purified and separated through column chromatography using silica gel to obtain Compound 154. (Yield: 44%)

### (2) Preparation and Evaluation of Light Emitting Element

Light emitting elements containing a polycyclic compound according to an embodiment in an emission layer were prepared using the following method. Light emitting elements of Examples 1 to 6 were prepared by respectively using Compounds 4, 73, 96, 97, 133, and 154, which are the Example Compounds described above, as a dopant material of an emission layer. Comparative Examples 1 to 3 respectively correspond to light emitting elements prepared respectively using Comparative Example Compound C1 to C3 as a dopant material of an emission layer.

### Example Compound

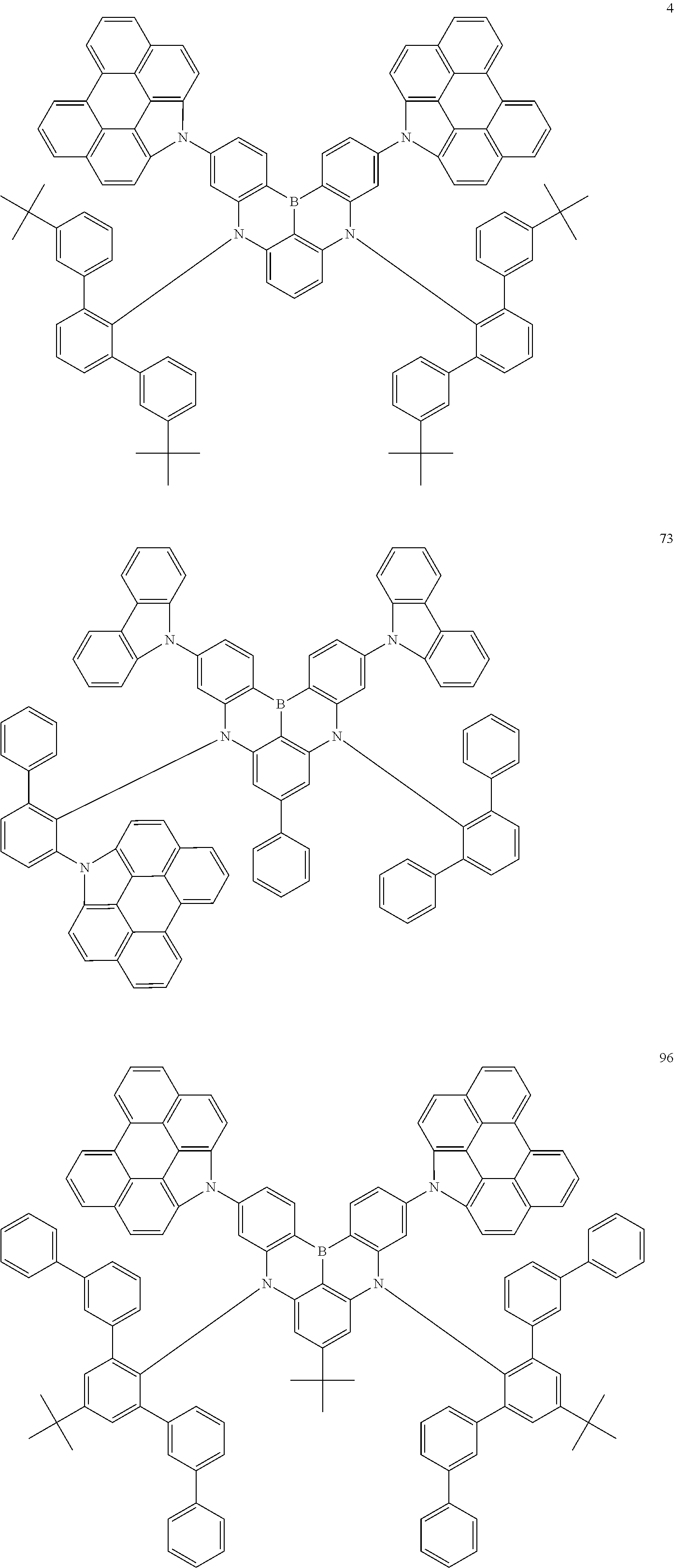

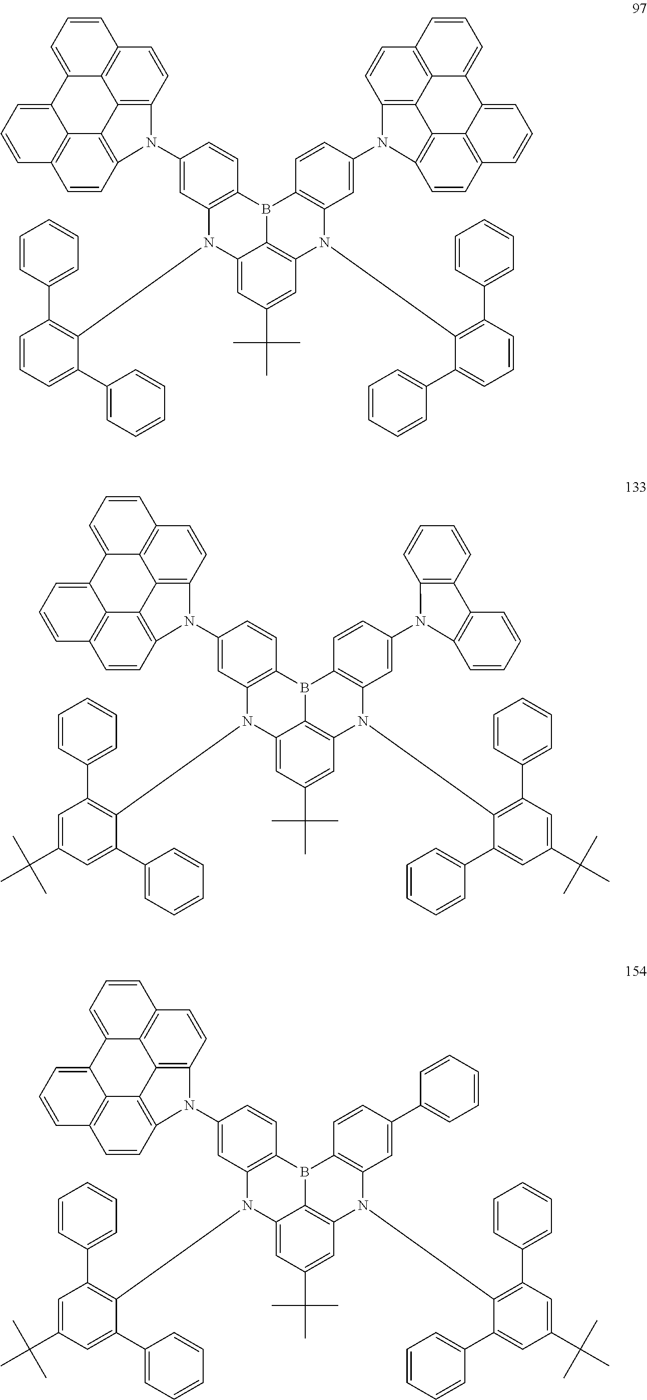

### Comparative Example Compound

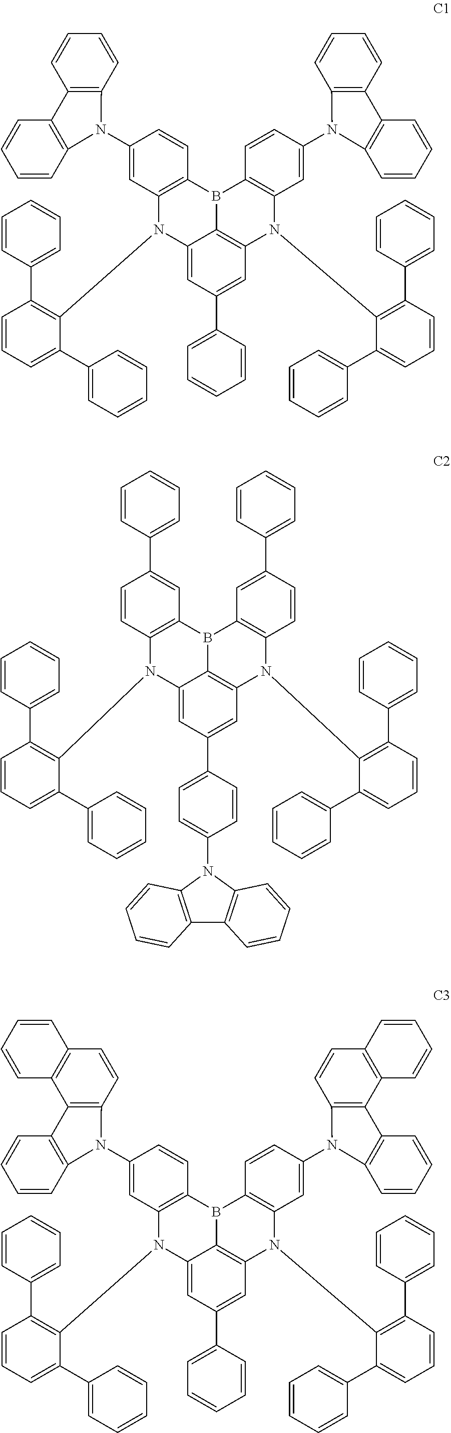 [SMILES: c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)cc1 ; c1ccc(-c2ccc3c(c2)B2c4cc(-c5ccccc5)ccc4N(c4c(-c5ccccc5)cccc4-c4ccccc4)c4cc(-c5ccc(-n6c7ccccc7c7ccccc76)cc5)cc(c42)N3c2c(-c3ccccc3)cccc2-c2ccccc2)cc1 ; c1ccc(-c2cc3c4c(c2)N(c2c(-c5ccccc5)cccc2-c2ccccc2)c2cc(-n5c6ccccc6c6c7ccccc7ccc65)ccc2B4c2ccc(-n4c5ccccc5c5c6ccccc6ccc54)cc2N3c2c(-c3ccccc3)cccc2-c2ccccc2)cc1]

### (Preparation of Light Emitting Elements)

As for the light emitting elements of the Examples and Comparative Examples, as an anode, a glass substrate having an ITO electrode (Corning, 15 Ω/cm², 1200 Å) formed thereon was cut to a size of about 50 mm×50 mm×0.7 mm, subjected to ultrasonic cleaning using isopropyl alcohol and pure water for 5 minutes and ultraviolet irradiation for 30 minutes, and exposed to ozone for cleaning to be mounted on a vacuum deposition apparatus.

On an upper portion of the anode, a hole injection layer having a thickness of 300 Å was formed through deposition of NPD, and on an upper portion of the hole injection layer, a hole transport layer having a thickness of 200 Å was formed through deposition of hole transport layer materials, and on an upper portion of the hole transport layer, an auxiliary emission layer having a thickness of 100 Å was formed through deposition of CzSi.

On an upper portion of the auxiliary emission layer, an emission layer having a thickness of 200 Å was formed through the co-deposition of a host mixture in which a second compound and a third compound were mixed in a ratio of 5:5, a fourth compound, and an Example Compound or a Comparative Example Compound in a weight ratio of 85:14:1. On an upper portion of the emission layer, a hole blocking layer having a thickness of 200 Å was formed through deposition of TSPO1, and on an upper portion of the hole blocking layer, an electron transport layer having a thickness of 300 Å was formed through deposition of TPBi, and on an upper portion of the electron transport layer, an electron injection layer having a thickness of 10 Å was formed through deposition of LiF. On an upper portion of the electron injection layer, a second electrode EL2 having a thickness of 3000 Å was formed using Al to form a LiF/Al electrode. A capping layer having a thickness of 700 Å was formed using P4 on an upper portion of the electrode.

Each layer was formed through vacuum deposition. For the hole transport layer materials, the second compound, the third compound, and the fourth compound, materials listed in Table 2 were used.

The compounds used in the preparation of the light emitting elements of the Examples and Comparative Examples are disclosed below. The following materials were used for the preparation of the elements after sublimation-purifying commercially available products.

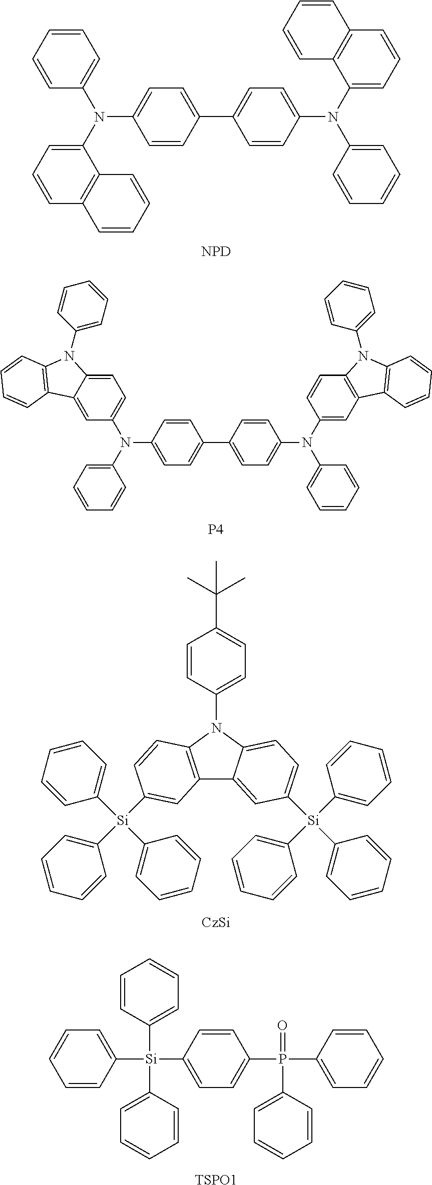

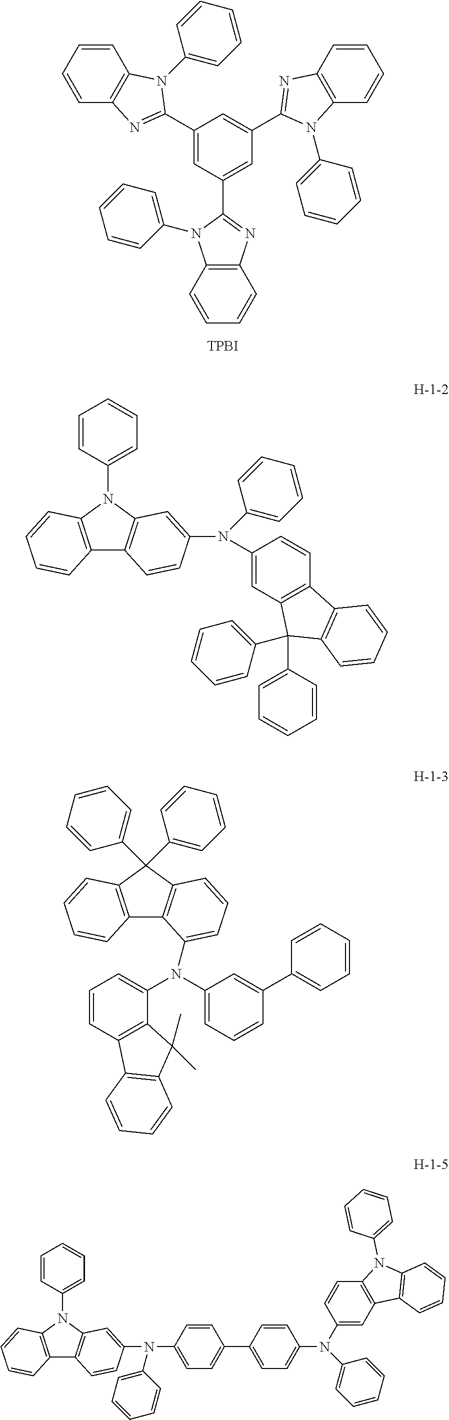

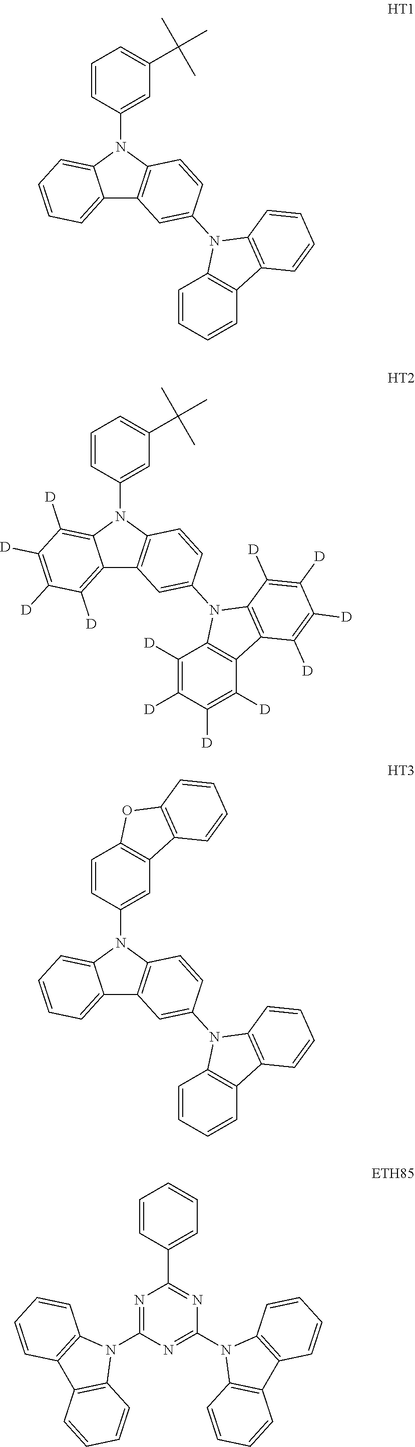

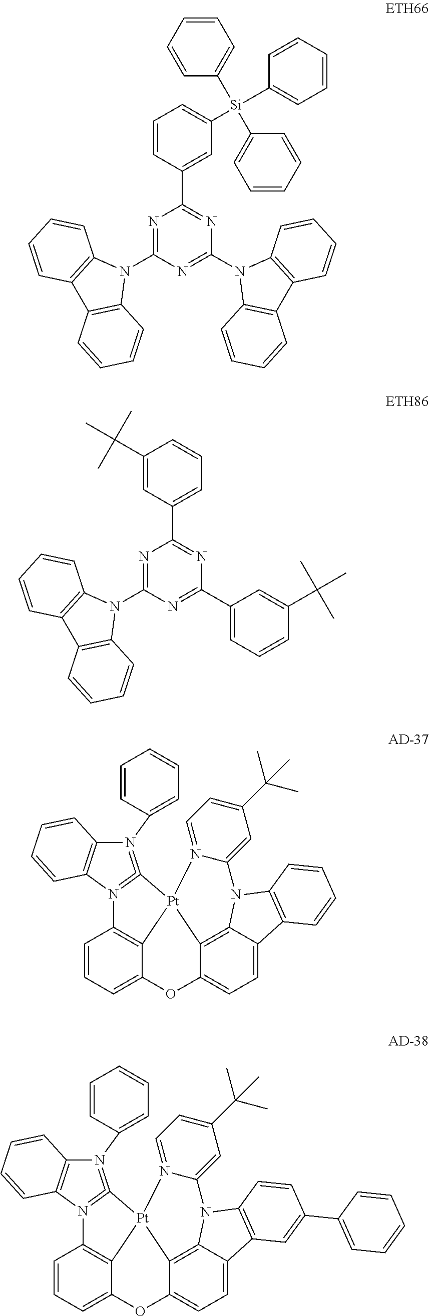

### (Property Evaluation of Light Emitting Elements)

### 1) Evaluation of Physical Properties of Example Compounds and Comparative Example Compounds

Table 1 shows the physical properties of Compound 4, 73, 96, 97, 133, and 154, which are Example Compounds, and Compounds C1 to C3, which are Comparative Example Compounds. Table 1 shows the results of measuring the lowest excited singlet energy level (Si level), lowest excited triplet energy level (T1 level), and triplet exciton lifetime (tau) of Example Compounds and Comparative Example Compounds.

S1 and T1 were measured using FluorEssence software on fluoromax+ spectrometer from HORIBA equipped with a xenon light source and monochromator. Tau was measured using ps Laser (PL2251, PG401) from EKSPLA as excitation light on streak camera (scope: C10627, spectrograph C11119-04) from Hamamatsu.

TABLE 1

| | S1_max | T1_max | Single Tau_TrEL |
|---|---|---|---|
| | (eV) | (eV) | (prompt 0~6 μs fit) (μs) |
| Compound 4 | 2.88 | 1.85 | 1.31 |
| Compound 73 | 2.91 | 1.86 | 1.21 |
| Compound 96 | 2.89 | 1.84 | 1.33 |
| Compound 97 | 2.89 | 1.83 | 1.22 |
| Compound 133 | 2.85 | 1.88 | 1.31 |
| Compound 154 | 2.85 | 1.86 | 1.27 |
| Comparative Example | 2.96 | 2.57 | 8.7 |
| Compound C1 | | | |
| Comparative Example | 3.03 | 2.58 | 9.2 |
| Compound C2 | | | |
| Comparative Example | 2.92 | 1.93 | 5.4 |
| Compound C3 | | | |

Referring to the results in Table 1, Compounds 4, 73, 96, 97, 133, and 154, which are polycyclic compounds of the Examples, have a low T1 level, and thus a triplet exciton at a high level transferred to emitters is quenched right away through a non-luminescent transition without going through RISC, resulting in reduced stress on the emitter and thus increased lifetime of light emitting elements. The properties of the polycyclic compound according to an embodiment were determined from transient electroluminescence measurements.

As shown in Table 1, it is determined that Compounds 4, 73, 96, 97, 133, and 154, which are polycyclic compounds according to an embodiment, have a shorter exciton lifetime in fluorescence (prompt) than the Comparative Example compounds, and have increased lifetime with no use of a triplet emission path exhibiting similar behavior to fluorescence and emission centered on S1 and thus having relatively low stability.

### 2) Property Evaluation of Light Emitting Element

Element efficiency and element service life of the light emitting elements prepared using Compounds 4, 73, 96, 97, 133, and 154, and Comparative Example Compounds C1 to C3 described above were evaluated. Table 2 shows results of evaluation on light emitting elements for Examples 1 to 6 and Comparative Examples 1 to 3. In the characteristic evaluation results for Examples and Comparative Examples shown in Table 2, driving voltage (V), luminous efficiency (Cd/A), and luminous color were each measured using Keithley MU 236 and luminance meter PR650. Maximum external quantum efficiency was measured using Quantaurus-Tau. In addition, a time taken for luminance to reach 95% with respect to an initial luminance was determined as lifetime (T₉₅), and relative lifetime was calculated with respect to Comparative Example 1, and the results are shown in Table 2.

TABLE 2

| | | | | | | | Maximum | | |
|---|---|---|---|---|---|---|---|---|---|
| | Hole | Host (2nd | | | | | external | Element | |
| | transport | compound:3rd | | | Driving | | quantum | service | |
| | layer | compound = | 4th | Dopant | voltage | Efficiency | efficiency | life | Emitted |
| | material | 5:5) | compound | compound | (V) | (cd/A) | (%) | (%) | color |
| Example 1 | H-1-2 | HT1/ETH85 | AD-37 | Compound 4 | 4.3 | 17.4 | 15.9 | 132 | Blue |
| Example 2 | H-1-3 | HT2/ETH86 | AD-38 | Compound 73 | 4.3 | 20.1 | 19.7 | 103 | Blue |
| Example 3 | H-1-3 | HT2/ETH66 | AD-38 | Compound 96 | 4.4 | 18.2 | 17.1 | 123 | Blue |
| Example 4 | H-1-2 | HT1/ETH66 | AD-38 | Compound 97 | 4.3 | 18.0 | 16.8 | 120 | Blue |
| Example 5 | H-1-3 | HT2/ETH86 | AD-37 | Compound 133 | 4.3 | 21.2 | 20.1 | 143 | Blue |
| Example 6 | H-1-5 | HT1/ETH66 | AD-38 | Compound 154 | 4.2 | 18.7 | 17.6 | 130 | Blue |
| Comparative | H-1-3 | HT3/ETH66 | AD-38 | Comparative | 4.3 | 22.1 | 21.8 | 100 | Blue |
| Example 1 | | | | Example | | | | | |
| | | | | Compound C1 | | | | | |
| Comparative | H-1-5 | HT2/ETH66 | AD-37 | Comparative | 4.4 | 18.3 | 17.5 | 85 | Blue |
| Example 2 | | | | Example | | | | | |
| | | | | Compound C2 | | | | | |
| Comparative | H-1-2 | HT1/ETH66 | AD-37 | Comparative | 4.4 | 12.3 | 11.5 | 75 | Blue |
| Example 3 | | | | Example | | | | | |
| | | | | Compound C3 | | | | | |

Referring to the results of Table 2, it is determined that the light emitting elements of the Examples using the polycyclic compound according to an embodiment as light emitting materials emit blue light. It is seen that the light emitting elements of Examples using the polycyclic compound according to an embodiment as light emitting materials exhibit excellent luminous efficiency and lifetime, low driving voltage, and satisfactory maximum external quantum efficiency. It is confirmed that compounds of the Comparative Examples show driving voltage levels similar to those of the polycyclic compound according to an embodiment, and the light emitting elements of the Comparative Examples using these Comparative Example compounds as light emitting materials also emit blue light.

It is seen that the polycyclic compound according to an embodiment has at least one phenanthro-carbazole group linked to the core, and thus has significantly improved lifetime compared to the Comparative Example compounds.

Comparative Example 1 shows excellent luminous efficiency, just like the Examples using the polycyclic compound according to an embodiment as a light emitting material. However, Comparative Example 1 uses Comparative Example Compound C1 with no phenanthro-carbazole group in molecules, as a light emitting material, and shows reduced element life compared to the Examples. It is seen that Comparative Examples 2 and 3 use compounds, in which a phenanthro-carbazole group is not linked to the core, as light emitting materials, and thus show reduced lifetime compared to the light emitting elements of the Examples.

A light emitting element according to an embodiment may exhibit improved element characteristics of long service life.

A polycyclic compound according to an embodiment is included in an emission layer of a light emitting element, and may thus contribute to the long service life of a light emitting element.

A display device according to an embodiment may exhibit high display quality.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A light emitting element comprising:
a first electrode;
a second electrode disposed on the first electrode; and
an emission layer disposed between the first electrode and the second electrode and including a first compound represented by Formula 1: 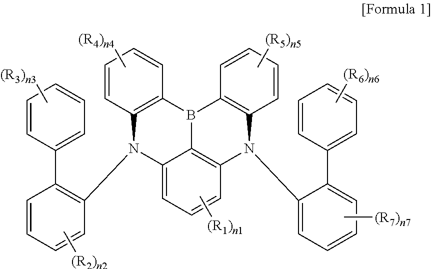
wherein in Formula 1,
R₁ to R₇ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkoxy group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n1 is an integer from 0 to 3,
n2, n4, n5, and n7 are each independently an integer from 0 to 4,
n3 and n6 are each independently an integer from 0 to 5, and
at least one of R₁ to R₇ is each independently a group represented by Formula 2: 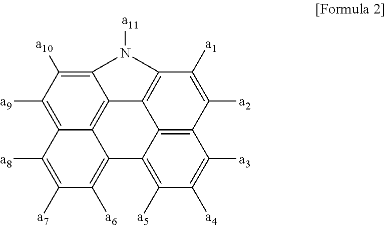
wherein in Formula 2,
one of a₁ to a₁₁ is a position bonded to Formula 1, and
the remainder of a₁ to a₁₁ are each independently a hydrogen atom, a deuterium atom, a substituted or unsubstituted alkyl group having 1 to 30 carbon atoms, or a substituted or unsubstituted aryl group having 6 to 30 ring-forming carbon atoms.

2. The light emitting element of claim 1, wherein
a₁, a₃ to a₈, and a₁₀ are each independently a hydrogen atom or a deuterium atom,
a₂ and a₉ are each independently a hydrogen atom, a deuterium atom, a substituted or unsubstituted t-butyl group, or a substituted or unsubstituted phenyl group, and
a₁₁ is a position bonded to Formula 1.

3. The light emitting element of claim 1, wherein the first compound is represented by Formula 3: 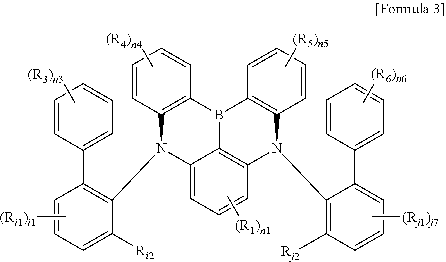
wherein in Formula 3,
Rᵢ₁ and Rⱼ₁ are each independently a hydrogen atom, a deuterium atom, a substituted or unsubstituted alkyl group having 1 to 60 carbon atoms, or a substituted or unsubstituted aryl group having 6 to 60 ring-forming carbon atoms,
Rᵢ₂ and Rⱼ₂ are each independently a substituted or unsubstituted aryl group having 6 to 60 ring-forming carbon atoms, or a substituted or unsubstituted heteroaryl group having 2 to 60 ring-forming carbon atoms,
i1 and j1 are each independently an integer from 0 to 3,
R₁, R₃ to R₆, n1, and n3 to n6 are each the same as defined in Formula 1, and
at least one of R₁, R₃ to R₆, Rᵢ₂, and Rⱼ₂ is each independently a group represented by Formula 2.

4. The light emitting element of claim 1, wherein the first compound is represented by one of Formulas 4-1 to 4-3: 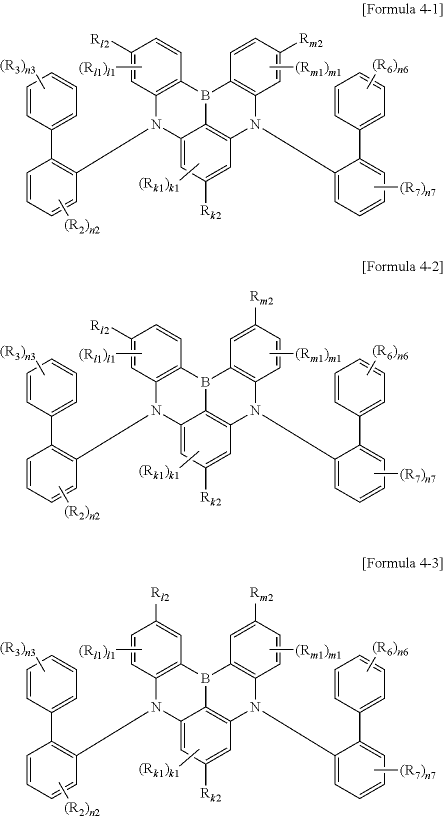
wherein in Formulas 4-1 to 4-3,
Rₖ₁, Rₗ₁, and Rₘ₁ are each independently a hydrogen atom, a deuterium atom, a substituted or unsubstituted alkyl group having 1 to 60 carbon atoms, or a substituted or unsubstituted aryl group having 6 to 60 ring-forming carbon atoms,
Rₖ₂, Rₗ₂, and Rₘ₂ are each independently a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms,
k1 is an integer from 0 to 2,
l1 and m1 are each independently an integer from 0 to 3,
R₂, R₃, R₆, R₇, n2, n3, n6, and n7 are each the same as defined in Formula 1, and
at least one of R₂, R₃, R₆, R₇, Rₖ₂, Rₗ₂, and Rₘ₂ is each independently a group represented by Formula 2.

5. The light emitting element of claim 1, wherein the first compound is represented by one of Formulas 5-1 to 5-4: 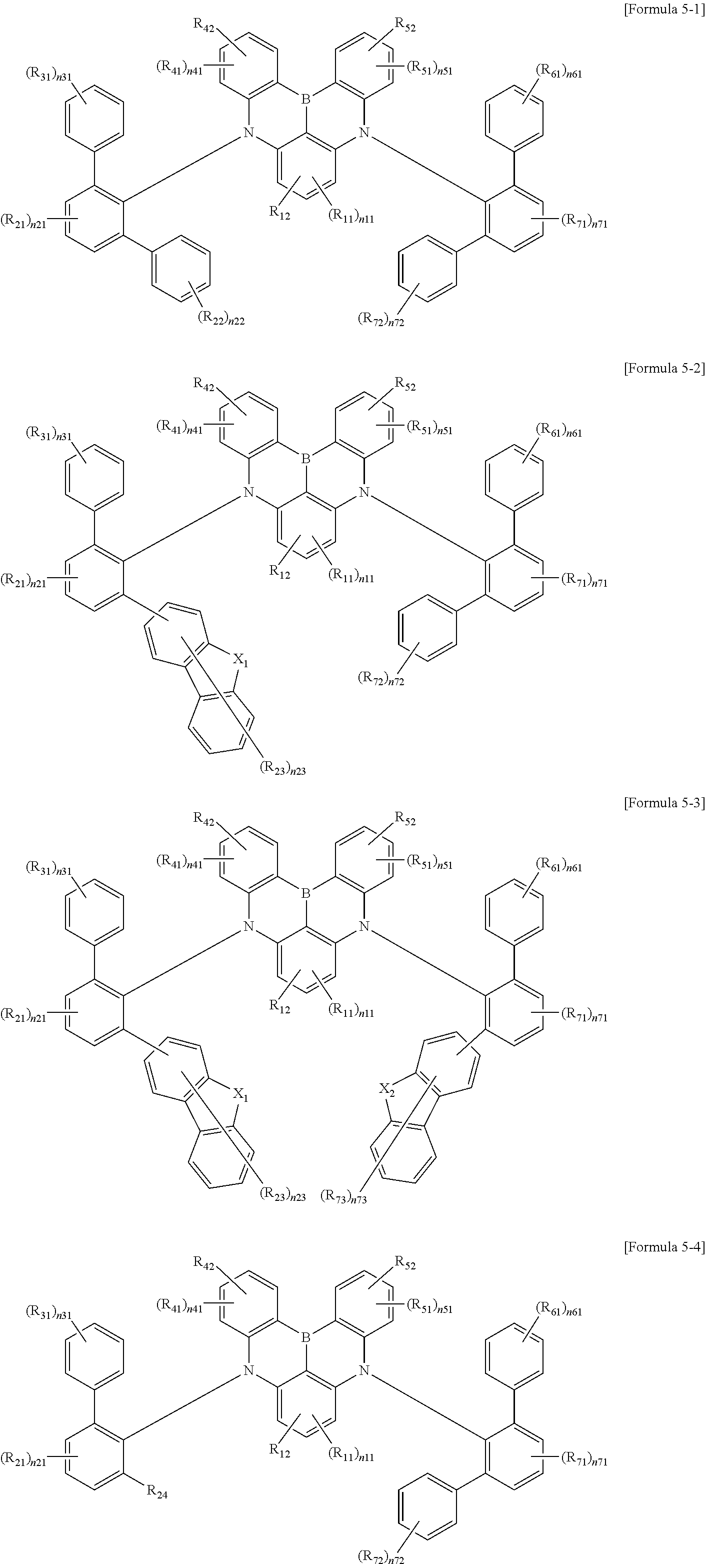
wherein in Formulas 5-1 to 5-4,
R₁₁, R₂₁, R₂₂, R₂₃, R₃₁, R₄₁, R₅₁, R₆₁, R₇₁, R₇₂, and R₇₃ are each independently a hydrogen atom, a deuterium atom, a substituted or unsubstituted alkyl group having 1 to 60 carbon atoms, or a substituted or unsubstituted aryl group having 6 to 60 ring-forming carbon atoms, or R₃₁ and R₆₁ are bonded to adjacent groups to form a ring,
R₁₂, R₂₄, R₄₂, and R₅₂ are each independently a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms,
n11 is an integer from 0 to 2,
n21, n41, n51, and n71 are each independently an integer from 0 to 3,
n22, n31, n61, and n72 are each independently an integer from 0 to 5, and
n23 and n73 are each independently an integer from 0 to 7,
wherein in Formulas 5-2 and 5-3,
X₁ and X₂ are each independently O or S,
wherein in Formulas 5-1 to 5-3,
at least one of R₁₂, R₄₂, and R₅₂ is each independently a group represented by Formula 2,
wherein in Formula 5-4,
at least one of R₁₂, R₂₄, R₄₂, and R₅₂ is each independently a group represented by Formula 2.

6. The light emitting element of claim 5, wherein the first compound is represented by one of Formulas 5-1-1 to 5-1-6: 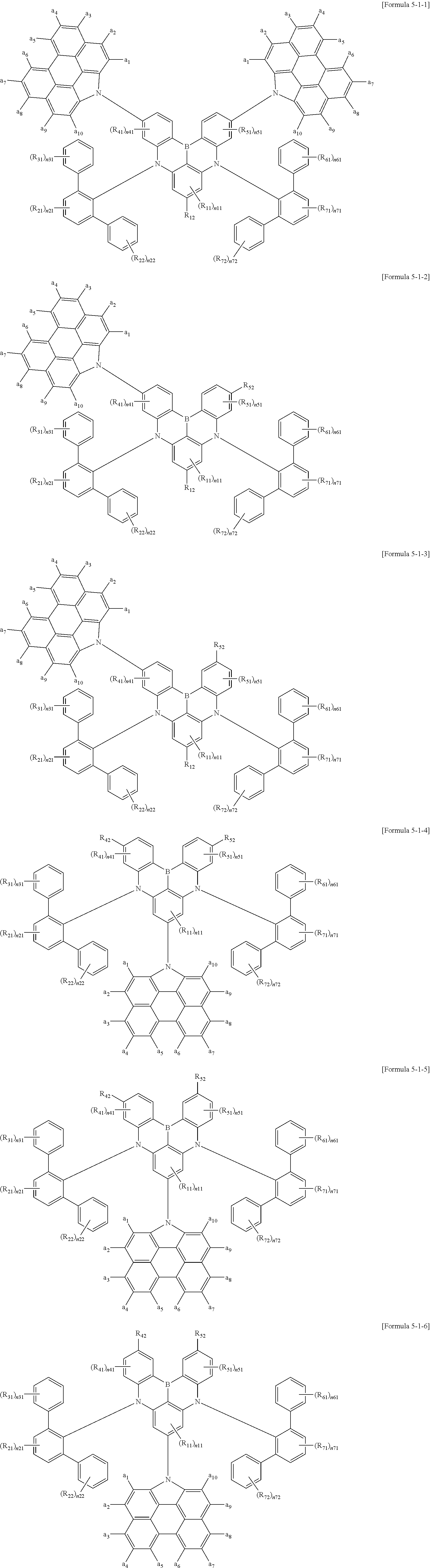
wherein in Formulas 5-1-1 to 5-1-6,
a₁ to a₁₀ are each independently a hydrogen atom or a deuterium atom, and
R₁₁, R₁₂, R₂₁, R₂₂, R₃₁, R₄₁, R₄₂, R₅₁, R₅₂, R₆₁, R₇₁, R₇₂, n11, n21, n22, n31, n41, n51, n61, n71, and n72 are each the same as defined in Formula 5-1.

7. The light emitting element of claim 5, wherein the first compound is represented by Formula 5-2-1: 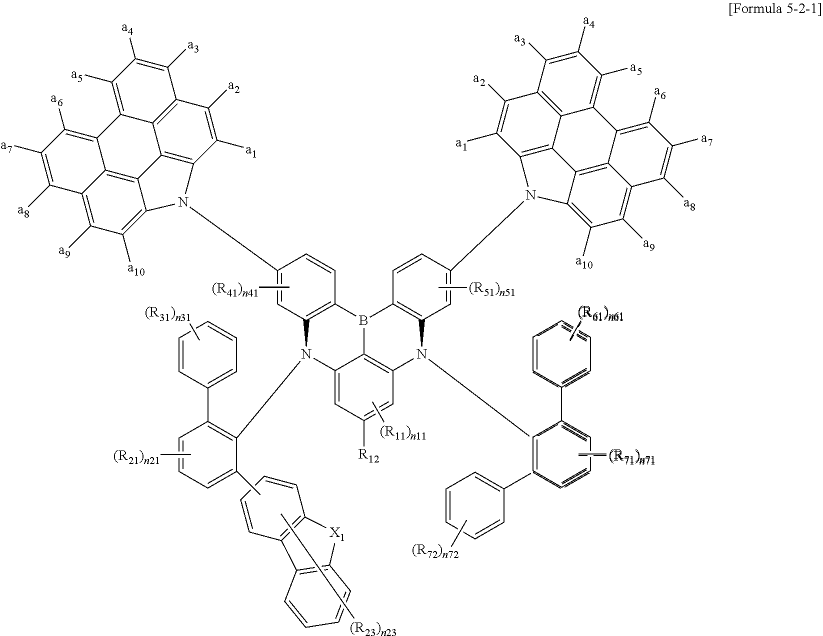
wherein in Formula 5-2-1,
a₁ to a₁₀ are each independently a hydrogen atom or a deuterium atom, and
X₁, R₁₁, R₁₂, R₂₁, R₂₃, R₃₁, R₄₁, R₅₁, R₆₁, R₇₁, R₇₂, n11, n21, n23, n31, n41, n51, n61, n71, and n72 are each the same as defined in Formula 5-2.

8. The light emitting element of claim 5, wherein the first compound is represented by Formula 5-3-1: 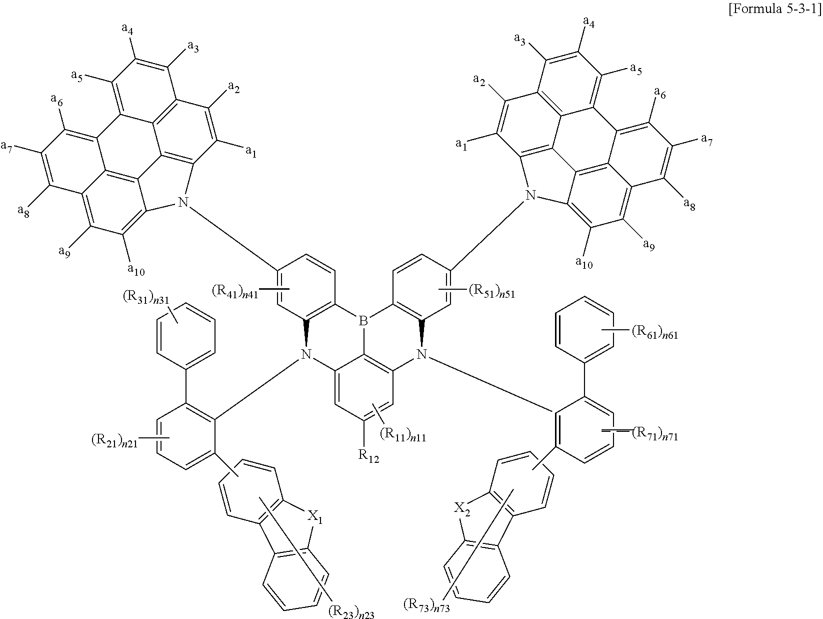
wherein in Formula 5-3-1,
a₁ to a₁₀ are each independently a hydrogen atom or a deuterium atom, and
X₁, X₂, R₁₁, R₁₂, R₂₁, R₂₃, R₃₁, R₄₁, R₅₁, R₆₁, R₇₁, R₇₃, n11, n21, n23, n31, n41, n51, n61, n71, and n73 are each the same as defined in Formula 5-3.

9. The light emitting element of claim 1, wherein
one or two of R₁ to R₇ are each independently a group represented by Formula 2, and
the remainder of R₁ to R₇ are each independently a hydrogen atom, a deuterium atom, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, a substituted or unsubstituted dibenzothiophene group, or bonded to an adjacent group to form a ring.

10. The light emitting element of claim 1, wherein in Formula 1, at least one of R₁ to R₇ is a deuterium atom or comprises a substituent containing a deuterium atom.

11. The light emitting element of claim 1, wherein the emission layer further comprises at least one of a second compound represented by Formula HT-1, a third compound represented by Formula ET-1, and a fourth compound represented by Formula D-1: 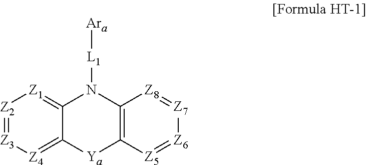
wherein in Formula HT-1,
Z₁ to Z₈ are each independently N or C(Rₐ₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(Rₐ₂)(Rₐ₃), or Si(Rₐ₄)(Rₐ₅),
Arₐ is a substituted or unsubstituted aryl group having 6 to 30 ring-forming carbon atoms, or a substituted or unsubstituted heteroaryl group having 2 to 30 ring-forming carbon atoms, and
Rₐ₁ to Rₐ₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; 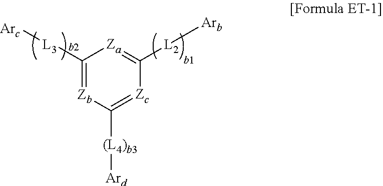
wherein in Formula ET-1,
at least one of Zₐ to Z_{c} is N,
the remainder of Zₐ to Z_{c} are each independently C(Rₐ₆),
Rₐ₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
Ar_{b} to Ar_{d} are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 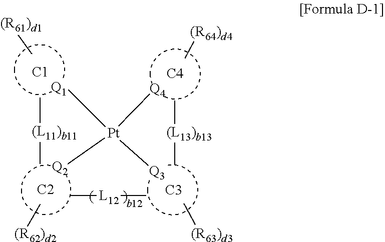
wherein in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 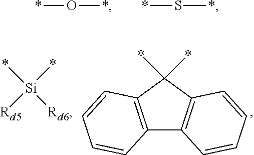
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R_{d1} to R_{d6} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer from 0 to 4.

12. The light emitting element of claim 11, wherein the emission layer further comprises the second compound, the third compound, and the fourth compound.

13. A polycyclic compound represented by Formula 1: 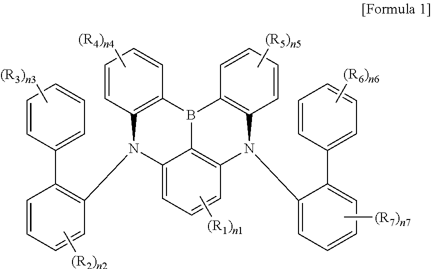
wherein in Formula 1,
R₁ to R₇ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkoxy group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n1 is an integer from 0 to 3,
n2, n4, n5, and n7 are each independently an integer from 0 to 4,
n3 and n6 are each independently an integer from 0 to 5, and
at least one of R₁ to R₇ is each independently a group represented by Formula 2: 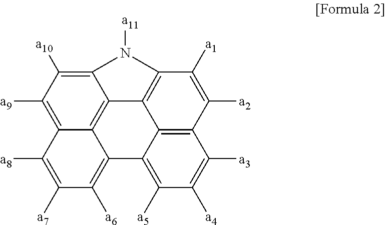
wherein in Formula 2,
one of a₁ to a₁₁ is a position bonded to Formula 1, and
the remainder of a₁ to a₁₁ are each independently a hydrogen atom, a deuterium atom, a substituted or unsubstituted alkyl group having 1 to 30 carbon atoms, or a substituted or unsubstituted aryl group having 6 to 30 ring-forming carbon atoms.

14. The polycyclic compound of claim 13, wherein
a₁, a₃ to a₈, and a₁₀ are each independently a hydrogen atom or a deuterium atom,
a₂ and a₉ are each independently a hydrogen atom, a deuterium atom, a substituted or unsubstituted t-butyl group, or a substituted or unsubstituted phenyl group, and
a₁₁ is a position bonded to Formula 1.

15. The polycyclic compound of claim 13, wherein the polycyclic compound is represented by Formula 3: 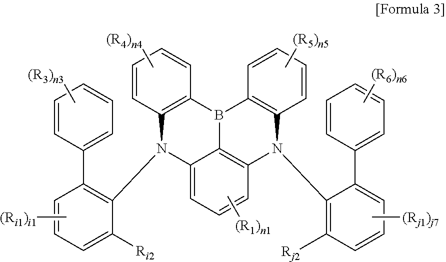
wherein in Formula 3,
Rᵢ₁ and Rⱼ₁ are each independently a hydrogen atom, a deuterium atom, a substituted or unsubstituted alkyl group having 1 to 60 carbon atoms, or a substituted or unsubstituted aryl group having 6 to 60 ring-forming carbon atoms,
Rᵢ₂ and Rⱼ₂ are each independently a substituted or unsubstituted aryl group having 6 to 60 ring-forming carbon atoms, or a substituted or unsubstituted heteroaryl group having 2 to 60 ring-forming carbon atoms,
i1 and j1 are each independently an integer from 0 to 3,
R₁, R₃ to R₆, n1, and n3 to n6 are each the same as defined in Formula 1, and
at least one of R₁, R₃ to R₆, Rᵢ₂, and Rⱼ₂ is each independently a group represented by Formula 2.

16. The polycyclic compound of claim 13, wherein the polycyclic compound is represented by one of Formulas 4-1 to 4-3: 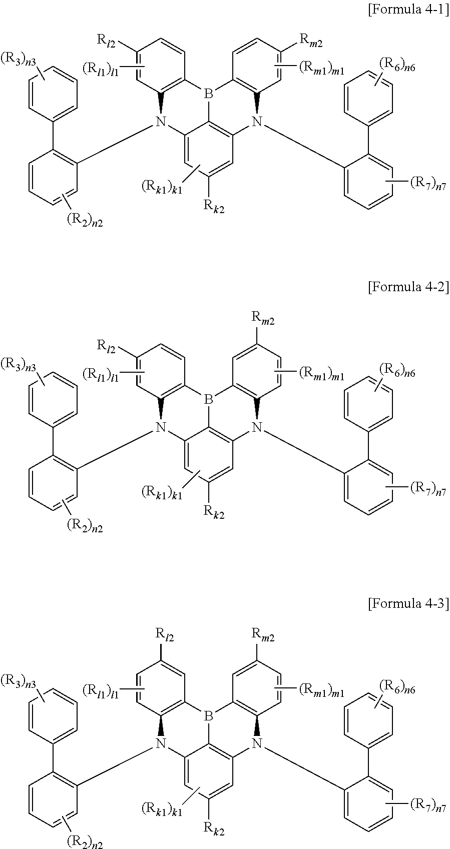
wherein in Formulas 4-1 to 4-3,
Rₖ₁, Rₗ₁, and Rₘ₁ are each independently a hydrogen atom, a deuterium atom, a substituted or unsubstituted alkyl group having 1 to 60 carbon atoms, or a substituted or unsubstituted aryl group having 6 to 60 ring-forming carbon atoms,
Rₖ₂, Rₗ₂, and Rₘ₂ are each independently a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms,
k1 is an integer from 0 to 2,
l1 and m1 are each independently an integer from 0 to 3,
R₂, R₃, R₆, R₇, n2, n3, n6, and n7 are each the same as defined in Formula 1, and at least one of R₂, R₃, R₆, R₇, Rₖ₂, Rₗ₂, and Rₘ₂ is each independently a group represented by Formula 2.

17. The polycyclic compound of claim 13, wherein the polycyclic compound is represented by one of Formulas 5-1 to 5-4: 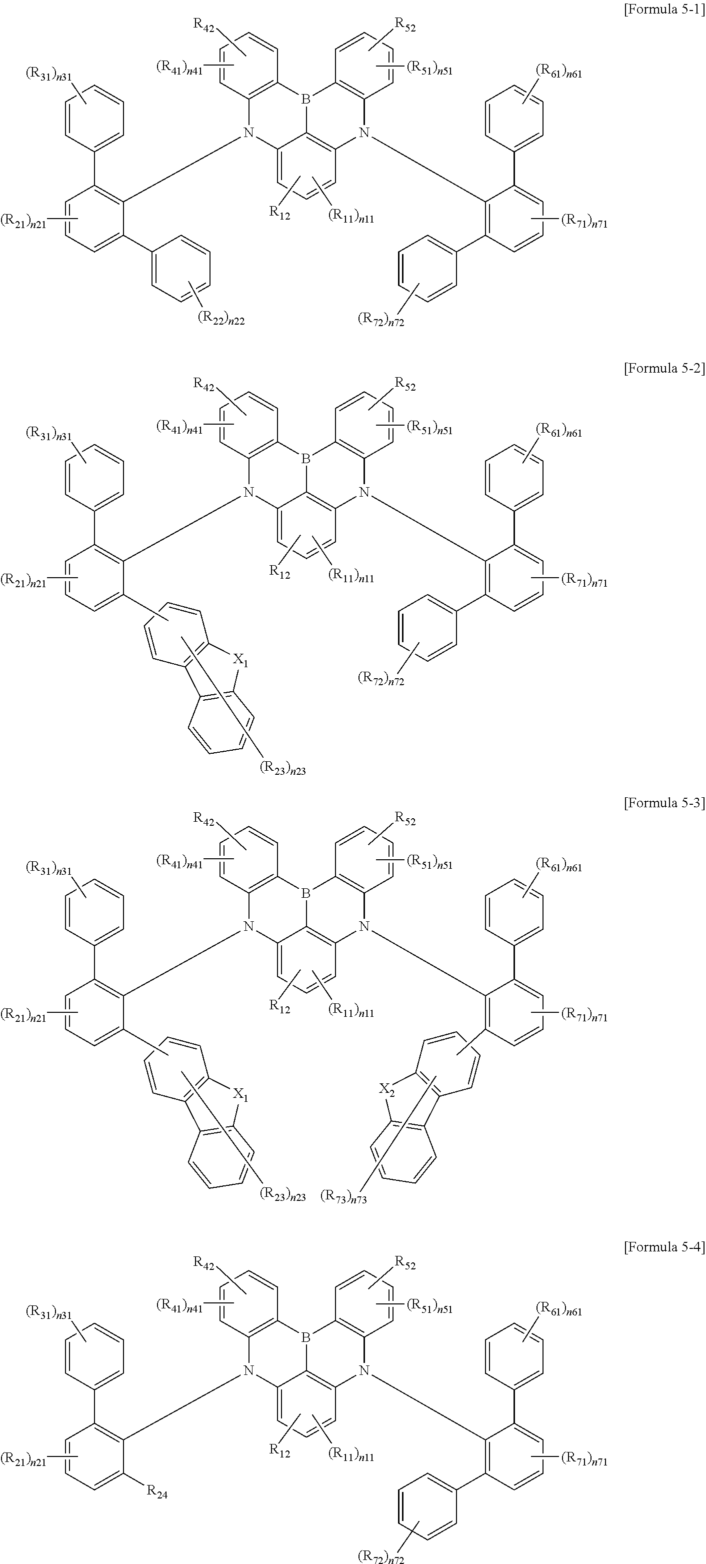
wherein in Formulas 5-1 to 5-4,
R₁₁, R₂₁, R₂₂, R₂₃, R₃₁, R₄₁, R₅₁, R₆₁, R₇₁, R₇₂, and R₇₃ are each independently a hydrogen atom, a deuterium atom, a substituted or unsubstituted alkyl group having 1 to 60 carbon atoms, or a substituted or unsubstituted aryl group having 6 to 60 ring-forming carbon atoms, or R₃₁ and R₆₁ are bonded to adjacent groups to form a ring,
R₁₂, R₂₄, R₄₂, and R₅₂ are each independently a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms,
n11 is an integer from 0 to 2,
n21, n41, n51, and n71 are each independently an integer from 0 to 3,
n22, n31, n61, and n72 are each independently an integer from 0 to 5, and
n23 and n73 are each independently an integer from 0 to 7,
wherein in Formulas 5-2 and 5-3,
X₁ and X₂ are each independently O or S,
wherein in Formulas 5-1 to 5-3,
at least one of R₁₂, R₄₂, or R₅₂ is each independently a group represented by Formula 2, wherein in Formula 5-4,
at least one of R₁₂, R₂₄, R₄₂, and R₅₂ is each independently a group represented by Formula 2.

18. The polycyclic compound of claim 13, wherein
one or two of R₁ to R₇ are each independently a group represented by Formula 2, and
the remainder of R₁ to R₇ are each independently a hydrogen atom, a deuterium atom, a substituted or unsubstituted t-butyl group, a substituted or unsubstituted phenyl group, a substituted or unsubstituted biphenyl group, a substituted or unsubstituted carbazole group, a substituted or unsubstituted dibenzofuran group, or a substituted or unsubstituted dibenzothiophene group, or bonded to an adjacent group to form a ring.

19. The polycyclic compound of claim 13, wherein a triplet exciton lifetime is less than or equal to about 2 μs.

20. The polycyclic compound of claim 13, wherein the polycyclic compound is selected from Compound Group 1:

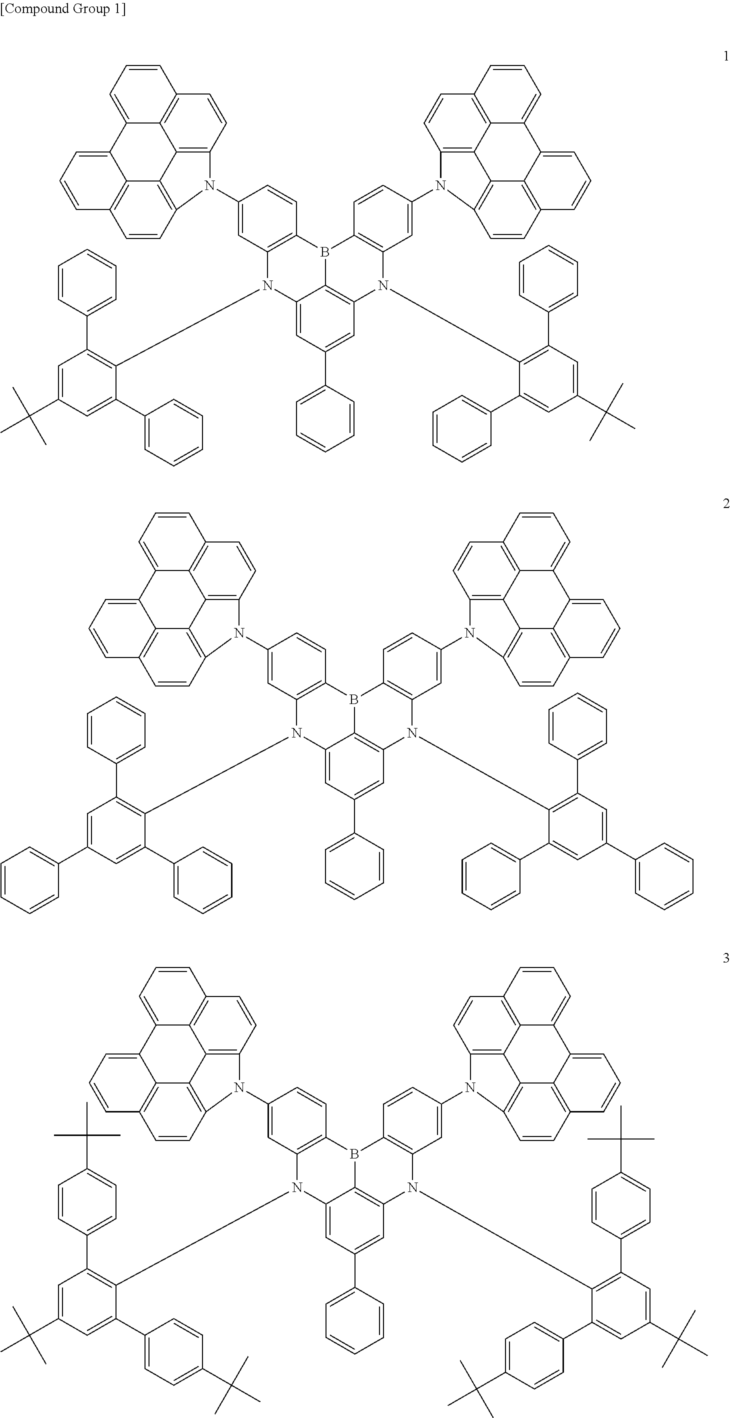

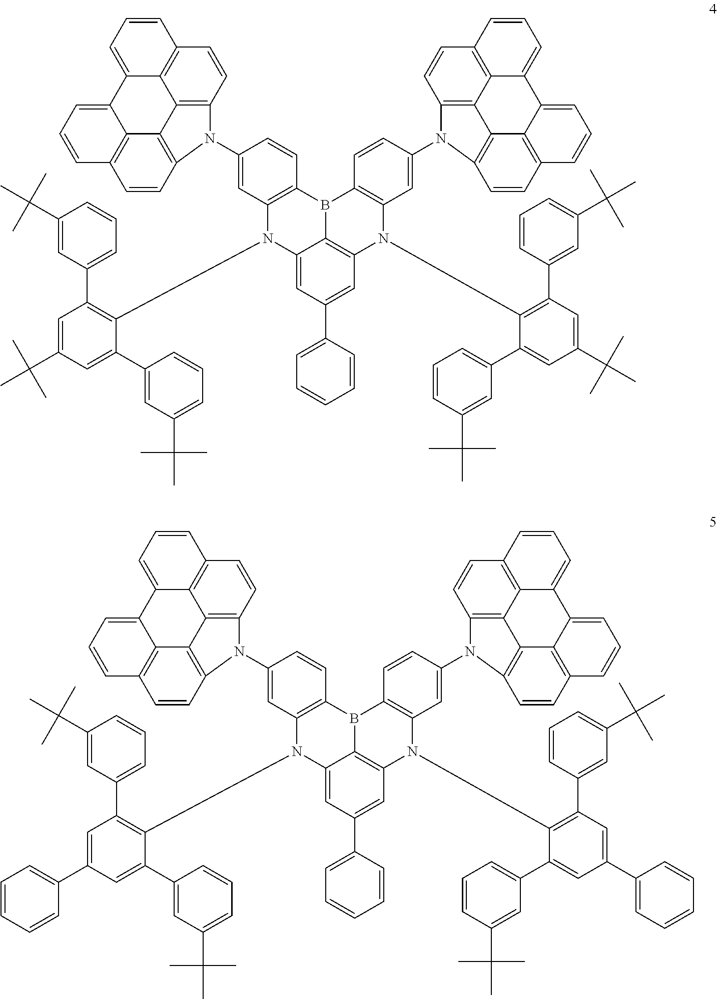 [SMILES: CC(C)(C)c1cccc(-c2cc(C(C)(C)C)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(-c5ccccc5)cc2c43)c1 ; CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(-c5ccccc5)cc2c43)c1]

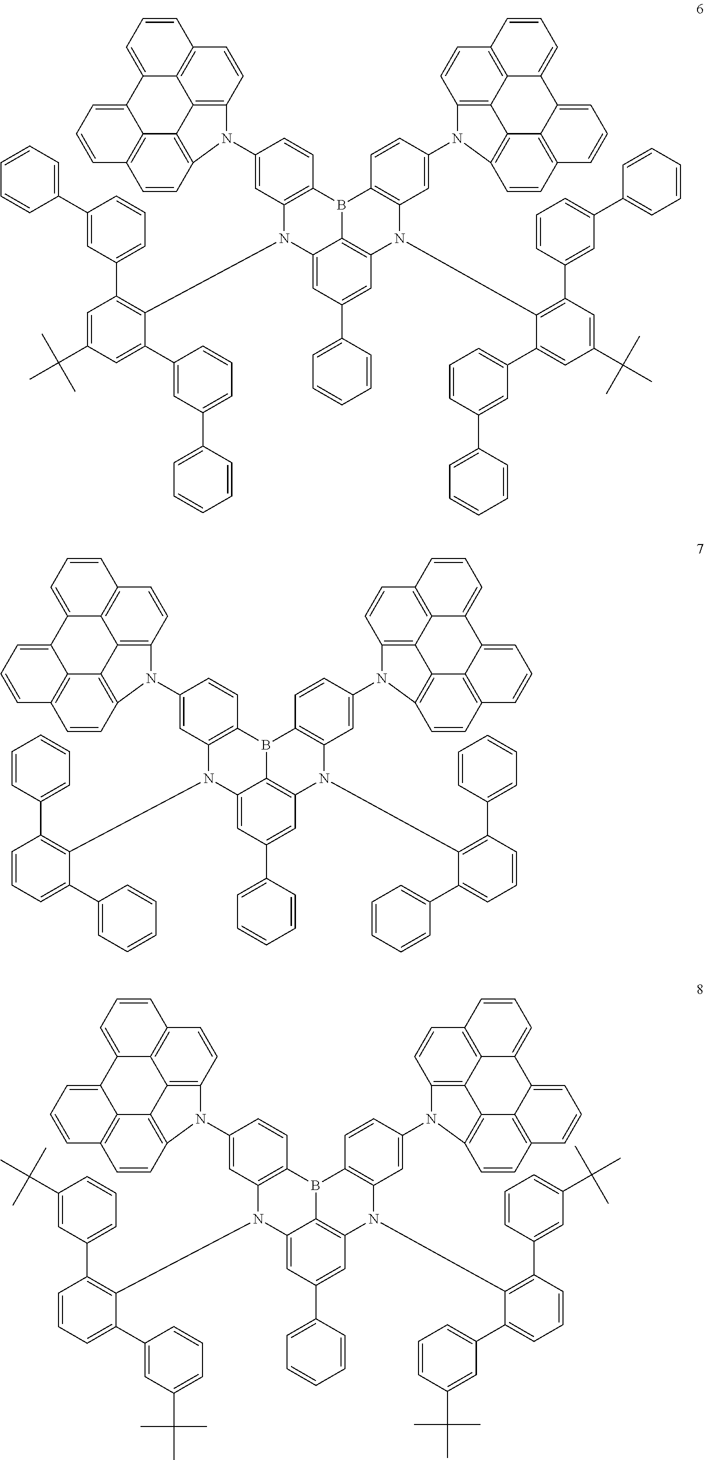

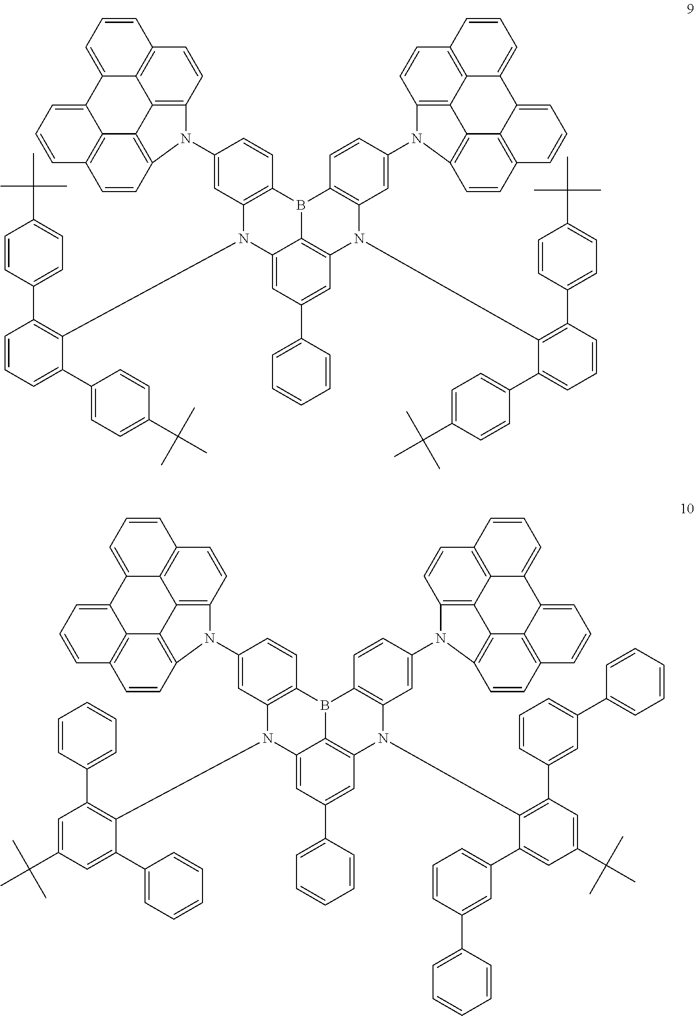

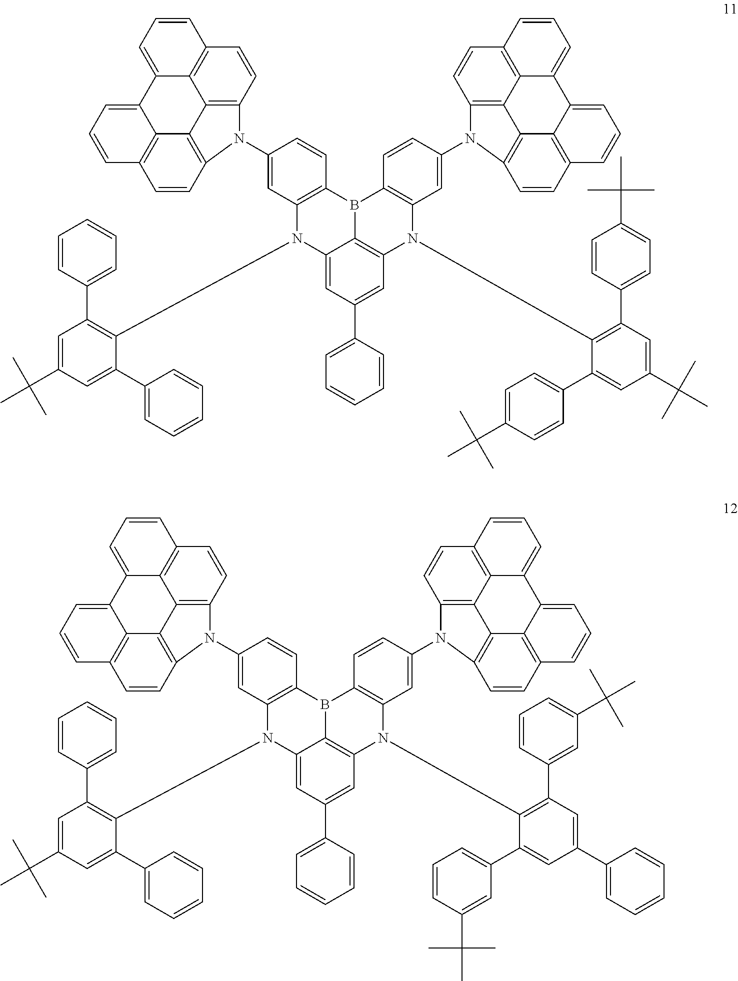

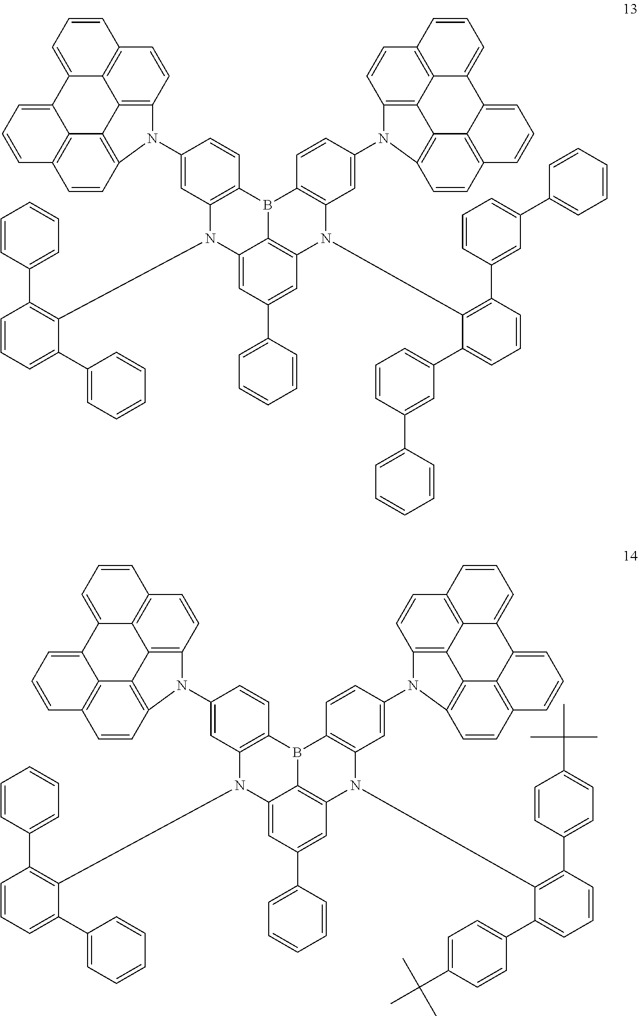 [SMILES: c1ccc(-c2cccc(-c3cccc(-c4cccc(-c5ccccc5)c4)c3N3c4cc(-n5c6ccc7cccc8c9cccc%10ccc5c(c%109)c6c78)ccc4B4c5ccc(-n6c7ccc8cccc9c%10cccc%11ccc6c(c%11%10)c7c89)cc5N(c5c(-c6ccccc6)cccc5-c5ccccc5)c5cc(-c6ccccc6)cc3c54)c2)cc1 ; CC(C)(C)c1ccc(-c2cccc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(-c5ccccc5)cc2c43)cc1]

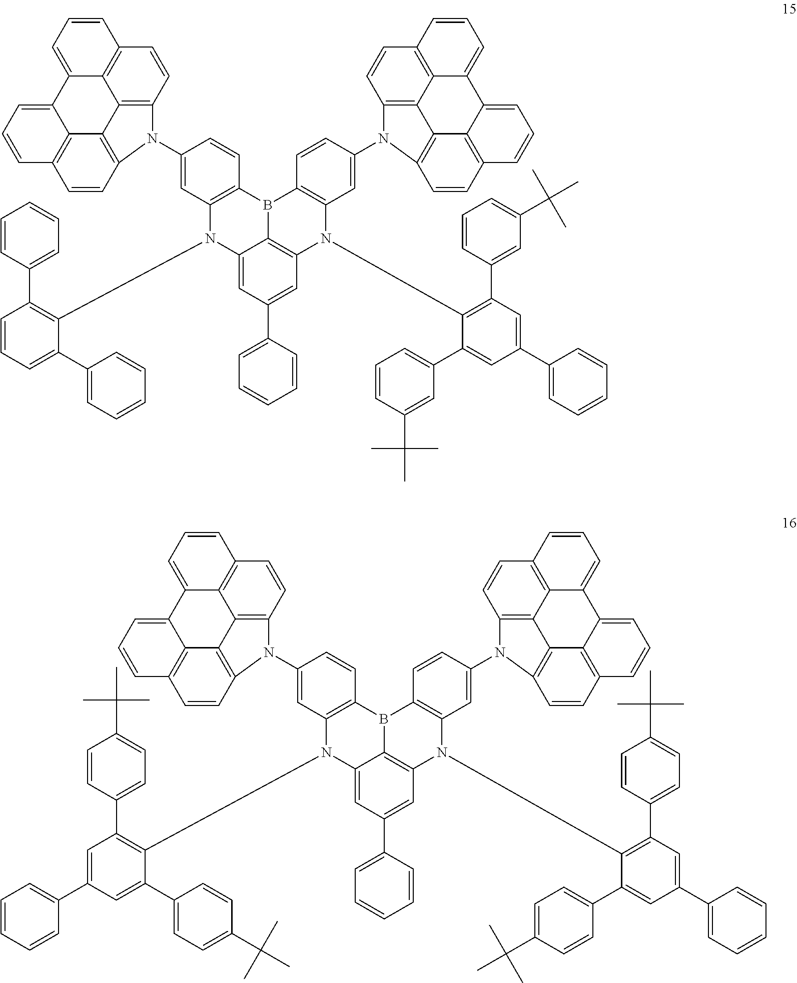 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(-c5ccccc5)cc2c43)c1 ; CC(C)(C)c1ccc(-c2cc(-c3ccccc3)cc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(-c5ccccc5)cc2c43)cc1]

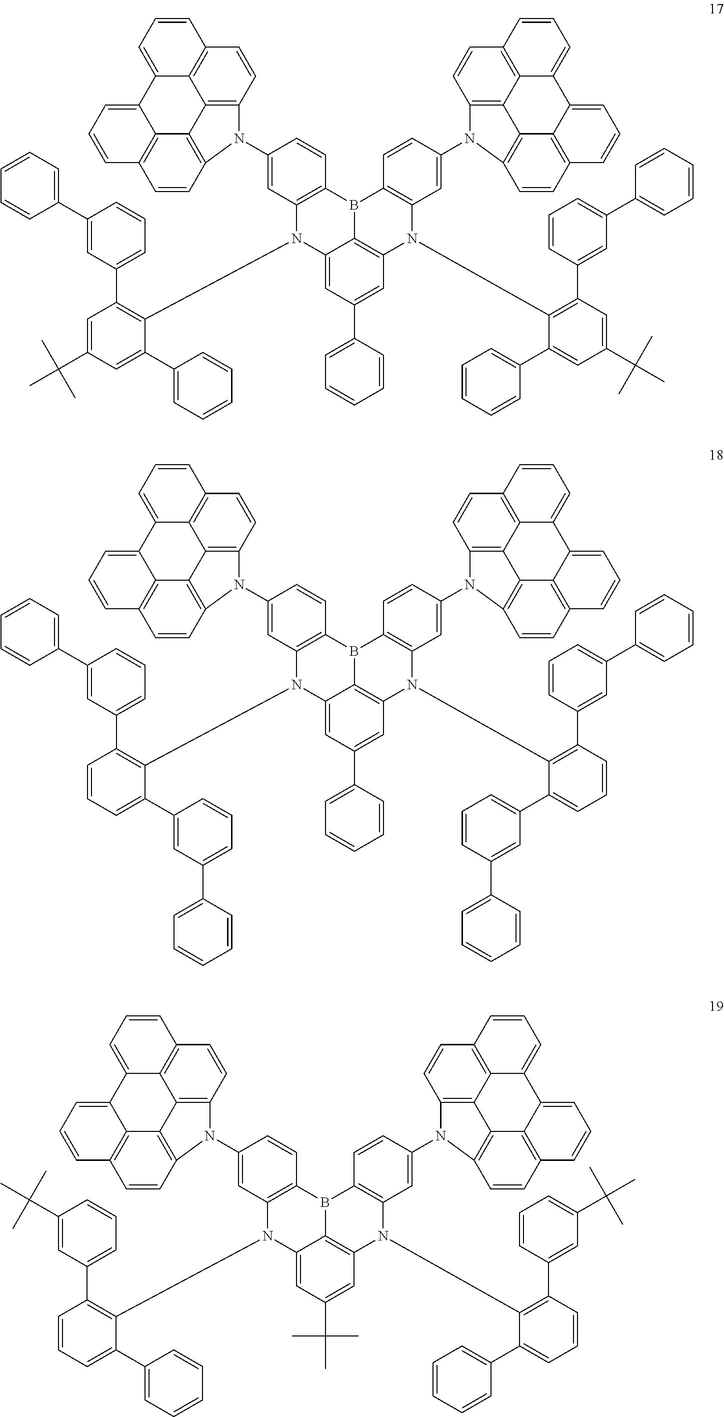

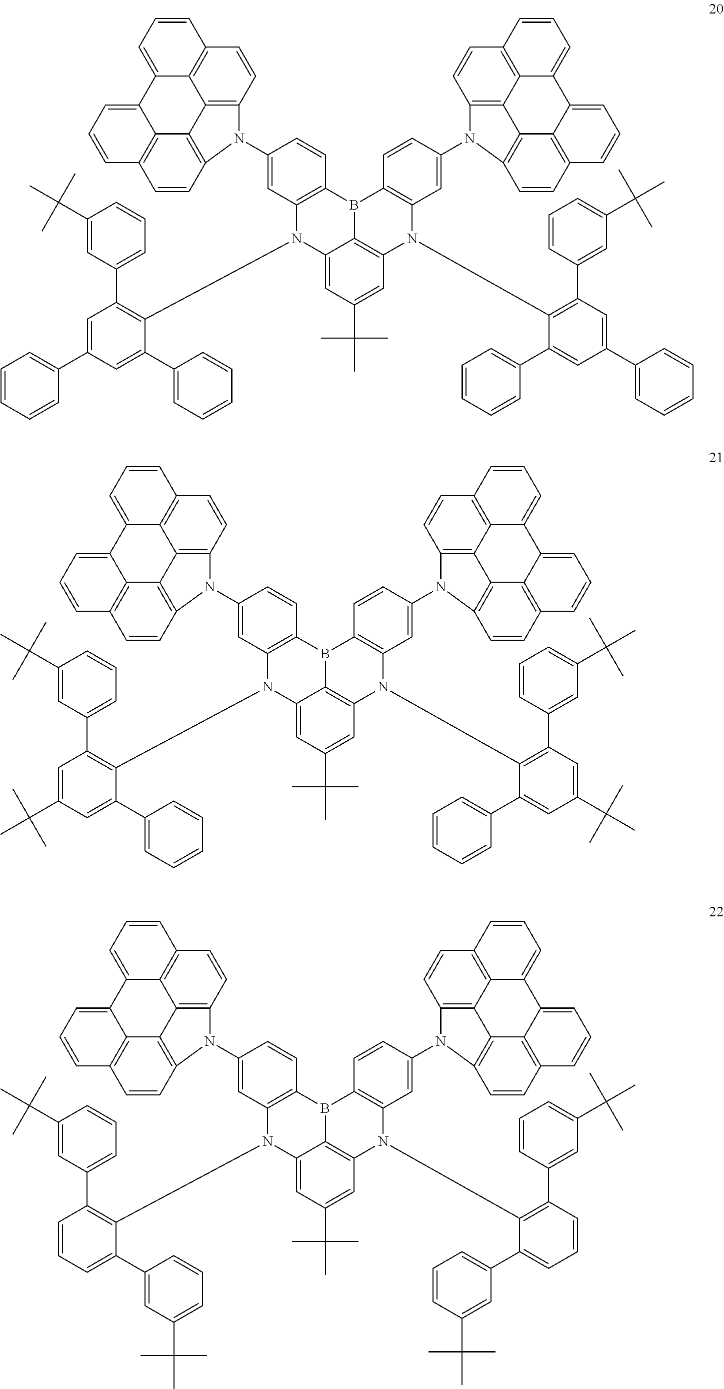

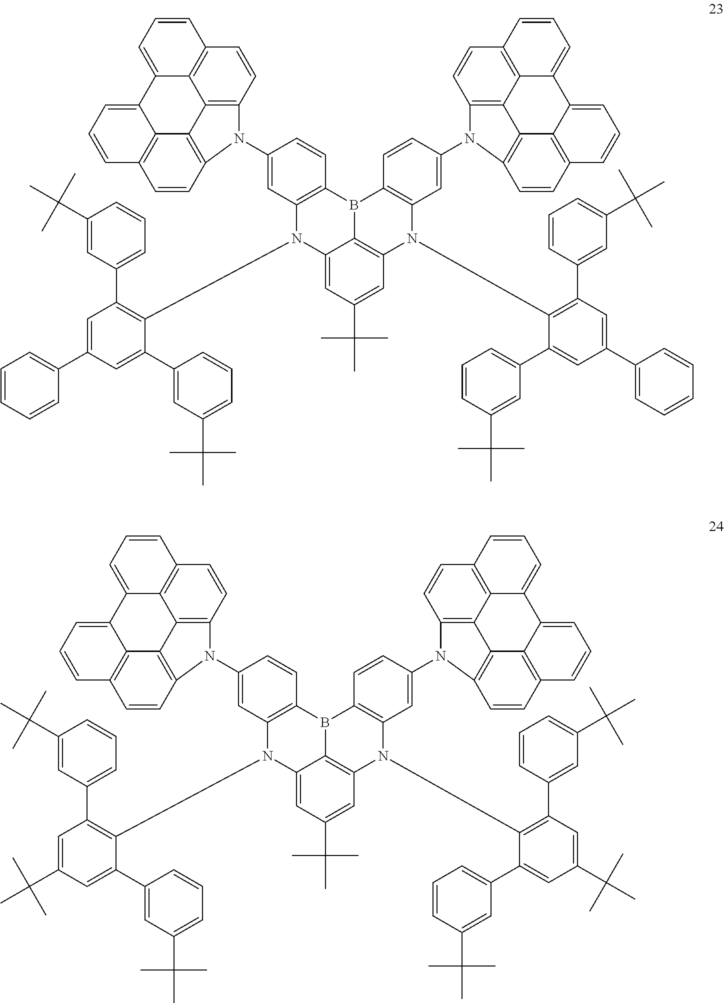 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cccc(-c2cc(C(C)(C)C)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(C(C)(C)C)cc2c43)c1]

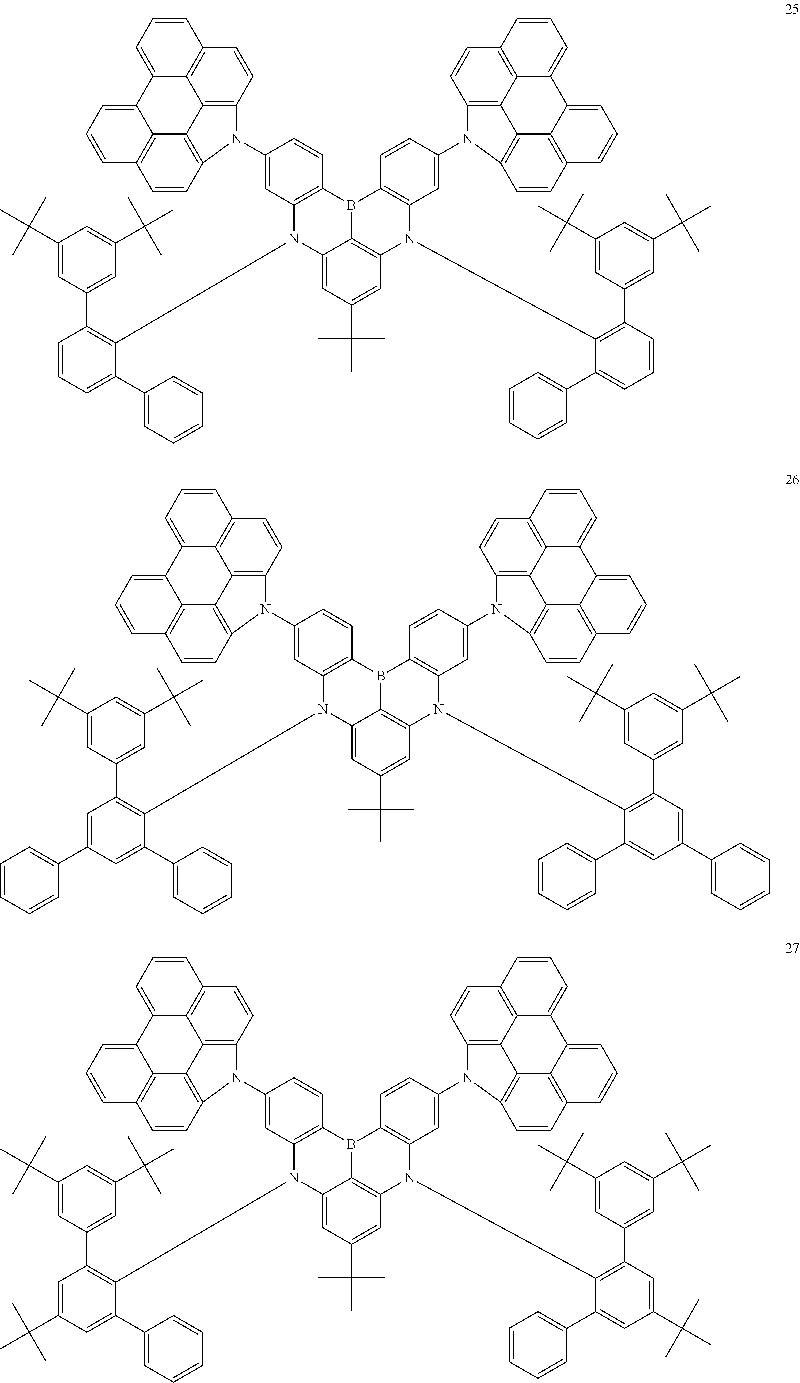

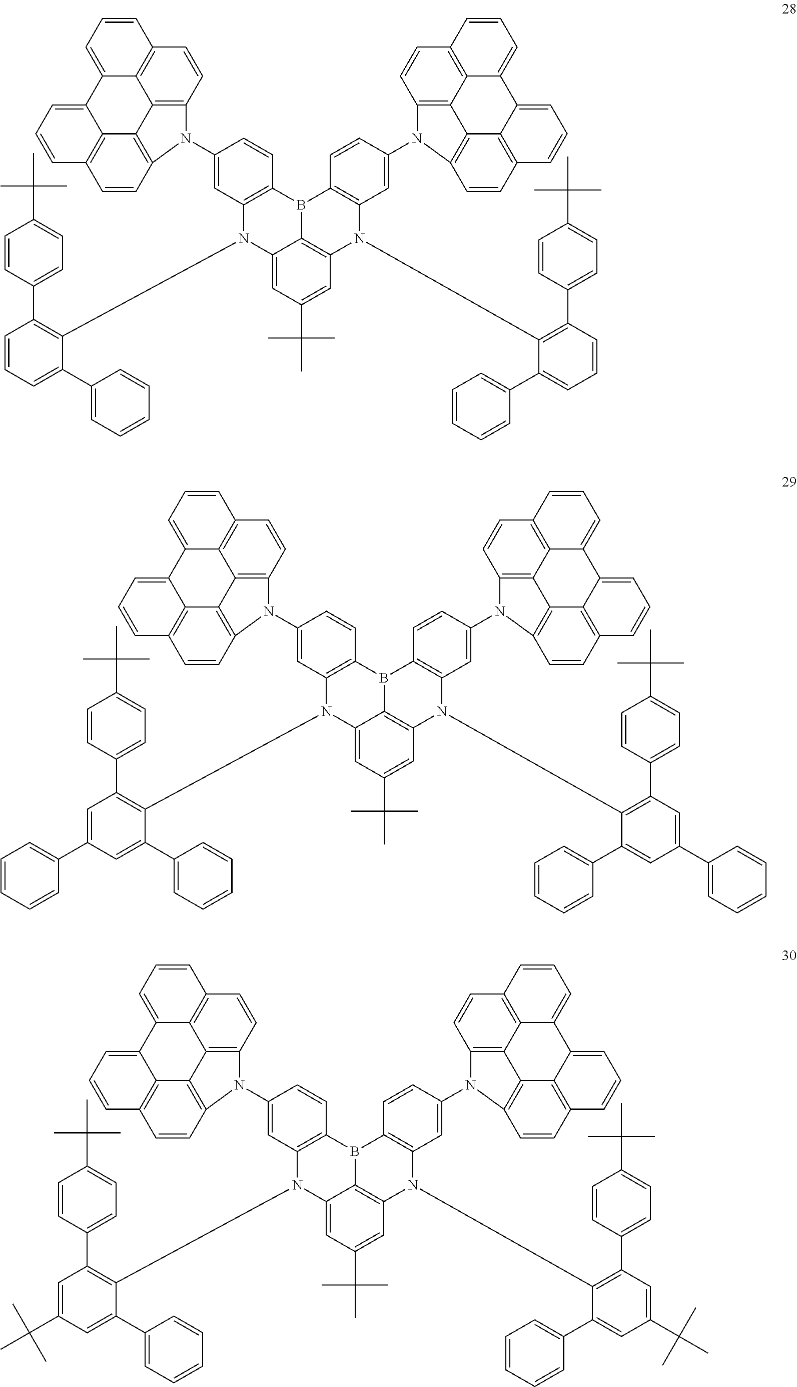

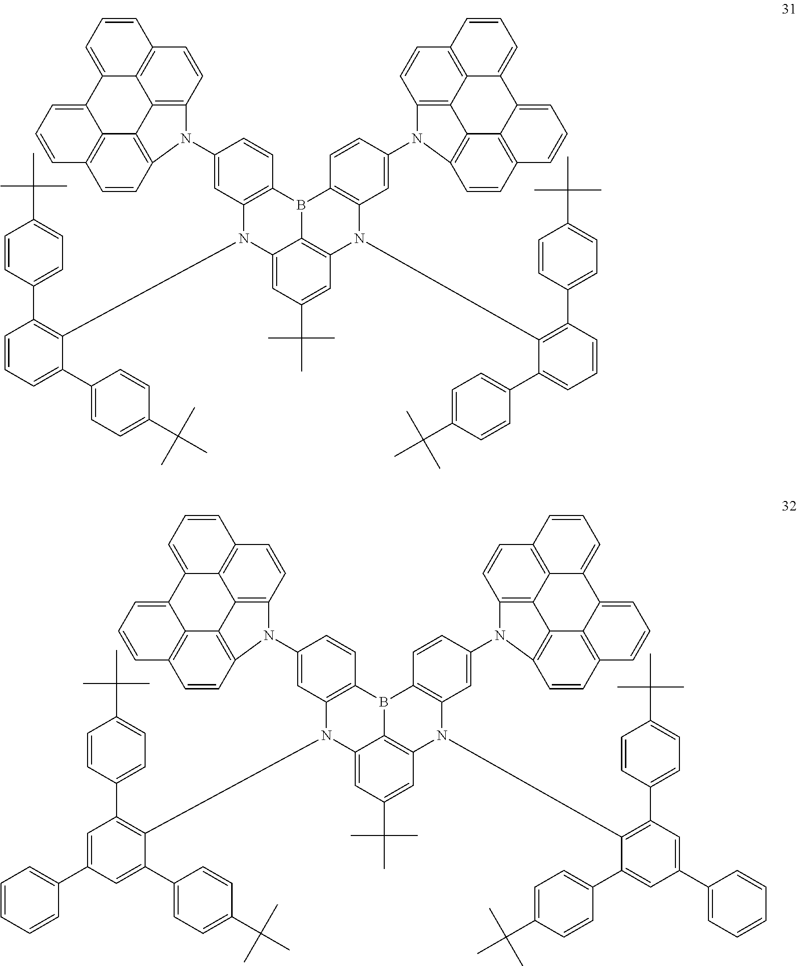 [SMILES: CC(C)(C)c1ccc(-c2cccc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(-c2cc(-c3ccccc3)cc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

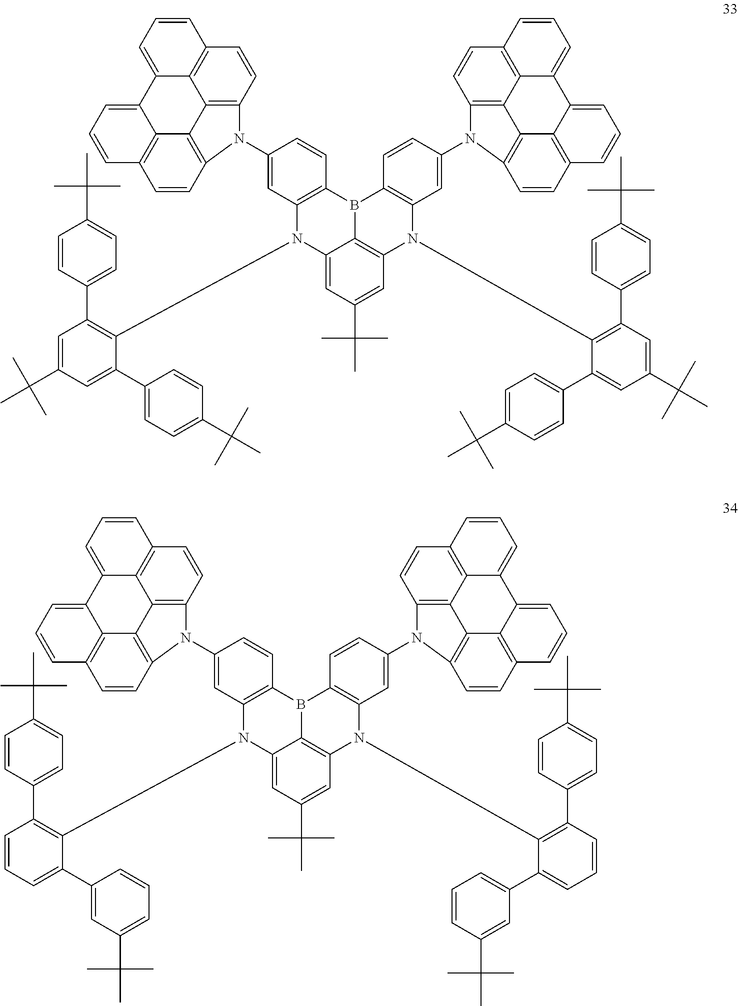

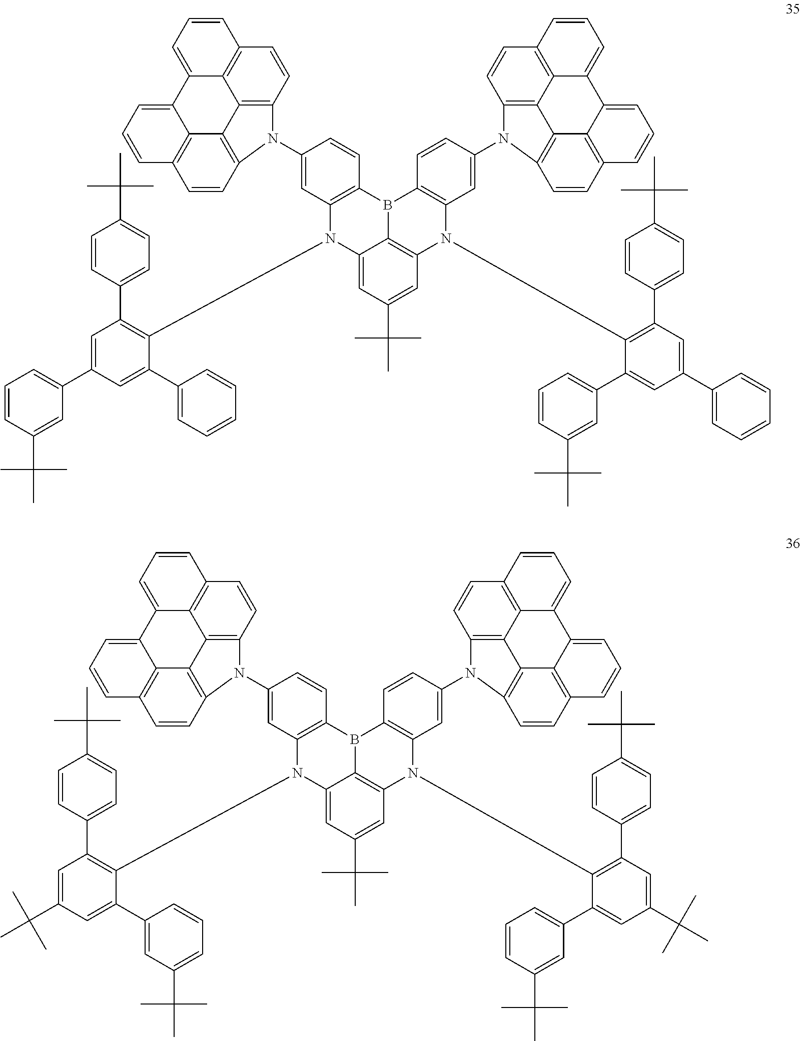 [SMILES: CC(C)(C)c1ccc(-c2cc(-c3cccc(C(C)(C)C)c3)cc(-c3ccccc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4cccc(C(C)(C)C)c4)c4cc(C(C)(C)C)cc2c43)cc1 ; CC(C)(C)c1ccc(-c2cc(C(C)(C)C)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4cccc(C(C)(C)C)c4)c4cc(C(C)(C)C)cc2c43)cc1]

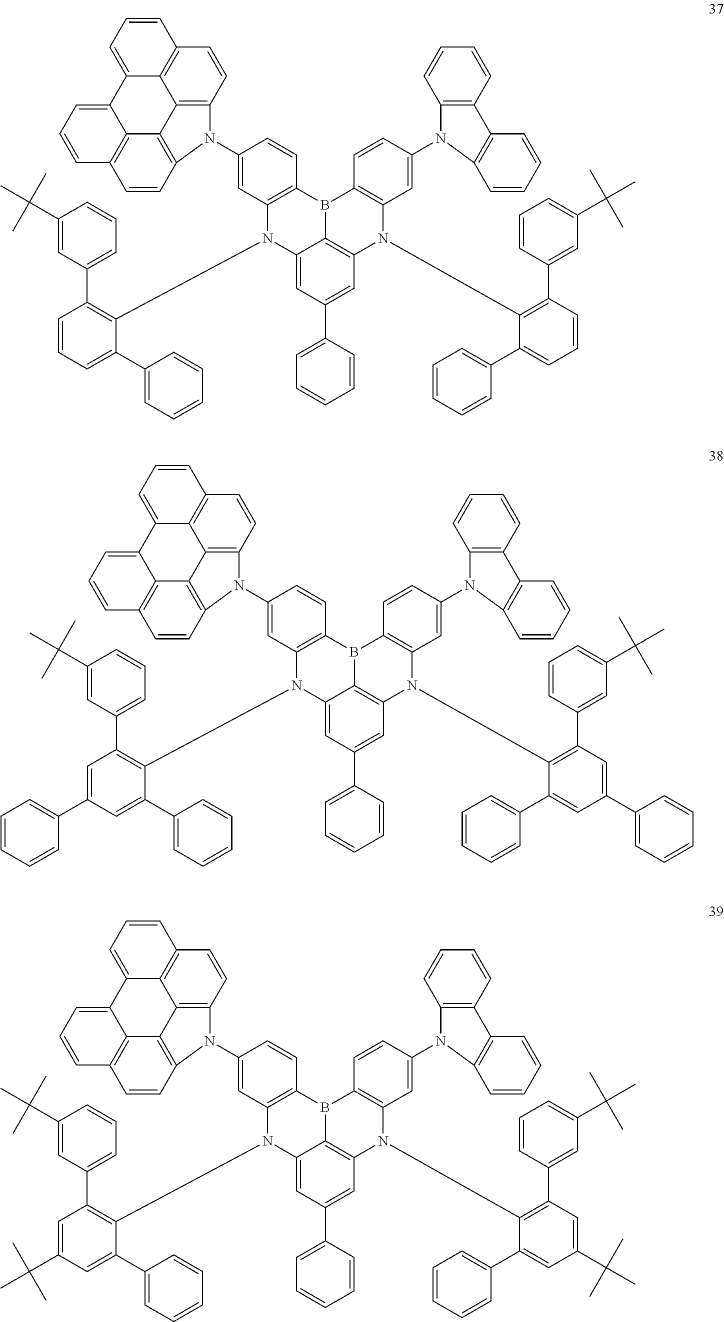

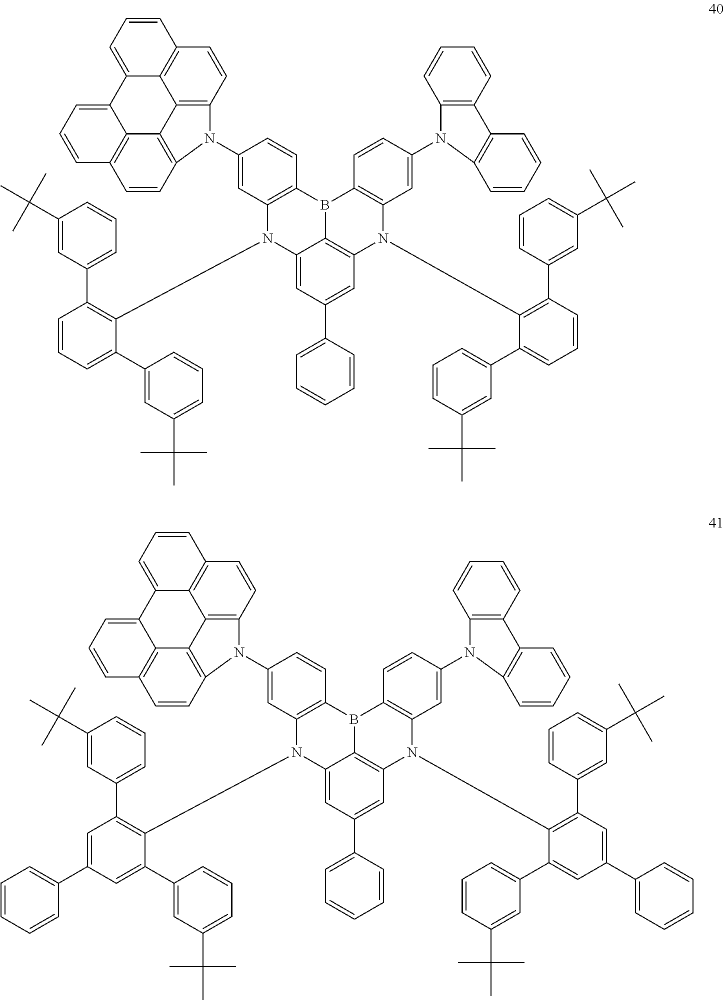 [SMILES: CC(C)(C)c1cccc(-c2cccc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(-c5ccccc5)cc2c43)c1 ; CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(-c5ccccc5)cc2c43)c1]

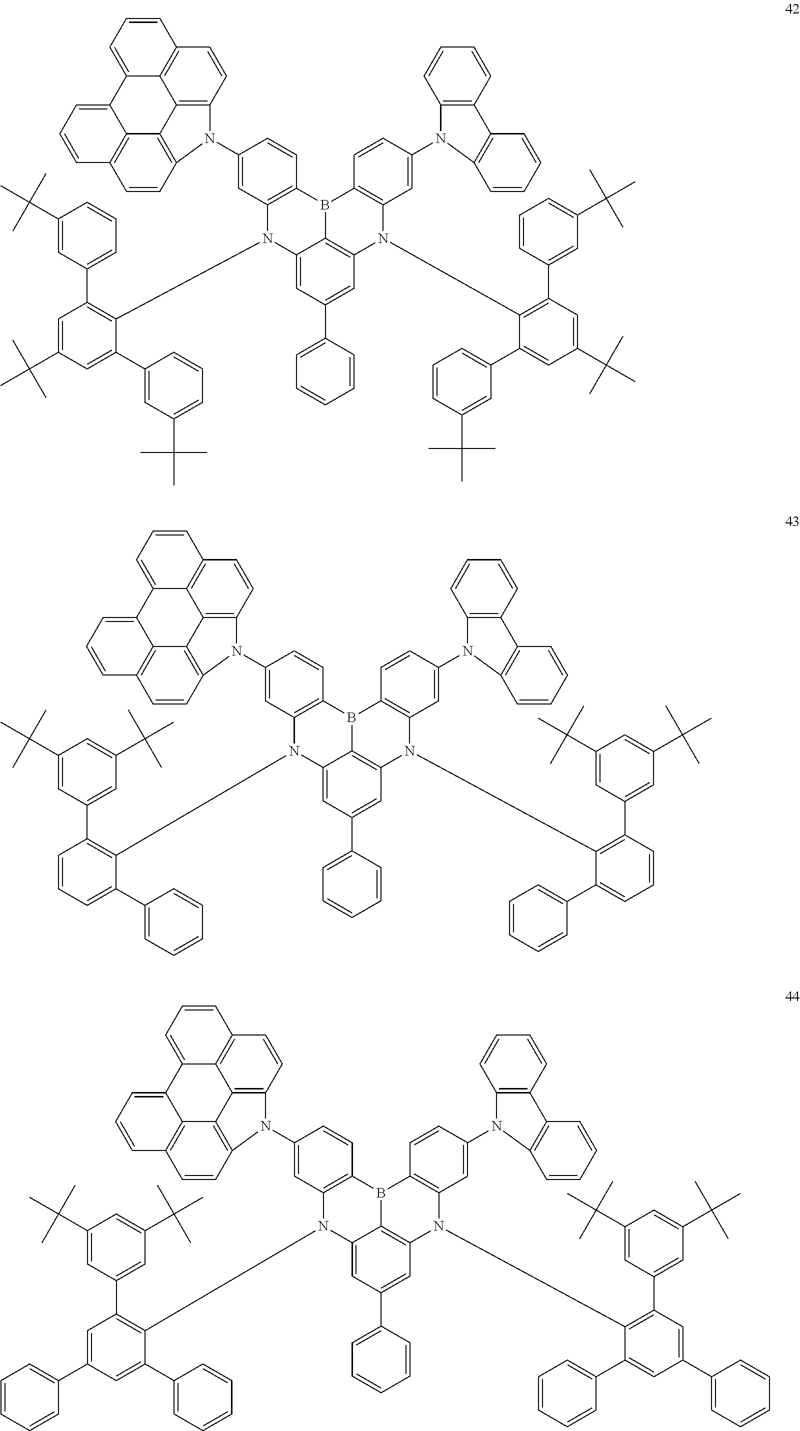

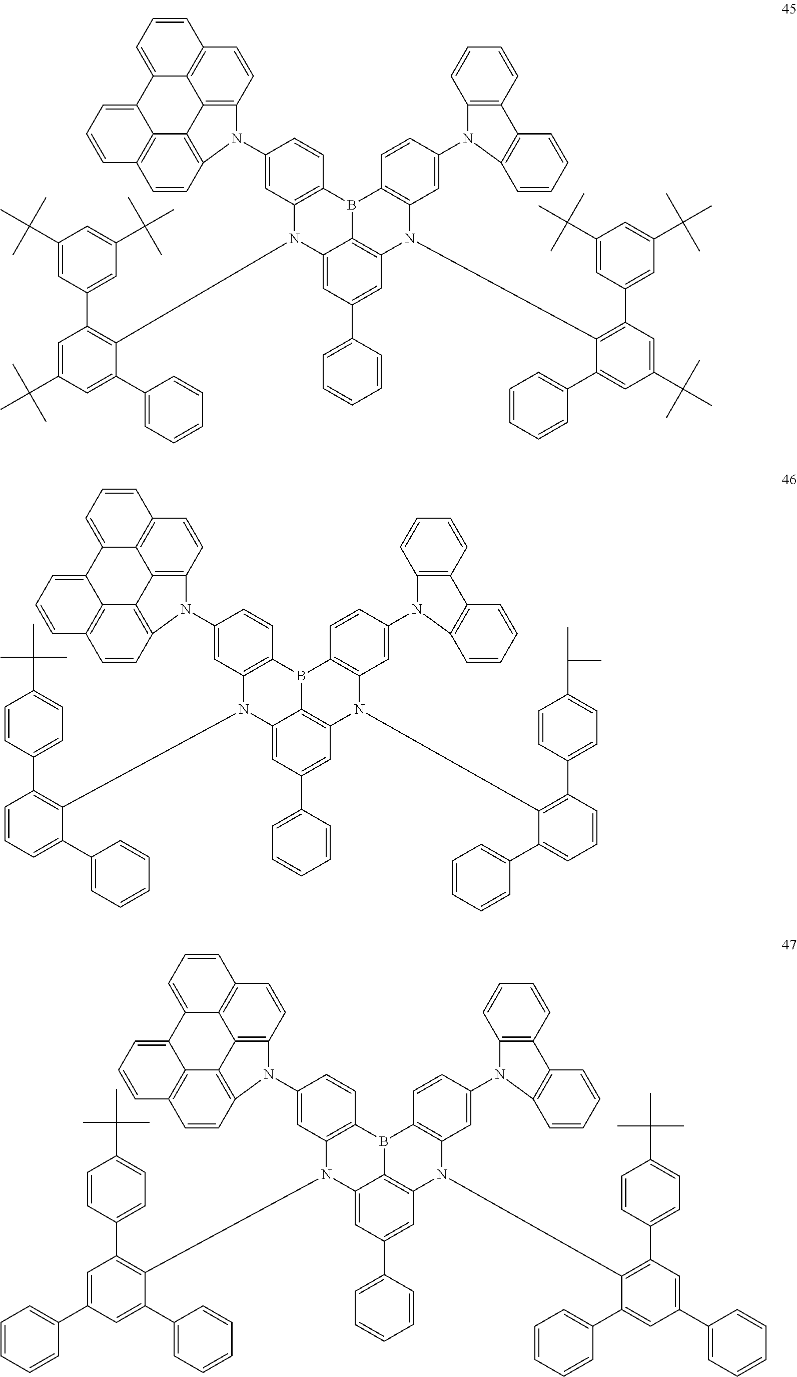

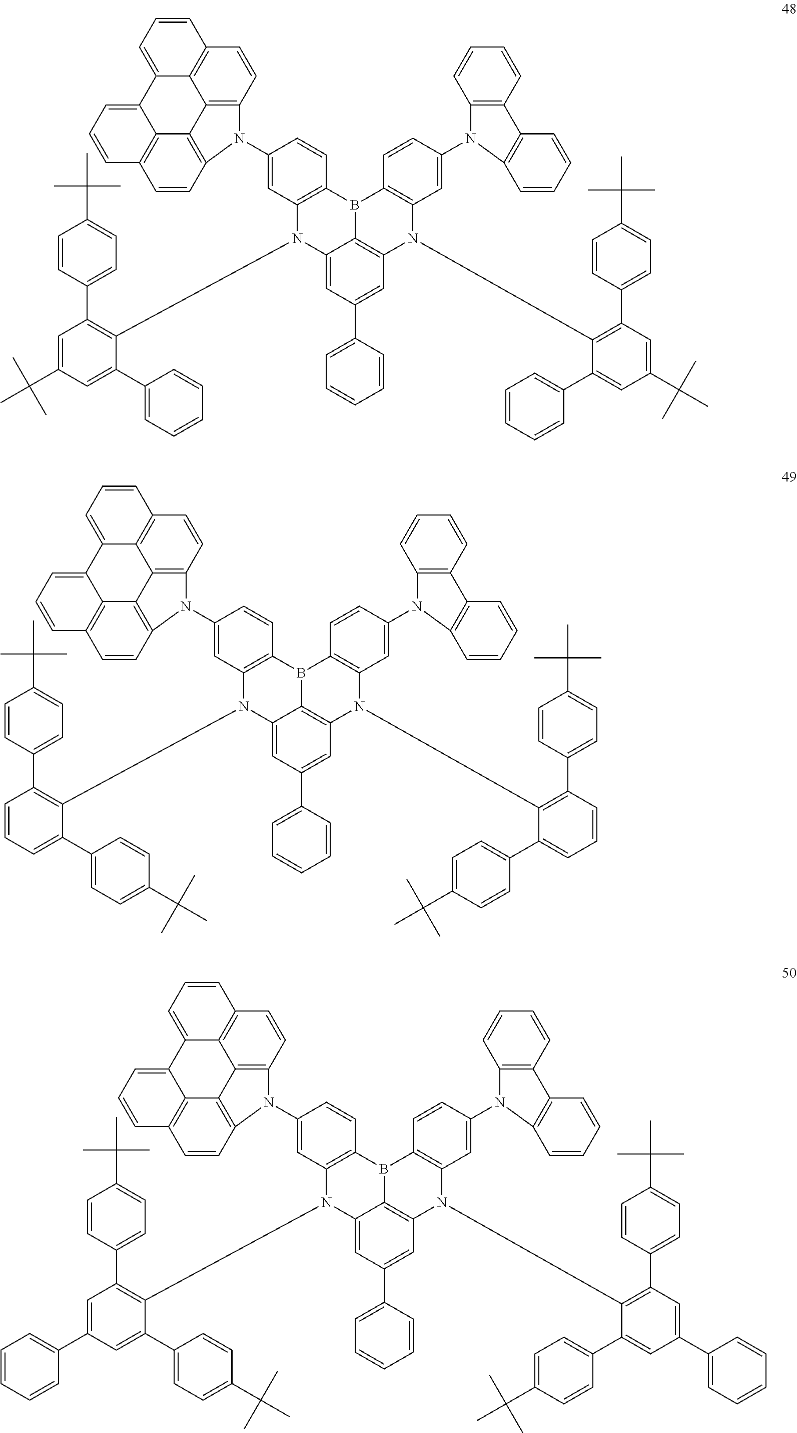

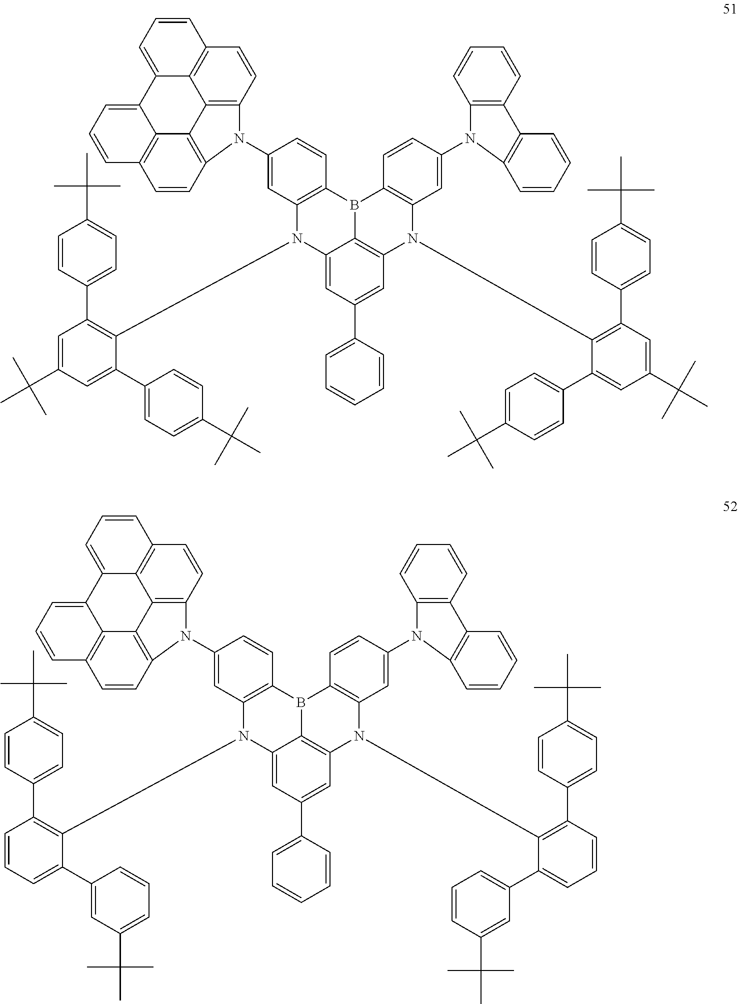

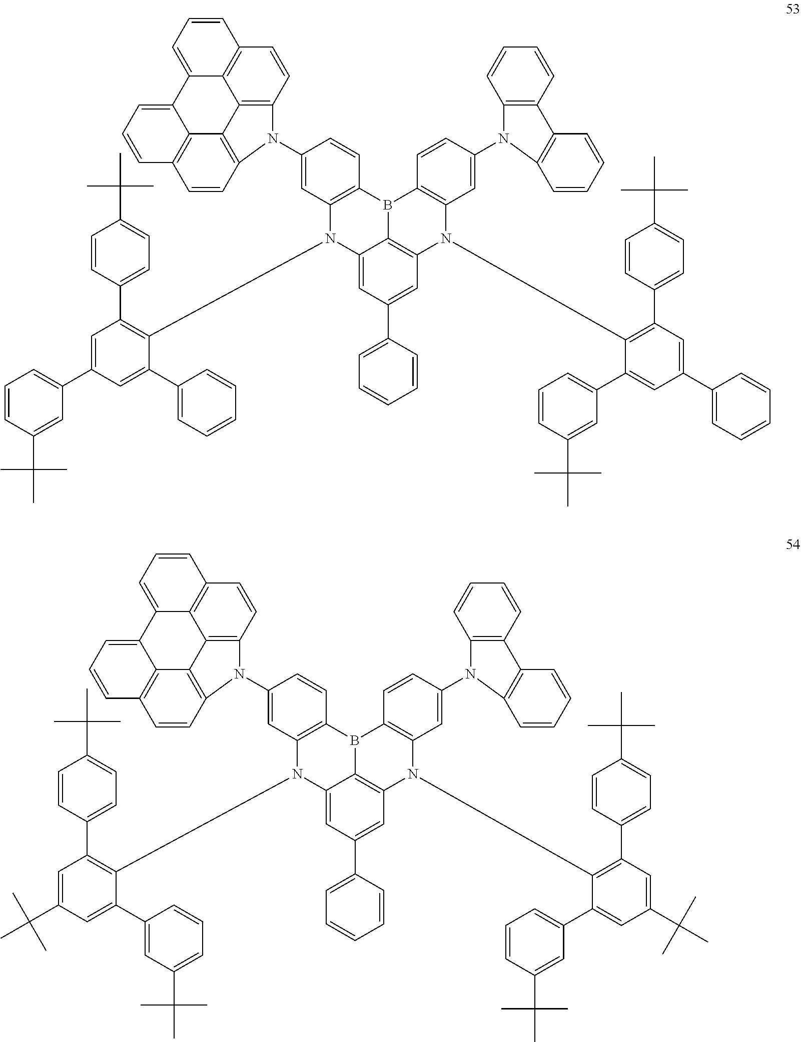 [SMILES: CC(C)(C)c1ccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(-c5cccc(C(C)(C)C)c5)cc4-c4ccc(C(C)(C)C)cc4)c4cc(-c5ccccc5)cc2c43)cc1 ; CC(C)(C)c1ccc(-c2cc(C(C)(C)C)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4cccc(C(C)(C)C)c4)c4cc(-c5ccccc5)cc2c43)cc1]

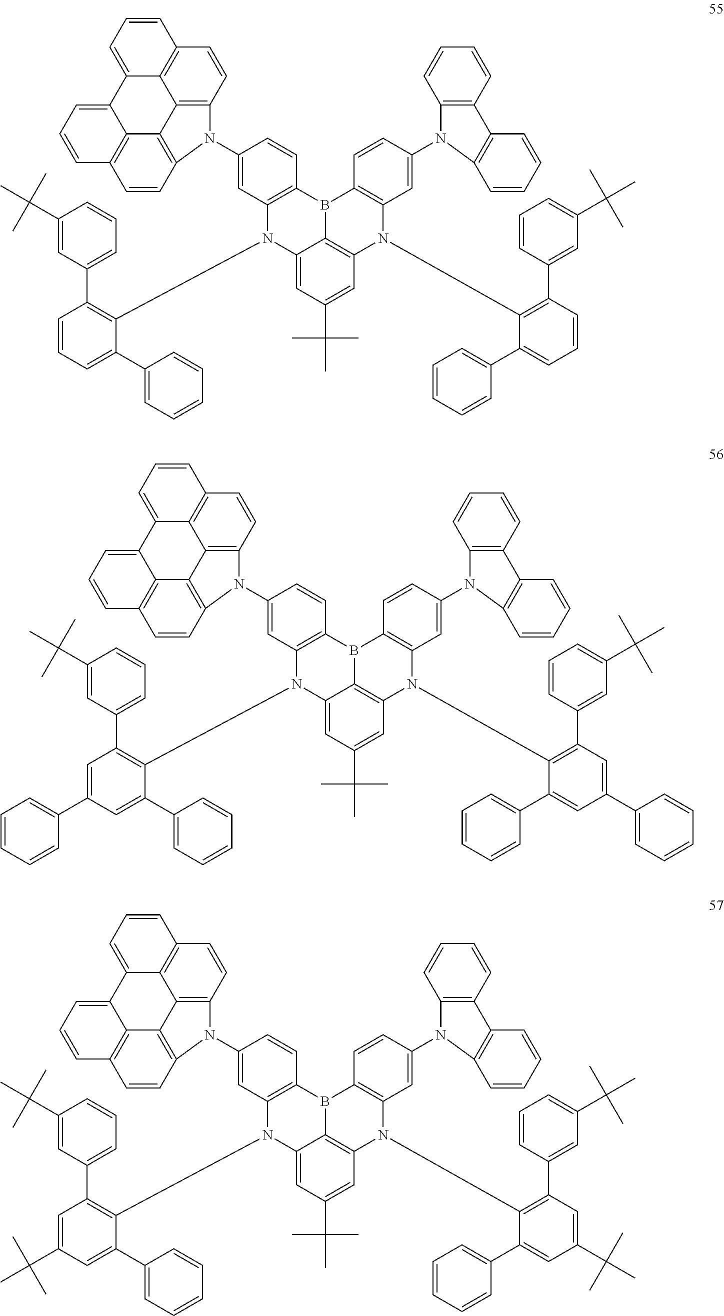

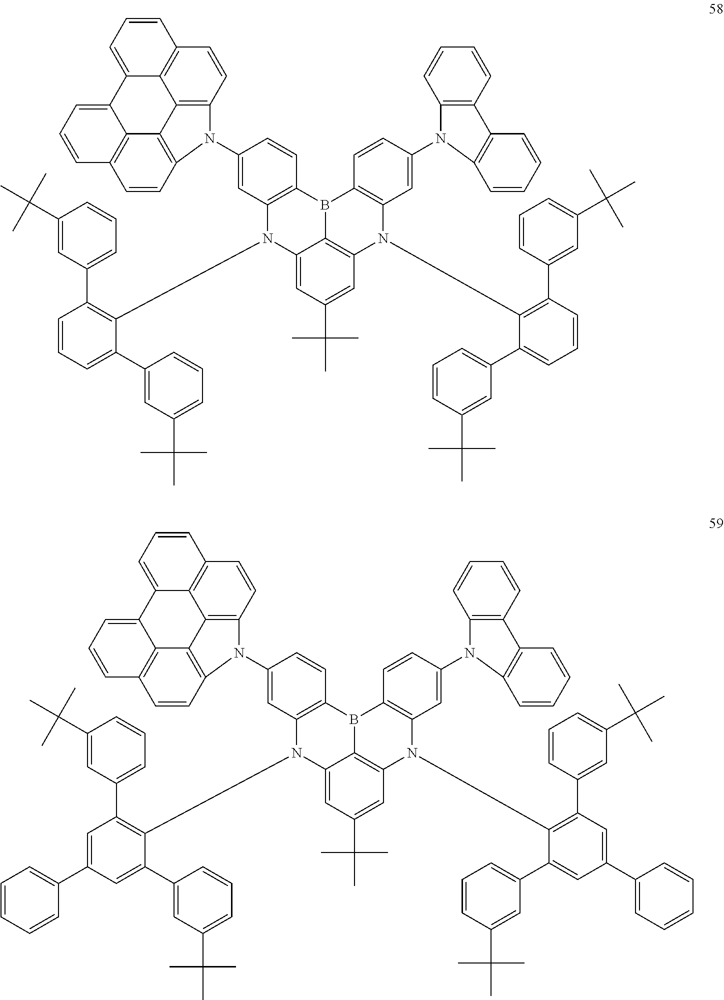 [SMILES: CC(C)(C)c1cccc(-c2cccc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1]

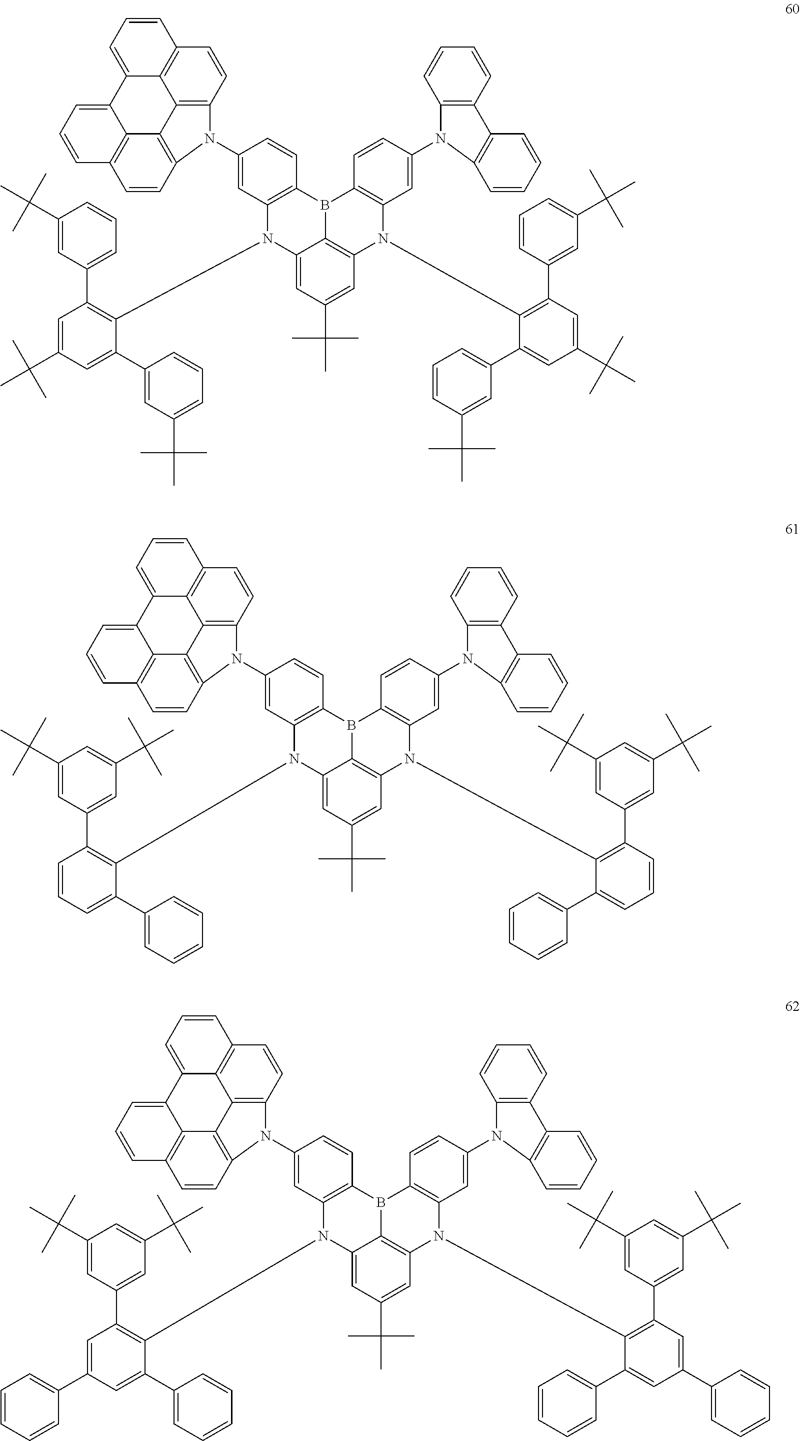

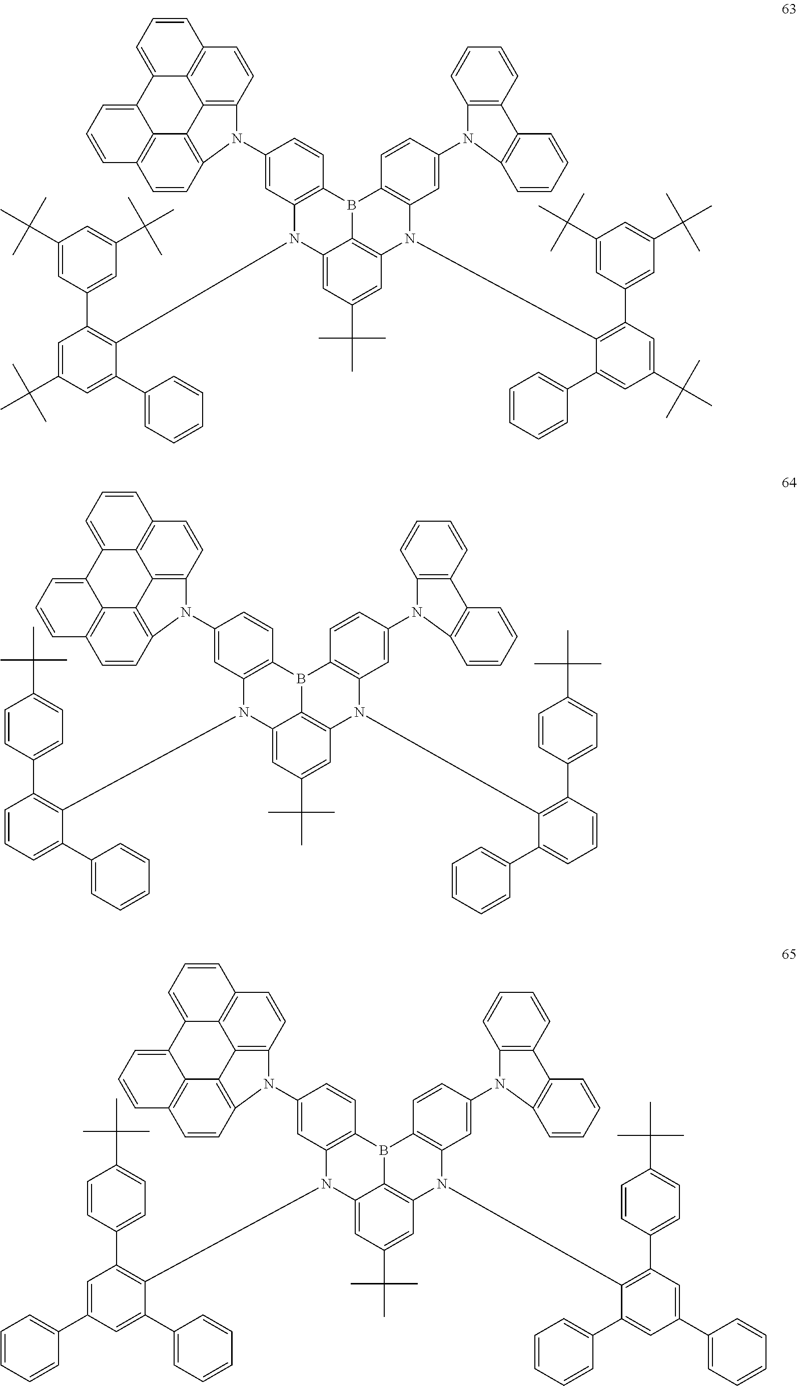

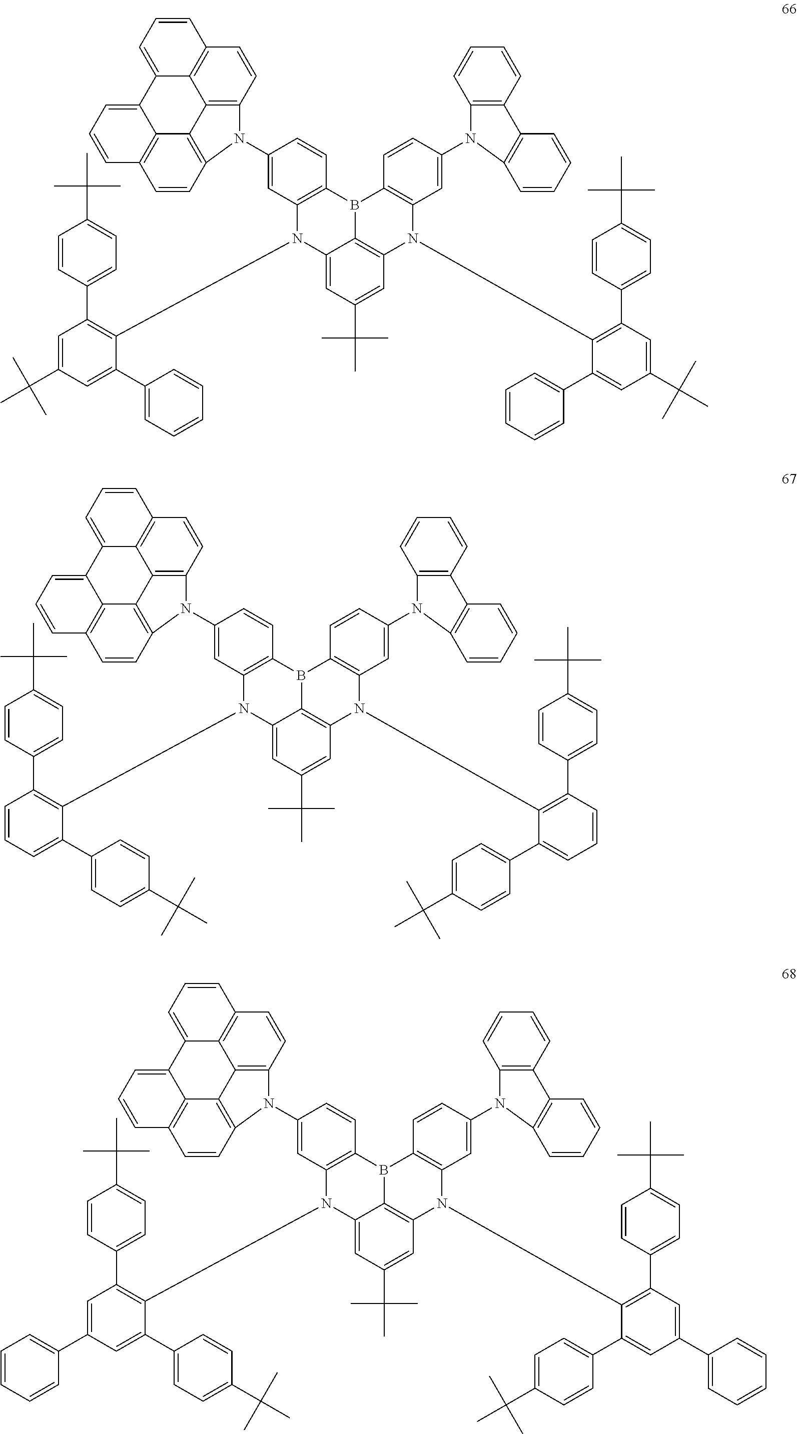

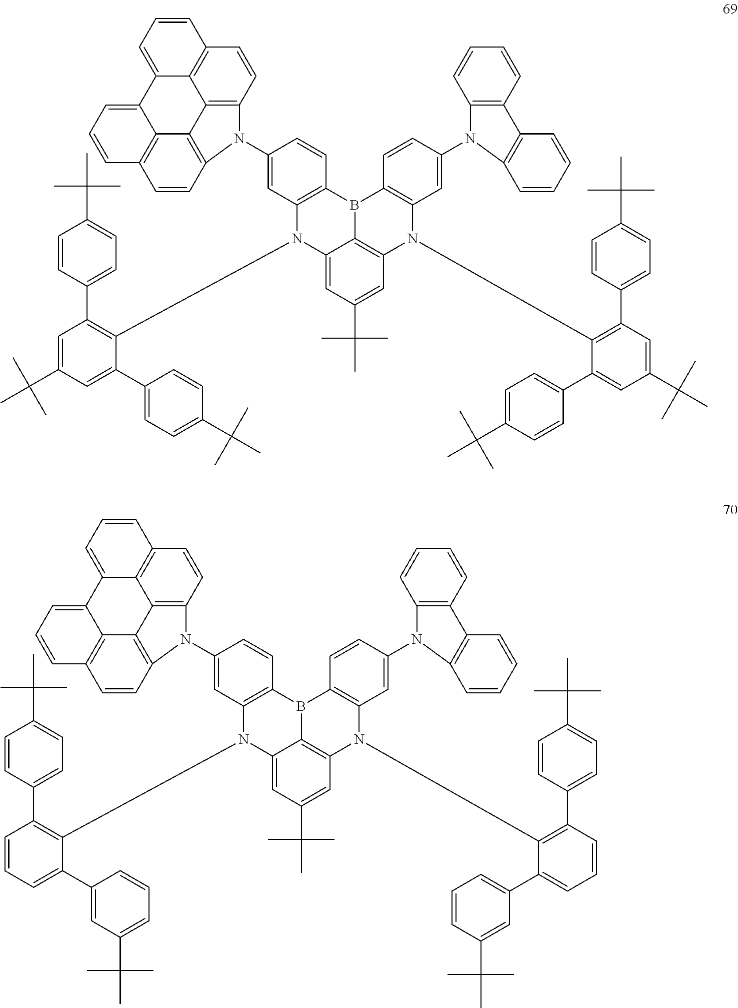

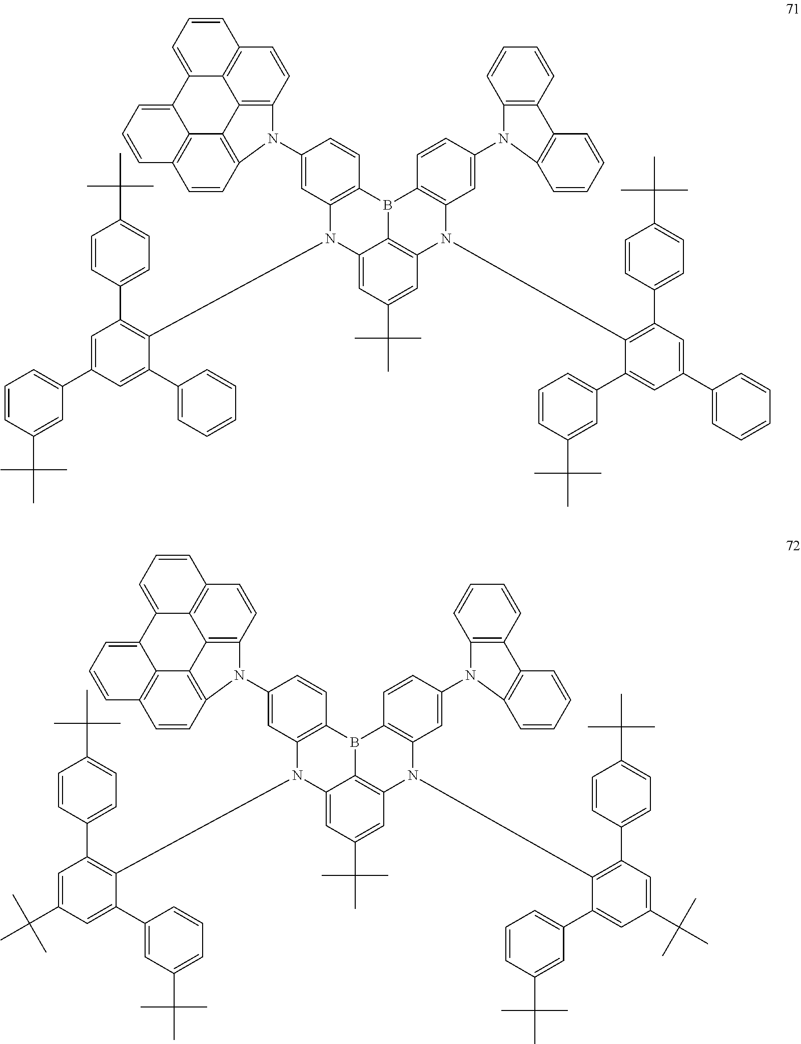 [SMILES: CC(C)(C)c1ccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(-c5cccc(C(C)(C)C)c5)cc4-c4ccc(C(C)(C)C)cc4)c4cc(C(C)(C)C)cc2c43)cc1 ; CC(C)(C)c1ccc(-c2cc(C(C)(C)C)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4cccc(C(C)(C)C)c4)c4cc(C(C)(C)C)cc2c43)cc1]

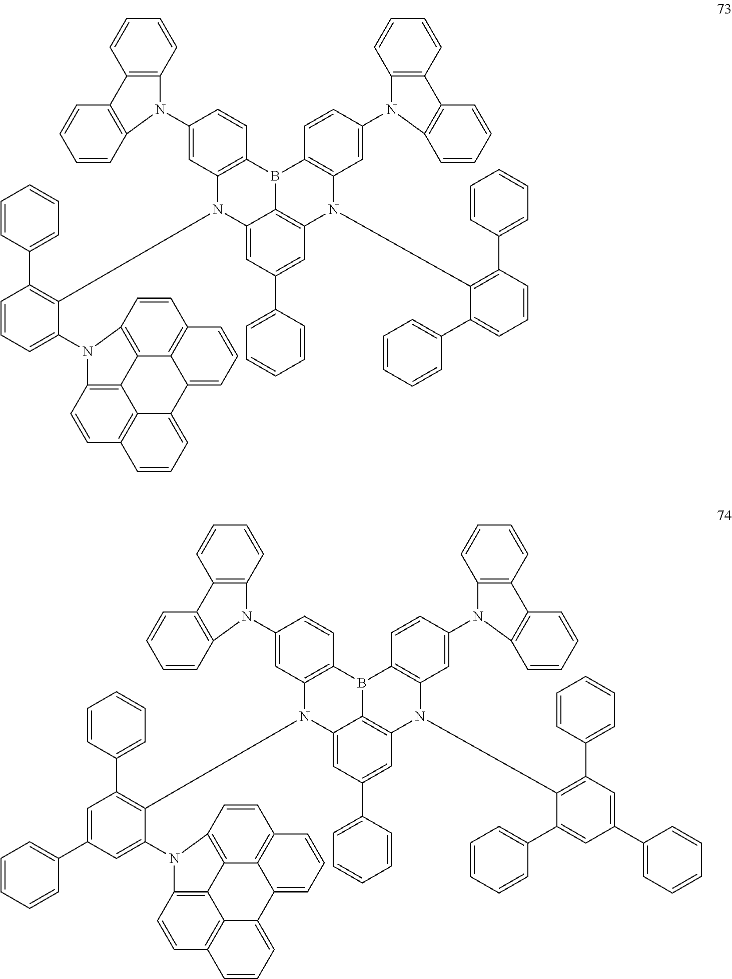 [SMILES: c1ccc(-c2cc3c4c(c2)N(c2c(-c5ccccc5)cccc2-n2c5ccc6cccc7c8cccc9ccc2c(c98)c5c67)c2cc(-n5c6ccccc6c6ccccc65)ccc2B4c2ccc(-n4c5ccccc5c5ccccc54)cc2N3c2c(-c3ccccc3)cccc2-c2ccccc2)cc1 ; c1ccc(-c2cc(-c3ccccc3)c(N3c4cc(-n5c6ccccc6c6ccccc65)ccc4B4c5ccc(-n6c7ccccc7c7ccccc76)cc5N(c5c(-c6ccccc6)cc(-c6ccccc6)cc5-n5c6ccc7cccc8c9cccc%10ccc5c(c%109)c6c78)c5cc(-c6ccccc6)cc3c54)c(-c3ccccc3)c2)cc1]

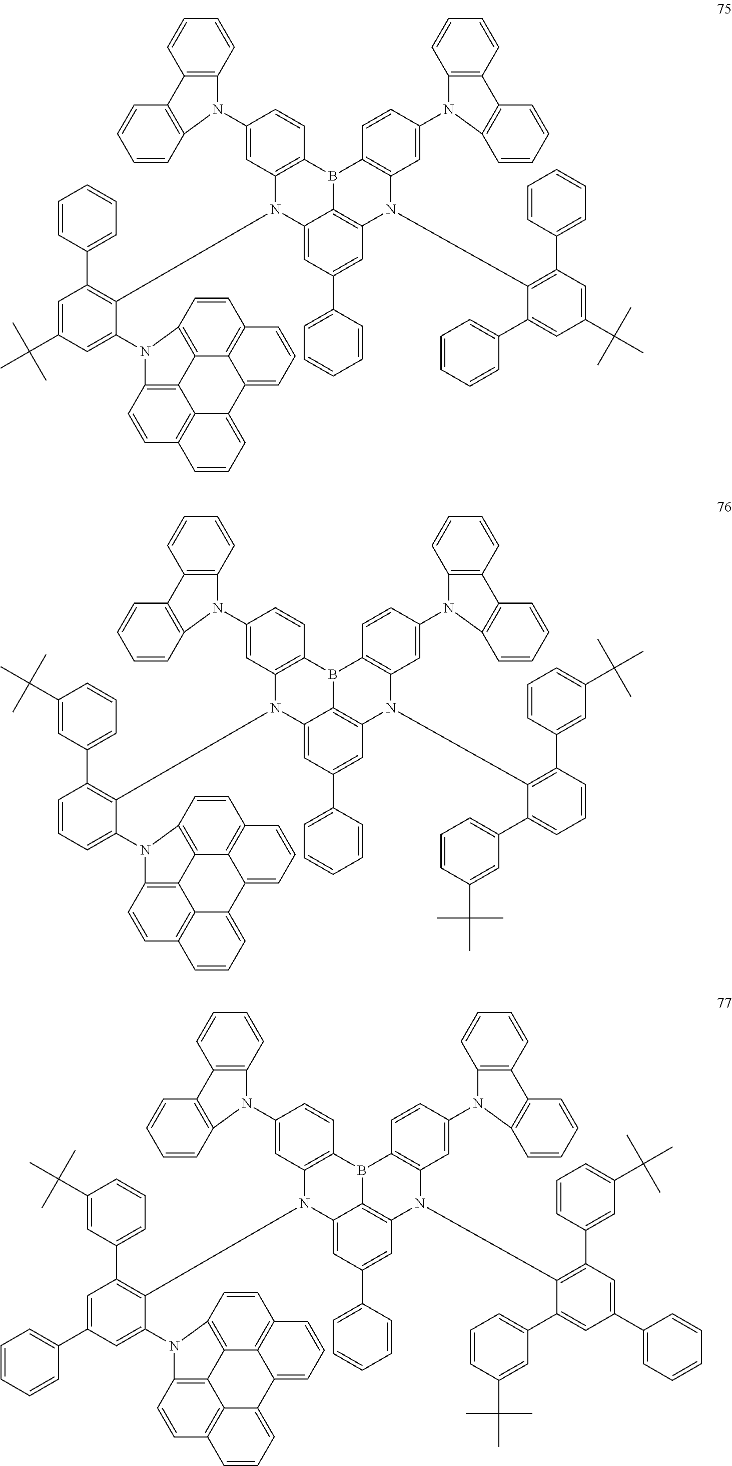

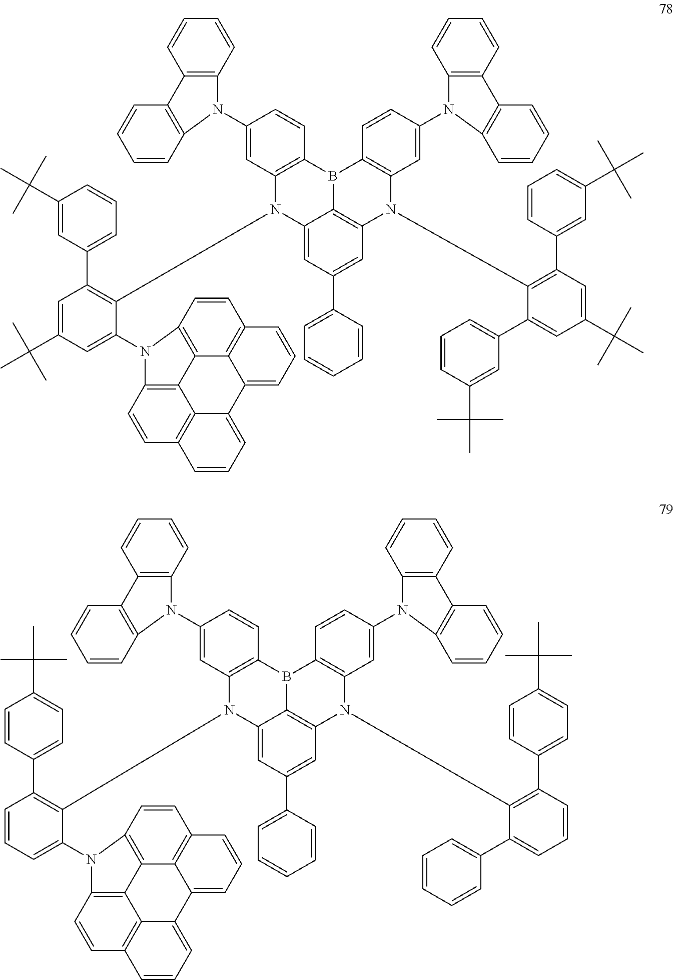

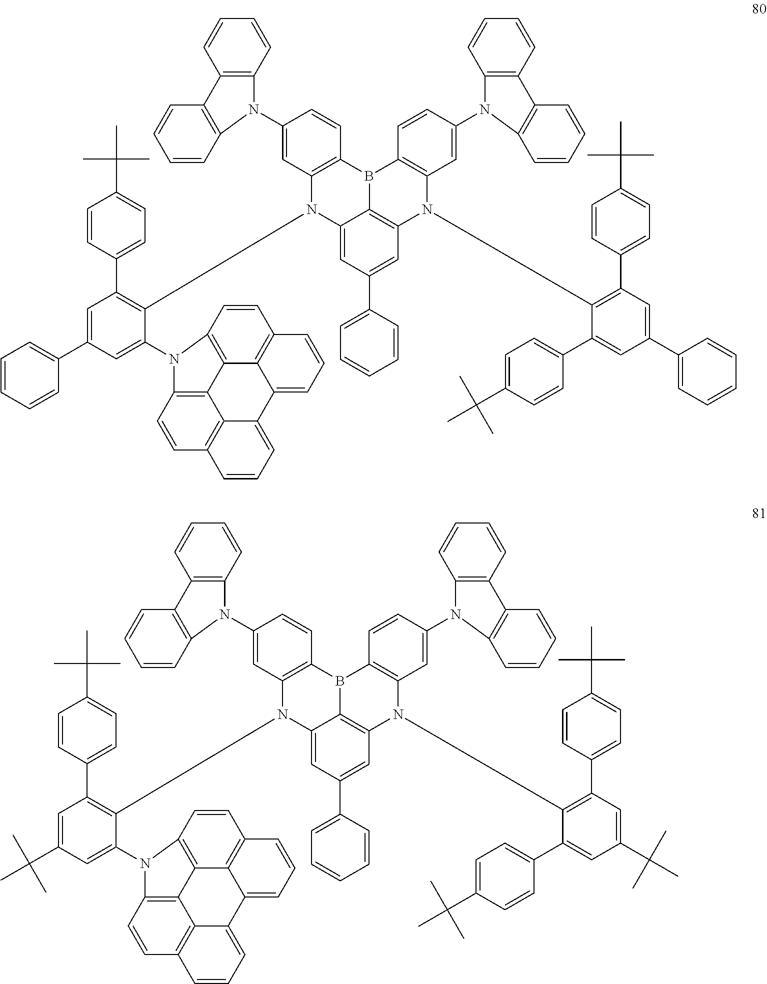

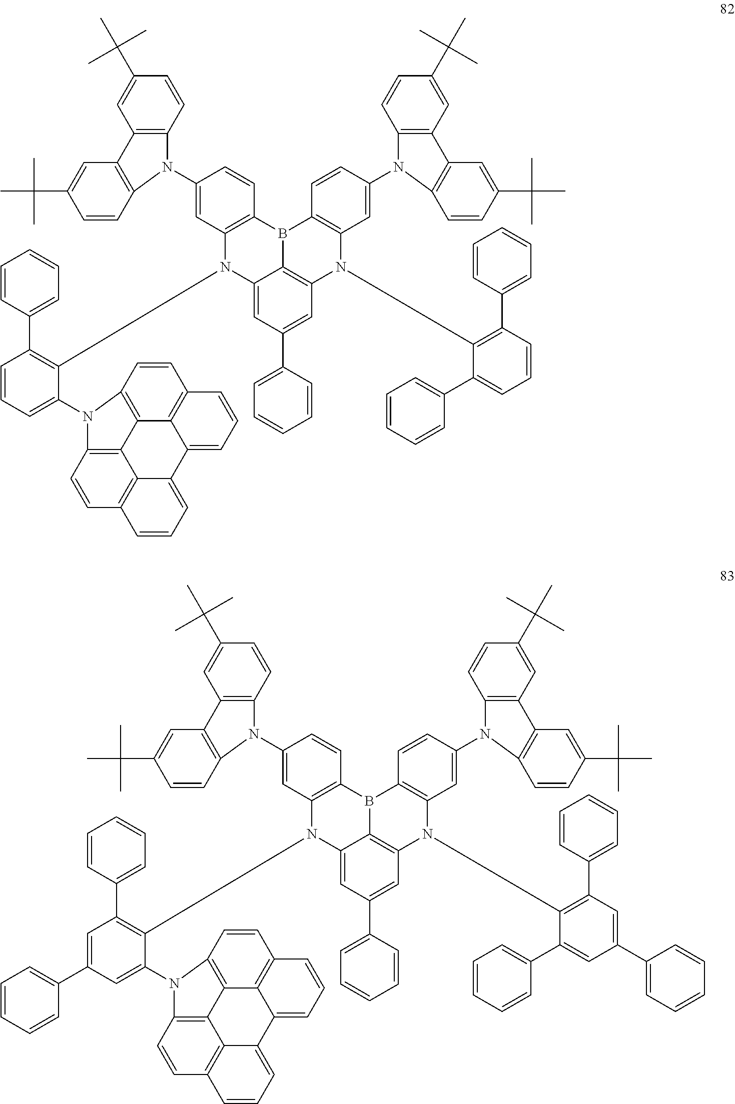 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2ccccc2)cccc1-n1c2ccc3cccc4c5cccc6ccc1c(c65)c2c34 ; CC(C)(C)c1ccc2c(c1)c1cc(C(C)(C)C)ccc1n2-c1ccc2c(c1)N(c1c(-c3ccccc3)cc(-c3ccccc3)cc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2ccccc2)cc(-c2ccccc2)cc1-n1c2ccc3cccc4c5cccc6ccc1c(c65)c2c34]

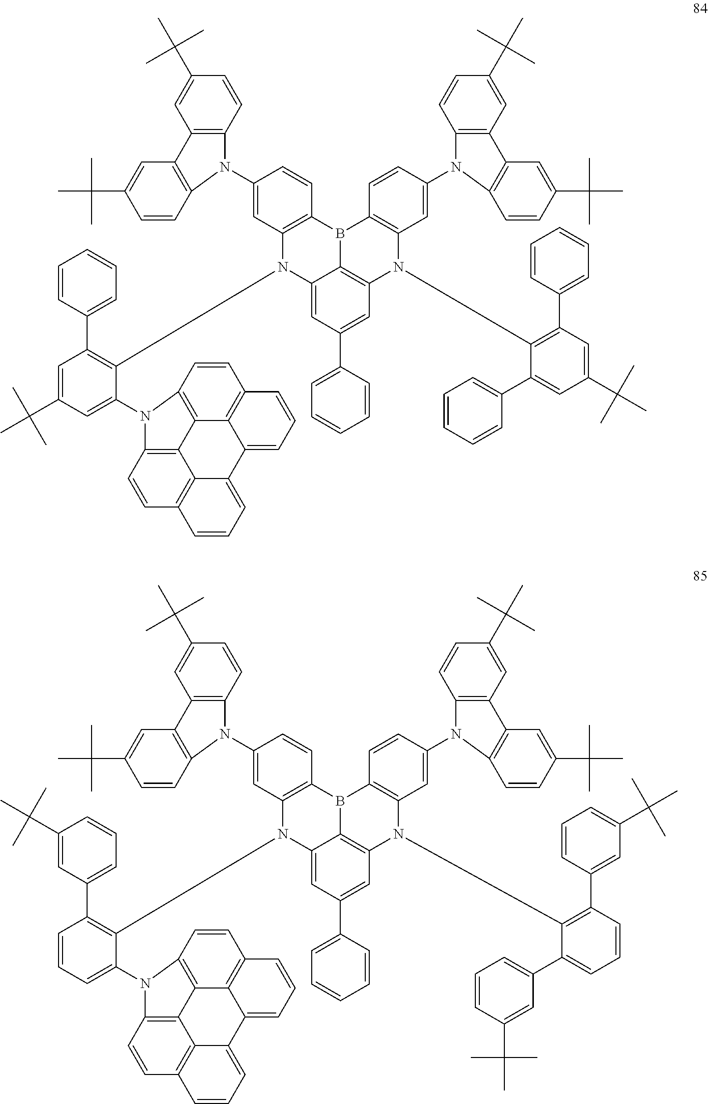

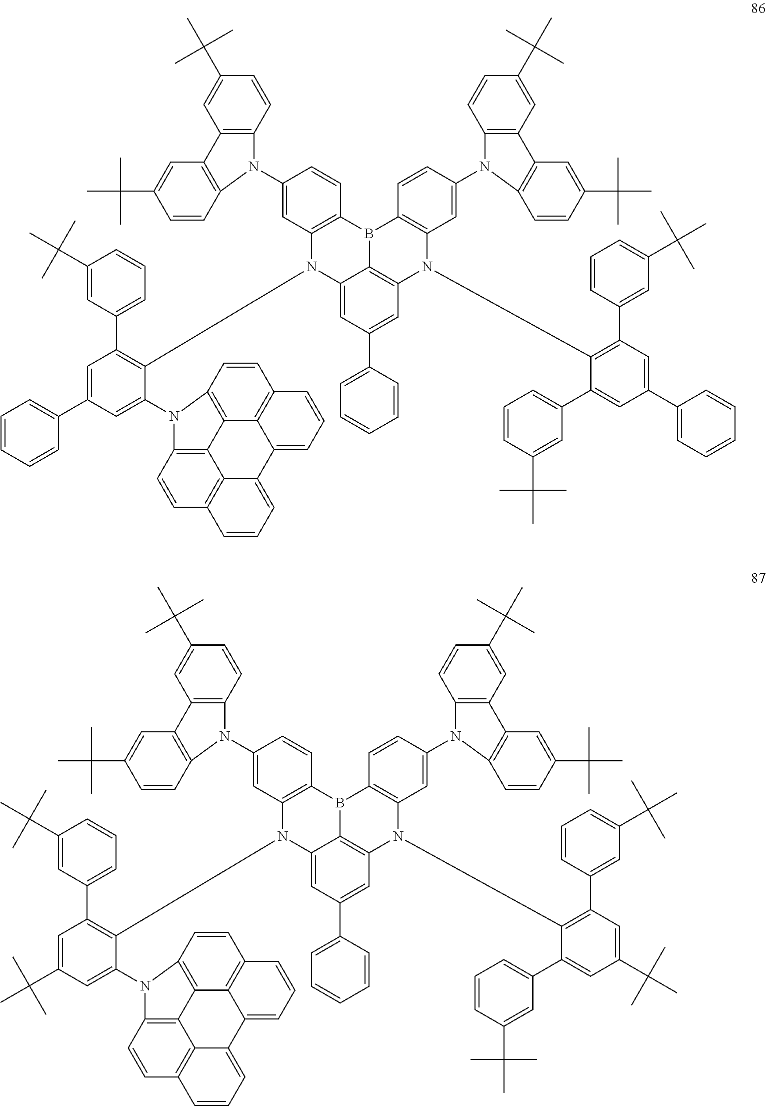

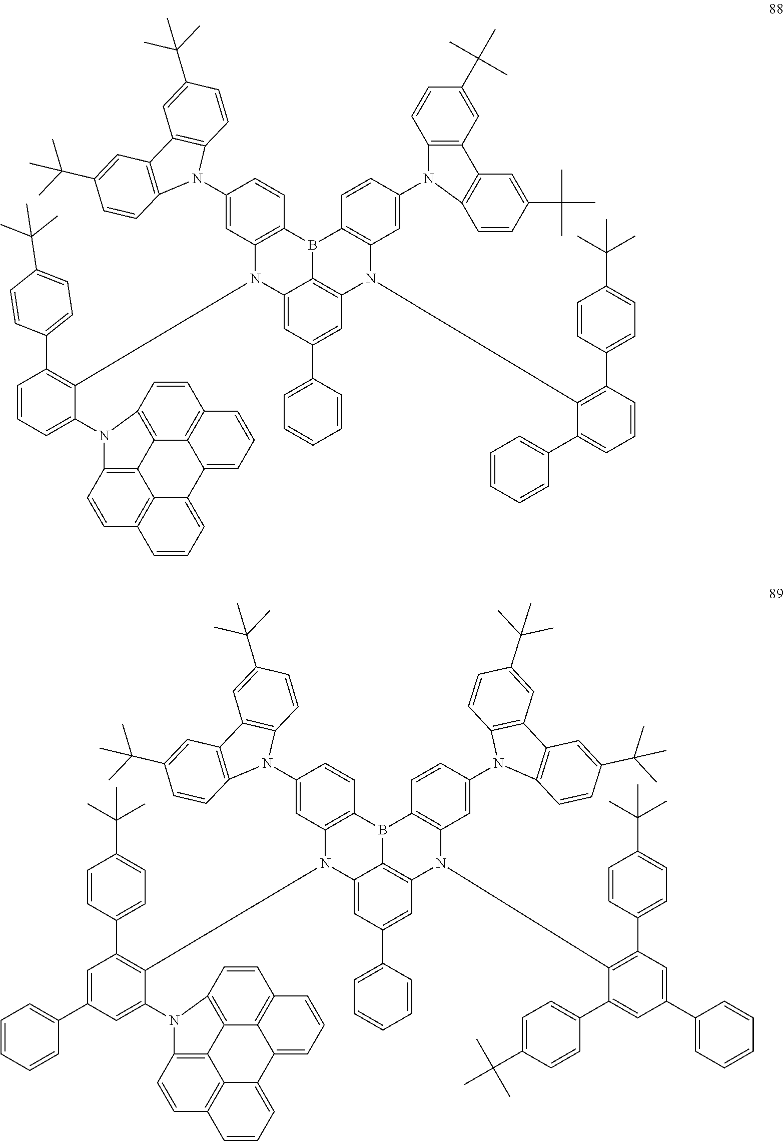 [SMILES: CC(C)(C)c1ccc(-c2cccc(-c3ccccc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccc(C(C)(C)C)cc5)cccc4-n4c5ccc6cccc7c8cccc9ccc4c(c98)c5c67)c4cc(-c5ccccc5)cc2c43)cc1 ; CC(C)(C)c1ccc(-c2cc(-c3ccccc3)cc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccc(C(C)(C)C)cc5)cc(-c5ccccc5)cc4-n4c5ccc6cccc7c8cccc9ccc4c(c98)c5c67)c4cc(-c5ccccc5)cc2c43)cc1]

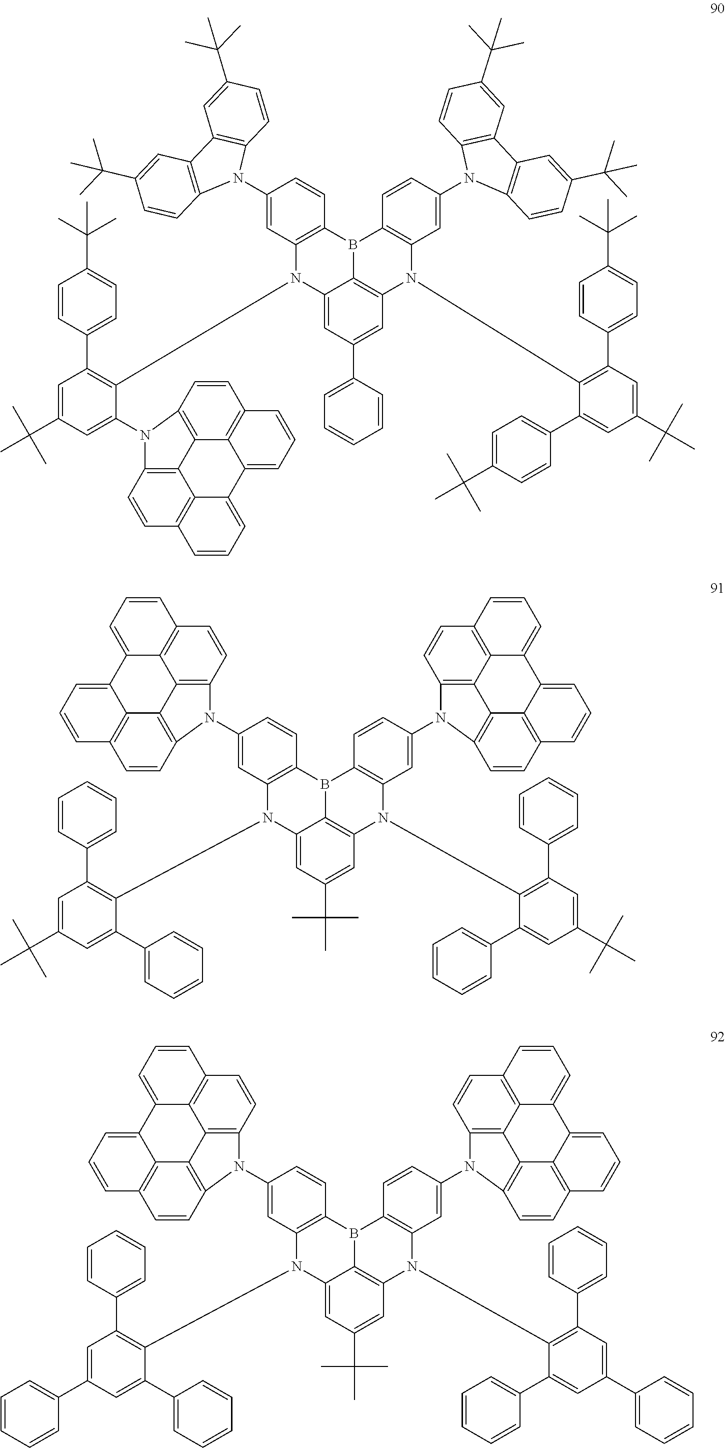

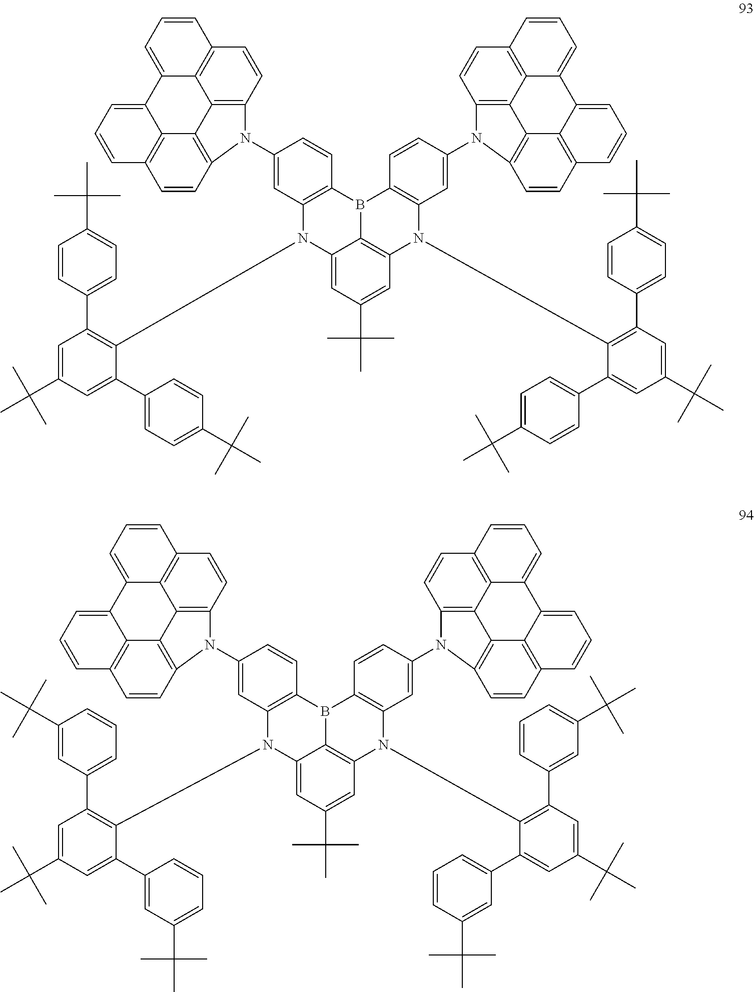

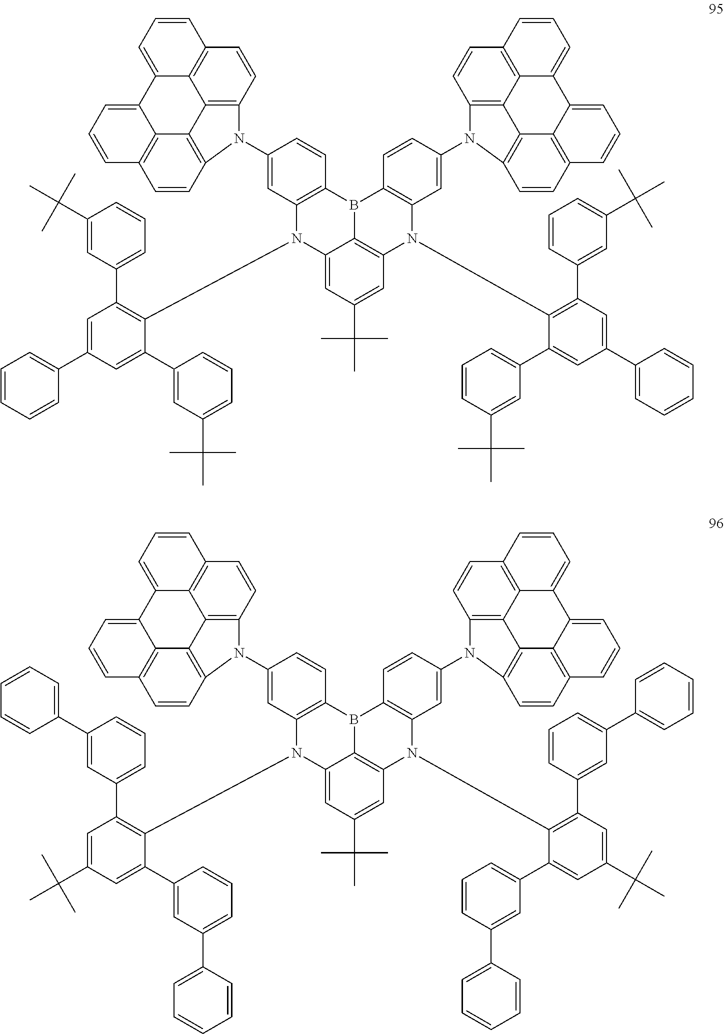 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2cccc(-c3ccccc3)c2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

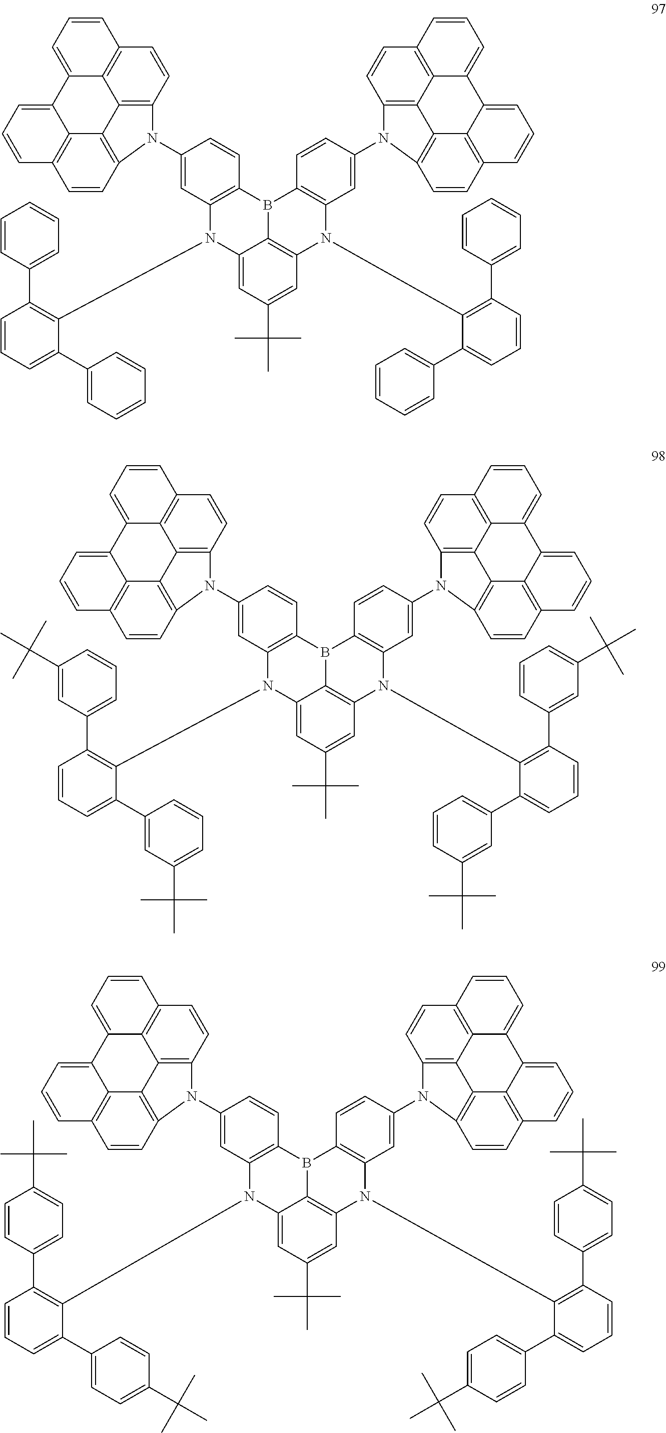

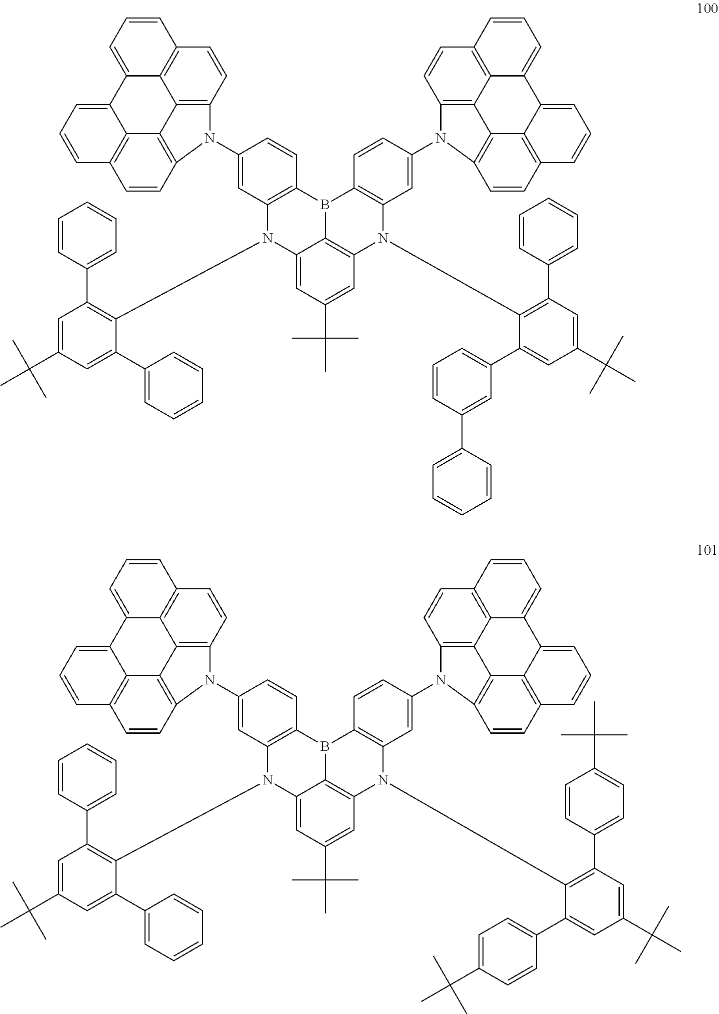

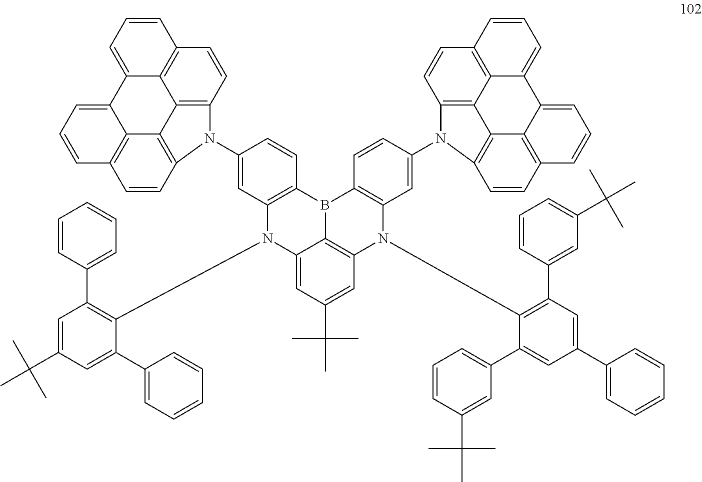 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c1]

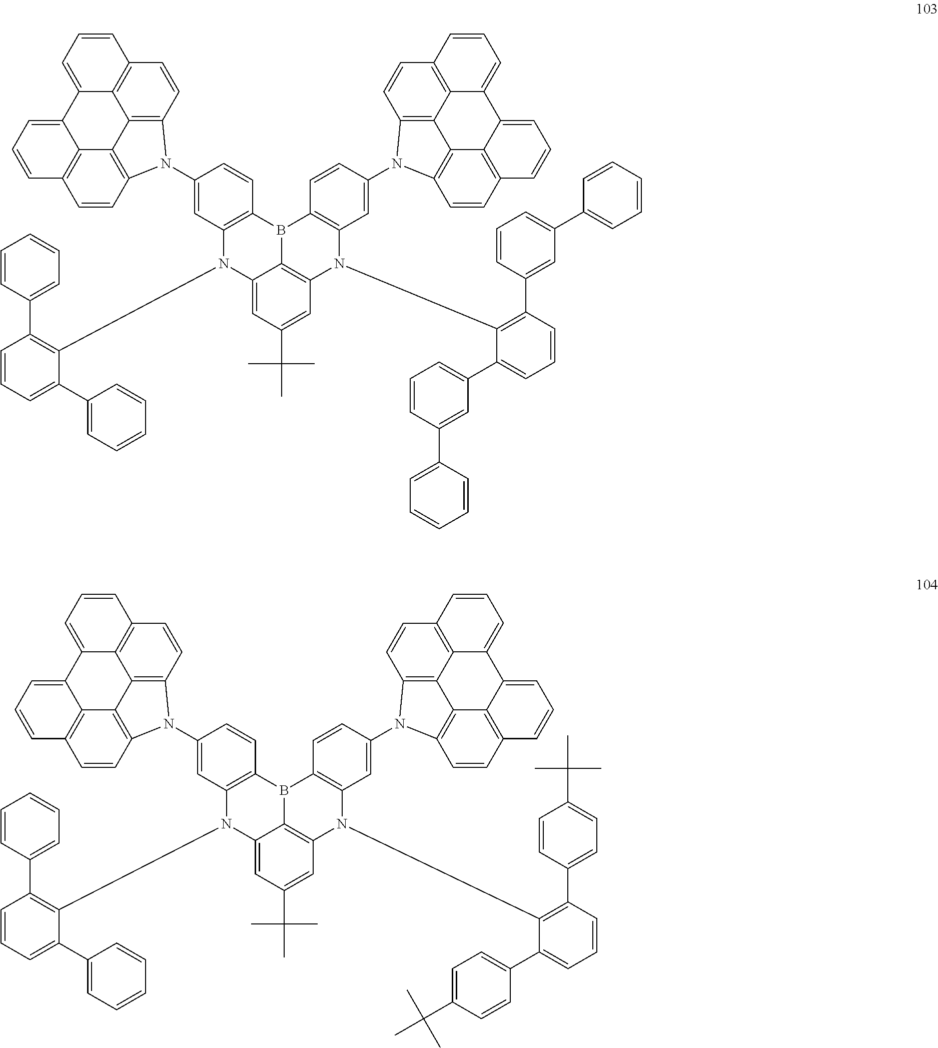 [SMILES: CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1 ; CC(C)(C)c1ccc(-c2cccc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)cc1]

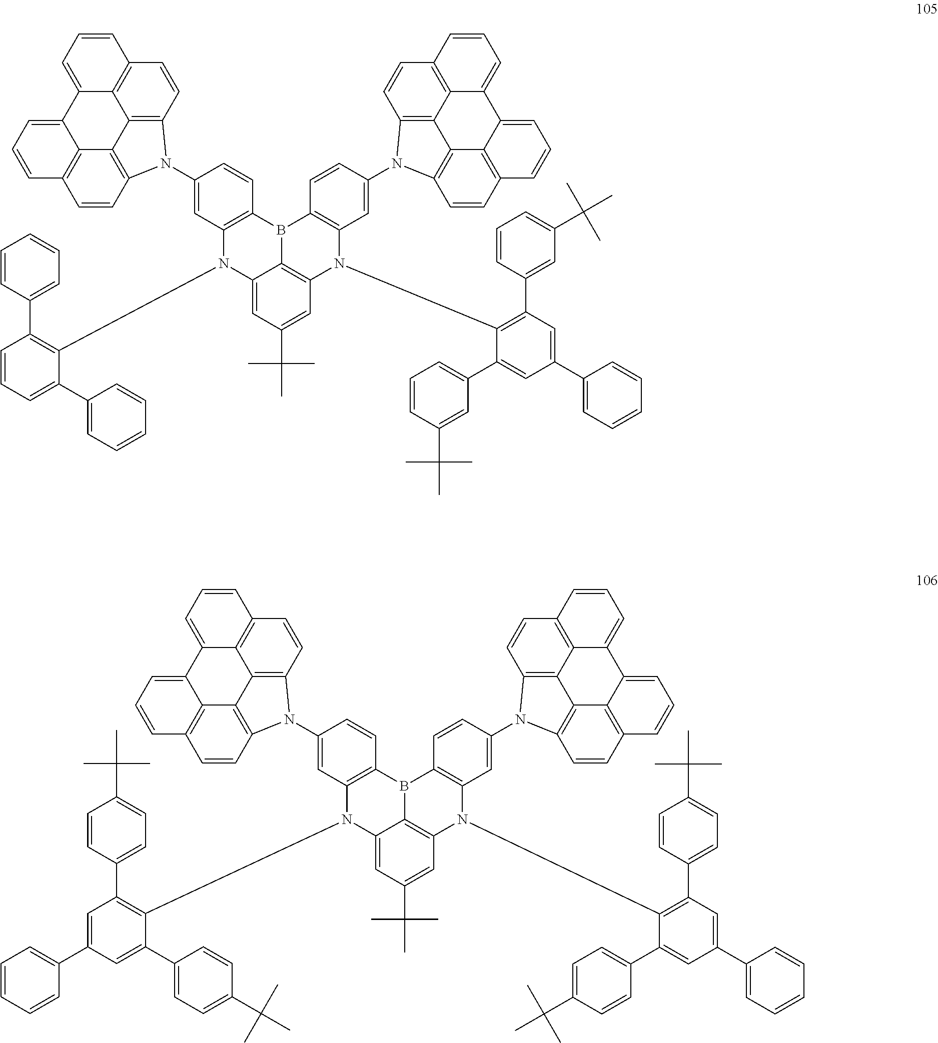 [SMILES: CC(C)(C)c1cccc(-c2cc(-c3ccccc3)cc(-c3cccc(C(C)(C)C)c3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)c1 ; CC(C)(C)c1ccc(-c2cc(-c3ccccc3)cc(-c3ccc(C(C)(C)C)cc3)c2N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

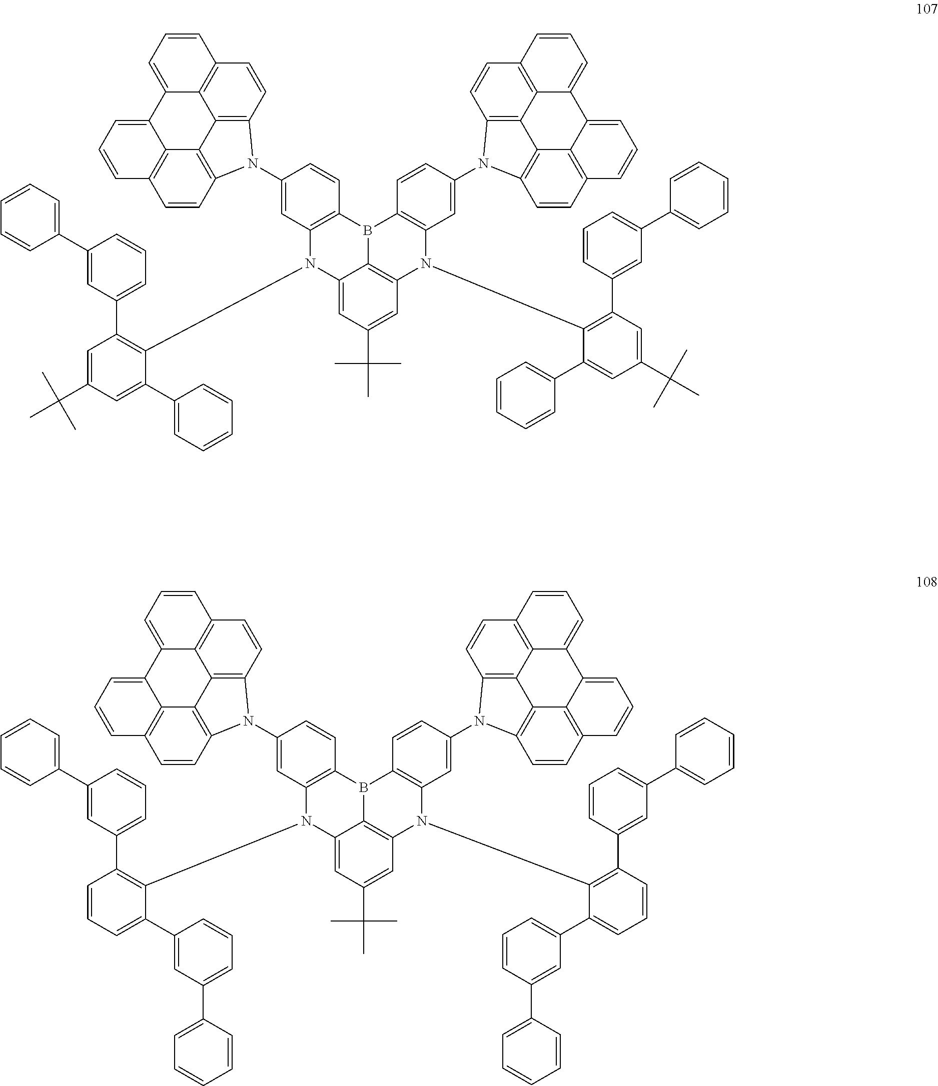 [SMILES: CC(C)(C)c1cc(-c2ccccc2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2cccc(-c3ccccc3)c2)cccc1-c1cccc(-c2ccccc2)c1]

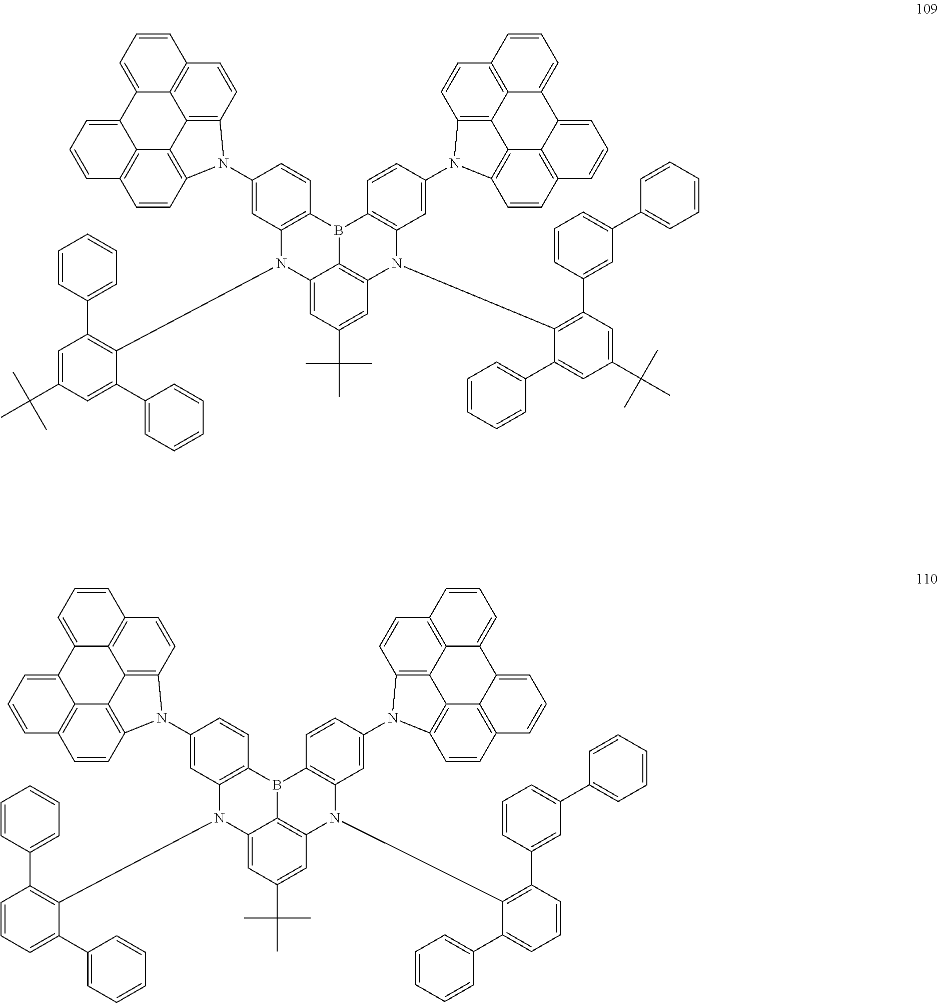 [SMILES: CC(C)(C)c1cc(-c2ccccc2)c(N2c3cc(-n4c5ccc6cccc7c8cccc9ccc4c(c98)c5c67)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2ccccc2)c1 ; CC(C)(C)c1cc2c3c(c1)N(c1c(-c4ccccc4)cccc1-c1cccc(-c4ccccc4)c1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1]

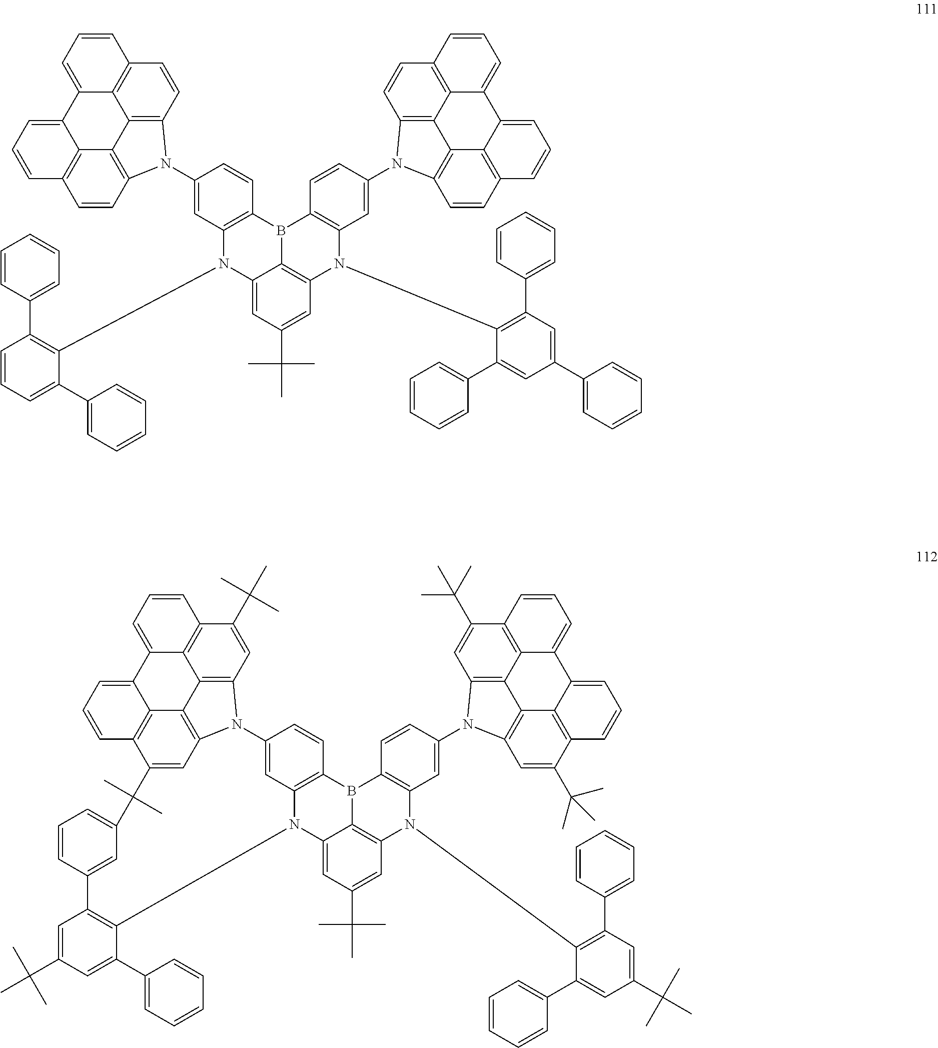 [SMILES: CC(C)(C)c1cc2c3c(c1)N(c1c(-c4ccccc4)cc(-c4ccccc4)cc1-c1ccccc1)c1cc(-n4c5ccc6cccc7c8cccc9ccc4c(c98)c5c67)ccc1B3c1ccc(-n3c4ccc5cccc6c7cccc8ccc3c(c87)c4c56)cc1N2c1c(-c2ccccc2)cccc1-c1ccccc1 ; CC(C)(C)c1cc(-c2ccccc2)c(N2c3cc(-n4c5cc(C(C)(C)C)c6cccc7c8cccc9c(C(C)(C)C)cc4c(c98)c5c67)ccc3B3c4ccc5cc4N(c4cc(C(C)(C)C)cc2c43)c2c(-c3ccccc3)cc(C(C)(C)C)cc2-c2cccc(c2)C(C)(C)c2cc3c4c6c2cccc6c2cccc6c(C(C)(C)C)cc(c4c62)n3-5)c(-c2ccccc2)c1]

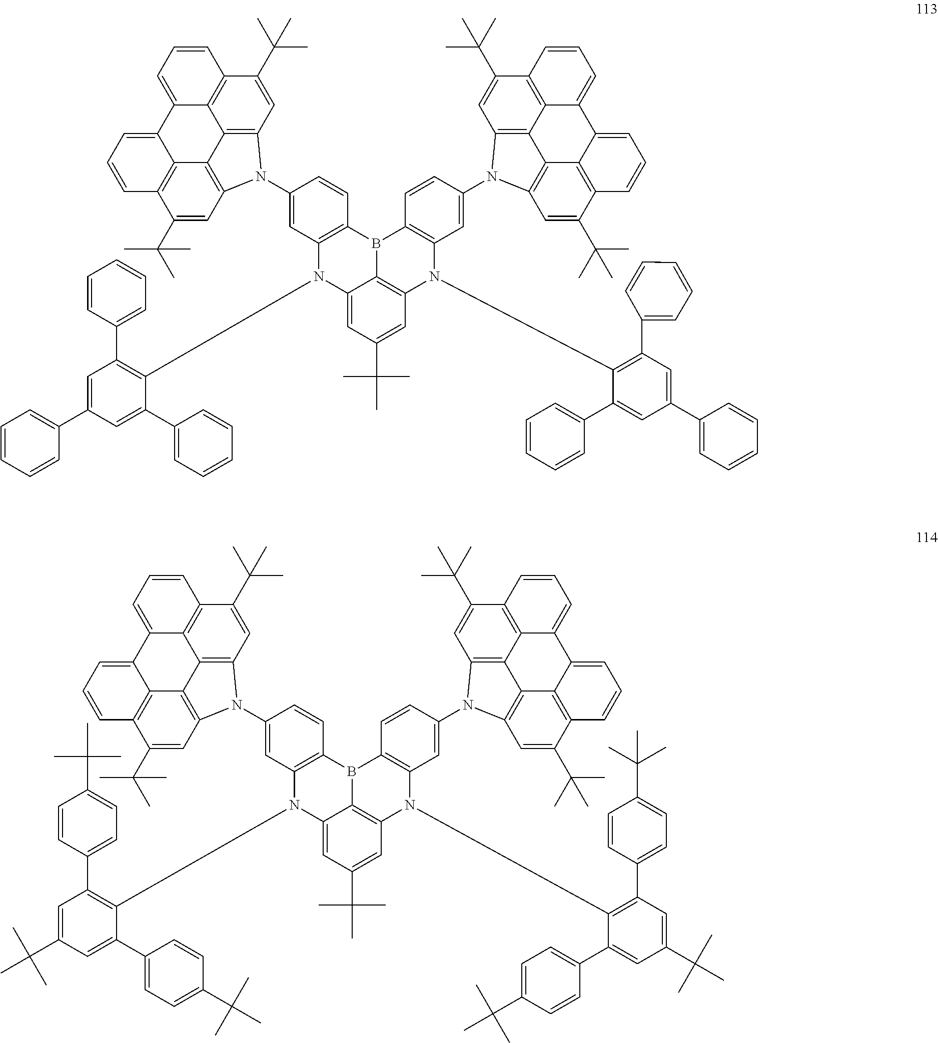

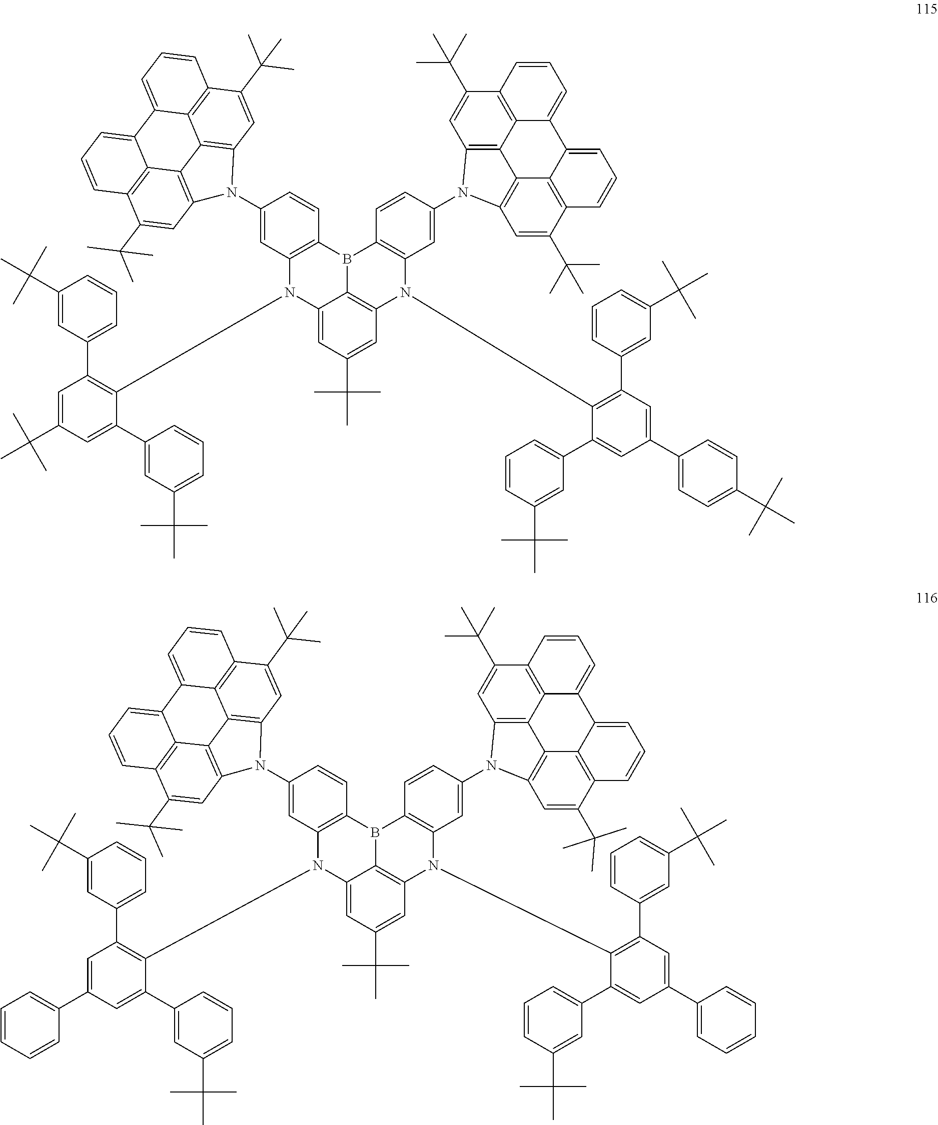

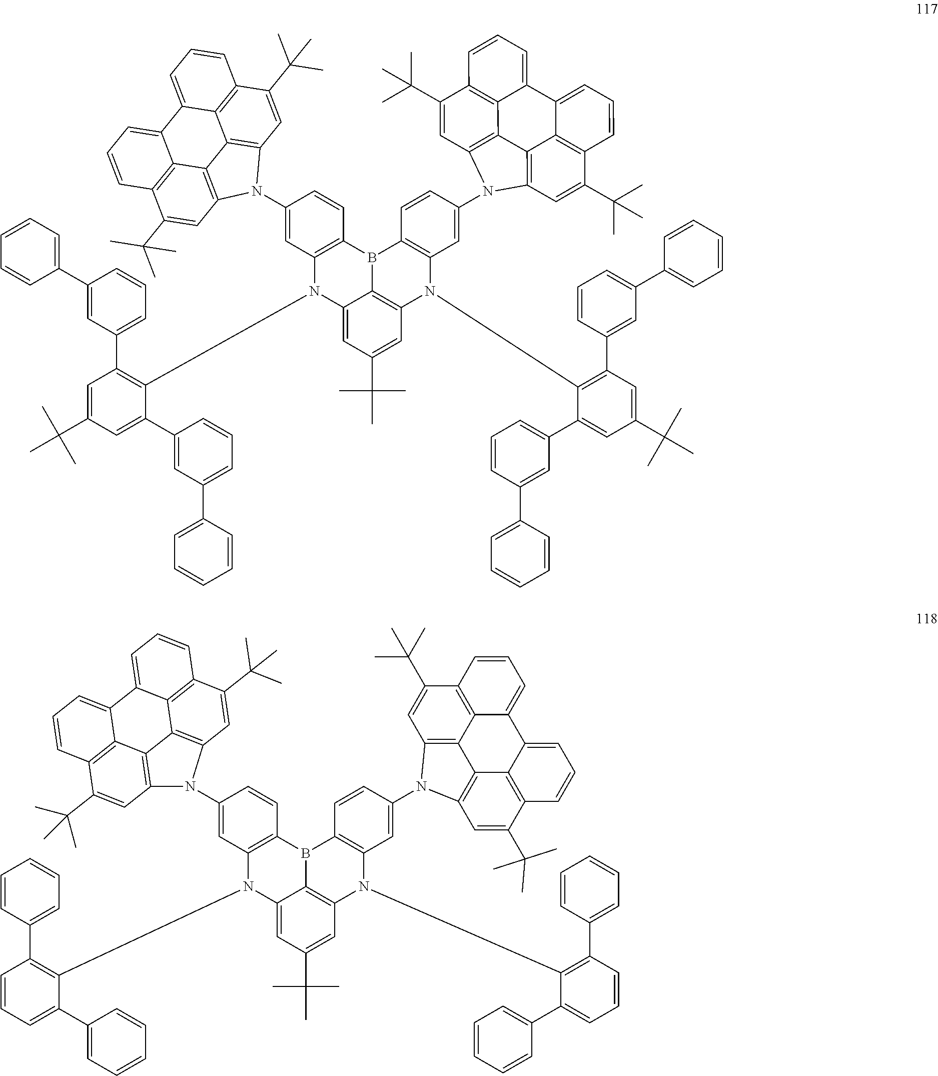

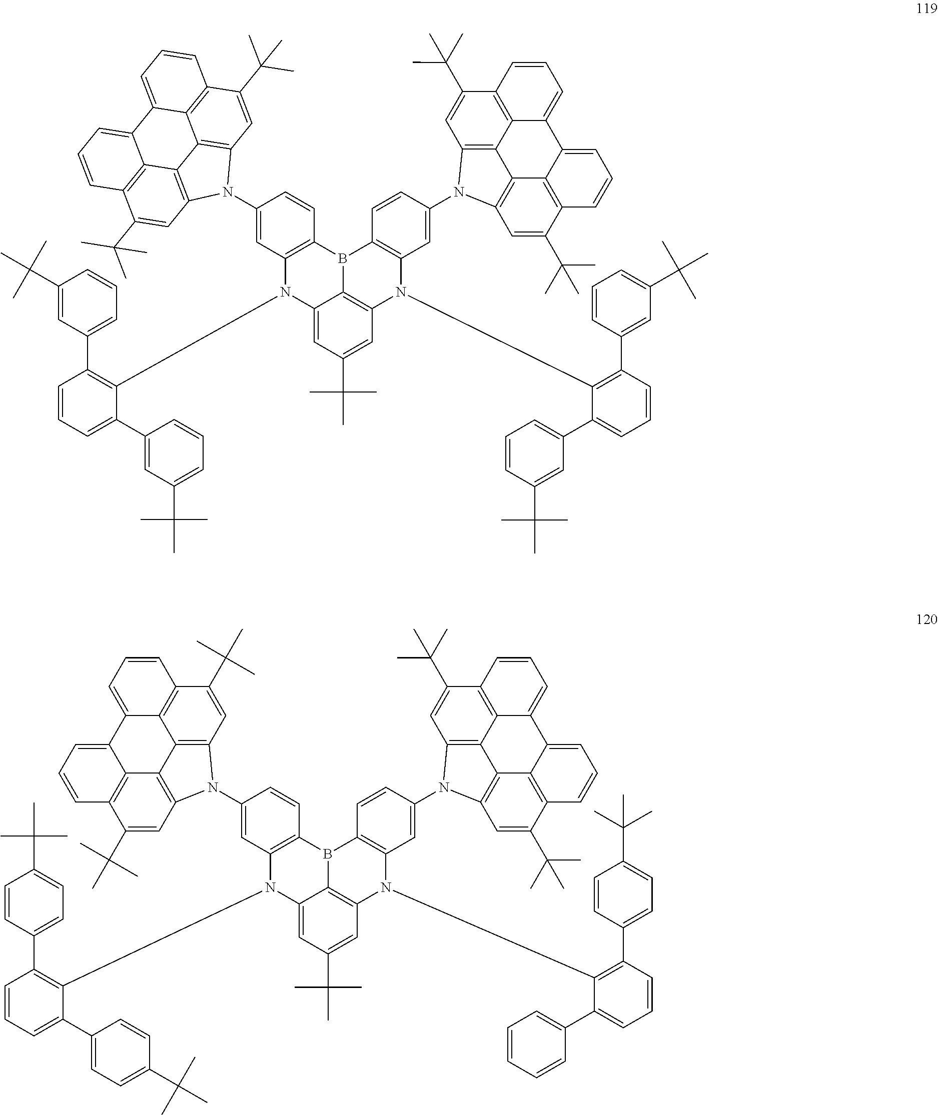

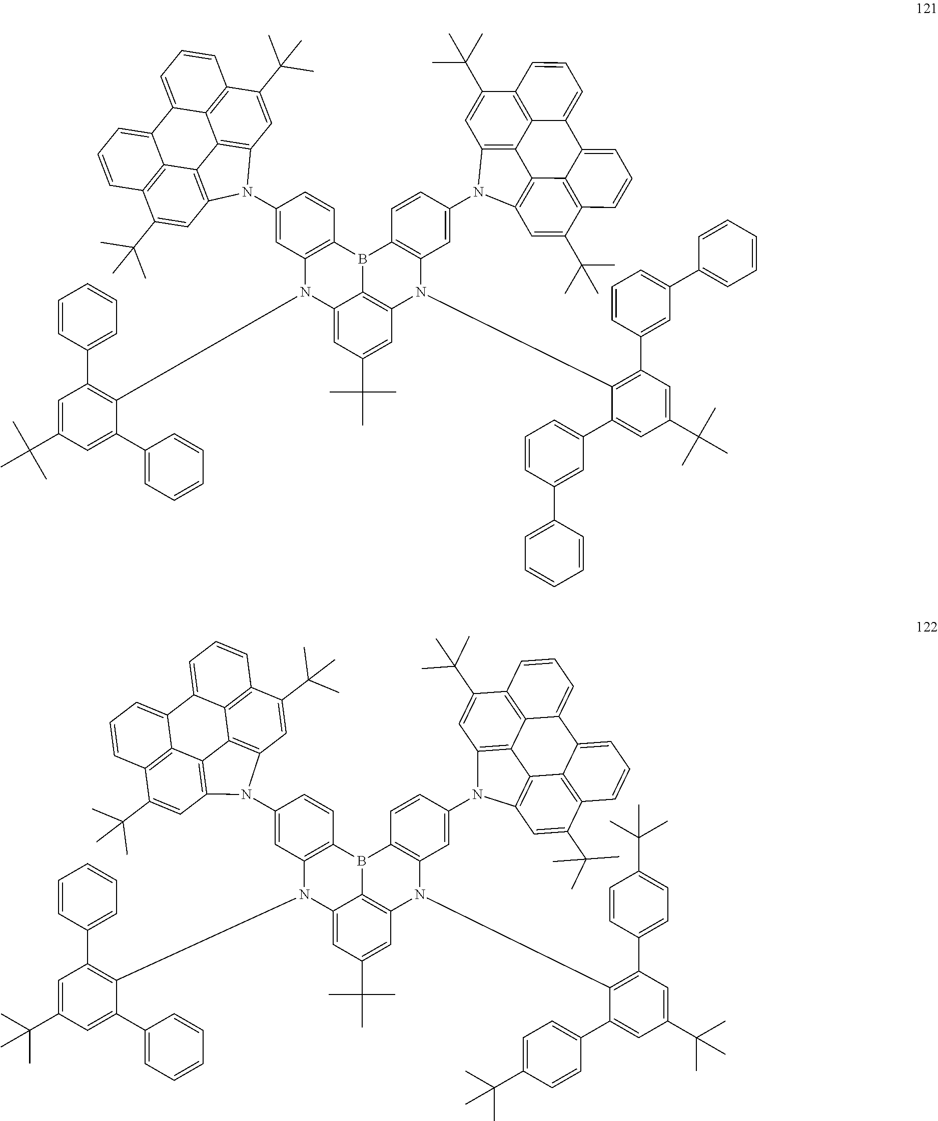

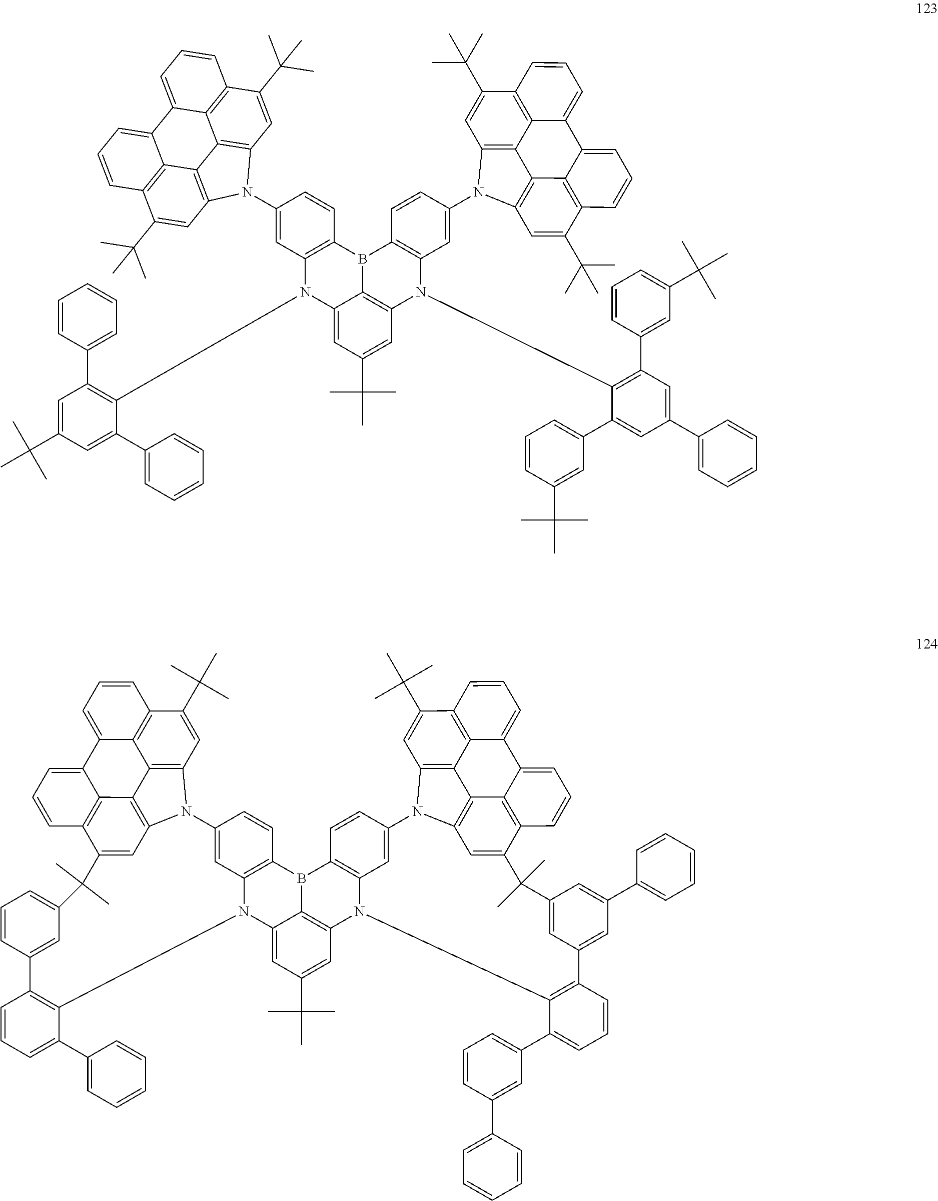 [SMILES: CC(C)(C)c1cccc(-c2cc(-c3ccccc3)cc(-c3cccc(C(C)(C)C)c3)c2N2c3cc(-n4c5cc(C(C)(C)C)c6cccc7c8cccc9c(C(C)(C)C)cc4c(c98)c5c67)ccc3B3c4ccc(-n5c6cc(C(C)(C)C)c7cccc8c9cccc%10c(C(C)(C)C)cc5c(c%109)c6c78)cc4N(c4c(-c5ccccc5)cc(C(C)(C)C)cc4-c4ccccc4)c4cc(C(C)(C)C)cc2c43)c1 ; CC(C)(C)c1cc2c3c(c1)N1c4cc(ccc4B3c3ccc4cc3N2c2c(-c3ccccc3)cccc2-c2cccc(c2)C(C)(C)c2cc3c5c6c2cccc6c2cccc6c(C(C)(C)C)cc(c5c62)n3-4)-n2c3cc(C(C)(C)C)c4cccc5c6cccc7c(cc2c(c76)c3c45)C(C)(C)c2cc(-c3ccccc3)cc(c2)-c2cccc(-c3cccc(-c4ccccc4)c3)c21]

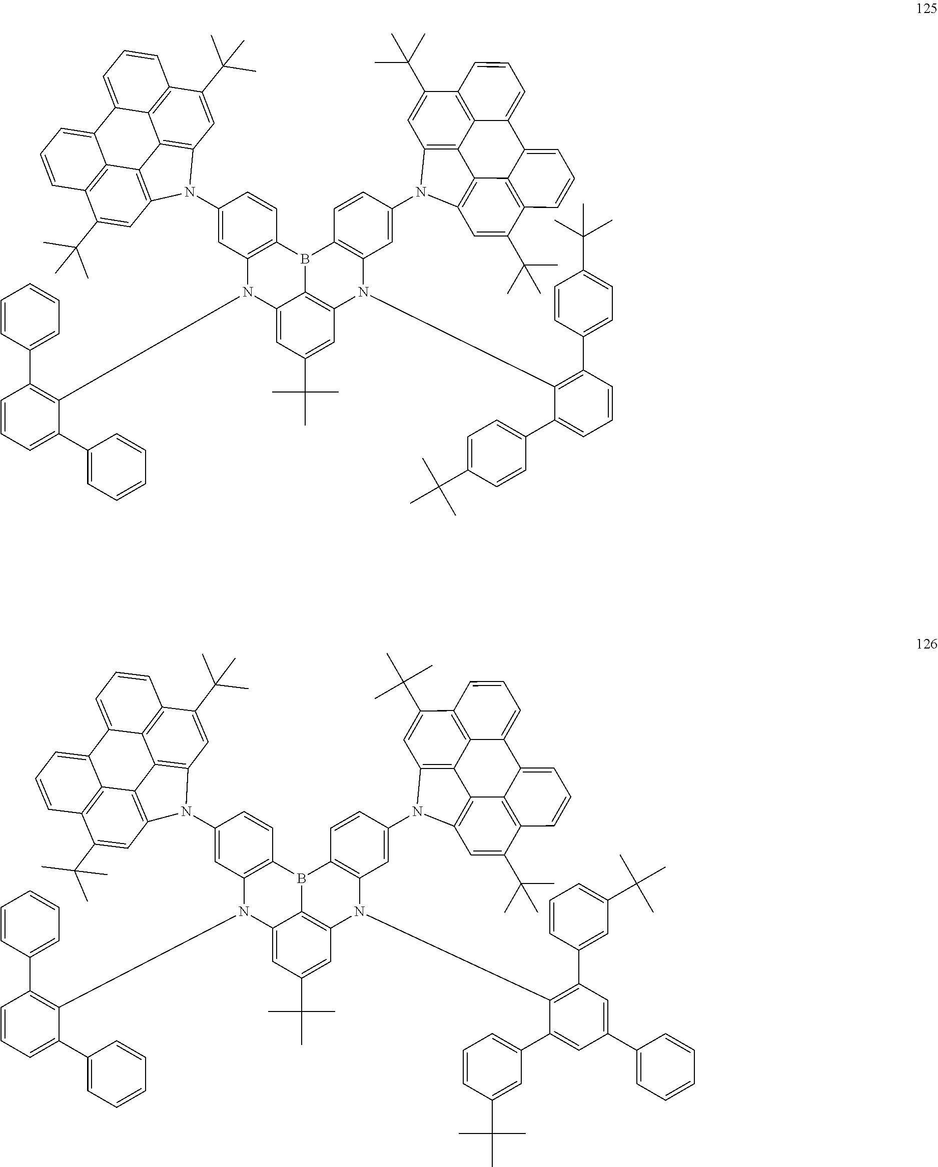 [SMILES: CC(C)(C)c1ccc(-c2cccc(-c3ccc(C(C)(C)C)cc3)c2N2c3cc(-n4c5cc(C(C)(C)C)c6cccc7c8cccc9c(C(C)(C)C)cc4c(c98)c5c67)ccc3B3c4ccc(-n5c6cc(C(C)(C)C)c7cccc8c9cccc%10c(C(C)(C)C)cc5c(c%109)c6c78)cc4N(c4c(-c5ccccc5)cccc4-c4ccccc4)c4cc(C(C)(C)C)cc2c43)cc1 ; CC(C)(C)c1cccc(-c2cc(-c3ccccc3)cc(-c3cccc(C(C)(C)C)c3)c2N2c3cc(-n4c5cc(C(C)(C)C)c6cccc7c8cccc9c(C(C)(C)C)cc4c(c98)c5c67)ccc3B3c4ccc(-n5c6cc(C(C)(C)C)c7cccc8c9cccc%10c(C(C)(C)C)cc5c(c%109)c6c78)cc4N(c4c(-c5ccccc5)cccc4-c4ccccc4)c4cc(C(C)(C)C)cc2c43)c1]

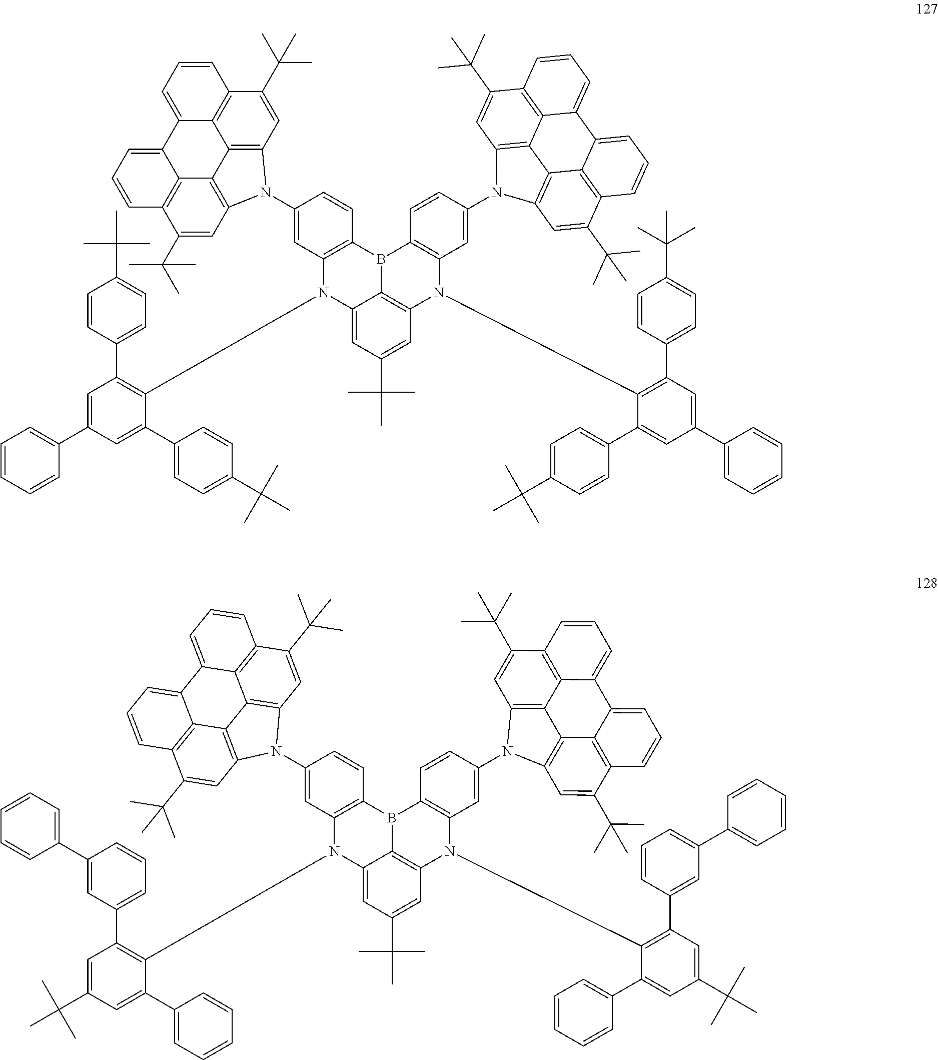

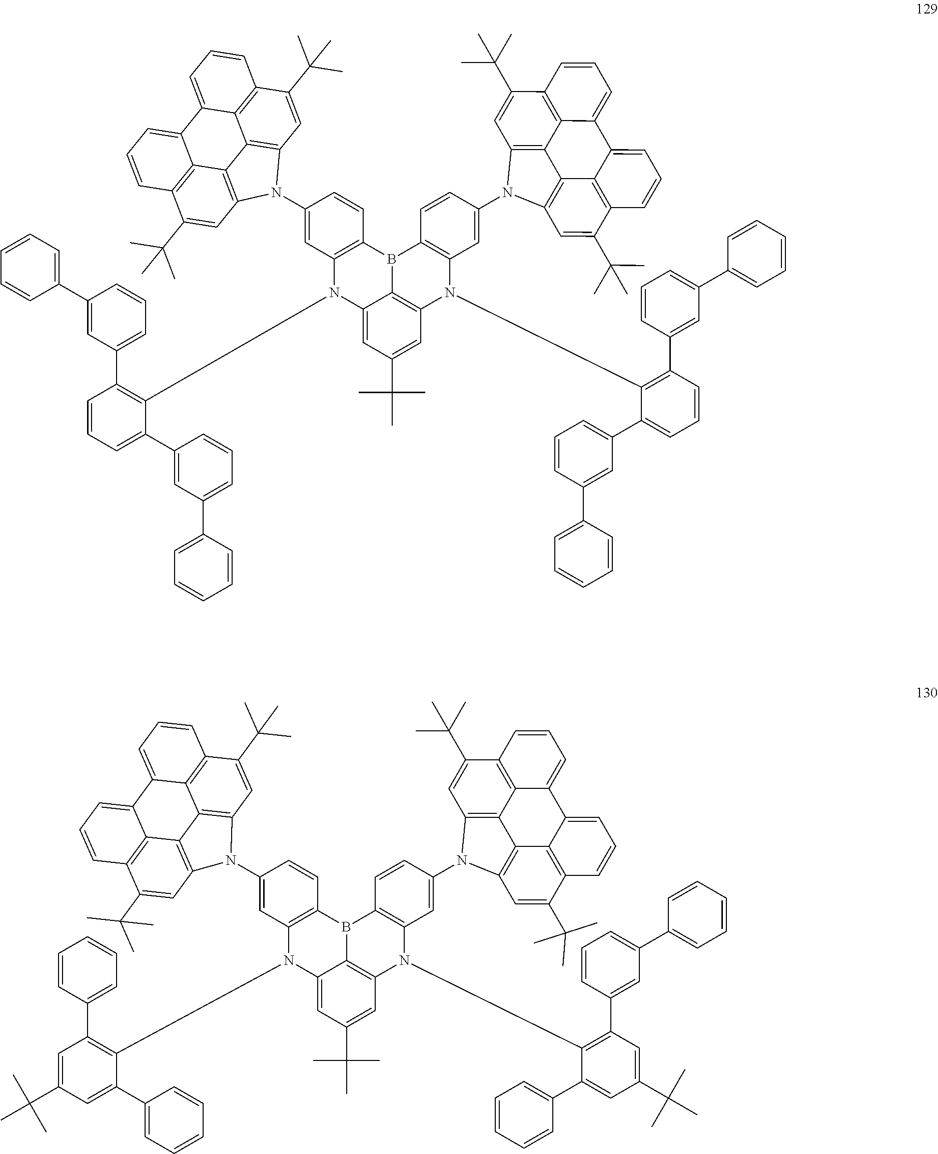

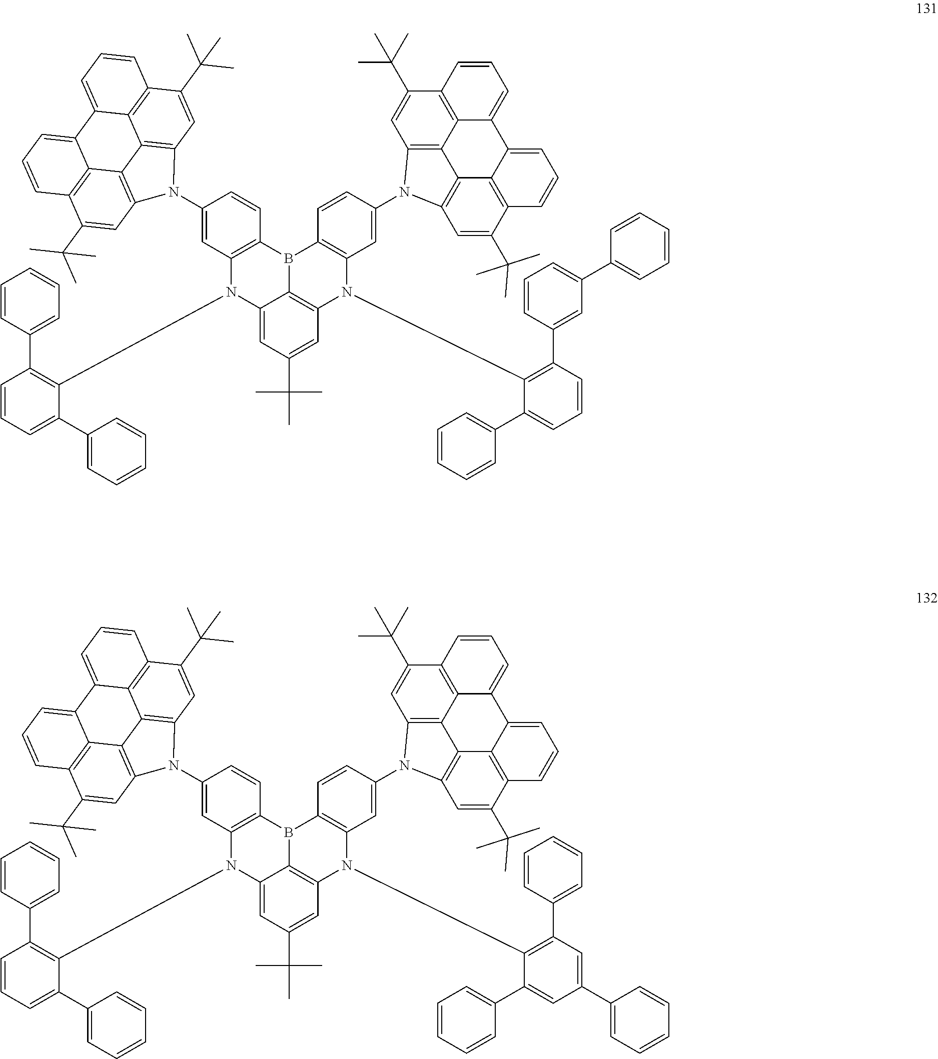 [SMILES: CC(C)(C)c1cc2c3c(c1)N(c1c(-c4ccccc4)cccc1-c1cccc(-c4ccccc4)c1)c1cc(-n4c5cc(C(C)(C)C)c6cccc7c8cccc9c(C(C)(C)C)cc4c(c98)c5c67)ccc1B3c1ccc(-n3c4cc(C(C)(C)C)c5cccc6c7cccc8c(C(C)(C)C)cc3c(c87)c4c56)cc1N2c1c(-c2ccccc2)cccc1-c1ccccc1 ; CC(C)(C)c1cc2c3c(c1)N(c1c(-c4ccccc4)cc(-c4ccccc4)cc1-c1ccccc1)c1cc(-n4c5cc(C(C)(C)C)c6cccc7c8cccc9c(C(C)(C)C)cc4c(c98)c5c67)ccc1B3c1ccc(-n3c4cc(C(C)(C)C)c5cccc6c7cccc8c(C(C)(C)C)cc3c(c87)c4c56)cc1N2c1c(-c2ccccc2)cccc1-c1ccccc1]

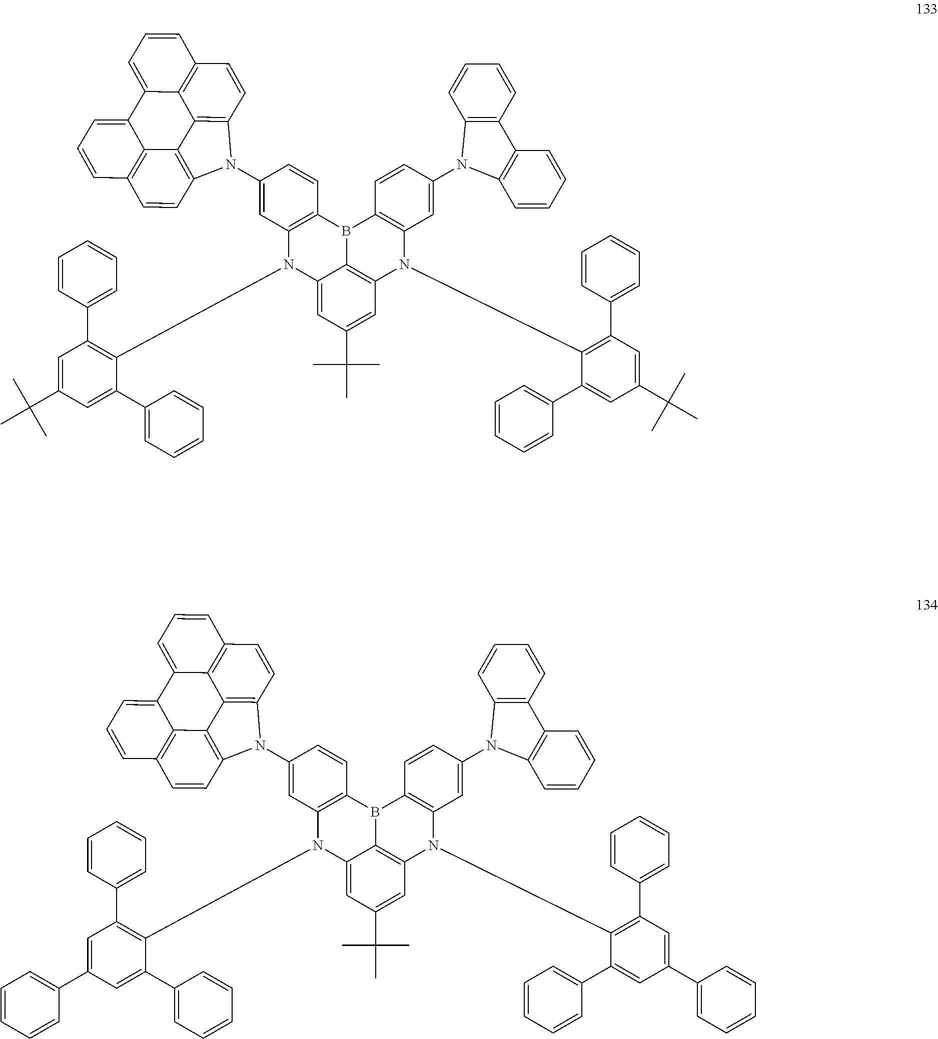 [SMILES: CC(C)(C)c1cc(-c2ccccc2)c(N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cc(-c2ccccc2)cc1-c1ccccc1]

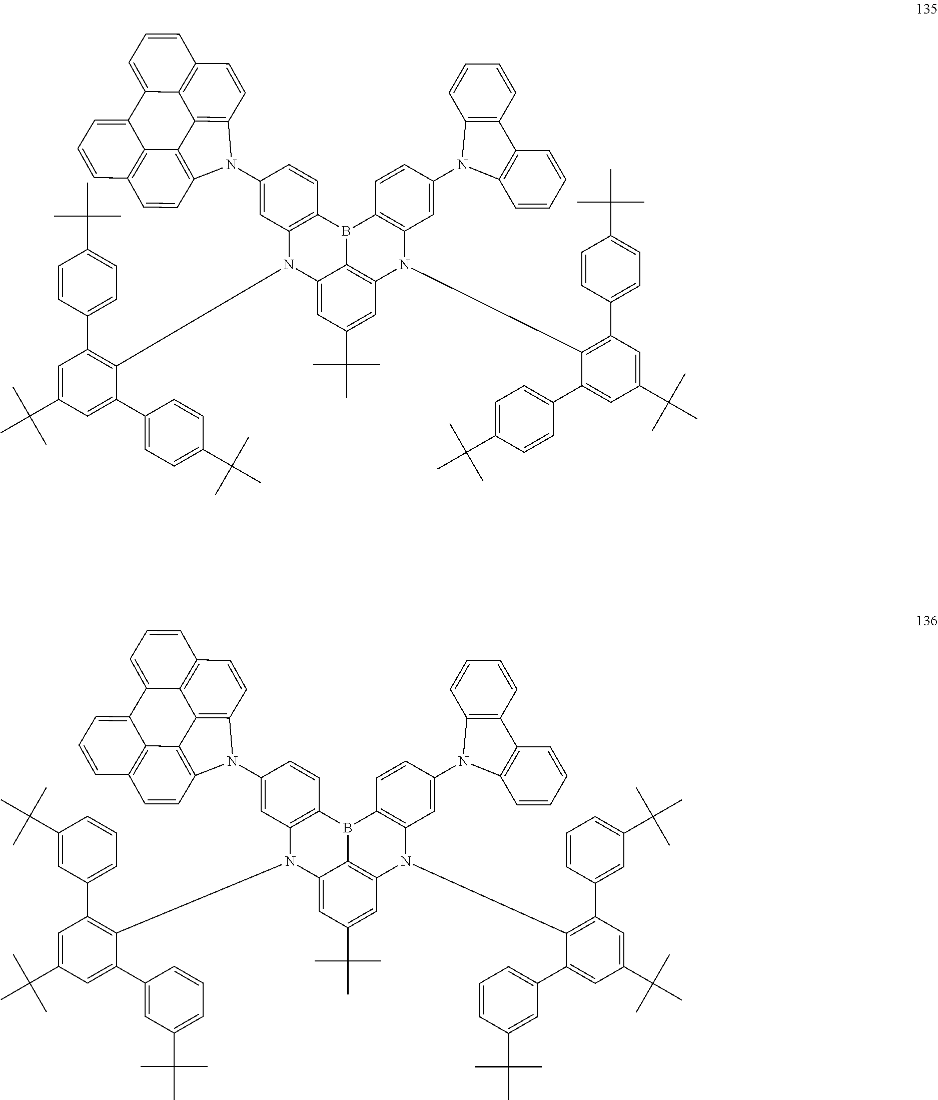

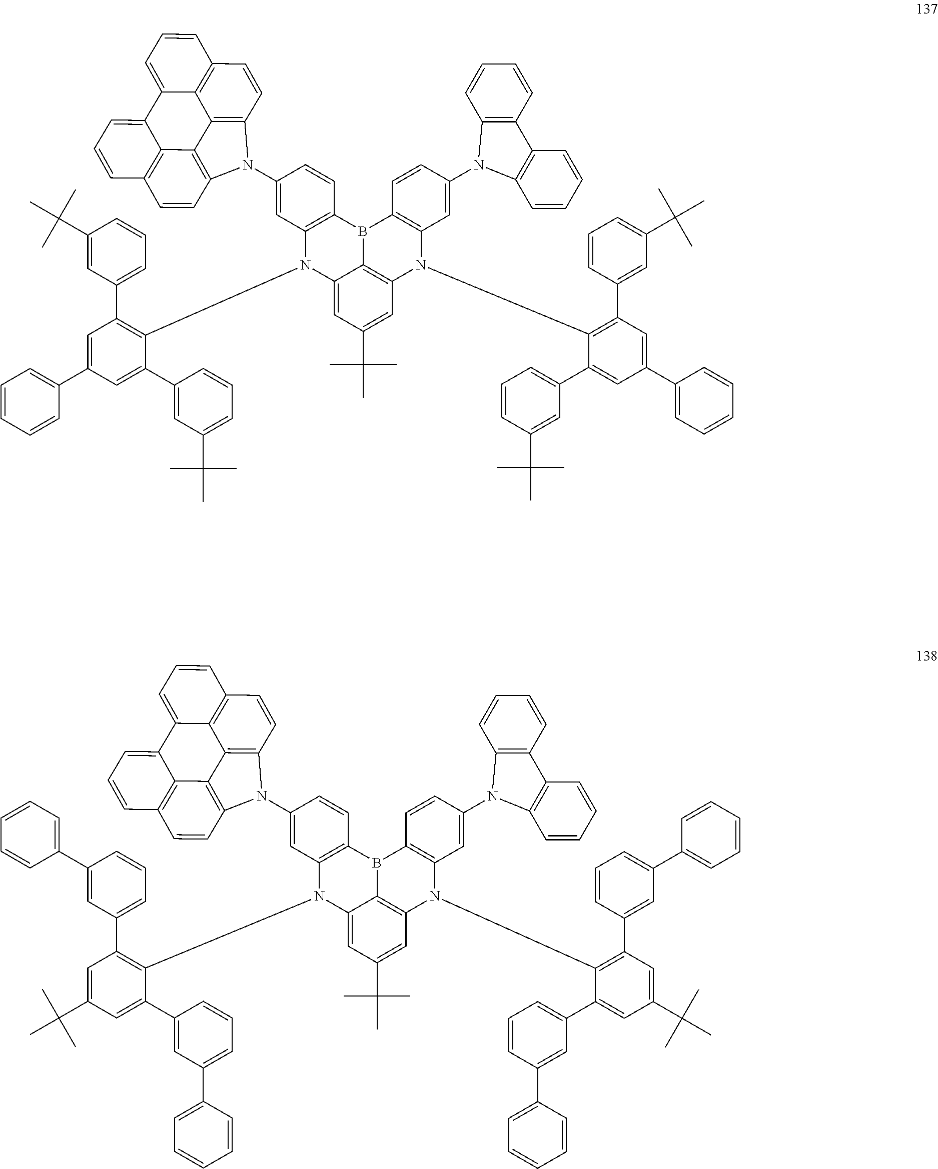 [SMILES: CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1 ; CC(C)(C)c1cc(-c2cccc(-c3ccccc3)c2)c(N2c3cc(-n4c5ccccc5c5ccccc54)ccc3B3c4ccc(-n5c6ccc7cccc8c9cccc%10ccc5c(c%109)c6c78)cc4N(c4c(-c5cccc(-c6ccccc6)c5)cc(C(C)(C)C)cc4-c4cccc(-c5ccccc5)c4)c4cc(C(C)(C)C)cc2c43)c(-c2cccc(-c3ccccc3)c2)c1]

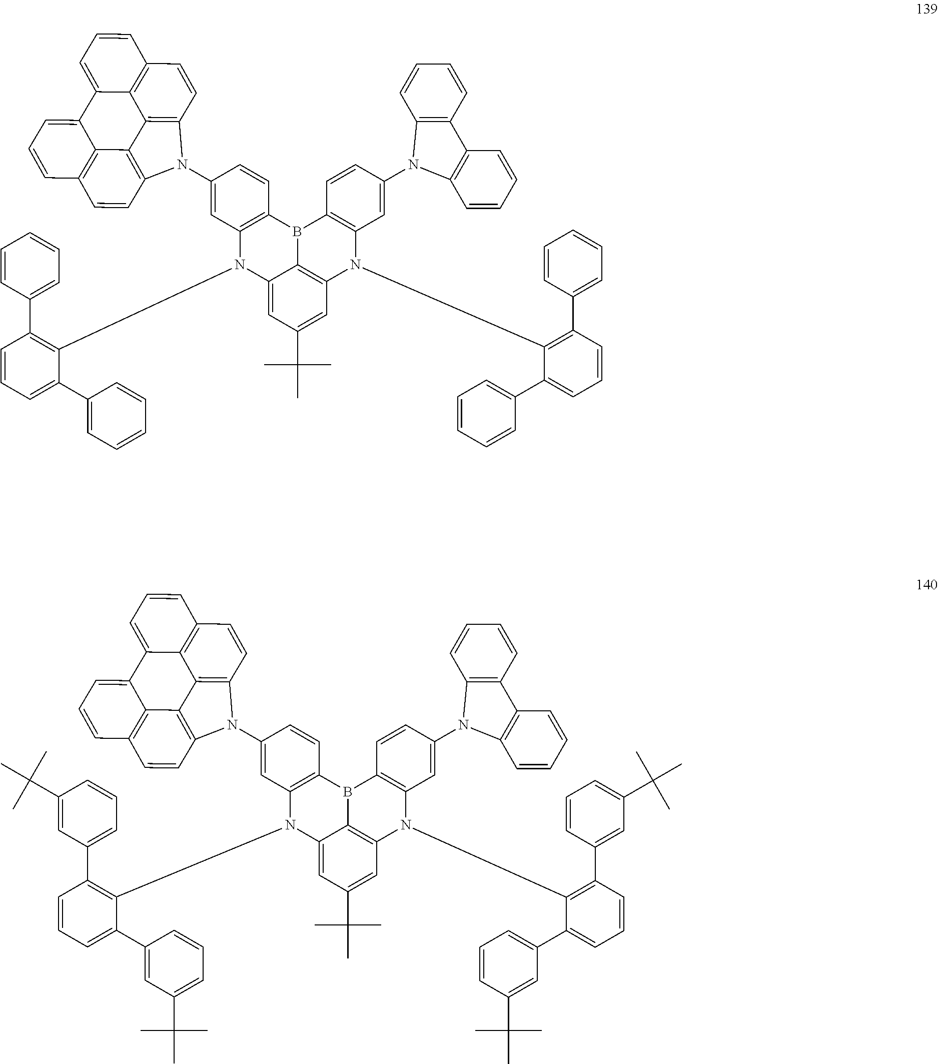 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cccc1-c1ccccc1 ; CC(C)(C)c1cccc(-c2cccc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5cccc(C(C)(C)C)c5)cccc4-c4cccc(C(C)(C)C)c4)c4cc(C(C)(C)C)cc2c43)c1]

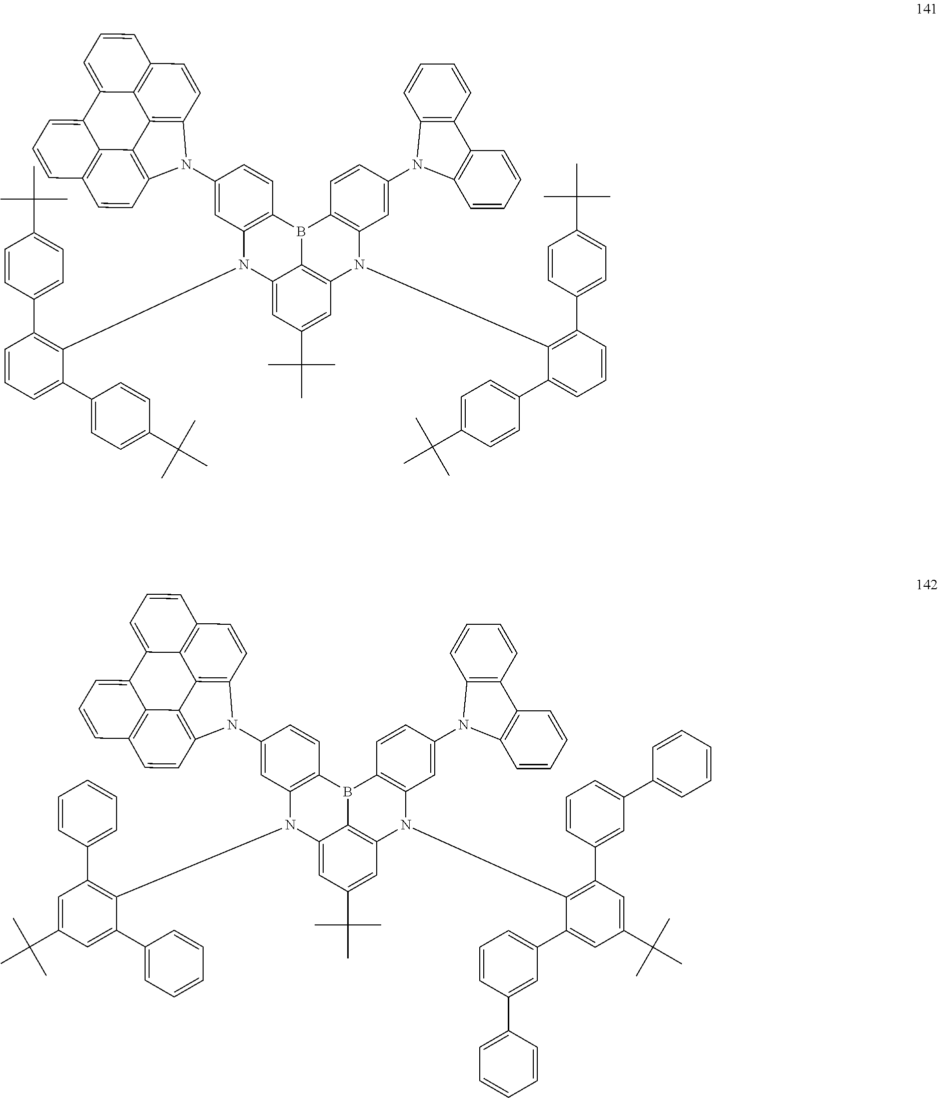

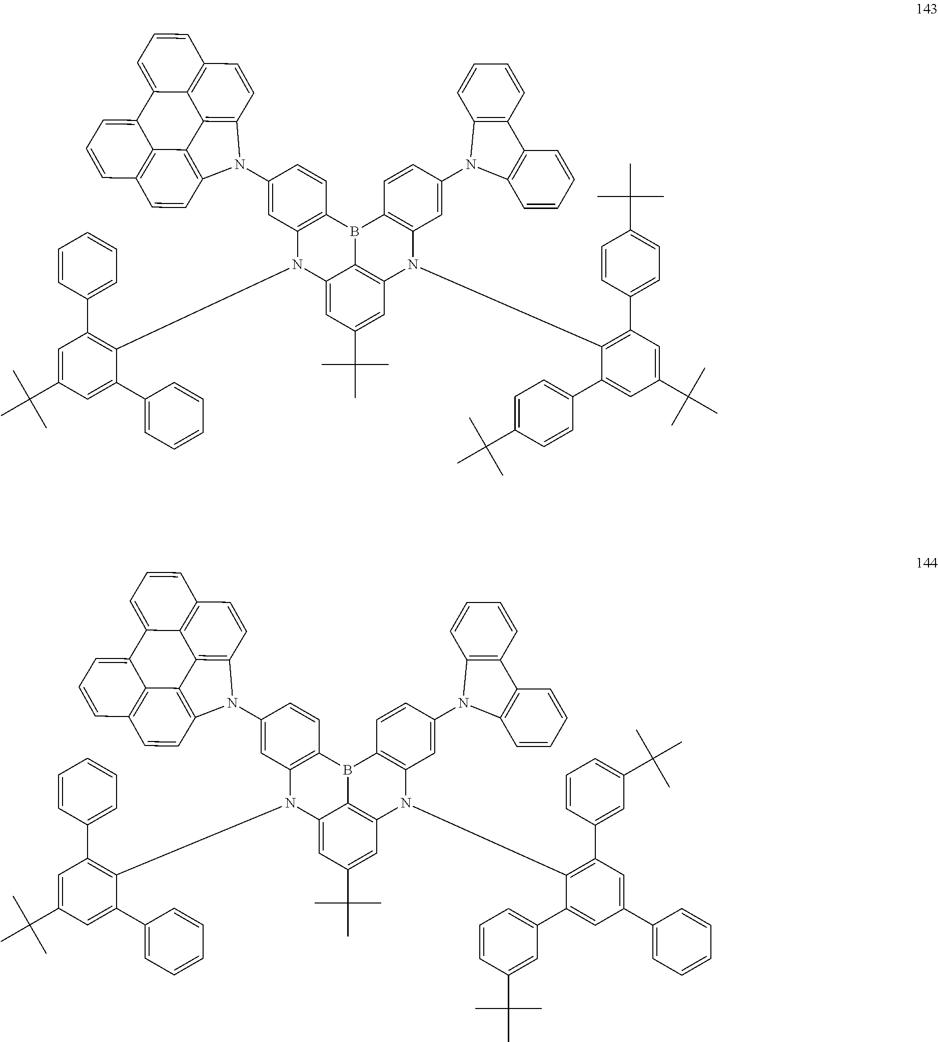

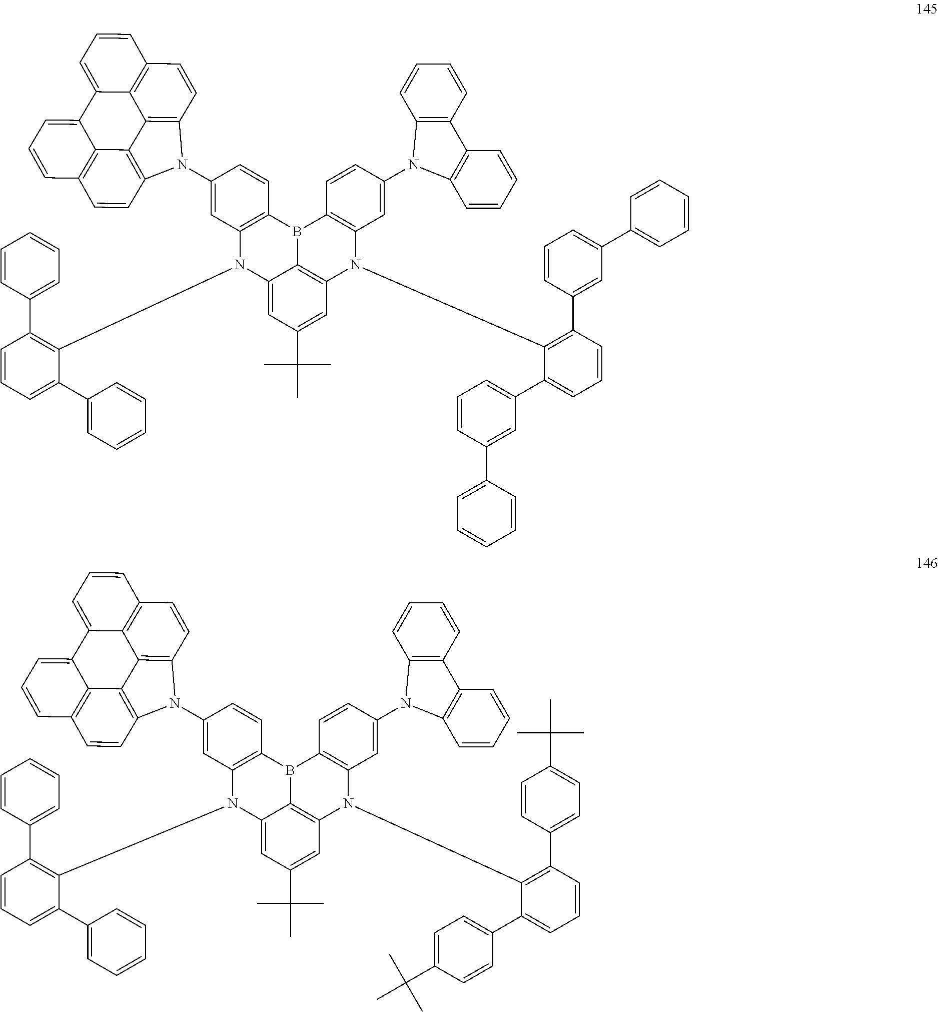 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2cccc(-c3ccccc3)c2)cccc1-c1cccc(-c2ccccc2)c1 ; CC(C)(C)c1ccc(-c2cccc(-c3ccc(C(C)(C)C)cc3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)cc1]

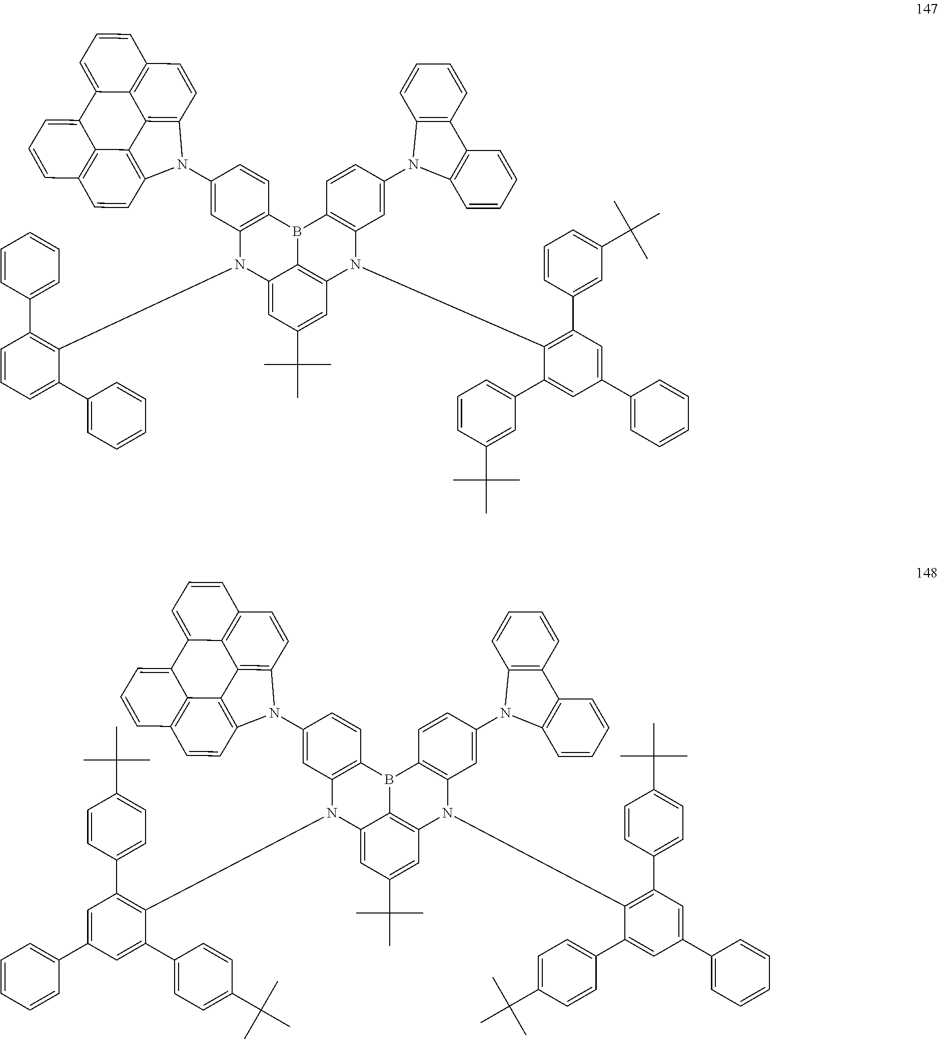 [SMILES: CC(C)(C)c1cccc(-c2cc(-c3ccccc3)cc(-c3cccc(C(C)(C)C)c3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)c1 ; CC(C)(C)c1ccc(-c2cc(-c3ccccc3)cc(-c3ccc(C(C)(C)C)cc3)c2N2c3cc(-n4c5ccccc5c5ccccc54)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

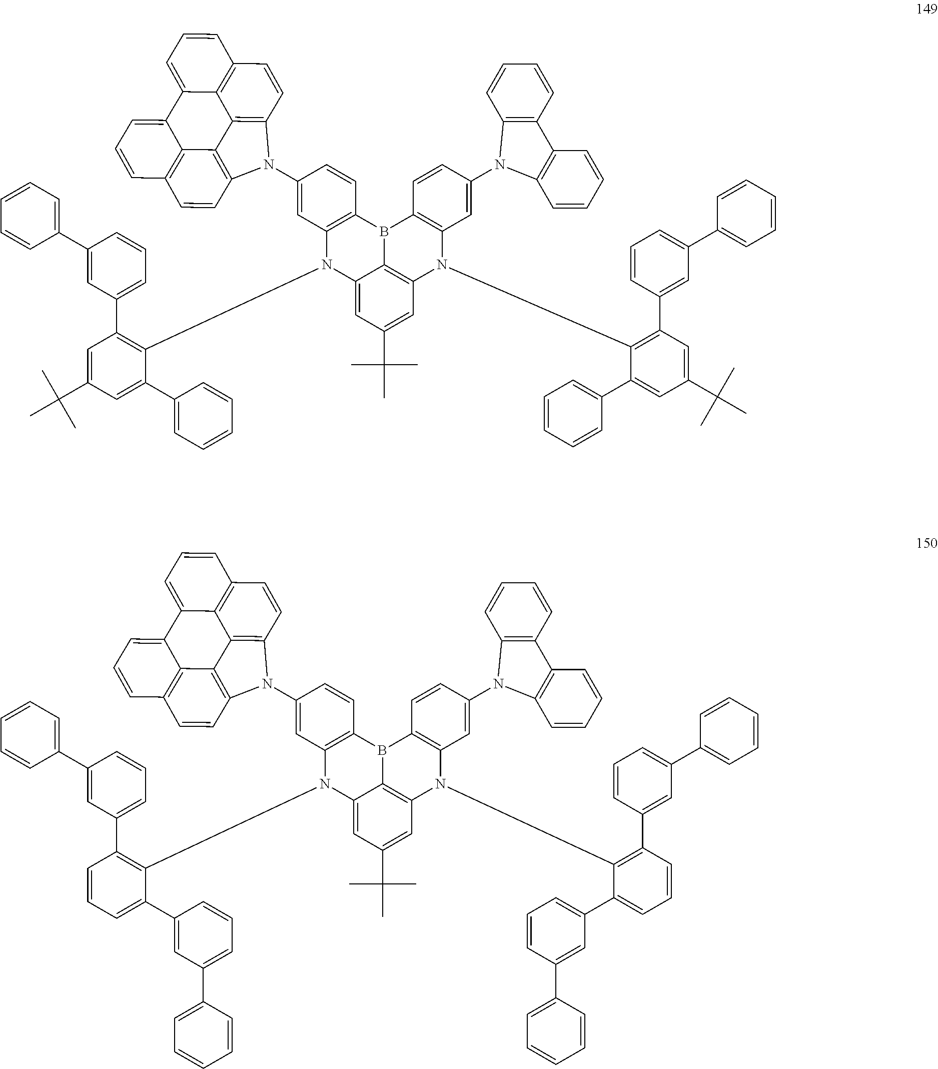 [SMILES: CC(C)(C)c1cc(-c2ccccc2)c(N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-n3c4ccccc4c4ccccc43)cc1N2c1c(-c2cccc(-c3ccccc3)c2)cccc1-c1cccc(-c2ccccc2)c1]

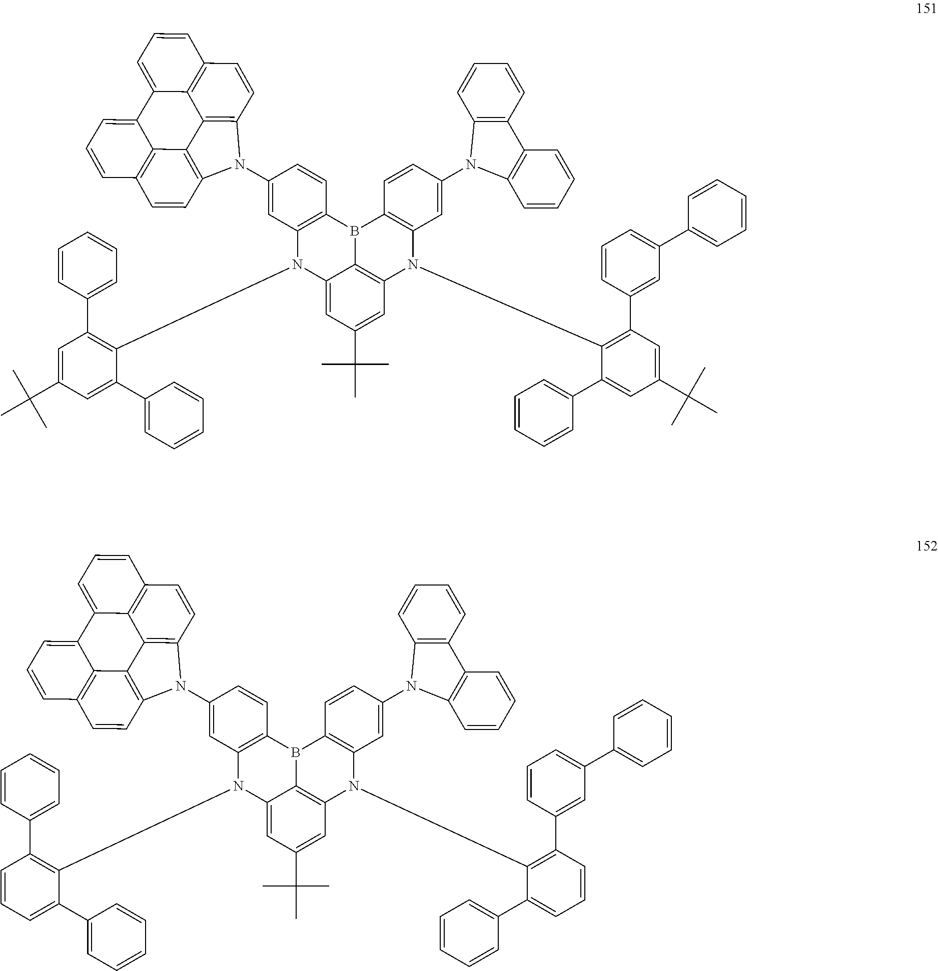 [SMILES: CC(C)(C)c1cc(-c2ccccc2)c(N2c3cc(-n4c5ccccc5c5ccccc54)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cccc1-c1cccc(-c2ccccc2)c1]

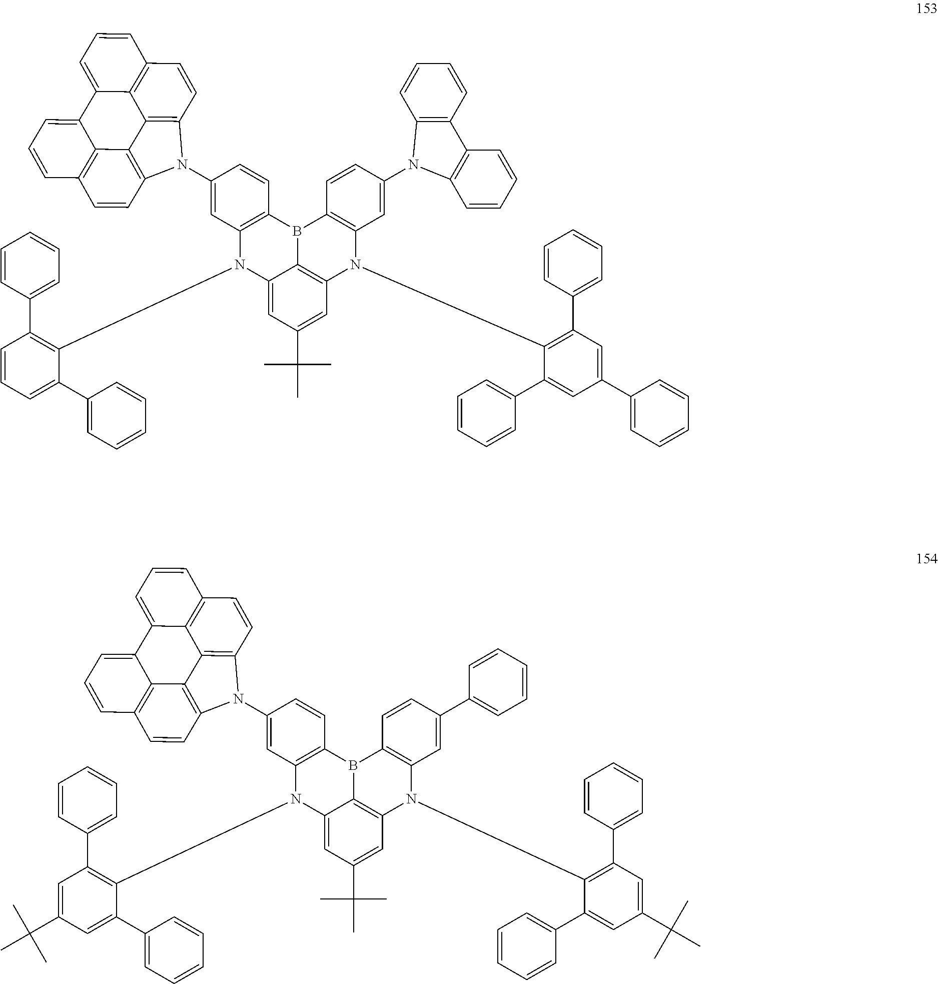 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-n3c4ccccc4c4ccccc43)cc1N2c1c(-c2ccccc2)cc(-c2ccccc2)cc1-c1ccccc1 ; CC(C)(C)c1cc(-c2ccccc2)c(N2c3cc(-c4ccccc4)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2ccccc2)c1]

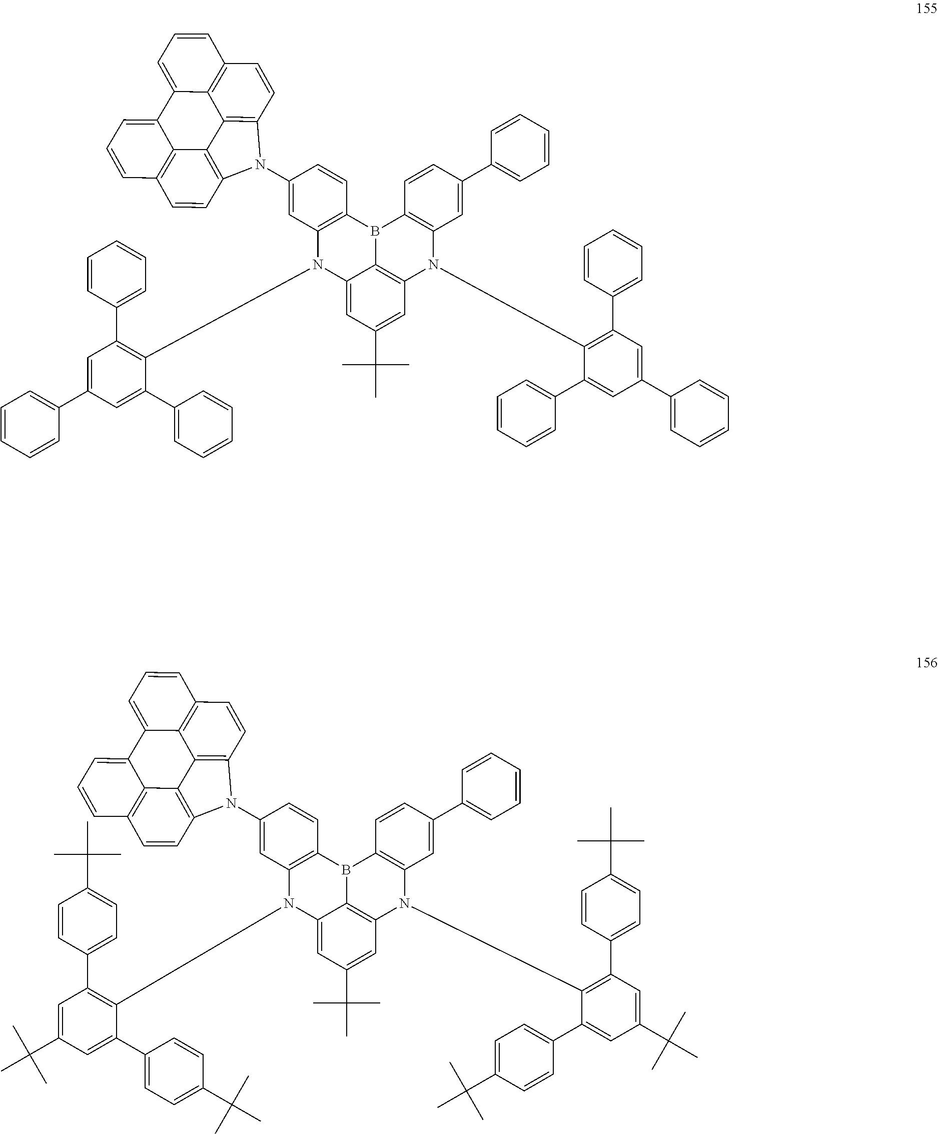 [SMILES: CC(C)(C)c1cc2c3c(c1)N(c1c(-c4ccccc4)cc(-c4ccccc4)cc1-c1ccccc1)c1cc(-n4c5ccc6cccc7c8cccc9ccc4c(c98)c5c67)ccc1B3c1ccc(-c3ccccc3)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-c4ccccc4)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

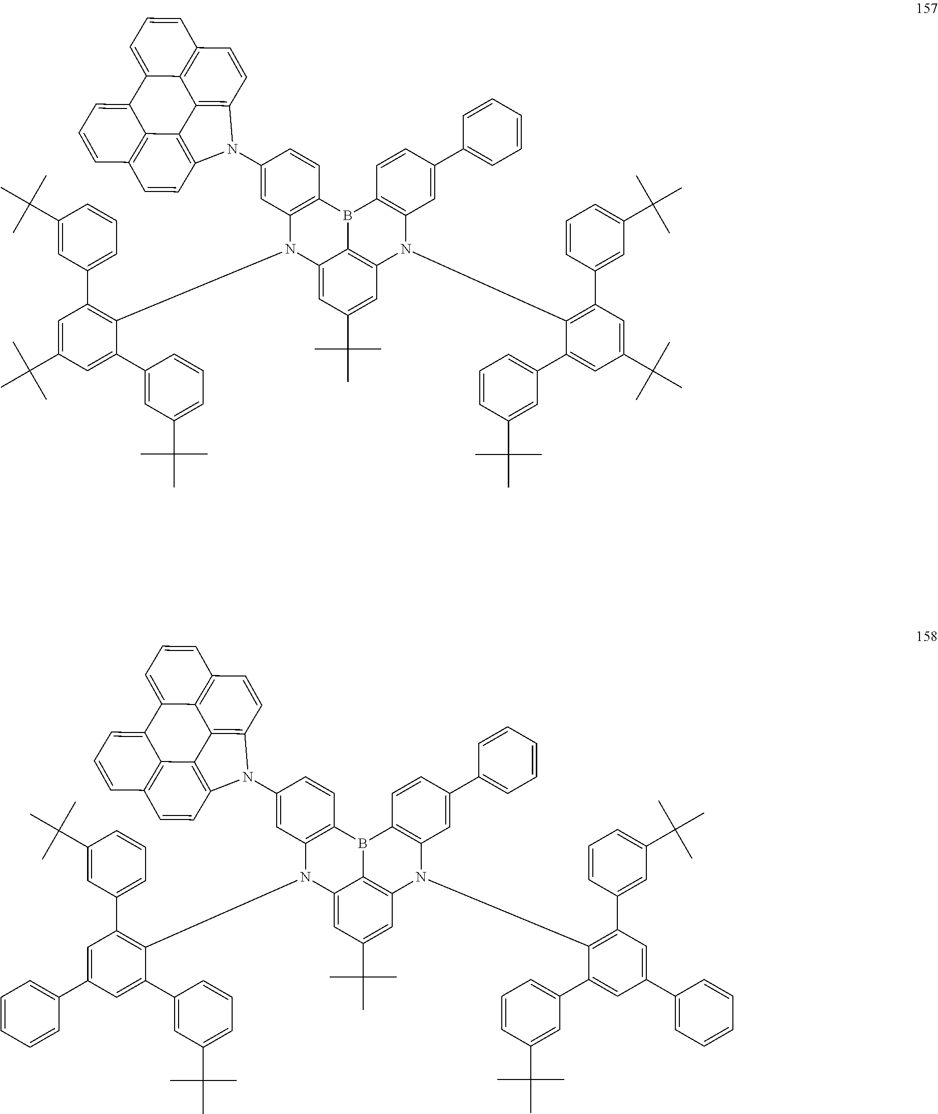 [SMILES: CC(C)(C)c1cccc(-c2cc(C(C)(C)C)cc(-c3cccc(C(C)(C)C)c3)c2N2c3cc(-c4ccccc4)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-c4ccccc4)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1]

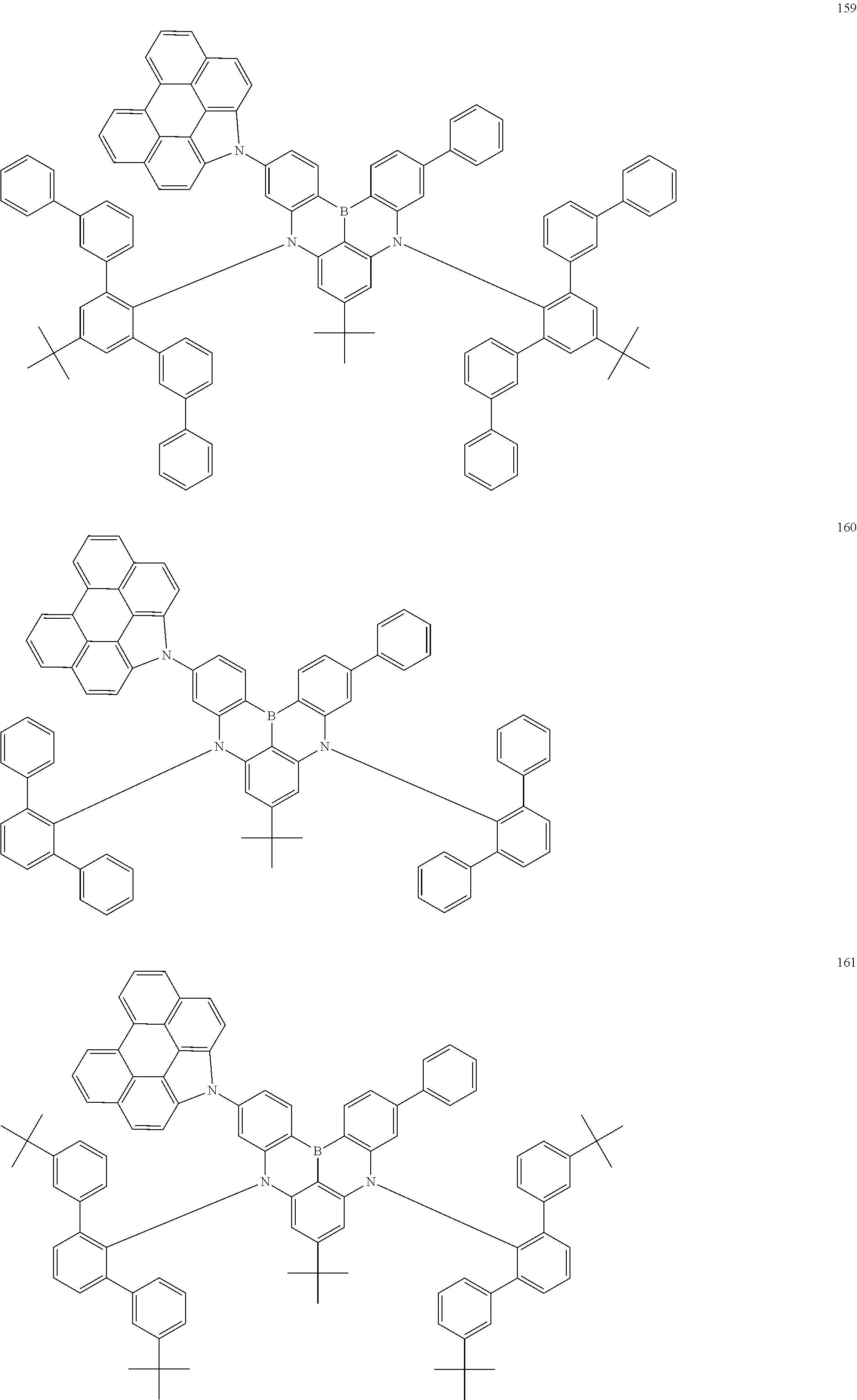

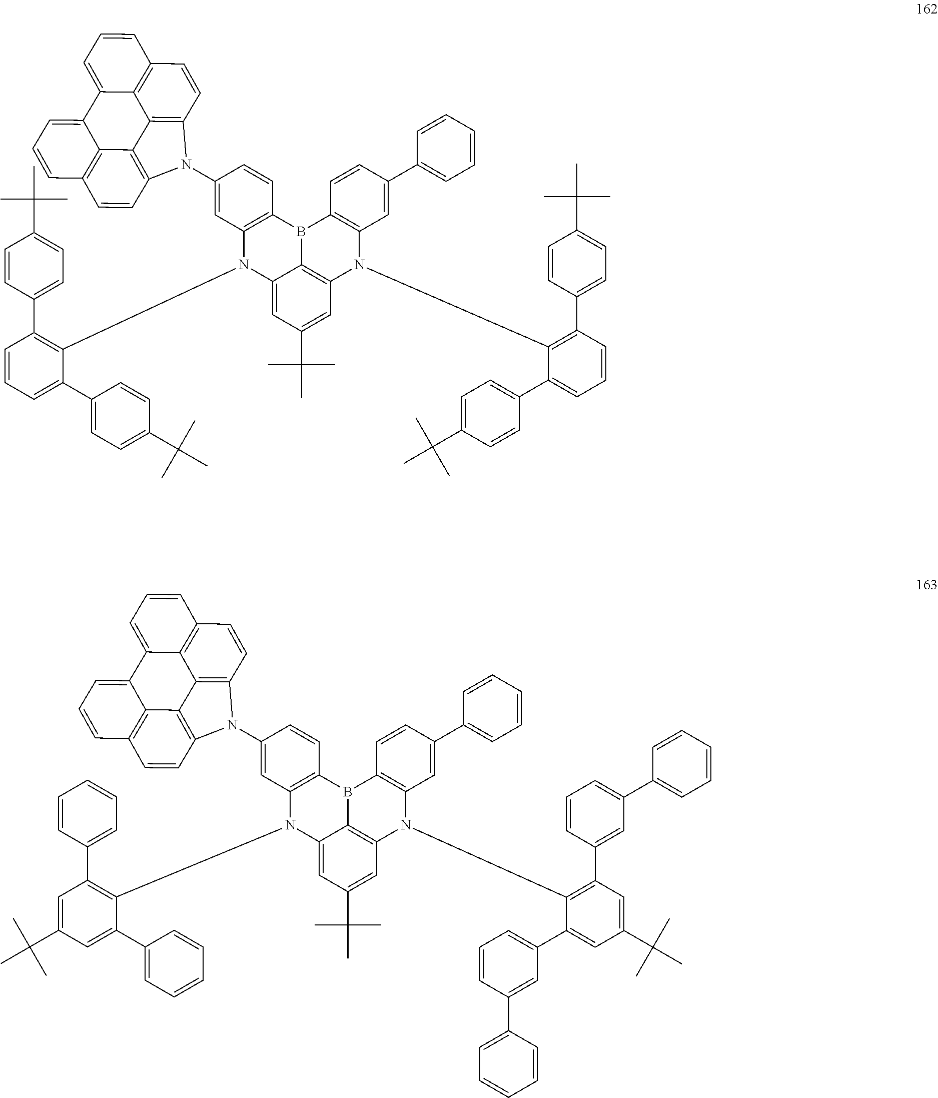

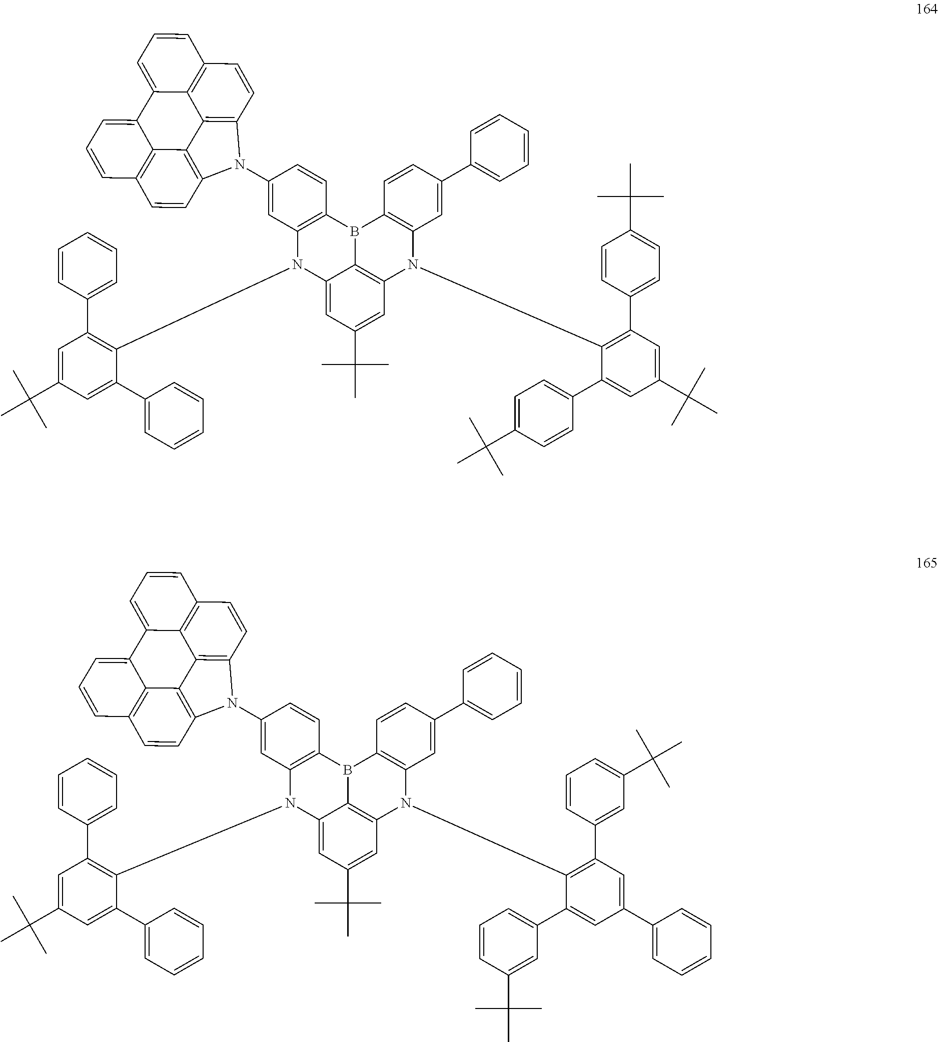

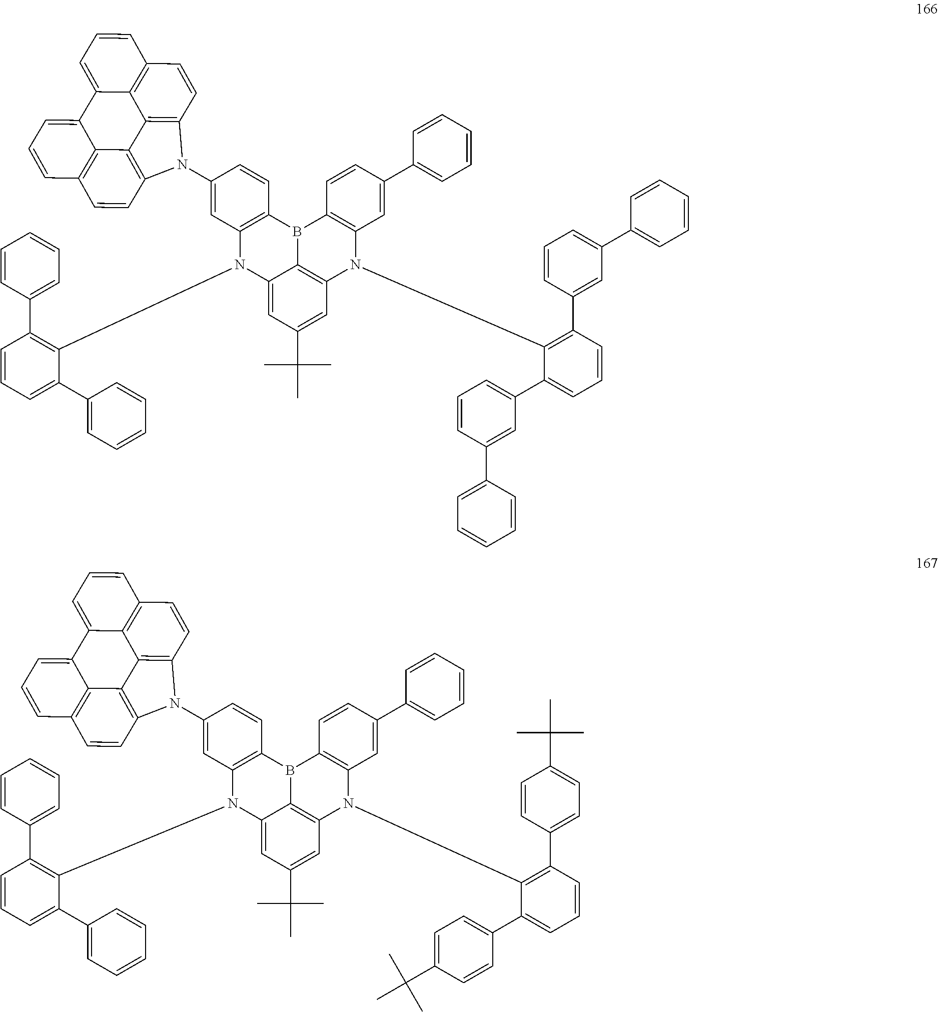 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-c3ccccc3)cc1N2c1c(-c2cccc(-c3ccccc3)c2)cccc1-c1cccc(-c2ccccc2)c1 ; CC(C)(C)c1ccc(-c2cccc(-c3ccc(C(C)(C)C)cc3)c2N2c3cc(-c4ccccc4)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)cc1]

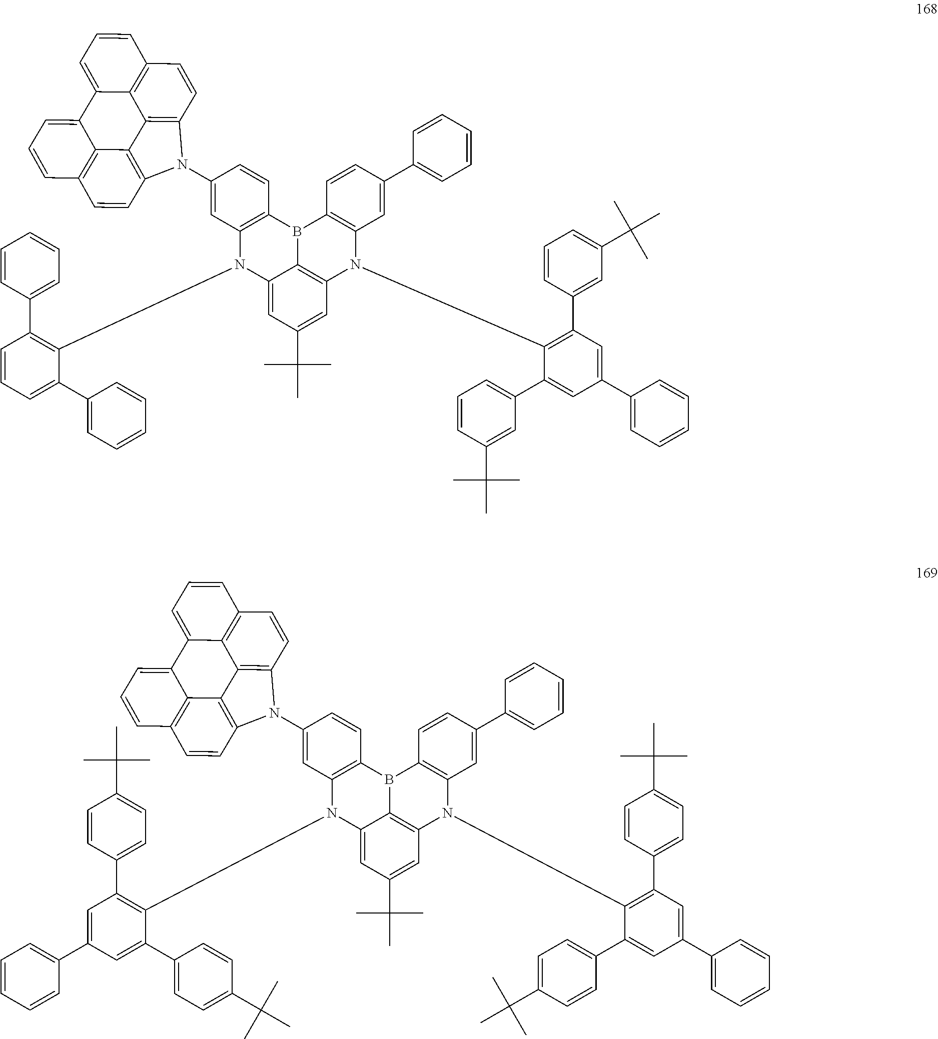 [SMILES: CC(C)(C)c1cccc(-c2cc(-c3ccccc3)cc(-c3cccc(C(C)(C)C)c3)c2N2c3cc(-c4ccccc4)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)c1 ; CC(C)(C)c1ccc(-c2cc(-c3ccccc3)cc(-c3ccc(C(C)(C)C)cc3)c2N2c3cc(-c4ccccc4)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

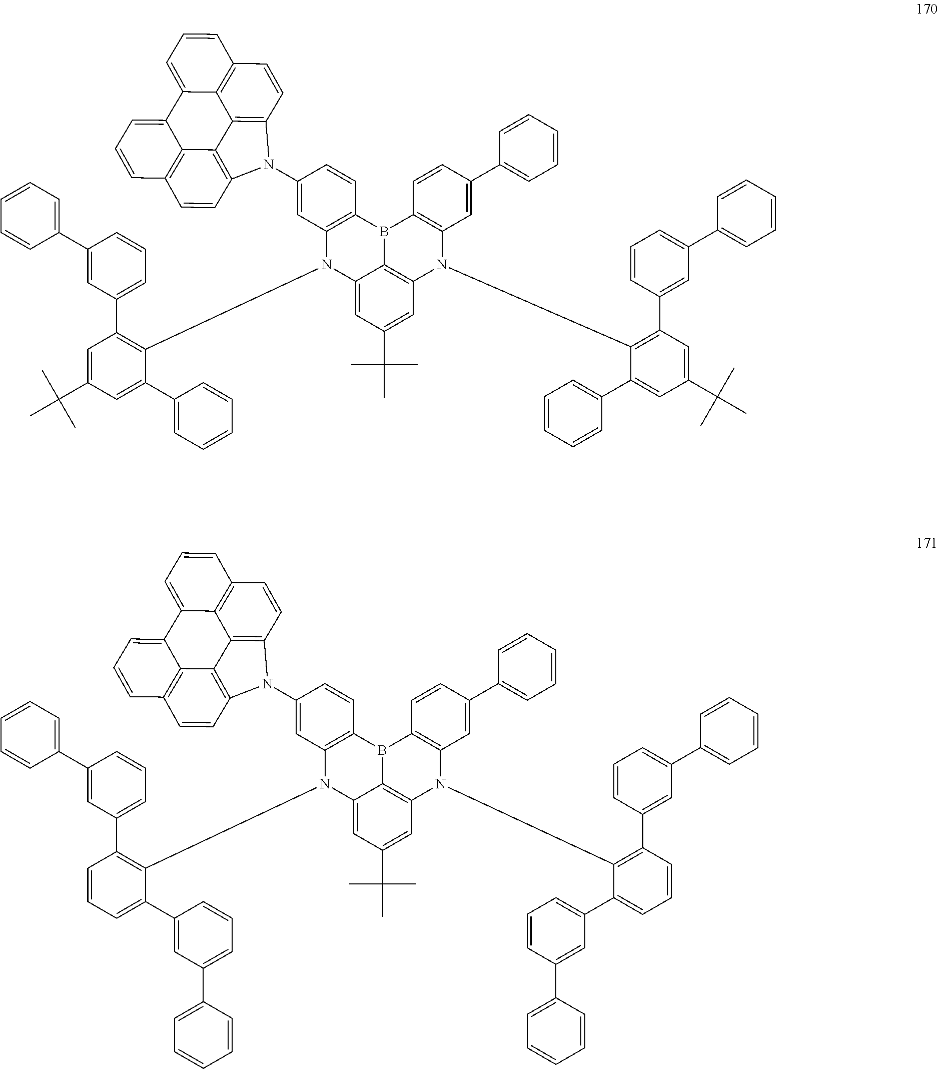 [SMILES: CC(C)(C)c1cc(-c2ccccc2)c(N2c3cc(-c4ccccc4)ccc3B3c4ccc(-n5c6ccc7cccc8c9cccc%10ccc5c(c%109)c6c78)cc4N(c4c(-c5ccccc5)cc(C(C)(C)C)cc4-c4cccc(-c5ccccc5)c4)c4cc(C(C)(C)C)cc2c43)c(-c2cccc(-c3ccccc3)c2)c1 ; CC(C)(C)c1cc2c3c(c1)N(c1c(-c4cccc(-c5ccccc5)c4)cccc1-c1cccc(-c4ccccc4)c1)c1cc(-n4c5ccc6cccc7c8cccc9ccc4c(c98)c5c67)ccc1B3c1ccc(-c3ccccc3)cc1N2c1c(-c2cccc(-c3ccccc3)c2)cccc1-c1cccc(-c2ccccc2)c1]

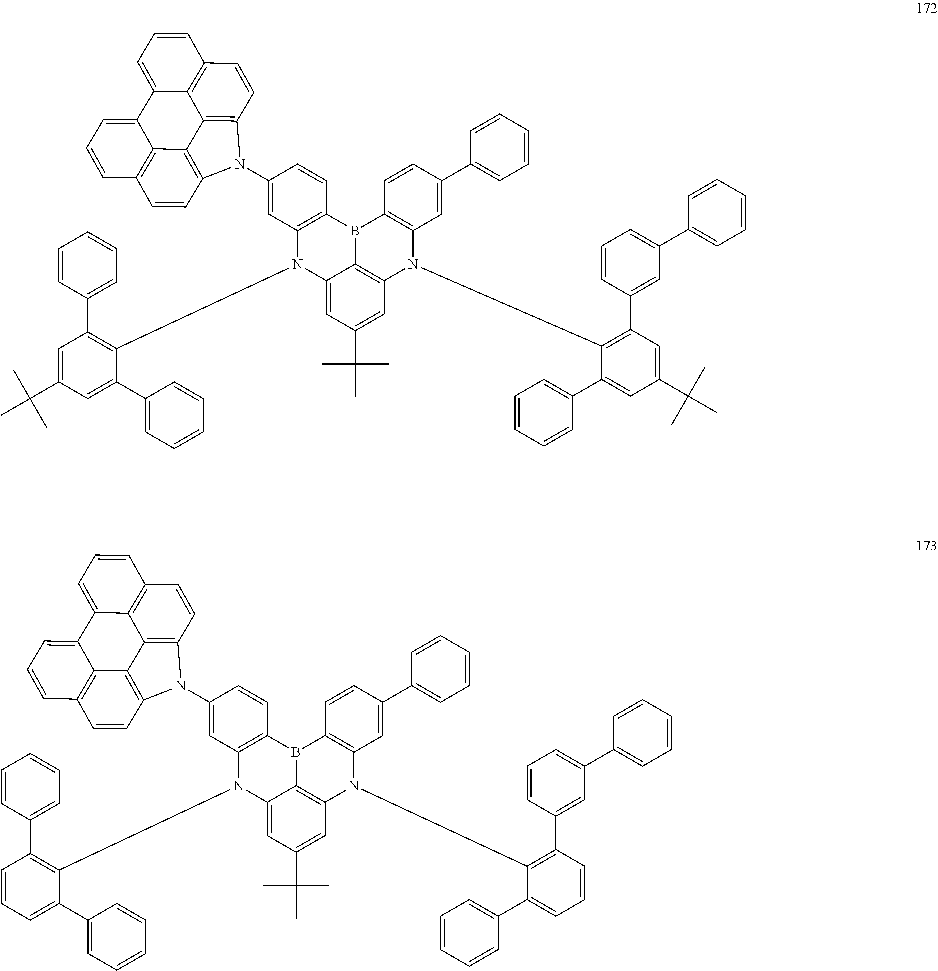 [SMILES: CC(C)(C)c1cc(-c2ccccc2)c(N2c3cc(-c4ccccc4)ccc3B3c4ccc(-n5c6ccc7cccc8c9cccc%10ccc5c(c%109)c6c78)cc4N(c4c(-c5ccccc5)cc(C(C)(C)C)cc4-c4ccccc4)c4cc(C(C)(C)C)cc2c43)c(-c2cccc(-c3ccccc3)c2)c1 ; CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-c3ccccc3)cc1N2c1c(-c2ccccc2)cccc1-c1cccc(-c2ccccc2)c1]

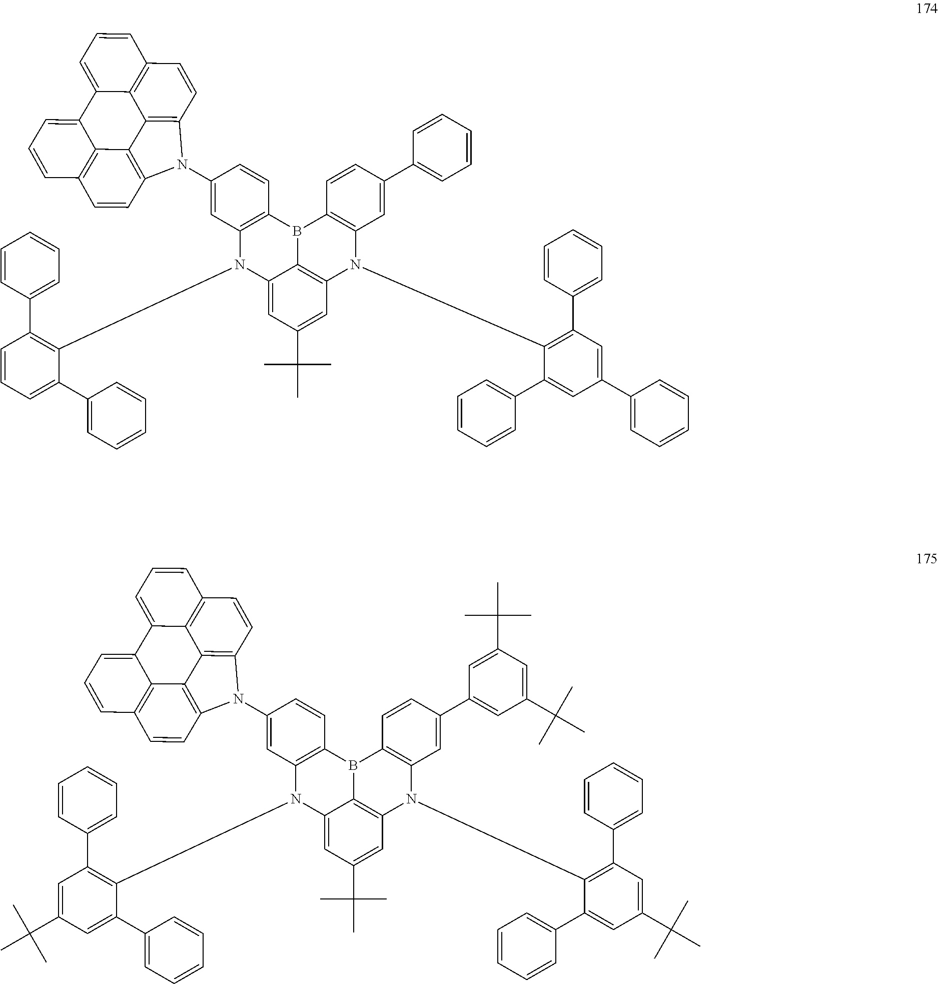 [SMILES: CC(C)(C)c1cc2c3c(c1)N(c1c(-c4ccccc4)cccc1-c1ccccc1)c1cc(-n4c5ccc6cccc7c8cccc9ccc4c(c98)c5c67)ccc1B3c1ccc(-c3ccccc3)cc1N2c1c(-c2ccccc2)cc(-c2ccccc2)cc1-c1ccccc1 ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccc6cccc7c8cccc9ccc3c(c98)c5c67)cc2N4c2c(-c3ccccc3)cc(C(C)(C)C)cc2-c2ccccc2)cc(C(C)(C)C)c1]

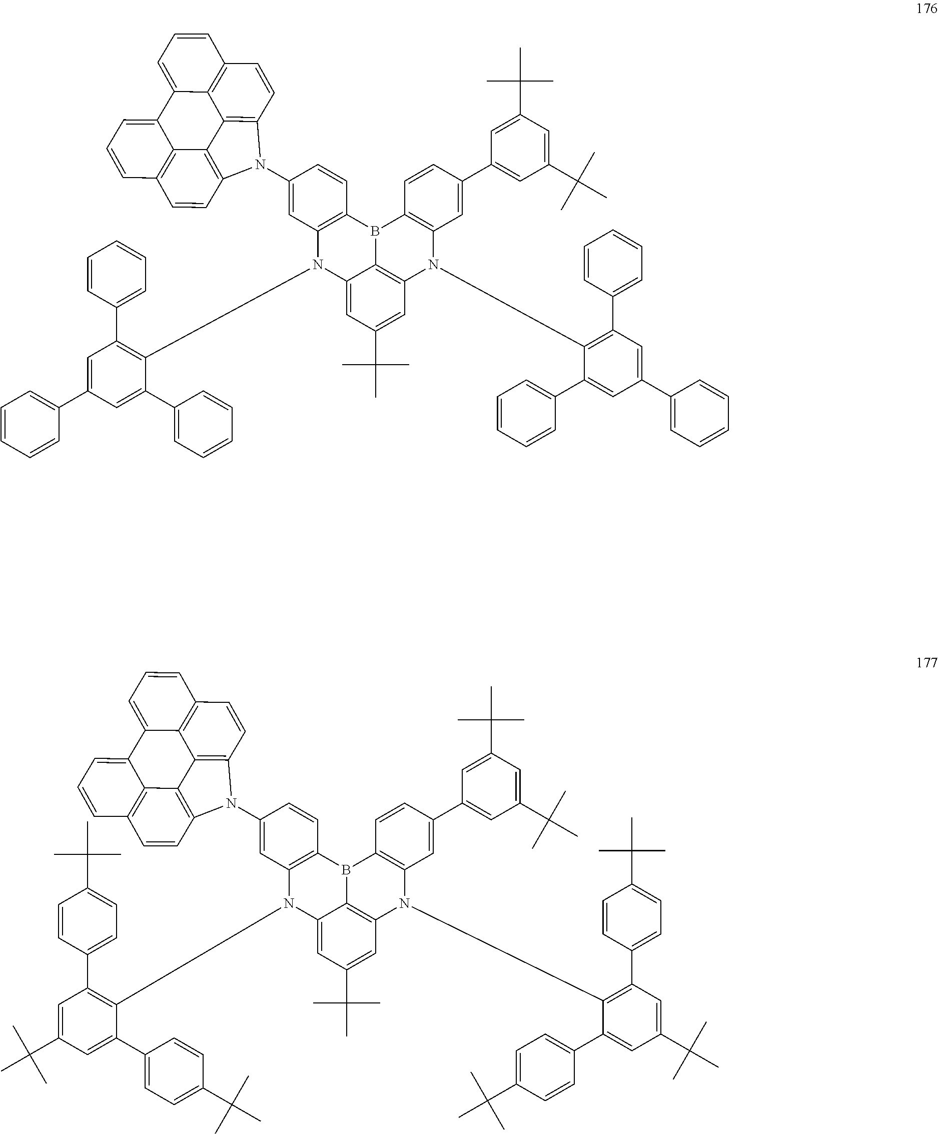 [SMILES: CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-n3c5ccc6cccc7c8cccc9ccc3c(c98)c5c67)cc2N4c2c(-c3ccccc3)cc(-c3ccccc3)cc2-c2ccccc2)cc(C(C)(C)C)c1 ; CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

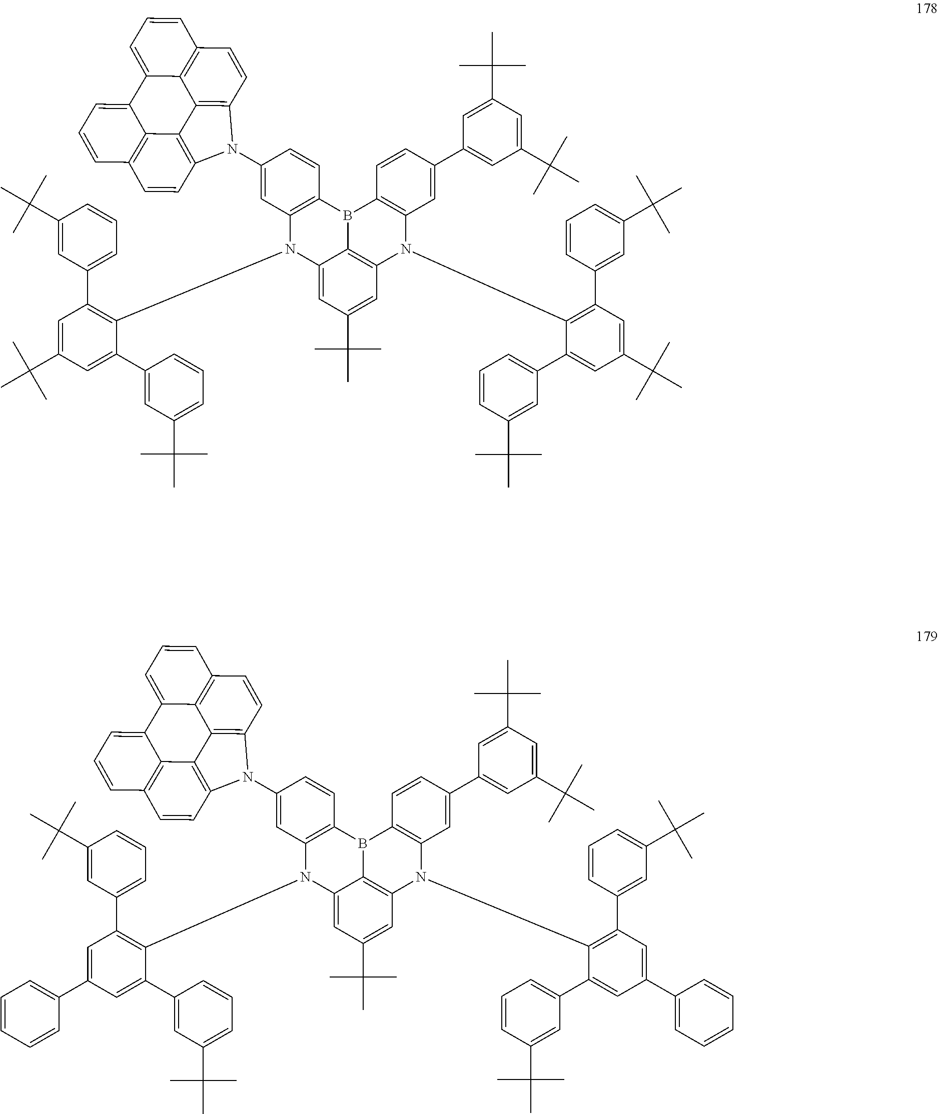 [SMILES: CC(C)(C)c1cccc(-c2cc(C(C)(C)C)cc(-c3cccc(C(C)(C)C)c3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5cccc(C(C)(C)C)c5)cc(C(C)(C)C)cc4-c4cccc(C(C)(C)C)c4)c4cc(C(C)(C)C)cc2c43)c1 ; CC(C)(C)c1cccc(-c2cc(-c3ccccc3)cc(-c3cccc(C(C)(C)C)c3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5cccc(C(C)(C)C)c5)cc(-c5ccccc5)cc4-c4cccc(C(C)(C)C)c4)c4cc(C(C)(C)C)cc2c43)c1]

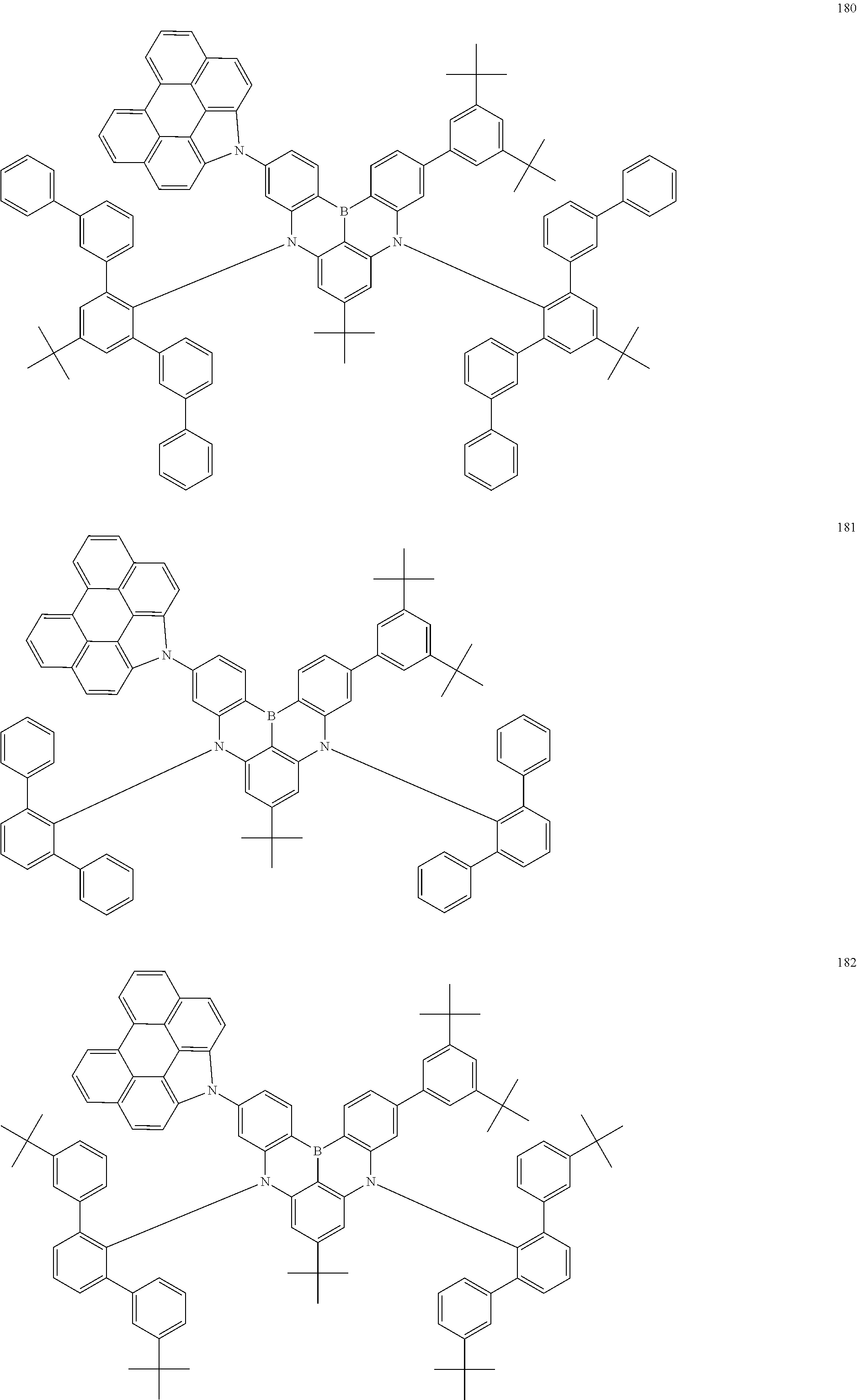

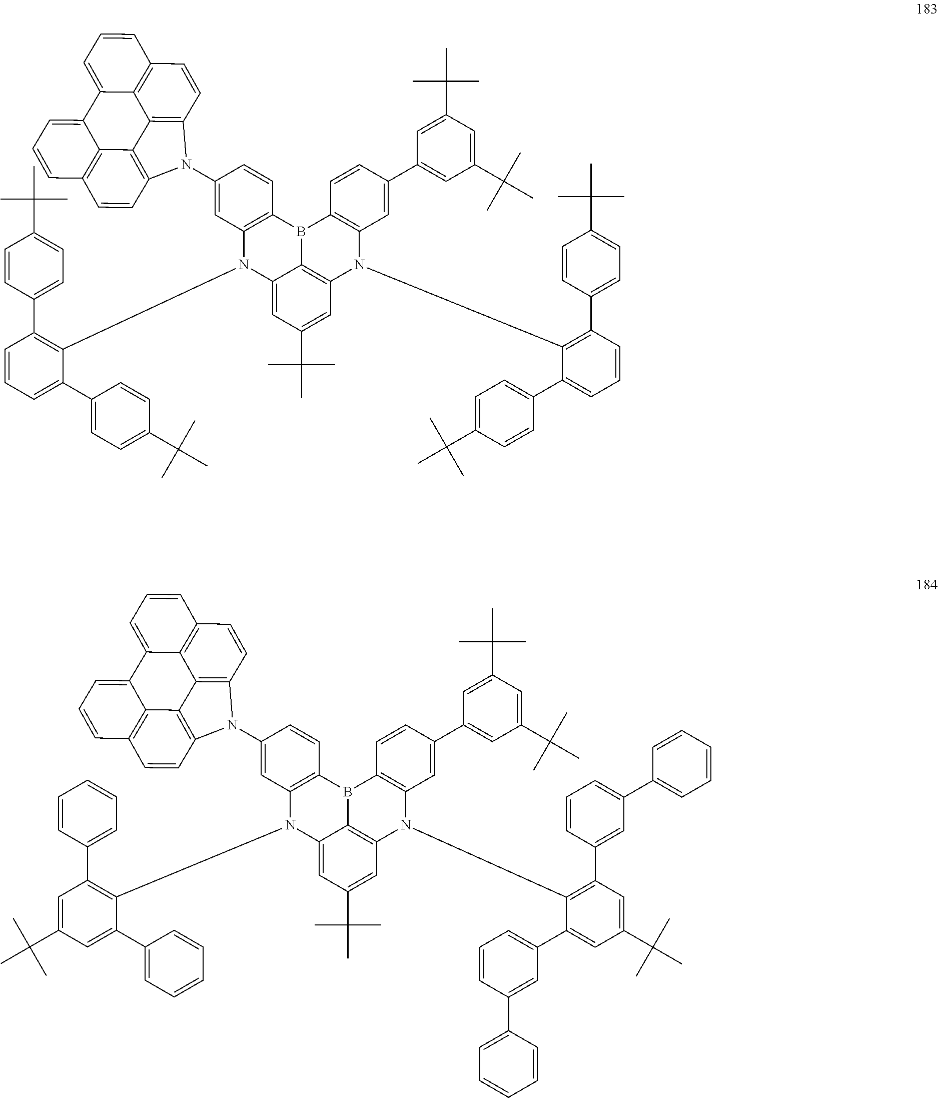

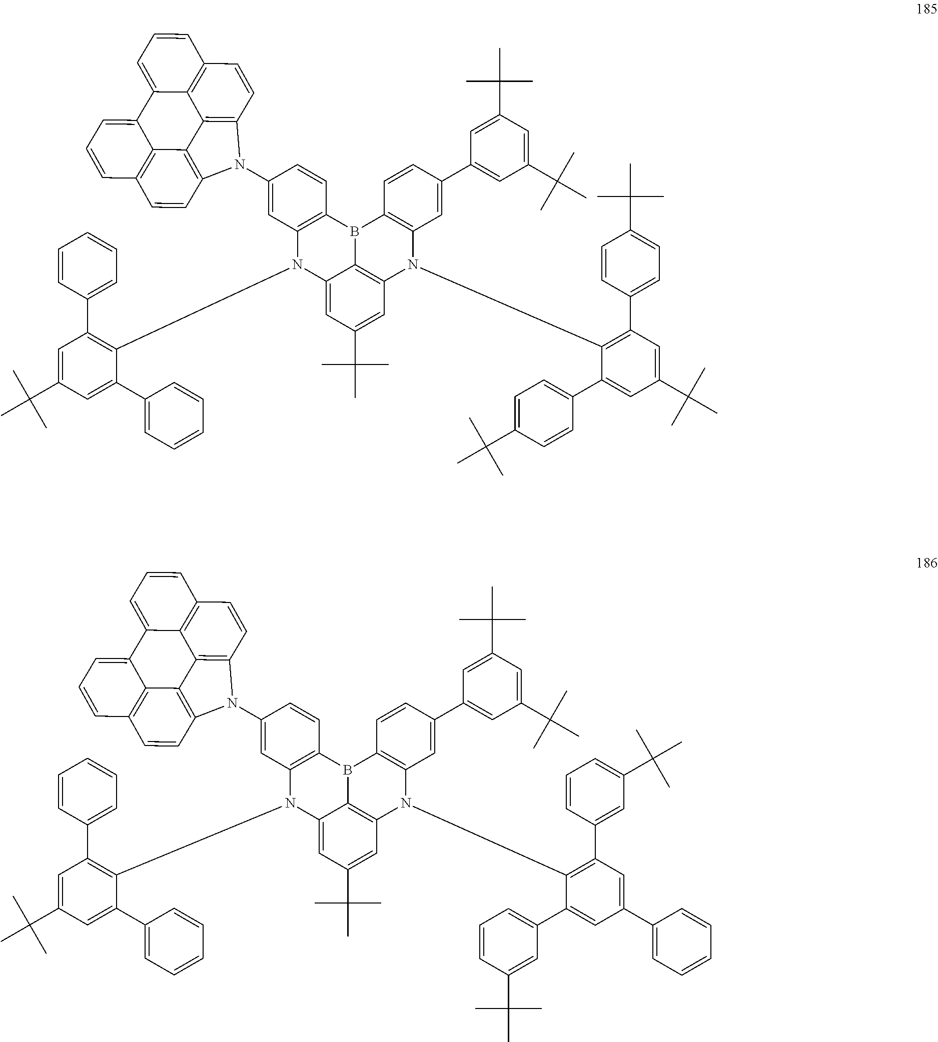

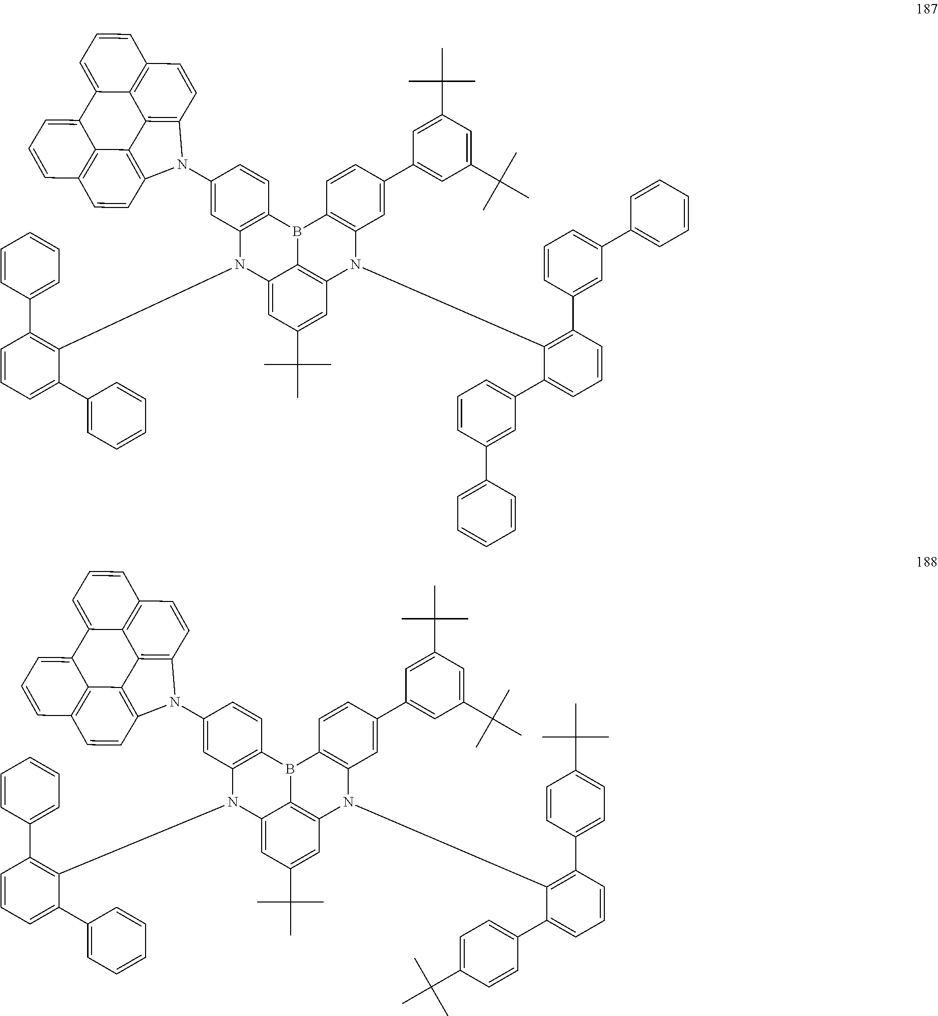 [SMILES: CC(C)(C)c1cc(-c2ccc3c(c2)N(c2c(-c4cccc(-c5ccccc5)c4)cccc2-c2cccc(-c4ccccc4)c2)c2cc(C(C)(C)C)cc4c2B3c2ccc(-n3c5ccc6cccc7c8cccc9ccc3c(c98)c5c67)cc2N4c2c(-c3ccccc3)cccc2-c2ccccc2)cc(C(C)(C)C)c1 ; CC(C)(C)c1ccc(-c2cccc(-c3ccc(C(C)(C)C)cc3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)cc1]

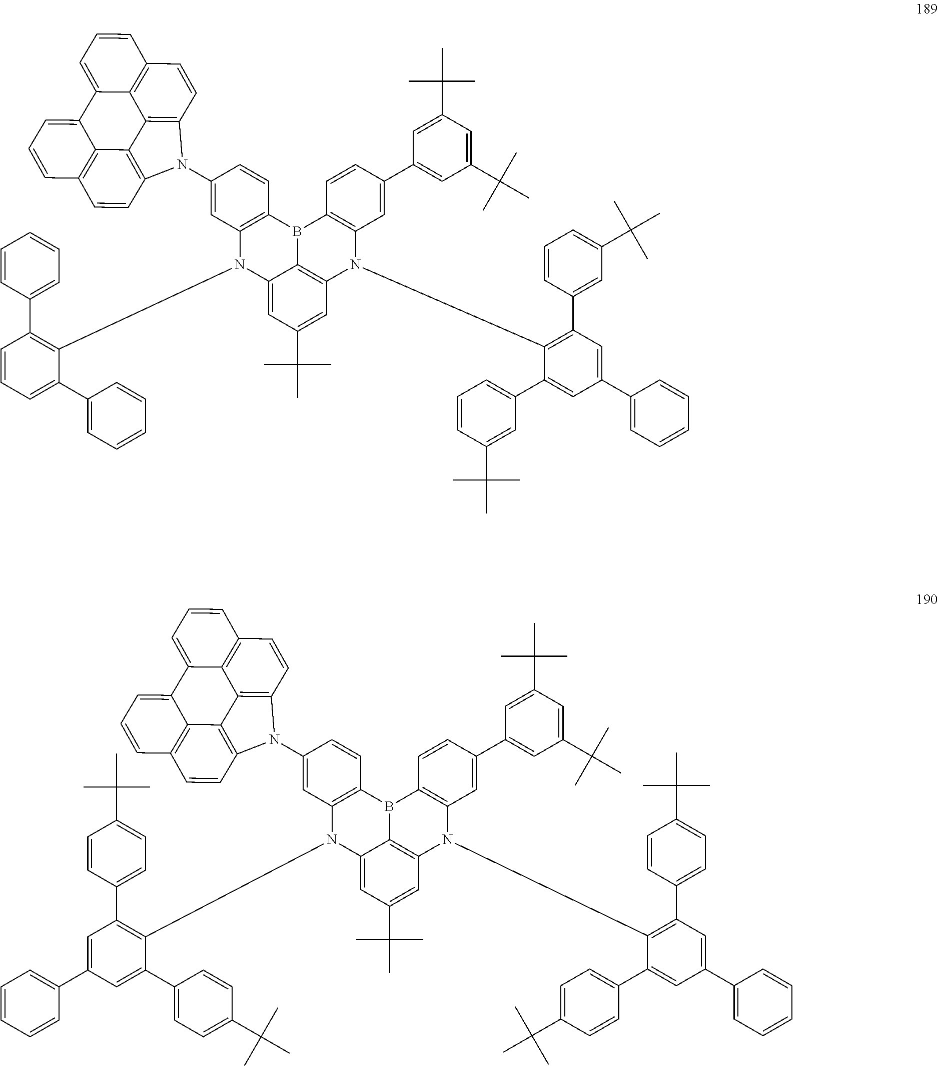 [SMILES: CC(C)(C)c1cccc(-c2cc(-c3ccccc3)cc(-c3cccc(C(C)(C)C)c3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5ccccc5)cccc4-c4ccccc4)c4cc(C(C)(C)C)cc2c43)c1 ; CC(C)(C)c1ccc(-c2cc(-c3ccccc3)cc(-c3ccc(C(C)(C)C)cc3)c2N2c3cc(-c4cc(C(C)(C)C)cc(C(C)(C)C)c4)ccc3B3c4ccc(-n5c6ccc7cccc8c9cccc%10ccc5c(c%109)c6c78)cc4N(c4c(-c5ccc(C(C)(C)C)cc5)cc(-c5ccccc5)cc4-c4ccc(C(C)(C)C)cc4)c4cc(C(C)(C)C)cc2c43)cc1]

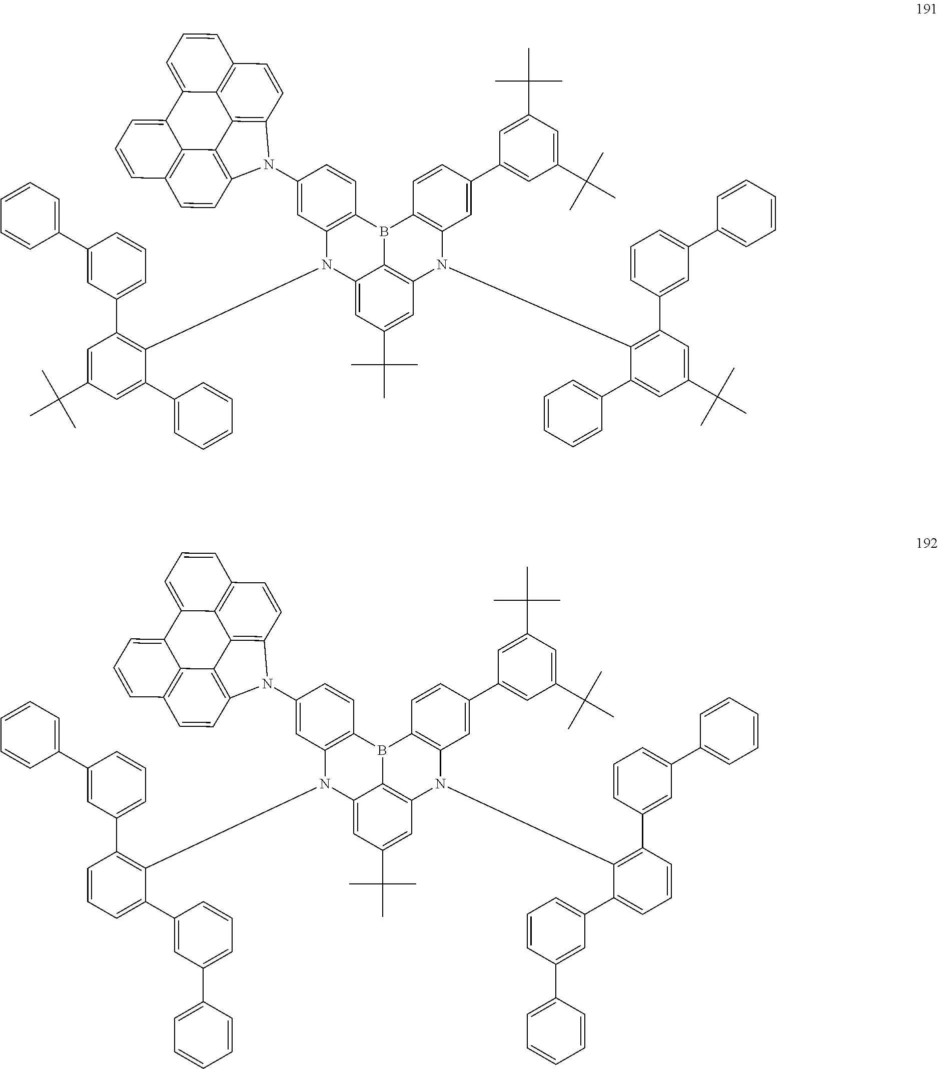 [SMILES: CC(C)(C)c1cc(-c2ccc3c(c2)N(c2c(-c4ccccc4)cc(C(C)(C)C)cc2-c2cccc(-c4ccccc4)c2)c2cc(C(C)(C)C)cc4c2B3c2ccc(-n3c5ccc6cccc7c8cccc9ccc3c(c98)c5c67)cc2N4c2c(-c3ccccc3)cc(C(C)(C)C)cc2-c2cccc(-c3ccccc3)c2)cc(C(C)(C)C)c1 ; CC(C)(C)c1cc(-c2ccc3c(c2)N(c2c(-c4cccc(-c5ccccc5)c4)cccc2-c2cccc(-c4ccccc4)c2)c2cc(C(C)(C)C)cc4c2B3c2ccc(-n3c5ccc6cccc7c8cccc9ccc3c(c98)c5c67)cc2N4c2c(-c3cccc(-c4ccccc4)c3)cccc2-c2cccc(-c3ccccc3)c2)cc(C(C)(C)C)c1]

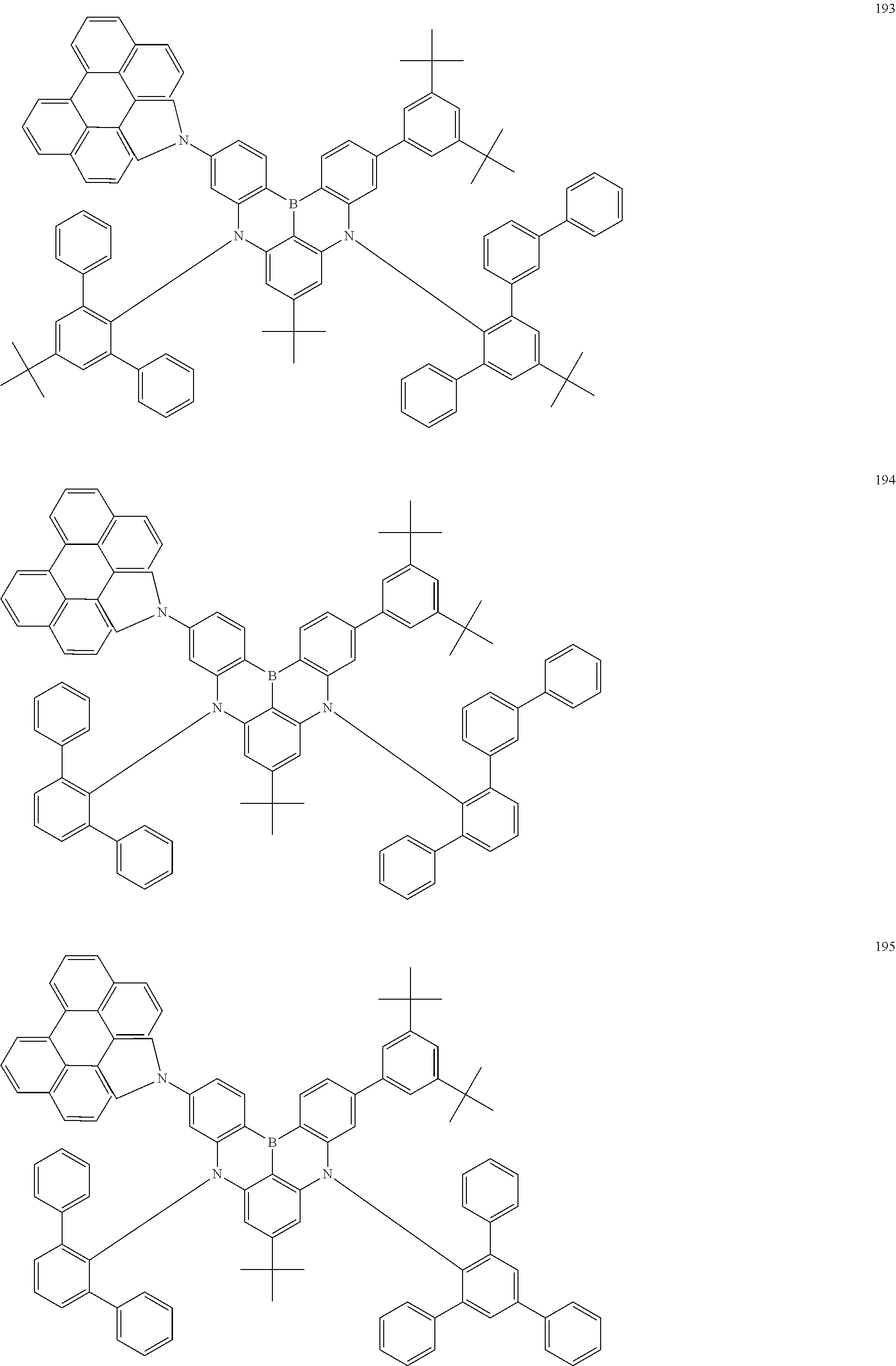

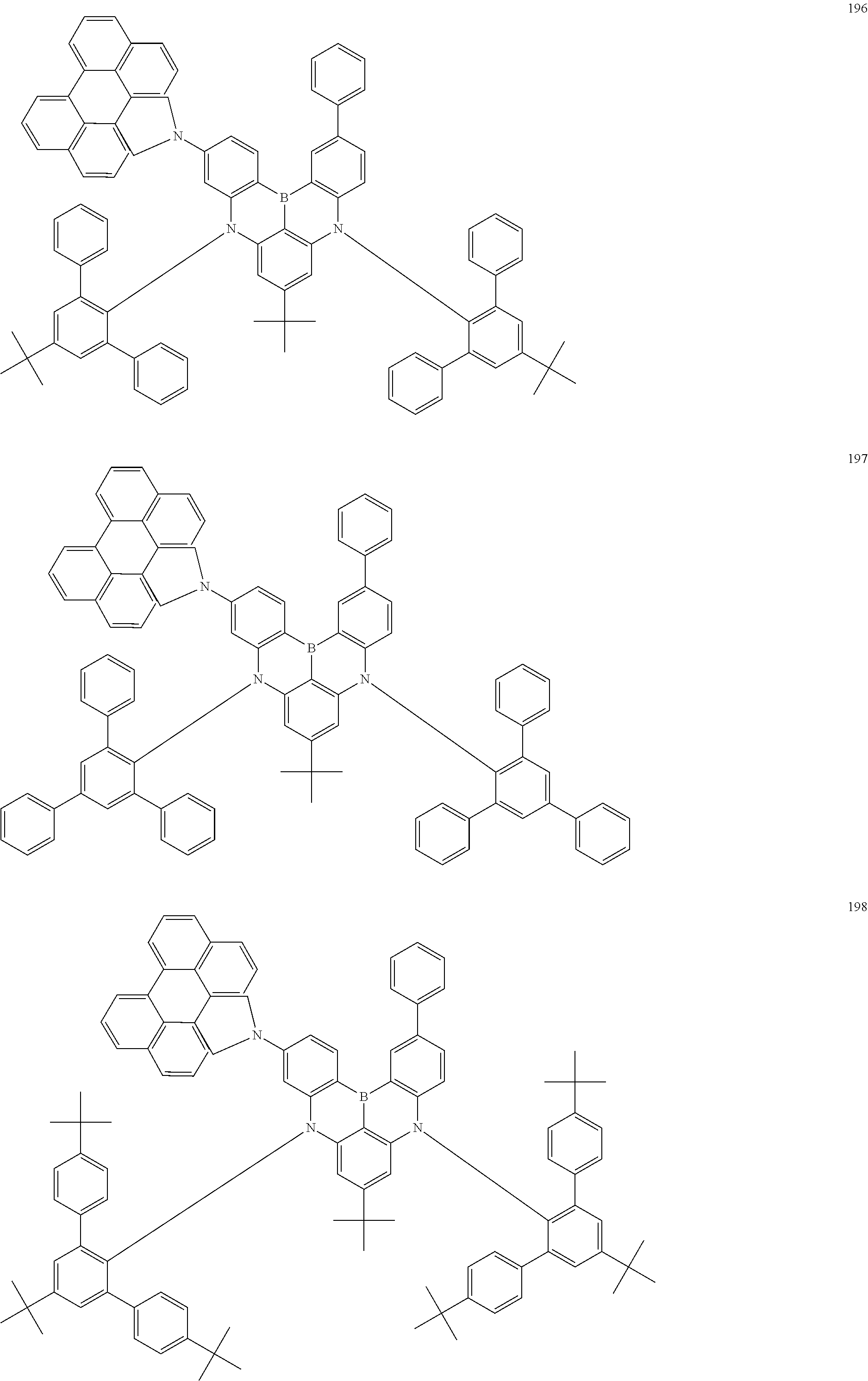

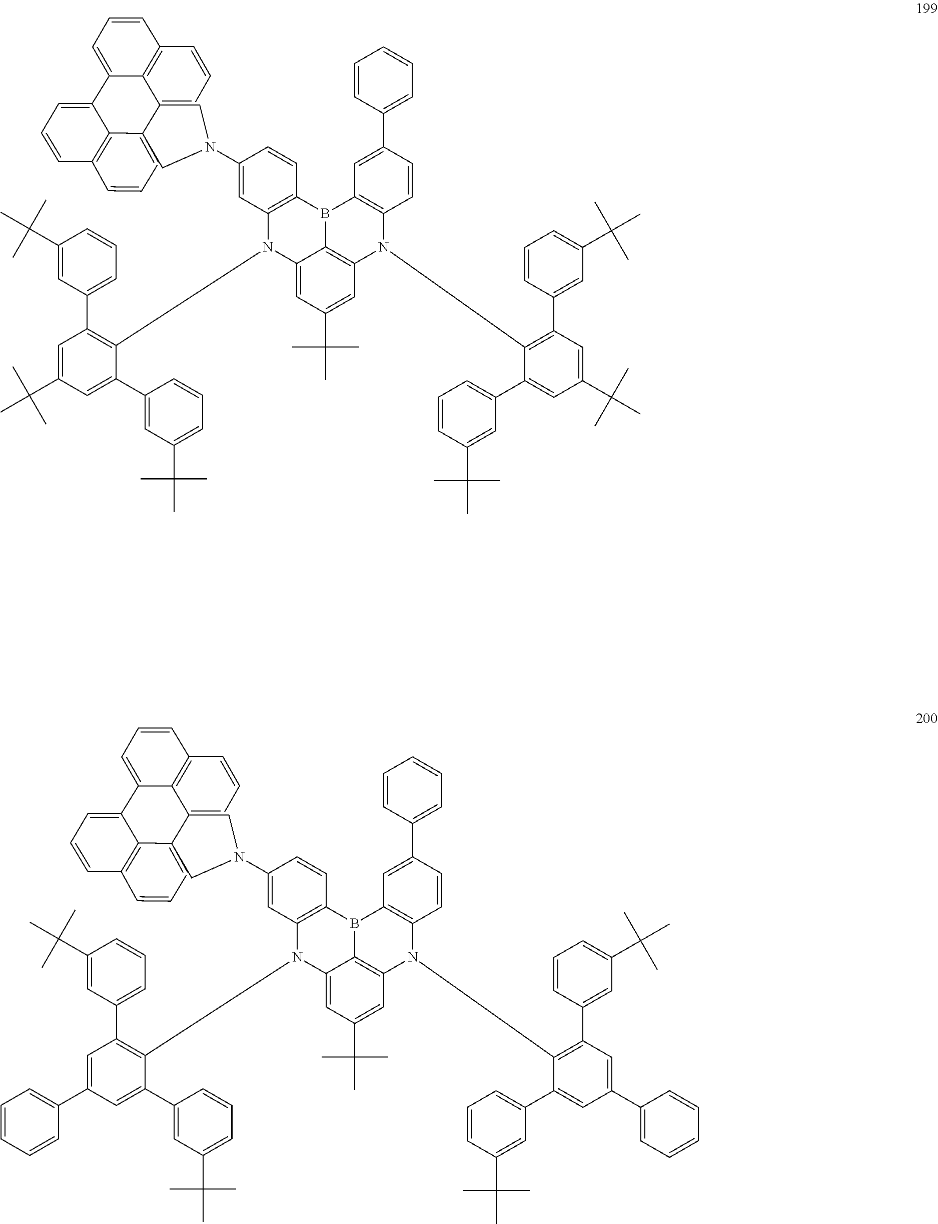

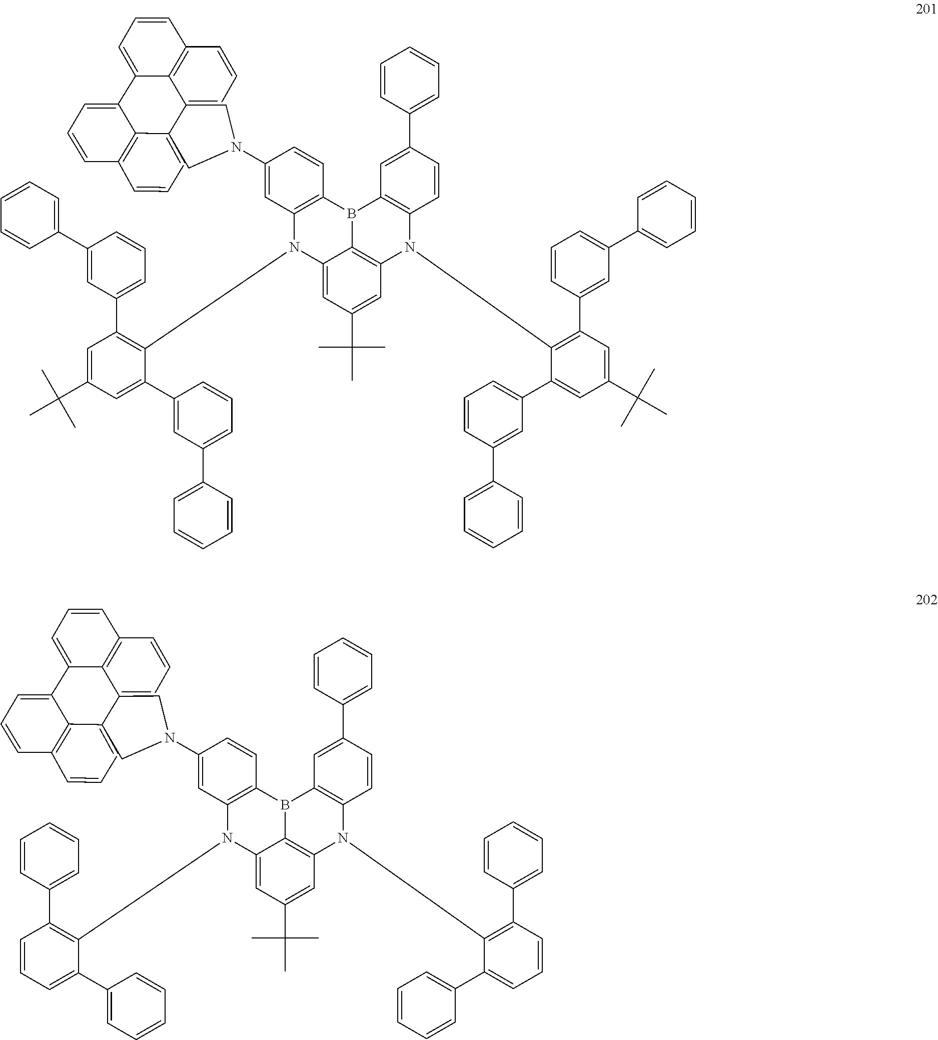

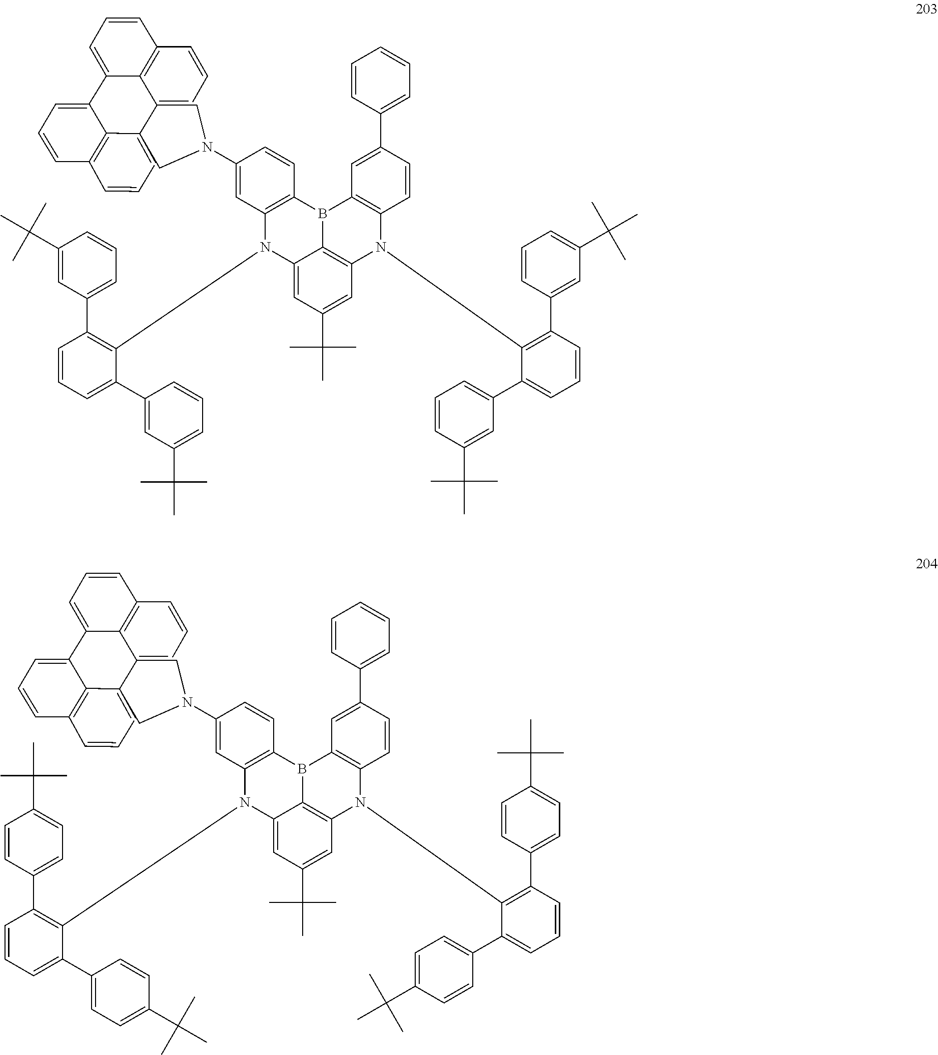

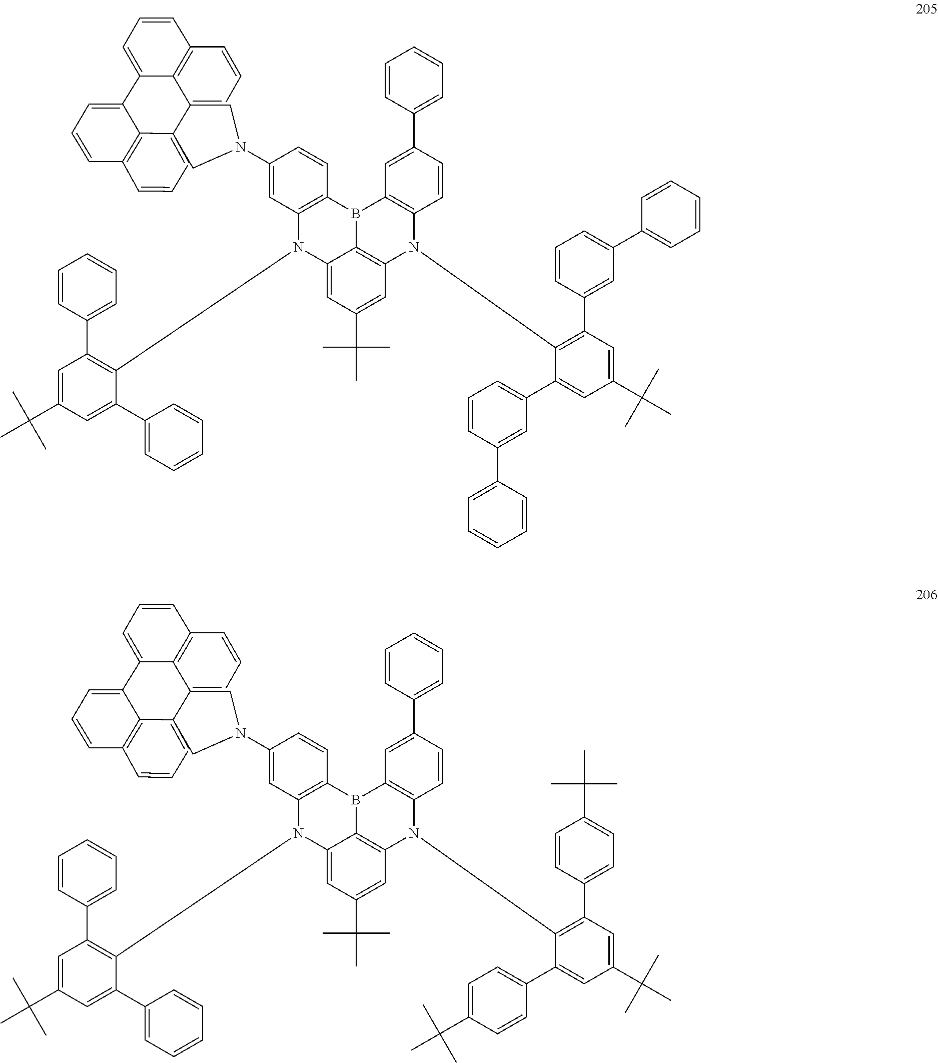

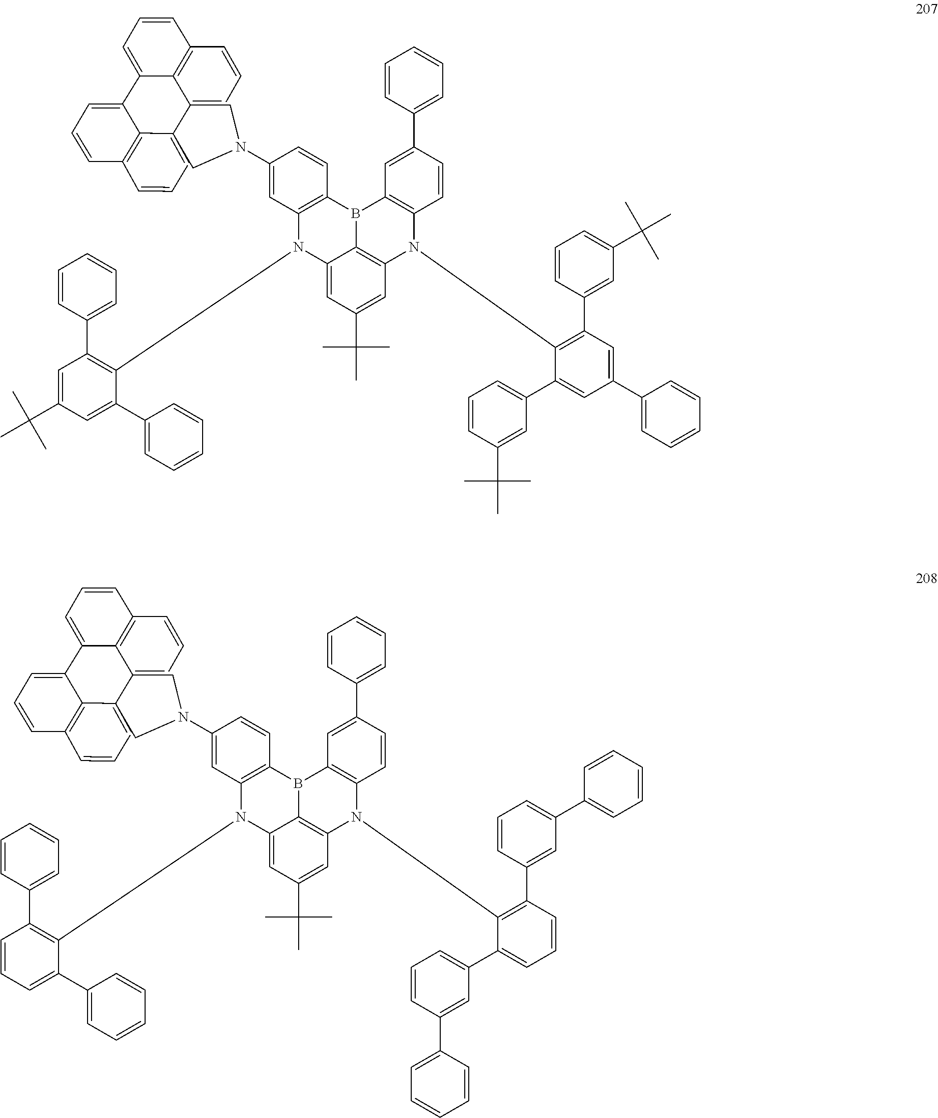

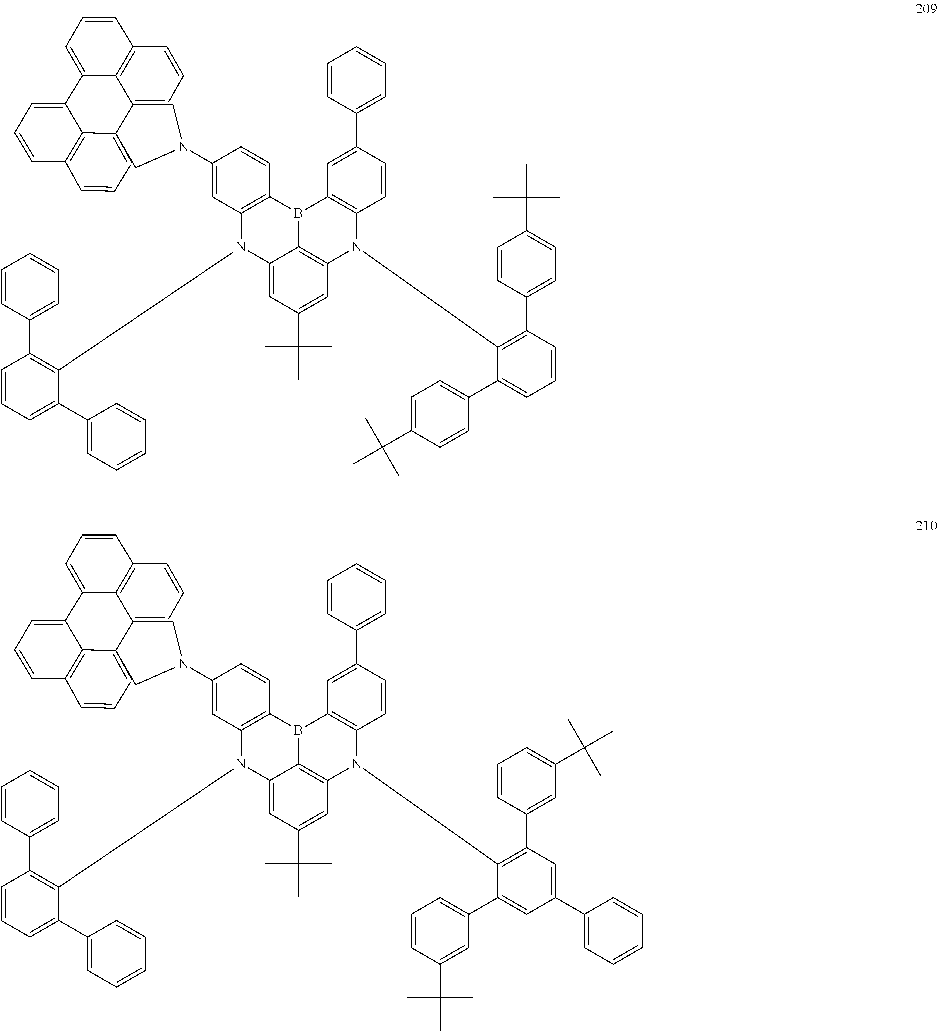

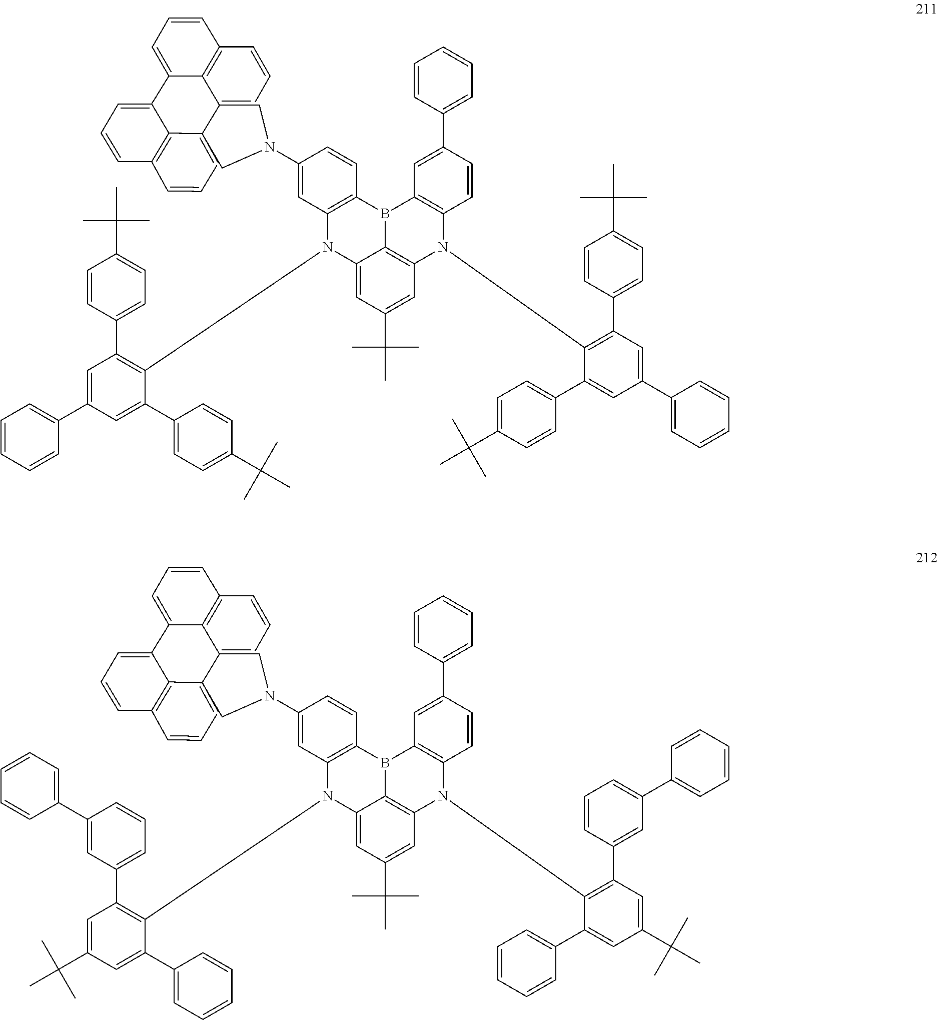

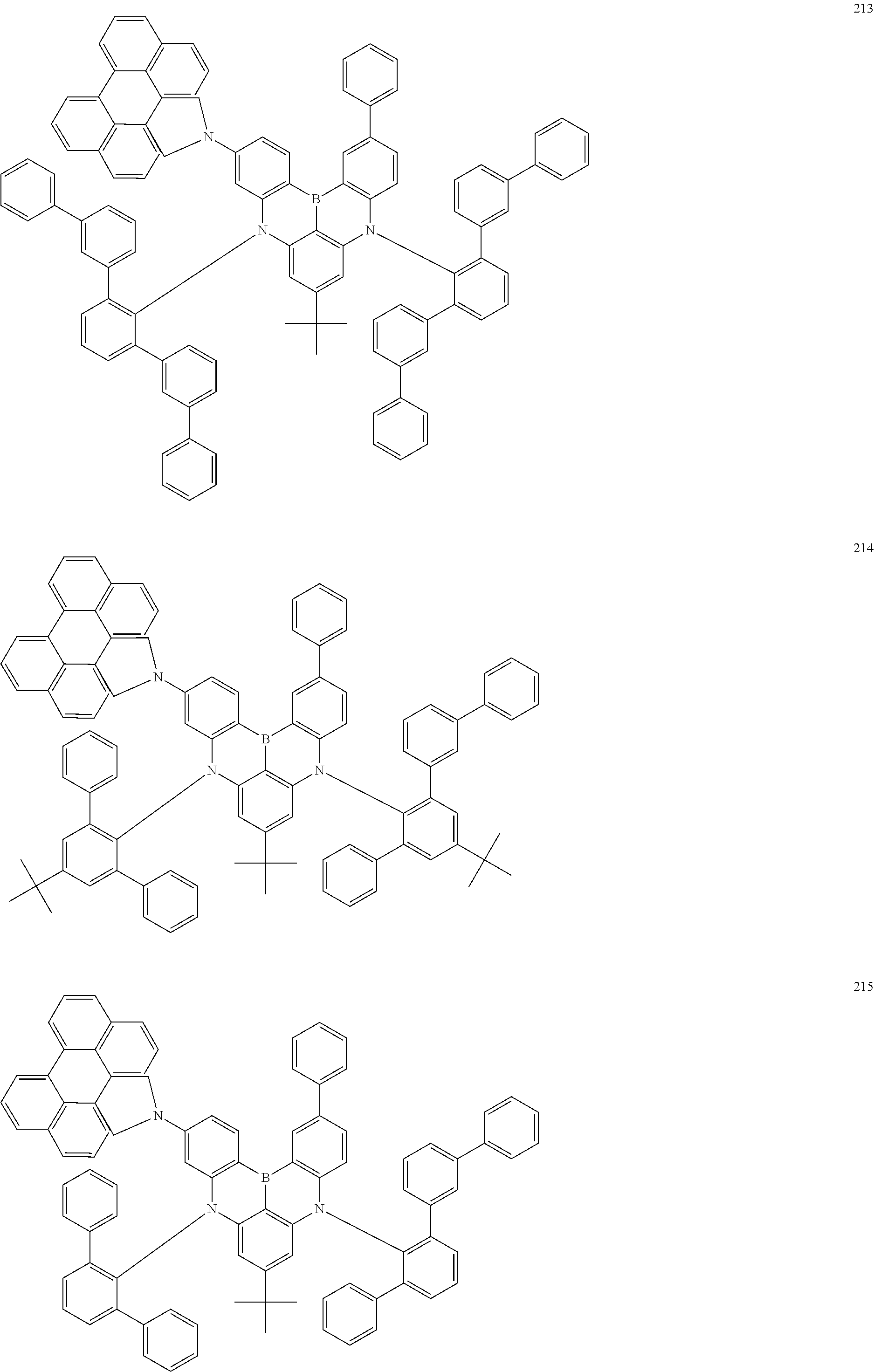

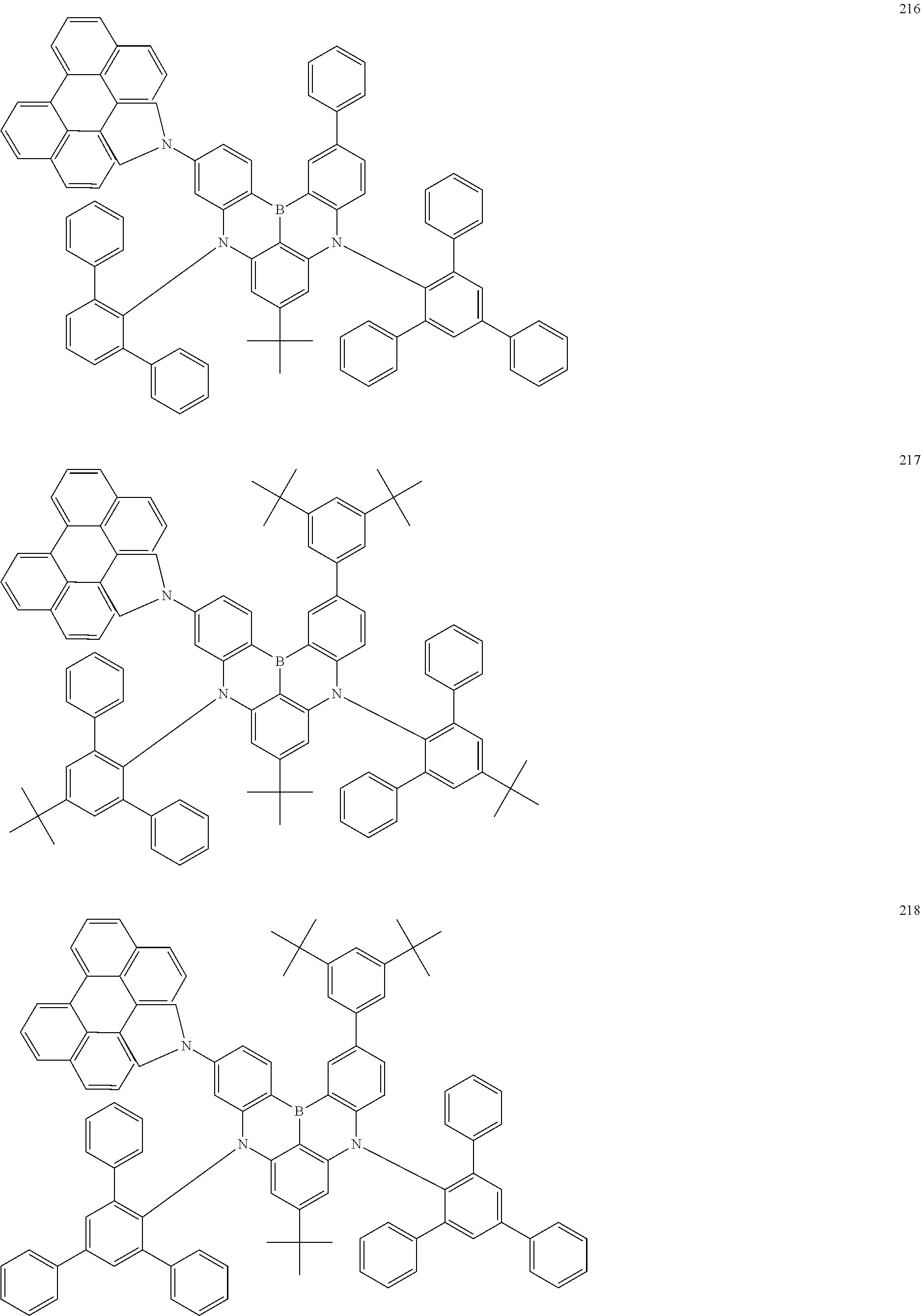

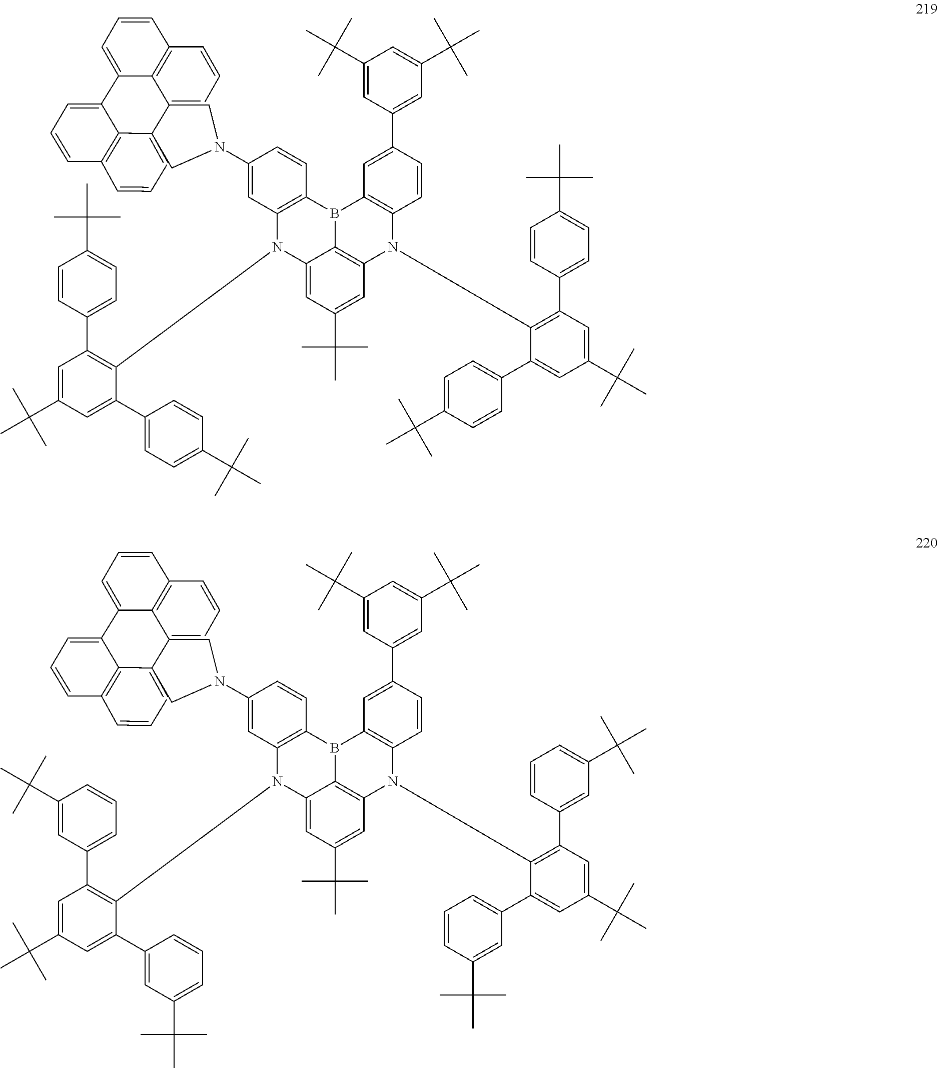

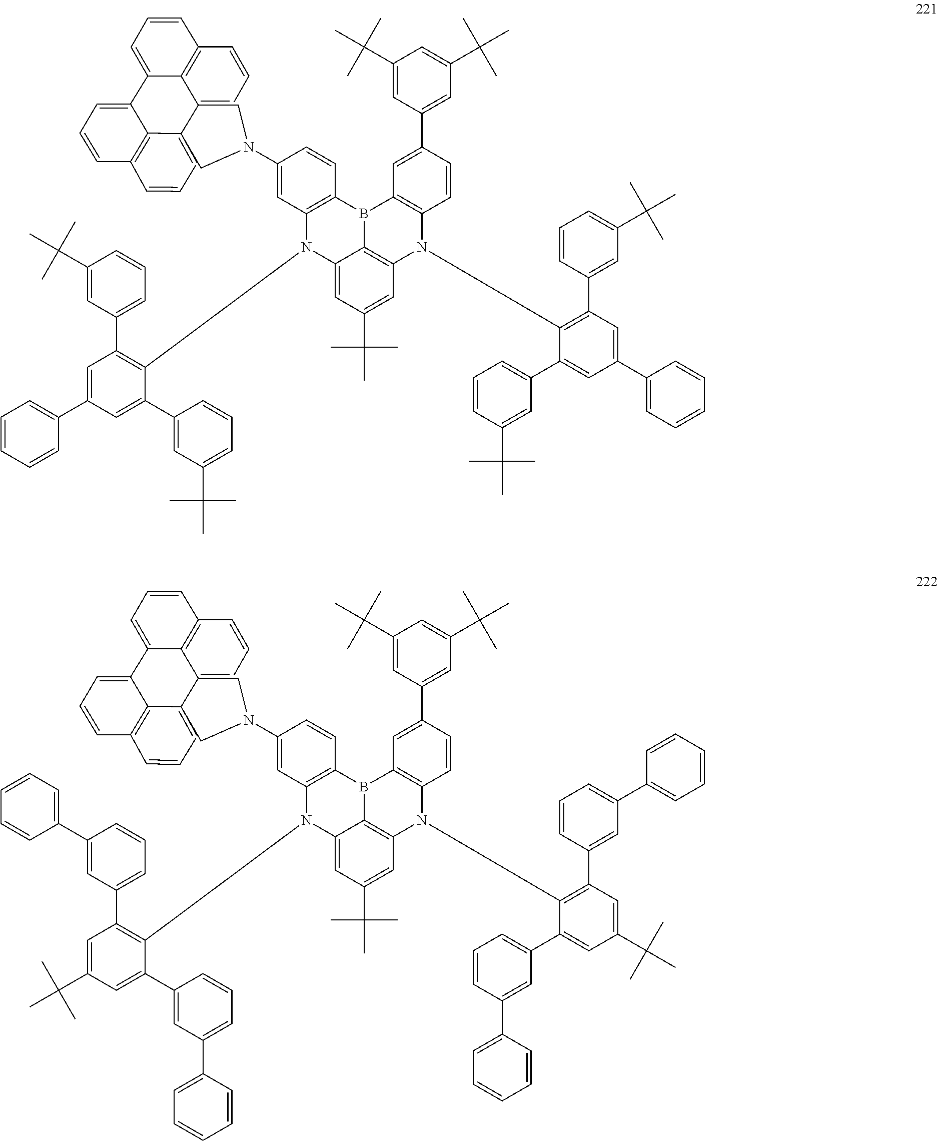

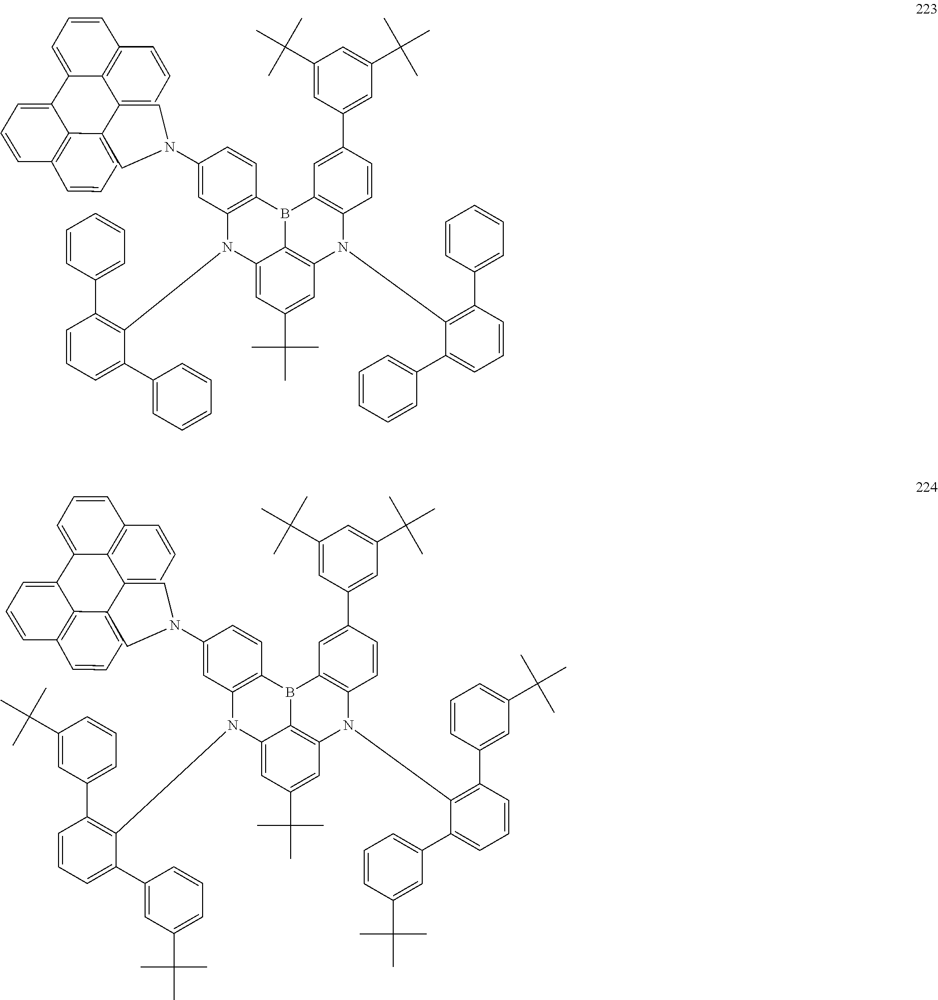

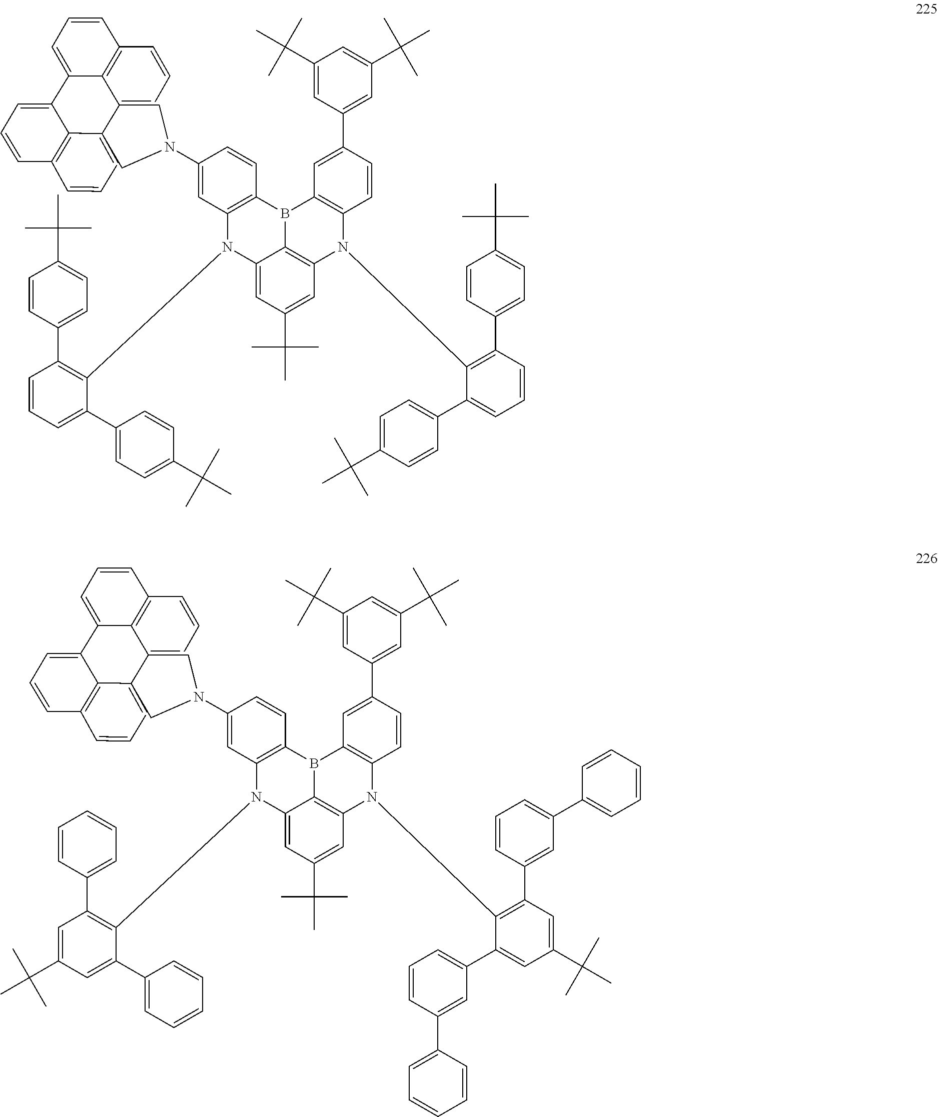

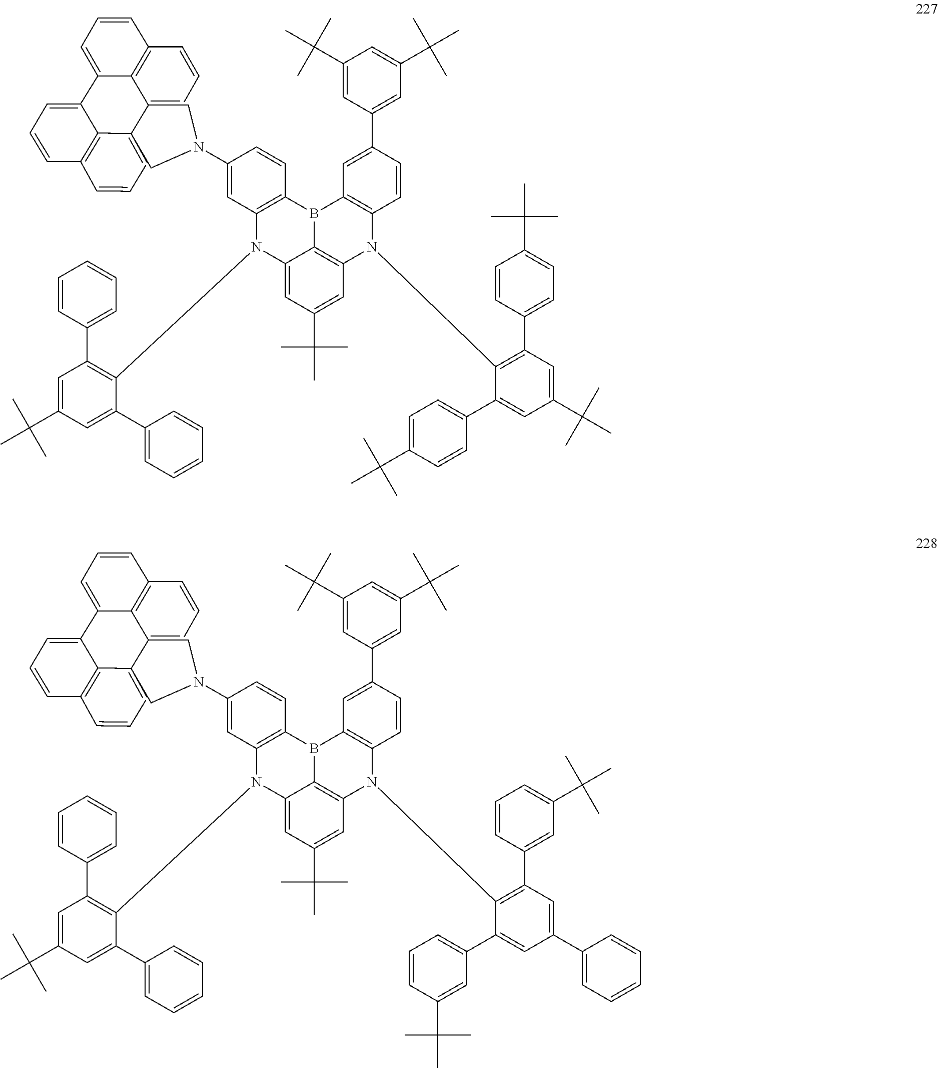

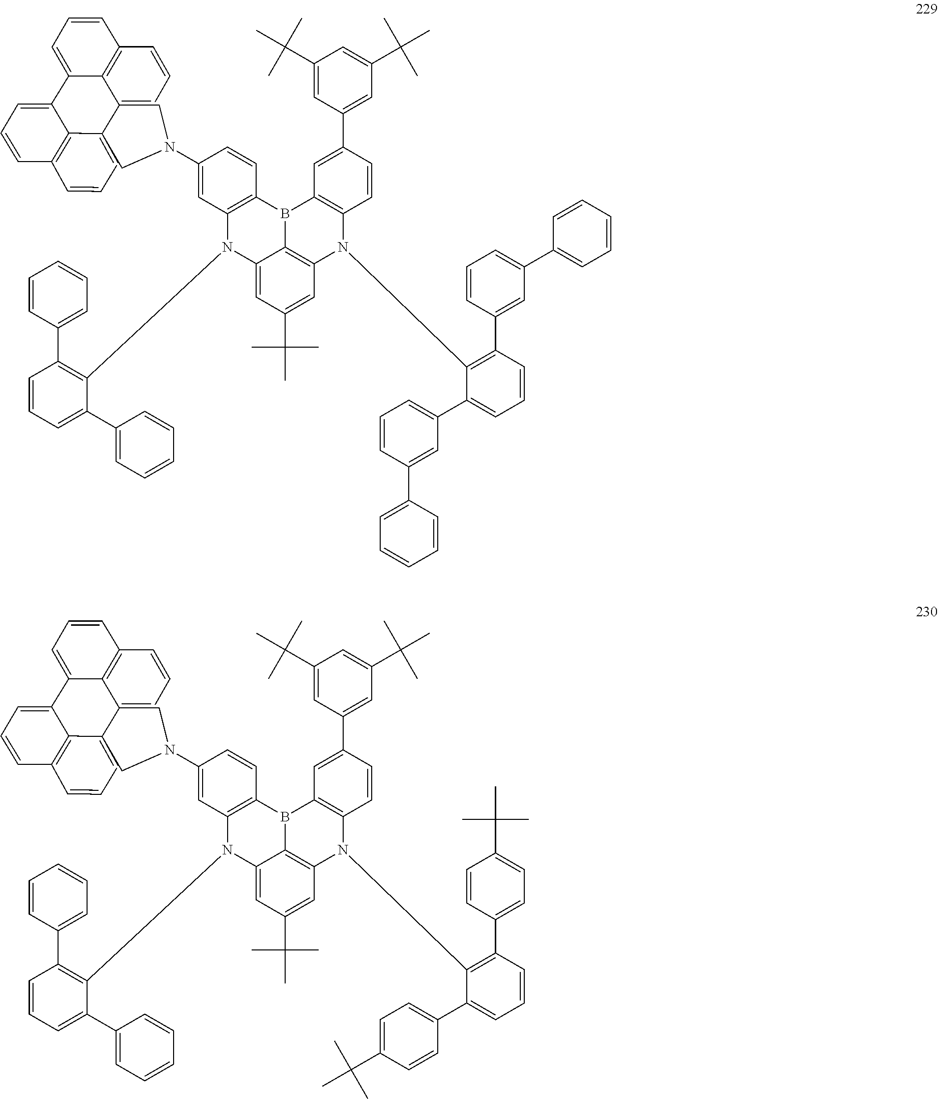

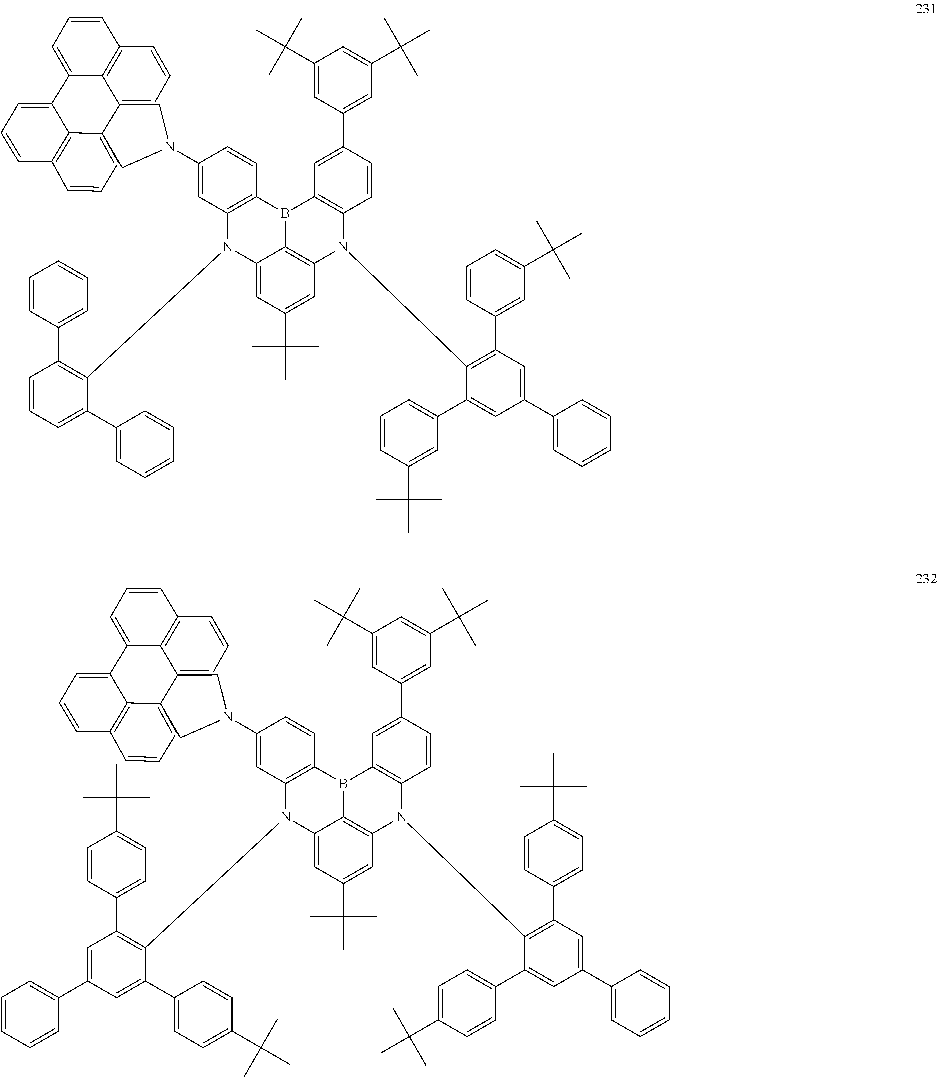

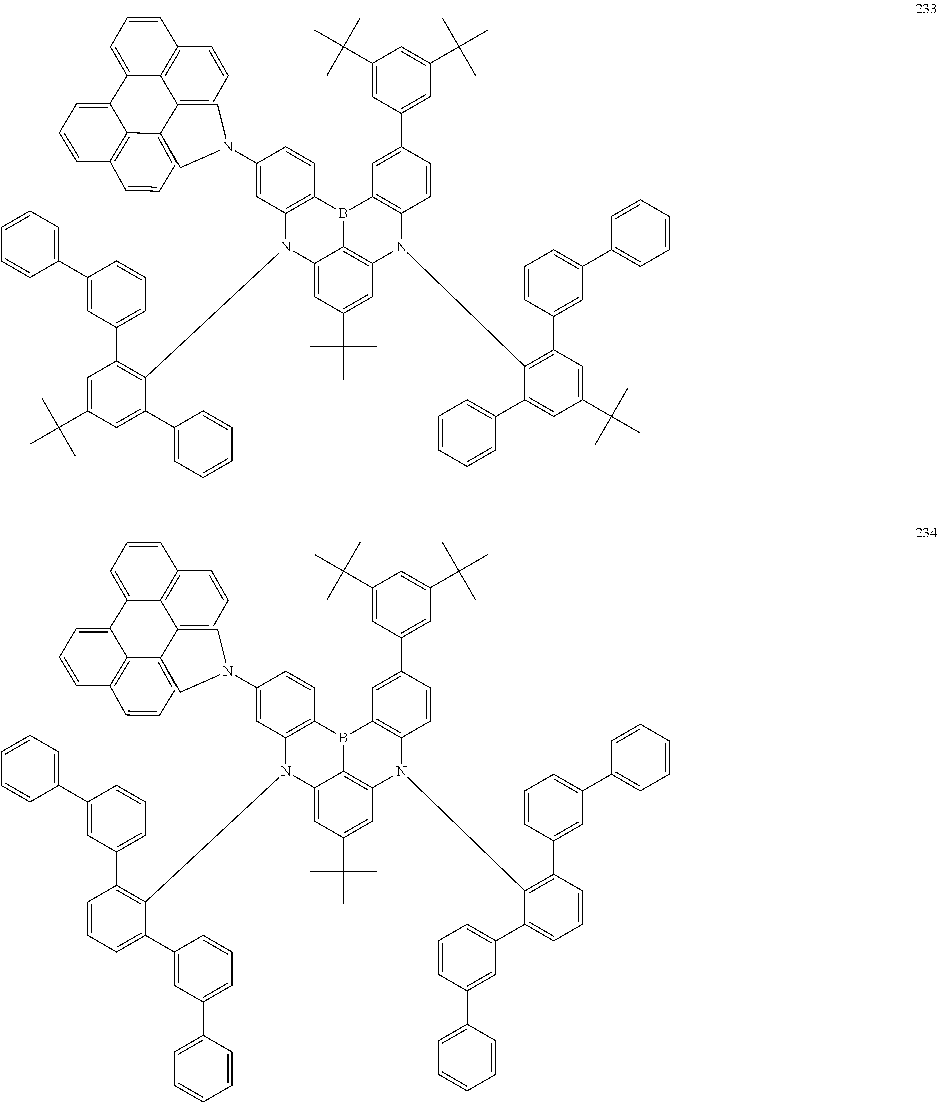

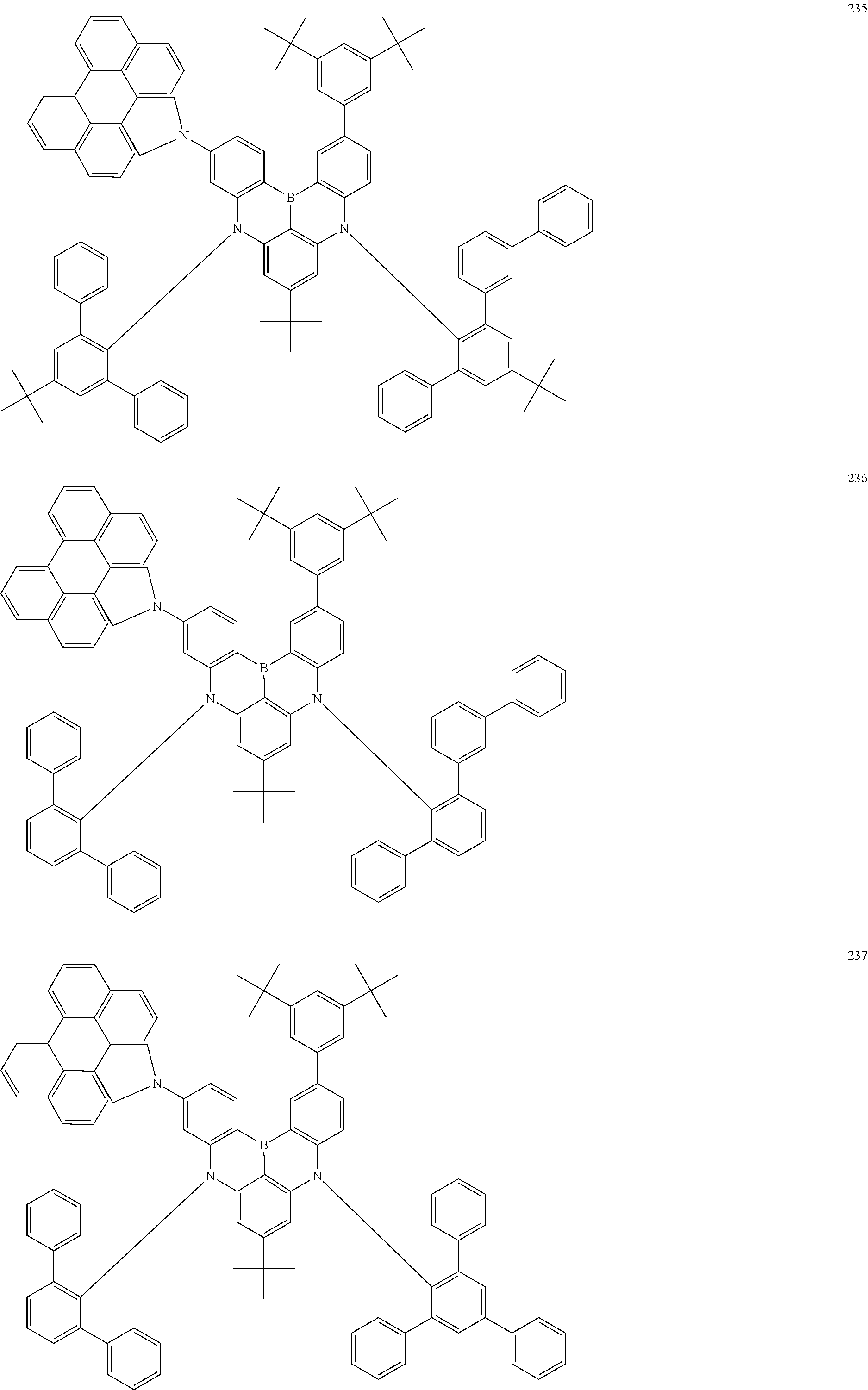

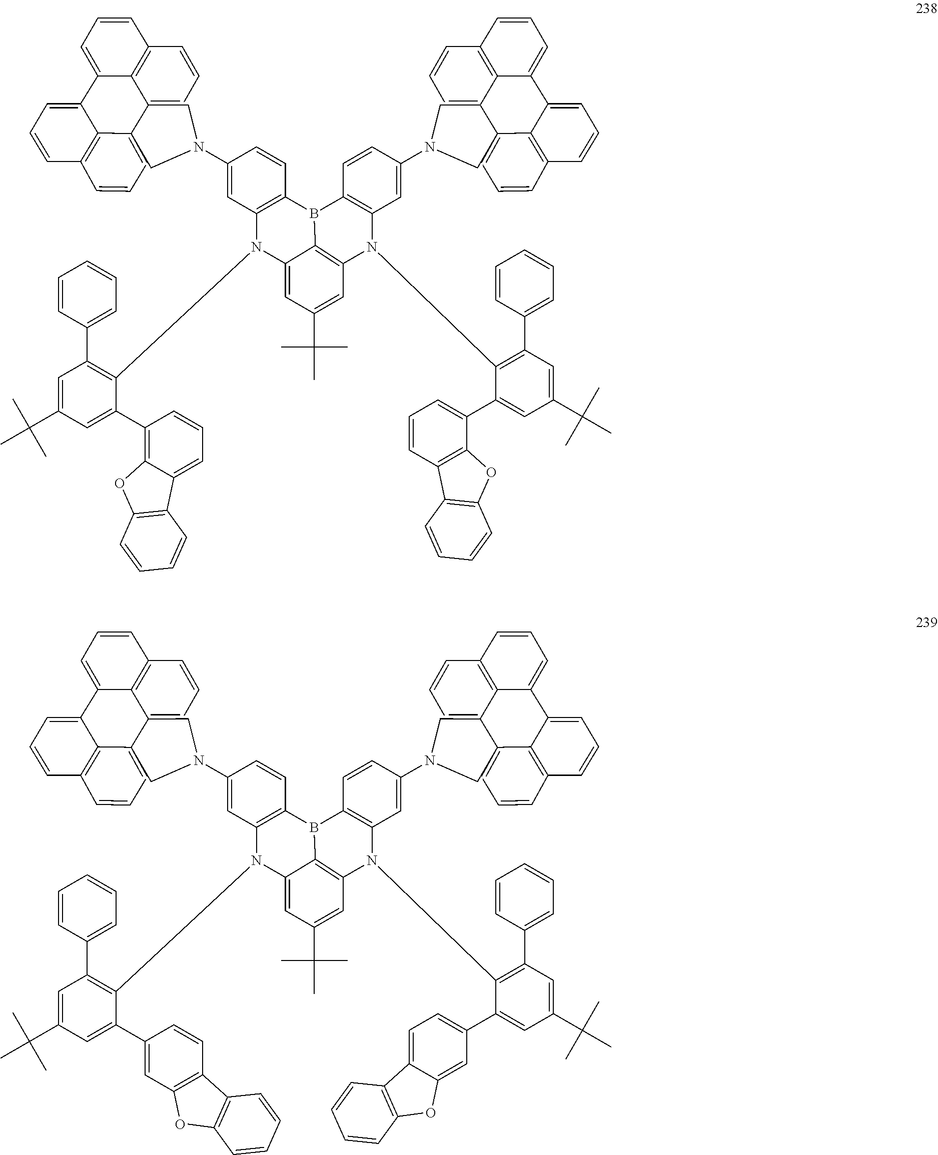

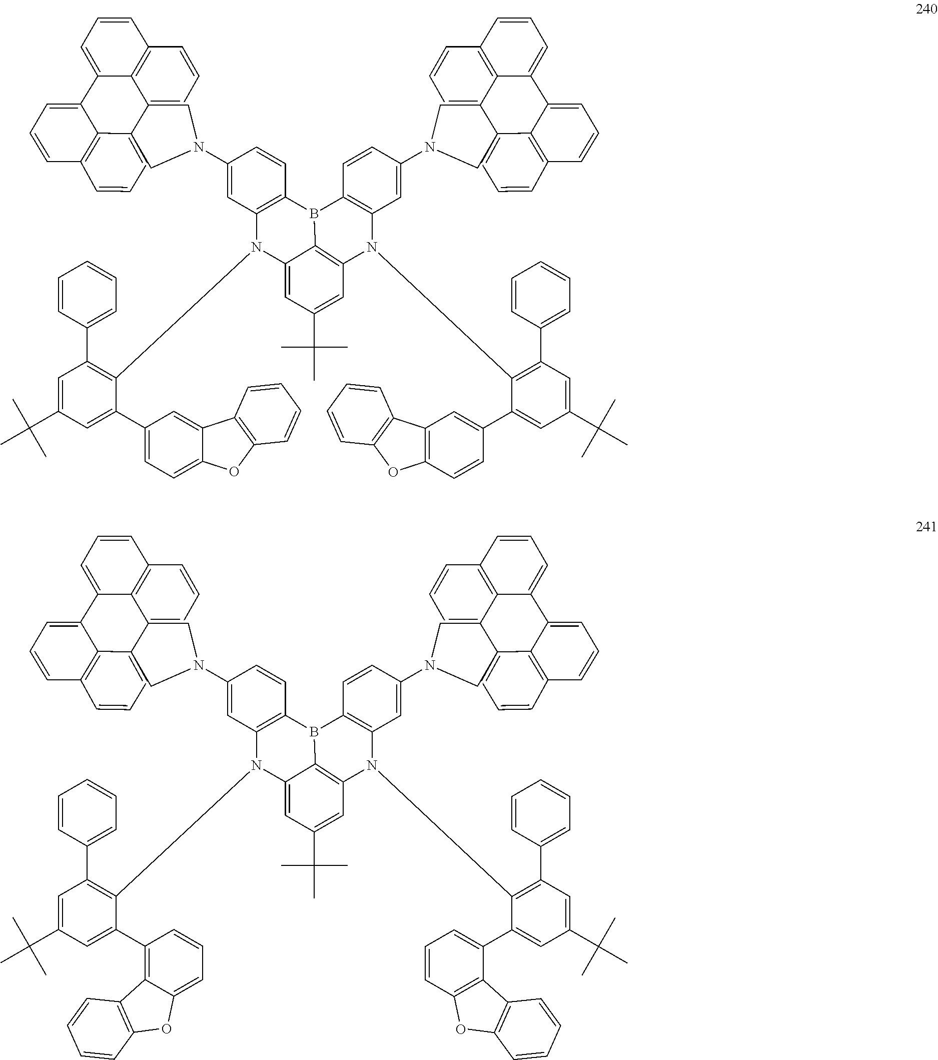

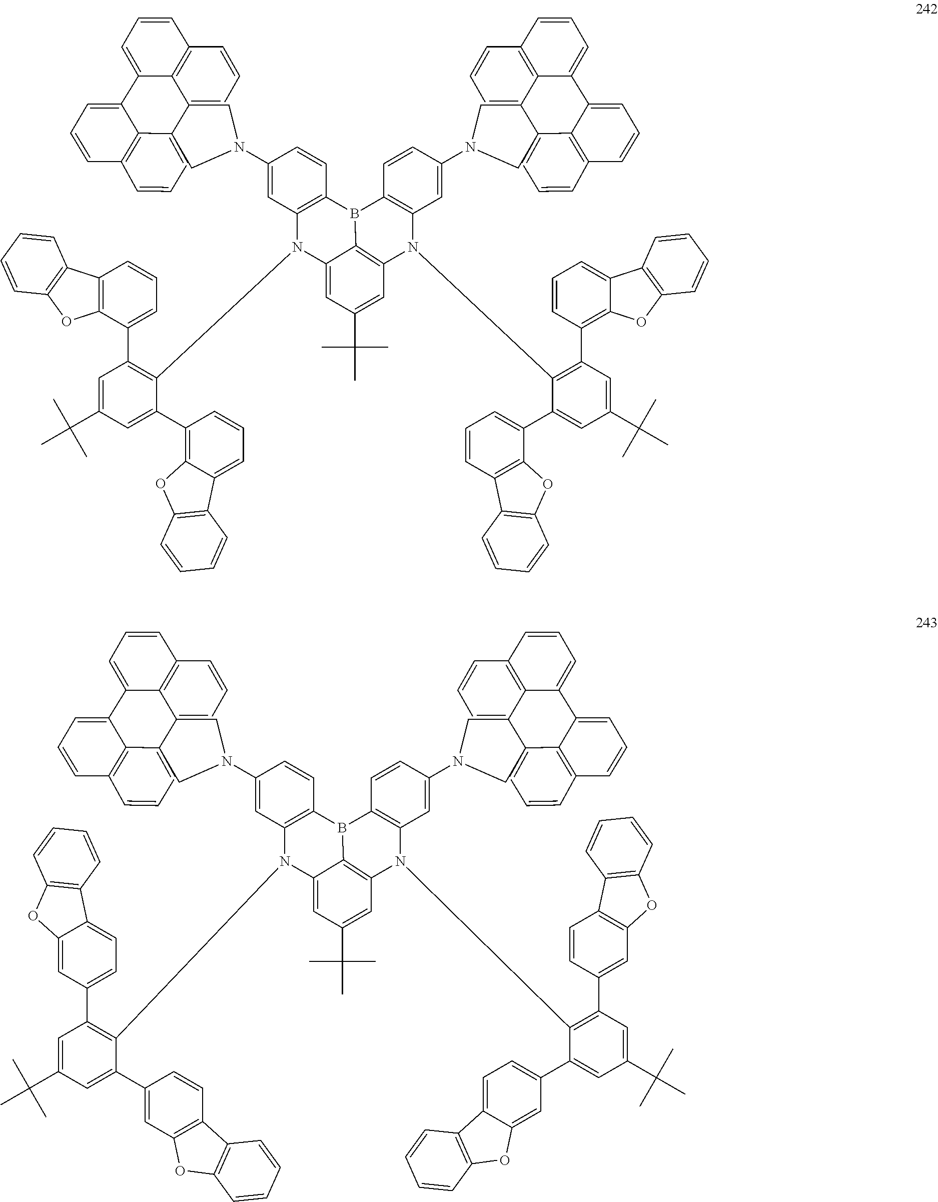

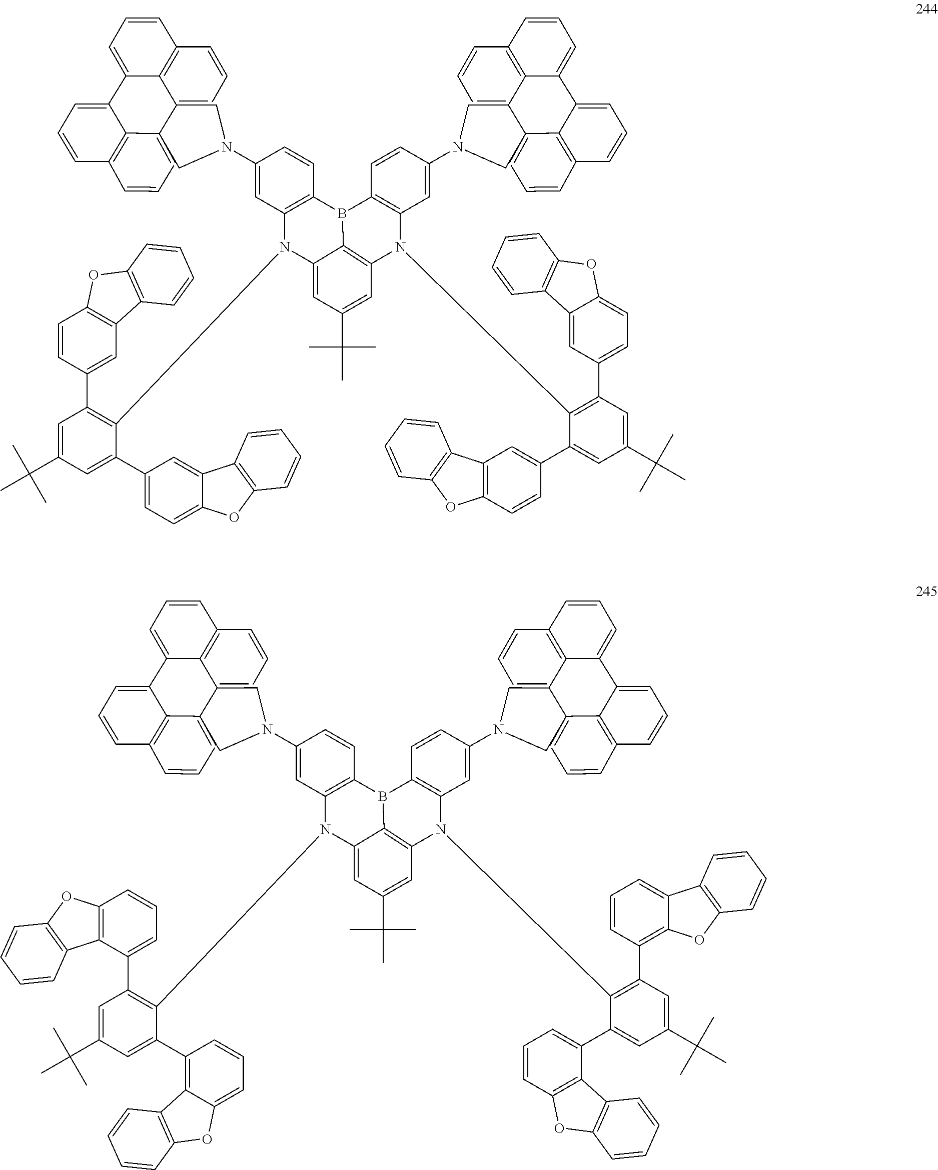

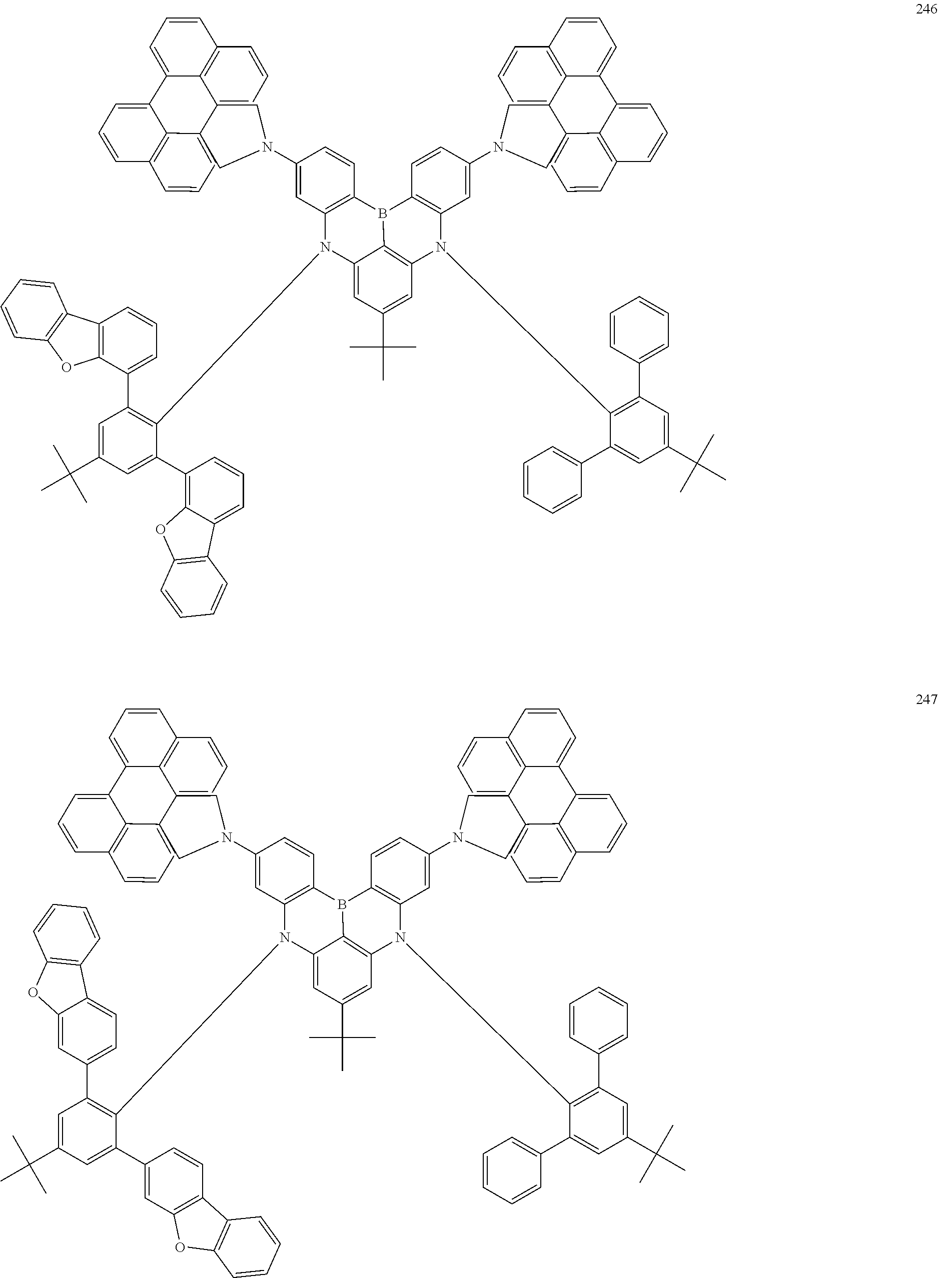

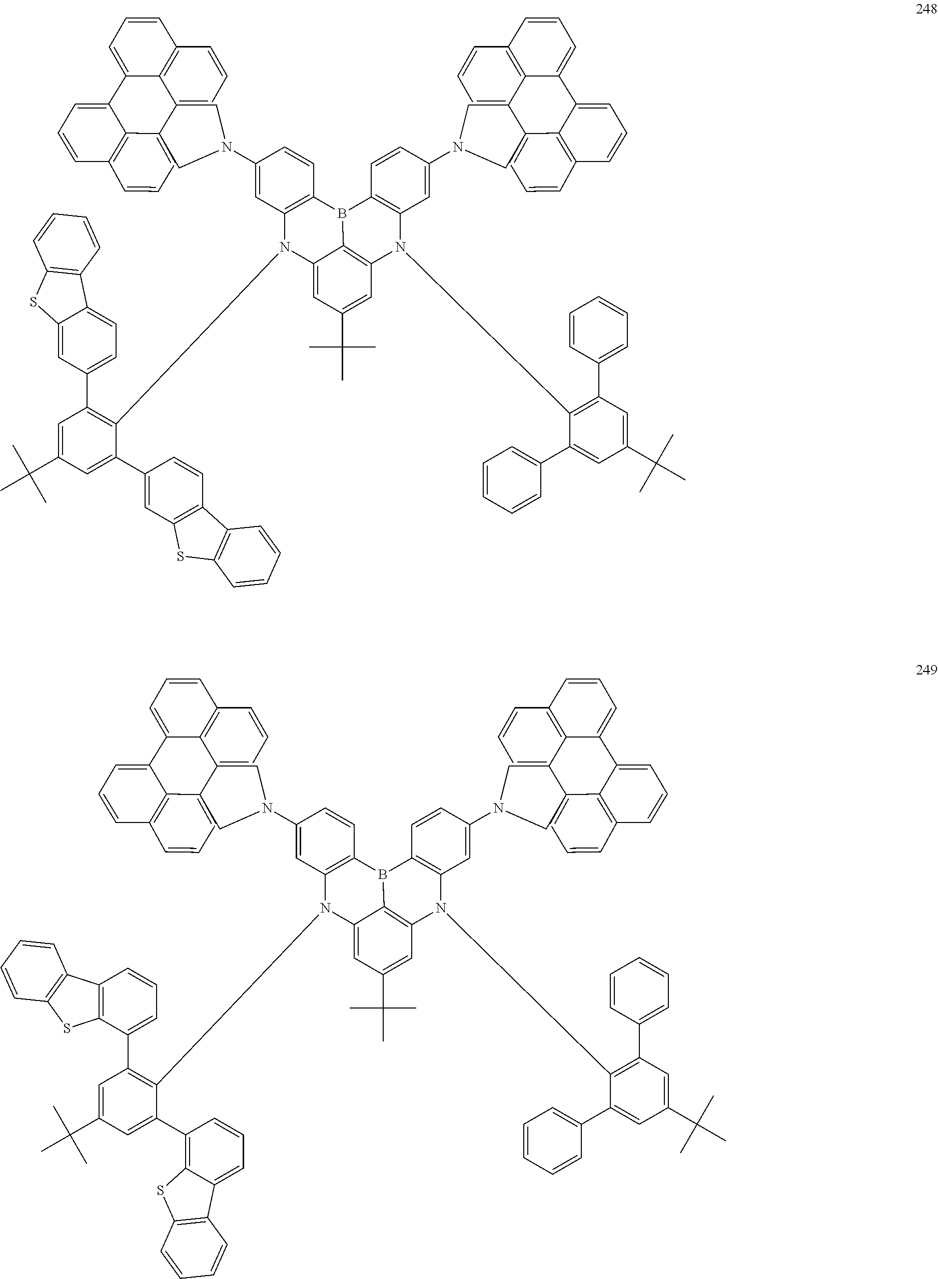

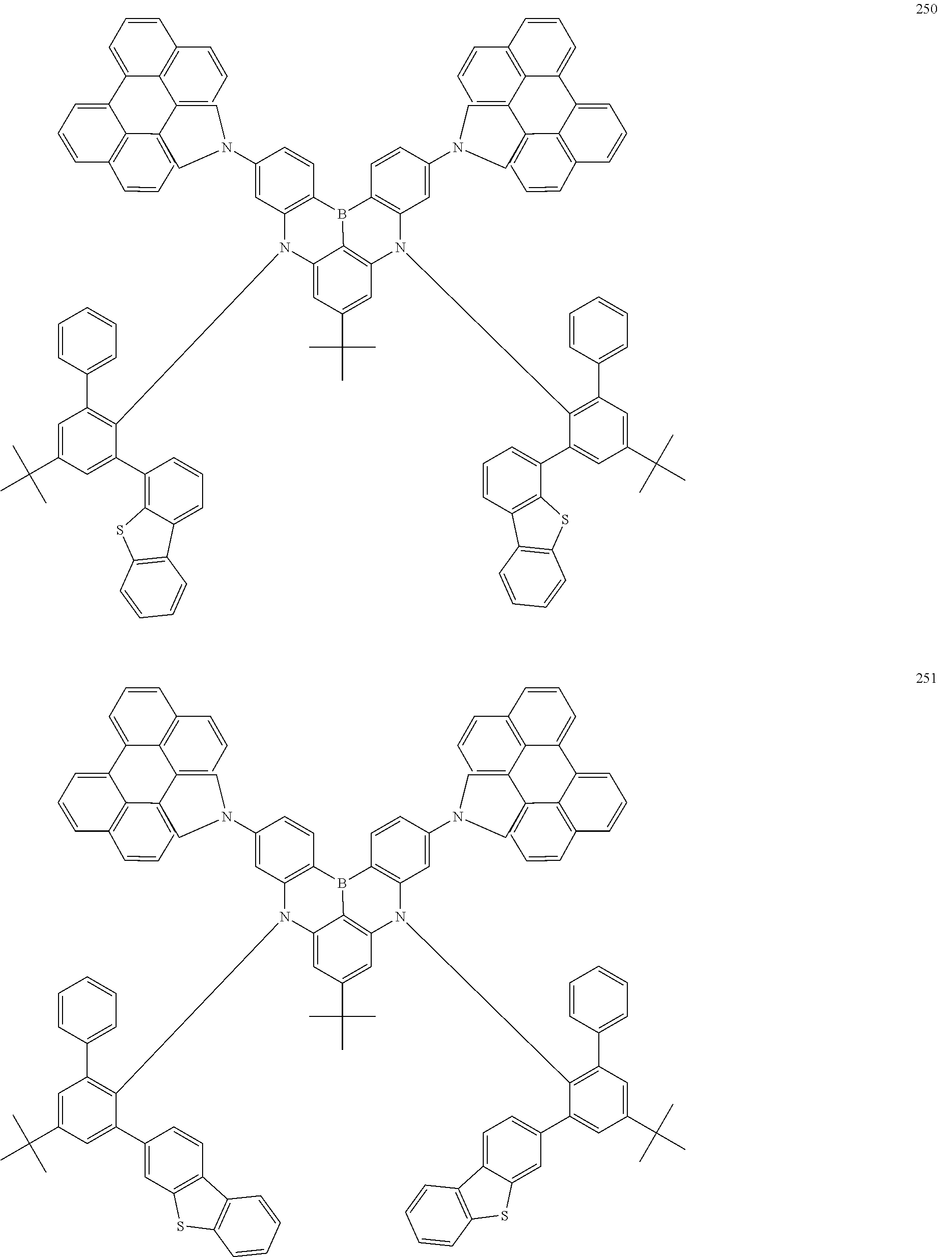

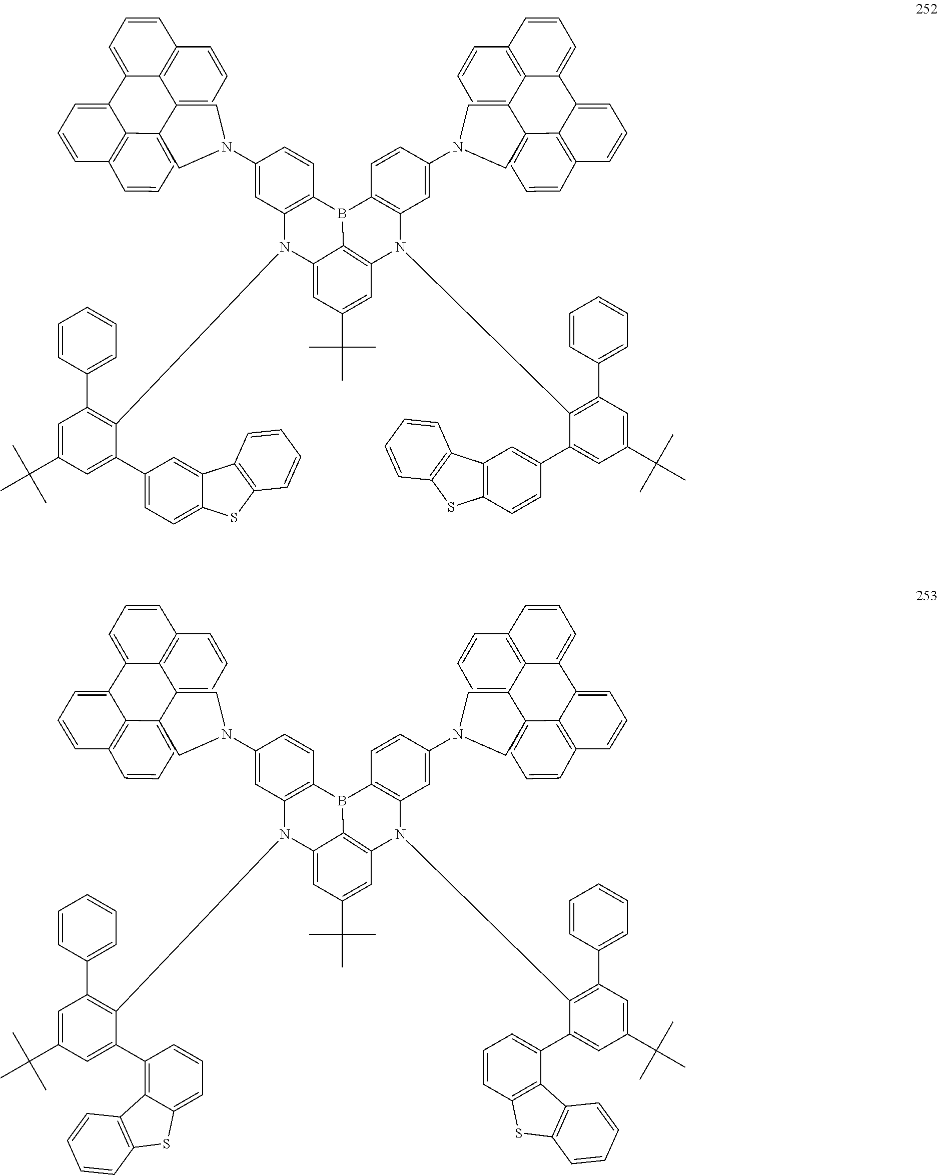

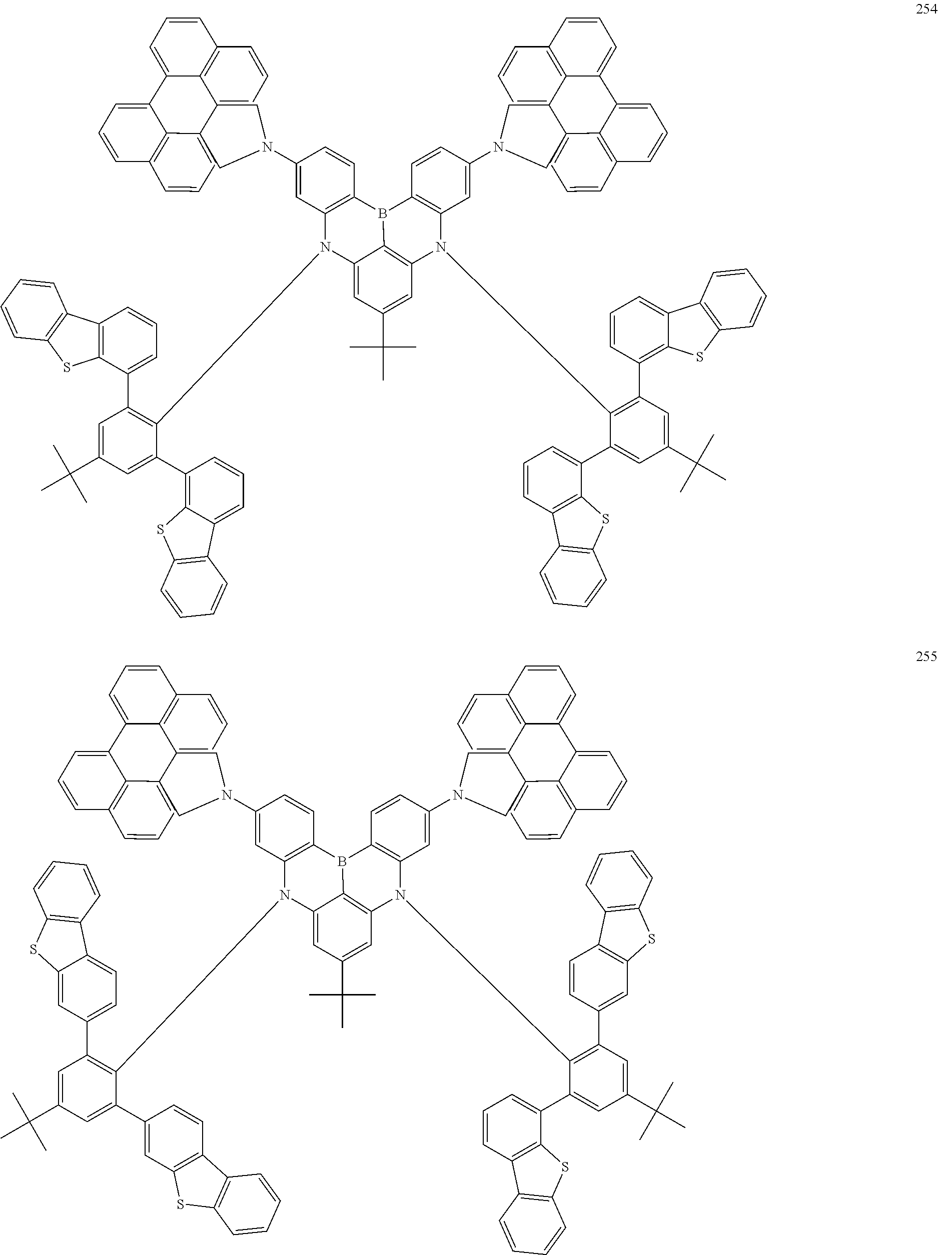

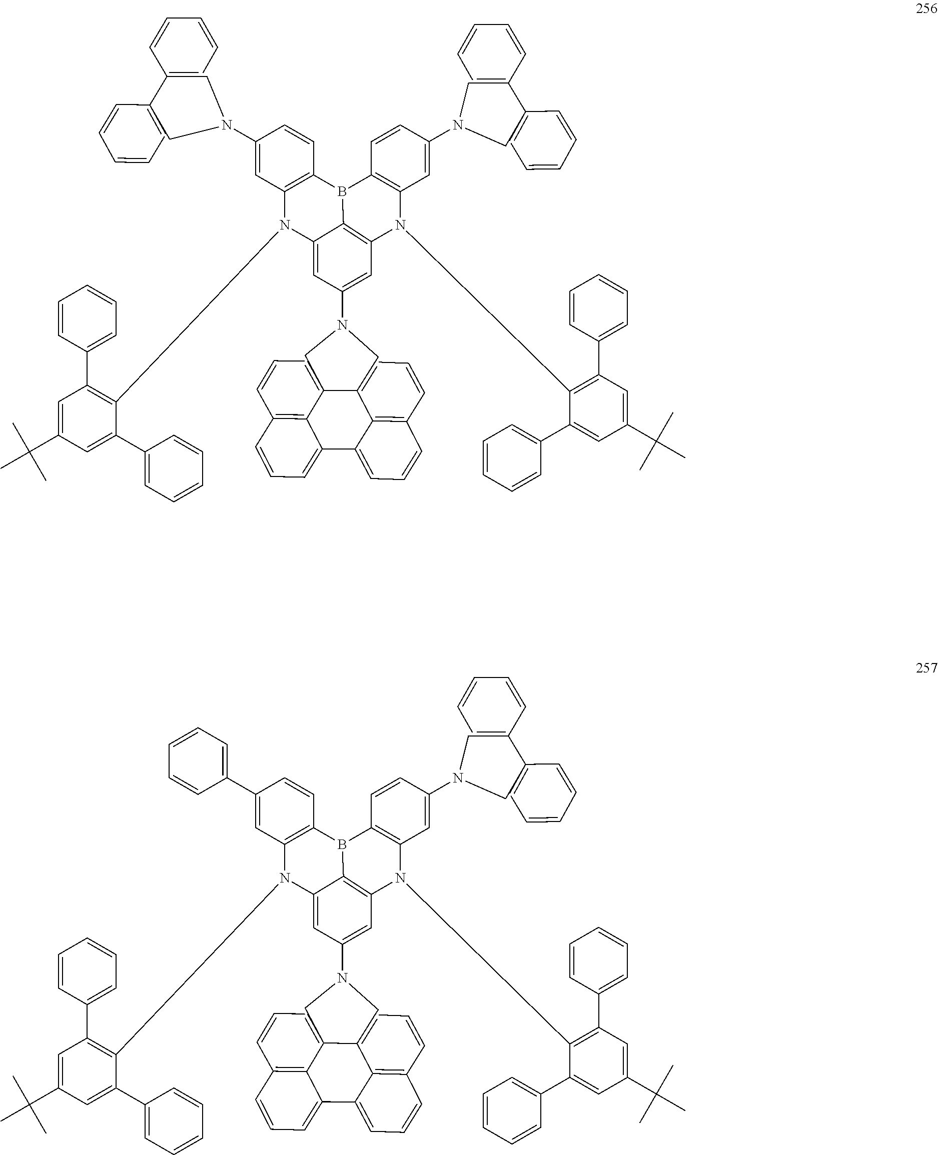

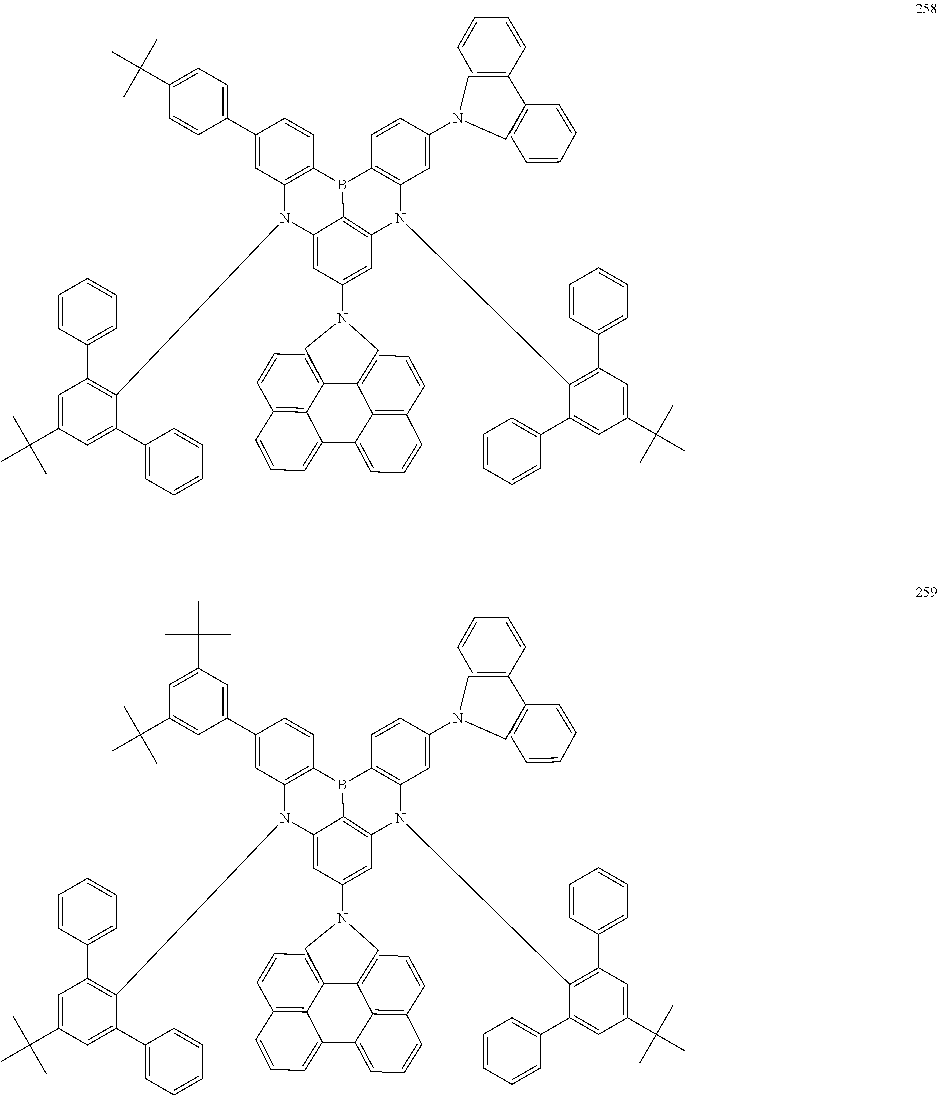

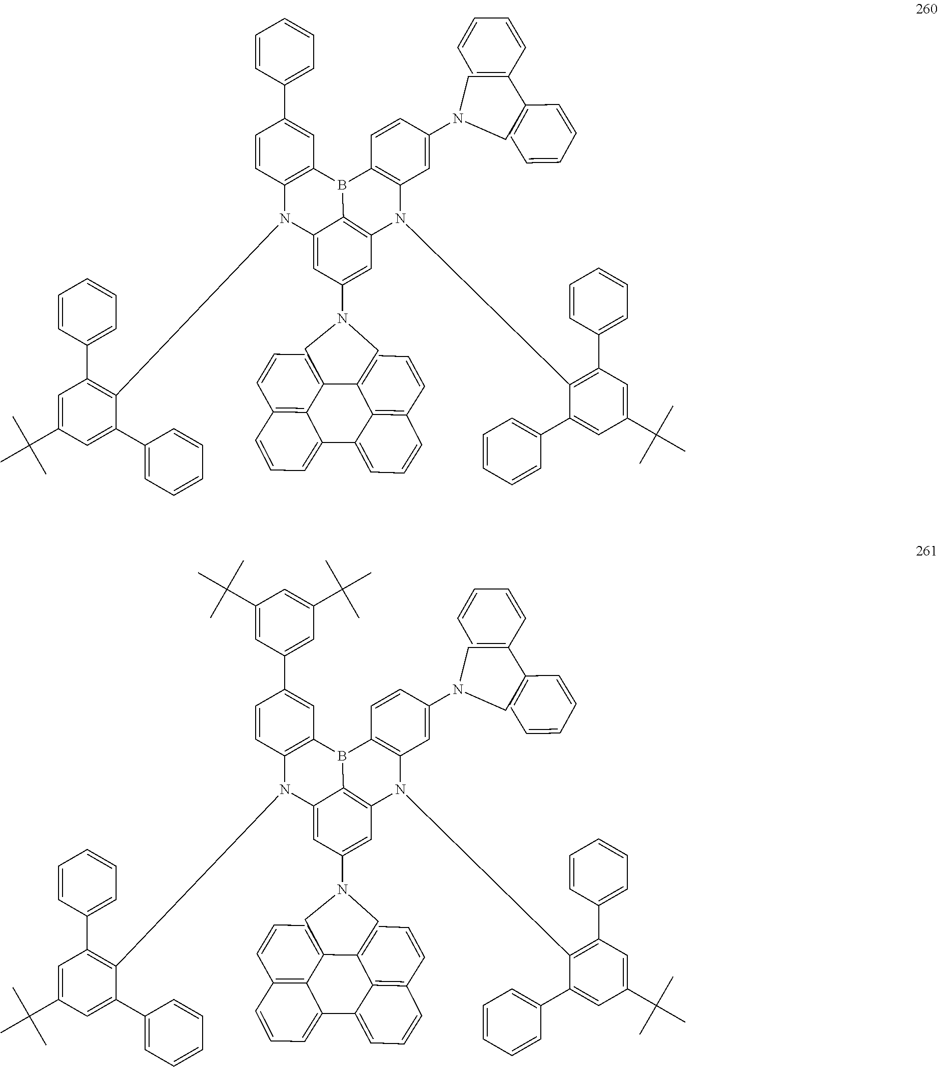

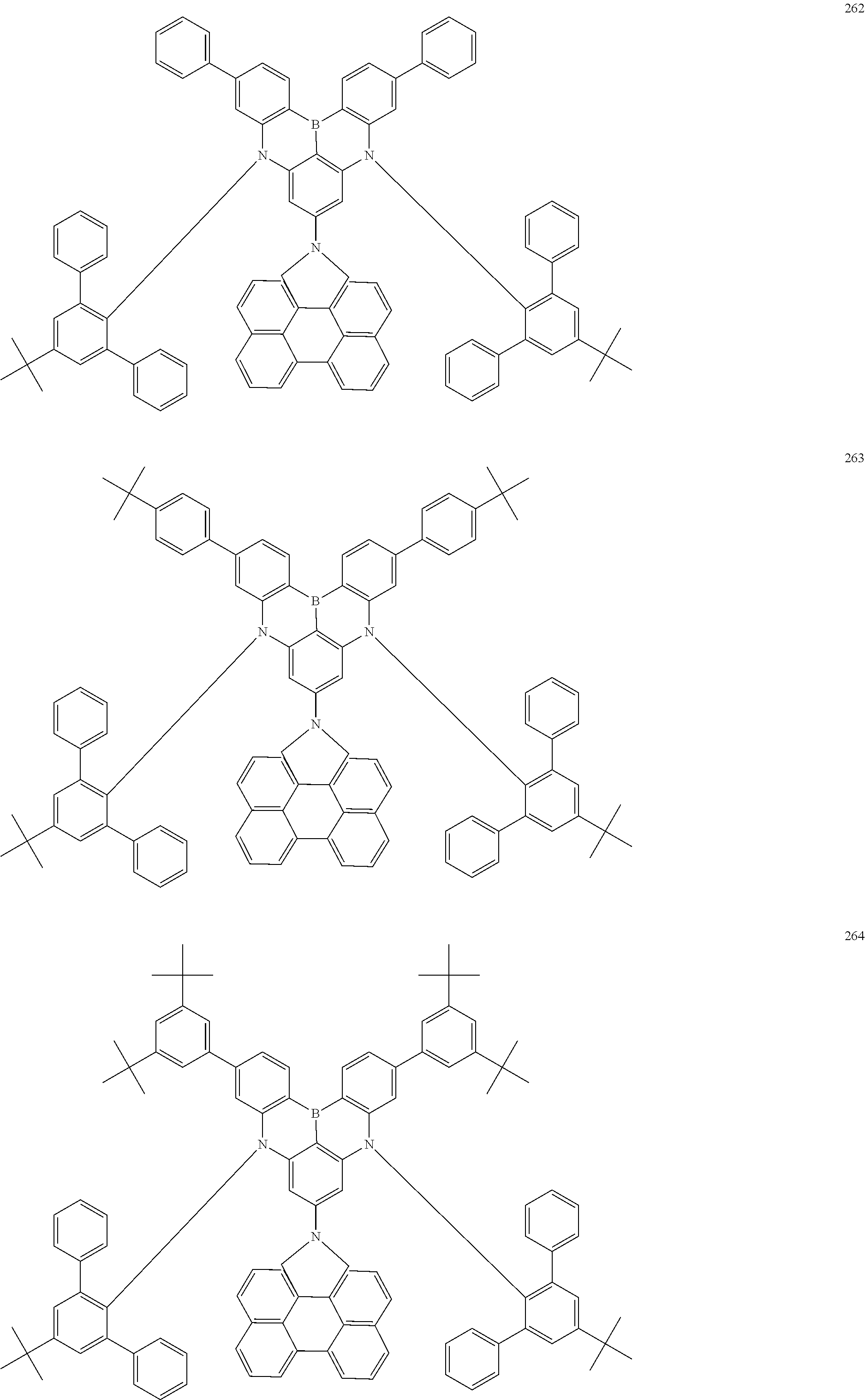

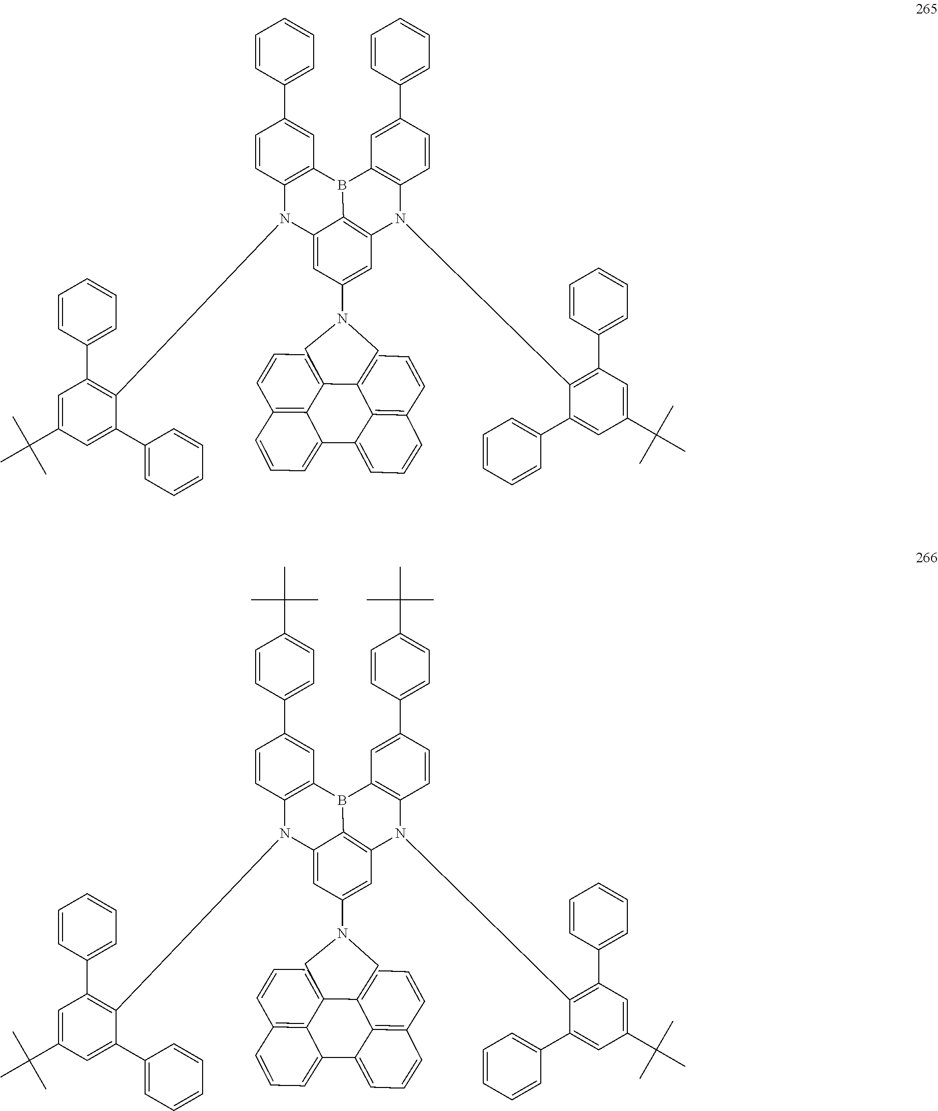

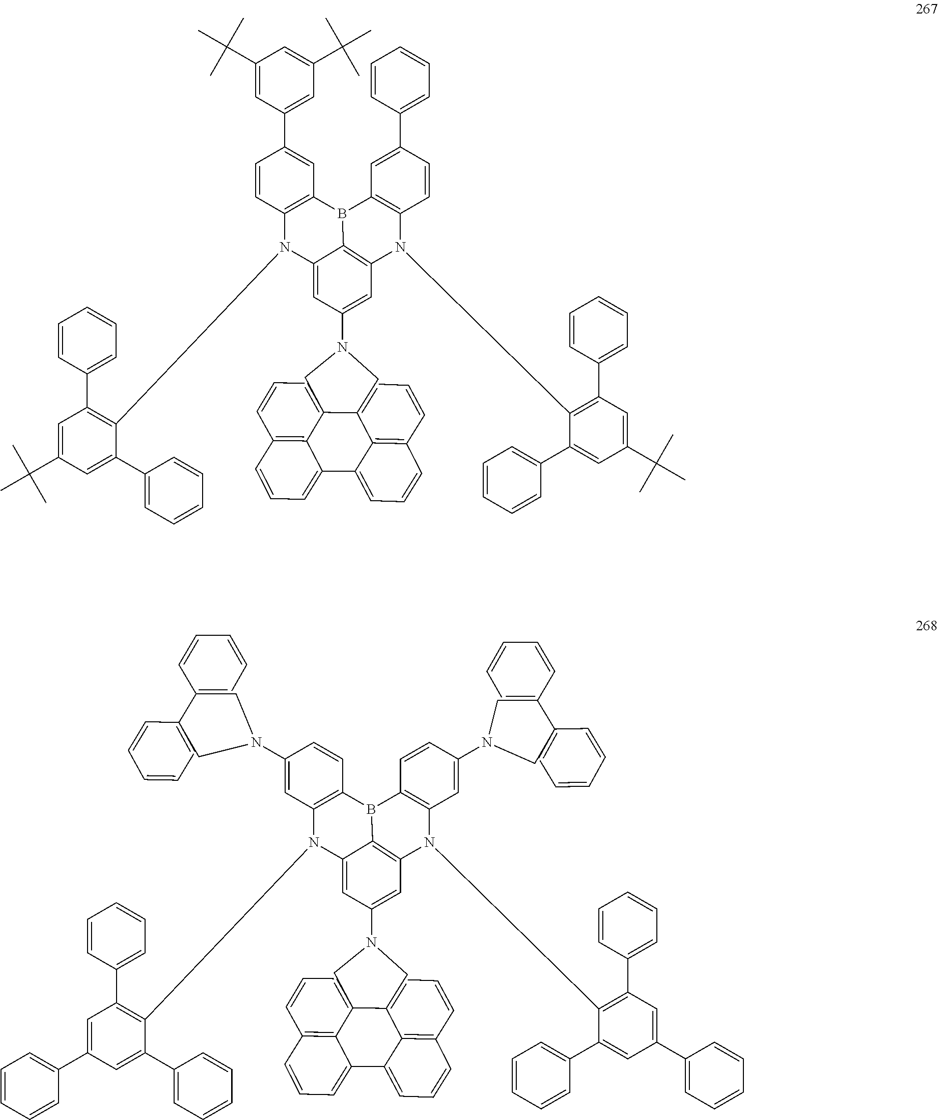

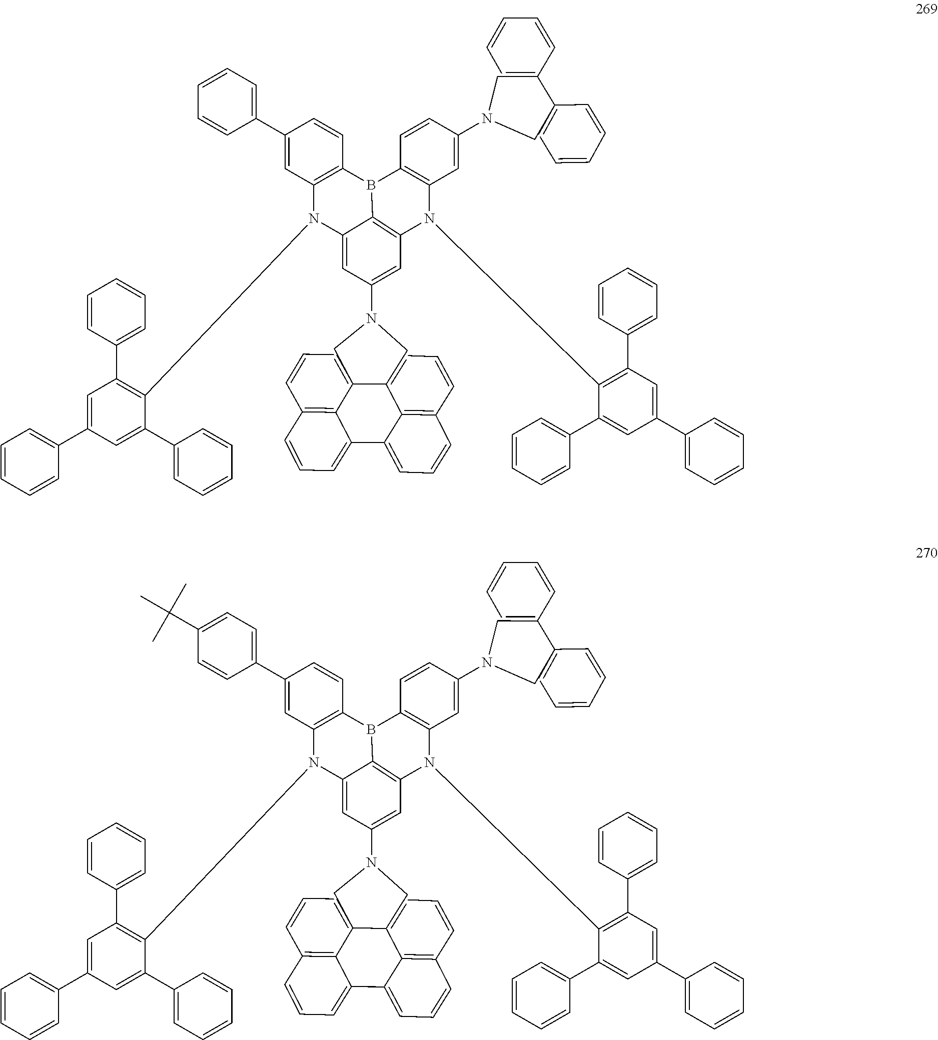

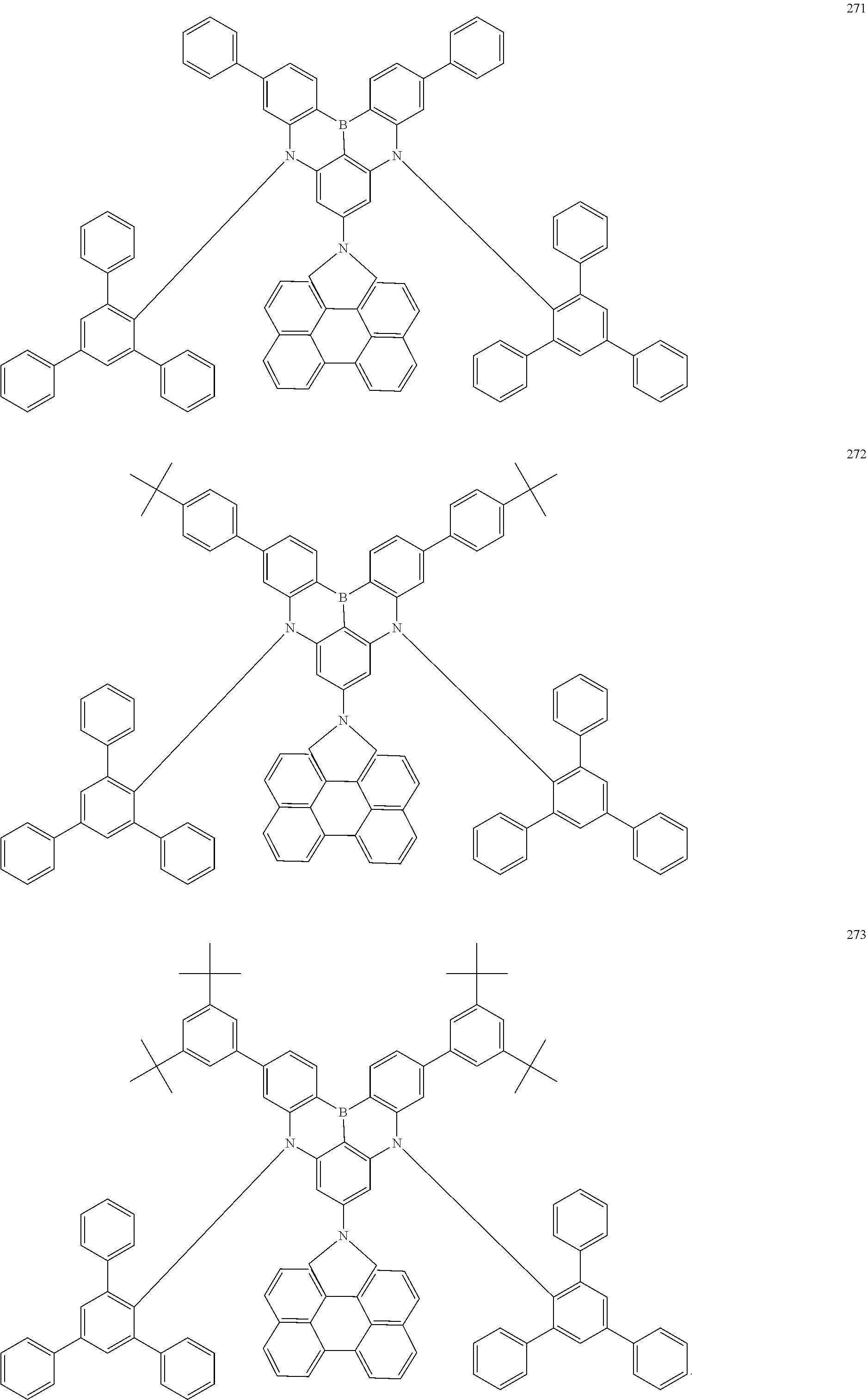

21. An electronic device comprising a display device, the display device comprising:
a circuit layer disposed on a base layer; and
a display element layer disposed on the circuit layer and including a light emitting element, wherein
the light emitting element includes
a first electrode;
a second electrode disposed on the first electrode; and
an emission layer disposed between the first electrode and the second electrode, and
the emission layer comprises a polycyclic compound represented by Formula 1: 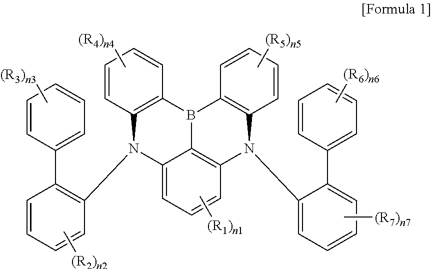
wherein in Formula 1,
R₁ to R₇ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkoxy group having 1 to 60 carbon atoms, a substituted or unsubstituted cycloalkyl group having 3 to 60 ring-forming carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n1 is an integer from 0 to 3,
n2, n4, n5, and n7 are each independently an integer from 0 to 4,
n3 and n6 are each independently an integer from 0 to 5, and
at least one of R₁ to R₇ is each independently a group represented by Formula 2: 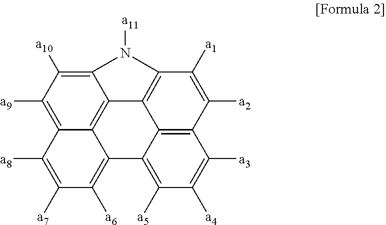
wherein in Formula 2,
one of a₁ to a₁₁ is a position bonded to Formula 1, and
the remainder of a₁ to a₁₁ are each independently a hydrogen atom, a deuterium atom, a substituted or unsubstituted alkyl group having 1 to 30 carbon atoms, or a substituted or unsubstituted aryl group having 6 to 30 ring-forming carbon atoms.
